(19) United States
(12) Patent Application Publication
(10) Pub. No.: US 2025/0241121 A1
(43) Pub. Date: Jul. 24, 2025

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Satomi TASAKI, Tokyo (JP); Emiko KAMBE, Tokyo (JP); Masato NAKAMURA, Tokyo (JP); Sayaka MIZUTANI, Tokyo (JP); Yusuke TAKAHASHI, Tokyo (JP); Yongguk LEE, Tokyo (JP)

(73) Assignee: IDEMITSU KOSAN CO.,LTD., Tokyo (JP)

(21) Appl. No.: 19/001,829

(22) Filed: Dec. 26, 2024

(30) Foreign Application Priority Data
Dec. 27, 2023 (JP) 2023-221823

(51) Int. Cl. H10K 50/16; H10K 50/11; H10K 50/15; H10K 50/18; H10K 85/40; H10K 85/60; H10K 101/10

(52) U.S. Cl. CPC H10K 50/166; H10K 50/11; H10K 50/156; H10K 50/18; H10K 85/40; H10K 85/622; H10K 85/623; H10K 85/626; H10K 85/633; H10K 85/636; H10K 85/654; H10K 85/655; H10K 85/656; H10K 85/6572; H10K 85/6574; H10K 85/6576; H10K 85/658; H10K 2101/10

(57) ABSTRACT

An organic EL device includes first and second emitting units. One or more low refractive index layers are disposed between first and second emitting zones. The one or more low refractive index layers each independently contain an organic material with a refractive index of 1.87 or less, and the organic EL device satisfies Condition (TDM1). Condition (TDM1): two or more low refractive index layers are disposed between the first and second emitting zones, at least two of the two low refractive index layers are in direct contact with each other, a total film thickness of the at least two low refractive index layers in direct contact is 50 nm or more, and at least one of the at least two low refractive index layers in direct contact contains the organic material and at least one selected from the group consisting of metal and a metal compound.

### TECHNICAL FIELD

The present invention relates to an organic electroluminescence device and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. At this time, according to the electron spin statistics theory, singlet excitons and triplet excitons are generated at a ratio of 25%:75%.

The performance of the organic EL device is evaluable in terms of, for instance, luminance, emission wavelength, chromaticity, luminous efficiency, drive voltage, and lifetime. One of the problems with the organic EL device is low light extraction efficiency. Especially, decay due to the reflection caused by the difference in refractive indices between adjacent layers is a main factor in reducing the light extraction efficiency of the organic EL device. An arrangement of the organic EL device including a layer formed from a low refractive index material has been proposed in order to reduce the above effect.

For instance, studies for improving performance of an organic EL device have been made in Literature 1 (International Publication No. WO 2022/154029). Literature 1 describes that using the layer formed from a low refractive index material as an organic layer (e.g. hole transporting layer) in a hole transporting zone reduces light emission loss in an evanescent mode. Further, Literature 1 describes that, as the organic layers (e.g. the hole transporting layer) in the hole transporting zone, the organic layer formed from a high refractive index material is disposed close to an anode and the organic layer formed from a low refractive index material close to an emitting layer, thereby making it possible to reduce light emission loss in a thin film mode.

As an exemplary arrangement of an organic EL device, a tandem organic EL device in which a plurality of emission units are layered is known. For instance, Literature 1 also describes the tandem organic EL device. Further improvement in performance (e.g. improvement in external quantum efficiency) of the tandem organic EL device is desired.

### SUMMARY OF THE INVENTION

An object of the invention is to provide a tandem organic electroluminescence device with improved external quantum efficiency, and to provide an electronic device including such an organic electroluminescence device.

According to an aspect of the invention, there is provided an organic electroluminescence device, including: an anode; a cathode; and two or more emitting units disposed between the anode and the cathode, in which the two or more emitting units include at least a first emitting unit and a second emitting unit, the first emitting unit and the second emitting unit are disposed in this order from a side close to the anode toward a side close to the cathode, the first emitting unit includes a first emitting zone, the second emitting unit includes a second emitting zone, one or more low refractive index layers are disposed between the first emitting zone and the second emitting zone, the one or more low refractive index layers each independently contain an organic material having a refractive index of 1.87 or less, and Condition (TDM1) or (TDM2) below is satisfied.

Condition (TDM1): the one or more low refractive index layers are two or more low refractive index layers, the two or more low refractive index layers are disposed between the first emitting zone and the second emitting zone, at least two of the two or more low refractive index layers are in direct contact with each other, a total film thickness of the at least two low refractive index layers in direct contact is 50 nm or more, and at least one of the at least two low refractive index layers in direct contact contains the organic material and at least one selected from the group consisting of metal and a metal compound.

Condition (TDM2): at least one low refractive index layer having a film thickness of 50 nm or more of the one or more low refractive index layers is disposed between the first emitting zone and the second emitting zone, and the at least one low refractive index layer having a film thickness of 50 nm or more contains the organic material and at least one selected from the group consisting of metal and a metal compound.

According to another aspect of the invention, there is provided an electronic device including the organic electroluminescence device according to the above aspect of the invention.

According to the above aspect of the invention, an organic electroluminescence device with improved external quantum efficiency can be provided. According to the another aspect of the invention, an electronic device including the organic electroluminescence device according to the above aspect can be provided.

### BRIEF DESCRIPTION OF DRAWINGS

FIG. 1 schematically depicts an exemplary arrangement of an organic electroluminescence device according to a first exemplary embodiment of the invention.

FIG. 2 schematically depicts another exemplary arrangement of the organic electroluminescence device according to the first exemplary embodiment of the invention.

### DETAILED DESCRIPTION

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as the ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Mentioned Herein

Substituents mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) and substituted aryl groups (specific example group G1B) below. (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1 B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1 B below with a substituent, and a group derived by further substituting a hydrogen atom of a substituent of the “substituted aryl group” in the specific example group G1 B below with a substituent.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

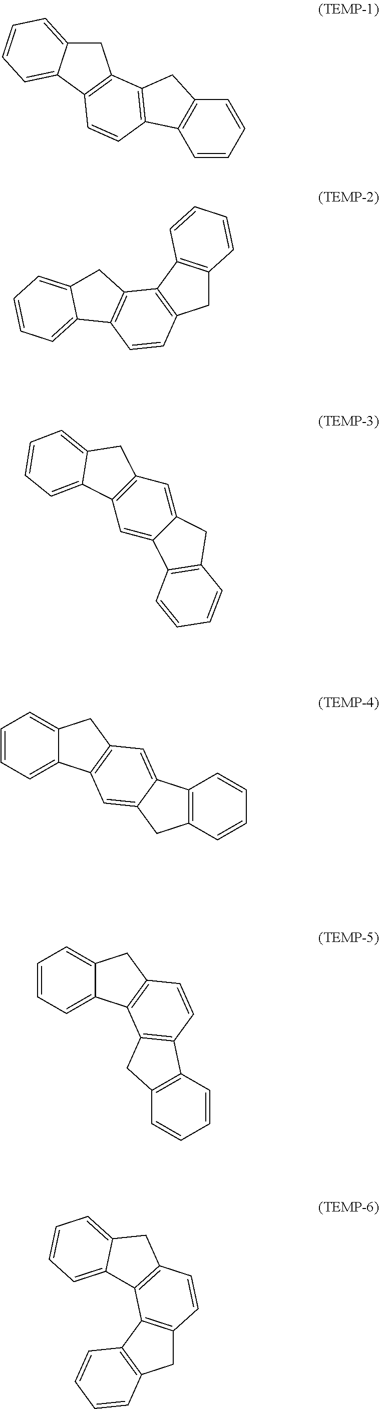

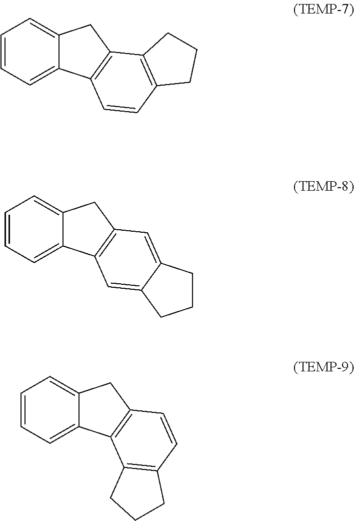

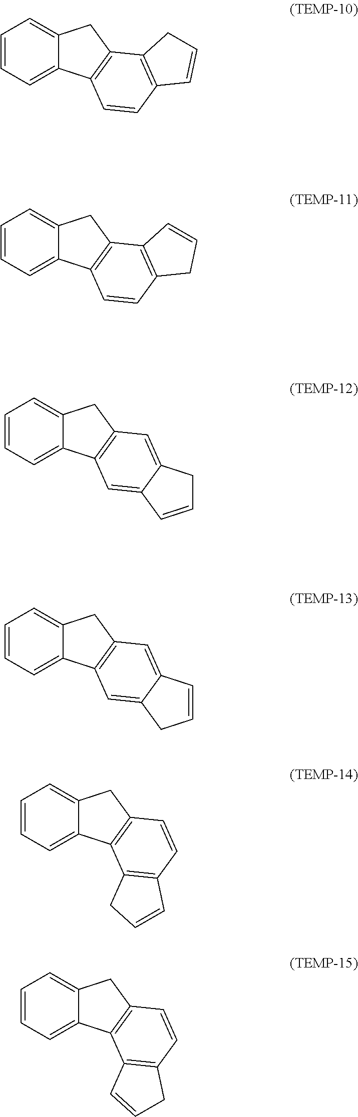

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethyl phenyl group, 9,9-dimethylfluorenyl group, 9,9-diphenylfluorenyl group, 9,9-bis(4-methyl phenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B) below. (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include examples of a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below with a substituent, and a group derived by further substituting a hydrogen atom of a substituent of the “substituted heterocyclic group” in the specific example group G2B below with a substituent.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing one hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by the formulae (TEMP-16) to (TEMP-33) below with a substituent.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

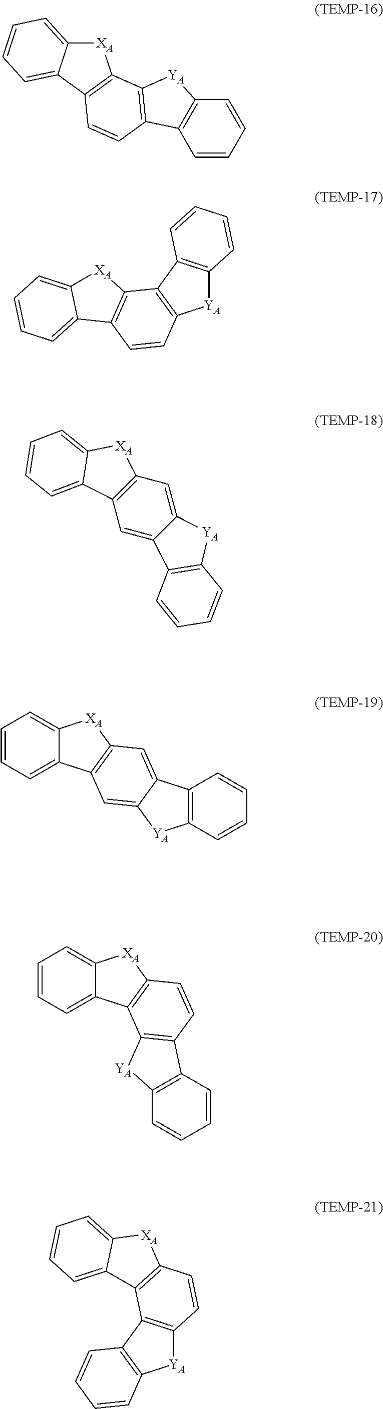

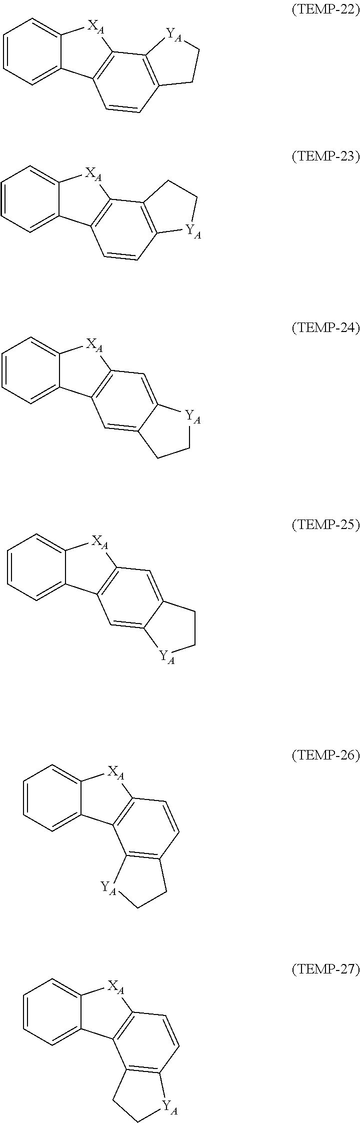

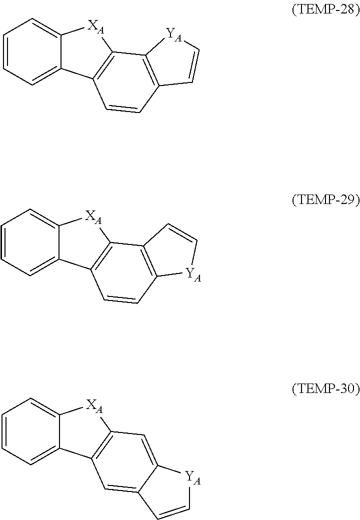

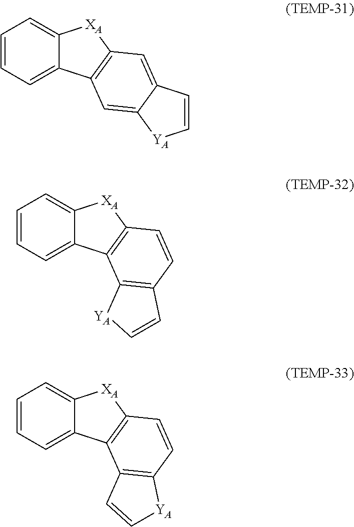

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B with a substituent, and a group derived by further substituting a hydrogen atom of a substituent of the “substituted alkyl group” in the specific example group G3B with a substituent.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include: —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group GB) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1), —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is occasionally referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

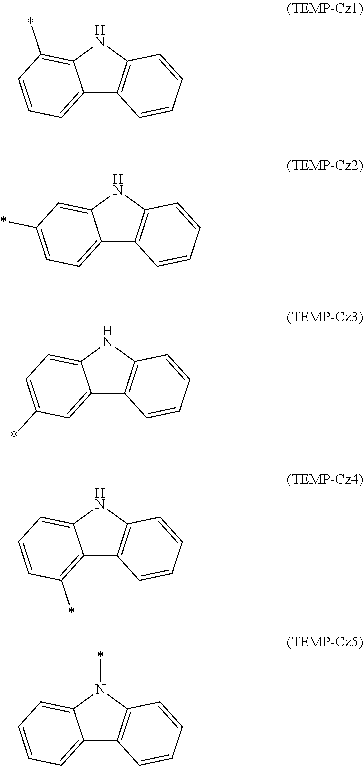 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

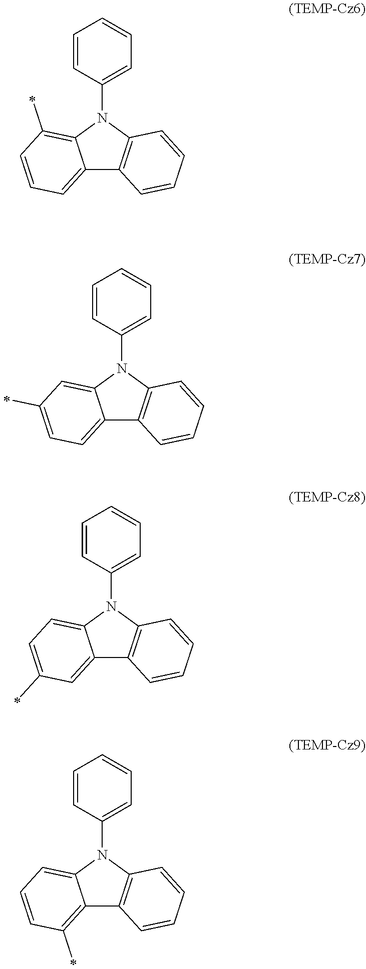

In the formulae (TEMP-Cz1) to (TEMP-Cz9), *represents a bonding position.

The dibenzofuranyl group and dibenzothiophenyl group mentioned herein are, unless otherwise specified herein, each specifically represented by one of formulae below.

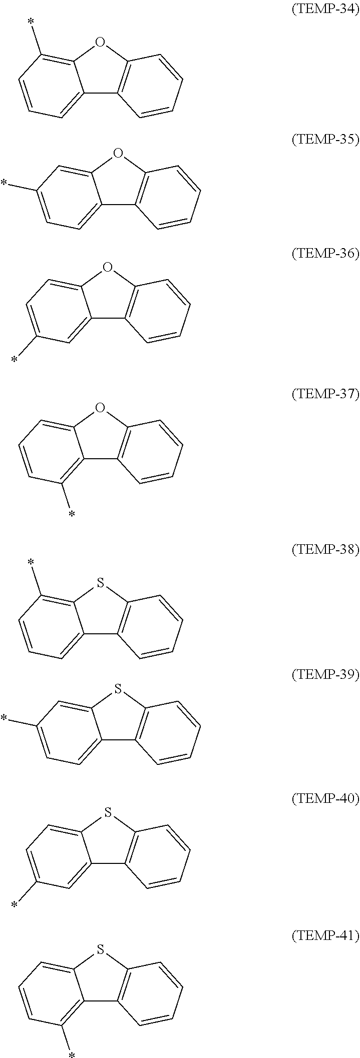

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocycle of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably a group represented by one of formulae (TEMP-42) to (TEMP-68) below.

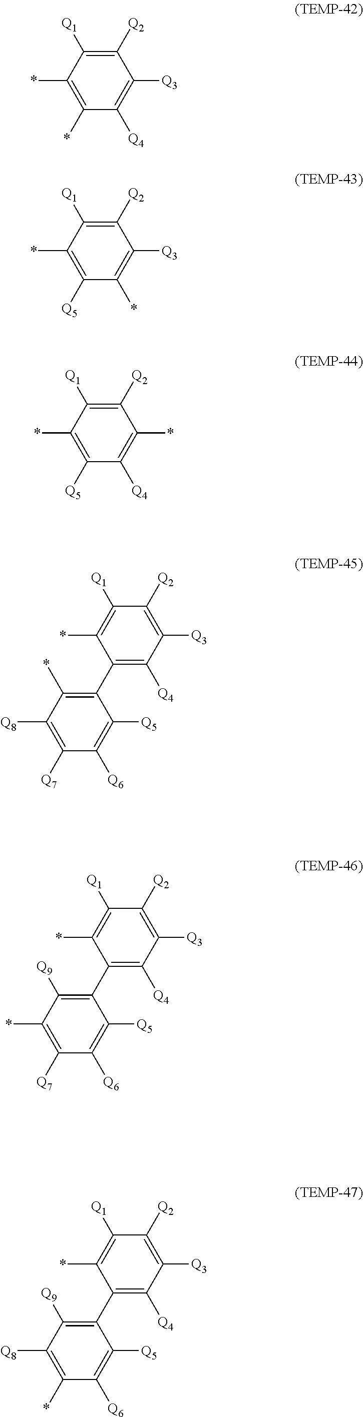

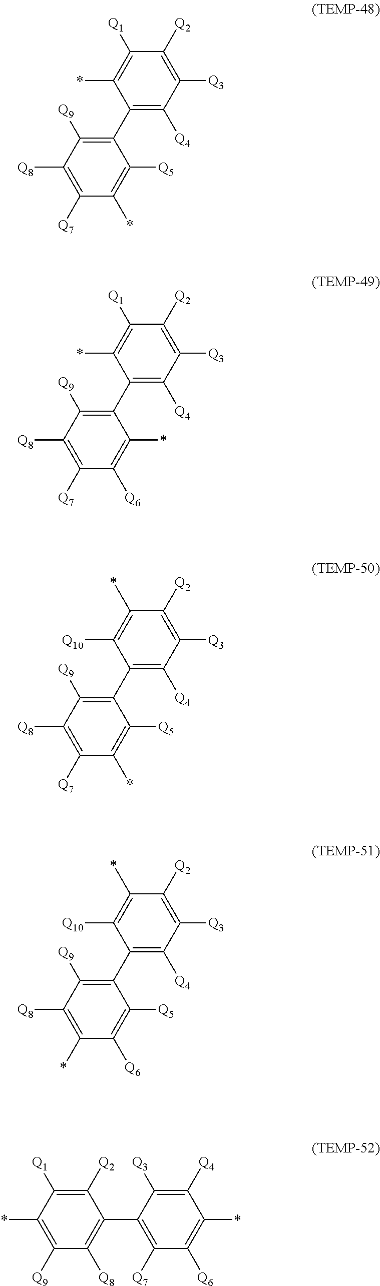

In the formulae (TEMP-42) to (TEMP-52), Q₁ to Q₁₀ are each independently a hydrogen atom or a substituent.

In the formulae (TEMP-42) to (TEMP-52), * represents a bonding position.

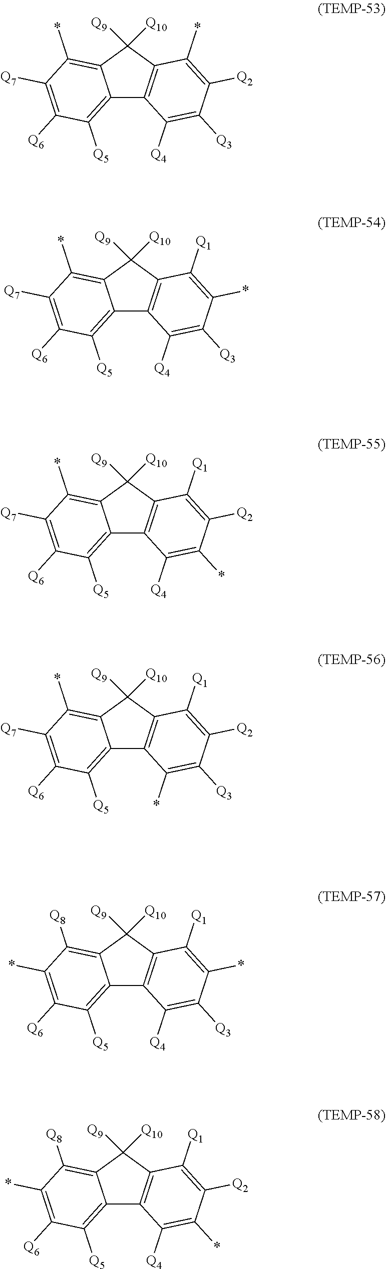

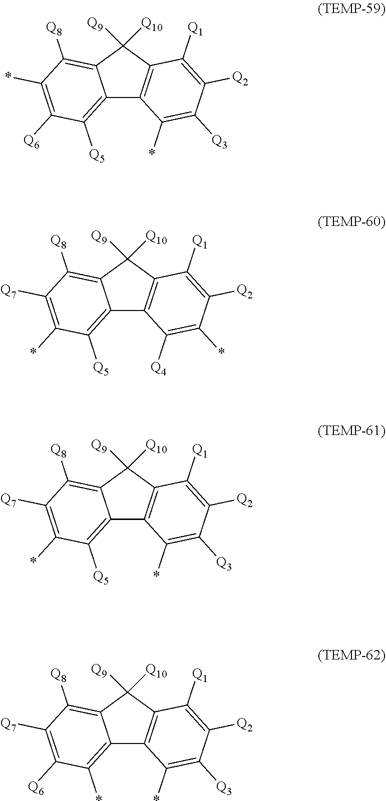

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * represents a bonding position.

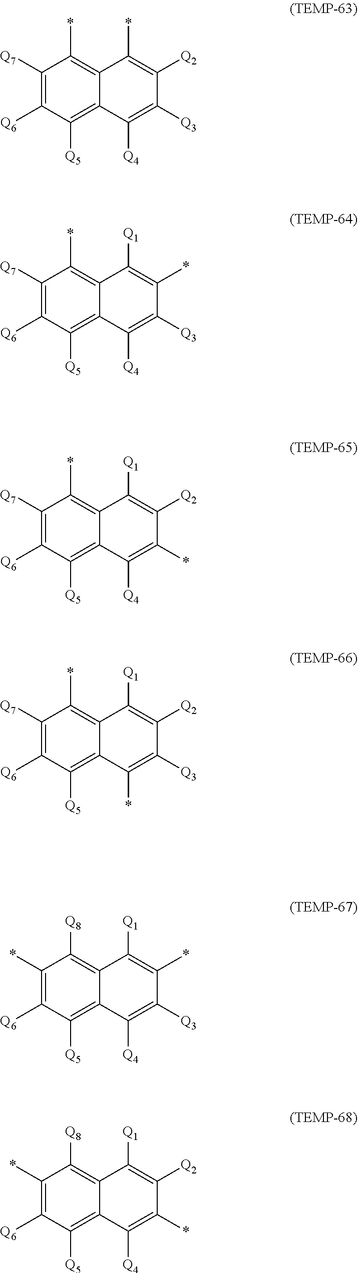

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by one of formulae (TEMP-69) to (TEMP-102) below.

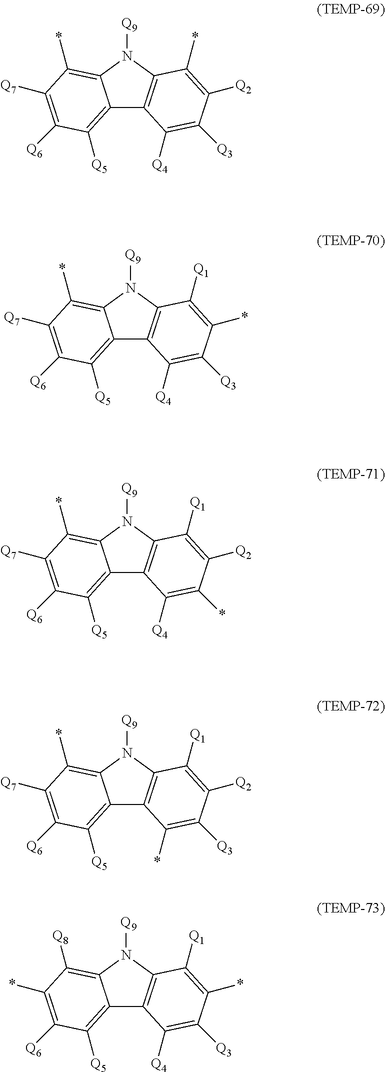

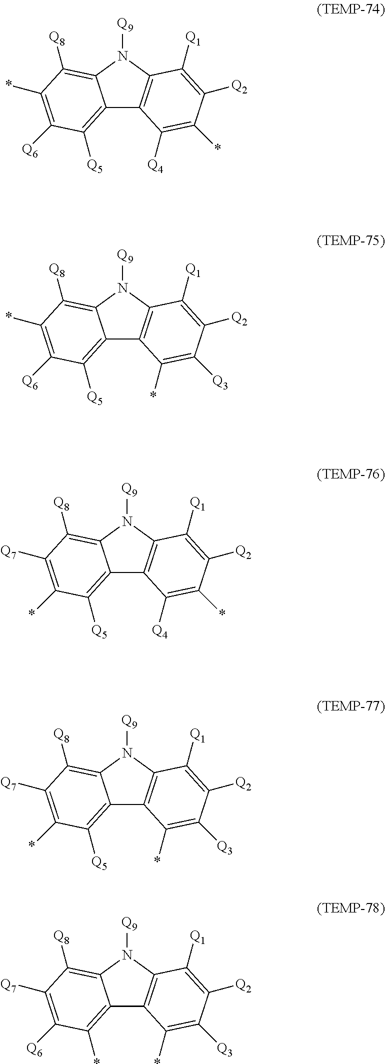

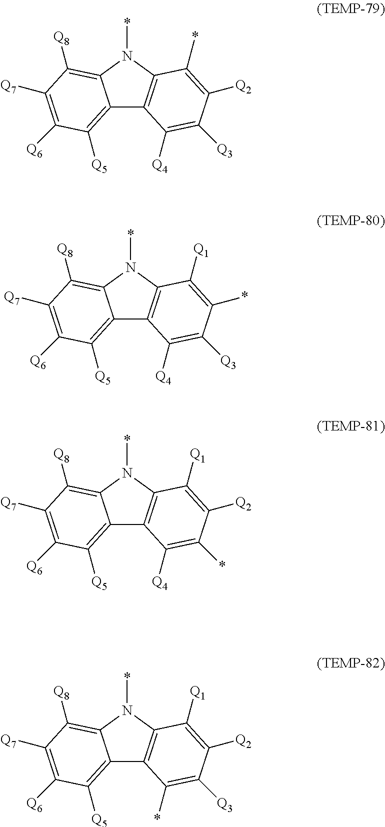

In the formulae (TEMP-69) to (TEMP-82), Q₁ to Q₉ are each independently a hydrogen atom or a substituent.

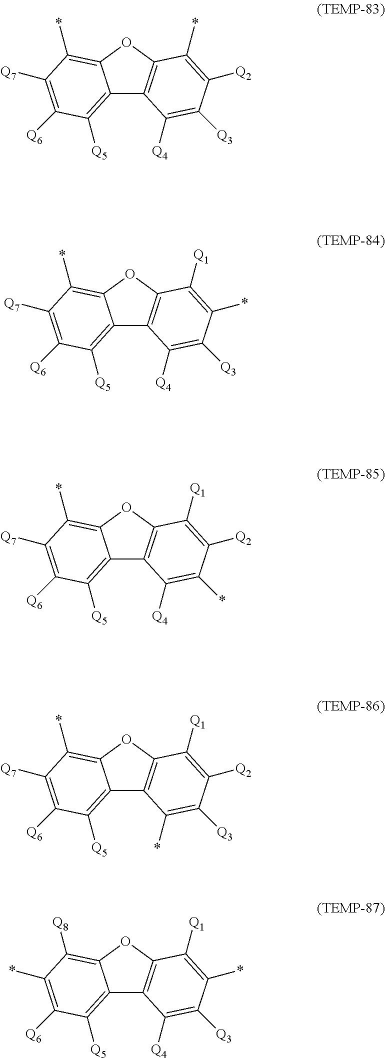

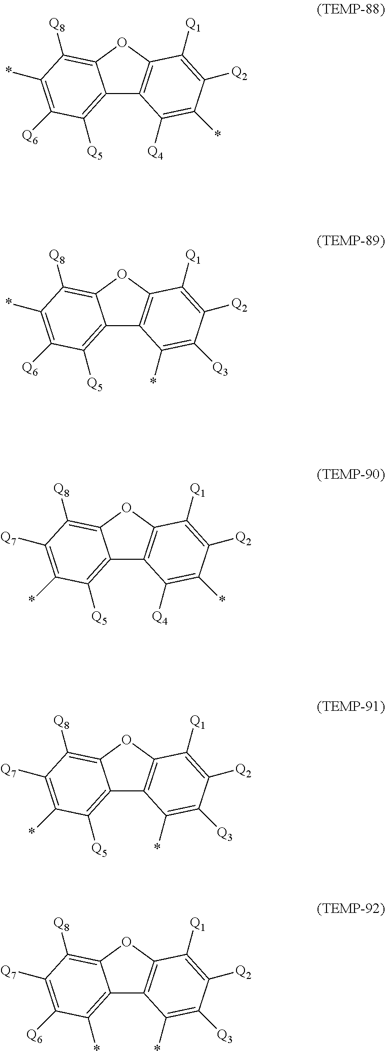

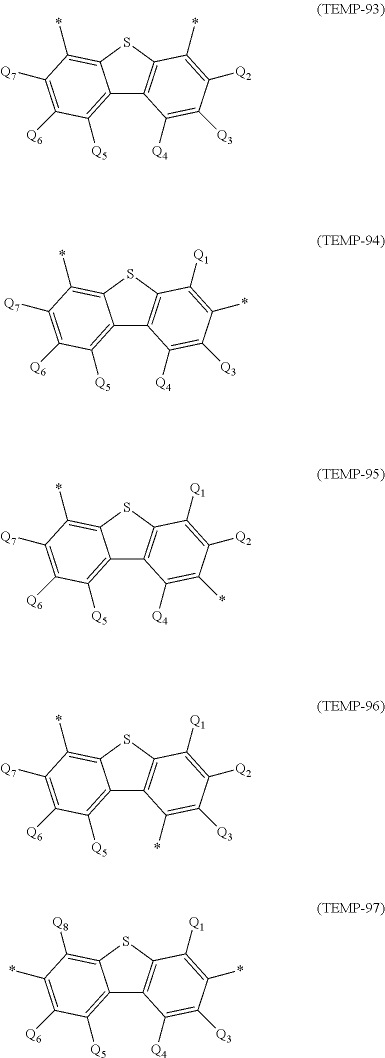

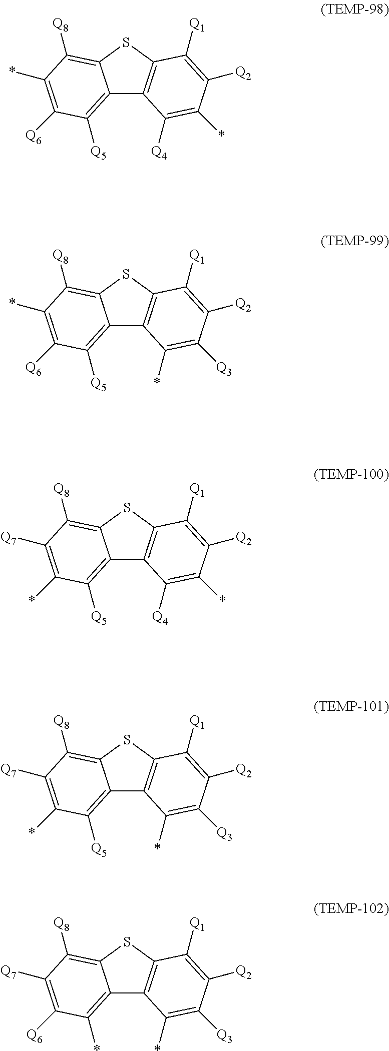

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring”, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

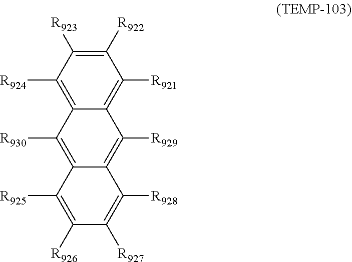

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

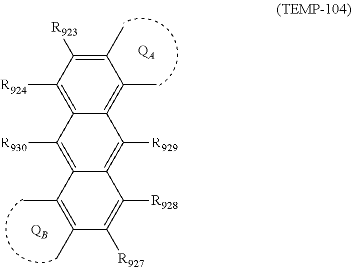

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share P922.

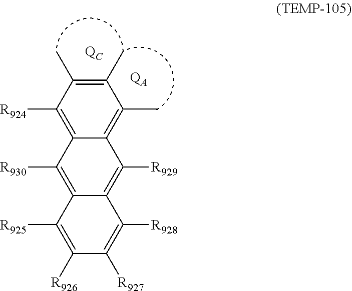

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocycle include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes any other optional atom than the carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, and still more preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

The organic electroluminescence device according to a first exemplary embodiment includes an anode, a cathode, and two or more emitting units disposed between the anode and the cathode, the two or more emitting units include at least a first emitting unit and a second emitting unit, the first emitting unit and the second emitting unit are disposed in this order from a side close to the anode toward a side close to the cathode, the first emitting unit includes a first emitting zone, the second emitting unit includes a second emitting zone, one or more low refractive index layers are disposed between the first emitting zone and the second emitting zone, the one or more low refractive index layers each independently contain an organic material having a refractive index of 1.87 or less, and Condition (TDM1) or (TDM2) below is satisfied.

Condition (TDM1): the one or more low refractive index layers are two or more low refractive index layers, the two or more low refractive index layers are disposed between the first emitting zone and the second emitting zone, at least two of the two or more low refractive index layers are in direct contact with each other, a total film thickness of the at least two low refractive index layers in direct contact is 50 nm or more, and at least one of the at least two low refractive index layers in direct contact contains the organic material and at least one selected from the group consisting of metal and a metal compound.

Condition (TDM2): at least one low refractive index layer having a film thickness of 50 nm or more of the one or more low refractive index layers is disposed between the first emitting zone and the second emitting zone, and the at least one low refractive index layer having a film thickness of 50 nm or more contains the organic material and at least one selected from the group consisting of metal and a metal compound.

A plurality of emitting units disposed between the anode and the cathode are each occasionally referred to as an emitting unit of an X-th tier, an (X+1)-th tier, and an (X+2)-th tier in the order from a side close to the anode (herein, “X” is an integer equal to or greater than 1).

In a tandem organic EL device, if at least one low refractive index layer is disposed between the two emitting zones and a total film thickness of the disposed low refractive index layer(s) is 50 nm or more, at least the light extraction efficiency of an emitting layer in the emitting unit positioned closer to the cathode beyond the low refractive index layer is improved. By disposing the low refractive index layer as described above between an emitting zone in the emitting unit of the X-th tier and an emitting zone in the emitting unit of the (X+1)-th tier, at least the light extraction efficiency of an emitting layer in the emitting unit of the (X+1)-th tier is improved.

In the organic EL device according to the first exemplary embodiment, one or more low refractive index layers are disposed between the first emitting zone in the first emitting unit and the second emitting zone in the second emitting unit and each contain an organic material with a refractive index of 1.87 or less, which satisfies Condition (TDM1) or (TDM2). Satisfying Condition (TDM1) or (TDM2) improves the light extraction efficiency of the emitting layer in the second emitting zone of the second emitting unit.

The organic EL device according to the first exemplary embodiment makes it possible to improve the external quantum efficiency by improving the light extraction efficiency.

The refractive index can be measured by a measurement method described in Examples below. Herein, a value of the refractive index at 2.7 eV in the substrate parallel direction (Ordinary direction) measured by multi-incidence angle spectroscopic ellipsometry measurement is defined as a refractive index of the measurement target material. The refractive index at 2.7 eV corresponds to a refractive index at 460 nm.

### Emitting Unit

The organic EL device according to the first exemplary embodiment is a device that includes a plurality of emitting units between the anode and the cathode. The organic EL device in which a plurality of emitting units are layered is occasionally referred to as the tandem organic EL device.

The organic EL device according to the first exemplary embodiment includes at least the first emitting unit and the second emitting unit as the two or more emitting units. In an exemplary arrangement of the organic EL device according to the first exemplary embodiment, the first emitting unit is an emitting unit disposed closest to the anode. In an exemplary arrangement of the organic EL device according to the first exemplary embodiment, the second emitting unit is an emitting unit disposed closest to the cathode.

In an exemplary arrangement of the organic EL device according to the first exemplary embodiment, the two or more emitting units further include a third emitting unit.

In an exemplary arrangement of the organic EL device according to the first exemplary embodiment, when the organic EL device includes the first, second and third emitting units as the two or more emitting units, the first emitting unit, the second emitting unit, and the third emitting unit may be disposed in this order from a side close to the anode toward a side close to the cathode. In this case, for instance, the first emitting unit, the second emitting unit, and the third emitting unit may be disposed in a first tier, a second tier, and a third tier, respectively. The third emitting unit, the first emitting unit and the second emitting unit may be disposed in this order. In this case, for instance, the third emitting unit, the first emitting unit, and the second emitting unit may be disposed in the first tier, the second tier, and the third tier, respectively.

Further, in an exemplary arrangement of the organic EL device according to the first exemplary embodiment, when the organic EL device includes the first emitting unit, the second emitting unit, the third emitting unit and a fourth emitting unit as four or more emitting units, the first emitting unit (the first tier), the second emitting unit (the second tier), the third emitting unit (the third tier) and the fourth emitting unit (a fourth tier) may be disposed in this order, or the third emitting unit (the first tier), the first emitting unit (the second tier), the second emitting unit (the third tier) and the fourth emitting unit (the fourth tier) may be disposed in this order.

### Emitting Zone

In the organic EL device according to the first exemplary embodiment, the two or more emitting units each independently include an emitting zone. That is, the organic EL device according to the first exemplary embodiment includes two or more emitting zones. In the organic EL device according to the first exemplary embodiment the first emitting unit includes the first emitting zone and the second emitting unit includes the second emitting zone.

In the organic EL device according to the first exemplary embodiment, the emitting zones each independently include at least one emitting layer. In an exemplary arrangement of the organic EL device according to the first exemplary embodiment, the emitting zones may each independently include only one emitting layer or two or more emitting layers. In an exemplary arrangement of the organic EL device according to the first exemplary embodiment, the emitting layers each independently contain a host material. In an exemplary arrangement of the organic EL device according to the first exemplary embodiment, the emitting layers each independently contain the host material and a luminescent compound. In an exemplary arrangement of the organic EL device according to the first exemplary embodiment, the luminescent compound contained in each emitting layer is fluorescent or phosphorescent. In the organic EL device according to the first exemplary embodiment, at least one of the emitting layers preferably contains a fluorescent compound.

In an exemplary arrangement of the organic EL device according to the first exemplary embodiment, the first emitting zone includes a first emitting layer.

In an exemplary arrangement of the organic EL device according to the first exemplary embodiment, the first emitting layer contains a first host material.

In an exemplary arrangement of the organic EL device according to the first exemplary embodiment, the first emitting zone contains a first luminescent compound.

In an exemplary arrangement of the organic EL device according to the first exemplary embodiment, the first emitting layer contains the first luminescent compound.

In an exemplary arrangement of the organic EL device according to the first exemplary embodiment, the first emitting layer contains the first host material and the first luminescent compound.

In an exemplary arrangement of the organic EL device according to the first exemplary embodiment, the second emitting zone includes a second emitting layer.

In an exemplary arrangement of the organic EL device according to the first exemplary embodiment, the second emitting layer contains a second host material.

In an exemplary arrangement of the organic EL device according to the first exemplary embodiment, the second emitting zone contains a second luminescent compound.

In an exemplary arrangement of the organic EL device according to the first exemplary embodiment, the second emitting layer contains the second luminescent compound.

In an exemplary arrangement of the organic EL device according to the first exemplary embodiment, the second emitting layer contains the second material and the second luminescent compound.

In an exemplary arrangement of the organic EL device according to the first exemplary embodiment, the first luminescent compound and the second luminescent compound are mutually the same or different.

In an exemplary arrangement of the organic EL device according to the first exemplary embodiment, one or both of the first and second luminescent compounds are compounds that emit light having a maximum peak wavelength of 500 nm or less.

In an exemplary arrangement of the organic EL device according to the first exemplary embodiment, one or both of the first and second luminescent compounds are compounds that emit light having a maximum peak wavelength of 480 nm or less.

In an exemplary arrangement of the organic EL device according to the first exemplary embodiment, one or both of the first and second luminescent compounds are compounds that emit light having a maximum peak wavelength of 430 nm or more.

A method of measuring the maximum peak wavelength of the compound is as follows. A toluene solution of a measurement target compound at a concentration ranging from 10⁻⁶ mol/L to 10⁻⁵ mol/L is prepared and put in a quartz cell. An emission spectrum of the thus-obtained sample is measured at a normal temperature (300K). The emission spectrum is measured with an ordinate axis representing luminous intensity, an abscissa axis representing wavelength. The emission spectrum can be measured using a spectrophotofluorometer (machine name: F-7000) produced by Hitachi High-Tech Science Corporation. The machine for measuring the emission spectrum is not limited to the machine used herein.

### Host Material and Dopant Material

In an exemplary arrangement of the organic EL device according to the exemplary embodiment, at least one emitting layer in the emitting zone each independently contains a host material and a dopant material. The host material is occasionally referred to as a matrix material. The dopant material is occasionally referred to as a luminescent compound, guest material, emitter or emitting material.

In an exemplary arrangement of the organic EL device according to the exemplary embodiment, at least one emitting layer in the emitting zone each independently contains at least one dopant material selected from the group consisting of dopant materials below and at least one host material selected from the group consisting of host materials below.

### Dopant Material for Emitting Layer

The emitting layer is a layer containing a highly luminescent substance and a variety of materials are usable. For instance, a fluorescent compound exhibiting fluorescence and a phosphorescent compound exhibiting phosphorescence are usable as the highly luminescent substance. The fluorescent compound is a compound capable of emitting from a singlet state. The phosphorescent compound is a compound capable of emitting from a triplet state.

Examples of a blue fluorescent material usable for the emitting layer include a pyrene derivative, styrylamine derivative, chrysene derivative, fluoranthene derivative, fluorene derivative, diamine derivative, and triarylamine derivative. Specific examples thereof include N,N′-bis[4-(9H-carbazole-9-yl)phenyl]-N,N′-diphenylstilbene-4,4′-diamine (abbreviation: YGA2S), 4-(9H-carbazole-9-yl)-4′-(10-phenyl-9-anthryl)triphenylamine (abbreviation: YGAPA), and 4-(10-phenyl-9-anthryl)-4′-(9-phenyl-9H-carbazole-3-yl)triphenylamine (abbreviation: PCBAPA).

Examples of a green fluorescent material usable for the emitting layer include an aromatic amine derivative. Specific examples thereof include N-(9,10-diphenyl-2-anthryl)-N,9-diphenyl-9H-carbazole-3-amine (abbreviation: 2PCAPA), N-[9,10-bis(1,1′-biphenyl-2-yl)-2-anthryl]-N,9-diphenyl-9H-carbazole-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylene diamine (abbreviation: 2DPABPhA), N-[9,10-bis(1,1′-biphenyl-2-yl)]-N-[4-(9H-carbazole-9-yl)phenyl]-N-phenylanthracene-2-amine (abbreviation: 2YGABPhA), and N,N,9-triphenylanthracene-9-amine (abbreviation: DPhAPhA).

Examples of a red fluorescent material usable for the emitting layer include a tetracene derivative and a diamine derivative. Specific examples thereof include N,N,N′,N′-tetrakis(4-methylphenyl)tetracene-5,11-diamine (abbreviation: p-mPhTD), and 7,14-diphenyl-N,N,N′,N′-tetrakis(4-methylphenyl)acenaphtho[1,2-a]fluoranthene-3,10-diamine (abbreviation: p-mPhAFD).

Examples of a blue phosphorescent material usable for the emitting layer include metal complexes such as an iridium complex, osmium complex and platinum complex. Specific examples thereof include bis[2-(4′,6′-difluorophenyl)pyridinato-N,C2′]iridium(II)tetrakis(1-pyrazolyl)borate (abbreviation: Flr6), bis[2-(4′,6′-difluorophenyl)pyridinato-N,C2′]iridium(III)picolinate (abbreviation: Flrpic), bis[2-(3′,5′bistrifluoromethylphenyl)pyridinato-N,C2′]iridium(III)picolinate (abbreviation: Ir(CF₃ppy)₂(pic)), and bis[2-(4′,6′-difluorophenyl)pyridinato-N,C2′]iridium(III)acetylacetonato (abbreviation: Flracac).

Examples of a green phosphorescent material usable for the emitting layer include an iridium complex. Specific examples thereof include tris(2-phenylpyridinato-N,C2′)iridium(III) (abbreviation: Ir(ppy)₃), bis(2-phenylpyridinato-N,C2′)iridium(III)acetylacetonato (abbreviation: Ir(ppy)₂(acac)), bis(1,2-diphenyl-1H-benzimidazolato)iridium(III)acetylacetonato (abbreviation: Ir(pbi)₂(acac)), and bis(benzo[h]quinolinato)iridium(III)acetylacetonato (abbreviation: Ir(bzq)₂(acac)).

Examples of a red phosphorescent material usable for the emitting layer include metal complexes such as an iridium complex, platinum complex, terbium complex, and europium complex. Specific examples thereof include an organic metal complex such as bis[2-(2′-benzo[4,5-a]thienyl)pyridinato-N,C3′]iridium(III)acetylacetonato (abbreviation: Ir(btp)₂(acac)), bis(1-phenylisoquinolinato-N,C2′)iridium(III)acetylacetonato (abbreviation: Ir(piq)₂(acac)), (acetylacetonato)bis[2,3-bis(4-fluorophenyl)quinoxalinato]iridium(III) (abbreviation: Ir(Fdpq)₂(acac)), and 2,3,7,8,12,13,17,18-octaethyl-21H,23H-porphyrinplatinum(II) (abbreviation: PtOEP).

Moreover, since a rare-earth metal complex, examples of which include tris(acetylacetonato)(monophenanthroline)terbium(III) (abbreviation: Tb(acac)₃(Phen)), tris(1,3-diphenyl-1,3-propanedionato)(monophenanthroline)europium(III) (abbreviation: Eu(DBM)₃(Phen)), and tris[1-(2-thenoyl)-3,3,3-trifluoroacetonato](monophenanthroline)europium(III) (abbreviation: Eu(TTA)₃(Phen)), emits light from rare-earth metal ions (electron transition between different multiplicities), the rare-earth metal complex is usable as a phosphorescent compound.

### Compound Represented by Formula (2)

In an exemplary arrangement of the organic EL device according to the first exemplary embodiment, the dopant material (luminescent compound) is a compound represented by the formula (2) below. In an exemplary arrangement of the organic EL device according to the first exemplary embodiment, the first luminescent compound and the second luminescent compound are each a compound represented by the formula (2) below. The compound represented by the formula (2) below is occasionally referred to as a second compound.

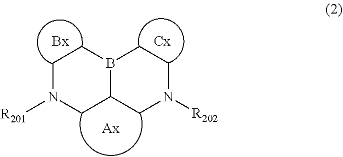

In the formula (2):
a ring Ax, a ring Bx and a ring Cx are each independently a substituted or unsubstituted aromatic hydrocarbon ring having 6 to 50 ring carbon atoms, or a substituted or unsubstituted heterocycle having 5 to 50 ring atoms:
R₂₀₁ and R₂₀₂ are each independently bonded with the ring Ax, the ring Bx or the ring Cx to form a substituted or unsubstituted monocyclic ring, bonded with the ring Ax, the ring Bx or the ring Cx to form a substituted or unsubstituted fused ring, or not bonded with the ring Ax, the ring Bx or the ring Cx;
R₂₀₁ and R₂₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, an iminyl group represented by —CR₂₅═N, a substituted or unsubstituted aryl group having 6 to 50 ring carbon atoms, or a substituted or unsubstituted heterocyclic group having 5 to 50 ring atoms; and
R₂₅ is a substituted or unsubstituted aryl group having 6 to 60 ring carbon atoms, a substituted or unsubstituted heterocyclic group having 5 to 60 ring atoms, a substituted or unsubstituted alkyl group having 1 to 20 carbon atoms, or a substituted or unsubstituted cycloalkyl group having 3 to 20 ring carbon atoms, and when a plurality of R₂₅ are present, the plurality of R₂₅ are mutually the same or different.

In an exemplary arrangement of the organic EL device according to the first exemplary embodiment, the second compound is a compound represented by a formula (21) or (22) below.

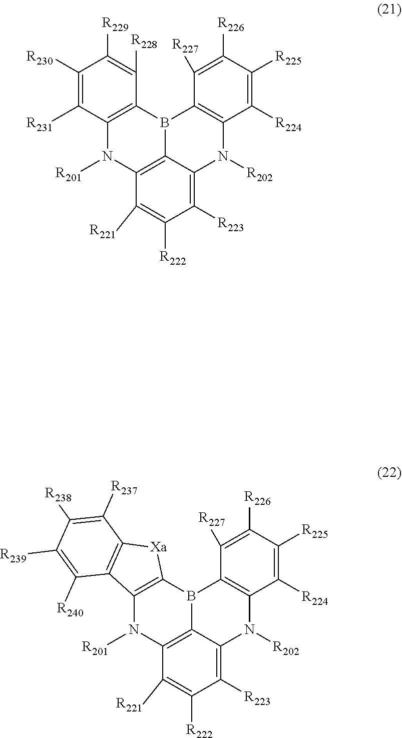

In the formula (21):
at least one combination selected from the group consisting of a combination of R₂₀₁ and R₂₂₁, a combination of adjacent two or more of R₂₂₁ to R₂₂₃, a combination of R₂₂₃ and R₂₀₂, a combination of R₂₀₂ and R₂₂₄, a combination of adjacent two or more of R₂₂₄ to R₂₂₇, a combination of R₂₂₇ and R₂₂₈, a combination of adjacent two or more of R₂₂₈ to R₂₃₁, and a combination of R₂₃₁ and R₂₀₁ are mutually bonded to form a substituted or unsubstituted monocyclic ring, mutually bonded to form a substituted or unsubstituted fused ring, or not mutually bonded; and
R₂₀₁ and R₂₀₂ forming neither the substituted or unsubstituted monocyclic ring nor the substituted or unsubstituted fused ring respectively represent the same as R₂₀₁ and R₂₀₂ in the formula (2).

In the formula (22):
Xa is O, S, Se, C(R₂₀₃)(R₂₀₄), or N(R₂₀₅);
at least one combination selected from the group consisting of a combination of R₂₀₁ and R₂₂₁, a combination of adjacent two or more of R₂₂₁ to R₂₂₃, a combination of R₂₂₃ and R₂₀₂, a combination of R₂₀₂ and R₂₂₄, a combination of adjacent two or more of R₂₂₄ to R₂₂₇, and a combination of adjacent two or more of R₂₃₇ to R₂₄₀ are mutually bonded to form a substituted or unsubstituted monocyclic ring, mutually bonded to form a substituted or unsubstituted fused ring, or not mutually bonded; and
R₂₀₁ and R₂₀₂ forming neither the substituted or unsubstituted monocyclic ring nor the substituted or unsubstituted fused ring respectively represent the same as R₂₀₁ and R₂₀₂ in the formula (2).

In the formula (21) or (22):
R₂₀₃, R₂₀₄ and R₂₀₅, and R₂₂₁, R₂₂₂, R₂₂₃, R₂₂₄, R₂₂₅, R₂₂₆, R₂₂₇, R₂₂₃, R₂₂₉, R₂₃₀, R₂₃₁, R₂₃₇, R₂₃₈, R₂₃₉ and R₂₄₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; and
when a plurality of R₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; when a plurality of R₉₀₄ are present, the plurality of R₉₀₄ are mutually the same or different; when a plurality of R₉₀₅ are present, the plurality of R₉₀₅ are mutually the same or different; when a plurality of R₉₀₆ are present, the plurality of R₉₀₆ are mutually the same or different; and when a plurality of R₉₀₇ are present, the plurality of R₉₀₇ are mutually the same or different.

In an exemplary arrangement of the organic EL device according to the first exemplary embodiment, R₂₀₁ and R₂₀₂ in the formula (21) or (22) are each independently a substituted or unsubstituted aryl group having 6 to 50 ring carbon atoms or a substituted or unsubstituted heterocyclic group having 5 to 50 ring atoms.

In an exemplary arrangement of the organic EL device according to the first exemplary embodiment, R₂₀₁ and R₂₀₂ in the formula (21) or (22) are each independently a substituted or unsubstituted aryl group having 6 to 50 ring carbon atoms.

In an exemplary arrangement of the organic EL device according to the first exemplary embodiment, R₂₀₁ and R₂₀₂ in the formula (21) or (22) are each independently a substituted or unsubstituted aryl group having 6 to 18 ring carbon atoms.

In an exemplary arrangement of the organic EL device according to the first exemplary embodiment, R₂₀₁ and R₂₀₂ in the formula (21) or (22) are each independently the group represented by a formula (23) below.

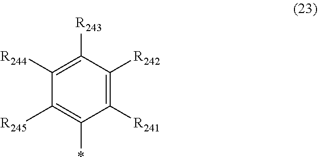

In the formula (23):
at least one combination of adjacent two or more of R₂₄₁, R₂₄₂, R₂₄₃, R₂₄₄, and R₂₄₅ are mutually bonded to form a substituted or unsubstituted monocyclic ring, mutually bonded to form a substituted or unsubstituted fused ring, or not mutually bonded;
R₂₄₁, R₂₄₂, R₂₄₃, R₂₄4, and R₂₄₅ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₉₀₁ to R₉₀₇ each independently represent the same as R₉₀₁ to R₉₀₇ in the formulae (21) and (22);
when a plurality of R₂₄₁ are present, the plurality of R₂₄₁ are mutually the same or different;
when a plurality of R₂₄₂ are present, the plurality of R₂₄₂ are mutually the same or different;
when a plurality of R₂₄₃ are present, the plurality of R₂₄₃ are mutually the same or different;
when a plurality of R₂₄₄ are present, the plurality of R₂₄4 are mutually the same or different;
when a plurality of R₂₄₅ are present, the plurality of R₂₄₅ are mutually the same or different; and
* represents a bonding position.

In an exemplary arrangement of the organic EL device according to the first exemplary embodiment, the second compound is a compound represented by a formula (211) or (221) below.

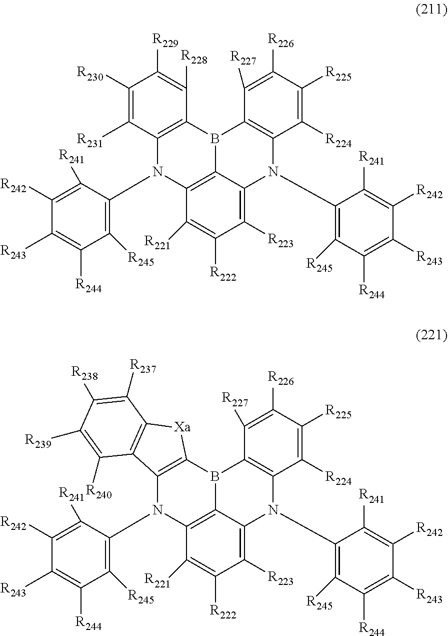

In the formulae (221) and (221), R₂₂₁ to R₂₃₁ and R₂₃₇ to R₂₄₀ respectively represent the same as R₂₂₁ to R₂₃₁ and R₂₃₇ to R₂₄₀ in the formulae (21) and (22), and R₂₄₁ to R₂₄₅ respectively represent the same as R₂₄₁ to R₂₄₅ in the formula (23), and Xa in the formula (221) represents the same as Xa in the formula (22).

In an exemplary arrangement of the organic EL device according to the first exemplary embodiment, the second compound is a compound represented by a formula (212) or (222) below.

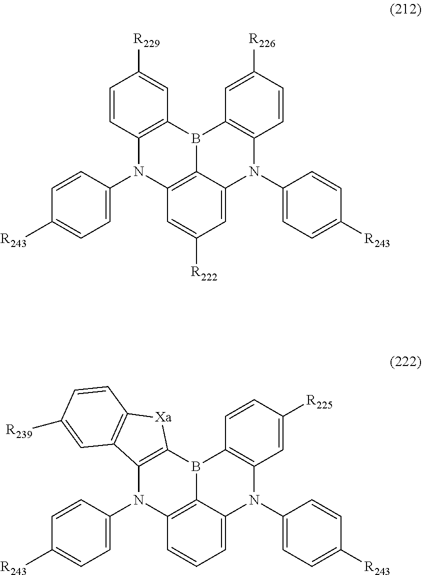

In the formula (212), R₂₂₂, R₂₂₆ and R₂₂₉ respectively represent the same as R₂₂₂, R₂₂₆ and R₂₂₉ in the formula (21);
in the formula (222), Xa, R₂₂₅ and R₂₃₉ respectively represent the same as Xa, R₂₂₅ and R₂₃₉ in the formula (22); and
R₂₄₃ in the formulae (212) and (222) represents the same as R₂₄₃ in the formula (23).

In an exemplary arrangement of the organic EL device according to the first exemplary embodiment, Xa in the formulae (22), (221) and (222) is S (a sulfur atom) or O (an oxygen atom).

Herein, the maximum peak wavelength of fluorescence is occasionally referred to as a maximum fluorescence peak wavelength.

In an exemplary arrangement of the first exemplary embodiment, the maximum fluorescence peak wavelength of the second compound is preferably 430 nm or more, more preferably 440 nm or more, and still more preferably 445 nm or more.

In an exemplary arrangement of the first exemplary embodiment, the maximum fluorescence peak wavelength of the second compound is preferably 480 nm or less, more preferably 470 nm or less, and still more preferably 465 nm or less.

In the first exemplary embodiment, when the maximum fluorescence peak wavelength of the second compound is 430 nm or more, an electronic device (e.g., display) including the organic EL device containing the compound according to the exemplary embodiment easily emits moderate blue light.

In the first exemplary embodiment, when the maximum fluorescence peak wavelength of the second compound is 480 nm or less, an electronic device (e.g., display) including the organic EL device containing the compound according to the exemplary embodiment easily emits moderate blue light.

Herein, the maximum fluorescence peak wavelength means the maximum peak wavelength of a fluorescence spectrum exhibiting a maximum luminous intensity among fluorescence spectra measured in a toluene solution in which a measurement target compound is dissolved at a concentration ranging from 10⁻⁶ mol/l to 10⁻⁵ mol/l. A fluorescence spectrum measurement device (device name: FP-8300, manufactured by JASCO Corporation) is usable as a measurement device. It should be noted that the fluorescence spectrum measurement device is not limited to the device exemplified herein.

In an exemplary arrangement of the organic EL device according to the first exemplary embodiment, also preferably, the groups specified to be “substituted or unsubstituted” are each an “unsubstituted” group.

Unless specifically mentioned herein, the details of a substituent (optional substituent) for “substituted or unsubstituted group” included in the definition of each formula of each compound are the same as described under the subtitle “Substituent for Substituted or Unsubstituted Group”.

### Producing Method of Second Compound According to First Exemplary Embodiment

The second compound according to the first exemplary embodiment can be produced by a known method. Further, the second compound according to the first exemplary embodiment can be produced based on a known method through a known alternative reaction using a known material(s) tailored for the target compound.

### Specific Examples of Second Compound According to First Exemplary Embodiment

Specific examples of the second compound according to the first exemplary embodiment include the following compounds. However, the invention is not limited to these specific examples.

In the specific examples of the compound herein, D represents a deuterium atom, Me represents a methyl group, tBu represents a tert-butyl group, and Ph represents a phenyl group.

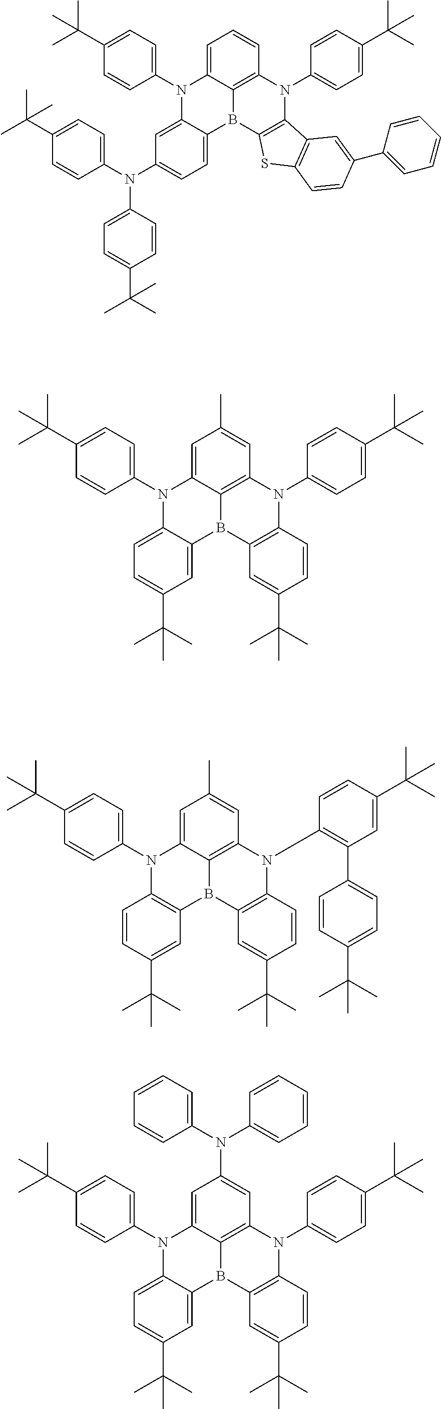

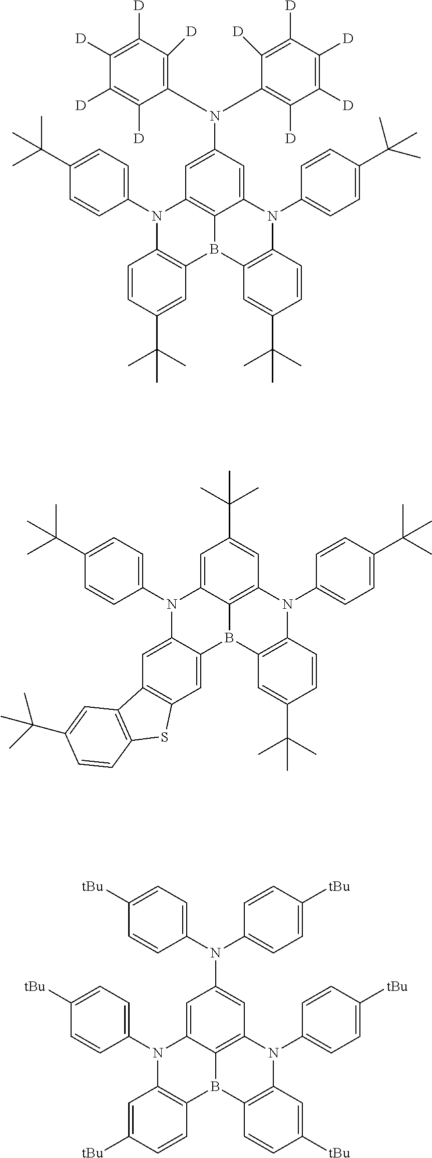

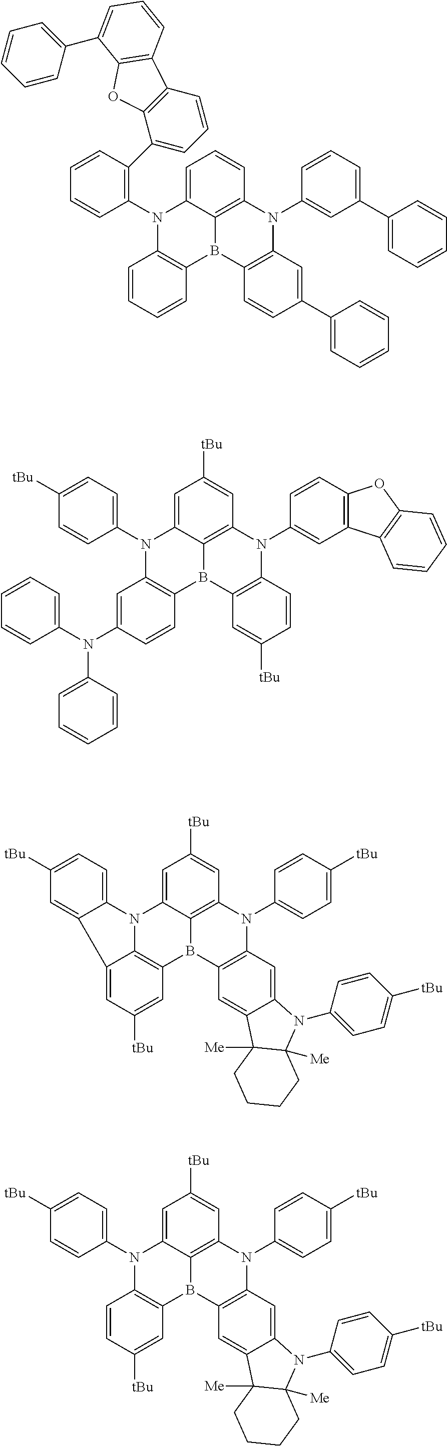 [SMILES: c1ccc(-c2cccc(N3c4cc(-c5ccccc5)ccc4B4c5ccccc5N(c5ccccc5-c5cccc6c5oc5c(-c7ccccc7)cccc56)c5cccc3c54)c2)cc1 ; CC(C)(C)c1ccc(N2c3cc(N(c4ccccc4)c4ccccc4)ccc3B3c4cc(C(C)(C)C)ccc4N(c4ccc5oc6ccccc6c5c4)c4cc(C(C)(C)C)cc2c43)cc1 ; CC(C)(C)c1ccc(N2c3cc4c(cc3B3c5c2cc(C(C)(C)C)cc5-n2c5ccc(C(C)(C)C)cc5c5cc(C(C)(C)C)cc3c52)C2(C)CCCCC2(C)N4c2ccc(C(C)(C)C)cc2)cc1 ; CC(C)(C)c1ccc(N2c3ccc(C(C)(C)C)cc3B3c4cc5c(cc4N(c4ccc(C(C)(C)C)cc4)c4cc(C(C)(C)C)cc2c43)N(c2ccc(C(C)(C)C)cc2)C2(C)CCCCC52C)cc1]

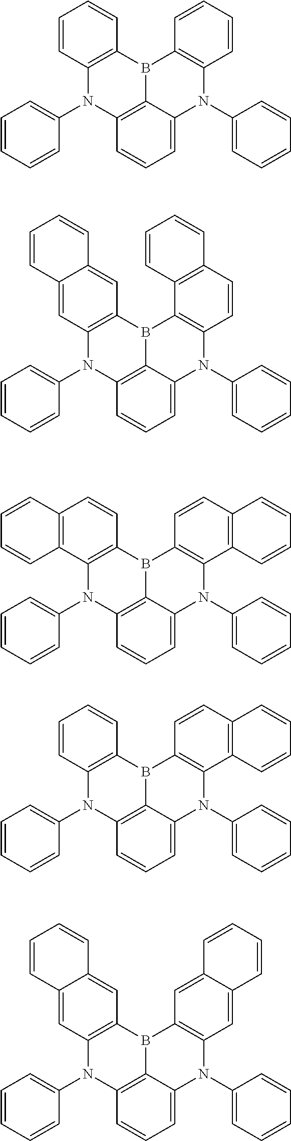

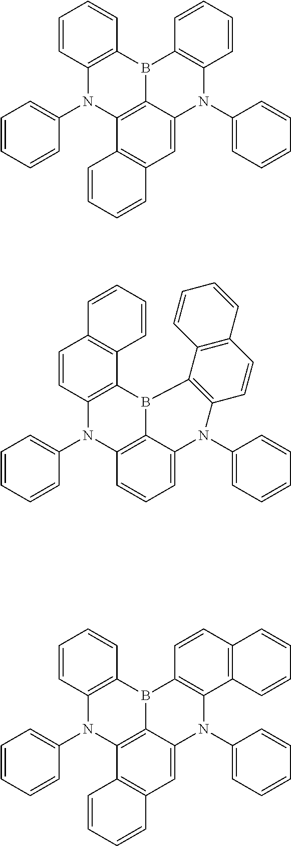 [SMILES: c1ccc(N2c3ccccc3B3c4ccccc4N(c4ccccc4)c4c3c2cc2ccccc42)cc1 ; c1ccc(N2c3cccc4c3B(c3c2ccc2ccccc32)c2c(ccc3ccccc23)N4c2ccccc2)cc1 ; c1ccc(N2c3cc4ccccc4c4c3B(c3ccccc3N4c3ccccc3)c3ccc4ccccc4c32)cc1]

### Host Material for Emitting Layer

The emitting layer may include the above-described highly luminescent substance (dopant material) dispersed in another substance (host material).

The substance for dispersing the highly luminescent substance may be various substances, preferably a substance having higher Lowest Unoccupied Molecular Orbital (LUMO level) and lower Highest Occupied Molecular Orbital (HOMO level) than the highly luminescent substance.

Preferable examples of the substance (host material) for dispersing the highly luminescent substance include at least one selected from the group consisting of compounds shown in (1) to (4) below:
(1) a metal complex such as an aluminum complex, beryllium complex or zinc complex;
(2) a heterocyclic compound such as an oxadiazole derivative, benzimidazole derivative or phenanthroline derivative;
(3) a fused aromatic compound such as a carbazole derivative, anthracene derivative, phenanthrene derivative, pyrene derivative or chrysene derivative; and
(4) an aromatic amine compound such as a triarylamine derivative or a fused polycyclic aromatic amine derivative.

Specific examples of the metal complex include tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ).

Specific examples of the heterocyclic compound include 2-(4-biphenylyl)-5-(4-tert-butylphenyl)-1,3,4-oxadiazole (abbreviation: PBD), 1,3-bis[5-(p-tert-butylphenyl)-1,3,4-oxadiazole-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: BPhen), and bathocuproine (abbreviation: BCP).

Specific examples of the fused aromatic compound include 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 3,3′,3″-(benzene-1,3,5-triyl)tripyrene (abbreviation: TPB3), 9,10-diphenylanthracene (abbreviation: DPAnth), and 6,12-dimethoxy-5,11-diphenylchrysene.

Specific examples of the aromatic amine compound include N,N-diphenyl-9-[4-(10-phenyl-9-anthryl)phenyl]-9H-carbazole-3-amine (abbreviation: CzA1PA), 4-(10-phenyl-9-anthryl)triphenylamine (abbreviation: DPhPA), N,9-diphenyl-N-[4-(10-phenyl-9-anthryl)phenyl]-9H-carbazole-3-amine (abbreviation: PCAPA), N,9-diphenyl-N-{4-[4-(10-phenyl-9-anthryl)phenyl]phenyl}-9H-carbazole-3-amine (abbreviation: PCAPBA), N-(9,10-diphenyl-2-anthryl)-N,9-diphenyl-9H-carbazole-3-amine (abbreviation: 2PCAPA), NPB (or α-NPD), TPD, DFLDPBi, and BSPB.

### Compound Represented by Formula (3)

In an exemplary arrangement of the organic EL device according to the first exemplary embodiment, the host material is a compound represented by a formula (3) below. In an exemplary arrangement of the organic EL device according to the first exemplary embodiment, the first host material and the second host material are each a compound represented by the formula (3) below. The compound represented by the formula (3) below is occasionally referred to as a third compound.

In the organic EL device according to the first exemplary embodiment, the third compound is a compound represented by the formula (3) below.

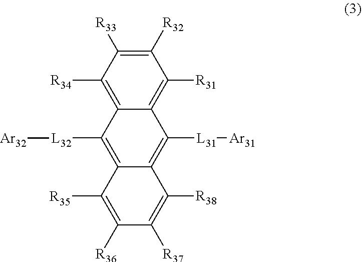

In the formula (3):
R₃₁ to R₃₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₃₁ and L₃₂ are each independently a single bond, a substituted or unsubstituted arylene group having 6 to 50 ring carbon atoms, or a substituted or unsubstituted divalent heterocyclic group having 5 to 50 ring atoms; and
Ar₃₁ and Ar₃₂ are each independently a substituted or unsubstituted aryl group having 6 to 50 ring carbon atoms, or a substituted or unsubstituted heterocyclic group having 5 to 50 ring atoms.

In the third compound, R₉₀₁ to R₉₀₇, R⁸⁰¹, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; when a plurality of R₉₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; when a plurality of R₉₀₄ are present, the plurality of R₉₀₄ are mutually the same or different; when a plurality of R₉₀₅ are present, the plurality of R₉₀₅ are mutually the same or different; when a plurality of R₉₀₆ are present, the plurality of R₉₀₆ are mutually the same or different; when a plurality of R₉₀₇ are present, the plurality of R₉₀₇ are mutually the same or different; when a plurality of R₈₀₁ are present, the plurality of R₃₁ are mutually the same or different; and when a plurality of R₈₀₂ are present, the plurality of R₈₀₂ are mutually the same or different.

In an exemplary arrangement of the organic EL device according to the first exemplary embodiment, the third compound is a compound represented by a formula (31) below.

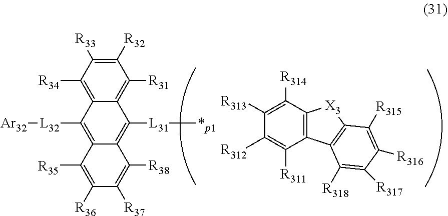

In the formula (31):
R₃₁ to R₃₈ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X3 is an oxygen atom or a sulfur atom;
one of R₃₁ to R₃₁₈ is a single bond bonded to *p1;
at least one combination of adjacent two or more of R₃₁₁ to R₃₁₃ not being the single bond bonded to *p1 are mutually bonded to form a substituted or unsubstituted monocyclic ring, mutually bonded to form a substituted or unsubstituted fused ring, or not mutually bonded;
R₃₁₁ to R₃₁₈ not being the single bond bonded to *p1, not forming the substituted or unsubstituted monocyclic ring, and not forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
L₃₁ and L₃₂ are each independently a single bond, a substituted or unsubstituted arylene group having 6 to 50 ring carbon atoms, or a substituted or unsubstituted divalent heterocyclic group having 5 to 50 ring atoms; and
Ar₃₂ is a substituted or unsubstituted aryl group having 6 to 50 ring carbon atoms, or a substituted or unsubstituted heterocyclic group having 5 to 50 ring atoms.

In an exemplary arrangement of the organic EL device according to the first exemplary embodiment, the third compound is a compound represented by a formula (31A), (31B) or (31C) below.

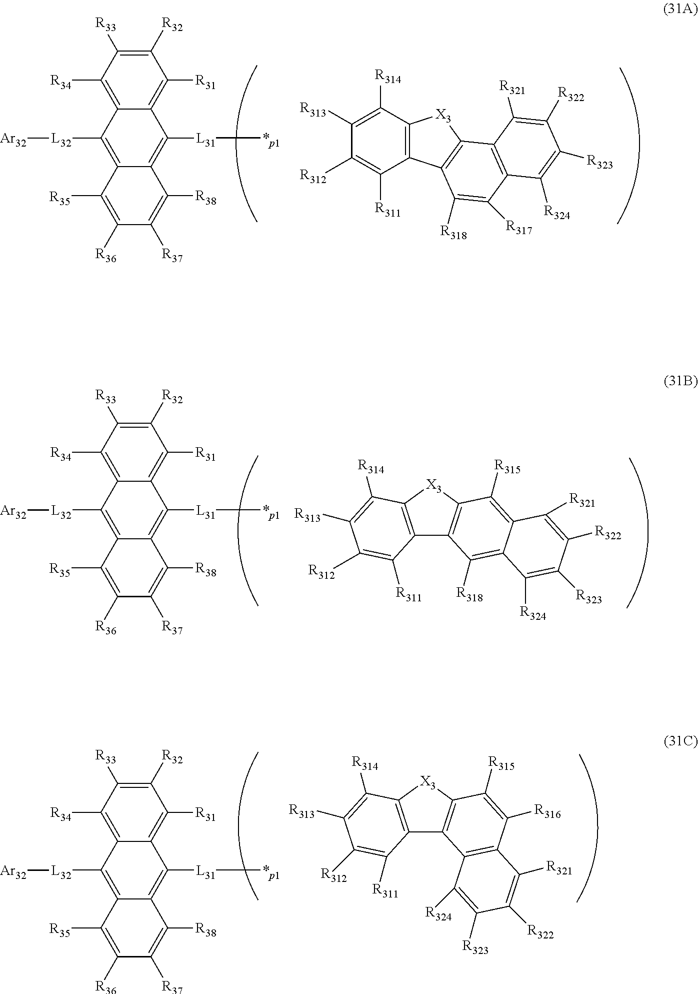

In the formulae (31A), (31 B) and (310):
R₃₁ to R₃₈, L₃₁, L₃₂, and Ar₃₂ respectively represent the same as R₃₁ to R₃₈, L₃₁, L₃₂, and Ar₃₂ in the formula (3);
X₃ represents the same as X₃ in the formula (31);
one of R₃₁₁ to R₃₁₈ and R₃₂₁ to R₃₂₄ is a single bond bonded to *p1;
at least one combination of adjacent two or more of R₃₁₁ to R₃₁₈ and R₃₂₁ to R₃₂₄ not being the single bond bonded to *p1 are mutually bonded to form a substituted or unsubstituted monocyclic ring, mutually bonded to form a substituted or unsubstituted fused ring, or not mutually bonded; and
R₃₁₁ to R₃₁₈ and R₃₂₁ to R₃₂₄ not being the single bond bonded to *p1, not forming the substituted or unsubstituted monocyclic ring, and not forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary arrangement of the organic EL device according to the first exemplary embodiment, the third compound is represented by the formula (31A), and R₃₁₁ is a single bond bonded to *p1.

In an exemplary arrangement of the organic EL device according to the first exemplary embodiment, the third compound is represented by the formula (31 B), and R₃₁₁ is a single bond bonded to *p1.

In an exemplary arrangement of the organic EL device of the first exemplary embodiment, the compound represented by the formula (3) is a compound represented by a formula (311), (312), (313) or (314) below.

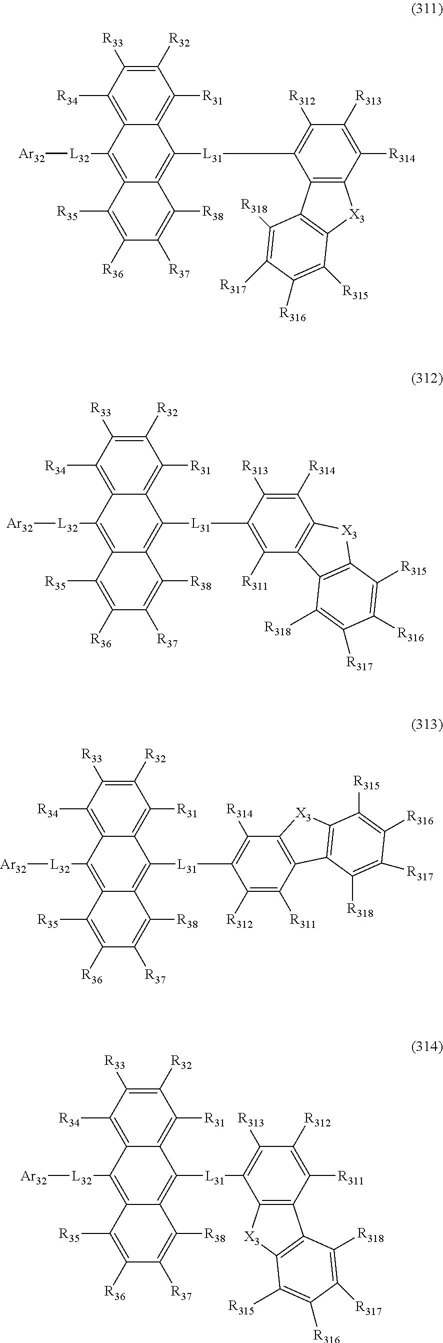

In the formulae (311), (312), (313) and (314), R₃₁ to R₃₈, R₃₁₁ to R₃₁₈, L₃₁, L₃₂, Ar₃₂ and X₃ are as defined in the formula (3) or (31).

In an exemplary arrangement of the organic EL device of the first exemplary embodiment, at least one combination of adjacent two or more of R₃₁₁ to R₃₁₈ not being the single bond bonded to *p1 are mutually bonded to form a substituted or unsubstituted monocyclic ring, or mutually bonded to form a substituted or unsubstituted fused ring.

In an exemplary arrangement of the organic EL device of the first exemplary embodiment, any combinations of adjacent two or more of R₃₁₁ to R₃₁₄ not being the single bond bonded to *p1 are not mutually bonded, and at least one combination of adjacent two or more of R₃₁₅ to R₃₁₈ not being the single bond bonded to *p1 are mutually bonded to form a substituted or unsubstituted monocyclic ring, or mutually bonded to form a substituted or unsubstituted fused ring.

In an exemplary arrangement of the organic EL device of the first exemplary embodiment, any combinations of adjacent two or more of R₃₁₁ to R₃₁₈ not being the single bond bonded to *p1 are not mutually bonded.

In an exemplary arrangement of the organic EL device of the first exemplary embodiment, L₃₁ and L₃₂ are each independently a single bond or a substituted or unsubstituted arylene group having 6 to 14 ring carbon atoms.

In an exemplary arrangement of the organic EL device of the first exemplary embodiment, L₃₁ and L₃₂ are each independently a single bond, a substituted or unsubstituted phenylene group, or a substituted or unsubstituted naphthylene group.

In an exemplary arrangement of the organic EL device of the first exemplary embodiment, at least one of Ar₃₁ or Ar₃₂ is a substituted or unsubstituted aryl group having 6 to 50 ring carbon atoms.

In an exemplary arrangement of the organic EL device of the first exemplary embodiment, Ar₃₂ is a substituted or unsubstituted aryl group having 6 to 50 ring carbon atoms.

In an exemplary arrangement of the organic EL device of the first exemplary embodiment, at least one of Ar₃₁ or Ar₃₂ is a group represented by a formula (32a), (32b), (32c) or (32d) below.

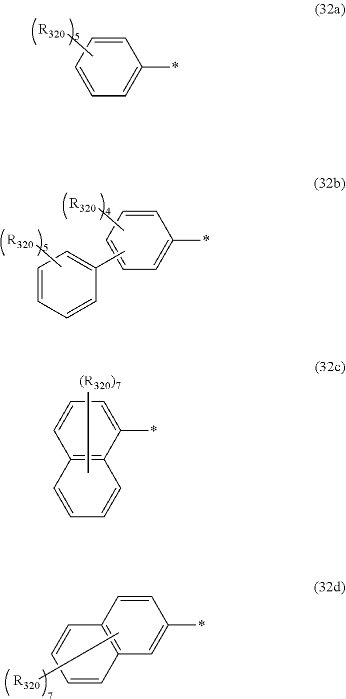

In the formulae (32a), (32b), (32c) and (32d):
at least one combination of adjacent two or more of a plurality of R₃₂₀ are mutually bonded to form a substituted or unsubstituted monocyclic ring, mutually bonded to form a substituted or unsubstituted fused ring, or not mutually bonded;
R₃₂₀ forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of R₃₂₀ are mutually the same or different; and
* represents a single bond bonded to L₃₁ or L₃₂.

In an exemplary arrangement of the organic EL device of the first exemplary embodiment, X₃ is an oxygen atom.

In an exemplary arrangement of the organic EL device of the first exemplary embodiment, Ar₃₂ is a group represented by the formula (32a), (32b), (32c), or (32d).

In an exemplary arrangement of the organic EL device of the first exemplary embodiment, R₃₁ to R₃₈ are each a hydrogen atom.

In an exemplary arrangement of the organic EL device of the first exemplary embodiment, the compound represented by the formula (3) is a compound represented by a formula (325), (326), (327), (328) or (329) below.

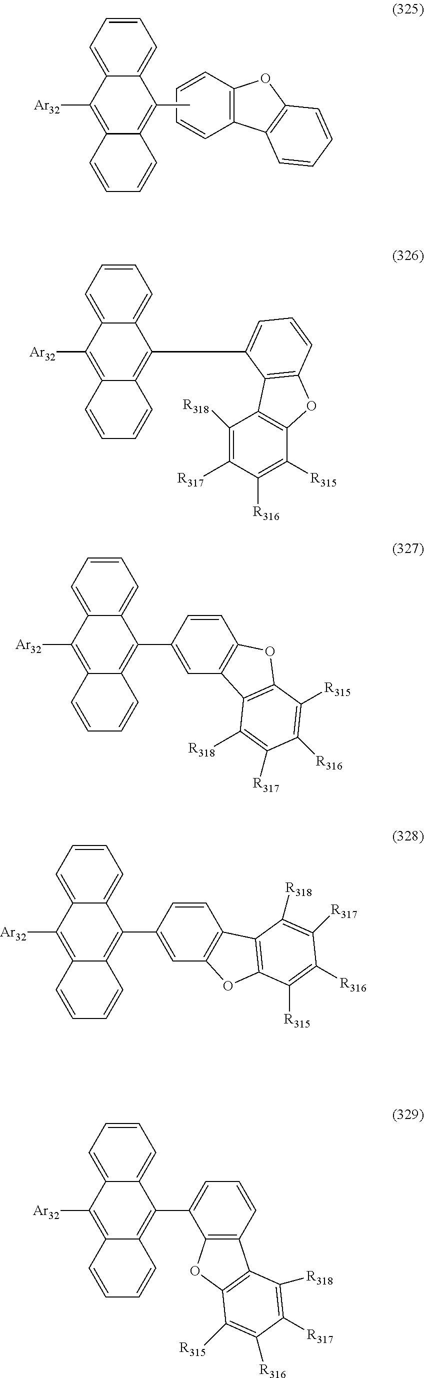

In the formulae (325) to (329), R₃₁₅ to R₃₁₈ and Ar₃₂ respectively represent the same as R₃₁₅ to R₃₁₅ and Ar₃₂ in the formula (31).

In an exemplary arrangement of the organic EL device of the first exemplary embodiment, at least one combination of adjacent two or more of R₃₁₅ to R₃₁₅ are mutually bonded to form a substituted or unsubstituted monocyclic ring.

In an exemplary arrangement of the organic EL device of the first exemplary embodiment, at least one combination of adjacent two or more of R₃₁₅ to R₃₁₈ are mutually bonded to form a substituted or unsubstituted benzene ring.

### Producing Method of Third Compound According to First Exemplary Embodiment

The third compound according to the first exemplary embodiment can be produced by a known method. Further, the third compound according to the first exemplary embodiment can be produced based on a known method through a known alternative reaction using a known material(s) tailored for the target compound.

### Specific Examples of Third Compound According to First Exemplary Embodiment

Specific examples of the third compound according to the first exemplary embodiment include the following compounds. However, the invention is not limited to these specific examples.

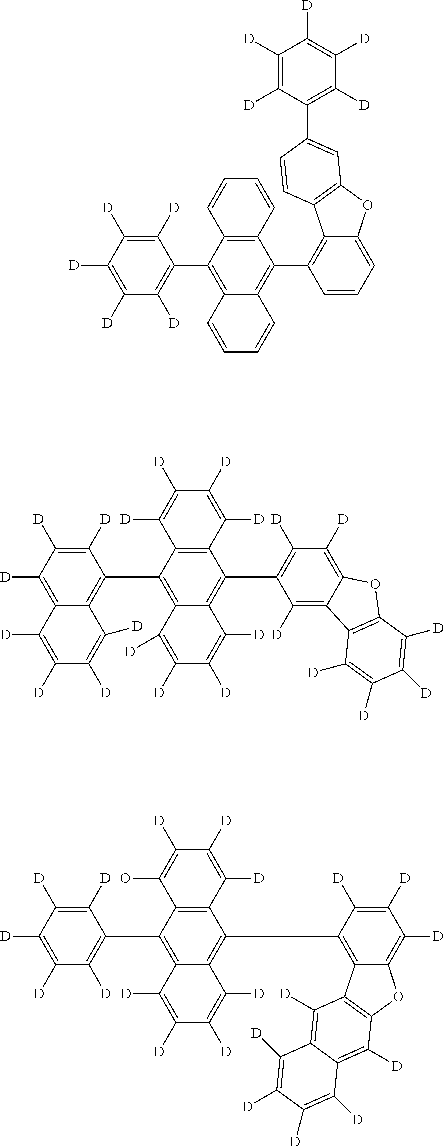 [SMILES: [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H] ; [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c(O)c23)c([2H])c1[2H]]

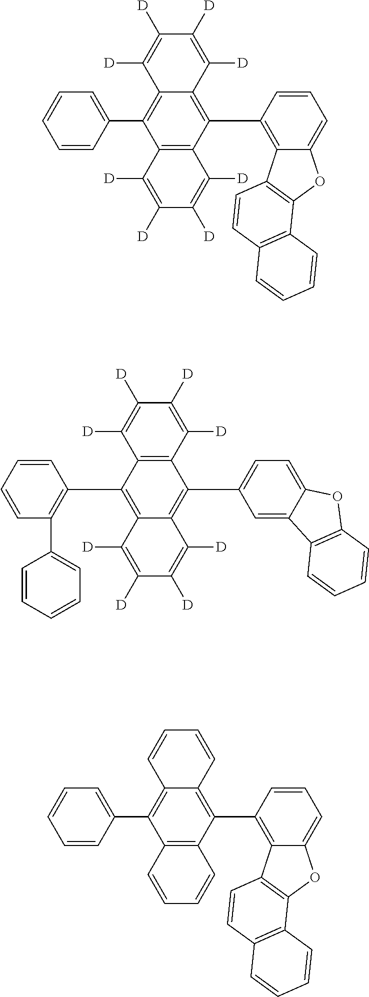 [SMILES: [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c2c(-c3ccccc3-c3ccccc3)c3c([2H])c([2H])c([2H])c([2H])c3c(-c3ccc4oc5ccccc5c4c3)c2c1[2H] ; c1ccc(-c2c3ccccc3c(-c3cccc4oc5c6ccccc6ccc5c34)c3ccccc23)cc1]

Herein, the “host material” refers to, for instance, a material that accounts for “50 mass % or more of the layer”. Accordingly, for instance, the emitting layer contains 50 mass % or more of the host material with respect to the total mass of the emitting layer. When the organic EL device includes a plurality of emitting layers, for instance, the plurality of emitting layers each contain 50 mass % or more of the host material with respect to the total mass of each emitting layer. In addition, for instance, the “host material” may account for 60 mass % or more of the emitting layer, 70 mass % or more of the emitting layer, 80 mass % or more of the emitting layer, 90 mass % or more of the emitting layer, or 95 mass % or more of the emitting layer. Further, for instance, the “host material” may accounts for 99.5 mass % or less of the emitting layer, or 99 mass % or less of the emitting layer.

When the emitting layer contains the host material and the dopant material, the upper limit of the total of the content ratios of the host material and the dopant material is 100 mass %.

In an exemplary arrangement of the organic EL device according to the first exemplary embodiment, at least one emitting layer contains no metal complex. Further, in an exemplary arrangement of the organic EL device according to the first exemplary embodiment, at least one emitting layer contains no boron-containing complex.

In an exemplary arrangement of the organic EL device according to the first exemplary embodiment, at least one emitting layer contains no phosphorescent material.

In an exemplary arrangement of the organic EL device according to the first exemplary embodiment, at least one emitting layer contains no heavy-metal complex and no phosphorescent rare earth metal complex.

In an exemplary arrangement of the organic EL device according to the first exemplary embodiment, at least one emitting layer contains no heavy-metal complex such as iridium complex, osmium complex, and platinum complex.

### Low Refractive Index Layer

In the organic EL device according to the first exemplary embodiment, one or more low refractive index layers are disposed between at least any emitting zones of the two or more emitting zones.

In the organic EL device according to the first exemplary embodiment, the one or more low refractive index layers are disposed between the first emitting zone and the second emitting zone.

In the organic EL device according to the first exemplary embodiment, the one or more low refractive index layers each independently contain an organic material having a refractive index of 1.87 or less. The organic material with a refractive index of 1.87 or less contained in each of the one or more low refractive index layers may mutually have the same chemical structure or different chemical structures. The organic material having a refractive index of 1.87 or less is occasionally referred to as a low refractive index organic material.

In an exemplary arrangement of the organic EL device according to the first exemplary embodiment, the one or more low refractive index layers each independently contain the organic material having a refractive index of 1.87 or less at 50 mass % or more, 60 mass % or more, 70 mass % or more, 80 mass % or more, 90 mass % or more, 95 mass % or more, or 99 mass % or more. In an exemplary arrangement of the organic EL device according to the first exemplary embodiment, the one or more low refractive index layers may be a layer(s) containing only an organic material having a refractive index of 1.87 or less.

In an exemplary arrangement of the organic EL device according to the first exemplary embodiment, at least one organic material (low refractive index organic material) of the organic materials contained in the one or more low refractive index layers has a refractive index of 1.83 or less.

### Condition (TDM1)

Condition (TDM1) will be described. In Condition (TDM1), two or more low refractive index layers are disposed between the first emitting zone and the second emitting zone, and at least two of the low refractive index layers are in direct contact with each other. Further, in Condition (TDM1), a total film thickness of the at least two low refractive index layers in direct contact is 50 nm or more, and at least one of the at least two of low refractive index layers in direct contact contains an organic material having a refractive index of 1.87 or less (low refractive index organic material) and at least one selected from the group consisting of metal and a metal compound.

In an exemplary arrangement of the organic EL device according to the first exemplary embodiment, when Condition (TDM1) is satisfied, a film thickness of each of the at least two low refractive index layers in direct contact is less than 50 nm, or equal to or less than 45 nm, independently of each other.

In an exemplary arrangement of the organic EL device according to the first exemplary embodiment, when Condition (TDM1) is satisfied, a film thickness of at least one low refractive index layer, of the at least two low refractive index layers in direct contact, is 30 nm or less, 25 nm or less, 20 nm or less, or 18 nm or less, independently of each other.

In an exemplary arrangement of the organic EL device according to the first exemplary embodiment, when Condition (TDM1) is satisfied, a film thickness of each of the at least two low refractive index layers in direct contact is 3 nm or more, or 5 nm or more, independently of each other.

In an exemplary arrangement of the organic EL device according to the first exemplary embodiment, a total film thickness of the at least two low refractive index layers in direct contact is 60 nm or more, or 70 nm more.

In an exemplary arrangement of the organic EL device according to the first exemplary embodiment, the organic EL device satisfies Condition (TDM1), and a total film thickness of the at least two low refractive index layers in direct contact in Condition (TDM1) is 100 nm or less, or 90 nm less.

In an exemplary arrangement of the organic EL device according to the first exemplary embodiment, Condition (TDM1) where a first low refractive index layer and a second low refractive index layer, as two low refractive index layers, are disposed between the first emitting zone and the second emitting zone in this order from a side close to the first emitting zone will be described below as Condition (TDM1-1).

In Condition (TDM1-1), the first low refractive index layer is in direct contact with the second low refractive index layer, a total film thickness of the first low refractive index layer and the second low refractive index layer is 50 nm or more, and at least one of the first and second low refractive index layers contains the low refractive index organic material and at least one selected from the group consisting of metal and a metal compound.

In an exemplary arrangement of the organic EL device according to the first exemplary embodiment, Condition (TDM1) where a third low refractive index layer, the first low refractive index layer and the second low refractive index layer, as three low refractive index layers, are disposed between the first emitting zone and the second emitting zone in this order from a side close to the first emitting zone will be described below as Condition (TDM1-2).

In an example of Condition (TDM1-2), the third low refractive index layer is in direct contact with the first low refractive index layer, the first low refractive index layer is in direct contact with the second low refractive index layer, a total film thickness of the first low refractive index layer, the second low refractive index layer, and the third low refractive index layer is 50 nm or more, and at least one of the first to third low refractive index layers contains the low refractive index organic material and at least one selected from the group consisting of metal and a metal compound.

In an exemplary arrangement of the organic EL device according to the first exemplary embodiment, Condition (TDM1) where the third low refractive index layer, the first low refractive index layer, the second low refractive index layer and a fourth low refractive index layer, as four low refractive index layers, are disposed between the first emitting zone and the second emitting zone in this order from a side close to the first emitting zone will be described below as Condition (TDM1-3).

In an example of Condition (TDM1-3), the third low refractive index layer is in direct contact with the first low refractive index layer, the first low refractive index layer is in direct contact with the second low refractive index layer, the second low refractive index layer is in direct contact with the fourth low refractive index layer, a total film thickness of the first low refractive index layer, the second low refractive index layer, the third low refractive index layer, and of the fourth low refractive index layer is 50 nm or more, and at least one of the first to fourth low refractive index layers contains the low refractive index organic material and at least one selected from the group consisting of metal and a metal compound.

In an exemplary arrangement of the organic EL device according to the first exemplary embodiment, Condition (TDM1) where a fifth low refractive index layer, the third low refractive index layer, the first low refractive index layer, the second low refractive index layer and the fourth low refractive index layer, as five low refractive index layers, are disposed between the first emitting zone and the second emitting zone in this order from a side close to the first emitting zone will be described below as Condition (TDM1-4).

In an example of Condition (TDM1-4), the fifth low refractive index layer is in direct contact with the third low refractive index layer, the third low refractive index layer is in direct contact with the first low refractive index layer, the first low refractive index layer is in direct contact with the second low refractive index layer, the second low refractive index layer is in direct contact with the fourth low refractive index layer, a total film thickness of the first low refractive index layer, the second low refractive index layer, the third low refractive index layer, the fourth low refractive index layer, and the fifth low refractive index layer is 50 nm or more, and at least one of the first to fifth low refractive index layers contains the low refractive index organic material and at least one selected from the group consisting of metal and a metal compound.

In an exemplary arrangement of the organic EL device according to the first exemplary embodiment, the organic EL device satisfies Condition (TDM1), and the at least two low refractive index layers in direct contact in Condition (TDM1) contain mutually different compounds. In an exemplary arrangement of the organic EL device according to the first exemplary embodiment, the low refractive index organic materials respectively contained in the two or more low refractive index layers are mutually different compounds.

For instance, an arrangement where the organic EL device includes the first low refractive index layer and the second low refractive index layer as two low refractive index layers, the first low refractive index layer contains a compound AA, and the second low refractive index layer contains a compound BB corresponds to an arrangement where at least two low refractive index layers (the first low refractive index layer and the second low refractive index layer) in direct contact with each other contain mutually different compounds.

In addition, an arrangement where the organic EL device includes the first low refractive index layer and the second low refractive index layer as two low refractive index layers, the first low refractive index layer contains two types of compounds (the compound AA and a compound AB), and the second low refractive index layer contains the compound BB corresponds to an arrangement where at least two low refractive index layers (the first low refractive index layer and the second low refractive index layer) in direct contact with each other contain mutually different compounds, because the compound AA and the compound AB are each different from the compound BB. The compound AA, compound AB and compound BB are mutually different compounds.

On the other hand, an arrangement where the organic EL device includes the first low refractive index layer and the second low refractive index layer as two low refractive index layers, the first low refractive index layer contains two types of compounds (the compound AA and the compound AB), and the second low refractive index layer contains the compound AA does not correspond to an arrangement where at least two low refractive index layers (the first low refractive index layer and the second low refractive index layer) in direct contact with each other contain mutually different compounds, because the first low refractive index layer and the second low refractive index layer contain the same compound (the compound AA).

The same logic as above can also be applied to whether three, four, five, six or more layers of low refractive index layers included in the organic EL device contain mutually different compounds or the same compound(s).

In an exemplary arrangement of the organic EL device according to the first exemplary embodiment, when the organic EL device satisfies Condition (TDM1) and an absolute value of a difference between the refractive indices of two organic materials (low refractive index organic materials) is defined as Δn, at least one Δn is less than 0.10, the two organic materials being selected from the group consisting of the organic materials (low refractive index organic materials) respectively contained in the at least two low refractive index layers that are in direct contact in Condition (TMD1). In the organic EL device according to the exemplary embodiment, the absolute value Δn is 0 or more.

In an exemplary arrangement of the organic EL device according to the first exemplary embodiment, for instance, when the organic EL device satisfies Condition (TDM1-1), the absolute value Δn₁₂ of the difference between the refractive indices of the low refractive index organic materials is less than 0.10.

In an exemplary arrangement of the organic EL device according to the first exemplary embodiment, for instance, when the organic EL device satisfies Condition (TDM1-2), at least one of Δn₁₂ or Δn₁₃ is less than 0.10.

In an exemplary arrangement of the organic EL device according to the first exemplary embodiment, for instance, when the organic EL device satisfies Condition (TDM1-3), at least one of Δn₁₂, Δn₁₃ or Δn₂₄ is less than 0.10.

In an exemplary arrangement of the organic EL device according to the first exemplary embodiment, for instance, when the organic EL device satisfies Condition (TDM1-4), at least one of Δn₃₅, Δn₁₂, Δn₁₃ or Δn₂₄ is less than 0.10.

Δn₁₂, Δn₁₃, Δn₂₄ and Δn₃₅ are defined as follows.

$$Δ {n}_{12} = \vert {n}_{1} - {n}_{2} \vert$$

$$Δ {n}_{13} = \vert {n}_{1} - {n}_{3} \vert$$

$$Δ {n}_{24} = \vert {n}_{2} - {n}_{4} \vert$$

$$Δ {n}_{35} = \vert {n}_{3} - {n}_{5} \vert$$

n₁: a refractive index of a low refractive index organic material contained in the first low refractive index layer
n₂: a refractive index of a low refractive index organic material contained in the second low refractive index layer
n₃: a refractive index of a low refractive index organic material contained in the third low refractive index layer
n₄: a refractive index of a low refractive index organic material contained in the fourth low refractive index layer
n₅: a refractive index of a low refractive index organic material contained in the fifth low refractive index layer
Δn₁₂: an absolute value of a difference between the refractive index n₁ and the refractive index n₂
Δn₁₃: an absolute value of a difference between the refractive index n₁ and the refractive index n₃
Δn₂₄: an absolute value of a difference between the refractive index n₂ and the refractive index n₄
Δn₃₅: an absolute value of a difference between the refractive index n₃ and the refractive index n₅

### Condition (TDM2)

Condition (TDM2) will be described. In Condition (TDM2), at least one low refractive index layer having a film thickness of 50 nm or more is disposed between the first emitting zone and the second emitting zone, and the at least one low refractive index layer having a film thickness of 50 nm or more contains an organic material (low refractive index organic material) having a refractive index of 1.87 or less and at least one selected from the group consisting of metal and a metal compound.

For instance, even when only one layer (low refractive index layer) containing a low refractive index organic material is disposed between the first emitting zone and the second emitting zone, a film thickness of that low refractive index layer being 50 nm or more satisfies Condition (TDM2).

In an exemplary arrangement of the organic EL device according to the first exemplary embodiment, Condition (TDM2) where one low refractive index layer with a film thickness of 50 nm or more is disposed between the first emitting zone and the second emitting zone will be described below as Condition (TDM2-1).

In an example of Condition (TDM2-1), any other layer(s) than the low refractive index layer may be disposed between the first emitting zone and the second emitting zone. The low refractive index layer with a film thickness of 50 nm or more may or may not be in direct contact with the first emitting zone. The low refractive index layer with a film thickness of 50 nm or more may or may not be in direct contact with the second emitting zone.

In an exemplary arrangement of the organic EL device according to the first exemplary embodiment, in addition to the low refractive index layer(s) that satisfies Condition (TDM1) or Condition (TDM2), one or more layers (occasionally referred to as high refractive index layers) containing an organic material with a refractive index exceeding 1.87 (occasionally referred to as a high refractive index organic material) may be included between an emitting zone in one emitting unit and an emitting zone in another emitting unit.

In an exemplary arrangement of the organic EL device according to the first exemplary embodiment, at least one low refractive index layer that satisfies Condition (TDM1) or Condition (TDM2) is disposed between an emitting layer included in an emitting zone of one emitting unit and an emitting layer included in an emitting zone of another emitting unit.

In an exemplary arrangement of the organic EL device according to the first exemplary embodiment, in addition to the low refractive index layer(s) that satisfies Condition (TDM1) or Condition (TDM2), one or more high refractive index layers containing a high refractive index organic material may be included between an emitting layer included in an emitting zone of one emitting unit and an emitting layer included in an emitting zone of another emitting unit.

### Charge Generating Zone

In an exemplary arrangement of the organic EL device according to the first exemplary embodiment, it is preferable that charge generating zones are respectively disposed between the two or more emitting units.

In an exemplary arrangement of the organic EL device according to the first exemplary embodiment, it is preferable that the charge generating zones each independently include at least one charge generating layer. The charge generating layer is a layer that generates holes and electrons when voltage is applied to the organic EL device, and supplies the electrons to a layer positioned closer to the anode beyond the charge generating layer and supplies the holes to a layer positioned closer to the cathode beyond the charge generating layer. The charge generating layer is occasionally referred to as an intermediate layer, an intermediate electrode, an intermediate conductive layer, an electron drawing layer, a connection layer or an intermediate insulating layer.

When the charge generating zone includes a plurality of charge generating layers, the charge generating zone preferably includes an N-type charge generating layer that is disposed at a side close to the anode and injects electrons to the first emitting unit, and a P-type charge generating layer disposed at a side close to the cathode and injects holes to the second emitting unit. In an exemplary arrangement of the organic EL device according to the first exemplary embodiment, one of the N-type charge generating layer and the P-type charge generating layer may be a first charge generating layer. In an exemplary arrangement of the organic EL device according to the first exemplary embodiment, the N-type charge generating layer may be the first charge generating layer and the P-type charge generating layer may be a second charge generating layer.

In an exemplary arrangement of the organic EL device according to the first exemplary embodiment, examples of a material usable for the charge generating layer of the charge generating zone include a known material(s) usable for the charge generating layer in the tandem organic EL device.

In an exemplary arrangement of the organic EL device according to the first exemplary embodiment, at least one of the charge generating zones includes two or more charge generating layers.

In an exemplary arrangement of the organic EL device according to the first exemplary embodiment, a first charge generating zone is disposed between the first emitting unit and the second emitting unit.

In an exemplary arrangement of the organic EL device according to the first exemplary embodiment, the first charge generating zone includes at least the first charge generating layer.

Further, in an exemplary arrangement of the organic EL device according to the first exemplary embodiment, when the first emitting unit, the second emitting unit and the third emitting unit are disposed in this order from a side close to the anode toward a side close to the cathode, a second charge generating zone is disposed between the second emitting unit and the third emitting unit.

Furthermore, in an exemplary arrangement of the organic EL device according to the first exemplary embodiment, when the third emitting unit, the first emitting unit and the second emitting unit are disposed in this order from a side close to the anode toward a side close to the cathode, the second charge generating zone is disposed between the third emitting unit and the first emitting unit.

In an exemplary arrangement of the organic EL device according to the first exemplary embodiment, when the organic EL device satisfies Condition (TDM1), one of the at least two low refractive index layers in direct contact in Condition (TDM1) is the first charge generating layer.

In an exemplary arrangement of the organic EL device according to the first exemplary embodiment, when the organic EL device satisfies Condition (TDM2), one of the at least one low refractive index layer having a film thickness of 50 nm or more in Condition (TDM2) is the first charge generating layer.

In an exemplary arrangement of the organic EL device according to the first exemplary embodiment, the first charge generating layer contains the organic material (organic material having a refractive index of 1.87 or less (low refractive index organic material)) and at least one selected from the group consisting of metal and a metal compound. The low refractive index organic material contained in the first charge generating layer is occasionally referred to as a first charge generating zone material.

In an exemplary arrangement of the organic EL device according to the first exemplary embodiment, the organic material (the first charge generating zone material) contained in the first charge generating layer has a refractive index of 1.83 or less, or 1.80 or less.

In an exemplary arrangement of the organic EL device according to the first exemplary embodiment, the first charge generating zone material is an electron transporting zone material (preferably, a first electron transporting zone material) described later.

In an exemplary arrangement of the organic EL device according to the first exemplary embodiment, the first charge generating zone material contained in the first charge generating layer and the electron transporting zone material contained in a layer (e.g., the first electron transporting layer) in the electron transporting zone are mutually different compounds or the same compound.

In an exemplary arrangement of the organic EL device according to the first exemplary embodiment, the first charge generating zone further includes the second charge generating layer.

In an exemplary arrangement of the organic EL device according to the first exemplary embodiment, the second charge generating layer is disposed between the first charge generating layer and the second emitting zone.

In an exemplary arrangement of the organic EL device according to the first exemplary embodiment, when the organic EL device satisfies Condition (TDM1), the at least two low refractive index layers in direct contact in Condition (TDM1) include the first charge generating layer and the second charge generating layer.

In an exemplary arrangement of the organic EL device according to the first exemplary embodiment, the first charge generating zone includes the first charge generating layer and the second charge generating layer in this order from a side close to the first emitting unit.

In an exemplary arrangement of the organic EL device according to the first exemplary embodiment, the first charge generating layer is in direct contact with the second charge generating layer.

In an exemplary arrangement of the organic EL device according to the first exemplary embodiment, the first charge generating layer is the first low refractive index layer described above and the second charge generating layer is the second low refractive index layer described above.

In an exemplary arrangement of the organic EL device according to the first exemplary embodiment, a total film thickness of the first charge generating layer and the second charge generating layer is 10 nm or more, or 15 nm or more.

In an exemplary arrangement of the organic EL device according to the first exemplary embodiment, a total film thickness of the first charge generating layer and the second charge generating layer is 100 nm or less, 80 nm or less, or 50 nm or less.

In an exemplary arrangement of the organic EL device according to the first exemplary embodiment, at least one of the first charge generating layer or the second charge generating layer contains an organic material (low refractive index organic material) having a refractive index of 1.87 or less and at least one selected from the group consisting of metal and a metal compound.

In the first exemplary embodiment, the organic material (low refractive index organic material) having a refractive index of 1.87 or less contained in the second charge generating layer is occasionally referred to as a second charge generating zone material.

In an exemplary arrangement of the organic EL device according to the first exemplary embodiment, a refractive index of the second charge generating zone material is 1.83 or less, or 1.80 or less.

In an exemplary arrangement of the organic EL device according to the first exemplary embodiment, a refractive index of the first charge generating zone material is 1.83 or less, and the refractive index of the second charge generating zone material is 1.83 or less.

In an exemplary arrangement of the organic EL device according to the first exemplary embodiment, the refractive index of the first charge generating zone material is 1.80 or less, and the refractive index of the second charge generating zone material is 1.80 or less.

In an exemplary arrangement of the organic EL device according to the first exemplary embodiment, the first charge generating zone material and the second charge generating zone material are different from each other.

In an exemplary arrangement of the organic EL device according to the first exemplary embodiment, the refractive index of the first charge generating zone material is larger than the refractive index of the second charge generating zone material.

In an exemplary arrangement of the organic EL device according to the first exemplary embodiment, the refractive index of the first charge generating zone material is more than 1.70, and the refractive index of the second charge generating zone material is 1.70 or less.

In an exemplary arrangement of the organic EL device according to the first exemplary embodiment, the second charge generating layer contains the second charge generating zone material and an acceptor material described later.

In an exemplary arrangement of the organic EL device according to the first exemplary embodiment, a content of the acceptor material in the second charge generating layer is less than 50 mass %.

In an exemplary arrangement of the organic EL device according to the first exemplary embodiment, the content of the acceptor material in the second charge generating layer is 10 mass % or less, or 5 mass % or less.

In an exemplary arrangement of the organic EL device according to the first exemplary embodiment, the content of the acceptor material in the second charge generating layer is 1 mass % or more, or 3 mass % or less.

In an exemplary arrangement of the organic EL device according to the first exemplary embodiment, when the second charge generating layer contains the second charge generating zone material and the acceptor material, a content of the second charge generating zone material in the second charge generating layer is 40 mass % or more, 45 mass % or more, 50 mass % or more, 80 mass % or more, 90 mass % or more, or 95 mass % or more.

In an exemplary arrangement of the organic EL device according to the first exemplary embodiment, the content of the second charge generating zone material in the second charge generating layer is 99.5 mass % or less, 99 mass % or less, or 97 mass % or less. A total of the content of the acceptor material and the content of the second charge generating zone material in the second charge generating layer is 100 mass % or less.

In an exemplary arrangement of the organic EL device according to the first exemplary embodiment, the second charge generating zone material is a hole transporting zone material (preferably, a second hole transporting zone material) described later.

In an exemplary arrangement of the organic EL device according to the first exemplary embodiment, the second charge generating zone material contained in the second charge generating layer and the hole transporting zone material contained in a layer (e.g., a second hole transporting layer) in the hole transporting zone are mutually the same compound or different compounds.

### Electron Transporting Zone

In an exemplary arrangement of the organic EL device according to the first exemplary embodiment, the two or more emitting units each independently include an electron transporting zone.

In an exemplary arrangement of the organic EL device according to the first exemplary embodiment, the first emitting unit includes a first electron transporting zone and the second emitting unit includes a second electron transporting zone.

### First Electron Transporting Zone

In an exemplary arrangement of the organic EL device according to the first exemplary embodiment, the first electron transporting zone is disposed between the first emitting zone and the second emitting unit.

In an exemplary arrangement of the organic EL device according to the first exemplary embodiment, the first electron transporting zone is disposed between the first emitting zone and the first charge generating zone.

In an exemplary arrangement of the organic EL device according to the first exemplary embodiment, the first electron transporting zone is disposed between the first emitting zone and the first charge generating layer.

In an exemplary arrangement of the organic EL device according to the first exemplary embodiment, the first electron transporting zone includes one or more layers.

In an exemplary arrangement of the organic EL device according to the first exemplary embodiment, the first electron transporting zone is disposed between the first emitting zone and the first charge generating layer, and the first electron transporting zone includes one layer or two or more layers.

In an exemplary arrangement of the organic EL device according to the first exemplary embodiment, the one layer or two or more layers included in the first electron transporting zone are each the low refractive index layer.

In an exemplary arrangement of the organic EL device according to the first exemplary embodiment, the first electron transporting zone includes the first electron transporting layer.

In an exemplary arrangement of the organic EL device according to the first exemplary embodiment, the first electron transporting layer is disposed between the first emitting zone and the first charge generating layer. The first electron transporting layer may be a hole blocking layer.

In an exemplary arrangement of the organic EL device according to the first exemplary embodiment, the first charge generating layer is in direct contact with the first electron transporting layer. In an exemplary arrangement of the organic EL device according to the first exemplary embodiment, the first charge generating layer needs not be in direct contact with the first electron transporting layer.

In an exemplary arrangement of the organic EL device according to the first exemplary embodiment, the first electron transporting layer is the low refractive index layer.

In an exemplary arrangement of the organic EL device according to the first exemplary embodiment, when the organic EL device satisfies Condition (TDM1), one of the at least two low refractive index layers in direct contact in Condition (TDM1) is the first electron transporting layer.

In an exemplary arrangement of the organic EL device according to the first exemplary embodiment, the first emitting layer is in direct contact with the first electron transporting layer.

In an exemplary arrangement of the organic EL device according to the first exemplary embodiment, the first electron transporting layer contains the first electron transporting zone material.

In an exemplary arrangement of the organic EL device according to the first exemplary embodiment, an organic material (low refractive index organic material) having a refractive index of 1.87 or less contained in the first electron transporting layer is the first electron transporting zone material.

In an exemplary arrangement of the organic EL device according to the first exemplary embodiment, a triplet energy of the first host material T₁(H1) and a triplet energy of the first electron transporting zone material T₁(E1) satisfy a relationship of a numerical formula (Numerical Formula 1) below.

T₁(E1)>T₁(H1) (Numerical Formula 1)

In an exemplary arrangement of the organic EL device according to the first exemplary embodiment, the first electron transporting zone includes two or more layers. In an exemplary arrangement of the organic EL device according to the first exemplary embodiment, the first electron transporting zone includes a first hole blocking layer and the first electron transporting layer.

In an exemplary arrangement of the organic EL device according to the first exemplary embodiment, the first electron transporting zone further includes the first hole blocking layer between the first electron transporting layer and the first emitting zone.

In an exemplary arrangement of the organic EL device according to the first exemplary embodiment, the first electron transporting zone includes the first hole blocking layer and the first electron transporting layer in the order from a side close to the first emitting zone.

In an exemplary arrangement of the organic EL device according to the first exemplary embodiment, the first electron transporting zone further includes the first hole blocking layer between the first electron transporting layer and the first emitting layer.

In an exemplary arrangement of the organic EL device according to the first exemplary embodiment, the first emitting layer is in direct contact with the first hole blocking layer.

In an exemplary arrangement of the organic EL device according to the first exemplary embodiment, the first electron transporting layer is in direct contact with the first hole blocking layer.

In an exemplary arrangement of the organic EL device according to the first exemplary embodiment, the first hole blocking layer is the low refractive index layer.

In an exemplary arrangement of the organic EL device according to the first exemplary embodiment, when the organic EL device satisfies Condition (TDM1), one of the at least two low refractive index layers in direct contact in Condition (TDM1) is the first hole blocking layer.

In an exemplary arrangement of the organic EL device according to the first exemplary embodiment, the first hole blocking layer contains the first electron transporting zone material. The first electron transporting zone material contained in the first hole blocking layer and the first electron transporting zone material contained in the first electron transporting layer may be mutually the same compound or different compounds.

In an exemplary arrangement of the organic EL device according to the first exemplary embodiment, an organic material (low refractive index organic material) having a refractive index of 1.87 or less contained in the first hole blocking layer is the first electron transporting zone material.

In an exemplary arrangement of the organic EL device according to the first exemplary embodiment, when the first electron transporting zone includes the first electron transporting layer, a triplet energy of the first host material T₁(H1) and a triplet energy of the first electron transporting zone material T₁(E_{ET}1) contained in the first electron transporting layer satisfy a relationship of a numerical formula (Numerical Formula 1A) below.

$${T}_{1} ( {E}_{ET} 1 ) > {T}_{1} ( H 1 ) \qquad ( Numerical Formula 1 A )$$

In an exemplary arrangement of the organic EL device according to the first exemplary embodiment, when the first electron transporting zone includes the first hole blocking layer, a triplet energy of the first host material T₁(H1) and a triplet energy of the first electron transporting zone material T₁(E_{HB}1) contained in the first hole blocking layer satisfy a relationship of a numerical formula (Numerical Formula 1B) below.

$${T}_{1} ( {E}_{HB} 1 ) > {T}_{1} ( H 1 ) \qquad ( Numerical Formula 1 B )$$

In an exemplary arrangement of the organic EL device according to the first exemplary embodiment, both the relationship of the numerical formula (Numerical Formula 1A) and the relationship of the numerical formula (Numerical Formula 1 B) are satisfied.

When the relationship of the numerical formula (Numerical Formula 1), (Numerical Formula 1A) or (Numerical Formula 1B) is satisfied, triplet excitons are prevented from diffusing into the first electron transporting zone and the first charge generating zone, and in the emitting layer, the triplet excitons of the host material are efficiently converted into singlet excitons, and the singlet excitons transfer to the dopant material (luminescent compound), causing optical energy deactivation. Therefore, TTF efficiency in the first emitting layer is improved, and improvement in luminous efficiency can be expected.

Conventionally, triplet-triplet annihilation (occasionally referred to as TTA) is known as a technique for improving the luminous efficiency of the organic electroluminescence device. The TTA is a mechanism in which triplet excitons collide with one another to generate singlet excitons. The TTA mechanism is occasionally also referred to as a TTF mechanism. The TTF is an abbreviation of Triplet-Triplet Fusion.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

$${}^{3} {A}^{*} {+}^{3} {A}^{*} \to {( 4 / 9 )}^{1} A + {( 1 / 9 )}^{1} {A}^{*} + ( 13 / 9 ] {}^{3} {A}^{*}$$

In other words, 5³A*→4¹A+1A* is satisfied, and it is expected that, among triplet excitons initially generated, which account for 75%, one fifth thereof (i.e. 20%) is changed to singlet excitons. Accordingly, the amount of singlet excitons which contribute to emission is 40%, which is a value obtained by adding 15% (75%×(⅕)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(½)=37.5%) to 25% (the amount ratio of initially generated singlet excitons). At this time, the TTF ratio is 37.5/62.5=60%.

### Triplet Energy T₁

A method of measuring a triplet energy T₁ is exemplified by a method below.

A measurement target compound is dissolved in EPA (diethylether:isopentane:ethanol=5:5:2 in volume ratio) so as to fall within a range from 10⁹ mol/L to 10⁻⁴ mol/L to prepare a solution, and the obtained solution is encapsulated in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value λ_{edge} [nm] at an intersection of the tangent and the abscissa axis. The calculated energy amount is defined as triplet energy T₁.

$${T}_{1} [ eV ] = 1239 \text{.85} / {λ}_{edge} \qquad Conversion Equation ( F1 )$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (produced by Hitachi High-Technologies Corporation) is usable. Any device for phosphorescence measurement is usable. A combination of a cooling unit, a low temperature container, an excitation light source and a light-receiving unit may be used for phosphorescence measurement.

In an exemplary arrangement of the organic EL device according to the first exemplary embodiment, the first electron transporting zone material has a refractive index of 1.83 or less.

In an exemplary arrangement of the organic EL device according to the first exemplary embodiment, the refractive index of the first electron transporting zone material is 1.83 or less, and the refractive index of the organic material (the first charge generating zone material) contained in the first charge generating layer is 1.83 or less.

In an exemplary arrangement of the organic EL device according to the first exemplary embodiment, the first electron transporting zone material and the first charge generating zone material are different from each other.

In an exemplary arrangement of the organic EL device according to the first exemplary embodiment, the first electron transporting zone material and the second charge generating zone material are different from each other.

In an exemplary arrangement of the organic EL device according to the first exemplary embodiment, the refractive index of the first electron transporting zone material is 1.83 or less, the refractive index of the organic material (the first charge generating zone material) contained in the first charge generating layer is 1.83 or less, and the refractive index of the second charge generating zone material is 1.83 or less.

In an exemplary arrangement of the organic EL device according to the first exemplary embodiment, the refractive index of the first electron transporting zone material is smaller than the refractive index of the first charge generating zone material.

In an exemplary arrangement of the organic EL device according to the first exemplary embodiment, the refractive index of the first charge generating zone material is more than 1.70, and the refractive index of the first electron transporting zone material is 1.70 or less.

### Second Electron Transporting Zone

In an exemplary arrangement of the organic EL device according to the first exemplary embodiment, the second electron transporting zone is disposed between the second emitting zone and the cathode.

In an exemplary arrangement of the organic EL device according to the first exemplary embodiment, the second electron transporting zone includes one or more layers. In an exemplary arrangement of the organic EL device according to the first exemplary embodiment, the second electron transporting zone includes a second electron transporting layer.

In an exemplary arrangement of the organic EL device according to the first exemplary embodiment, the second electron transporting zone includes two or more layers. In an exemplary arrangement of the organic EL device according to the first exemplary embodiment, the second electron transporting zone includes the second electron transporting layer and a second electron injecting layer.

In an exemplary arrangement of the organic EL device according to the first exemplary embodiment, the second electron transporting layer is in direct contact with the second emitting layer in the second emitting zone.

In an exemplary arrangement of the organic EL device according to the first exemplary embodiment, the second electron transporting zone includes three or more layers.

In an exemplary arrangement of the organic EL device according to the first exemplary embodiment, the second electron transporting zone includes three layers, and the three layers are a second hole blocking layer, the second electron transporting layer, and the second electron injecting layer.

In an exemplary arrangement of the organic EL device according to the first exemplary embodiment, the second electron transporting zone includes the second hole blocking layer, the second electron transporting layer and the second electron injecting layer in the order from a side close to the second emitting zone.

In an exemplary arrangement of the organic EL device according to the first exemplary embodiment, the second hole blocking layer is in direct contact with the second emitting layer in the second emitting zone.

In an exemplary arrangement of the organic EL device according to the first exemplary embodiment, the second hole blocking layer is in direct contact with the second electron transporting layer.

In an exemplary arrangement of the organic EL device according to the first exemplary embodiment, the second electron transporting layer is in direct contact with the second electron injecting layer.

In an exemplary arrangement of the organic EL device according to the first exemplary embodiment, the second electron injecting layer is in direct contact with the cathode.

In an exemplary arrangement of the organic EL device according to the first exemplary embodiment, the second electron transporting zone contains a second electron transporting zone material.

### Electron Transporting Zone Material

In the organic EL device according to the first exemplary embodiment, a material contained in the electron transporting zone is referred to as an electron transporting zone material. The electron transporting zone material is, for instance, the first electron transporting zone material described above and the second electron transporting zone material. The electron transporting zone material is also usable as the first charge generating zone material.

In an exemplary arrangement of the organic EL device according to the first exemplary embodiment, at least one layer of layers included in the first electron transporting zone contains, as the first electron transporting zone material, a compound represented by a formula (E1), (E2), (E3), (E4), (E41), (E42), (E43), (E44), (E5), (E61), (E62) or (E7) below.

In an exemplary arrangement of the organic EL device according to the first exemplary embodiment, at least one layer of layers included in the second electron transporting zone contains, as the second electron transporting zone material, a compound represented by the formula (E1), (E2), (E3), (E4), (E41), (E42), (E43), (E44), (E5), (E61), (E62) or (E7) below.

In an exemplary arrangement of the organic EL device according to the first exemplary embodiment, the first charge generating layer contains, as the first charge generating zone material, a compound represented by the formula (E1), (E2), (E3), (E4), (E41), (E42), (E43), (E44), (E5), (E61), (E62) or (E7) below.

In an exemplary arrangement of the organic EL device according to the first exemplary embodiment, the electron transporting zone material (the first electron transporting zone material or the second electron transporting zone material) is a compound represented by the formula (E1) below.

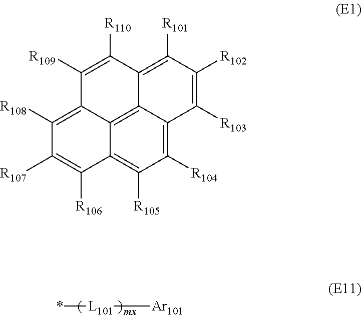

In the formula (E1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (E11) above;
at least one of R₁₀₁ to R₁₁₀ is a group represented by the formula (E11);
when a plurality of groups represented by the formula (E11) are present, the plurality of groups represented by the formula (E11) are mutually the same or different:
L₁₀₁ is a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4 or 5, and when mx is 0, -(L₁₀₁)₀- is a single bond;
when two or more L₁₀₁ are present, the two or more L₁₀₁ are mutually the same or different;
when two or more Ar₁₀₁ are present, the two or more Ar₁₀₁ are mutually the same or different; and
* in the formula (E11) represents a bonding position to the pyrene ring in the formula (E1).

In the formula (E1):
R₉₀₁, R₉₀₂, R₉₀₃, R₉₀₄, R₉₀₅, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different:
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the first exemplary embodiment, the electron transporting zone material (the first electron transporting zone material or the second electron transporting zone material) is a compound represented by the formula (E2) below.

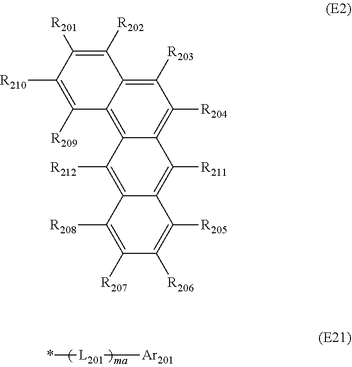

In the formula (E2):
at least one combination of adjacent two or more of R₂₀₁ to R₂₁₂ are mutually bonded to form a substituted or unsubstituted monocyclic ring, mutually bonded to form a substituted or unsubstituted fused ring, or not mutually bonded;
R₂₀₁ to R₂₁₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (E21) above;
at least one of R₂₀₁ to R₂₁₂ forming neither the substituted or unsubstituted monocyclic ring nor the substituted or unsubstituted fused ring is a group represent by the formula (E21);
when a plurality of groups represented by the formula (E21) are present, the plurality of groups represented by the formula (E21) are mutually the same or different;
L₂₀₁ is a substituted or unsubstituted arylene group having 6 to 50 ring carbon atoms, or a substituted or unsubstituted divalent heterocyclic group having 5 to 50 ring atoms:
ma is 0, 1, 2, 3, 4 or 5, and when ma is 0, -(L₂₀₁)₀- is a single bond;
when two or more L₂₀₁ are present, the two or more L₂₀₁ are mutually the same or different;
Ar₂₀₁ is a substituted or unsubstituted aryl group having 6 to 50 ring carbon atoms, or a substituted or unsubstituted heterocyclic group having 5 to 50 ring atoms;
when two or more Ar₂₀₁ are present, the two or more Ar₂₀₁ are mutually the same or different:
* in the formula (E21) represents a bonding position to a benz[a]anthracene ring in the formula (E2); and
when at least one combination of adjacent two or more of R₂₀₁ to R₂₁₂ form either the substituted or unsubstituted monocyclic ring or the substituted or unsubstituted fused ring, * in the formula (E21) represents a bonding position to a basic skeleton of the formed cyclic structure.

In the formula (E2):
R₉₀₁, R₉₀₂, R₉₀₃, R₉₀₄, R₉₀₅, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different:
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the first exemplary embodiment, the electron transporting zone material (the first electron transporting zone material or the second electron transporting zone material) is a compound represented by a formula (E3) below.

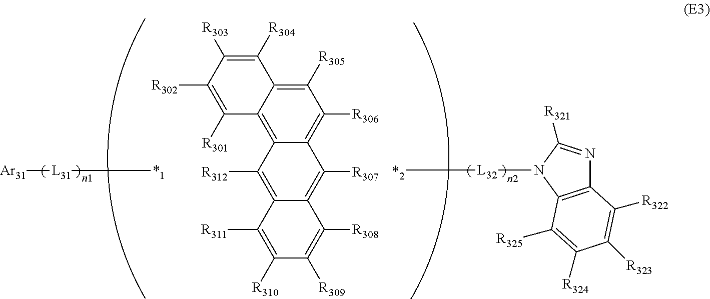

In the formula (E3):
one of R₃₀₇ and R₃₁₂ represents a single bond to *1 and the other of R₃₀₇ and R₃₁₂ represents a single bond to *2;
R₃₀₁ to R₃₀₆, R₃₀₈ to R₃₁₁, and R₃₂₂ to R₃₂₅ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₃₂₁ is a substituted or unsubstituted alkyl group having 1 to 6 carbon atoms, or a substituted or unsubstituted cycloalkyl group having 3 to 10 ring carbon atoms:
Ar₃₁ is a hydrogen atom, a substituted or unsubstituted aryl group having 6 to 18 ring carbon atoms, a substituted or unsubstituted oxygen-containing heterocyclic group having 5 to 18 ring atoms, or a substituted or unsubstituted sulfur-containing heterocyclic group having 5 to 18 ring atoms;
L₃₁ and L₃₂ are each independently a substituted or unsubstituted arylene group having 6 to 14 ring carbon atoms, or a substituted or unsubstituted divalent heterocyclic group having 5 to 14 ring atoms;
n₁ is 0, 1, 2 or 3, and n₂ is 0, 1, 2 or 3;
when n₁ is 0, -(L₃₁)₀- is a single bond;
when n₁ is 2 or more, two or more L₃₁ are mutually linked in series;
when n₁ is 2 or more, the two or more L₃₁ are mutually the same or different;
when n₂ is 0, -(L₃₂)₀- is a single bond;
when n₂ is 2 or more, two or more L₃₂ are mutually linked in series; and
when n₂ is 2 or more, the two or more L₃₂ are mutually the same or different.

In the formula (E3):
R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device according to the first exemplary embodiment, the electron transporting zone material (the first electron transporting zone material or the second electron transporting zone material) is a compound represented by a formula (E4) below.

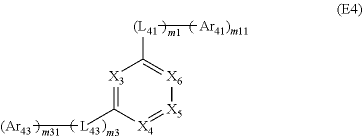

In the formula (E4):
X₂ is N or C-(L₄₂)m₂-(Ar₄₂)m₂₁, X₄ is N or C-(L₄₄)m₄-(Ar₄₄)m₄₁, X₅ is N or C-(L₄₅)m₅-(Ar₄₅)m₅₁, X₆ is N or C-(L₄₆)m₆-(Ar₄₆)m₆₁, and at least one of X₂, X₄, X₅ or X₆ is a nitrogen atom;
L₄₁ to L₄₆ are each independently a substituted or unsubstituted arylene group having 6 to 50 ring carbon atoms, or a substituted or unsubstituted divalent heterocyclic group having 5 to 50 ring atoms;
m₁ is 0, 1, 2 or 3, and when m₁ is 0, -(L₄₁)₀- is a single bond;
m₂ is 0, 1, 2 or 3, and when m₂ is 0, -(L₄₂)₀- is a single bond;
m₃ is 0, 1, 2 or 3, and when m₃ is 0, -(L₄₃)₀- is a single bond;
m₄ is 0, 1, 2 or 3, and when m₄ is 0, -(L₄₄)₀- is a single bond;
m₅ is 0, 1, 2 or 3, and when m₅ is 0, -(L₄S)₀-is a single bond;
m₆ is 0, 1, 2 or 3, and when m₆ is 0, -(L₄₆)₀- is a single bond;
m₁₁ is 1, 2, 3 or 4, m₂₁ is 1, 2, 3 or 4, m₃₁ is 1, 2, 3 or 4, m₄₁ is 1, 2, 3 or 4, m₅₁ is 1, 2, 3 or 4, and m₆₁ is 1, 2, 3 or 4;
Ar₄₁ to Ar₄₆ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms; and
at least one of Ar₄₁ to Ar₄₆ is a substituted or unsubstituted aryl group having 13 to 50 ring carbon atoms, or a substituted or unsubstituted heterocyclic group having 13 to 50 ring atoms.

In the formula (E4):
R₉₁₁, R₉₁₂, R₉₁₃, R₉₁₄, R₉₁₅, R₉₁₆, R₉₁₇, R₉₁₈, R₉₁₉, R₉₂₀, and R₉₂₁ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₁₁ are present, the plurality of R₉₁₁ are mutually the same or different;
when a plurality of R₉₁₂ are present, the plurality of R₉₁₂ are mutually the same or different:
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁₈ are mutually the same or different;
when a plurality of R₉₁₉ are present, the plurality of R₉₁₉ are mutually the same or different;
when a plurality of R₉₂₀ are present, the plurality of R₉₂₀ are mutually the same or different; and
when a plurality of R₉₂₁ are present, the plurality of R₉₂₁ are mutually the same or different.

In an exemplary arrangement of the organic EL device according to the first exemplary embodiment, the electron transporting zone material (the first electron transporting zone material or the second electron transporting zone material) is a compound represented by a formula (E41) below.

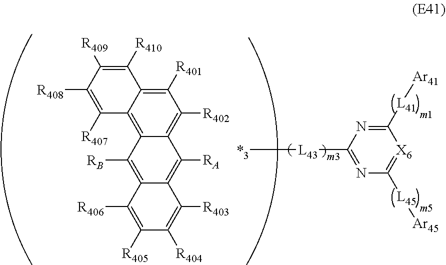

In the formula (E41):
L₄₁, L₄₃, and L₄₅ respectively represent the same as L₄₁, L₄₃, and L₄₅ in the formula (E4), and m₁, m₃, and m₅ respectively represent the same as m₁, m₃, and m₅ in the formula (E4);
one of R_{A} and R_{B} represents a single bond with *3, the other of R_{A} and R_{B} not being the single bond with *3 is a hydrogen atom or a substituent S, and “a substituent group” of “a substituted or unsubstituted group” in the substituent S as R_{A} or R_{B} has at least one substituent T;
R₄₀₁ to R₄₀₉ are each independently a hydrogen atom or a substituent R;
the substituent R is selected from the group consisting of a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms;
when two or more substituents R are present, the two or more substituents R are mutually the same or different;
R₄₁₀ is a hydrogen atom;
combinations of adjacent two or more of R₄₀₁ to R₄₀₉ and one of R_{A} and R_{B} not being a single bond with *3 are not mutually bonded;
X₆ is a nitrogen atom or C—Ar₄₆, and Ar₄₆ is a hydrogen atom or a substituent V;
at least one of Ar₄₁ or Ar₄₅ is a substituent X, and “a substituent group” of “a substituted or unsubstituted group” in the substituent X as Ar₄₁ and Ar₄₅ has at least one substituent U;
Ar₄₁ and Ar₄₅ not being the substituent X is a substituted or unsubstituted aryl group having 6 to 50 ring carbon atoms, or a substituted or unsubstituted heterocyclic group having 5 to 50 ring atoms and including no nitrogen atom;
the substituent X is a group selected from the group consisting of a substituted or unsubstituted biphenylyl group, a substituted or unsubstituted terphenylyl group, a substituted or unsubstituted naphthyl group, a substituted or unsubstituted benzanthryl group, a substituted or unsubstituted phenanthryl group, a substituted or unsubstituted benzophenanthryl group, a substituted or unsubstituted phenalenyl group, a substituted or unsubstituted pyrenyl group, a substituted or unsubstituted chrysenyl group, a substituted or unsubstituted benzochrysenyl group, a substituted or unsubstituted triphenylenyl group, a substituted or unsubstituted benzotriphenylenyl group, a substituted or unsubstituted tetracenyl group, a substituted or unsubstituted pentacenyl group, a substituted or unsubstituted fluorenyl group, a substituted or unsubstituted 9,9′-spirobifluorenyl group, a substituted or unsubstituted benzofluorenyl group, a substituted or unsubstituted dibenzofluorenyl group, a substituted or unsubstituted fluoranthenyl group, a substituted or unsubstituted benzofluoranthenyl group, a substituted or unsubstituted perylenyl group, a heterocyclic group represented by a formula (E411) below, and a heterocyclic group represented by a formula (E412) below;
when two or more substituents X are present, the two or more substituents X are mutually the same or different;
when two or more substituents U are present, the two or more substituents U are mutually the same or different;
the substituent S as R_{A} or R_{B}, the substituent T for “a substituted or unsubstituted group” in R_{A} or R_{B}, the substituent U for “a substituted or unsubstituted group” in Ar₄₁ and Ar₄₅, and the substituent V as Ar₄₆ are each independently selected from the group consisting of a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms; and
when two or more substituents T are present, the two or more substituents T are mutually the same or different.

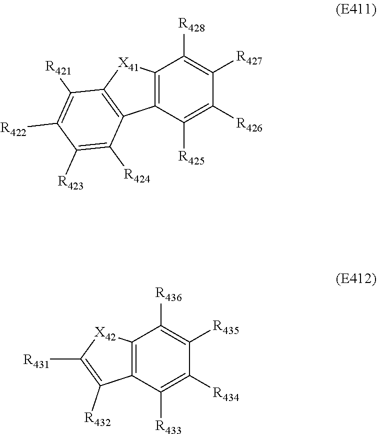

In the formula (E411):
X₄₁ is N(R₄₂₉), an oxygen atom or a sulfur atom;
one of R₄₂₁ to R₄₂₉ represents a single bond with L₄₁ or L₄₅;
at least one combination of adjacent two or more of R₄₂₁ to R₄₂₉ are mutually bonded to form a substituted or unsubstituted monocyclic ring, mutually bonded to form a substituted or unsubstituted fused ring, or not mutually bonded; and
R₄₂₁ to R₄₂₉ not representing a single bond with L₄₁ or L₄₅, not forming the substituted or unsubstituted monocyclic ring, and not forming the substituted or unsubstituted fused ring are each independently selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms and including no nitrogen atom.

In the formula (E412):
X₄₂ is N(R₄₃₇), an oxygen atom or a sulfur atom;
one of R₄₃₁ to R₄₃₇ represents a single bond with L₄₁ or L₄₅;
at least one combination of adjacent two or more of R₄₃₁ to R₄₃₇ are mutually bonded to form a substituted or unsubstituted monocyclic ring, mutually bonded to form a substituted or unsubstituted fused ring, or not mutually bonded; and
R₄₃₁ to R₄₃₇ not representing a single bond with L₄₁ or L₄₅, not forming the substituted or unsubstituted monocyclic ring, and not forming the substituted or unsubstituted fused ring are each independently selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms and including no nitrogen atom.

In the formulae (E41), (E411) and (E412):
R₉₁₁ to R₉₁₉ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms and including no nitrogen atom;
when a plurality of R₉₁₁ are present, the plurality of R₉₁₁ are mutually the same or different;
when a plurality of R₉₁₂ are present, the plurality of R₉₁₂ are mutually the same or different;
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁₈ are mutually the same or different; and
when a plurality of R₉₁₉ are present, the plurality of R₉₁₉ are mutually the same or different.

In an exemplary arrangement of the organic EL device according to the first exemplary embodiment, the electron transporting zone material (the first electron transporting zone material or the second electron transporting zone material) is a compound represented by a formula (E42) below.

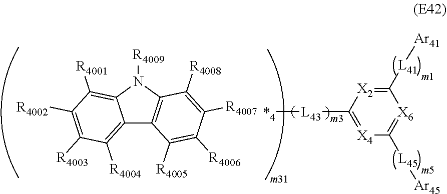

In the formula (E42):
X₂, X₄, X₆, L₄₁, L₄₃, L₄₅, Ar₄₁ and Ar₄, respectively represent the same as X₂, X₄, X₆, L₄₁, L₄₃, L₄₅, Ar₄₁ and Ar₄₅ in the formula (E4), and m₁, m₃, m₃₁ and m₅ respectively represent the same as m₁, m₃, m₃₁ and m₅ in the formula (E4);
at least one combination of adjacent two or more of R₄₀₀₁ to R₄₀₀₈ are mutually bonded to form a substituted or unsubstituted monocyclic ring, mutually bonded to form a substituted or unsubstituted fused ring, or not mutually bonded;
R₄₀₀₉, and R₄₀₀₁ to R₄₀₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₄₀₀₉, or R₄₀₀₁ to R₄₀₀₈ forming neither the substituted or unsubstituted monocyclic ring nor the substituted or unsubstituted fused ring is a single bond with *4;
*4 represents a bonding position to a carbazole ring in the formula (E42); and
when at least one combination of adjacent two or more of R₄₀₀₁ to R₄₀₀₈ form the substituted or unsubstituted monocyclic ring or the substituted or unsubstituted fused ring, *4 in the formula (E42) represents a bonding position to a basic skeleton of the formed cyclic structure.

In the formula (E42), R₉₁₁, R₉₁₂, R₉₁₃, R₉₁₄, R₉₁₅, R₉₂₀, and R₉₂₁ respectively represent the same as R₉₁₁, R₉₁₂, R₉₁₃, R₉₁₄, R₉₁₅, R₉₂₀, and R₉₂₁ in the formula (E4).

In an exemplary arrangement of the organic EL device according to the first exemplary embodiment, the electron transporting zone material (the first electron transporting zone material or the second electron transporting zone material) is a compound represented by a formula (E43) below.

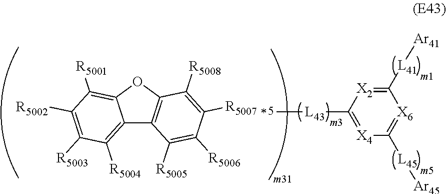

In the formula (E43):
X₂, X₄, X₆, L₄₁, L₄₃, L₄₅, Ar₄₁ and Ar₄₅ respectively represent the same as X₂, X₄, X₆, L₄₁, L₄₃, L₄₅, Ar₄₁ and Ar₄₅ in the formula (E4), and m₁, m₃, m₃₁ and m₅ respectively represent the same as m₁, m₃, m₃₁ and m₅ in the formula (E4);
at least one combination of adjacent two or more of R₅₀₀₁ to R₅₀₀₈ are mutually bonded to form a substituted or unsubstituted monocyclic ring, mutually bonded to form a substituted or unsubstituted fused ring, or not mutually bonded:
R₅₀₀₁ to R₅₀₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms:
at least one of R₅₀₀₁ to R₅₀₀₈ forming neither the substituted or unsubstituted monocyclic ring nor the substituted or unsubstituted fused ring is a single bond with *5;
*5 represents a bonding position to a dibenzofuran ring in the formula (E43); and
when at least one combination of adjacent two or more of R₅₀₀₁ to R₅₀₀₈ form the substituted or unsubstituted monocyclic ring or the substituted or unsubstituted fused ring, *5 in the formula (E43) represents a bonding position to a basic skeleton of the formed cyclic structure.

In the formula (E43), R₉₁₁, R₉₁₂, R₉₁₃, R₉₁₄, R₉₁₅, R₉₂₀, and R₉₂₁ respectively represent the same as R₉₁₁, R₉₁₂, R₉₁₃, R₁₄, R₉₁₅, R₉₂₀, and R₉₂₁ in the formula (E4).

In an exemplary arrangement of the organic EL device according to the first exemplary embodiment, the electron transporting zone material (the first electron transporting zone material or the second electron transporting zone material) is a compound represented by a formula (E44) below.

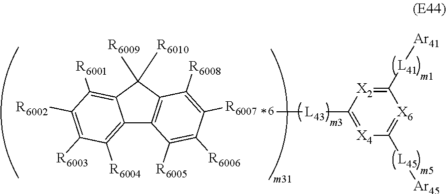

In the formula (E44):
X₂, X₄, X₆, L₄₁, L₄₃, L₄₅, Ar₄₁ and Ar₄₅ respectively represent the same as X₂, X₄, X₆, L₄₁, L₄₃, L₄₅, Ar₄₁ and Ar₄₅ in the formula (E4), and m₁, m₃, m₃₁ and m₅ respectively represent the same as m₁, m₃, m₃₁ and me in the formula (E4);
a combination of R₆₀₀₉ and R₆₀₁₀ are mutually bonded to form a substituted or unsubstituted monocyclic ring, mutually bonded to form a substituted or unsubstituted fused ring, or not mutually bonded;
at least one combination of adjacent two or more of R₆₀₀₁ to R₆₀₀₈ are mutually bonded to form a substituted or unsubstituted monocyclic ring, mutually bonded to form a substituted or unsubstituted fused ring, or not mutually bonded:
R₆₀₀₁ to R₆₀₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms:
at least one of R₆₀₀₁ to R₆₀₁₀ forming neither the substituted or unsubstituted monocyclic ring nor the substituted or unsubstituted fused ring is a single bond with *6;
*6 represents a bonding position to a fluorene ring in the formula (E44); and
when at least one combination of adjacent two or more of R₆₀₀₁ to R₆₀₁₀ form the substituted or unsubstituted monocyclic ring or the substituted or unsubstituted fused ring, *6 in the formula (E44) represents a bonding position to a basic skeleton of the formed cyclic structure.

In the formula (E44), R₉₁₁, R₉₁₂, R₉₁₃, R₉₁₄, R₉₁₅, R₉₂₀, and R₉₂₁ respectively represent the same as R₉₁₁, R₉₁₂, R₉₁₃, R₉₁₄, R₉₁₅, R₉₂₀, and R₉₂₁ in the formula (E4).

In an exemplary arrangement of the organic EL device according to the first exemplary embodiment, the electron transporting zone material (the first electron transporting zone material or the second electron transporting zone material) is a compound represented by a formula (E5) below.

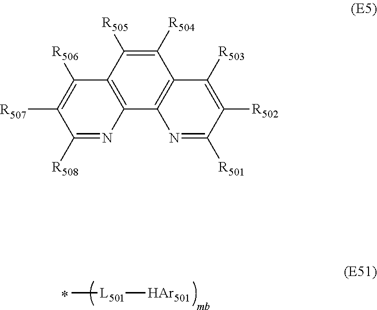

In the formula (E5):
at least one combination of adjacent two or more of R₅₀₁ to R₅₀₈ are mutually bonded to form a substituted or unsubstituted monocyclic ring, mutually bonded to form a substituted or unsubstituted fused ring, or not mutually bonded;
R₅₀₁ to R₅₀₈ forming neither the substituted or unsubstituted monocyclic ring nor the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₅₀₅), a substituted or unsubstituted alkoxycarbonyl group having 1 to 50 carbon atoms, a halogen atom, a cyano group, a nitro group, a carboxy group a group represented by —N(R_{906N})(R_{907N}), or a group represented by a formula (E51) above;
when a plurality of groups represented by the formula (E51) are present, the plurality of groups represented by the formula (E51) are mutually the same or different;
L₅₀₁ is a single bond, a substituted or unsubstituted arylene group having 6 to 50 ring carbon atoms, or a substituted or unsubstituted divalent heterocyclic group having 5 to 50 ring atoms;
HAr₅₀₁ is a substituted or unsubstituted aryl group having 6 to 50 ring carbon atoms, or a substituted or unsubstituted heterocyclic group having 5 to 50 ring atoms;
mb is 1, 2, 3 or 4;
when mb is 2, 3 or 4;
two or more L₅₀₁ are mutually the same or different;
two or more HAr₅₀₁ are mutually the same or different;
* in the formula (E51) represents a bonding position to a phenanthroline ring in the formula (E5); and
when at least one combination of adjacent two or more of R₅₀₁ to R₅₀₈ form the substituted or unsubstituted monocyclic ring or the substituted or unsubstituted fused ring, * in the formula (E51) represents a bonding position to a basic skeleton of the formed cyclic structure.

In the formula (E5):
R₉₀₄ and R₉₀₅ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₄ are present, the plurality of R₉₀₄ are mutually the same or different;
when a plurality of R₉₀₅ are present, the plurality of R₉₀₅ are mutually the same or different;
R_{905N} and R_{906N} are each independently a substituted or unsubstituted aryl group having 6 to 50 ring carbon atoms;
when a plurality of R_{905N} are present, the plurality of R_{905N} are mutually the same or different; and
when a plurality of R_{906N} are present, the plurality of R_{906N} are mutually the same or different.

In an exemplary arrangement of the organic EL device according to the first exemplary embodiment, at least one of R₅₀₁ to R₅₀₈ in the electron transporting zone material (the first electron transporting zone material or the second electron transporting zone material) is a group represented by the formula (E51), and the group represented by the formula (E51) is a group represented by one of formulae (E511) to (E515) below.

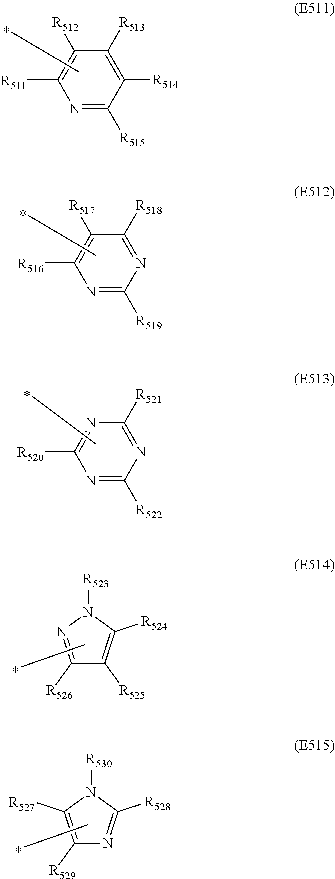

In the formula (E511), one of R₅₁₁, R₅₁₂, R₅₁₃, R₅₁₄, and R₅₁₅ represents a single bond with L₅₀₁;
in the formula (E512), one of R₅₁₆, R₅₁₇, R₅₁₈, and R₅₁₉ represents a single bond with L₅₀₁;
in the formula (E513), one of R₅₂₀, R₅₂₁, and R₅₂₂ represents a single bond with L₅₀₁;
in the formula (E514), one of R₅₂₃, R₅₂₄, R₅₂₅, and R₅₂₆ represents a single bond with L₅₀₁;
in the formula (E515), one of R₅₂₇, R₅₂₈, R₅₂₉, and R₅₃₀ represents a single bond with L₅₀₁;
at least one combination of adjacent two or more of R₅₁₁ to R₅₃₀ are mutually bonded to form a substituted or unsubstituted monocyclic ring, mutually bonded to form a substituted or unsubstituted fused ring, or not mutually bonded;
R₅₁₁ to R₅₃₀ not representing a single bond with L₅₀₁, not forming the substituted or unsubstituted monocyclic ring, and not forming the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₉₀₅), a substituted or unsubstituted alkoxycarbonyl group having 1 to 50 carbon atoms, a halogen atom, a cyano group, a nitro group, a carboxy group, or a group represented by —N(R_{905N})(R_{906N}); and
R₉₀₄, R₉₀₅, R_{905N}, and R_{906N} respectively represent the same as R₉₀₄, R₉₀₅, R_{905N}, and R_{906N} in the formula (E5), and * represents a bonding position.

In an exemplary arrangement of the organic EL device according to the first exemplary embodiment, at least one of R₅₀₁ to R₅₀₈ in the electron transporting zone material (the first electron transporting zone material or the second electron transporting zone material) is a group represented by the formula (E51), and the group represented by the formula (E51) is a group represented by one of formulae (E516) to (E526) below.

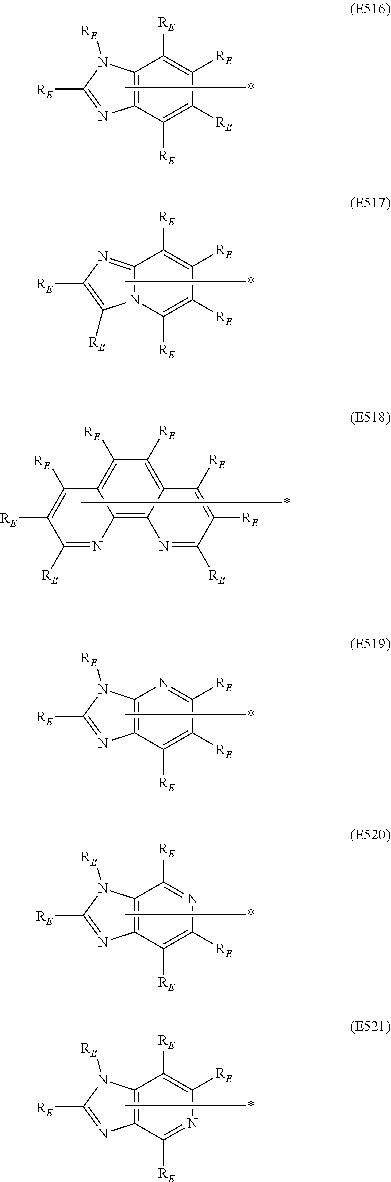

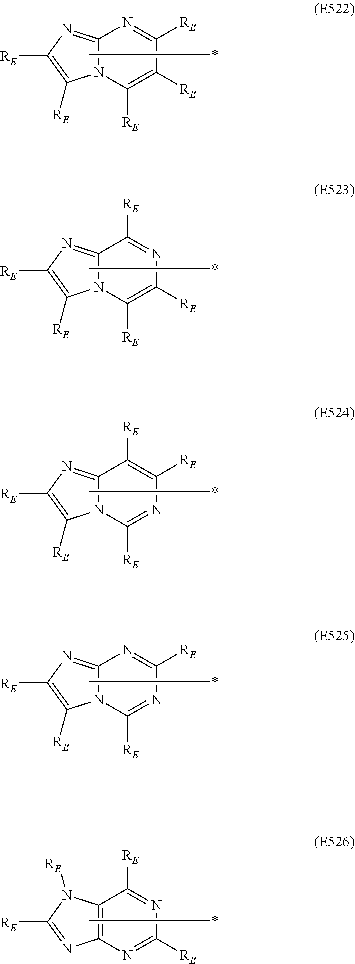

In the formulae (E516) to (E526):
one of R_{E} represents a single bond with L₅₀₁;
at least one combination of adjacent two or more of a plurality of R_{E} are mutually bonded to form a substituted or unsubstituted monocyclic ring, mutually bonded to form a substituted or unsubstituted fused ring, or not mutually bonded;
each R_{E} not representing a single bond with L₅₀₁, not forming the substituted or unsubstituted monocyclic ring, and not forming the substituted or unsubstituted fused ring independently represents the same as R₅₁₁ to R₅₃₀ not representing a single bond with L₅₀₁, not forming the substituted or unsubstituted monocyclic ring, and not forming the substituted or unsubstituted fused ring in the formulae (E511) to (E515); and
a plurality of R_{E} are mutually the same or different, and * represents a bonding position.

In an exemplary arrangement of the organic EL device according to the first exemplary embodiment, the electron transporting zone material (the first electron transporting zone material or the second electron transporting zone material) is a compound represented by a formula (E61) or (E62) below.

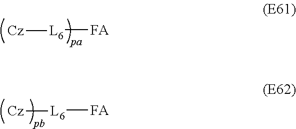

In the formulae (E61) and (E62):
each Cz is independently carbazolyl groups or indolyl groups represented by one formula selected from the group consisting of formulae (E63), (E64), (E65), (E66), (E67) and (E68) below;
each L₆ is independently a single bond, a substituted or unsubstituted arylene group having 6 to 50 ring carbon atoms, or a substituted or unsubstituted divalent heterocyclic group having 5 to 50 ring atoms;
pa is 0, 1, 2, 3, 4, 5, 6, 7, 8, 9 or 10, and pb is 0, 1, 2, 3, 4, 5, 6, 7, 8, 9 or 10;
when a plurality of L₆ are present, the plurality of L₆ are mutually the same or different;
when a plurality of Cz are present, the plurality of Cz are mutually the same or different; and
each FA is independently a substituted or unsubstituted fused ring group having 6 to 50 ring carbon atoms, where FA is not an unsubstituted carbazolyl group.

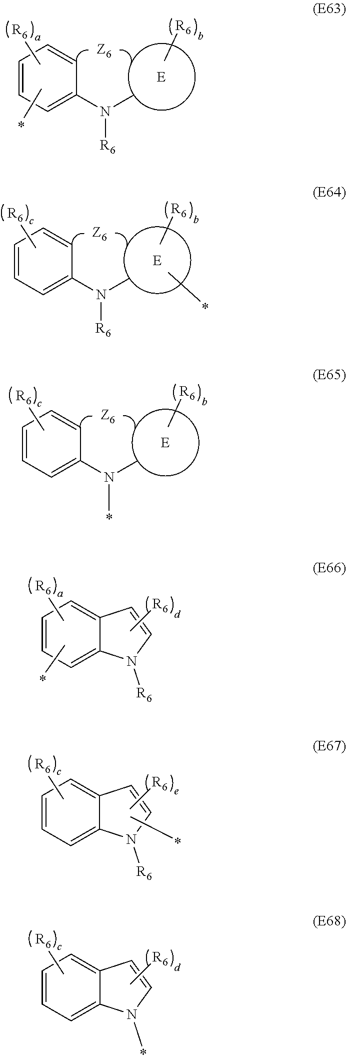

In the formulae (E63), (E64), (E65), (E66), (E67) and (E68):
each Z₆ is independently a single bond, —C(R₆₀₁)(R₆₀₂)—, —Si(R₆₀₃)(R₆₀₄)—, —O—, —CO—, or —N(R₆₀₅)—;
R₆₀₁, R₆₀₂, R₆₀₃, R₆₀₄ and R₆₀₅ are each independently a hydrogen atom, a substituted or unsubstituted aryl group having 6 to 50 ring carbon atoms, a substituted or unsubstituted heterocyclic group having 5 to 50 ring atoms, or a substituted or unsubstituted alkyl group having 1 to 50 carbon atoms;
a ring E is each independently a substituted or unsubstituted aliphatic hydrocarbon ring having 3 to 20 ring carbon atoms, a substituted or unsubstituted nitrogen-atom-containing nonaromatic heterocycle having 3 to 20 ring atoms, a substituted or unsubstituted aromatic hydrocarbon ring having 4 to 50 ring carbon atoms, or a substituted or unsubstituted aromatic heterocycle having 4 to 50 ring atoms;
a is 3, each b is independently 0, 1, 2, 3 or 4, c is 4, d is 2, and e is 1;
at least one combination of adjacent two or more of a plurality of R₆ are mutually bonded to form a substituted or unsubstituted monocyclic ring, mutually bonded to form a substituted or unsubstituted fused ring, or not mutually bonded;
each R₆ forming neither the substituted or unsubstituted monocyclic ring nor the substituted or unsubstituted fused ring is independently a hydrogen atom, a substituted or unsubstituted aryl group having 6 to 50 ring carbon atoms, a substituted or unsubstituted heterocyclic group having 5 to 50 ring atoms, a substituted or unsubstituted alkyl group having 1 to 50 carbon atoms, a group represented by —O—(R₉₀₄), a group represented by —S—(R₉₀₅), a substituted or unsubstituted aralkyl group having 7 to 50 carbon atoms, a carboxy group, a halogen atom, a cyano group, or a nitro group;
a plurality of R₆₀₁ are mutually the same or different;
a plurality of R₆₀₂ are mutually the same or different;
a plurality of R₆₀₃ are mutually the same or different;
a plurality of R₆₀₄ are mutually the same or different;
a plurality of Ros are mutually the same or different;
a plurality of R are mutually the same or different; and
* represents a bonding position.

In the compound represented by the formula (E61) or (E62), R₉₀₄ and R₉₀₅ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₄ are present, the plurality of R₉₀₄ are mutually the same or different; and
when a plurality of R₉₀₅ are present, the plurality of R₉₀₅ are mutually the same or different.

In an exemplary arrangement of the organic EL device according to the first exemplary embodiment, the group represented by the formula (E63) is a group represented by one formula selected from the group consisting of formulae (E631), (E632), (E633) and (E634) below.

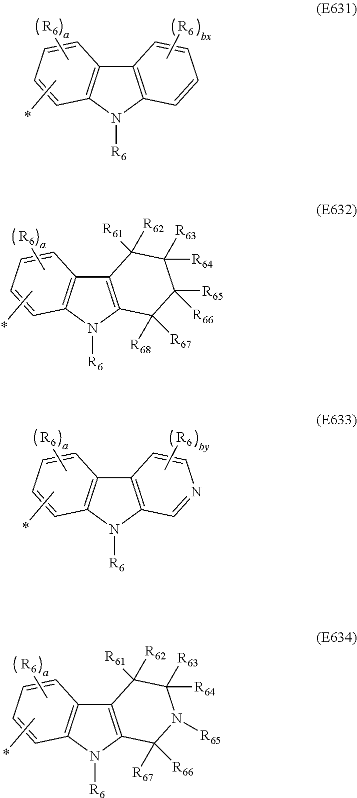

R₆ and a in the formulae (E631), (E632), (E633) and (E634) respectively represent the same as R₆ and a in the formula (E63), bx is 4, by is 3, R₆₁ to R₆₈ each independently represent the same as R₆ in the formula (E63), a plurality of R₆ are mutually the same or different, and * represents a bonding position.

In an exemplary arrangement of the organic EL device according to the first exemplary embodiment, the group represented by the formula (E65) is a group represented by one formula selected from the group consisting of formulae (E651), (E652), (E653) and (E654) below.

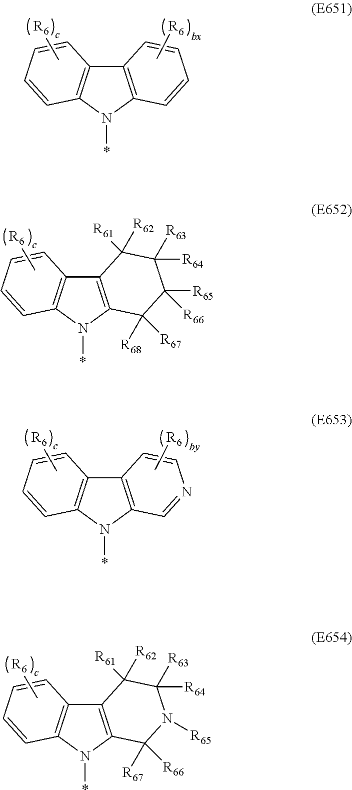

In the formulae (E651), (E652), (E653) and (E654), R₆ and c respectively represent the same as R₆ and c in the formula (E65), bx is 4, by is 3, R₆₁ to R₆₆ each independently represent the same as R₆ in the formula (E65), a plurality of R₆ are mutually the same or different, and * represents a bonding position.

In an exemplary arrangement of the organic EL device according to the first exemplary embodiment, the electron transporting zone material (the first electron transporting zone material or the second electron transporting zone material) is a compound represented by a formula (E7) below.

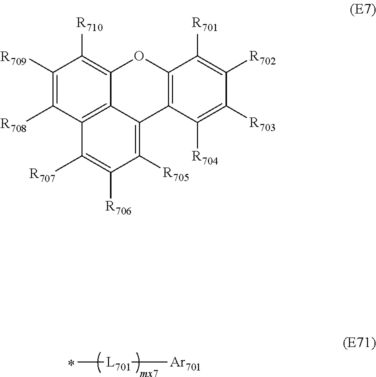

In the formula (E7):
R₇₀₁ to R₇₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (E71) above;
at least one of R₇₀₁ to R₇₁₀ is a group represented by the formula (E71);
when a plurality of groups represented by the formula (E71) are present, the plurality of groups represented by the formula (E71) are mutually the same or different;
L₇₀₁ is a single bond, a substituted or unsubstituted arylene group having 6 to 50 ring carbon atoms, or a substituted or unsubstituted divalent heterocyclic group having 5 to 50 ring atoms;
Ar₇₀₁ is a substituted or unsubstituted aryl group having 6 to 50 ring carbon atoms, or a substituted or unsubstituted heterocyclic group having 5 to 50 ring atoms;
mx7 is 0, 1, 2, 3, 4 or 5, and when mx7 is 0, -(L₇₀₁)₀- is a single bond;
when two or more L₇₀₁ are present, the two or more L₇₀₁ are mutually the same or different;
when two or more Ar₇₀₁ are present, the two or more Ar₇₀₁ are mutually the same or different; and
* in the formula (E71) represents a bonding position to a ring represented by the formula (E7).

In the compound represented by the formula (E7), R₉₀₁, R₉₀₂, R₉₀₃, R₉₀₄, R₉₀₅, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms:
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different:
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the first exemplary embodiment, the first charge generating zone material is not a compound having an anthracene skeleton.

In an exemplary arrangement of the organic EL device according to the first exemplary embodiment, when the first charge generating zone material is a compound represented by the formula (E5) (a compound having a phenanthroline skeleton), that first charge generating zone material includes only one phenanthroline skeleton.

In an exemplary arrangement of the organic EL device according to the first exemplary embodiment, the first electron transporting zone material is not a compound having an anthracene skeleton.

In an exemplary arrangement of the organic EL device according to the first exemplary embodiment, the first electron transporting zone material is a compound represented by the formula (E4) or (E42).

### Method of Producing Electron Transporting Zone Material

The electron transporting zone material can be produced by a known method. Further, the electron transporting zone material can be produced based on a known method through a known alternative reaction using a known material(s) tailored for the target compound.

### Specific Examples of Electron Transporting Zone Material

Specific examples of the electron transporting zone material include the following compounds. However, the invention is not limited to these specific examples. In the chemical formulae herein, a deuterium atom is denoted as D, and a protium atom is denoted as H or a description for a protium is omitted. Herein, occasionally, a methyl group is denoted as Me, a phenyl group is denoted as Ph, and a tert-butyl group is denoted as tBu.

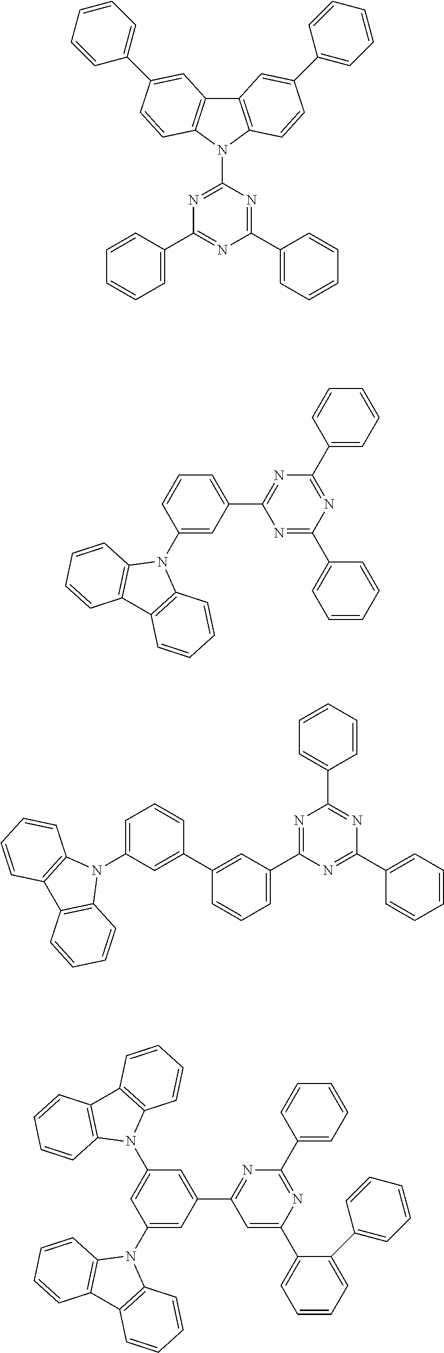 [SMILES: c1ccc(-c2ccc3c(c2)c2cc(-c4ccccc4)ccc2n3-c2nc(-c3ccccc3)nc(-c3ccccc3)n2)cc1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cccc(-c4cccc(-n5c6ccccc6c6ccccc65)c4)c3)n2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1]

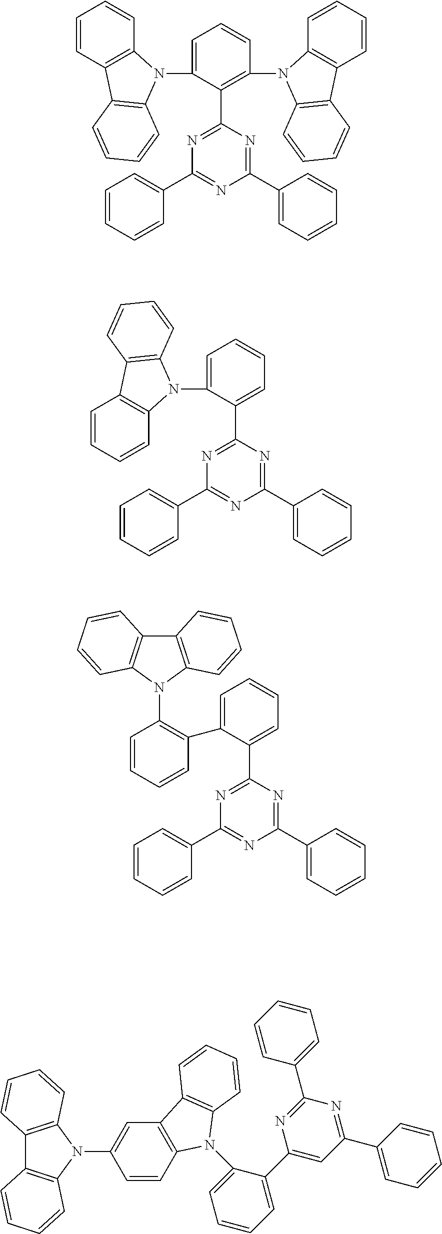 [SMILES: c1ccc(-c2nc(-c3ccccc3)nc(-c3c(-n4c5ccccc5c5ccccc54)cccc3-n3c4ccccc4c4ccccc43)n2)cc1 ; c1ccc(-c2nc(-c3ccccc3)nc(-c3ccccc3-n3c4ccccc4c4ccccc43)n2)cc1 ; c1ccc(-c2nc(-c3ccccc3)nc(-c3ccccc3-c3ccccc3-n3c4ccccc4c4ccccc43)n2)cc1 ; c1ccc(-c2cc(-c3ccccc3-n3c4ccccc4c4cc(-n5c6ccccc6c6ccccc65)ccc43)nc(-c3ccccc3)n2)cc1]

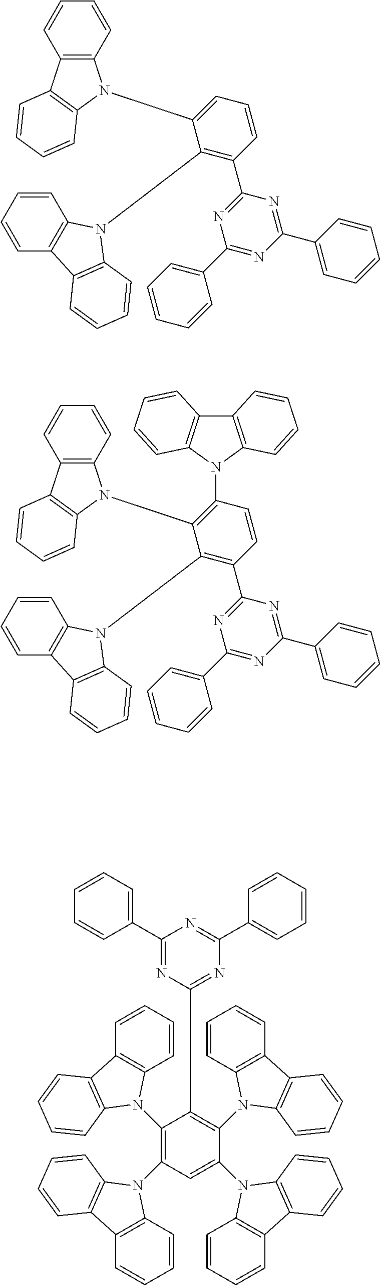 [SMILES: c1ccc(-c2nc(-c3ccccc3)nc(-c3cccc(-n4c5ccccc5c5ccccc54)c3-n3c4ccccc4c4ccccc43)n2)cc1 ; c1ccc(-c2nc(-c3ccccc3)nc(-c3ccc(-n4c5ccccc5c5ccccc54)c(-n4c5ccccc5c5ccccc54)c3-n3c4ccccc4c4ccccc43)n2)cc1 ; c1ccc(-c2nc(-c3ccccc3)nc(-c3c(-n4c5ccccc5c5ccccc54)c(-n4c5ccccc5c5ccccc54)cc(-n4c5ccccc5c5ccccc54)c3-n3c4ccccc4c4ccccc43)n2)cc1]

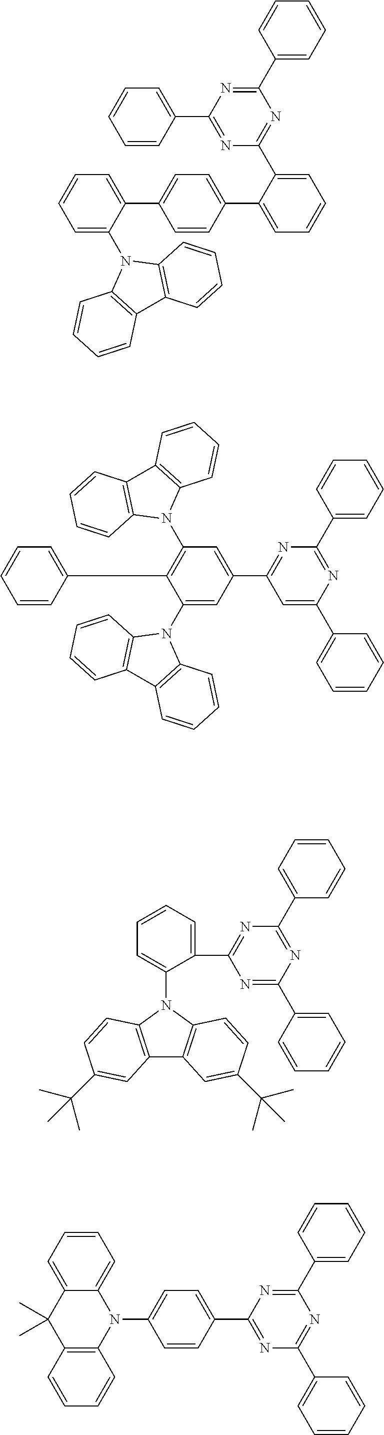 [SMILES: c1ccc(-c2nc(-c3ccccc3)nc(-c3ccccc3-c3ccc(-c4ccccc4-n4c5ccccc5c5ccccc54)cc3)n2)cc1 ; c1ccc(-c2cc(-c3cc(-n4c5ccccc5c5ccccc54)c(-c4ccccc4)c(-n4c5ccccc5c5ccccc54)c3)nc(-c3ccccc3)n2)cc1 ; CC(C)(C)c1ccc2c(c1)c1cc(C(C)(C)C)ccc1n2-c1ccccc1-c1nc(-c2ccccc2)nc(-c2ccccc2)n1 ; CC1(C)c2ccccc2N(c2ccc(-c3nc(-c4ccccc4)nc(-c4ccccc4)n3)cc2)c2ccccc21]

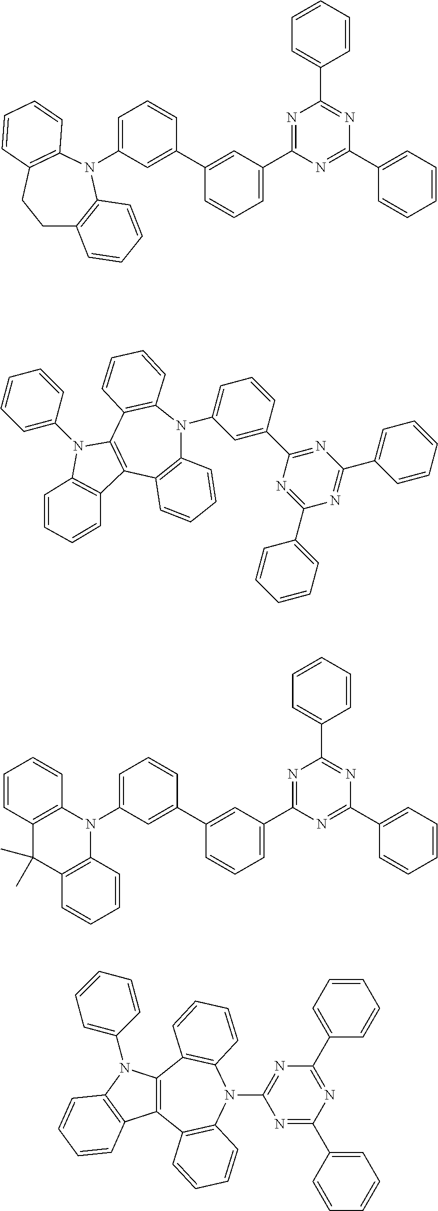 [SMILES: c1ccc(-c2nc(-c3ccccc3)nc(-c3cccc(-c4cccc(N5c6ccccc6CCc6ccccc65)c4)c3)n2)cc1 ; c1ccc(-c2nc(-c3ccccc3)nc(-c3cccc(N4c5ccccc5-c5c(n(-c6ccccc6)c6ccccc56)-c5ccccc54)c3)n2)cc1 ; CC1(C)c2ccccc2N(c2cccc(-c3cccc(-c4nc(-c5ccccc5)nc(-c5ccccc5)n4)c3)c2)c2ccccc21 ; c1ccc(-c2nc(-c3ccccc3)nc(N3c4ccccc4-c4c(n(-c5ccccc5)c5ccccc45)-c4ccccc43)n2)cc1]

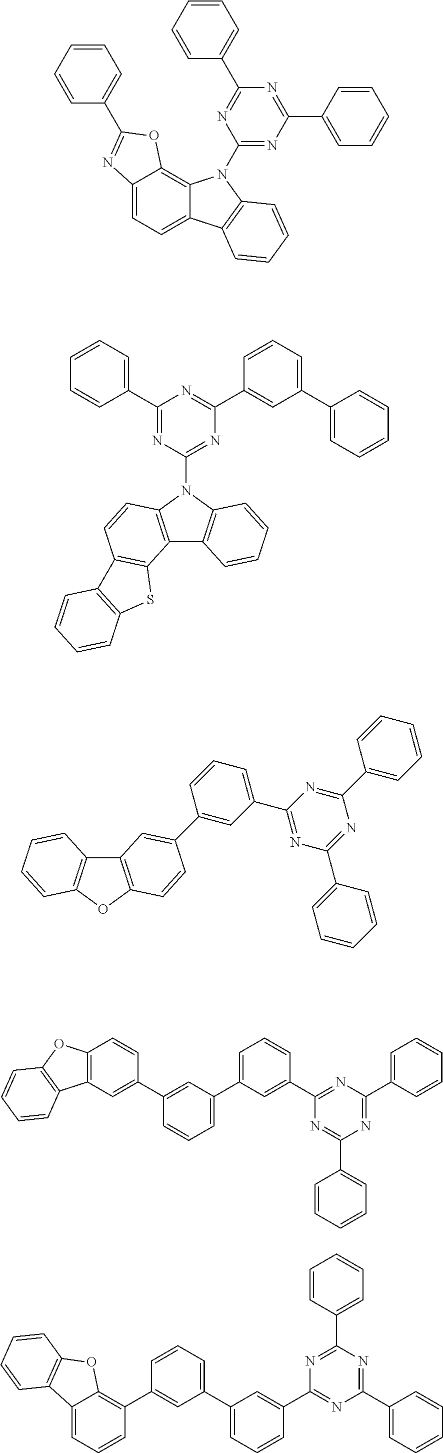

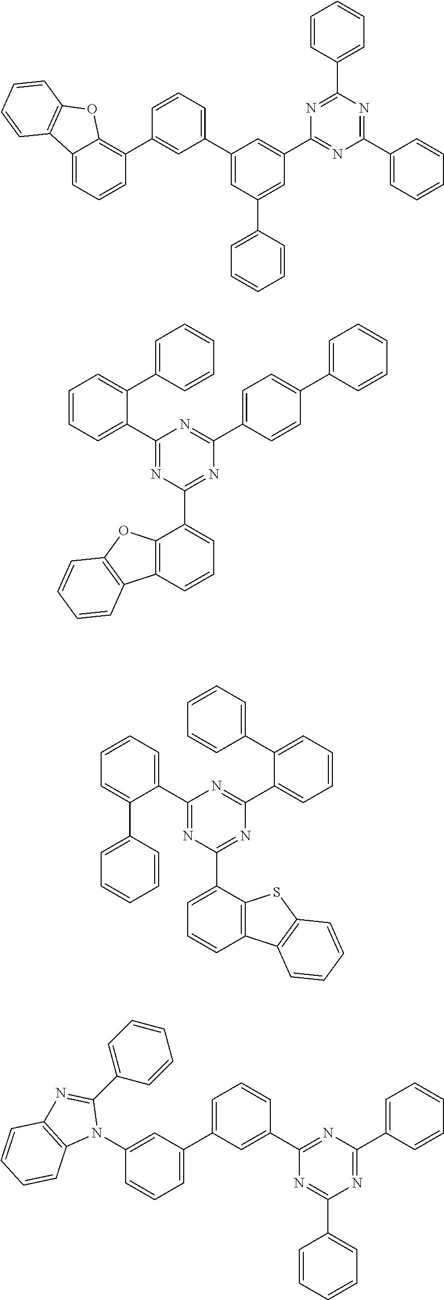 [SMILES: c1ccc(-c2cc(-c3cccc(-c4cccc5c4oc4ccccc45)c3)cc(-c3nc(-c4ccccc4)nc(-c4ccccc4)n3)c2)cc1 ; c1ccc(-c2ccc(-c3nc(-c4ccccc4-c4ccccc4)nc(-c4cccc5c4oc4ccccc45)n3)cc2)cc1 ; c1ccc(-c2ccccc2-c2nc(-c3ccccc3-c3ccccc3)nc(-c3cccc4c3sc3ccccc34)n2)cc1 ; c1ccc(-c2nc(-c3ccccc3)nc(-c3cccc(-c4cccc(-n5c(-c6ccccc6)nc6ccccc65)c4)c3)n2)cc1]

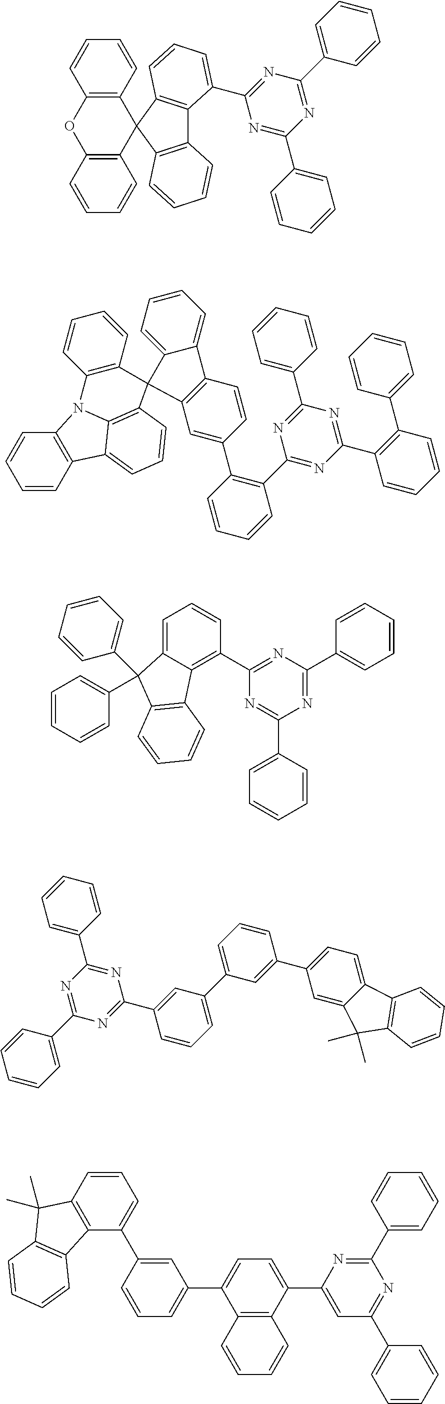 [SMILES: c1ccc(-c2nc(-c3ccccc3)nc(-c3cccc4c3-c3ccccc3C43c4ccccc4Oc4ccccc43)n2)cc1 ; c1ccc(-c2nc(-c3ccccc3-c3ccccc3)nc(-c3ccccc3-c3ccc4c(c3)C3(c5ccccc5-4)c4ccccc4-n4c5ccccc5c5cccc3c54)n2)cc1 ; c1ccc(-c2nc(-c3ccccc3)nc(-c3cccc4c3-c3ccccc3C4(c3ccccc3)c3ccccc3)n2)cc1 ; CC1(C)c2ccccc2-c2ccc(-c3cccc(-c4cccc(-c5nc(-c6ccccc6)nc(-c6ccccc6)n5)c4)c3)cc21 ; CC1(C)c2ccccc2-c2c(-c3cccc(-c4ccc(-c5cc(-c6ccccc6)nc(-c6ccccc6)n5)c5ccccc45)c3)cccc21]

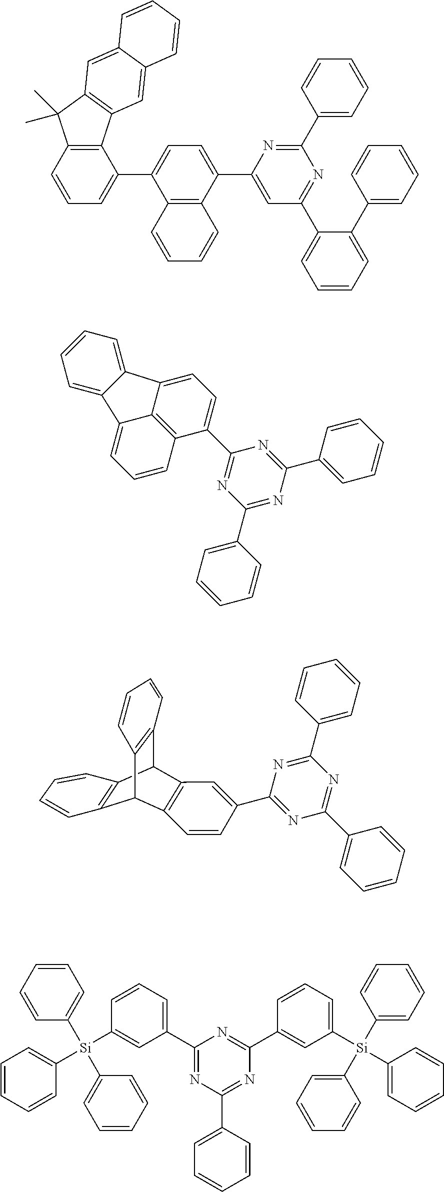 [SMILES: CC1(C)c2cc3ccccc3cc2-c2c(-c3ccc(-c4cc(-c5ccccc5-c5ccccc5)nc(-c5ccccc5)n4)c4ccccc34)cccc21 ; c1ccc(-c2nc(-c3ccccc3)nc(-c3ccc4c5c(cccc35)-c3ccccc3-4)n2)cc1 ; c1ccc(-c2nc(-c3ccccc3)nc(-c3ccc4c(c3)C3c5ccccc5C4c4ccccc43)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

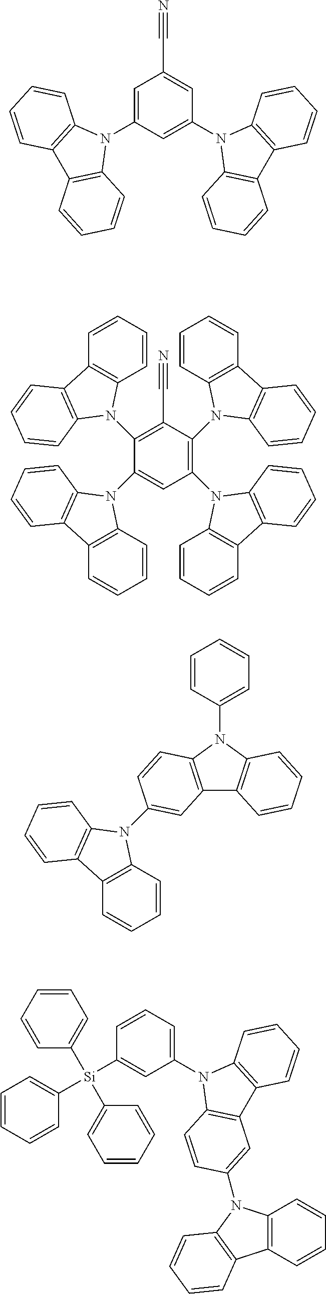

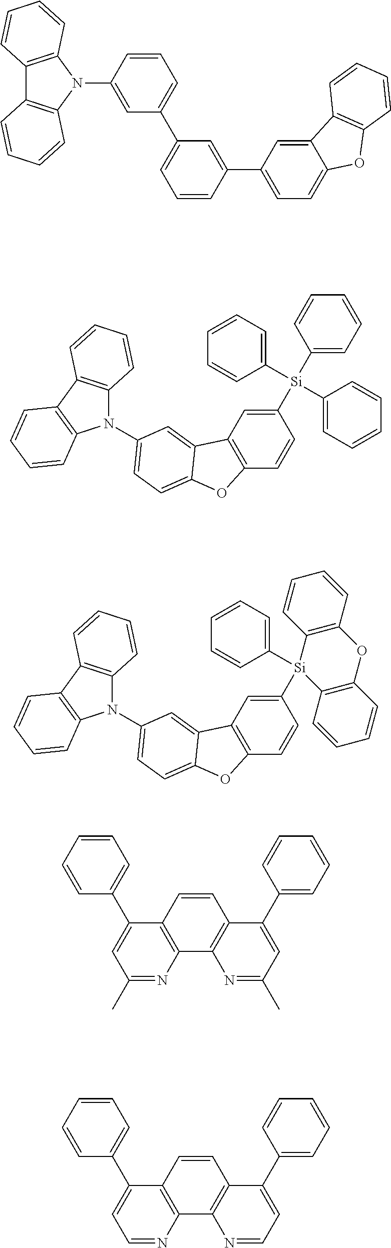 [SMILES: c1cc(-c2cccc(-n3c4ccccc4c4ccccc43)c2)cc(-c2ccc3oc4ccccc4c3c2)c1 ; c1ccc([Si](c2ccccc2)(c2ccccc2)c2ccc3oc4ccc(-n5c6ccccc6c6ccccc65)cc4c3c2)cc1 ; c1ccc([Si]2(c3ccc4oc5ccc(-n6c7ccccc7c7ccccc76)cc5c4c3)c3ccccc3Oc3ccccc32)cc1 ; Cc1cc(-c2ccccc2)c2ccc3c(-c4ccccc4)cc(C)nc3c2n1 ; c1ccc(-c2ccnc3c2ccc2c(-c4ccccc4)ccnc23)cc1]

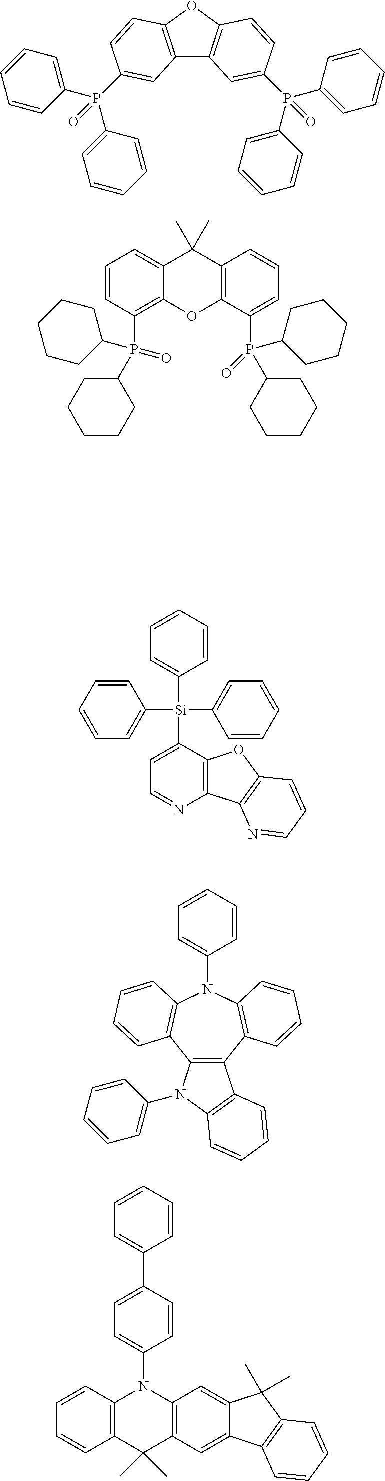 [SMILES: O=P(c1ccccc1)(c1ccccc1)c1ccc2oc3ccc(P(=O)(c4ccccc4)c4ccccc4)cc3c2c1 ; CC1(C)c2cccc(P(=O)(C3CCCCC3)C3CCCCC3)c2Oc2c1cccc2P(=O)(C1CCCCC1)C1CCCCC1 ; c1ccc([Si](c2ccccc2)(c2ccccc2)c2ccnc3c2oc2cccnc23)cc1 ; c1ccc(N2c3ccccc3-c3c(n(-c4ccccc4)c4ccccc34)-c3ccccc32)cc1 ; CC1(C)c2ccccc2-c2cc3c(cc21)N(c1ccc(-c2ccccc2)cc1)c1ccccc1C3(C)C]

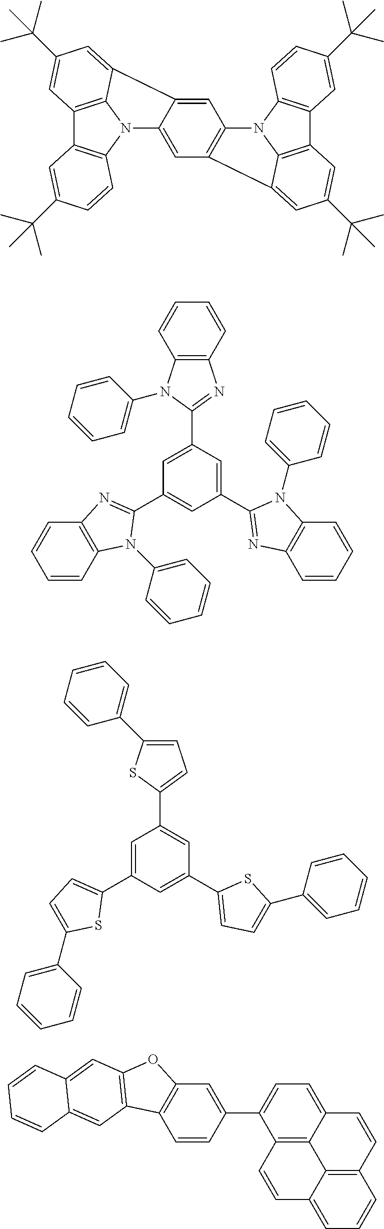

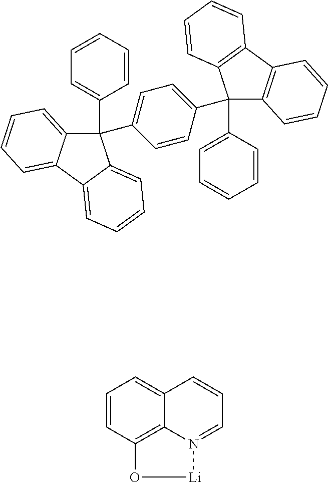

### Metal and Metal Compound

In an exemplary arrangement of the organic EL device according to the first exemplary embodiment, a metal contained in a low refractive index layer together with an organic material having a refractive index of 1.87 or less is at least one metal selected from the group consisting of rare earth metal, alkali metal and alkaline earth metal.

In an exemplary arrangement of the organic EL device according to the first exemplary embodiment, the metal contained in the low refractive index layer together with the organic material having a refractive index of 1.87 or less is at least one metal selected from the group consisting of ytterbium, erbium, lithium, cesium, magnesium, and calcium.

In an exemplary arrangement of the organic EL device according to the first exemplary embodiment, a metal compound contained in the low refractive index layer together with an organic material having a refractive index of 1.87 or less is at least one metal compound selected from the group consisting of a compound of alkali metal and a compound of alkaline earth metal.

In an exemplary arrangement of the organic EL device according to the first exemplary embodiment, the metal compound contained in the low refractive index layer together with the organic material having a refractive index of 1.87 or less is at least one metal compound selected from the group consisting of 8-(quinolinolato)lithium (abbreviation: Liq), lithium fluoride (LiF), cesium fluoride (CsF), calcium fluoride (CaF₂), 2-(2-pyridyl)phenolatlithium (abbreviation: LiPP), 2-(2-pyridyl)-3-pyridinolatolithium (abbreviation: LiPPy), 4-phenyl-2-(2-pyridyl)phenolatlithium (abbreviation: LiPPP), lithium oxide (LiOx), and cesium carbonate. Examples of the metal compound also include a metal complex (metal complex having a refractive index of 1.87 or less) usable as a low refractive index organic material such as Liq. The electron transporting zone materials (the first electron transporting zone material and the second electron transporting zone material) may be a metal complex as a low refractive index organic material.

### Hole Blocking Layer

Preferably, the hole blocking layer permits transport of electrons and blocks holes from reaching a layer provided closer to the cathode (e.g., the electron transporting layer) beyond the hole blocking layer. Examples of the compound contained in the hole blocking layer include a well-known compound used for the hole blocking layer. The compound contained in the hole blocking layer is preferably, for instance, the above-described electron transporting zone material or a later-described electron transporting zone material. The compound contained in the hole blocking layer, which is similar to a compound usable for the later-described electron transporting layer, is also preferably at least one compound selected from the group consisting of a metal complex, a heteroaromatic compound, and a high polymer compound. The compound contained in the hole blocking layer may be, for instance, at least one compound selected from the group consisting of an imidazole derivative, benzimidazole derivative, azine derivative, carbazole derivative, and phenanthroline derivative.

In order to prevent excitation energy from leaking out from the emitting layer toward neighboring layer(s), the hole blocking layer also preferably blocks excitons generated in the emitting layer from being transferred to a layer(s) provided closer to the cathode (e.g. the electron transporting layer and the electron injecting layer) beyond the hole blocking layer.

### Electron Transporting Layer

The electron transporting layer is a layer containing a substance exhibiting a high electron transportability. The above-described electron transporting zone material is usable for the electron transporting layer. For the electron transporting layer, 1) a metal complex such as an aluminum complex, beryllium complex, and zinc complex, 2) a heteroaromatic compound such as an imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinolato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. The above-described substances mostly have an electron mobility of 10⁻⁶ cm²Vs or more. It should be noted that any other substance than the above substances may be used for the electron transporting layer as long as the substance exhibits a higher electron transportability than the hole transportability. The electron transporting layer may be a single layer or a laminate of two or more layers formed of the above substance(s).

In an exemplary arrangement of the organic EL device according to the exemplary embodiment, the electron transporting layer preferably contains an azine derivative as the electron transporting zone material, and the azine derivative is preferably a diazine derivative or triazine derivative, more preferably a pyrimidine derivative or 1,3,5-triazine derivative.

Further, a high polymer compound is usable for the electron transporting layer. For instance, poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy) are usable.

### Specific Examples of Other Electron Transporting Zone Material

In addition to the above electron transporting zone material, specific examples of other electron transporting zone material include the following compounds. However, the invention is not limited to these specific examples of the electron transporting zone material.

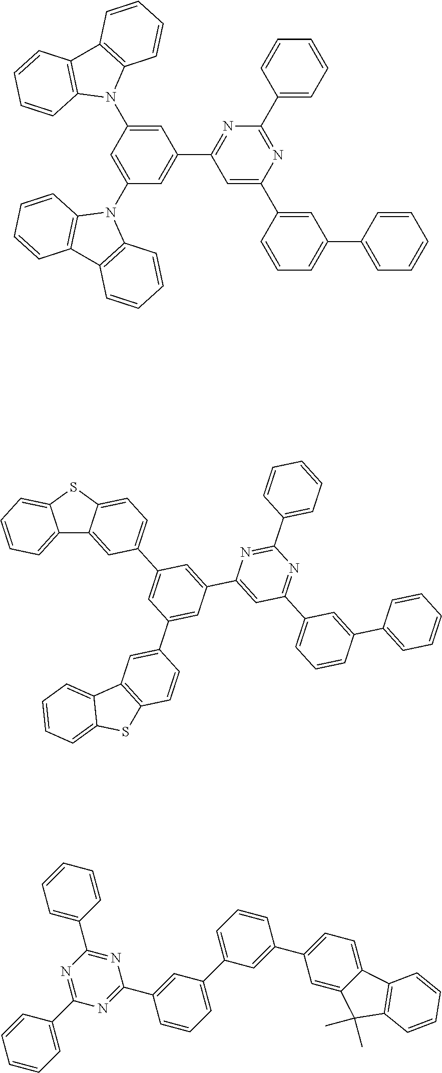 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cccc(-c3cc(-c4cc(-c5ccc6sc7ccccc7c6c5)cc(-c5ccc6sc7ccccc7c6c5)c4)nc(-c4ccccc4)n3)c2)cc1 ; CC1(C)c2ccccc2-c2ccc(-c3cccc(-c4cccc(-c5nc(-c6ccccc6)nc(-c6ccccc6)n5)c4)c3)cc21]

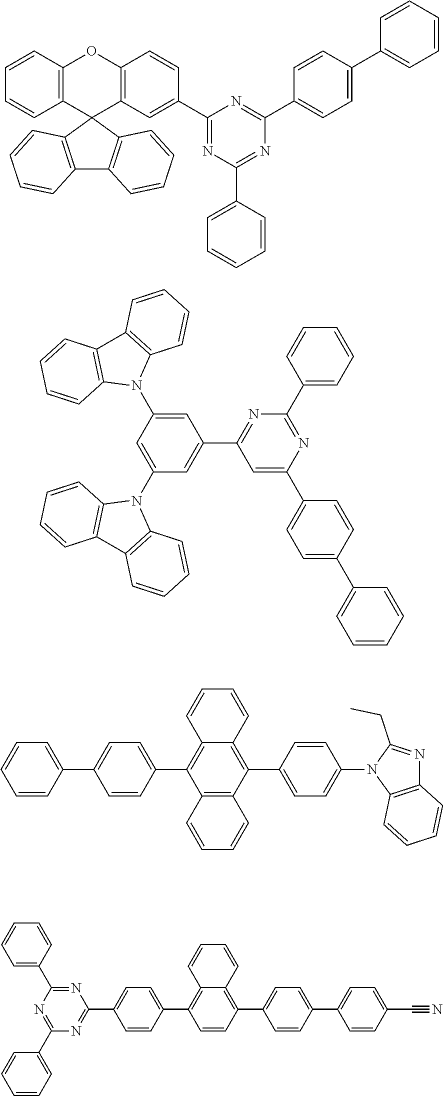 [SMILES: c1ccc(-c2ccc(-c3nc(-c4ccccc4)nc(-c4ccc5c(c4)C4(c6ccccc6O5)c5ccccc5-c5ccccc54)n3)cc2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; CCc1nc2ccccc2n1-c1ccc(-c2c3ccccc3c(-c3ccc(-c4ccccc4)cc3)c3ccccc23)cc1 ; N#Cc1ccc(-c2ccc(-c3ccc(-c4ccc(-c5nc(-c6ccccc6)nc(-c6ccccc6)n5)cc4)c4ccccc34)cc2)cc1]

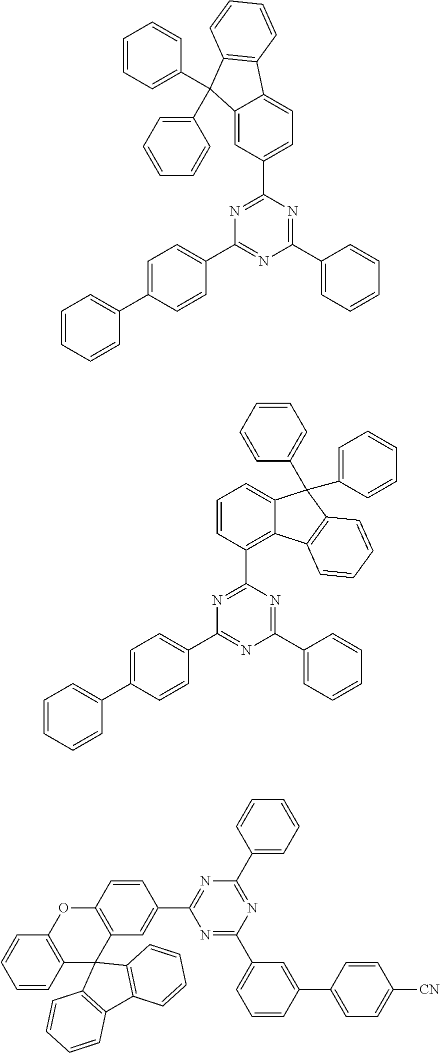 [SMILES: c1ccc(-c2ccc(-c3nc(-c4ccccc4)nc(-c4ccc5c(c4)C(c4ccccc4)(c4ccccc4)c4ccccc4-5)n3)cc2)cc1 ; c1ccc(-c2ccc(-c3nc(-c4ccccc4)nc(-c4cccc5c4-c4ccccc4C5(c4ccccc4)c4ccccc4)n3)cc2)cc1 ; N#Cc1ccc(-c2cccc(-c3nc(-c4ccccc4)nc(-c4ccc5c(c4)C4(c6ccccc6O5)c5ccccc5-c5ccccc54)n3)c2)cc1]

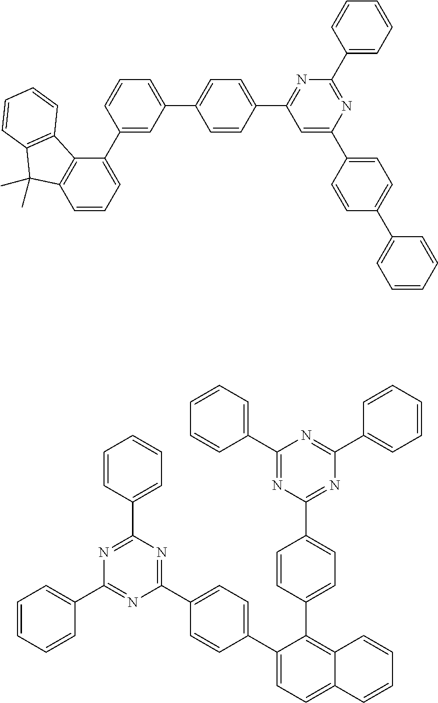 [SMILES: CC1(C)c2ccccc2-c2c(-c3cccc(-c4ccc(-c5cc(-c6ccc(-c7ccccc7)cc6)nc(-c6ccccc6)n5)cc4)c3)cccc21 ; c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1]

### Electron Injecting Layer

The electron injecting layer is a layer that contains a substance exhibiting a high electron injectability. Examples of a material usable for the electron injecting layer include an alkali metal, alkaline earth metal, rare earth metal, or a compound thereof, examples of which include lithium (Li), cesium (Cs), calcium (Ca), ytterbium (Yb), erbium (Er), 8-(quinolinolato)lithium (Liq), lithium fluoride (LiF), cesium fluoride (CsF), calcium fluoride (CaF₂), and lithium oxide (LiOx). In addition, the alkali metal, alkaline earth metal, rare earth metal, or the compound thereof may be added to the substance exhibiting electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of an organic compound and an electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the heteroaromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Further, a Lewis base such as magnesium oxide is usable. Furthermore, the organic compound such as tetrathiafulvalene (abbreviation: TTF) is usable.

### Hole Transporting Zone

In an exemplary arrangement of the organic EL device according to the first exemplary embodiment, the two or more emitting units each independently include a hole transporting zone. In an exemplary arrangement of the organic EL device according to the first exemplary embodiment, the first emitting unit includes a first hole transporting zone and the second emitting unit includes a second hole transporting zone.

### First Hole Transporting Zone

In an exemplary arrangement of the organic EL device according to the first exemplary embodiment, the first hole transporting zone is disposed between the anode and the first emitting zone.

In an exemplary arrangement of the organic EL device according to the first exemplary embodiment, the first hole transporting zone includes one or more layers.

In an exemplary arrangement of the organic EL device according to the first exemplary embodiment, the first hole transporting zone includes two or more layers. In an exemplary arrangement of the organic EL device according to the first exemplary embodiment, the first hole transporting zone includes a first hole injecting layer and a first hole transporting layer. In an exemplary arrangement of the organic EL device according to the first exemplary embodiment, the first hole transporting zone includes the first hole injecting layer and the first hole transporting layer in the order from a side close to the anode. In an exemplary arrangement of the organic EL device according to the first exemplary embodiment, the first hole transporting layer is in direct contact with the first emitting layer in the first emitting zone.

In an exemplary arrangement of the organic EL device according to the first exemplary embodiment, the first hole transporting zone includes three or more layers. In an exemplary arrangement of the organic EL device according to the first exemplary embodiment, the first hole transporting zone includes three layers, which are the first hole injecting layer, the first hole transporting layer, and a first electron blocking layer. In an exemplary arrangement of the organic EL device according to the first exemplary embodiment, the first hole transporting zone includes the first hole injecting layer, the first hole transporting layer, and the first electron blocking layer in the order from a side close to an emitting region.

In an exemplary arrangement of the organic EL device according to the first exemplary embodiment, the first electron blocking layer is in direct contact with the first emitting layer in the first emitting zone. In an exemplary arrangement of the organic EL device according to the first exemplary embodiment, the first electron blocking layer is in direct contact with the first hole transporting layer. In an exemplary arrangement of the organic EL device according to the first exemplary embodiment, the first hole transporting layer is in direct contact with the first hole injecting layer. In an exemplary arrangement of the organic EL device according to the first exemplary embodiment, the first hole injecting layer is in direct contact with the anode.

In an exemplary arrangement of the organic EL device according to the first exemplary embodiment, the first hole transporting zone contains a first hole transporting zone material.

### Second Hole Transporting Zone

In an exemplary arrangement of the organic EL device according to the first exemplary embodiment, the second hole transporting zone is disposed between the first emitting unit and the second emitting zone.

In an exemplary arrangement of the organic EL device according to the first exemplary embodiment, the second hole transporting zone is disposed between the first charge generating zone and the second emitting zone.

In an exemplary arrangement of the organic EL device according to the first exemplary embodiment, the second hole transporting zone is disposed between the first charge generating layer and the second emitting zone.

In an exemplary arrangement of the organic EL device according to the first exemplary embodiment, the second hole transporting zone is disposed between the second charge generating layer and the second emitting zone.

In an exemplary arrangement of the organic EL device according to the first exemplary embodiment, the second hole transporting zone includes one or more layers.

In an exemplary arrangement of the organic EL device according to the first exemplary embodiment, the second hole transporting zone includes the second hole transporting layer. In an exemplary arrangement of the organic EL device according to the first exemplary embodiment, the second hole transporting layer is in direct contact with the second emitting layer in the second emitting zone.

In an exemplary arrangement of the organic EL device according to the first exemplary embodiment, the second hole transporting zone includes two or more layers. In an exemplary arrangement of the organic EL device according to the first exemplary embodiment, the second hole transporting zone includes the second hole transporting layer and a second electron blocking layer. In an exemplary arrangement of the organic EL device according to the first exemplary embodiment, the second hole transporting zone includes the second hole transporting layer and the second electron blocking layer in the order from a side close to the first emitting unit. In an exemplary arrangement of the organic EL device according to the first exemplary embodiment, the second hole transporting layer is in direct contact with the second electron blocking layer. In an exemplary arrangement of the organic EL device according to the first exemplary embodiment, the second electron blocking layer is in direct contact with the second emitting layer in the second emitting zone. In an exemplary arrangement of the organic EL device according to the first exemplary embodiment, the second electron blocking layer may be a layer (low refractive index layer) containing an organic material (low refractive index organic material) with a refractive index less than 1.87, or may be a layer (high refractive index layer) containing an organic material (high refractive index organic material) with a refractive index more than 1.87.

In an exemplary arrangement of the organic EL device according to the first exemplary embodiment, the second hole transporting layer is disposed between the second charge generating layer and the second emitting zone.

In an exemplary arrangement of the organic EL device according to the first exemplary embodiment, the second charge generating layer is in direct contact with the second hole transporting layer. In an exemplary arrangement of the organic EL device according to the first exemplary embodiment, the second charge generating layer needs not be in direct contact with the second hole transporting layer.

In an exemplary arrangement of the organic EL device according to the first exemplary embodiment, the second hole transporting layer is the low refractive index layer. When the second hole transporting layer is the low refractive index layer, the second hole transporting layer contains an organic material having a refractive index of 1.87 or less.

In an exemplary arrangement of the organic EL device according to the first exemplary embodiment, the second hole transporting layer contains the second hole transporting zone material.

In an exemplary arrangement of the organic EL device according to the first exemplary embodiment, the organic material having a refractive index of 1.87 or less contained in the second hole transporting layer is the second hole transporting zone material.

In an exemplary arrangement of the organic EL device according to the first exemplary embodiment, the second hole transporting zone material has a refractive index of 1.83 or less.

In an exemplary arrangement of the organic EL device according to the first exemplary embodiment, the refractive index of the first charge generating zone material is 1.83 or less, the refractive index of the second charge generating zone material is 1.83 or less, and the refractive index of the second hole transporting zone material is 1.83 or less.

In an exemplary arrangement of the organic EL device according to the first exemplary embodiment, the refractive index of the first charge generating zone material is more than 1.70, the refractive index of the second charge generating zone material is 1.70 or less, and the refractive index of the second hole transporting zone material is 1.70 or less.

In an exemplary arrangement of the organic EL device according to the first exemplary embodiment, the refractive index of the first electron transporting zone material is 1.83 or less, the refractive index of the first charge generating zone material is 1.83 or less, the refractive index of the second charge generating zone material is 1.83 or less, and the refractive index of the second hole transporting zone material is 1.83 or less.

In an exemplary arrangement of the organic EL device according to the first exemplary embodiment, the refractive index of the first electron transporting zone material is 1.70 or less, the refractive index of the first charge generating zone material is more than 1.70, the refractive index of the second change generating zone material is 1.70 or less, and the refractive index of the second hole transporting zone material is 1.70 or less.

In an exemplary arrangement of the organic EL device according to the first exemplary embodiment, the second hole transporting zone material and the second charge generating zone material are mutually the same or different.

In an exemplary arrangement of the organic EL device according to the first exemplary embodiment, the second hole transporting zone material and the first charge generating zone material are different from each other.

In an exemplary arrangement of the organic EL device according to the first exemplary embodiment, the second hole transporting zone material and the first electron transporting zone material are different from each other.

In an exemplary arrangement of the organic EL device according to the first exemplary embodiment, when the organic EL device satisfies Condition (TDM1), one of the at least two low refractive index layers in direct contact in Condition (TDM1) is the second hole transporting layer.

In an exemplary arrangement of the organic EL device according to the first exemplary embodiment, the second charge generating layer is the first low refractive index layer described above and the second hole transporting layer is the second low refractive index layer described above.

In an exemplary arrangement of the organic EL device according to the first exemplary embodiment, a total film thickness of the second charge generating layer and the second hole transporting layer is 50 nm or more.

In an exemplary arrangement of the organic EL device according to the first exemplary embodiment, the first charge generating layer is the third low refractive index layer described above, the second charge generating layer is the first low refractive index layer described above, and the second hole transporting layer is the second low refractive index layer described above.

In an exemplary arrangement of the organic EL device according to the first exemplary embodiment, a total film thickness of the first charge generating layer, the second charge generating layer, and the second hole transporting layer is 50 nm or more, or 55 nm or more.

In an exemplary arrangement of the organic EL device according to the first exemplary embodiment, the first electron transporting layer is the third low refractive index layer described above, the first charge generating layer is the first low refractive index layer described above, the second charge generating layer is the second low refractive index layer described above, and the second hole transporting layer is the fourth low refractive index layer described above.

In an exemplary arrangement of the organic EL device according to the first exemplary embodiment, a total film thickness of the first electron transporting layer, the first charge generating layer, the second charge generating layer, and the second hole transporting layer is 50 nm or more, 60 nm or more, or 70 nm or more.

In an exemplary arrangement of the organic EL device according to the first exemplary embodiment, a total film thickness of the first electron transporting layer, the first charge generating layer, the second charge generating layer, and the second hole transporting layer is 100 nm or less, or 90 nm or less.

In an exemplary arrangement of the organic EL device according to the first exemplary embodiment, the first hole blocking layer is the fifth low refractive index layer described above, the first electron transporting layer is the third low refractive index layer described above, the first charge generating layer is the first low refractive index layer described above, the second charge generating layer is the second low refractive index layer described above, and the second hole transporting layer is the fourth low refractive index layer described above.

In an exemplary arrangement of the organic EL device according to the first exemplary embodiment, a total film thickness of the first hole blocking layer, the first electron transporting layer, the first charge generating layer, the second charge generating layer, the second hole transporting layer is 50 nm or more, 60 nm or more, or 70 nm or more.

In an exemplary arrangement of the organic EL device according to the first exemplary embodiment, a total film thickness of the first hole blocking layer, the first electron transporting layer, the first charge generating layer, the second charge generating layer, and the second hole transporting layer is 100 nm or less, or 90 nm or less.

### Hole Transporting Zone Material

In the organic EL device according to the first exemplary embodiment, a material contained in the hole transporting zone is referred to as a hole transporting zone material. The hole transporting zone material is, for instance, the first hole transporting zone material and the second hole transporting zone material described above. The hole transporting zone material is also usable as the second charge generating zone material.

In an exemplary arrangement of the organic EL device according to the first exemplary embodiment, at least one layer of layers included in the first hole transporting zone contains a compound represented by a formula (B1) or (B2) below, as the first hole transporting zone material.

In an exemplary arrangement of the organic EL device according to the first exemplary embodiment, at least one layer of layers included in the second hole transporting zone contains the compound represented by the formula (B1) or (B2) below, as the second hole transporting zone material.

In an exemplary arrangement of the organic EL device according to the first exemplary embodiment, the second charge generating layer contains the compound represented by the formula (B1) or (B2) below. In an exemplary arrangement of the organic EL device according to the first exemplary embodiment, the second charge generating layer contains the compound represented by the formula (B1) or (B2) below, as the second charge generating zone material.

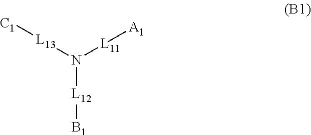

In the formula (B1):
L₁₁, L₁₂, and L₁₃ are each independently a single bond, a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms:
A₁, B₁, and C₁ are each independently a substituted or unsubstituted aryl group having 6 to 50 ring carbon atoms, a substituted or unsubstituted heterocyclic group having 5 to 50 ring atoms, or a group represented by —Si(R₁₂₁)(R₁₂₂)(R₁₂₃);
R₁₂₁, R₁₂₂, and R₁₂₃ are each independently a substituted or unsubstituted aryl group having 6 to 50 ring carbon atoms;
when a plurality of R₁₂₁ are present, the plurality of R₁₂₁ are mutually the same or different;
when a plurality of R₁₂₂ are present, the plurality of R₁₂₂ are mutually the same or different; and
when a plurality of R₁₂₃ are present, the plurality of R₁₂₃ are mutually the same or different.

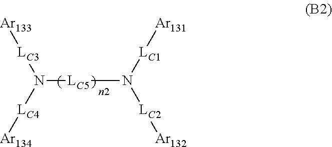

In the formula (B₂):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3 or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3 or 4, a plurality of Lcs are mutually the same or different;
when n2 is 2, 3 or 4, a plurality of Los are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or a group represented by —Si(R₁₂₁)(R₁₂₂)(R₁₂₃);
R₁₂₁, R₁₂₂, and R₁₂₃ are each independently a substituted or unsubstituted aryl group having 6 to 50 ring carbon atoms;
when a plurality of R₁₂₁ are present, the plurality of R₁₂₁ are mutually the same or different;
when a plurality of R₁₂₂ are present, the plurality of R₁₂₂ are mutually the same or different; and
when a plurality of R₁₂₃ are present, the plurality of R₁₂₃ are mutually the same or different.

In an exemplary arrangement of the organic EL device of the exemplary embodiment, a first amino group represented by a formula (B2-1) below and a second amino group represented by a formula (B2-2) below in the compound represented by the formula (B2) are an identical group.

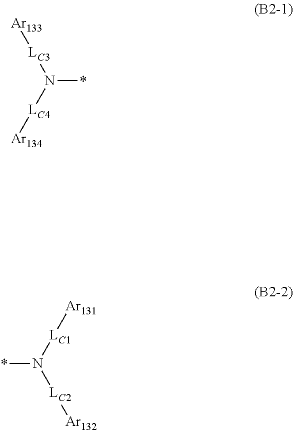

In the formulae (B2-1) and (B2-2), each * represents a bonding position to L_{C5}.

In an exemplary arrangement of the organic EL device of the exemplary embodiment, the first amino group represented by the formula (B2-1) and the second amino group represented by the formula (B2-2) may be mutually different.

In an exemplary arrangement of the organic EL device according to the first exemplary embodiment, A₁, B₁ and C₁ in the formula (B1) and a formula (B100) below are each independently a group represented by one formula selected from the group consisting of formulae (1A), (1B), (1C), (1D), (1E), (1F) and (1G) below.

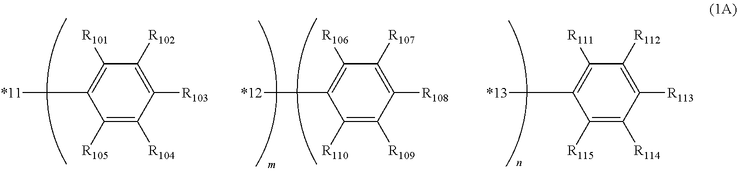

In the formula (1A):
*11 is a bonding position to L₁₁, L₁₂ or L₁₃;
one selected from R₁₀₁ to R₁₀₅ is a single bond bonded to *12, and one selected from R₁₀₆ to R₁₁₀ is a single bond bonded to *13;
R₁₀₁ to R₁₀₅ and R₁₀₆ to R₁₁₀ not being the single bond are each independently a hydrogen atom, an unsubstituted alkyl group having 1 to 10 carbon atoms, or an unsubstituted aryl group having 6 to 12 ring carbon atoms;
any combinations of adjacent two or more of R₁₀₁ to R₁₀₅ not being the single bond are not mutually bonded;
any combinations of adjacent two or more of R₁₀₆ to R₁₁₀ not being the single bond are not mutually bonded:
R₁₁₁ to R₁₁₅ are each independently a hydrogen atom, a substituted or unsubstituted alkyl group having 1 to 10 carbon atoms, a substituted or unsubstituted aryl group having 6 to 12 ring carbon atoms, or a substituted or unsubstituted heterocyclic group having 5 to 13 ring atoms;
any combinations of adjacent two or more of R₁₁₁ to R₁₁₅ are not mutually bonded;
m is 0, 1 or 2, and n is 0 or 1;
when m=0 and n=0 are satisfied, *13 is a bonding position to L₁₁, L₁₂ or L₁₃;
when m=0 and n=1 are satisfied, *12 is a bonding position to L₁₁, L₁₂ or L₁₃; and
when m=1 and n=0 are satisfied, one selected from R₁₀₁ to R₁₀₅ is a single bond bonded to *13.

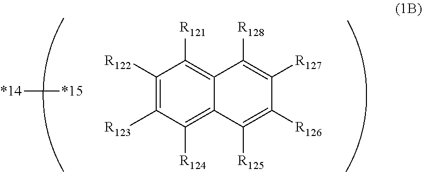

In the formula (1 B):
*14 is a bonding position to L₁₁, L₁₂ or L₁₃;
one selected from R₁₂₁ to R₅₁₂₈ is a single bond bonded to *15;
R₁₂₁ to R₅₁₂₈ not being the single bond are each independently a hydrogen atom, a substituted or unsubstituted alkyl group having 1 to 10 carbon atoms, or a substituted or unsubstituted aryl group having 6 to 12 ring carbon atoms; and
any combinations of adjacent two or more of R₁₂₁ to R₁₂₈ not being the single bond are not mutually bonded.

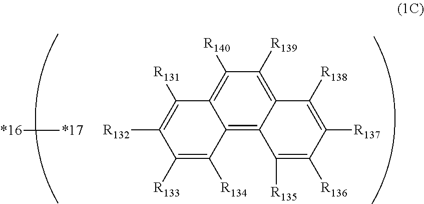

In the formula (1C):
*16 is a bonding position to L₁₁, L₁₂ or L₁₃;
one selected from R₁₃₁ to R₁₄₀ is a single bond bonded to *17;
R₁₃₁ to R₁₄₀ not being the single bond are each independently a hydrogen atom, a substituted or unsubstituted alkyl group having 1 to 10 carbon atoms, or a substituted or unsubstituted aryl group having 6 to 12 ring carbon atoms; and
any combinations of adjacent two or more of R₁₃₁ to R₁₄₀ not being the single bond are not mutually bonded.

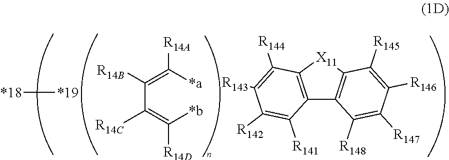

In the formula (1 D):
*18 is a bonding position to L₁₁, L₁₂ or L₁₃;
X₁₁ is an oxygen atom, a sulfur atom, C(Ra)(Rb), or N(Rc);
a combination of Ra and Rb are mutually bonded to form a substituted or unsubstituted monocyclic ring, mutually bonded to form a substituted or unsubstituted fused ring, or not mutually bonded;
n is 0 or 1;
when n is 0, one selected from R₁₄₁ to R₁₄₈ and Rc, and Ra and Rb forming neither the substituted or unsubstituted monocyclic ring nor the substituted or unsubstituted fused ring is a single bond bonded to *19;
when n is 1, one of R₁₄₁ and R₁₄₂ is a single bond bonded to *a, and the other of R₁₄₁ and R₁₄₂ is a single bond bonded to *b; one of R₁₄₂ and R₁₄₃ is a single bond bonded to *a, and the other of R₁₄₂ and R₁₄₃ is a single bond bonded to *b; or one of R₁₄₃ and R₁₄₄ is a single bond bonded to *a, and the other of R₁₄₃ and R₁₄₄ is a single bond bonded to *b;
one selected from the group consisting of (i) R₁₄₅ to R₁₄₈, R_{14A}, R_{14B}, R_{14C}, R_{14D}, and Rc, (ii) R₁₄₁ to R₁₄₄ not being the single bond bonded to a* or b*, and (iii) Ra and Rb not being the single bond bonded to a* or b*, not forming the substituted or unsubstituted monocyclic ring, and not forming the substituted or unsubstituted fused ring is a single bond bonded to *19; and
R₁₄₁ to R₁₄₈, R_{14A}, R_{14B}, R_{14C}, R_{14D} and Rc not being the single bond bonded to *19, and Ra and Rb not being the single bond bonded to *19, not forming the substituted or unsubstituted monocyclic ring, and not forming the substituted or unsubstituted fused ring are each independently a hydrogen atom, a substituted or unsubstituted alkyl group having 1 to 10 carbon atoms, a substituted or unsubstituted aryl group having 6 to 12 ring carbon atoms, or a substituted or unsubstituted heteroaryl group having 5 to 13 ring atoms.

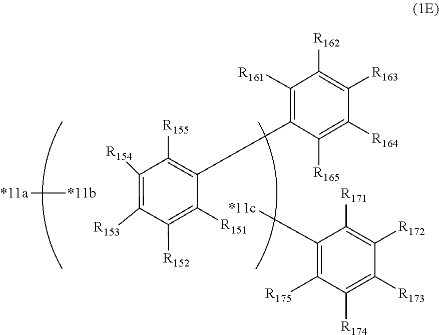

In the formula (1E):
*11a is a bonding position to L₁₁, L₁₂ or L₁₃;
one selected from R₁₅₁ to R₁₅₅ is a single bond bonded to *11b, and one selected from R₁₅₁ to R₁₅₅ is a single bond bonded to *11c;
R₁₅₁ to R₁₅₅ not being the single bond are each independently a hydrogen atom, an unsubstituted alkyl group having 1 to 10 carbon atoms, or an unsubstituted phenyl group;
any combinations of adjacent two or more of R₁₅₁ to R₁₅₅ not being the single bond are not mutually bonded; and
R₁₆₁ to R₁₆₅ and R₁₇₁ to R₁₇₅ are each independently a hydrogen atom or an unsubstituted alkyl group having 1 to 10 carbon atoms.

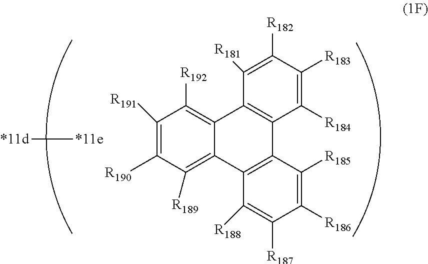

In the formula (1F):
*11 d is a bonding position to L₁₁, L₁₂ or L₁₃;
one selected from R₁₈₁ to R₁₉₂ is a single bond bonded to *11e;
R₁₈₁ to R₁₉₂ not being the single bond are each independently a hydrogen atom, a substituted or unsubstituted alkyl group having 1 to 10 carbon atoms, or a substituted or unsubstituted aryl group having 6 to 12 ring carbon atoms; and
any combinations of adjacent two or more of R₁₈₁ to R₁₉₂ not being the single bond are not mutually bonded.

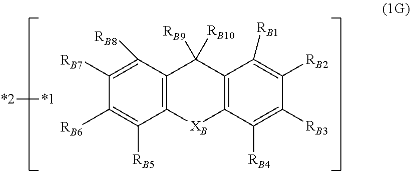

In the formula (1 G):
X_{B} is a single bond, an oxygen atom, a sulfur atom, N(R_{B11}) or C(R_{B12})(R_{B13});
when a plurality of X_{B} are present, the plurality of X_{B} are mutually the same or different;
when X_{B} is C(R_{B12})(R_{B13}), a combination of R_{B12} and R_{B13} are mutually bonded to form a substituted or unsubstituted monocyclic ring, mutually bonded to form a substituted or unsubstituted fused ring, or not mutually bonded;
one of R_{B1}, R_{B2}, R_{B3}, R_{B4}, R_{B5}, R_{B6}, R_{B7}, R_{B8}, R_{B9}, R_{B10}, R_{B11}, R_{B12}, and R_{B13} is a single bond bonded to *1;
R_{B1}, R_{B2}, R_{B3}, R_{B4}, R_{B5}, R_{B6}, R_{B7}, R_{B8}, and R_{B11} not being the single bond bonded to *1 are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a combination of R_{B9} and R_{B10} are mutually bonded to form a substituted or unsubstituted monocyclic ring, mutually bonded to form a substituted or unsubstituted fused ring, or not mutually bonded;
R_{B9}, R_{B10}, R_{B12} and R_{B13} not being the single bond bonded to *1, not forming the substituted or unsubstituted monocyclic ring, and not forming the substituted or unsubstituted fused ring are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms; and
*2 is a bonding position to L₁₁, L₁₂ or L₁₃.

In the group represented by the formula (1G): R₉₀₁, R₉₀₂, R₉₀₃ and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; when a plurality of R₉₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; and when a plurality of R₉₀₄ are present, the plurality of R₉₀₄ are mutually the same or different.

In an exemplary arrangement of the organic EL device according to the first exemplary embodiment, the hole transporting zone material is a compound represented by a formula (B100) below.

In an exemplary arrangement of the organic EL device according to the first exemplary embodiment, the second hole transporting zone material is a compound represented by the formula (B100) below.

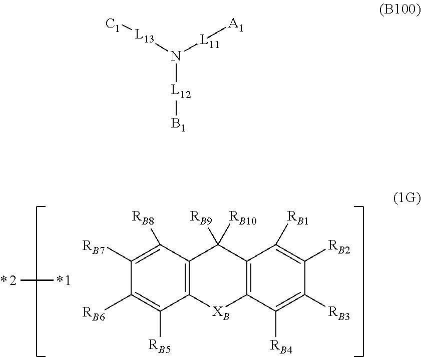

In the formula (B100):
L₁₁, L₁₂, and L₁₃ are each independently a single bond, a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
A₁, B₁, and C₁ are each independently a substituted or unsubstituted aryl group having 6 to 50 ring carbon atoms, a substituted or unsubstituted heterocyclic group having 5 to 50 ring atoms, a group represented by —Si(R_{C1})(R_{C2})(R_{C3}), or a group represented by the formula (1 G);
at least one selected from the group consisting of A₁, B₁, and C₁ is a group represented by the formula (1 G);
R_{C1}, R_{C2}, and R_{C3} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different; and
in the formula (1G):
X_{B} is a single bond, an oxygen atom, a sulfur atom, N(R_{B11}) or C(R_{B12})(R_{B13});
when a plurality of X_{B} are present, the plurality of X_{B} are mutually the same or different;
when X_{B} is C(R_{B12})(R_{B13}), a combination of R_{B12} and R_{B13} are mutually bonded to form a substituted or unsubstituted monocyclic ring, mutually bonded to form a substituted or unsubstituted fused ring, or not mutually bonded;
one of R_{B1}, R_{B2}, R_{B3}, R_{B4}, R_{B5}, R_{B6}, R_{B7}, R_{B8}, R_{B9}, R_{B1}, R_{B11}, R_{B12} and R_{B13} is a single bond bonded to *1;
R_{B1}, R_{B2}, R_{B3}, R_{B4}, R_{B5}, R_{B6}, R_{B7}, R_{B8}, and R_{B11} not being the single bond bonded to *1 are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a combination of R_{B9} and R_{B10} are mutually bonded to form a substituted or unsubstituted monocyclic ring, mutually bonded to form a substituted or unsubstituted fused ring, or not mutually bonded;
R_{B9}, R_{B10}, R_{B12} and R_{B13} not being the single bond bonded to *1, not forming the substituted or unsubstituted monocyclic ring, and not forming the substituted or unsubstituted fused ring are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms;
*2 is a bonding position to L₁₁, L₁₂ or L₁₃; and
when two or more groups represented by the formula (1G) are present, the two or more groups represented by the formula (1G) are mutually the same or different.

In the compound represented by the formula (B₁₀₀), R₉₀₁, R₉₀₂, R₉₀₃ and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different:
when a plurality of R₉₀₃ are present, the plurality of R₉₀₃ are mutually the same or different; and
when a plurality of R₉₀₄ are present, the plurality of R₉₀₄ are mutually the same or different.

In an exemplary arrangement of the organic EL device according to the first exemplary embodiment, the group represented by the formula (1G) is a group represented by one formula selected from the group consisting of formulae (11G), (12G) and (13G) below.

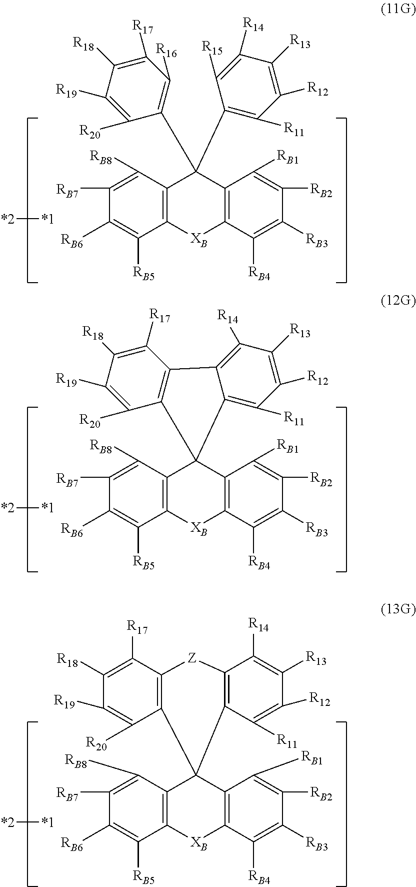

In the formula (11G), (12G) or (13G):
X_{B}, R_{B1}, R_{B2}, R_{B3}, R_{B4}, R_{B5}, R_{B6}, R_{B7}, R_{B8}, *1 and *2 respectively represent the same as X_{B}, RBI, R_{B2}, R_{B3}, R_{B4}, R_{B5}, R_{B6}, R_{B7}, R_{B8}, *1 and *2 in the formula (1G);
R₁₁, R₁₂, R₁₃, R₁₄, R₁₅, R₁₆, R₁₇, R₁₈, R₁₉ and R₂₀ are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
Z is an oxygen atom, a sulfur atom, or C(R_{Z1})(R_{Z2}); and
R_{Z1} and R_{Z2} are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In an exemplary arrangement of the organic EL device according to the first exemplary embodiment, X_{B} in the formulae (1G), (11 G), (12G), and (13G) is a single bond or an oxygen atom.

In an exemplary arrangement of the organic EL device according to the first exemplary embodiment, the group represented by the formula (1G) is a group represented by one formula selected from the group consisting of formulae (11 G-1), (12G-1), (12G-2) and (13G-1) below.

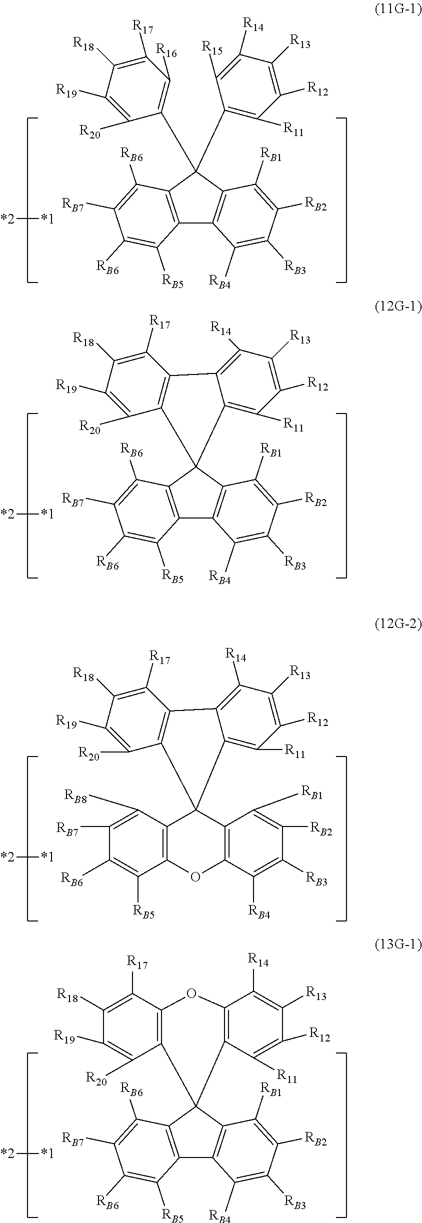

In the formula (11 G-1), (12G-1), (12G-2), or (13G-1):
R_{B1}, R_{B2}, R_{B3}, R_{B4}, R_{B5}, R_{B6}, R_{B7}, R_{B8}, *1 and *2 respectively represent the same as R_{B1}, R_{B2}, R_{B3}, R_{B4}, R_{B5}, R_{B6}, R_{B7}, R_{B8}, *1 and *2 in the formula (1G); and
R₁₁, R₁₂, R₁₃, R₁₄, R₁₅, R₁₆, R₁₇, R₁₈, R₁₉ and R₂₀ are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms.

R₁₁, R₁₃, R₁₄, R₁₅, R₁₆, R₁₇, R₁₈, and R₂₀ in the formulae (11G), (12G), (13G), (11G-1), (12G-1), (12G-2) and (13G-1) are each a hydrogen atom.

R₁₂ and R₁₉ in the formulae (11G), (12G), (13G), (11G-1), (12G-1), (12G-2) and (13G-1) are each independently a substituent other than a hydrogen atom.

R₁₁, R₁₃, R₁₄, R₁₅, R₁₆, R₁₇, R₁₈, and R₂₀ in the formulae (11G), (12G), (13G), (11G-1), (12G-1), (12G-2) and (13G-1) are each a hydrogen atom, and R₁₂ and R₁₉ are each independently a substituted or unsubstituted alkyl group having 1 to 50 carbon atoms, or a substituted or unsubstituted cycloalkyl group having 3 to 50 ring carbon atoms.

In an exemplary arrangement of the organic EL device according to the exemplary embodiment, when n is 1 in the formula (1 D);
in a case where one of R₁₄₁ and R₁₄₂ is a single bond bonded to *a, and the other of R₁₄₁ and R₁₄₂ is a single bond bonded to *b, the formula (1 D) is represented by a formula (13D) below;
in a case where one of R₁₄₂ and R₁₄₃ is a single bond bonded to *a, and the other of R₁₄₂ and R₁₄₃ is a single bond bonded to *b, the formula (1 D) is represented by a formula (12D) below; and
in a case where one of R₁₄₃ and R₁₄₄ is a single bond bonded to *a, and the other of R₁₄₃ and R₁₄₄ is a single bond bonded to *b, the formula (1 D) is represented by a formula (11D) below.

In an exemplary arrangement of the organic EL device according to the first exemplary embodiment, at least one selected from the group consisting of A₁, B₁ and C₁ in the formula (B₁) or (B₁₀₀) is a group represented by one formula selected from the group consisting of the formulae (11 D), (12D) and (13D) below.

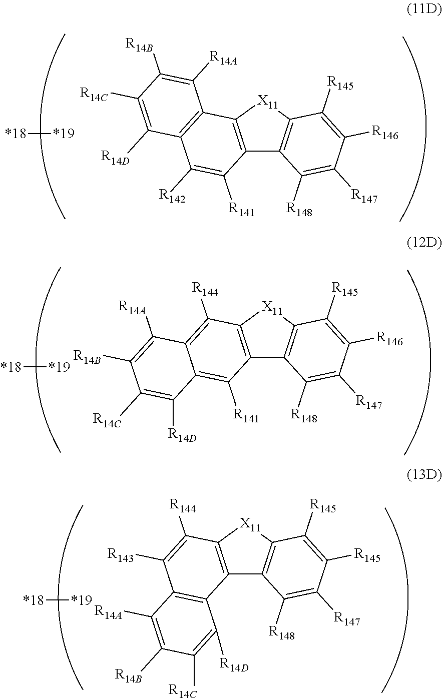

In the formulae (11D), (12D) and (13D):
*18 is a bonding position to L₁₁, L₁₂ or L₁₃;
X₁₁ represents the same as X₁₁ in the formula (1D);
one selected from the group consisting of (iv) R₁₄₁ to R₁₄₈, R_{14A}, R_{14B}, R_{14C}, R_{14D}, and Rc, and (v) Ra and Rb forming neither the substituted or unsubstituted monocyclic ring nor the substituted or unsubstituted fused ring is a single bond bonded to *19; and
R₁₄₁ to R₁₄₈, R_{14A}, R_{14B}, R_{14C}, R_{14D} and Rc not being the single bond bonded to *19, and Ra and Rb not being the single bond bonded to *19, not forming the substituted or unsubstituted monocyclic ring, and not forming the substituted or unsubstituted fused ring are each independently a hydrogen atom, a substituted or unsubstituted alkyl group having 1 to 10 carbon atoms, a substituted or unsubstituted aryl group having 6 to 12 ring carbon atoms, or a substituted or unsubstituted heteroaryl group having 5 to 13 ring atoms.

In an exemplary arrangement of the organic EL device according to the first exemplary embodiment, R₁₄₈ in the formula (11 D) is a single bond bonded to *19.

In an exemplary arrangement of the organic EL device according to the first exemplary embodiment, X₁₁ in the formula (11D) is an oxygen atom.

In an exemplary arrangement of the organic EL device according to the first exemplary embodiment, n in the formula (1 D) is 0.

In an exemplary arrangement of the organic EL device according to the first exemplary embodiment, at least one selected from the group consisting of A₁, B₁ and C₁ in the formula (B₁) or (B₁₀₀) is a group represented by one formula selected from the group consisting of formulae (14D), (15D), (16D), and (17D) below.

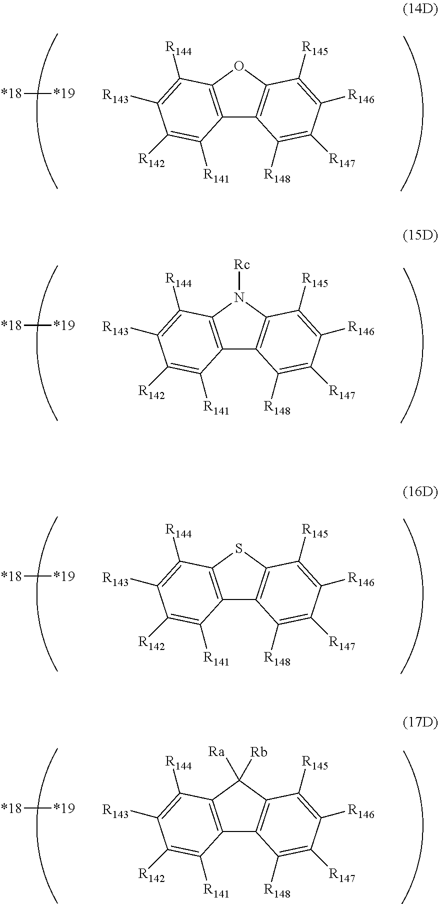

In the formulae (14D), (15D), (16D) and (17D):
*18 is a bonding position to L₁₁, L₁₂ or L₁₃;
one selected from the group consisting of (vi) R₁₄₁ to R₁₄₈ and Rc, and (vii) Ra and Rb forming neither the substituted or unsubstituted monocyclic ring nor the substituted or unsubstituted fused ring is a single bond bonded to *19; and
R₁₄₁ to R₁₄₈ and Rc not being the single bond bonded to *19, and Ra and Rb not being the single bond bonded to *19, not forming the substituted or unsubstituted monocyclic ring, and not forming the substituted or unsubstituted fused ring are each independently a hydrogen atom, a substituted or unsubstituted alkyl group having 1 to 10 carbon atoms, a substituted or unsubstituted aryl group having 6 to 12 ring carbon atoms, or a substituted or unsubstituted heteroaryl group having 5 to 13 ring atoms.

In an exemplary arrangement of the organic EL device according to the first exemplary embodiment, R₁₄₁, R₁₄₄, R₁₄₅, or R₁₄₈ in the formula (14D) is a single bond bonded to *19.

In an exemplary arrangement of the organic EL device according to the first exemplary embodiment, Rc in the formula (15D) is a single bond bonded to *19.

In an exemplary arrangement of the organic EL device according to the first exemplary embodiment, L₁₁, L₁₂ and L₁₃ in the formula (B₁) or (B₁₀₀) are each independently a single bond, or a group represented by a formula (L1), (L2), (L3), (L4), (L5), (L6), (L7), (L8), (L9), or (L10) below.

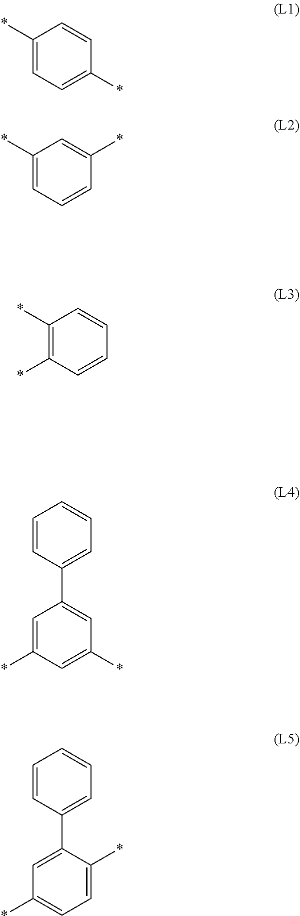 [SMILES: *c1ccc(*)cc1 ; *c1cccc(*)c1 ; *c1ccccc1* ; *c1cc(*)cc(-c2ccccc2)c1 ; *c1ccc(*)c(-c2ccccc2)c1]

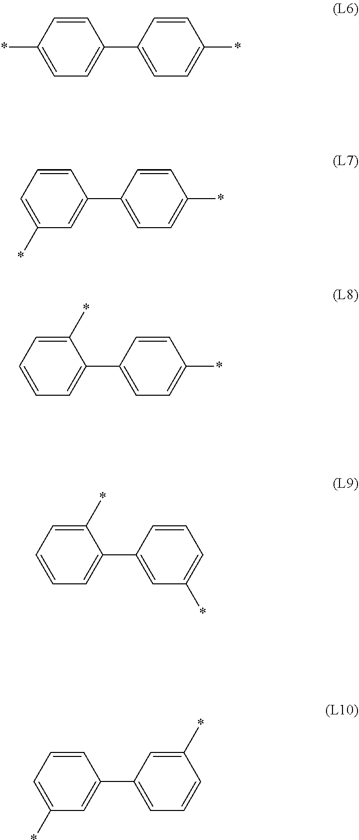 [SMILES: *c1ccc(-c2ccc(*)cc2)cc1 ; *c1ccc(-c2cccc(*)c2)cc1 ; *c1ccc(-c2ccccc2*)cc1 ; *c1cccc(-c2ccccc2*)c1 ; *c1cccc(-c2cccc(*)c2)c1]

In the formulae (L1) to (L10), * represents a bonding position. The groups represented by the formulae (L1) to (L10) each independently may or may not have at least one “optional substituent” described above. The groups represented by the formulae (L1) to (L10) each independently may have at least one deuterium atom.

In an exemplary arrangement of the organic EL device according to the first exemplary embodiment: when L₁₁ is a single bond, A₁ is directly bonded to an amino group nitrogen atom in the formula (B1) or (B100); when L₁₂ is a single bond, B₁ is directly bonded to an amino group nitrogen atom in the formula (B1) or (B100); and when L₁₃ is a single bond, C₁ is directly bonded to an amino group nitrogen atom in the formula (B1) or (B100).

In an exemplary arrangement of the organic EL device according to the first exemplary embodiment, the hole transporting zone materials (e.g., the first hole transporting zone material and the second hole transporting zone material) are each independently a compound represented by a formula (B10), (B11), (B12), (B13), (B14) or (B15) below.

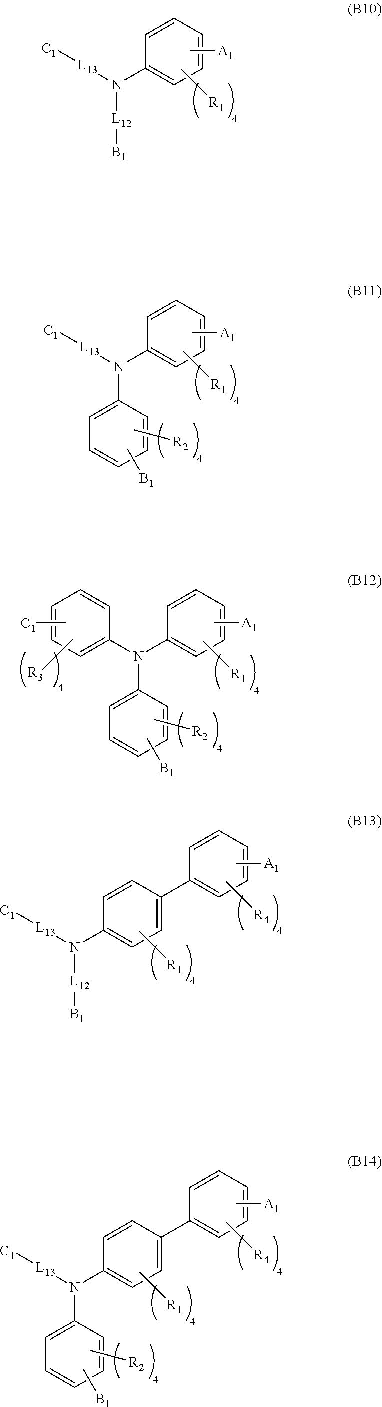

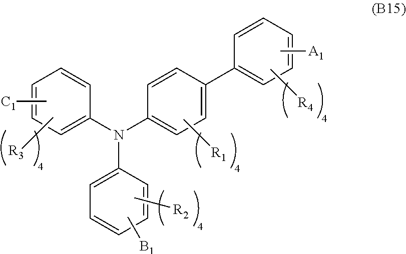

In the formulae (B10), (B11) (B12), (B13), (B14) and (B15):
L₁₁, L₁₂, L₁₃, A₁, B₁ and C₁ respectively represent the same as L₁₁, L₁₂, L₁₃, A₁, B₁ and C₁ in the formula (B₁) or (B₁₀₀);
R₁, R₂, R₃ and R₄ are each independently a hydrogen atom, a substituted or unsubstituted alkyl group having 1 to 10 carbon atoms, a substituted or unsubstituted aryl group having 6 to 13 ring carbon atoms, or a substituted or unsubstituted heteroaryl group having 5 to 13 ring atoms;
four R₁ are mutually the same or different;
four R₂ are mutually the same or different;
four R₃ are mutually the same or different; and
four R₄ are mutually the same or different.

In an exemplary arrangement of the organic EL device according to the first exemplary embodiment, the hole transporting zone materials (e.g., the first hole transporting zone material and the second hole transporting zone material) are each independently a compound represented by a formula (B16), (B17), (B18), (B19), or (B20) below.

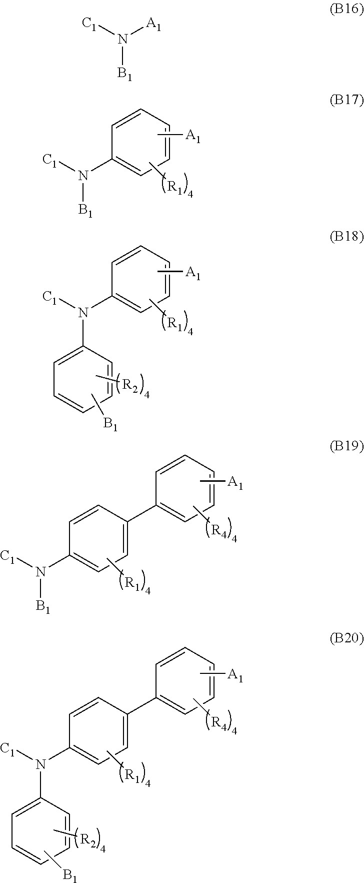

In the formulae (B16), (B17), (B18), (B19), and (B20):
A₁, B₁, and C₁ respectively represent the same as A₁, B₁, and C₁ in the formula (B1) or (B100); and
R₁, R₂, R₃ and R₄ are each independently a hydrogen atom, a substituted or unsubstituted alkyl group having 1 to 10 carbon atoms, a substituted or unsubstituted aryl group having 6 to 13 ring carbon atoms, or a substituted or unsubstituted heteroaryl group having 5 to 13 ring atoms; four R₁ are mutually the same or different; four R₂ are mutually the same or different; four R₃ are mutually the same or different; and four R₄ are mutually the same or different.

In an exemplary arrangement of the organic EL device according to the first exemplary embodiment, R₁, R₂, and R₃ in the first hole transporting zone material and the second hole transporting zone material are each a deuterium atom.

In an exemplary arrangement of the organic EL device according to the first exemplary embodiment, at least one selected from the group consisting of A₁, B₁ and C₁ in the formulae (B1), (B100), (B10), (B11), (B12), (B13), (B14), (B15), (B16), (B17), (B18), (B19) and (B2G) includes at least one group selected from the group consisting of groups represented by the formulae (1A) and (1 B). Hereinafter, the formulae “(B10), (B11), (B12), (B13), (B14), (B15), (B16), (B17), (B18), (B19) and (B20)” are sometimes simply referred to as “(B10) to (B20)”.

In an exemplary arrangement of the organic EL device according to the first exemplary embodiment, one selected from the group consisting of A₁, B₁ and C₁ in the formulae (B1) and (B10) to (B20) includes at least one group selected from the group consisting of groups represented by the formulae (1A) and (1B), and the remaining two selected from the group consisting of A₁, B₁ and C₁ include at least one group selected from the group consisting of groups represented by the formulae (1D), (11D), (12D), (13D), (14D), (15D), (16D), and (17D).

In an exemplary arrangement of the organic EL device according to the first exemplary embodiment, two selected from the group consisting of A₁, B₁ and C₁ in the formulae (B1), (B100), and (B10) to (B20) include at least one group selected from the group consisting of groups represented by the formulae (1A) and (1 B).

In an exemplary arrangement of the organic EL device according to the first exemplary embodiment, two selected from the group consisting of A₁, B₁ and C₁ in the formulae (B₁) and (B10) to (B20) include at least one group selected from the group consisting of groups represented by the formulae (1A) and (11B), and the remaining one selected from the group consisting of A₁, B₁ and C₁ each independently includes at least one group selected from the group consisting of groups represented by the formulae (1 D), (11D), (12D), (13D), (14D), (15D), (16D), and (17D).

In an exemplary arrangement of the organic EL device according to the first exemplary embodiment, at least one selected from the group consisting of A₁, B₁ and C₁ in the formulae (B1), (B100), and (B10) to (B20) is a group represented by the formula (1G), and X_{B} is an oxygen atom.

In an exemplary arrangement of the organic EL device according to the first exemplary embodiment, two selected from the group consisting of A₁, B₁ and C₁ in the formulae (B1), (B100), and (B10) to (B20) are each a group represented by the formula (1G), and X_{B} is an oxygen atom.

In an exemplary arrangement of the organic EL device according to the first exemplary embodiment, at least one selected from the group consisting of A₁, B₁ and C₁ in the formulae (B1), (B100), and (B10) to (B20) includes at least one group selected from the group consisting of groups represented by the formulae (11G), (12G) and (13G).

In an exemplary arrangement of the organic EL device according to the first exemplary embodiment, two selected from the group consisting of A₁, B₁ and C₁ in the formulae (B1), (B100), and (B10) to (B20) include at least one group selected from the group consisting of groups represented by the formulae (11 G), (12G) and (13G).

In an exemplary arrangement of the organic EL device according to the first exemplary embodiment, at least one selected from the group consisting of A₁, B₁ and C₁ in the formulae (B1), (B100), and (B10) to (B20) includes at least one group selected from the group consisting of groups represented by the formulae (11 G-1), (12G-1), (12G-2), and (13G-1).

In an exemplary arrangement of the organic EL device according to the first exemplary embodiment, two selected from the group consisting of A₁, B₁ and C₁ in the formulae (B1), (B100), and (B10) to (B20) include at least one group selected from the group consisting of groups represented by the formulae (11G-1), (12G-1), (12G-2), and (13G-1).

In an exemplary arrangement of the organic EL device according to the first exemplary embodiment, at least one selected from the group consisting of A₁, B₁ and C₁ in the formulae (B1), (B100), and (B10) to (B20) has, as a substituent, at least one substituted or unsubstituted alkyl group having 1 to 20 carbon atoms (preferably, 1 to 6 carbon atoms).

In an exemplary arrangement of the organic EL device according to the first exemplary embodiment, at least one selected from the group consisting of A₁, B₁ and C₁ in the formulae (B1), (B100), and (B10) to (B20) has, as a substituent, at least one alkyl group including branched chain.

In an exemplary arrangement of the organic EL device according to the first exemplary embodiment, at least one selected from the group consisting of A₁, B₁ and C₁ in the formulae (B1), (B100), and (B10) to (B20) has, as a substituent, at least one tert-butyl group.

In an exemplary arrangement of the organic EL device according to the first exemplary embodiment, the hole transporting zone material is at least one amine compound selected from the group consisting of a monoamine compound having one substituted or unsubstituted amino group in a molecule, a diamine compound having two substituted or unsubstituted amino groups in a molecule, a triamine compound having three substituted or unsubstituted amino groups in a molecule, and a tetraamine compound having four substituted or unsubstituted amino groups in a molecule.

In an exemplary arrangement of the organic EL device according to the first exemplary embodiment, the first hole transporting zone material and the second hole transporting zone material are each independently a monoamine compound or a diamine compound.

In an exemplary arrangement of the organic EL device according to the first exemplary embodiment, the first hole transporting zone material and the second hole transporting zone material are each independently a monoamine compound.

### Method of Producing Hole Transporting Zone Material According to Exemplary Embodiment

The hole transporting zone material according to the exemplary embodiment can be produced by a known method. Further, the hole transporting zone material according to the exemplary embodiment can be produced based on a known method through a known alternative reaction using a known material(s) tailored for the target compound.

### Specific Examples of Hole Transporting Zone Material According to Exemplary Embodiment

Specific examples of the hole transporting zone material according to the exemplary embodiment include the following compounds. However, the invention is not limited to these specific examples.

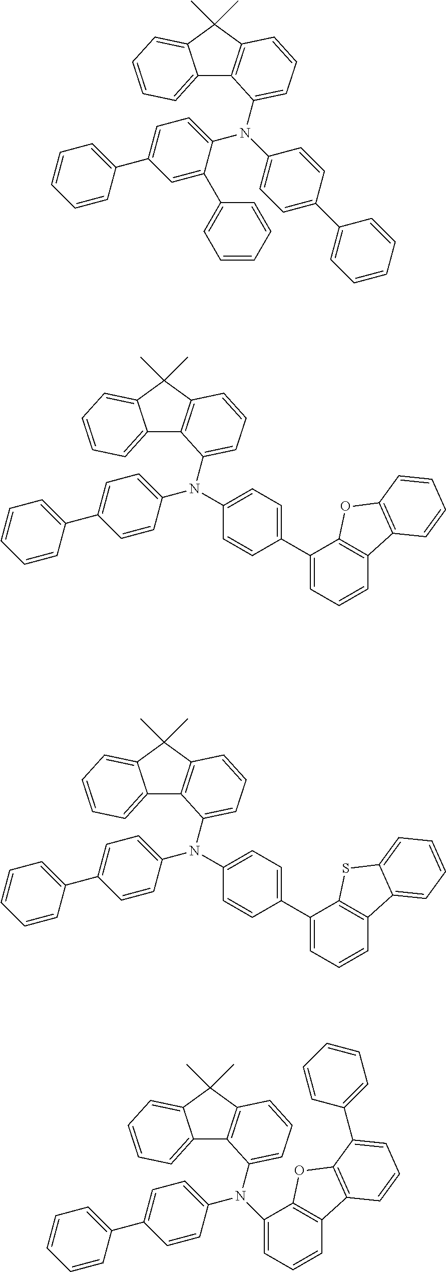 [SMILES: CC1(C)c2ccccc2-c2c(N(c3ccc(-c4ccccc4)cc3)c3ccc(-c4ccccc4)cc3-c3ccccc3)cccc21 ; CC1(C)c2ccccc2-c2c(N(c3ccc(-c4ccccc4)cc3)c3ccc(-c4cccc5c4oc4ccccc45)cc3)cccc21 ; CC1(C)c2ccccc2-c2c(N(c3ccc(-c4ccccc4)cc3)c3ccc(-c4cccc5c4sc4ccccc45)cc3)cccc21 ; CC1(C)c2ccccc2-c2c(N(c3ccc(-c4ccccc4)cc3)c3cccc4c3oc3c(-c5ccccc5)cccc34)cccc21]

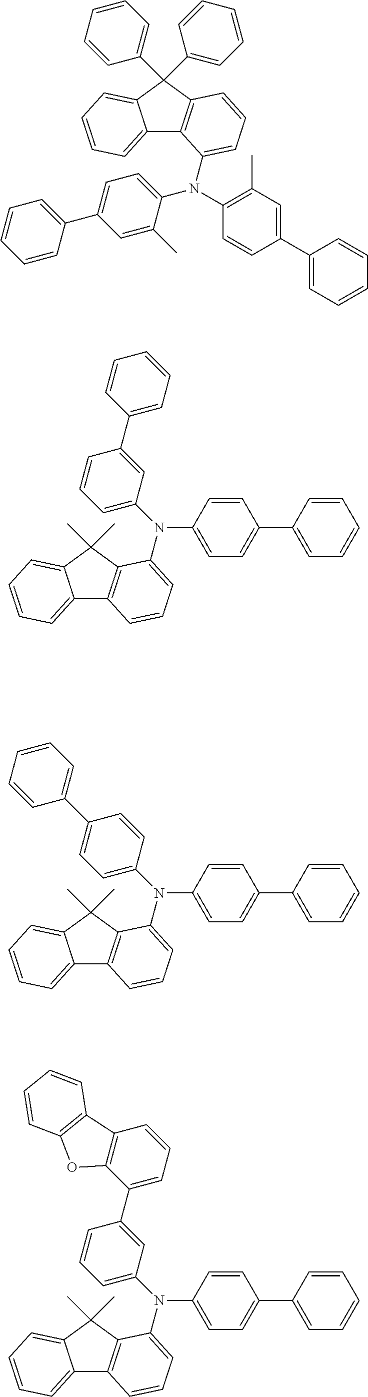 [SMILES: Cc1cc(-c2ccccc2)ccc1N(c1ccc(-c2ccccc2)cc1C)c1cccc2c1-c1ccccc1C2(c1ccccc1)c1ccccc1 ; CC1(C)c2ccccc2-c2cccc(N(c3ccc(-c4ccccc4)cc3)c3cccc(-c4ccccc4)c3)c21 ; CC1(C)c2ccccc2-c2cccc(N(c3ccc(-c4ccccc4)cc3)c3ccc(-c4ccccc4)cc3)c21 ; CC1(C)c2ccccc2-c2cccc(N(c3ccc(-c4ccccc4)cc3)c3cccc(-c4cccc5c4oc4ccccc45)c3)c21]

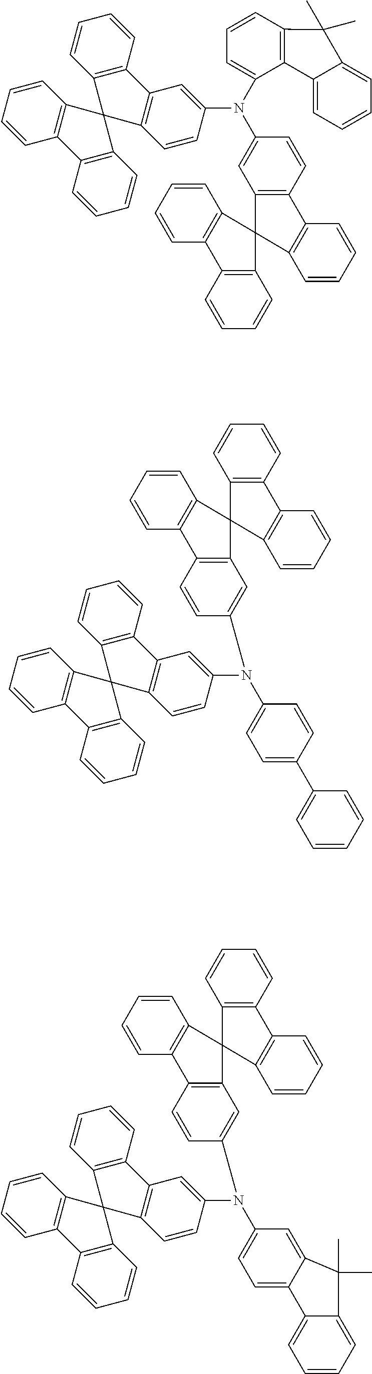 [SMILES: CC1(C)c2ccccc2-c2c(N(c3ccc4c(c3)-c3ccccc3C43c4ccccc4-c4ccccc43)c3ccc4c(c3)C3(c5ccccc5-c5ccccc53)c3ccccc3-4)cccc21 ; c1ccc(-c2ccc(N(c3ccc4c(c3)-c3ccccc3C43c4ccccc4-c4ccccc43)c3ccc4c(c3)C3(c5ccccc5-c5ccccc53)c3ccccc3-4)cc2)cc1 ; CC1(C)c2ccccc2-c2ccc(N(c3ccc4c(c3)-c3ccccc3C43c4ccccc4-c4ccccc43)c3ccc4c(c3)C3(c5ccccc5-c5ccccc53)c3ccccc3-4)cc21]

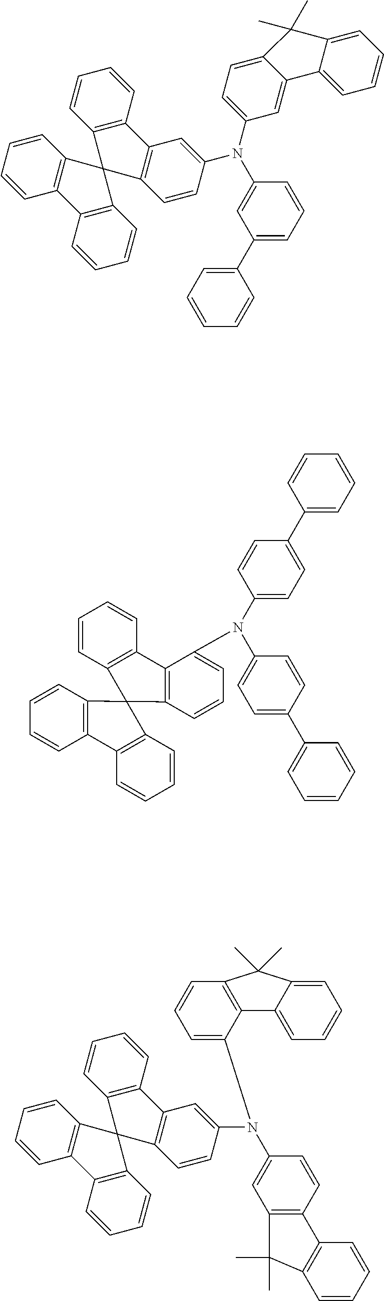 [SMILES: CC1(C)c2ccccc2-c2cc(N(c3cccc(-c4ccccc4)c3)c3ccc4c(c3)-c3ccccc3C43c4ccccc4-c4ccccc43)ccc21 ; c1ccc(-c2ccc(N(c3ccc(-c4ccccc4)cc3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3cccc4c3-c3ccccc3C4(C)C)cc21]

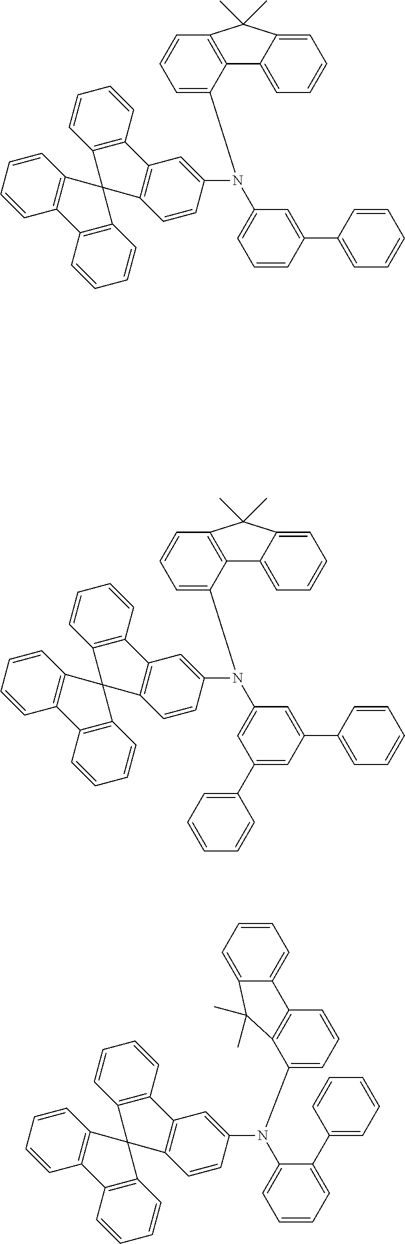 [SMILES: CC1(C)c2ccccc2-c2c(N(c3cccc(-c4ccccc4)c3)c3ccc4c(c3)-c3ccccc3C43c4ccccc4-c4ccccc43)cccc21 ; CC1(C)c2ccccc2-c2c(N(c3cc(-c4ccccc4)cc(-c4ccccc4)c3)c3ccc4c(c3)-c3ccccc3C43c4ccccc4-c4ccccc43)cccc21 ; CC1(C)c2ccccc2-c2cccc(N(c3ccc4c(c3)-c3ccccc3C43c4ccccc4-c4ccccc43)c3ccccc3-c3ccccc3)c21]

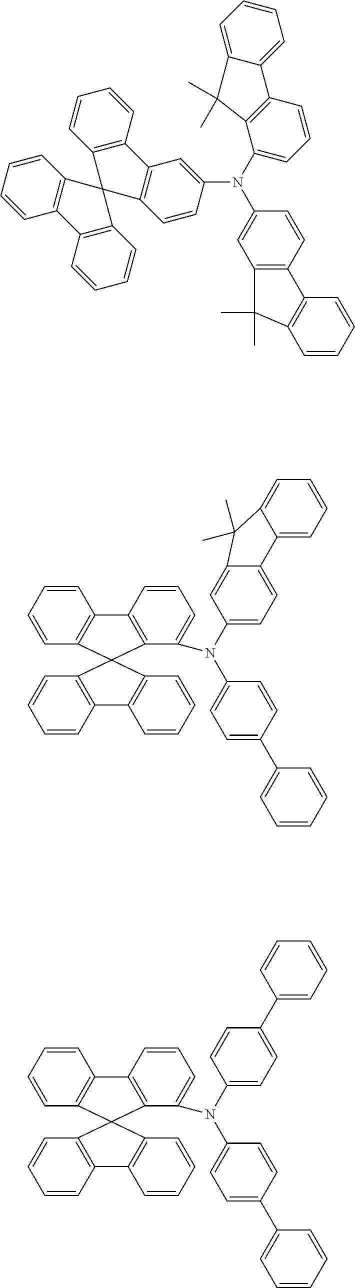 [SMILES: CC1(C)c2ccccc2-c2ccc(N(c3ccc4c(c3)-c3ccccc3C43c4ccccc4-c4ccccc43)c3cccc4c3C(C)(C)c3ccccc3-4)cc21 ; CC1(C)c2ccccc2-c2ccc(N(c3ccc(-c4ccccc4)cc3)c3cccc4c3C3(c5ccccc5-c5ccccc53)c3ccccc3-4)cc21 ; c1ccc(-c2ccc(N(c3ccc(-c4ccccc4)cc3)c3cccc4c3C3(c5ccccc5-c5ccccc53)c3ccccc3-4)cc2)cc1]

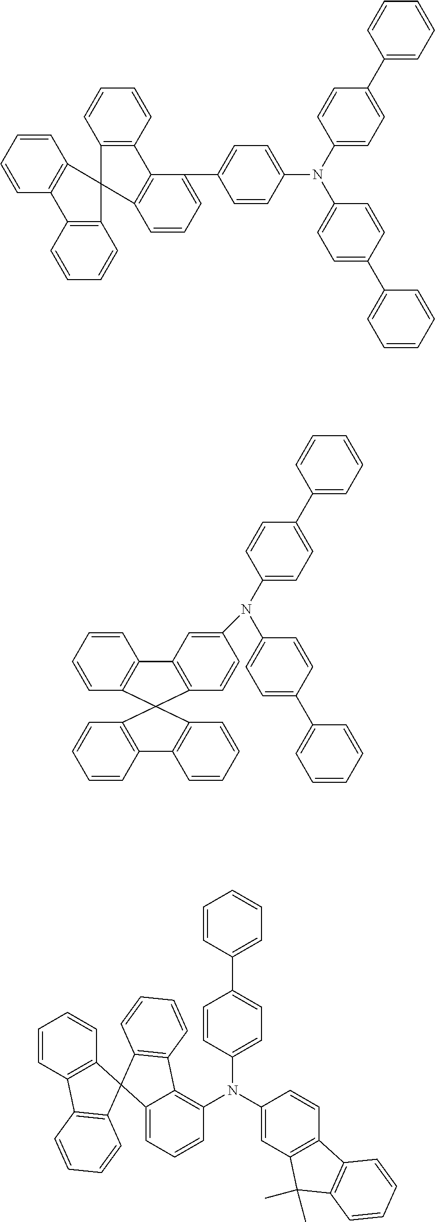 [SMILES: c1ccc(-c2ccc(N(c3ccc(-c4ccccc4)cc3)c3ccc(-c4cccc5c4-c4ccccc4C54c5ccccc5-c5ccccc54)cc3)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C43c4ccccc4-c4ccccc43)cc21]

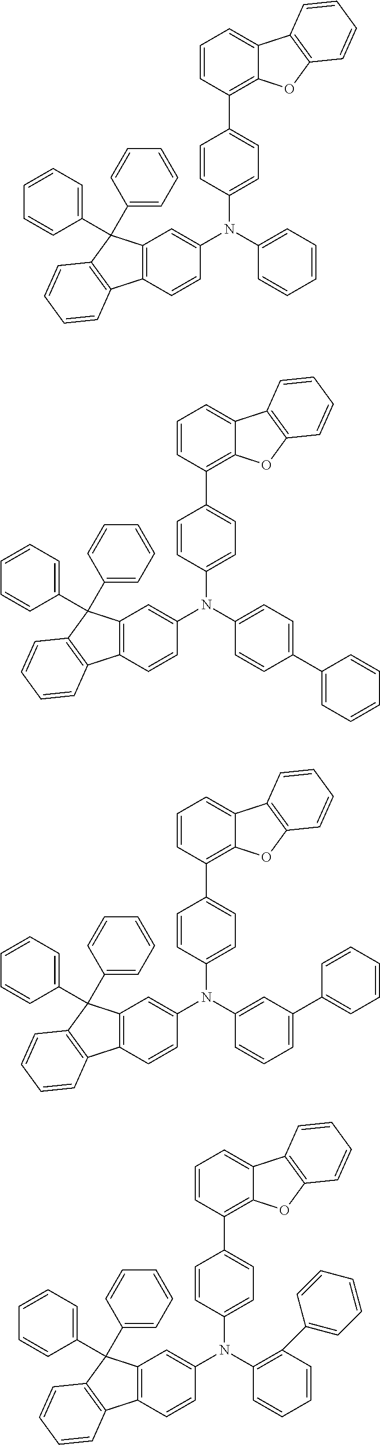 [SMILES: c1ccc(N(c2ccc(-c3cccc4c3oc3ccccc34)cc2)c2ccc3c(c2)C(c2ccccc2)(c2ccccc2)c2ccccc2-3)cc1 ; c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; c1ccc(-c2cccc(N(c3ccc(-c4cccc5c4oc4ccccc45)cc3)c3ccc4c(c3)C(c3ccccc3)(c3ccccc3)c3ccccc3-4)c2)cc1 ; c1ccc(-c2ccccc2N(c2ccc(-c3cccc4c3oc3ccccc34)cc2)c2ccc3c(c2)C(c2ccccc2)(c2ccccc2)c2ccccc2-3)cc1]

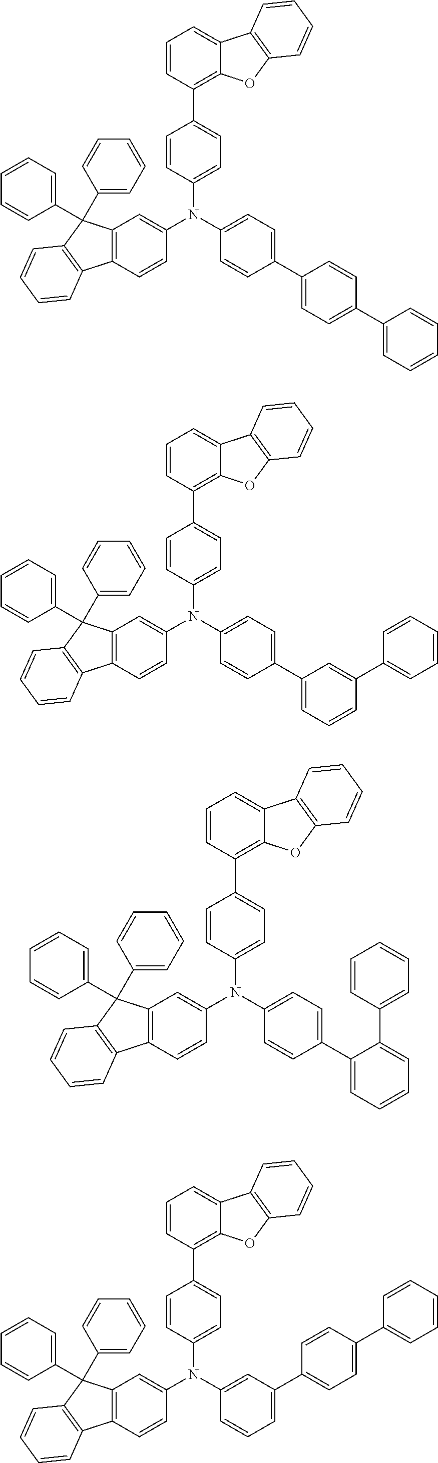

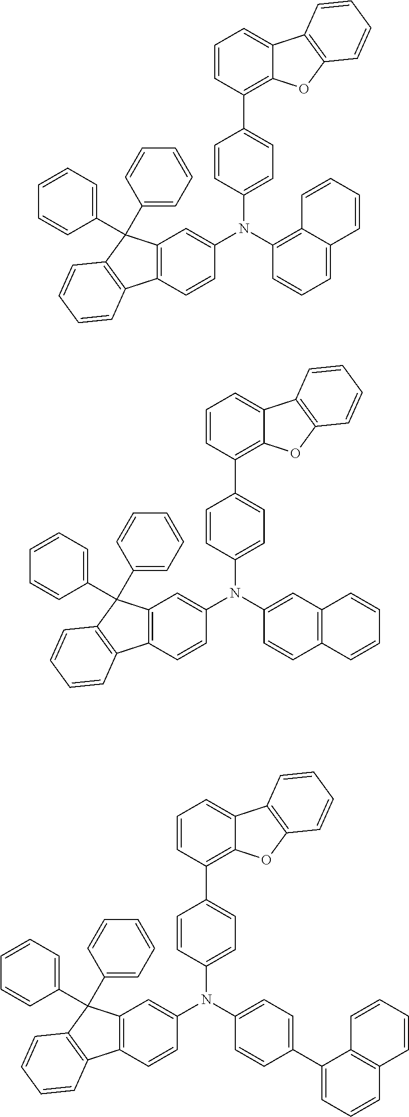 [SMILES: c1ccc(C2(c3ccccc3)c3ccccc3-c3ccc(N(c4ccc(-c5cccc6c5oc5ccccc56)cc4)c4cccc5ccccc45)cc32)cc1 ; c1ccc(C2(c3ccccc3)c3ccccc3-c3ccc(N(c4ccc(-c5cccc6c5oc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5oc5ccccc56)cc4)cc32)cc1]

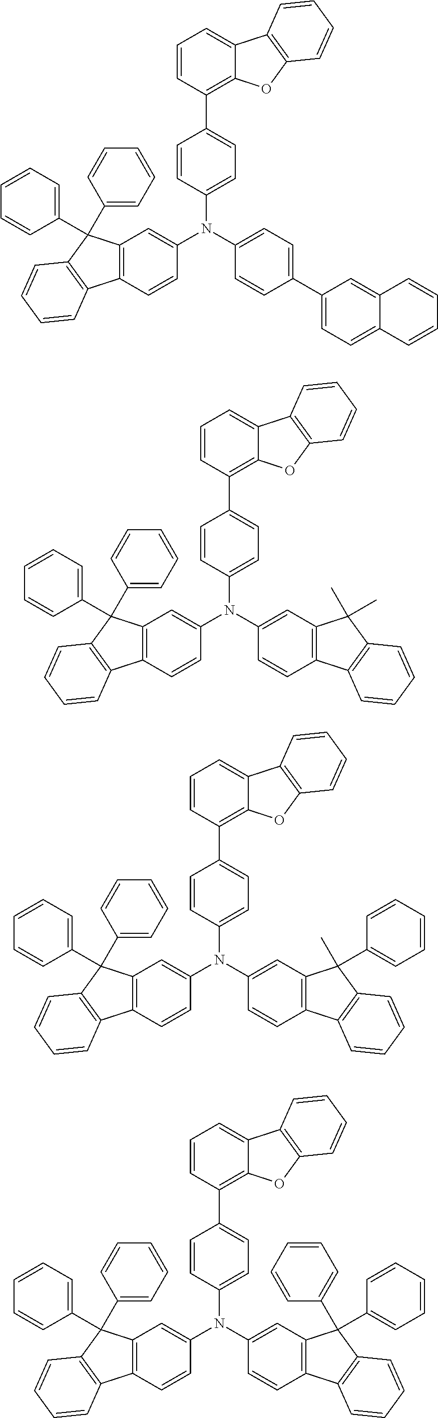

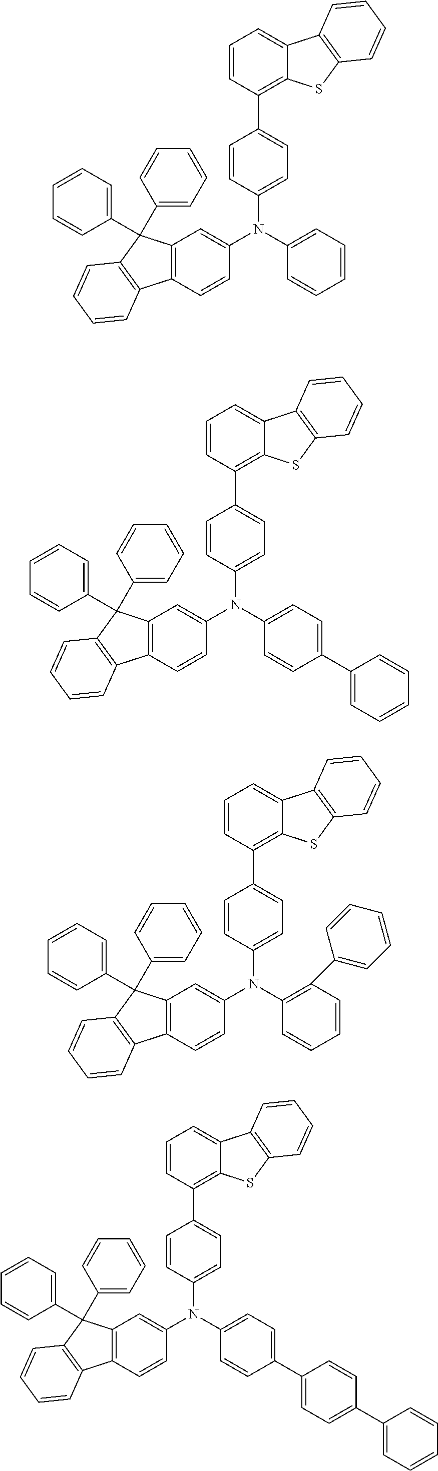

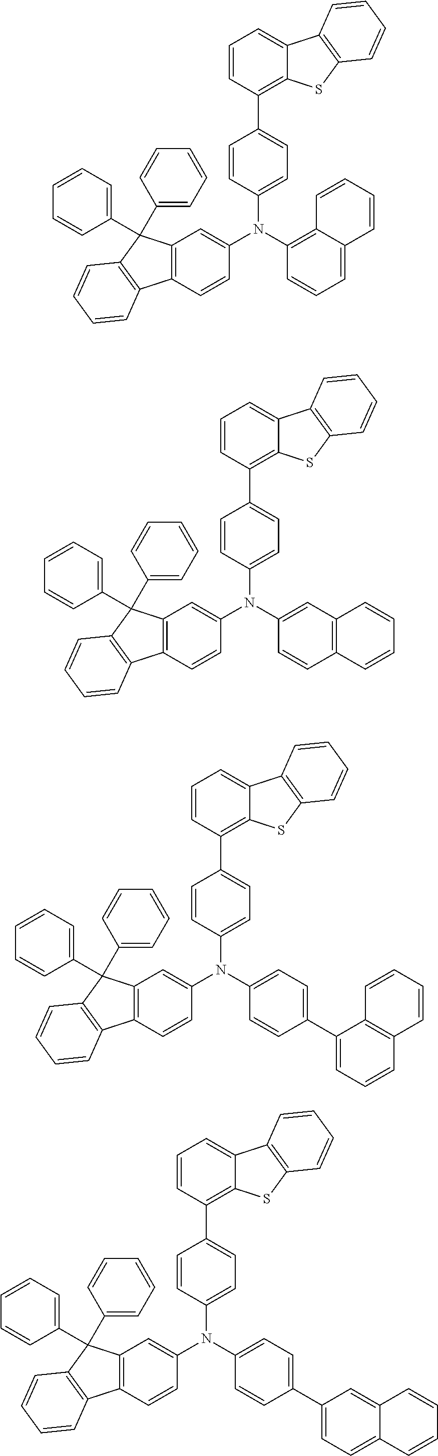 [SMILES: c1ccc(C2(c3ccccc3)c3ccccc3-c3ccc(N(c4ccc(-c5cccc6c5sc5ccccc56)cc4)c4cccc5ccccc45)cc32)cc1 ; c1ccc(C2(c3ccccc3)c3ccccc3-c3ccc(N(c4ccc(-c5cccc6c5sc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5sc5ccccc56)cc4)cc32)cc1 ; c1ccc(C2(c3ccccc3)c3ccccc3-c3ccc(N(c4ccc(-c5ccc6ccccc6c5)cc4)c4ccc(-c5cccc6c5sc5ccccc56)cc4)cc32)cc1]

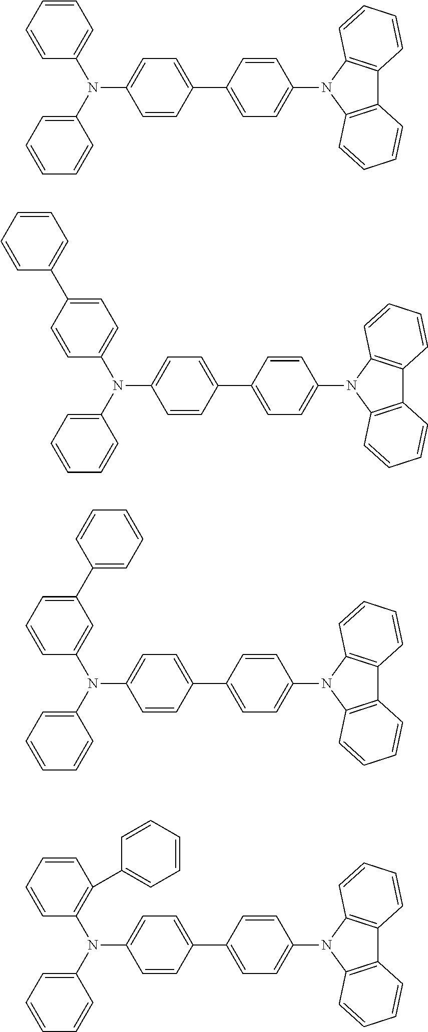

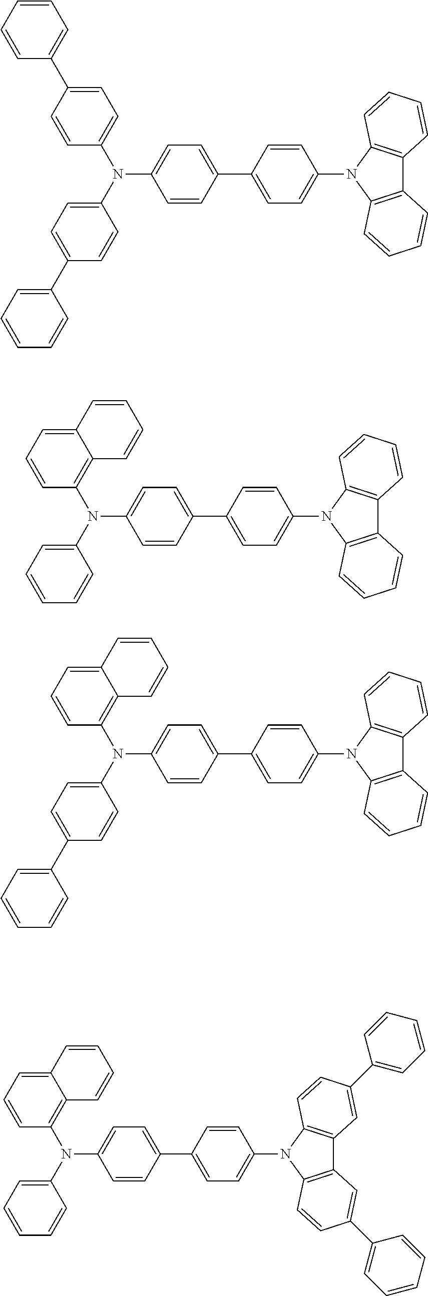 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(-n4c5ccccc5c5ccccc54)cc3)cc2)c2cccc3ccccc23)cc1 ; c1ccc(-c2ccc(N(c3ccc(-c4ccc(-n5c6ccccc6c6ccccc65)cc4)cc3)c3cccc4ccccc34)cc2)cc1 ; c1ccc(-c2ccc3c(c2)c2cc(-c4ccccc4)ccc2n3-c2ccc(-c3ccc(N(c4ccccc4)c4cccc5ccccc45)cc3)cc2)cc1]

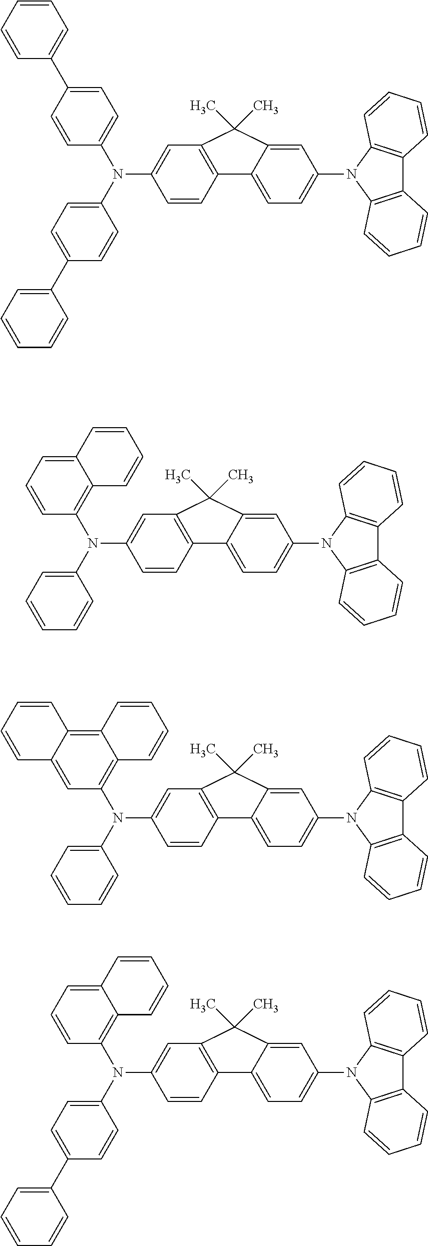 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2cc(N(c3ccccc3)c3cccc4ccccc34)ccc2-c2ccc(-n3c4ccccc4c4ccccc43)cc21 ; CC1(C)c2cc(N(c3ccccc3)c3cc4ccccc4c4ccccc34)ccc2-c2ccc(-n3c4ccccc4c4ccccc43)cc21 ; CC1(C)c2cc(N(c3ccc(-c4ccccc4)cc3)c3cccc4ccccc34)ccc2-c2ccc(-n3c4ccccc4c4ccccc43)cc21]

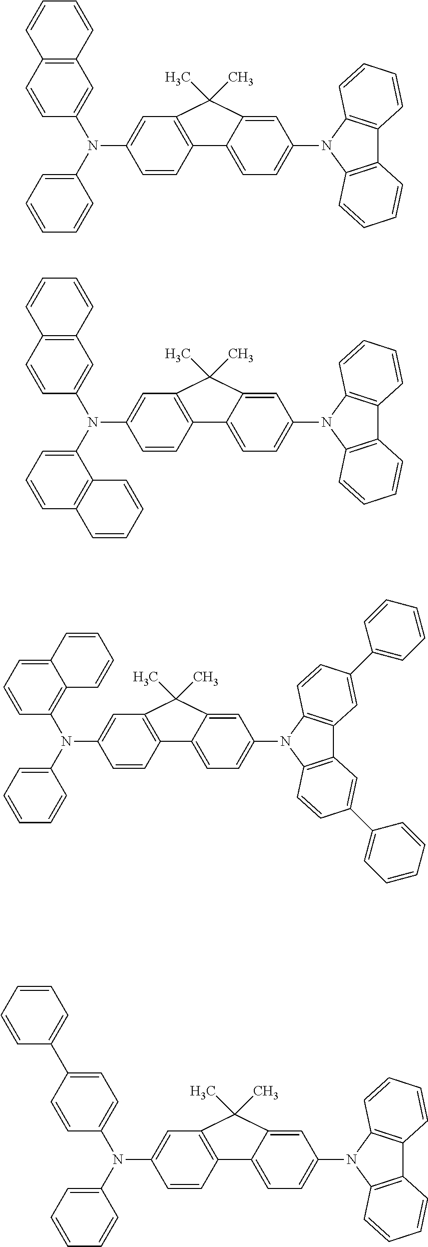

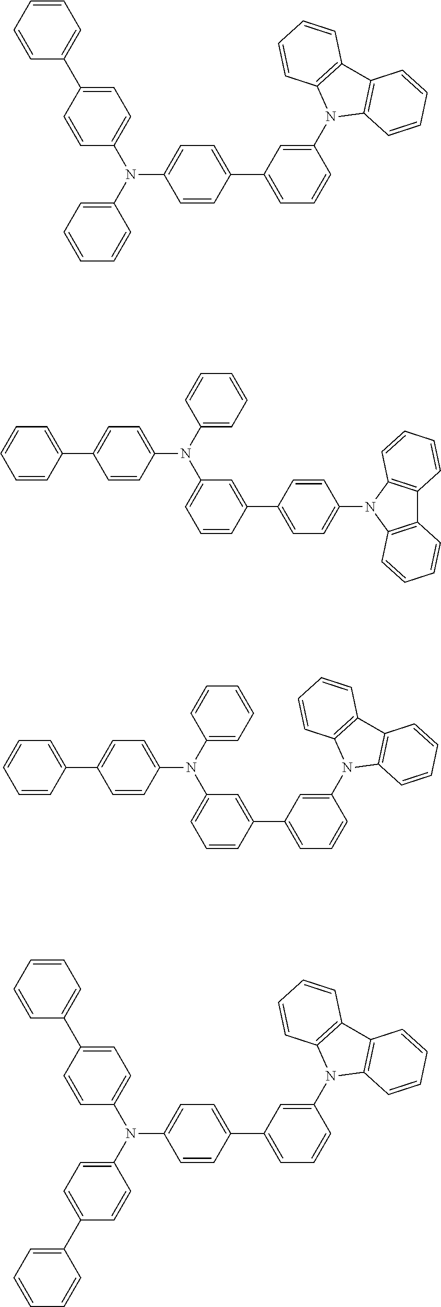 [SMILES: c1ccc(-c2ccc(N(c3ccccc3)c3ccc(-c4cccc(-n5c6ccccc6c6ccccc65)c4)cc3)cc2)cc1 ; c1ccc(-c2ccc(N(c3ccccc3)c3cccc(-c4ccc(-n5c6ccccc6c6ccccc65)cc4)c3)cc2)cc1 ; c1ccc(-c2ccc(N(c3ccccc3)c3cccc(-c4cccc(-n5c6ccccc6c6ccccc65)c4)c3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

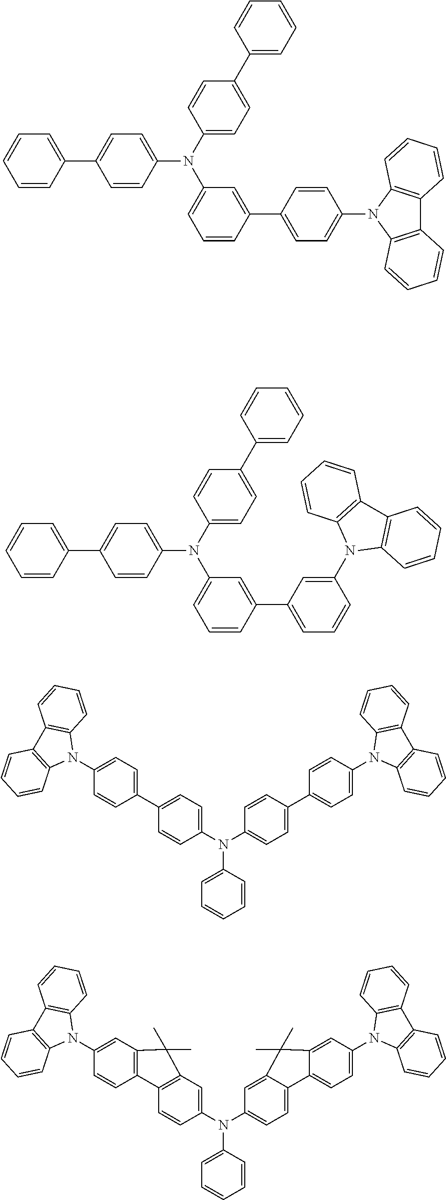 [SMILES: c1ccc(-c2ccc(N(c3ccc(-c4ccccc4)cc3)c3cccc(-c4ccc(-n5c6ccccc6c6ccccc65)cc4)c3)cc2)cc1 ; c1ccc(-c2ccc(N(c3ccc(-c4ccccc4)cc3)c3cccc(-c4cccc(-n5c6ccccc6c6ccccc65)c4)c3)cc2)cc1 ; c1ccc(N(c2ccc(-c3ccc(-n4c5ccccc5c5ccccc54)cc3)cc2)c2ccc(-c3ccc(-n4c5ccccc5c5ccccc54)cc3)cc2)cc1 ; CC1(C)c2cc(N(c3ccccc3)c3ccc4c(c3)C(C)(C)c3cc(-n5c6ccccc6c6ccccc65)ccc3-4)ccc2-c2ccc(-n3c4ccccc4c4ccccc43)cc21]

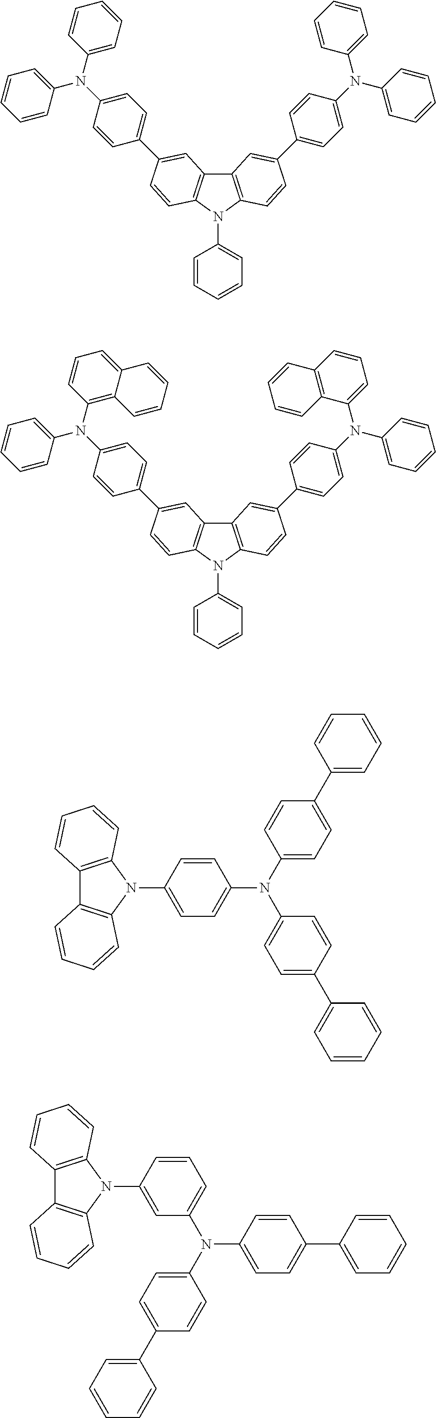 [SMILES: c1ccc(N(c2ccccc2)c2ccc(-c3ccc4c(c3)c3cc(-c5ccc(N(c6ccccc6)c6ccccc6)cc5)ccc3n4-c3ccccc3)cc2)cc1 ; c1ccc(N(c2ccc(-c3ccc4c(c3)c3cc(-c5ccc(N(c6ccccc6)c6cccc7ccccc67)cc5)ccc3n4-c3ccccc3)cc2)c2cccc3ccccc23)cc1 ; c1ccc(-c2ccc(N(c3ccc(-c4ccccc4)cc3)c3ccc(-n4c5ccccc5c5ccccc54)cc3)cc2)cc1 ; c1ccc(-c2ccc(N(c3ccc(-c4ccccc4)cc3)c3cccc(-n4c5ccccc5c5ccccc54)c3)cc2)cc1]

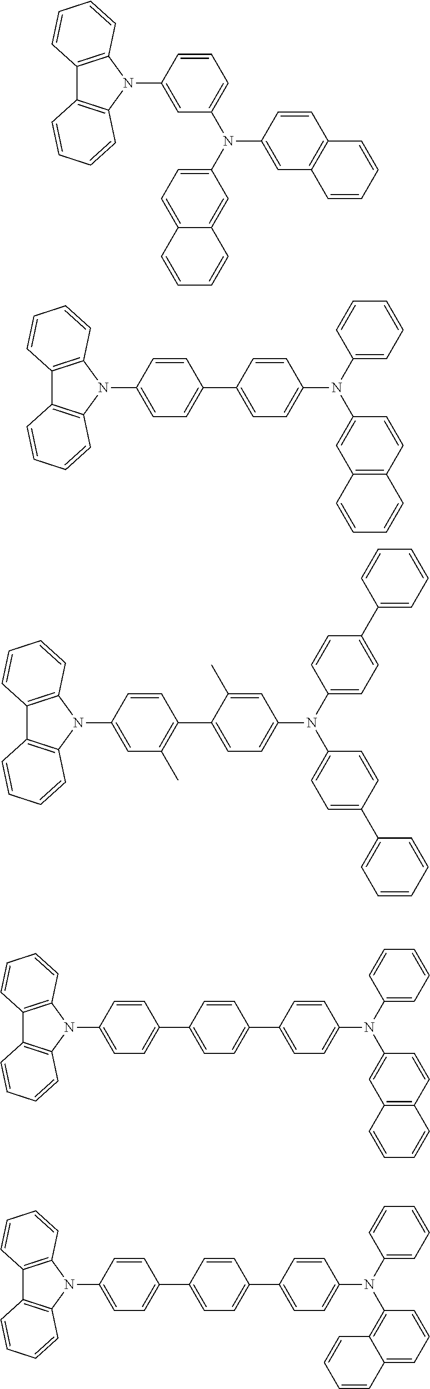

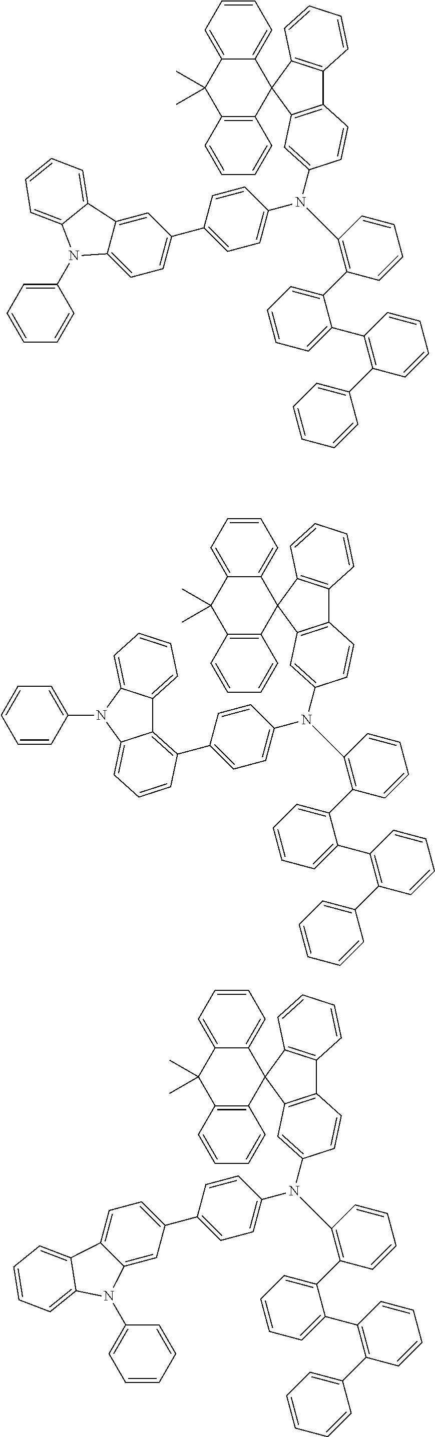

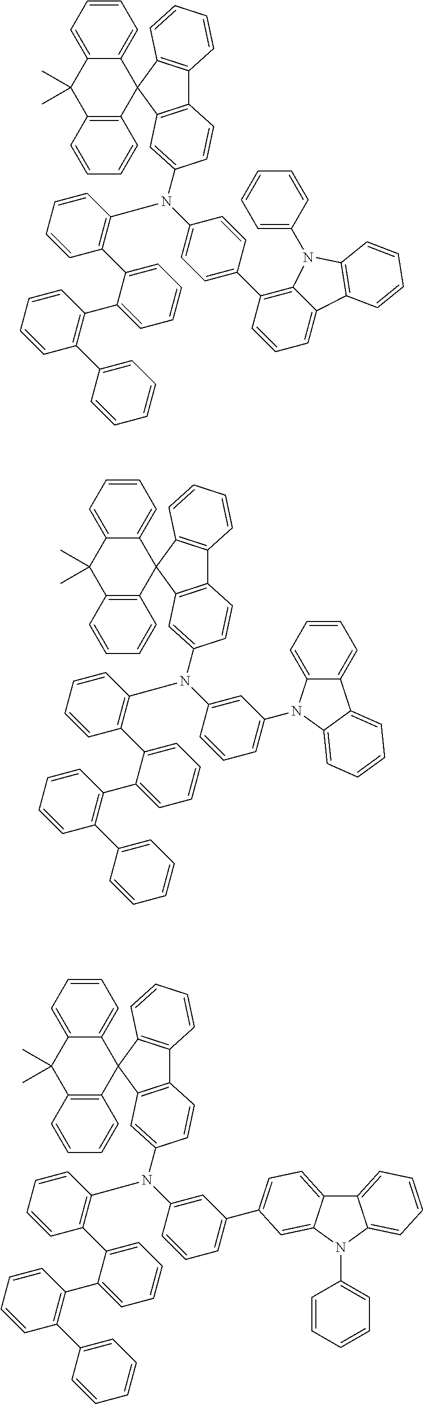 [SMILES: CC1(C)c2ccccc2C2(c3ccccc3-c3ccc(N(c4ccc(-c5cccc6c7ccccc7n(-c7ccccc7)c56)cc4)c4ccccc4-c4ccccc4-c4ccccc4-c4ccccc4)cc32)c2ccccc21 ; CC1(C)c2ccccc2C2(c3ccccc3-c3ccc(N(c4cccc(-n5c6ccccc6c6ccccc65)c4)c4ccccc4-c4ccccc4-c4ccccc4-c4ccccc4)cc32)c2ccccc21 ; CC1(C)c2ccccc2C2(c3ccccc3-c3ccc(N(c4cccc(-c5ccc6c7ccccc7n(-c7ccccc7)c6c5)c4)c4ccccc4-c4ccccc4-c4ccccc4-c4ccccc4)cc32)c2ccccc21]

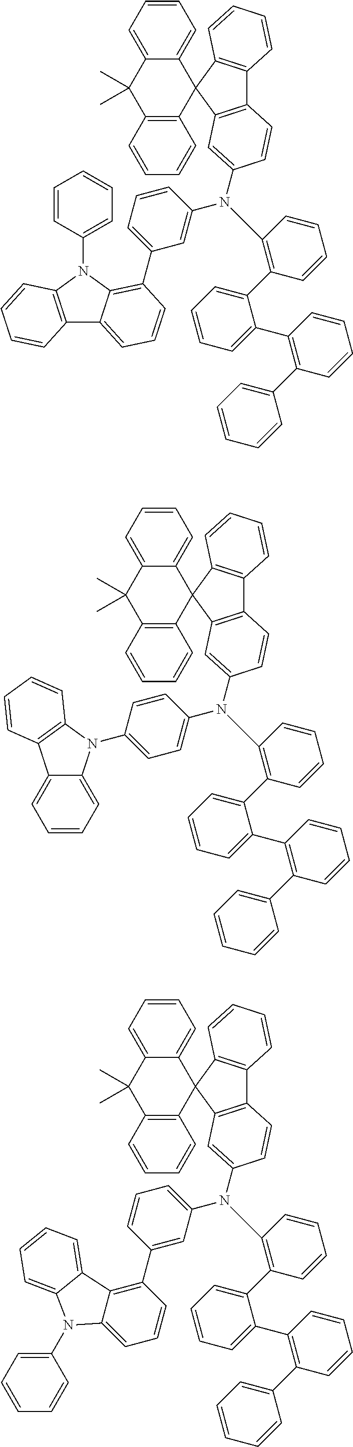 [SMILES: CC1(C)c2ccccc2C2(c3ccccc3-c3ccc(N(c4cccc(-c5cccc6c7ccccc7n(-c7ccccc7)c56)c4)c4ccccc4-c4ccccc4-c4ccccc4-c4ccccc4)cc32)c2ccccc21 ; CC1(C)c2ccccc2C2(c3ccccc3-c3ccc(N(c4ccc(-n5c6ccccc6c6ccccc65)cc4)c4ccccc4-c4ccccc4-c4ccccc4-c4ccccc4)cc32)c2ccccc21 ; CC1(C)c2ccccc2C2(c3ccccc3-c3ccc(N(c4cccc(-c5cccc6c5c5ccccc5n6-c5ccccc5)c4)c4ccccc4-c4ccccc4-c4ccccc4-c4ccccc4)cc32)c2ccccc21]

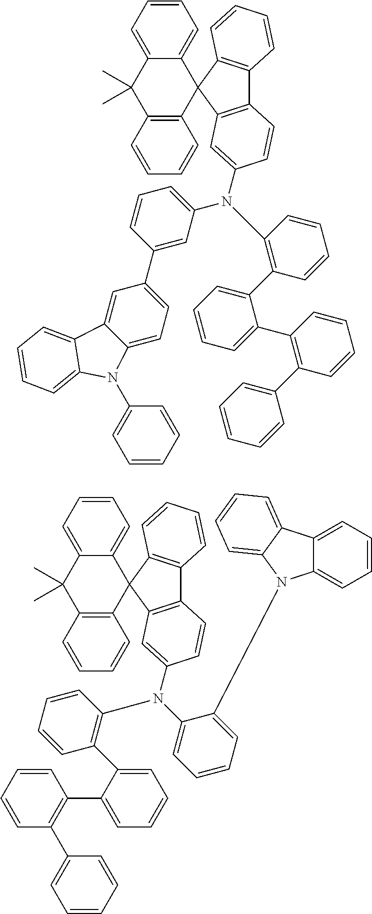

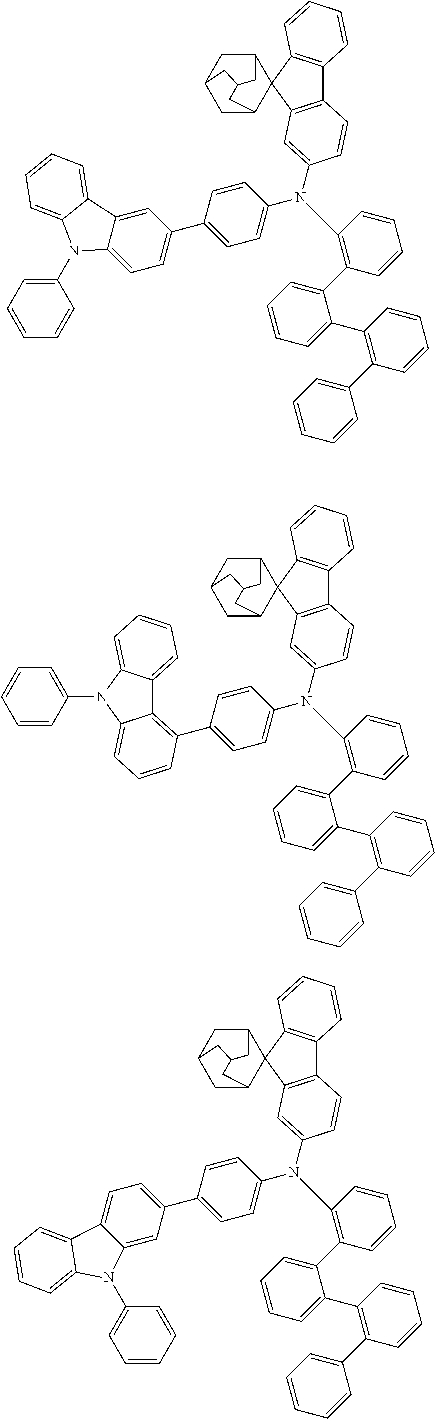

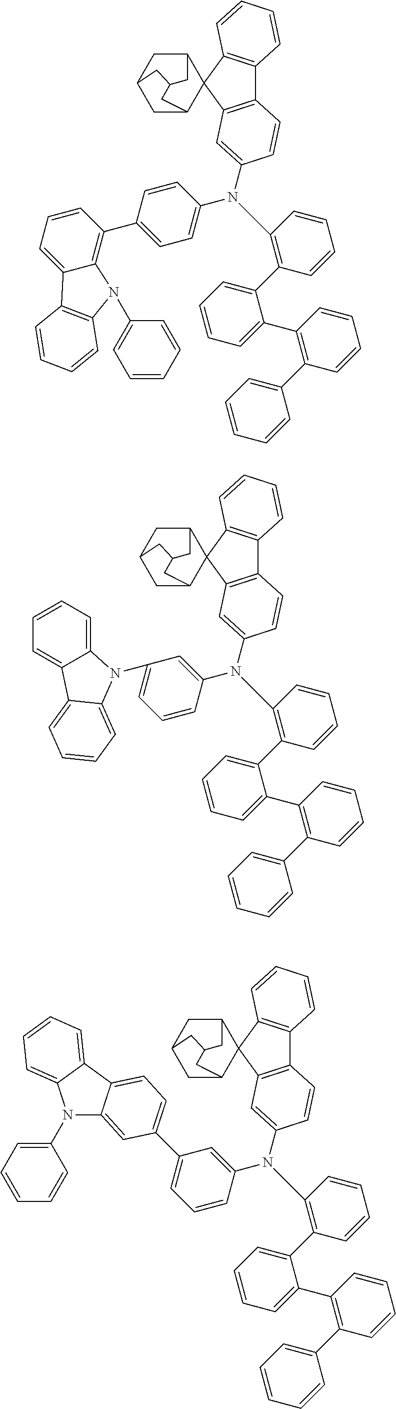

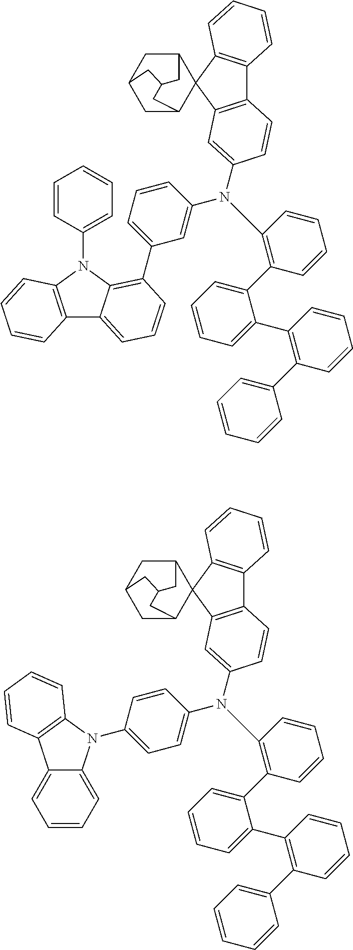 [SMILES: c1ccc(-c2ccccc2-c2ccccc2-c2ccccc2N(c2cccc(-c3cccc4c5ccccc5n(-c5ccccc5)c34)c2)c2ccc3c(c2)C2(c4ccccc4-3)C3CC4CC(C3)CC2C4)cc1 ; c1ccc(-c2ccccc2-c2ccccc2-c2ccccc2N(c2ccc(-n3c4ccccc4c4ccccc43)cc2)c2ccc3c(c2)C2(c4ccccc4-3)C3CC4CC(C3)CC2C4)cc1]

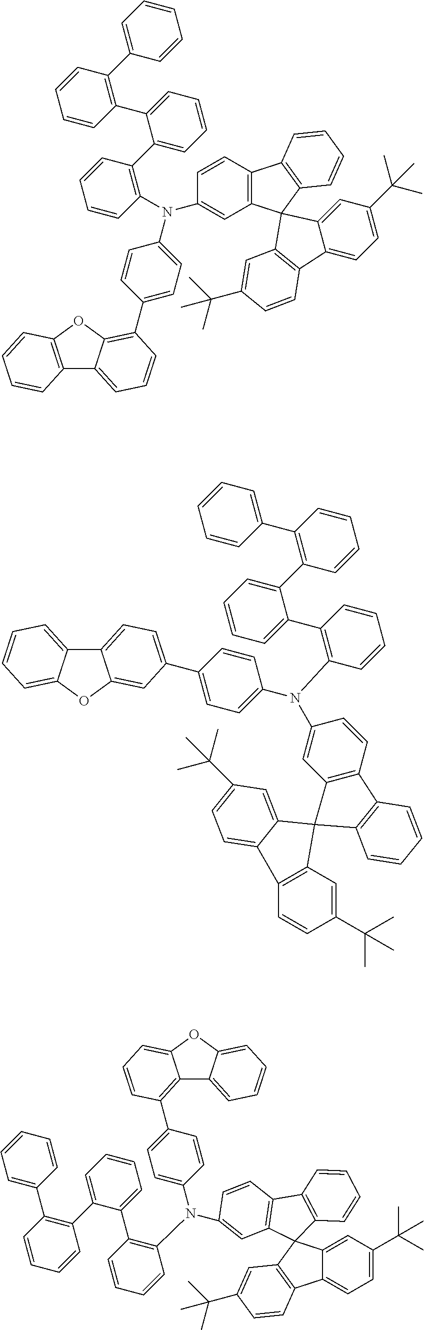 [SMILES: CC(C)(C)c1ccc2c(c1)C1(c3ccccc3-c3ccc(N(c4ccc(-c5cccc6c5oc5ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6c(c5)oc5ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cccc6oc7ccccc7c56)cc4)c4ccccc4-c4ccccc4-c4ccccc4-c4ccccc4)cc31)c1cc(C(C)(C)C)ccc1-2]

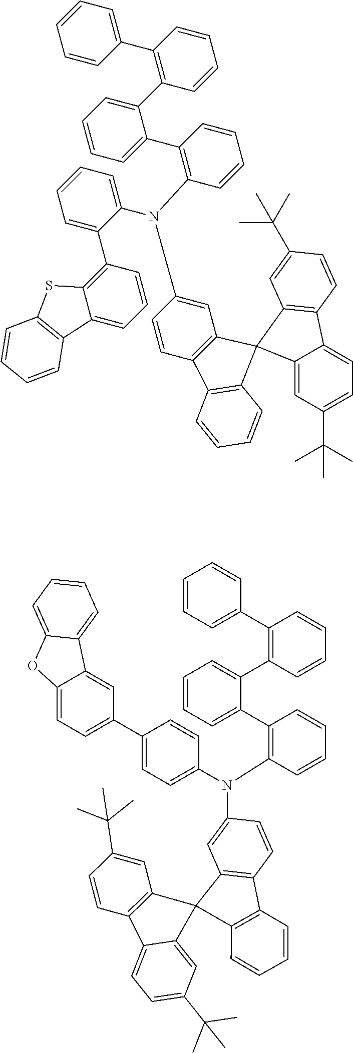 [SMILES: CC(C)(C)c1ccc2c(c1)C1(c3ccccc3-c3ccc(N(c4ccccc4-c4ccccc4-c4ccccc4-c4ccccc4)c4ccccc4-c4cccc5c4sc4ccccc45)cc31)c1cc(C(C)(C)C)ccc1-2 ; CC(C)(C)c1ccc2c(c1)C1(c3ccccc3-c3ccc(N(c4ccc(-c5ccc6oc7ccccc7c6c5)cc4)c4ccccc4-c4ccccc4-c4ccccc4-c4ccccc4)cc31)c1cc(C(C)(C)C)ccc1-2]

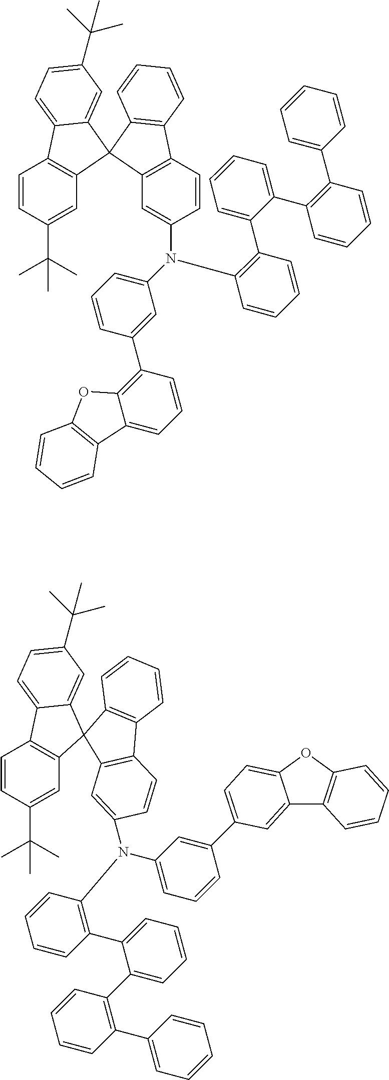 [SMILES: CC(C)(C)c1ccc2c(c1)C1(c3ccccc3-c3ccc(N(c4cccc(-c5cccc6c5oc5ccccc56)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4cccc(-c5ccc6oc7ccccc7c6c5)c4)c4ccccc4-c4ccccc4-c4ccccc4-c4ccccc4)cc31)c1cc(C(C)(C)C)ccc1-2]

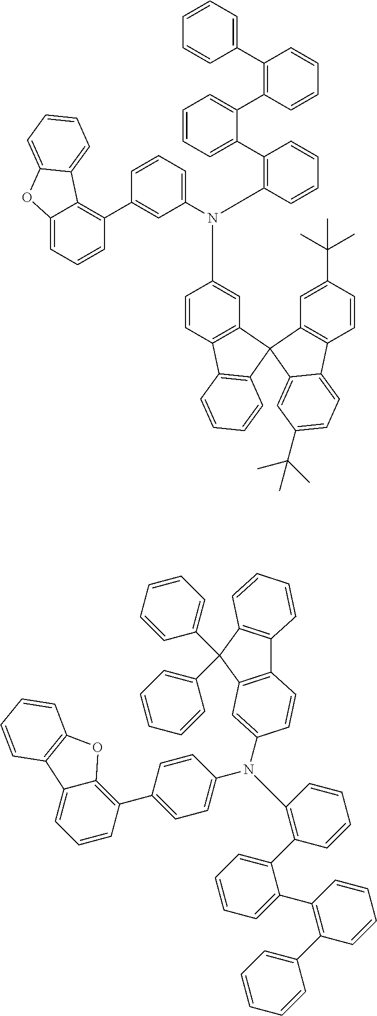 [SMILES: CC(C)(C)c1ccc2c(c1)C1(c3ccccc3-c3ccc(N(c4cccc(-c5cccc6oc7ccccc7c56)c4)c4ccccc4-c4ccccc4-c4ccccc4-c4ccccc4)cc31)c1cc(C(C)(C)C)ccc1-2 ; c1ccc(-c2ccccc2-c2ccccc2-c2ccccc2N(c2ccc(-c3cccc4c3oc3ccccc34)cc2)c2ccc3c(c2)C(c2ccccc2)(c2ccccc2)c2ccccc2-3)cc1]

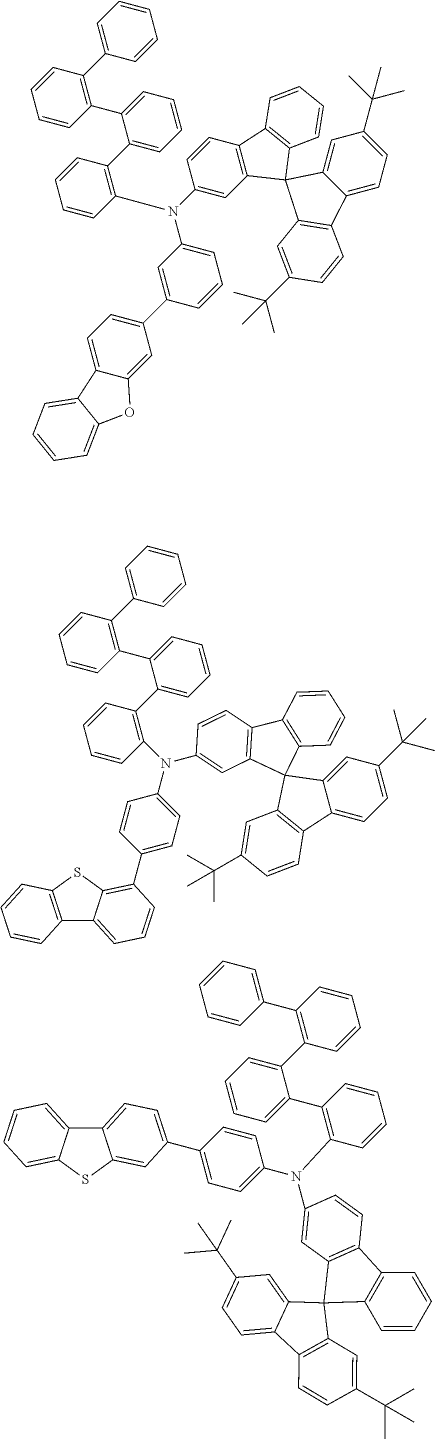 [SMILES: CC(C)(C)c1ccc2c(c1)C1(c3ccccc3-c3ccc(N(c4cccc(-c5ccc6c(c5)oc5ccccc56)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cccc6c5sc5ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6c(c5)sc5ccccc56)cc4)c4ccccc4-c4ccccc4-c4ccccc4-c4ccccc4)cc31)c1cc(C(C)(C)C)ccc1-2]

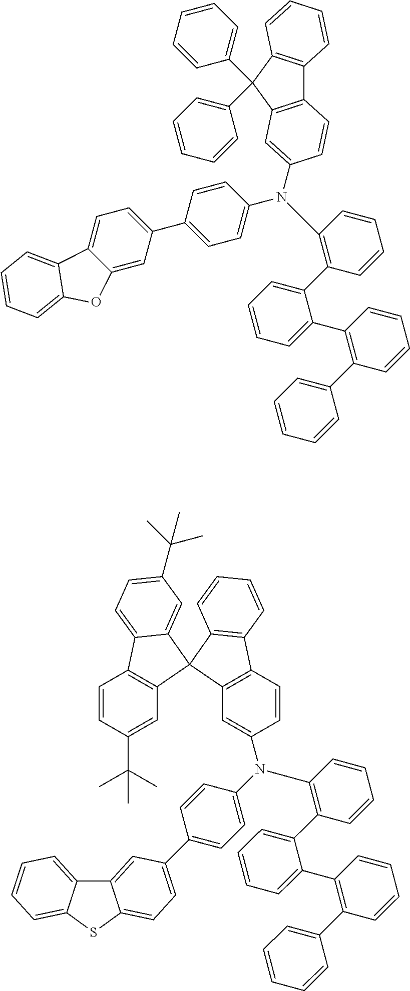 [SMILES: c1ccc(-c2ccccc2-c2ccccc2-c2ccccc2N(c2ccc(-c3ccc4c(c3)oc3ccccc34)cc2)c2ccc3c(c2)C(c2ccccc2)(c2ccccc2)c2ccccc2-3)cc1 ; CC(C)(C)c1ccc2c(c1)C1(c3ccccc3-c3ccc(N(c4ccc(-c5ccc6sc7ccccc7c6c5)cc4)c4ccccc4-c4ccccc4-c4ccccc4-c4ccccc4)cc31)c1cc(C(C)(C)C)ccc1-2]

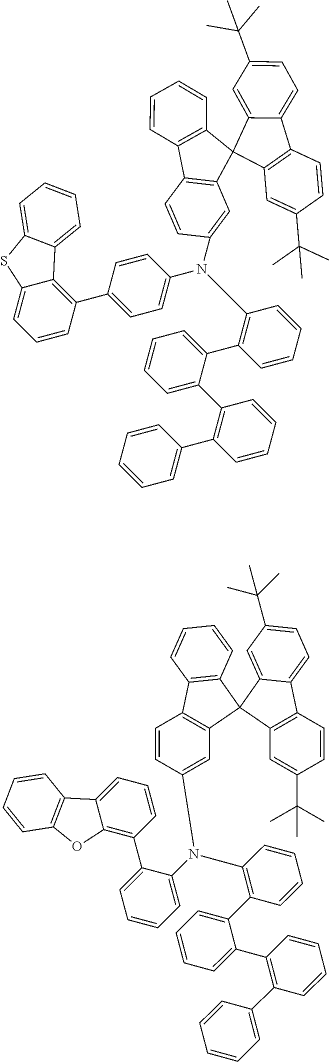 [SMILES: CC(C)(C)c1ccc2c(c1)C1(c3ccccc3-c3ccc(N(c4ccc(-c5cccc6sc7ccccc7c56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccccc4-c4ccccc4-c4ccccc4-c4ccccc4)c4ccccc4-c4cccc5c4oc4ccccc45)cc31)c1cc(C(C)(C)C)ccc1-2]

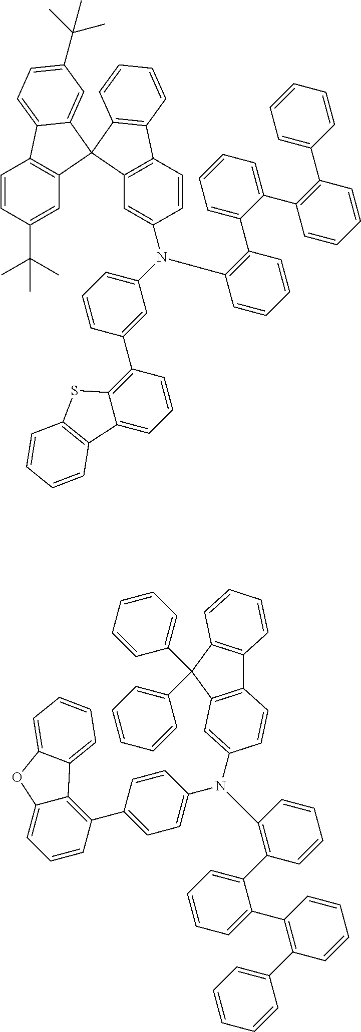 [SMILES: CC(C)(C)c1ccc2c(c1)C1(c3ccccc3-c3ccc(N(c4cccc(-c5cccc6c5sc5ccccc56)c4)c4ccccc4-c4ccccc4-c4ccccc4-c4ccccc4)cc31)c1cc(C(C)(C)C)ccc1-2 ; c1ccc(-c2ccccc2-c2ccccc2-c2ccccc2N(c2ccc(-c3cccc4oc5ccccc5c34)cc2)c2ccc3c(c2)C(c2ccccc2)(c2ccccc2)c2ccccc2-3)cc1]

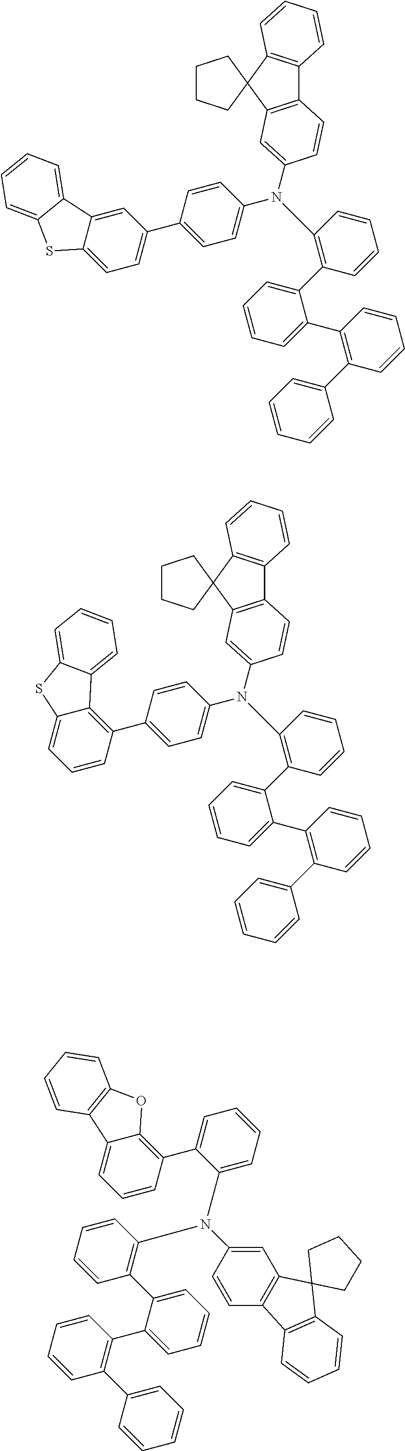 [SMILES: c1ccc(-c2ccccc2-c2ccccc2-c2ccccc2N(c2ccc(-c3ccc4sc5ccccc5c4c3)cc2)c2ccc3c(c2)C2(CCCC2)c2ccccc2-3)cc1 ; c1ccc(-c2ccccc2-c2ccccc2-c2ccccc2N(c2ccc(-c3cccc4sc5ccccc5c34)cc2)c2ccc3c(c2)C2(CCCC2)c2ccccc2-3)cc1 ; c1ccc(-c2ccccc2-c2ccccc2-c2ccccc2N(c2ccc3c(c2)C2(CCCC2)c2ccccc2-3)c2ccccc2-c2cccc3c2oc2ccccc23)cc1]

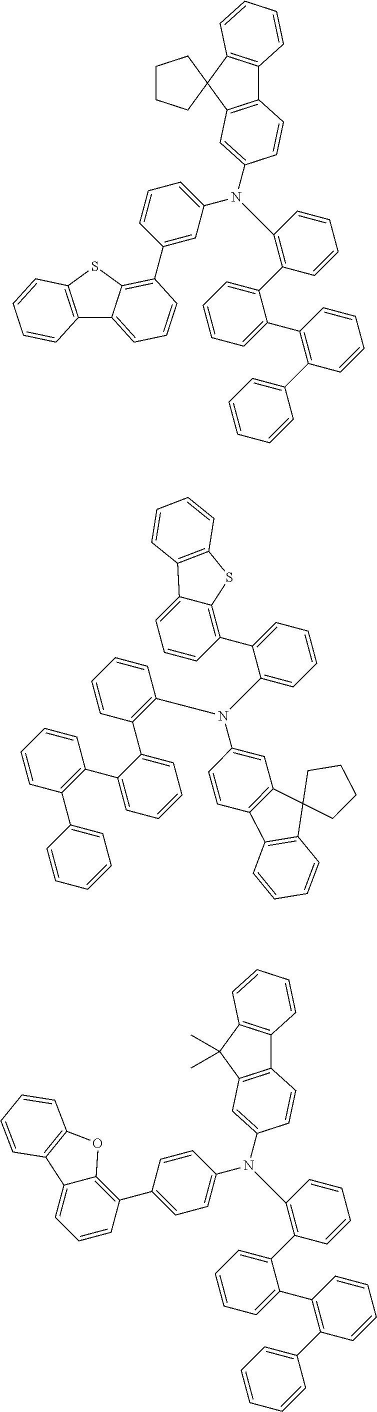 [SMILES: c1ccc(-c2ccccc2-c2ccccc2-c2ccccc2N(c2cccc(-c3cccc4c3sc3ccccc34)c2)c2ccc3c(c2)C2(CCCC2)c2ccccc2-3)cc1 ; c1ccc(-c2ccccc2-c2ccccc2-c2ccccc2N(c2ccc3c(c2)C2(CCCC2)c2ccccc2-3)c2ccccc2-c2cccc3c2sc2ccccc23)cc1 ; CC1(C)c2ccccc2-c2ccc(N(c3ccc(-c4cccc5c4oc4ccccc45)cc3)c3ccccc3-c3ccccc3-c3ccccc3-c3ccccc3)cc21]

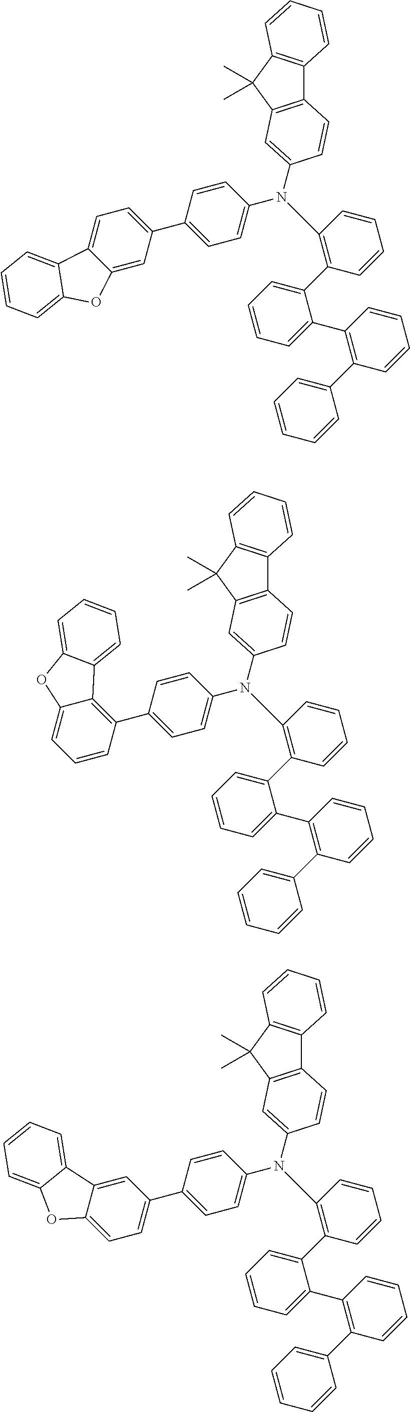

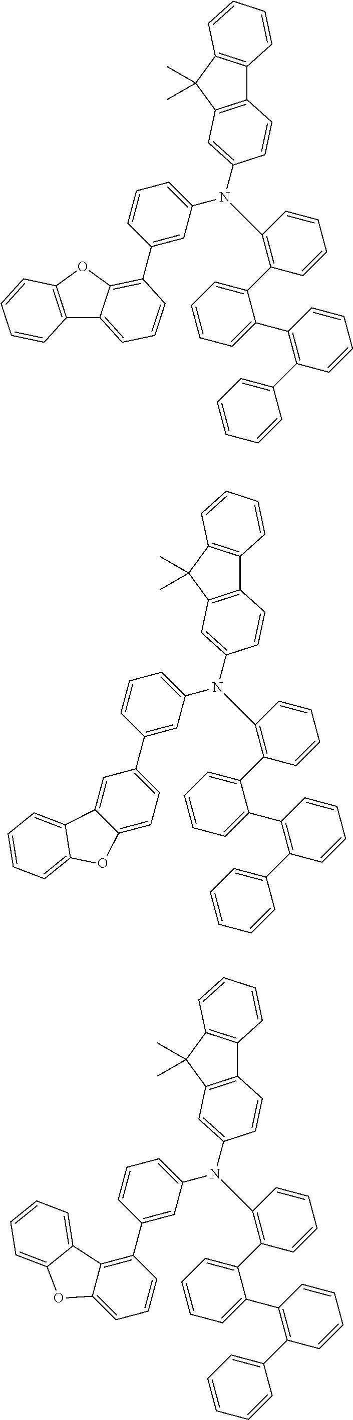 [SMILES: CC1(C)c2ccccc2-c2ccc(N(c3cccc(-c4cccc5c4oc4ccccc45)c3)c3ccccc3-c3ccccc3-c3ccccc3-c3ccccc3)cc21 ; CC1(C)c2ccccc2-c2ccc(N(c3cccc(-c4ccc5oc6ccccc6c5c4)c3)c3ccccc3-c3ccccc3-c3ccccc3-c3ccccc3)cc21 ; CC1(C)c2ccccc2-c2ccc(N(c3cccc(-c4cccc5oc6ccccc6c45)c3)c3ccccc3-c3ccccc3-c3ccccc3-c3ccccc3)cc21]

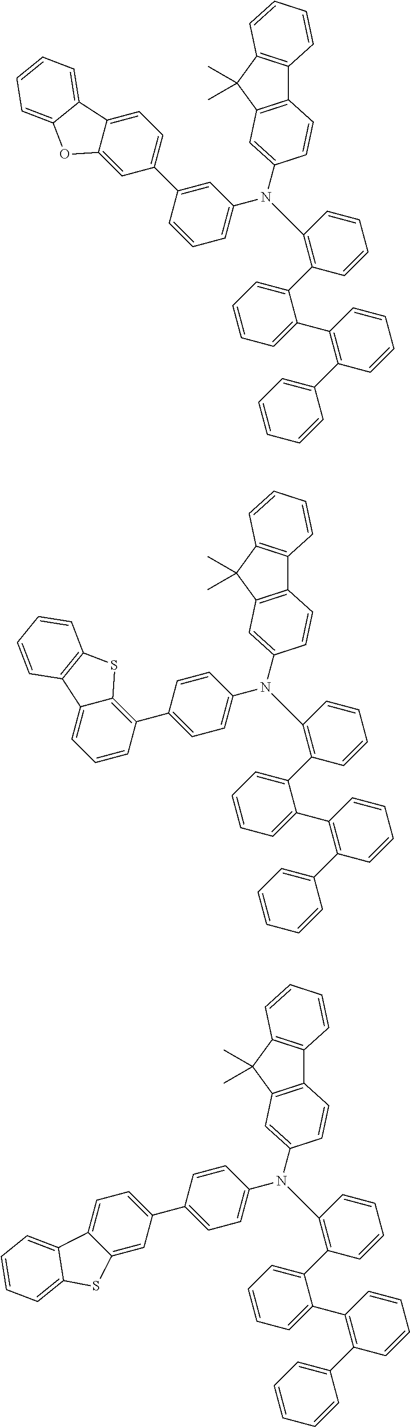 [SMILES: CC1(C)c2ccccc2-c2ccc(N(c3cccc(-c4ccc5c(c4)oc4ccccc45)c3)c3ccccc3-c3ccccc3-c3ccccc3-c3ccccc3)cc21 ; CC1(C)c2ccccc2-c2ccc(N(c3ccc(-c4cccc5c4sc4ccccc45)cc3)c3ccccc3-c3ccccc3-c3ccccc3-c3ccccc3)cc21 ; CC1(C)c2ccccc2-c2ccc(N(c3ccc(-c4ccc5c(c4)sc4ccccc45)cc3)c3ccccc3-c3ccccc3-c3ccccc3-c3ccccc3)cc21]

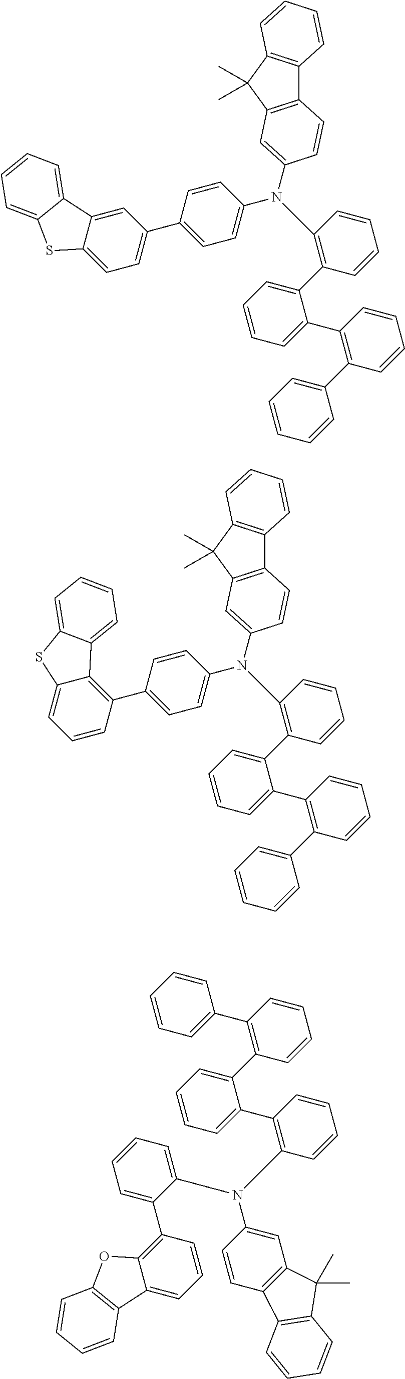

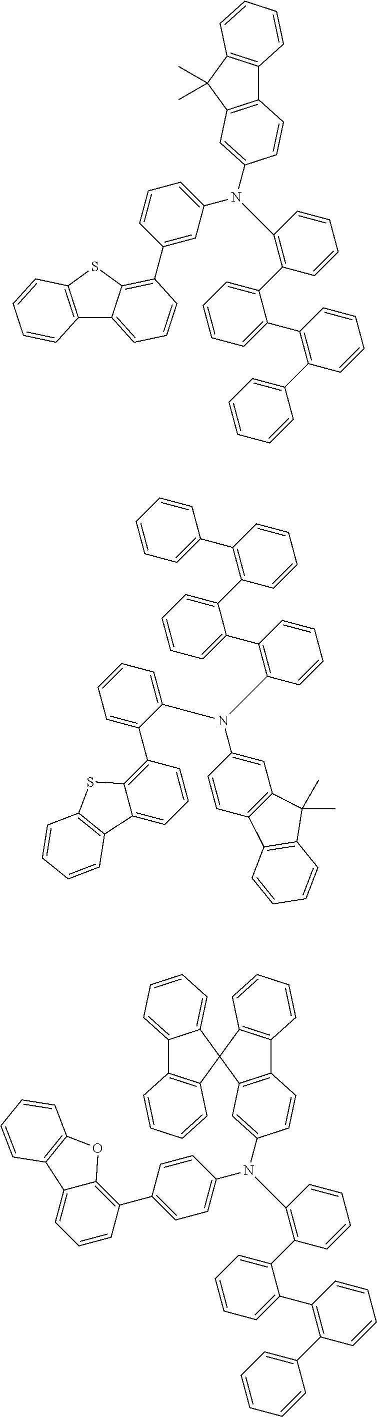 [SMILES: CC1(C)c2ccccc2-c2ccc(N(c3cccc(-c4cccc5c4sc4ccccc45)c3)c3ccccc3-c3ccccc3-c3ccccc3-c3ccccc3)cc21 ; CC1(C)c2ccccc2-c2ccc(N(c3ccccc3-c3ccccc3-c3ccccc3-c3ccccc3)c3ccccc3-c3cccc4c3sc3ccccc34)cc21 ; c1ccc(-c2ccccc2-c2ccccc2-c2ccccc2N(c2ccc(-c3cccc4c3oc3ccccc34)cc2)c2ccc3c(c2)C2(c4ccccc4-c4ccccc42)c2ccccc2-3)cc1]

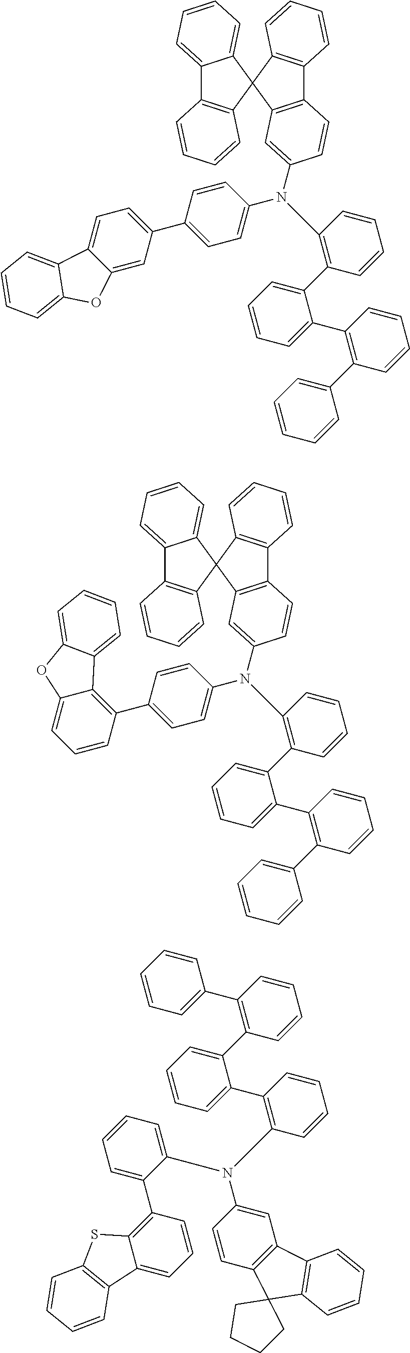 [SMILES: c1ccc(-c2ccccc2-c2ccccc2-c2ccccc2N(c2ccc(-c3ccc4c(c3)oc3ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3cccc4oc5ccccc5c34)cc2)c2ccc3c(c2)C2(c4ccccc4-c4ccccc42)c2ccccc2-3)cc1 ; c1ccc(-c2ccccc2-c2ccccc2-c2ccccc2N(c2ccc3c(c2)-c2ccccc2C32CCCC2)c2ccccc2-c2cccc3c2sc2ccccc23)cc1]

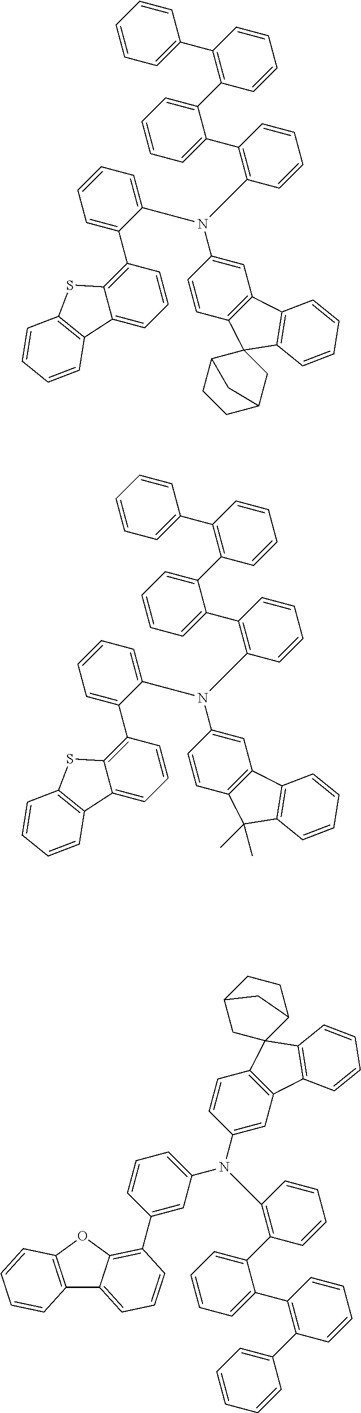 [SMILES: c1ccc(-c2ccccc2-c2ccccc2-c2ccccc2N(c2ccc3c(c2)-c2ccccc2C32CC3CCC2C3)c2ccccc2-c2cccc3c2sc2ccccc23)cc1 ; CC1(C)c2ccccc2-c2cc(N(c3ccccc3-c3ccccc3-c3ccccc3-c3ccccc3)c3ccccc3-c3cccc4c3sc3ccccc34)ccc21 ; c1ccc(-c2ccccc2-c2ccccc2-c2ccccc2N(c2cccc(-c3cccc4c3oc3ccccc34)c2)c2ccc3c(c2)-c2ccccc2C32CC3CCC2C3)cc1]

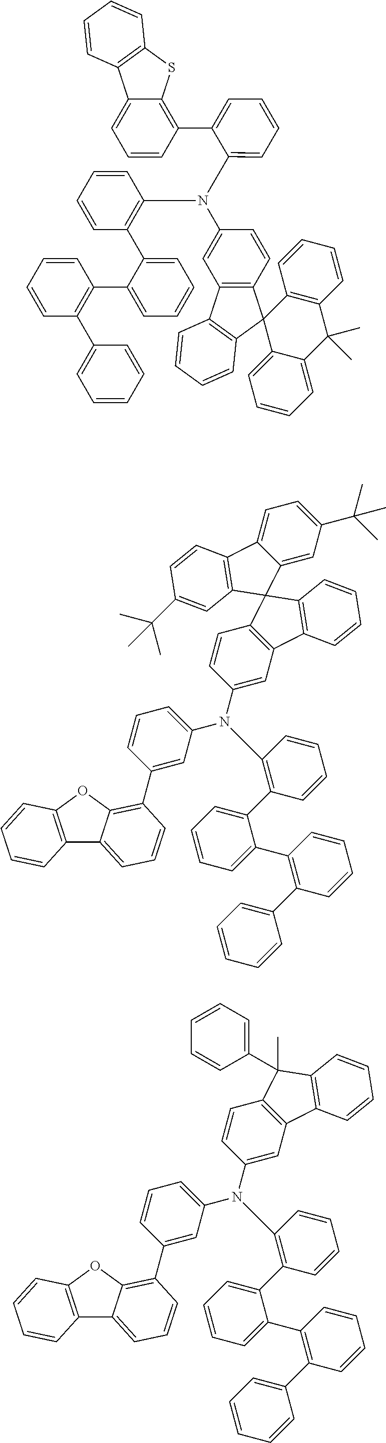

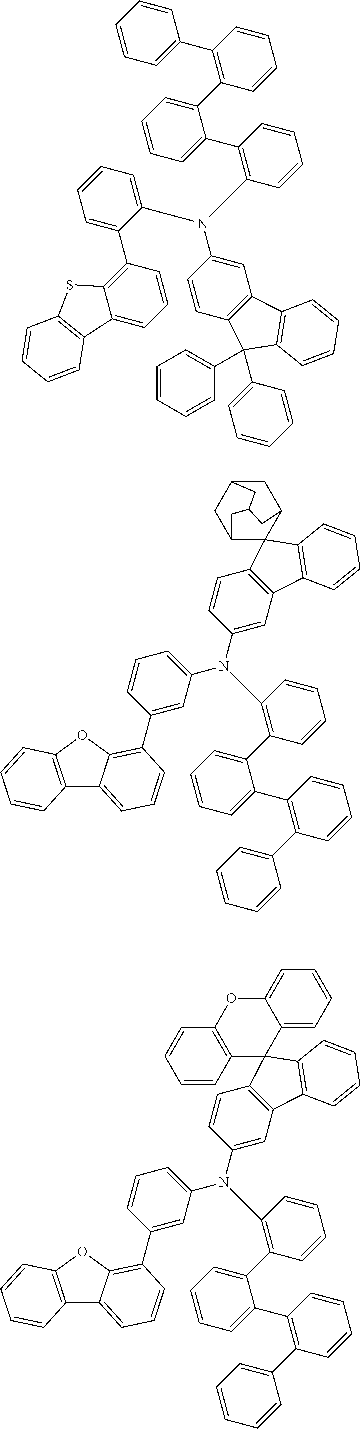

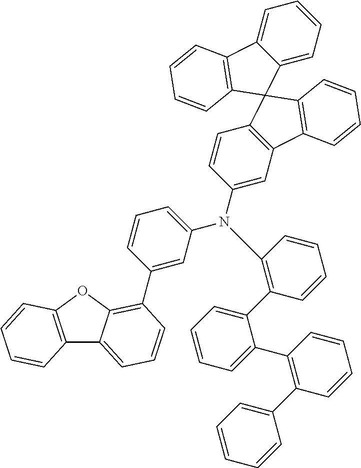 [SMILES: c1ccc(-c2ccccc2-c2ccccc2-c2ccccc2N(c2cccc(-c3cccc4c3oc3ccccc34)c2)c2ccc3c(c2)-c2ccccc2C32c3ccccc3-c3ccccc32)cc1]

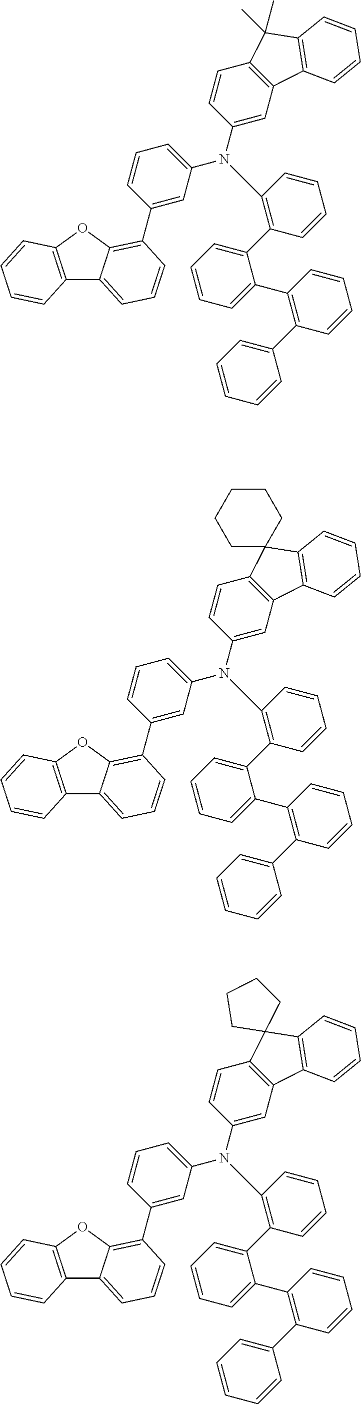 [SMILES: CC1(C)c2ccccc2-c2cc(N(c3cccc(-c4cccc5c4oc4ccccc45)c3)c3ccccc3-c3ccccc3-c3ccccc3-c3ccccc3)ccc21 ; c1ccc(-c2ccccc2-c2ccccc2-c2ccccc2N(c2cccc(-c3cccc4c3oc3ccccc34)c2)c2ccc3c(c2)-c2ccccc2C32CCCCC2)cc1 ; c1ccc(-c2ccccc2-c2ccccc2-c2ccccc2N(c2cccc(-c3cccc4c3oc3ccccc34)c2)c2ccc3c(c2)-c2ccccc2C32CCCC2)cc1]

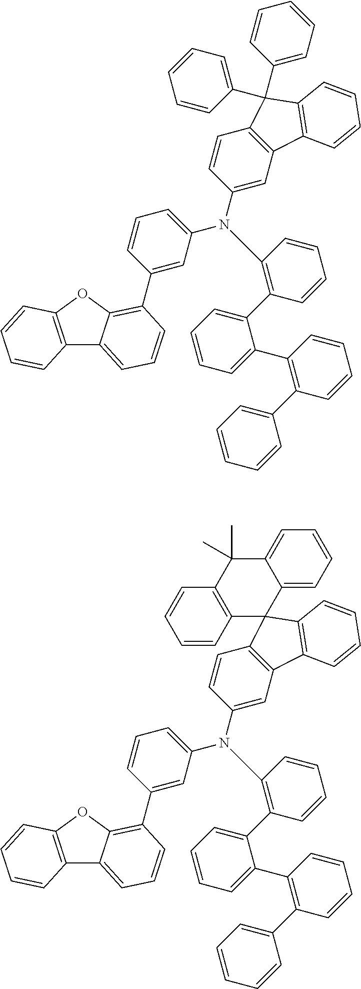 [SMILES: c1ccc(-c2ccccc2-c2ccccc2-c2ccccc2N(c2cccc(-c3cccc4c3oc3ccccc34)c2)c2ccc3c(c2)-c2ccccc2C3(c2ccccc2)c2ccccc2)cc1 ; CC1(C)c2ccccc2C2(c3ccccc3-c3cc(N(c4cccc(-c5cccc6c5oc5ccccc56)c4)c4ccccc4-c4ccccc4-c4ccccc4-c4ccccc4)ccc32)c2ccccc21]

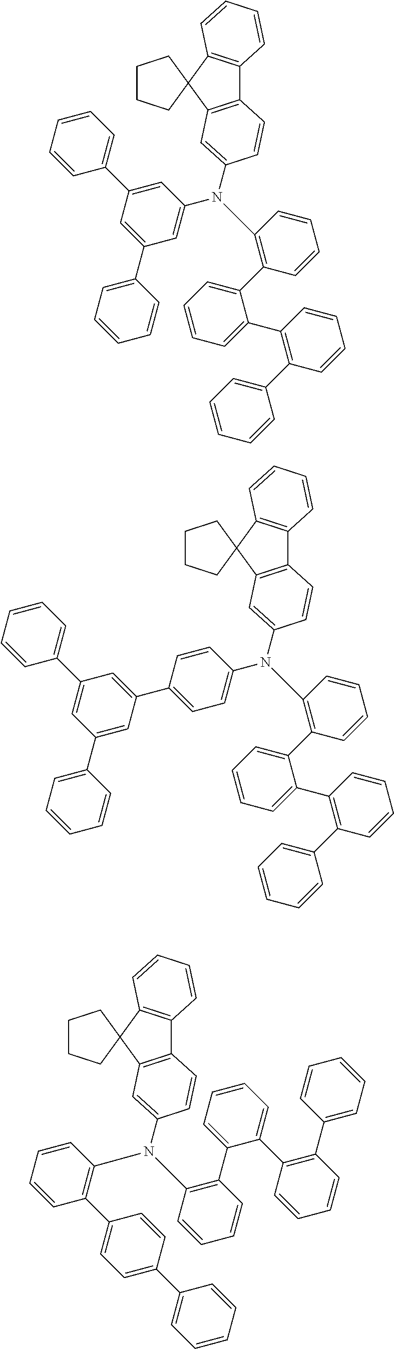

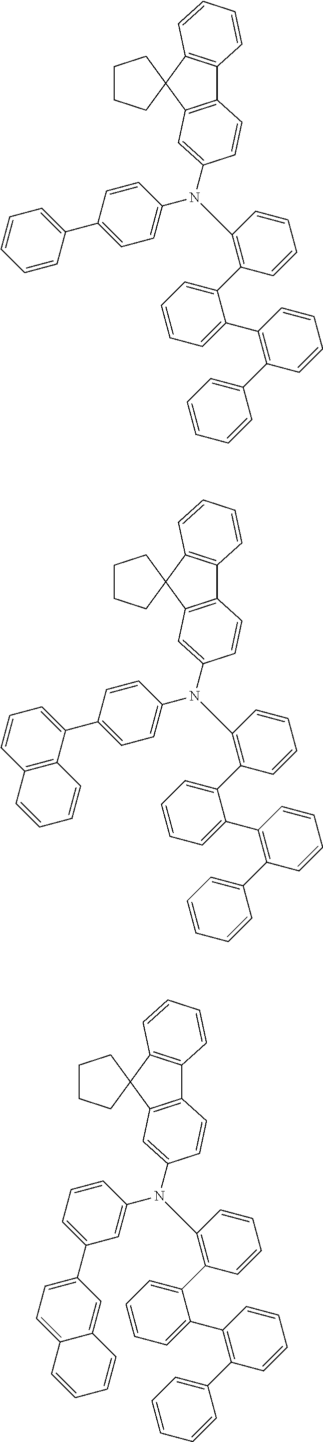 [SMILES: c1ccc(-c2ccc(N(c3ccc4c(c3)C3(CCCC3)c3ccccc3-4)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(CCCC2)c2ccccc2-3)cc1 ; c1ccc(-c2ccccc2-c2ccccc2-c2ccccc2N(c2cccc(-c3ccc4ccccc4c3)c2)c2ccc3c(c2)C2(CCCC2)c2ccccc2-3)cc1]

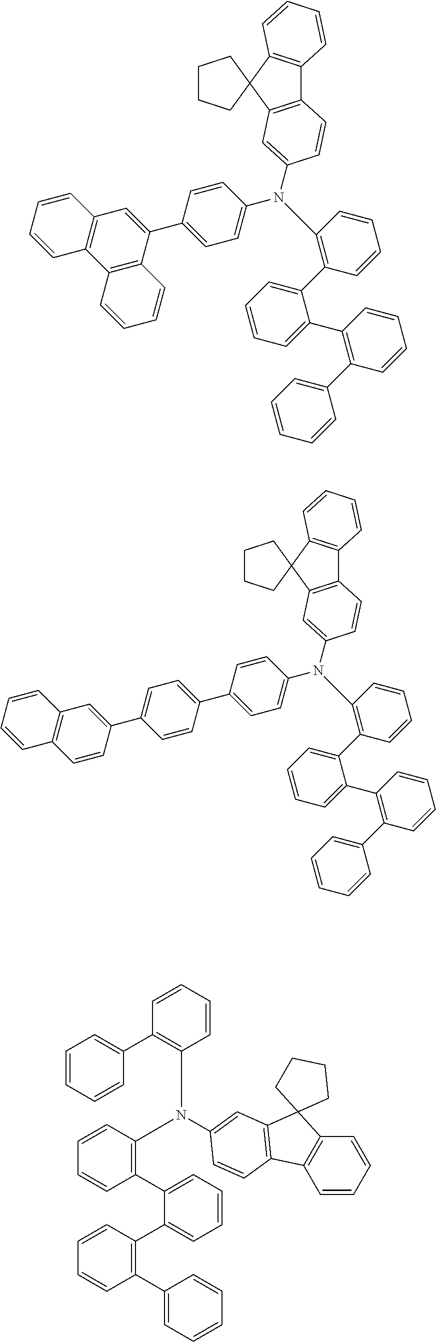 [SMILES: c1ccc(-c2ccccc2-c2ccccc2-c2ccccc2N(c2ccc(-c3cc4ccccc4c4ccccc34)cc2)c2ccc3c(c2)C2(CCCC2)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C2(CCCC2)c2ccccc2-3)cc1 ; c1ccc(-c2ccccc2-c2ccccc2-c2ccccc2N(c2ccc3c(c2)C2(CCCC2)c2ccccc2-3)c2ccccc2-c2ccccc2)cc1]

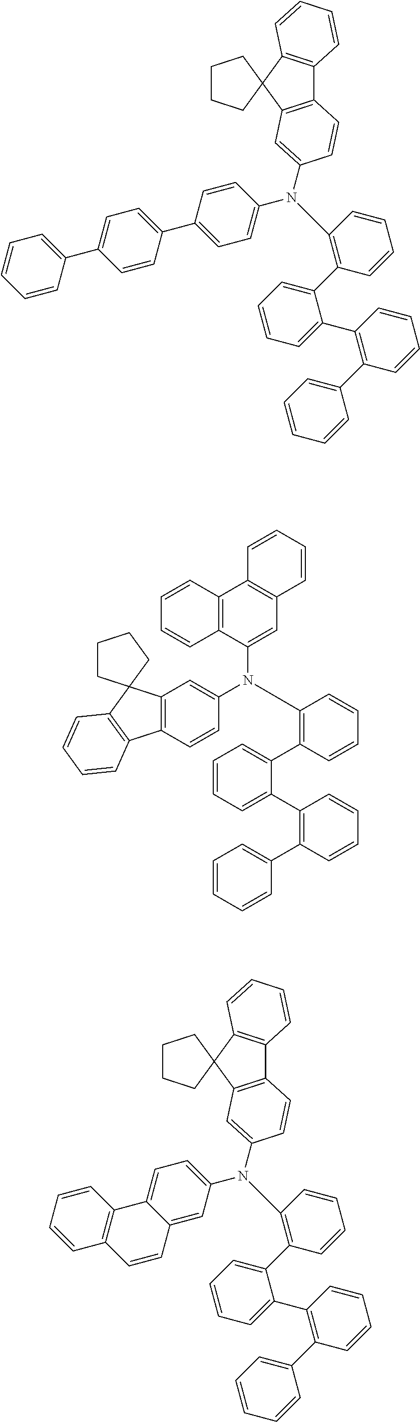 [SMILES: c1ccc(-c2ccc(-c3ccc(N(c4ccc5c(c4)C4(CCCC4)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(CCCC2)c2ccccc2-3)c2cc3ccccc3c3ccccc23)cc1 ; c1ccc(-c2ccccc2-c2ccccc2-c2ccccc2N(c2ccc3c(c2)C2(CCCC2)c2ccccc2-3)c2ccc3c(ccc4ccccc43)c2)cc1]

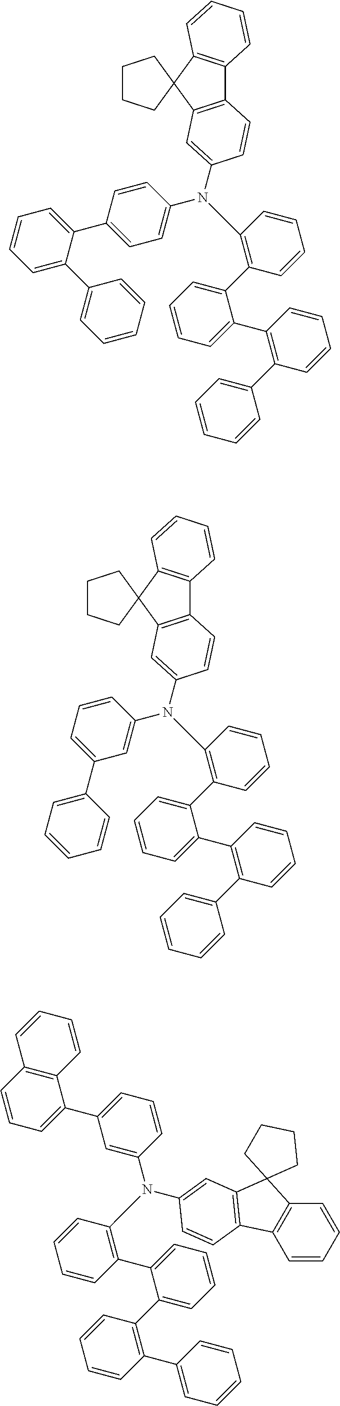 [SMILES: c1ccc(-c2ccccc2-c2ccc(N(c3ccc4c(c3)C3(CCCC3)c3ccccc3-4)c3ccccc3-c3ccccc3-c3ccccc3-c3ccccc3)cc2)cc1 ; c1ccc(-c2cccc(N(c3ccc4c(c3)C3(CCCC3)c3ccccc3-4)c3ccccc3-c3ccccc3-c3ccccc3-c3ccccc3)c2)cc1 ; c1ccc(-c2ccccc2-c2ccccc2-c2ccccc2N(c2cccc(-c3cccc4ccccc34)c2)c2ccc3c(c2)C2(CCCC2)c2ccccc2-3)cc1]

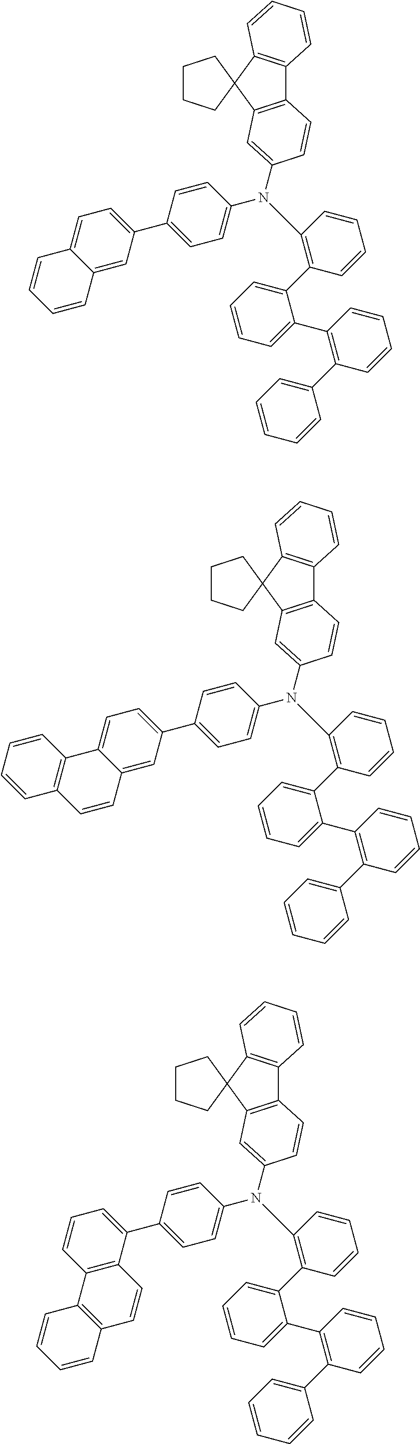 [SMILES: c1ccc(-c2ccccc2-c2ccccc2-c2ccccc2N(c2ccc(-c3ccc4ccccc4c3)cc2)c2ccc3c(c2)C2(CCCC2)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C2(CCCC2)c2ccccc2-3)cc1 ; c1ccc(-c2ccccc2-c2ccccc2-c2ccccc2N(c2ccc(-c3cccc4c3ccc3ccccc34)cc2)c2ccc3c(c2)C2(CCCC2)c2ccccc2-3)cc1]

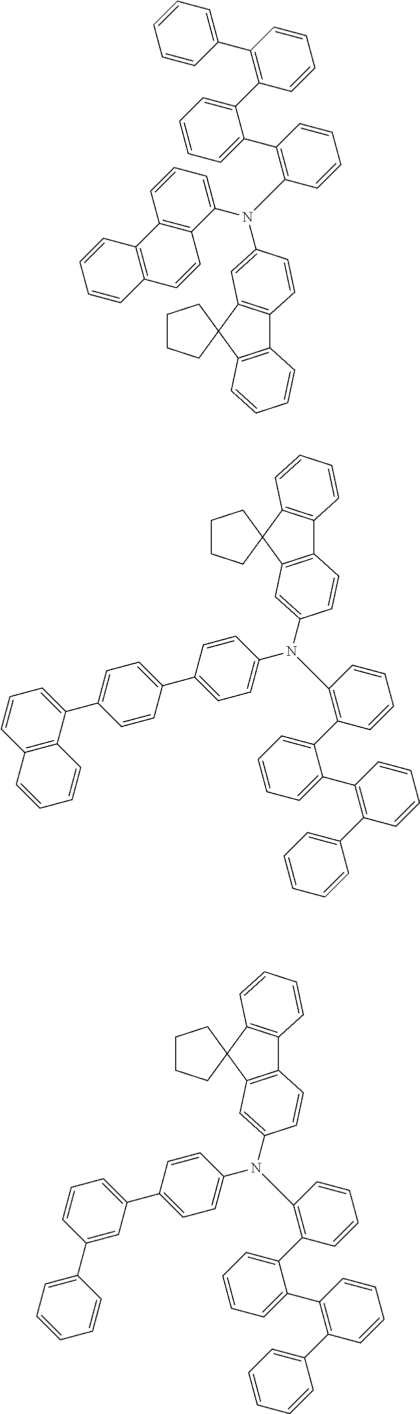 [SMILES: c1ccc(-c2ccccc2-c2ccccc2-c2ccccc2N(c2ccc3c(c2)C2(CCCC2)c2ccccc2-3)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C2(CCCC2)c2ccccc2-3)cc1 ; c1ccc(-c2cccc(-c3ccc(N(c4ccc5c(c4)C4(CCCC4)c4ccccc4-5)c4ccccc4-c4ccccc4-c4ccccc4-c4ccccc4)cc3)c2)cc1]

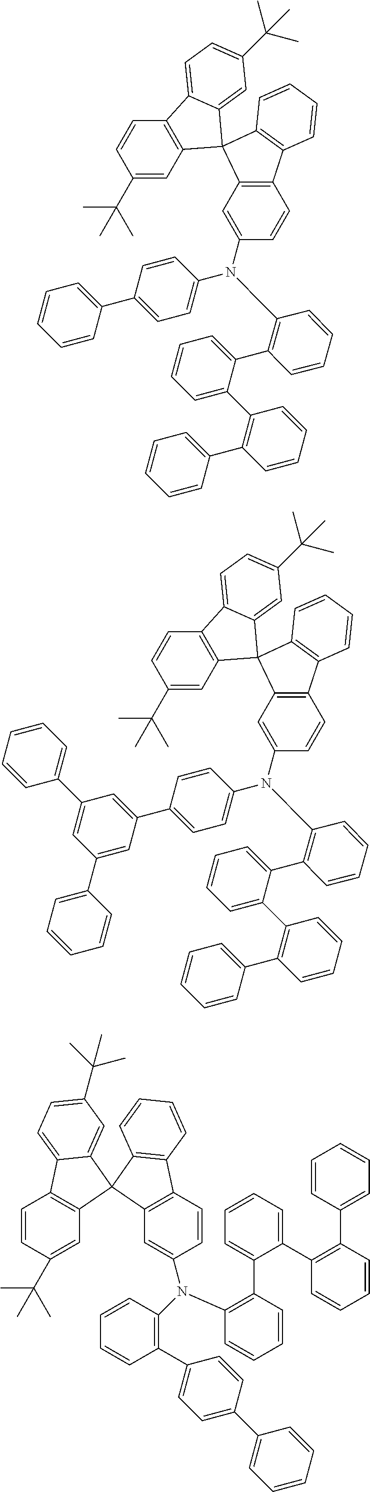 [SMILES: CC(C)(C)c1ccc2c(c1)C1(c3ccccc3-c3ccc(N(c4ccc(-c5ccccc5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cc(-c6ccccc6)cc(-c6ccccc6)c5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccccc4-c4ccc(-c5ccccc5)cc4)c4ccccc4-c4ccccc4-c4ccccc4-c4ccccc4)cc31)c1cc(C(C)(C)C)ccc1-2]

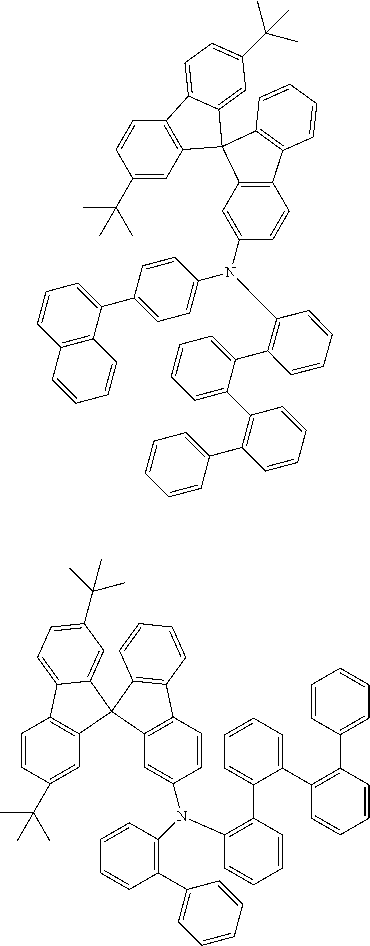 [SMILES: CC(C)(C)c1ccc2c(c1)C1(c3ccccc3-c3ccc(N(c4ccc(-c5cccc6ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccccc4-c4ccccc4)c4ccccc4-c4ccccc4-c4ccccc4-c4ccccc4)cc31)c1cc(C(C)(C)C)ccc1-2]

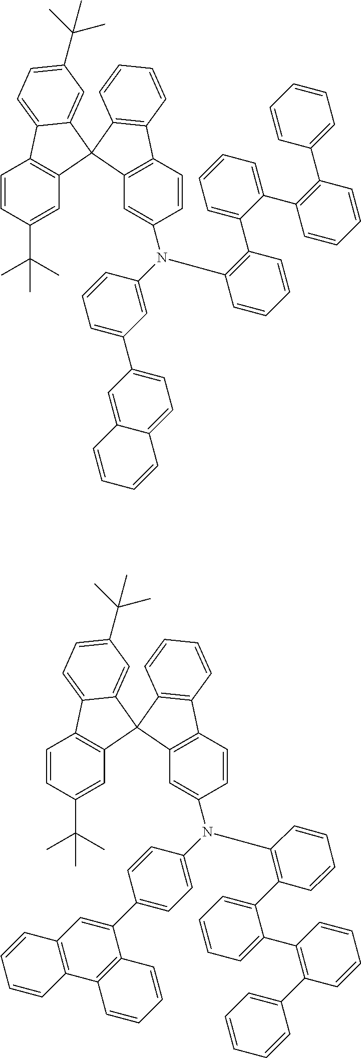 [SMILES: CC(C)(C)c1ccc2c(c1)C1(c3ccccc3-c3ccc(N(c4cccc(-c5ccc6ccccc6c5)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cc6ccccc6c6ccccc56)cc4)c4ccccc4-c4ccccc4-c4ccccc4-c4ccccc4)cc31)c1cc(C(C)(C)C)ccc1-2]

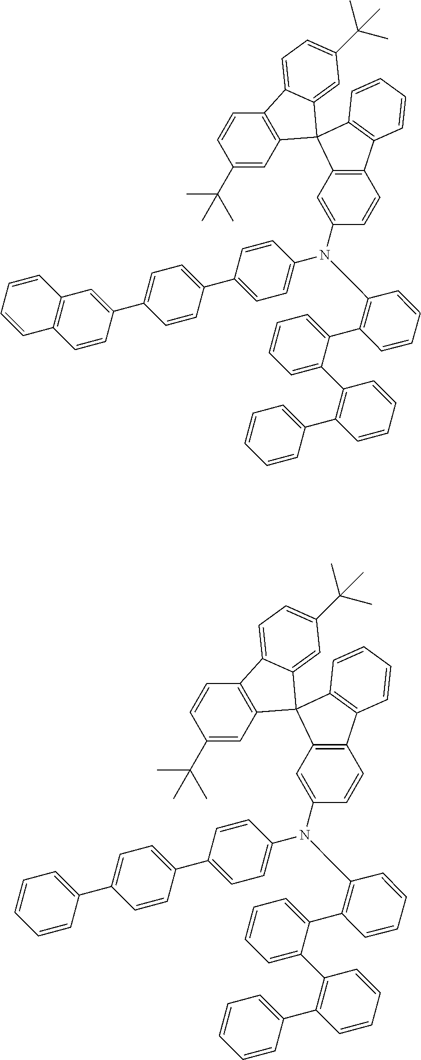 [SMILES: CC(C)(C)c1ccc2c(c1)C1(c3ccccc3-c3ccc(N(c4ccc(-c5ccc(-c6ccc7ccccc7c6)cc5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc(-c6ccccc6)cc5)cc4)c4ccccc4-c4ccccc4-c4ccccc4-c4ccccc4)cc31)c1cc(C(C)(C)C)ccc1-2]

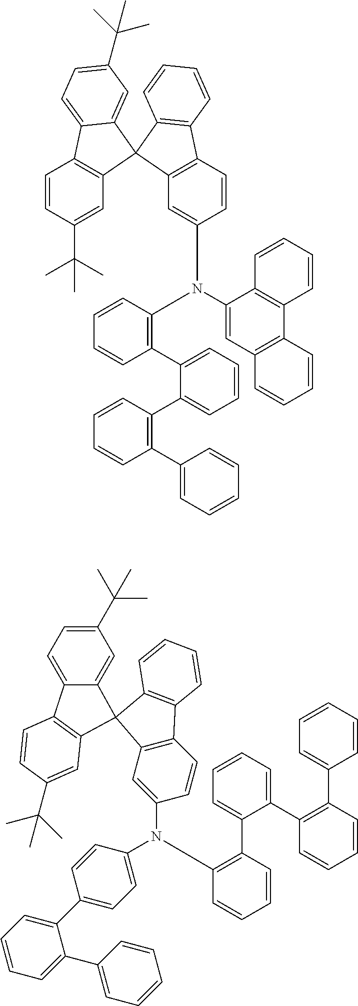 [SMILES: CC(C)(C)c1ccc2c(c1)C1(c3ccccc3-c3ccc(N(c4ccccc4-c4ccccc4-c4ccccc4-c4ccccc4)c4cc5ccccc5c5ccccc45)cc31)c1cc(C(C)(C)C)ccc1-2 ; CC(C)(C)c1ccc2c(c1)C1(c3ccccc3-c3ccc(N(c4ccc(-c5ccccc5-c5ccccc5)cc4)c4ccccc4-c4ccccc4-c4ccccc4-c4ccccc4)cc31)c1cc(C(C)(C)C)ccc1-2]

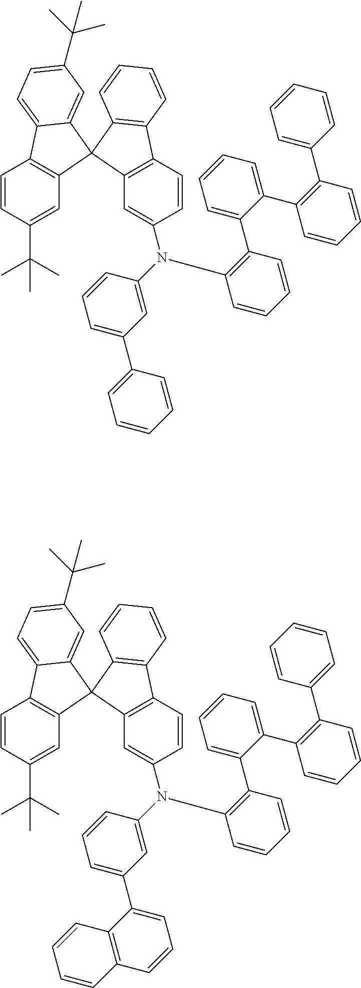 [SMILES: CC(C)(C)c1ccc2c(c1)C1(c3ccccc3-c3ccc(N(c4cccc(-c5ccccc5)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4cccc(-c5cccc6ccccc56)c4)c4ccccc4-c4ccccc4-c4ccccc4-c4ccccc4)cc31)c1cc(C(C)(C)C)ccc1-2]

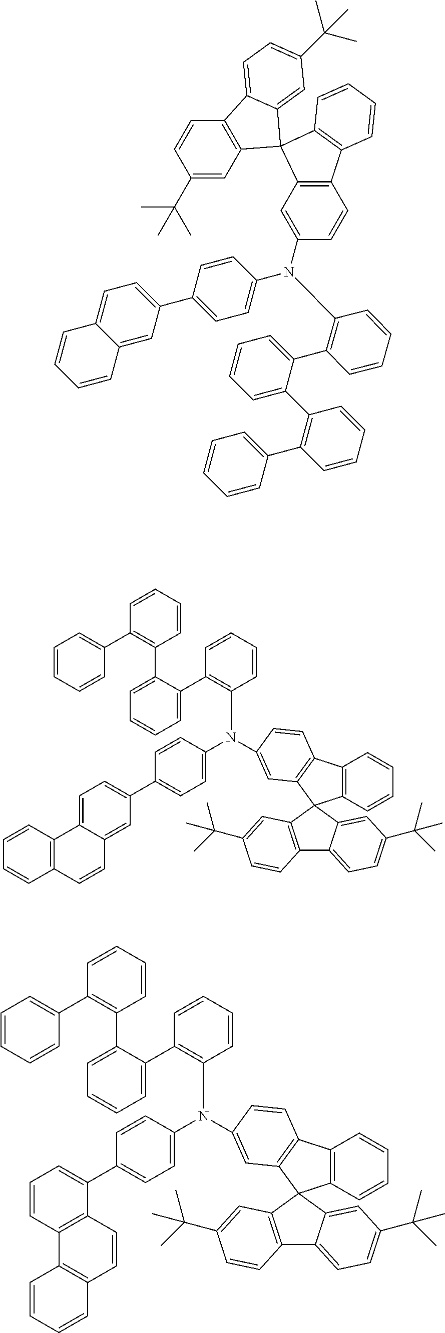 [SMILES: CC(C)(C)c1ccc2c(c1)C1(c3ccccc3-c3ccc(N(c4ccc(-c5ccc6ccccc6c5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6c(ccc7ccccc76)c5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cccc6c5ccc5ccccc56)cc4)c4ccccc4-c4ccccc4-c4ccccc4-c4ccccc4)cc31)c1cc(C(C)(C)C)ccc1-2]

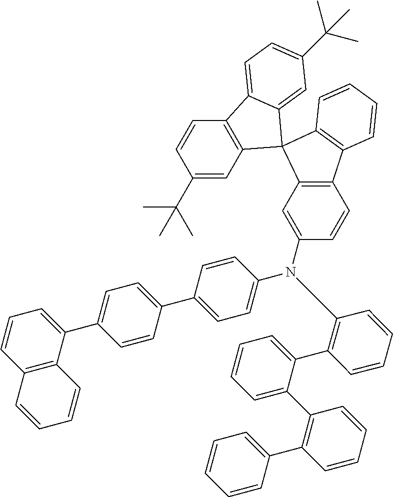 [SMILES: CC(C)(C)c1ccc2c(c1)C1(c3ccccc3-c3ccc(N(c4ccc(-c5ccc(-c6cccc7ccccc67)cc5)cc4)c4ccccc4-c4ccccc4-c4ccccc4-c4ccccc4)cc31)c1cc(C(C)(C)C)ccc1-2]

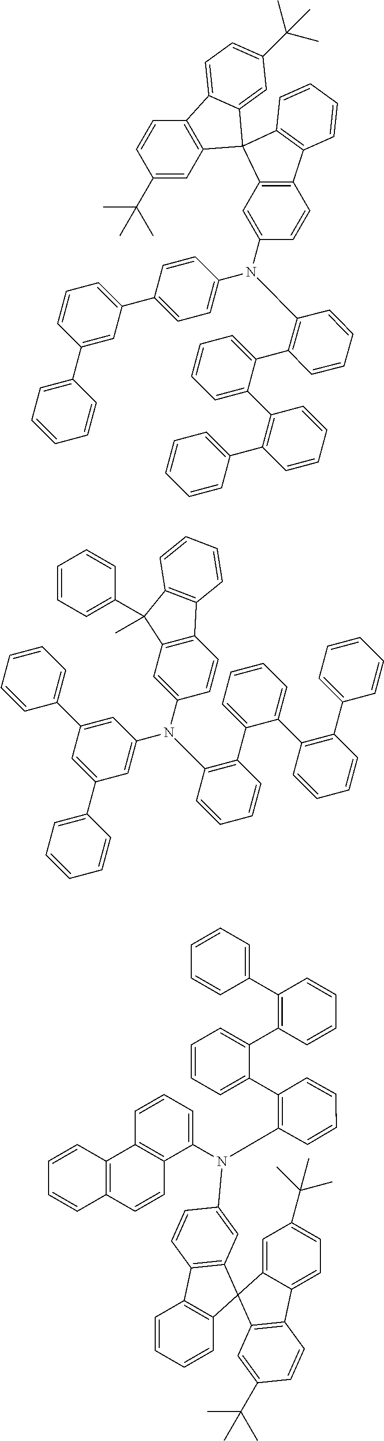

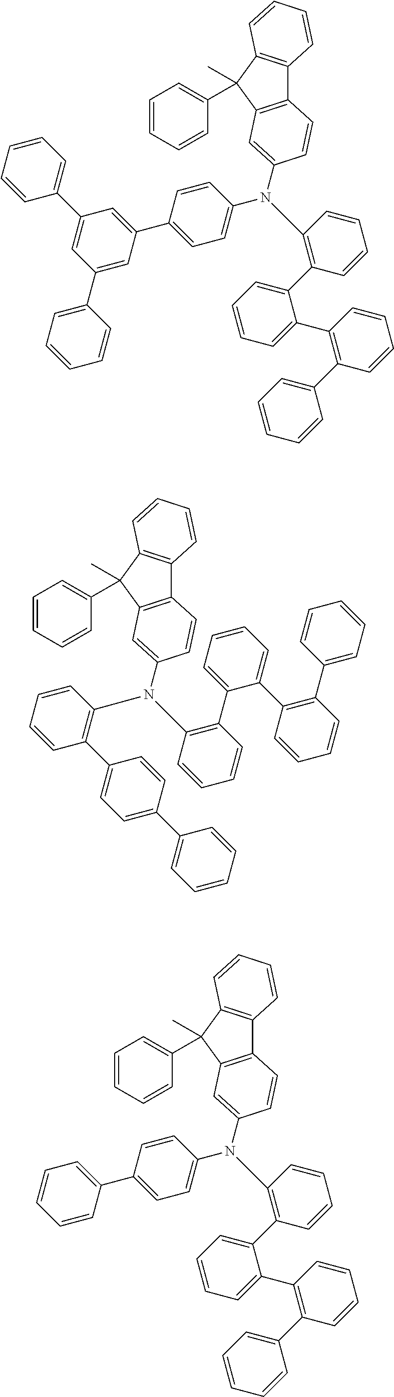 [SMILES: CC1(c2ccccc2)c2ccccc2-c2ccc(N(c3ccc(-c4cc(-c5ccccc5)cc(-c5ccccc5)c4)cc3)c3ccccc3-c3ccccc3-c3ccccc3-c3ccccc3)cc21 ; CC1(c2ccccc2)c2ccccc2-c2ccc(N(c3ccccc3-c3ccc(-c4ccccc4)cc3)c3ccccc3-c3ccccc3-c3ccccc3-c3ccccc3)cc21 ; CC1(c2ccccc2)c2ccccc2-c2ccc(N(c3ccc(-c4ccccc4)cc3)c3ccccc3-c3ccccc3-c3ccccc3-c3ccccc3)cc21]

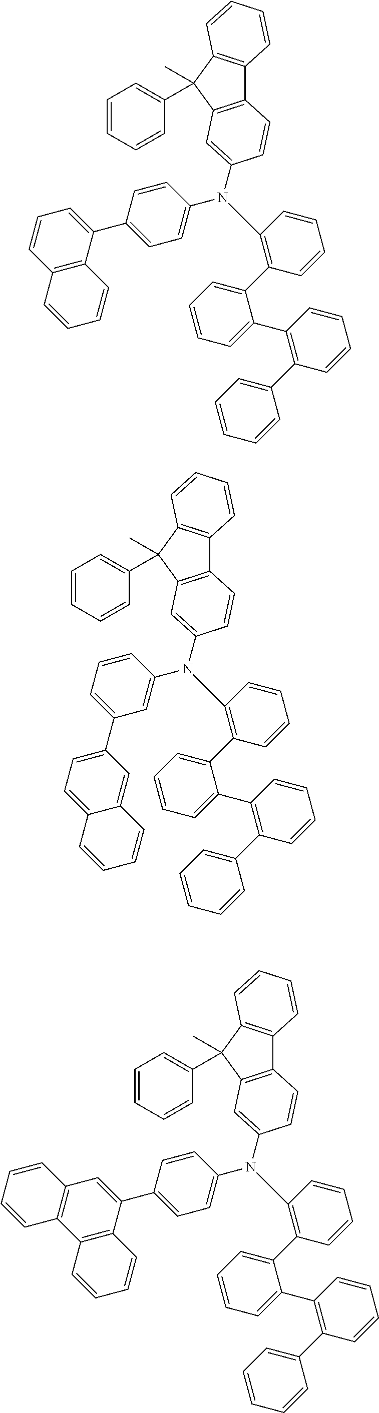 [SMILES: CC1(c2ccccc2)c2ccccc2-c2ccc(N(c3ccc(-c4cccc5ccccc45)cc3)c3ccccc3-c3ccccc3-c3ccccc3-c3ccccc3)cc21 ; CC1(c2ccccc2)c2ccccc2-c2ccc(N(c3cccc(-c4ccc5ccccc5c4)c3)c3ccccc3-c3ccccc3-c3ccccc3-c3ccccc3)cc21 ; CC1(c2ccccc2)c2ccccc2-c2ccc(N(c3ccc(-c4cc5ccccc5c5ccccc45)cc3)c3ccccc3-c3ccccc3-c3ccccc3-c3ccccc3)cc21]

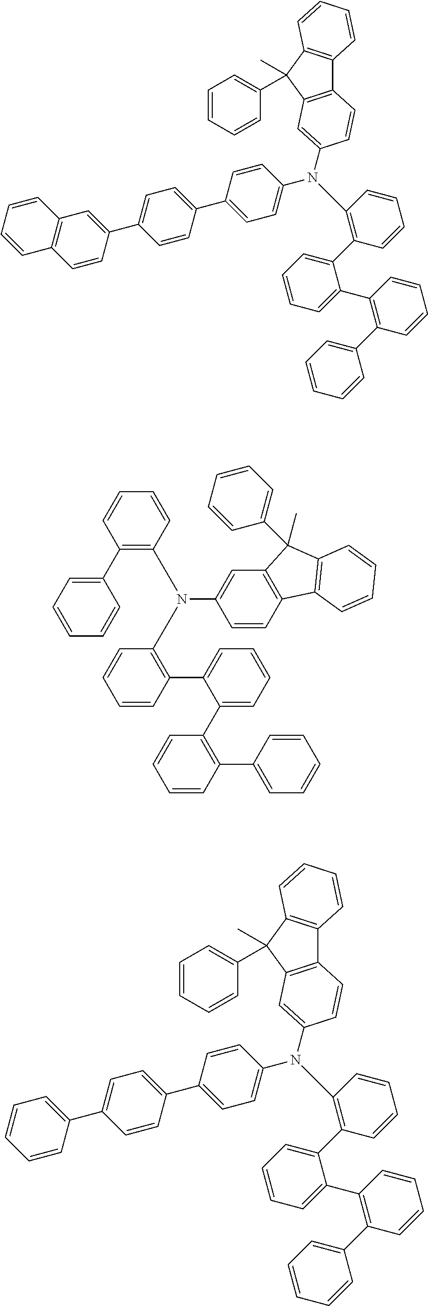 [SMILES: CC1(c2ccccc2)c2ccccc2-c2ccc(N(c3ccc(-c4ccc(-c5ccc6ccccc6c5)cc4)cc3)c3ccccc3-c3ccccc3-c3ccccc3-c3ccccc3)cc21 ; CC1(c2ccccc2)c2ccccc2-c2ccc(N(c3ccccc3-c3ccccc3)c3ccccc3-c3ccccc3-c3ccccc3-c3ccccc3)cc21 ; CC1(c2ccccc2)c2ccccc2-c2ccc(N(c3ccc(-c4ccc(-c5ccccc5)cc4)cc3)c3ccccc3-c3ccccc3-c3ccccc3-c3ccccc3)cc21]

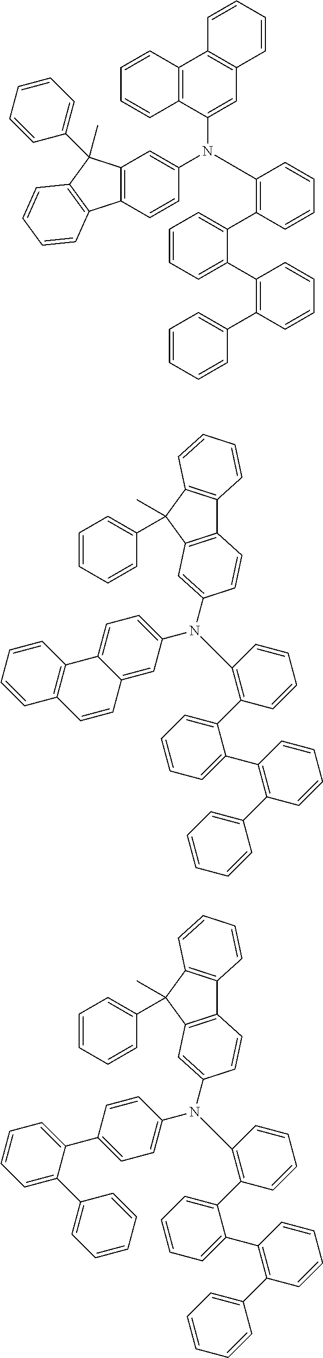

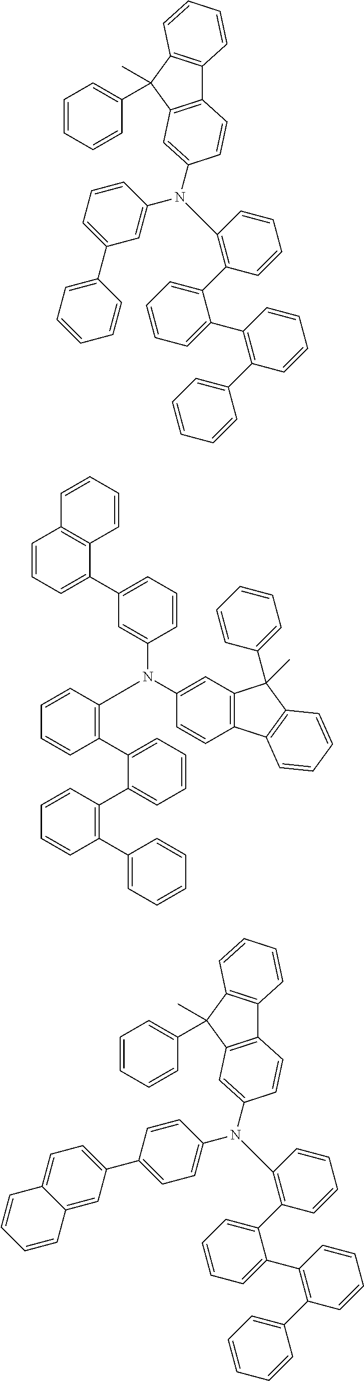 [SMILES: CC1(c2ccccc2)c2ccccc2-c2ccc(N(c3cccc(-c4ccccc4)c3)c3ccccc3-c3ccccc3-c3ccccc3-c3ccccc3)cc21 ; CC1(c2ccccc2)c2ccccc2-c2ccc(N(c3cccc(-c4cccc5ccccc45)c3)c3ccccc3-c3ccccc3-c3ccccc3-c3ccccc3)cc21 ; CC1(c2ccccc2)c2ccccc2-c2ccc(N(c3ccc(-c4ccc5ccccc5c4)cc3)c3ccccc3-c3ccccc3-c3ccccc3-c3ccccc3)cc21]

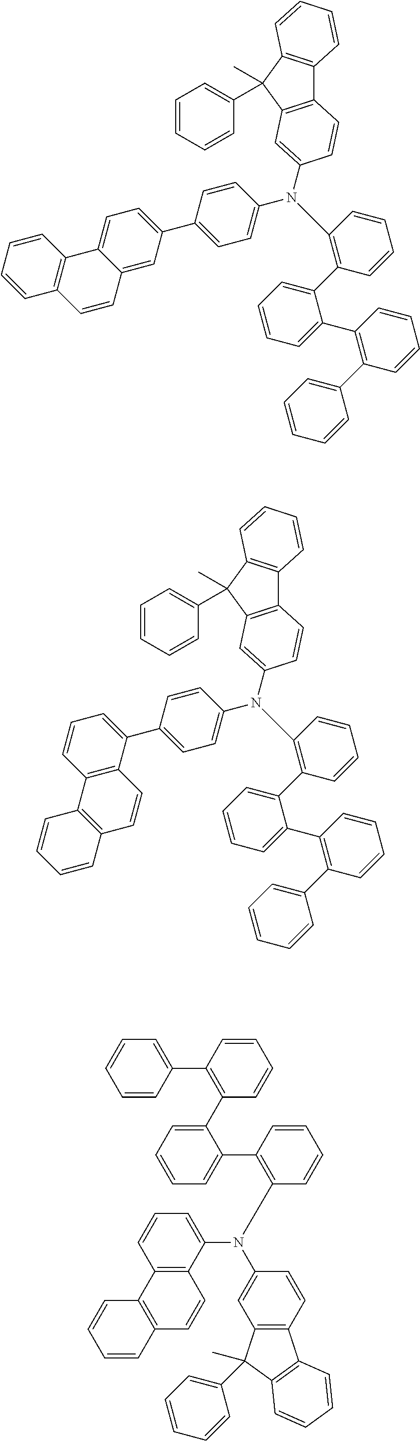 [SMILES: CC1(c2ccccc2)c2ccccc2-c2ccc(N(c3ccc(-c4ccc5c(ccc6ccccc65)c4)cc3)c3ccccc3-c3ccccc3-c3ccccc3-c3ccccc3)cc21 ; CC1(c2ccccc2)c2ccccc2-c2ccc(N(c3ccc(-c4cccc5c4ccc4ccccc45)cc3)c3ccccc3-c3ccccc3-c3ccccc3-c3ccccc3)cc21 ; CC1(c2ccccc2)c2ccccc2-c2ccc(N(c3ccccc3-c3ccccc3-c3ccccc3-c3ccccc3)c3cccc4c3ccc3ccccc34)cc21]

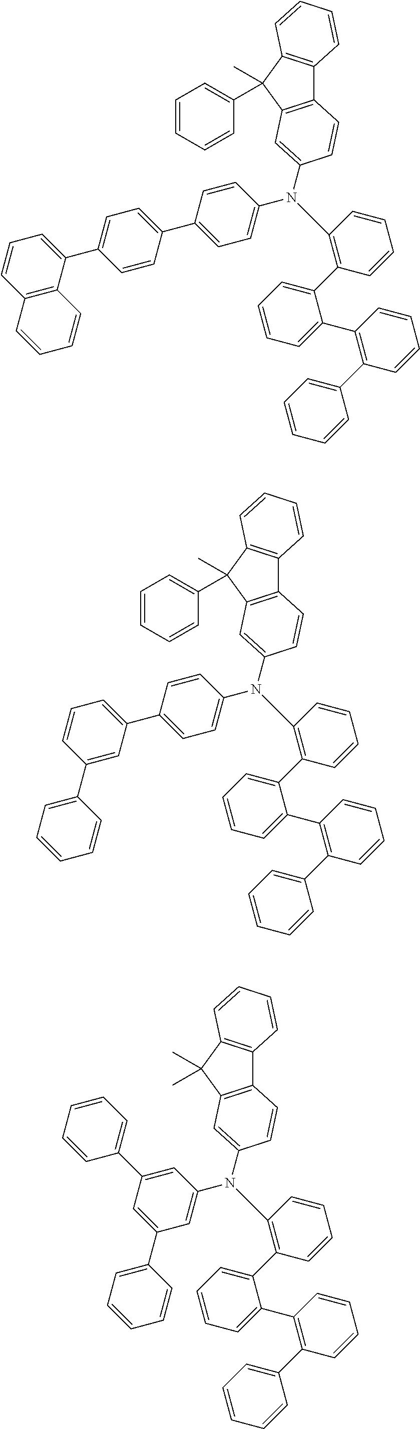 [SMILES: CC1(c2ccccc2)c2ccccc2-c2ccc(N(c3ccc(-c4ccc(-c5cccc6ccccc56)cc4)cc3)c3ccccc3-c3ccccc3-c3ccccc3-c3ccccc3)cc21 ; CC1(c2ccccc2)c2ccccc2-c2ccc(N(c3ccc(-c4cccc(-c5ccccc5)c4)cc3)c3ccccc3-c3ccccc3-c3ccccc3-c3ccccc3)cc21 ; CC1(C)c2ccccc2-c2ccc(N(c3cc(-c4ccccc4)cc(-c4ccccc4)c3)c3ccccc3-c3ccccc3-c3ccccc3-c3ccccc3)cc21]

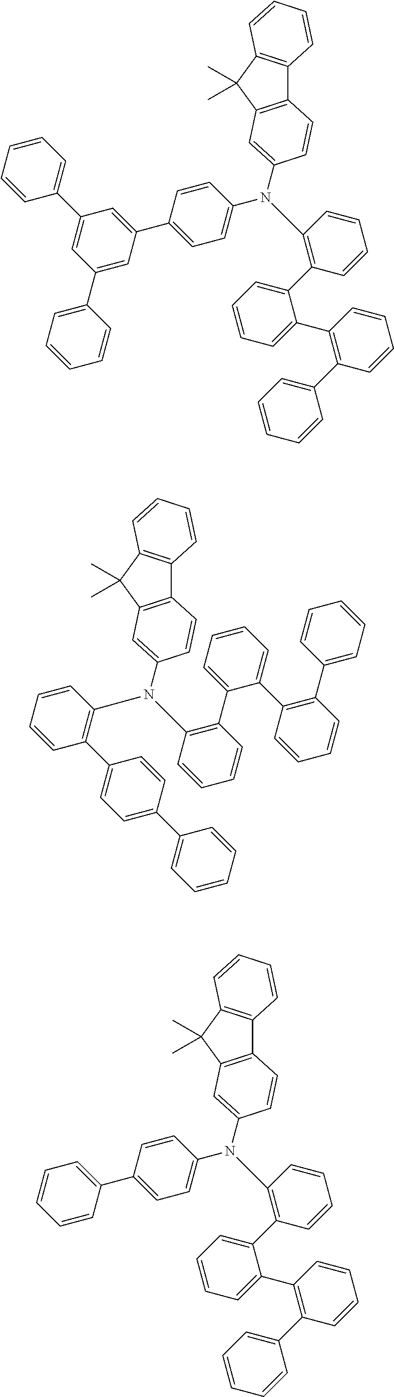 [SMILES: CC1(C)c2ccccc2-c2ccc(N(c3ccc(-c4cc(-c5ccccc5)cc(-c5ccccc5)c4)cc3)c3ccccc3-c3ccccc3-c3ccccc3-c3ccccc3)cc21 ; CC1(C)c2ccccc2-c2ccc(N(c3ccccc3-c3ccc(-c4ccccc4)cc3)c3ccccc3-c3ccccc3-c3ccccc3-c3ccccc3)cc21 ; CC1(C)c2ccccc2-c2ccc(N(c3ccc(-c4ccccc4)cc3)c3ccccc3-c3ccccc3-c3ccccc3-c3ccccc3)cc21]

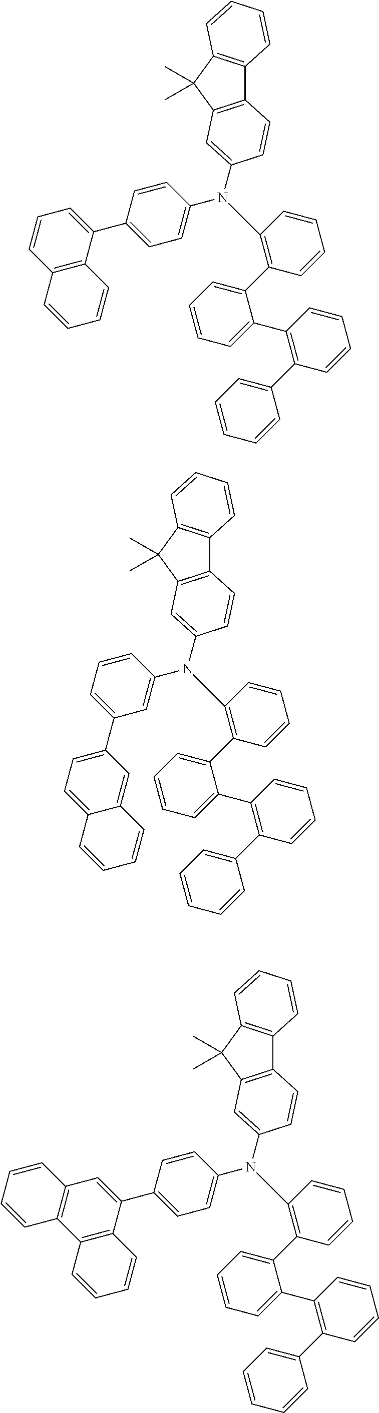 [SMILES: CC1(C)c2ccccc2-c2ccc(N(c3ccc(-c4cccc5ccccc45)cc3)c3ccccc3-c3ccccc3-c3ccccc3-c3ccccc3)cc21 ; CC1(C)c2ccccc2-c2ccc(N(c3cccc(-c4ccc5ccccc5c4)c3)c3ccccc3-c3ccccc3-c3ccccc3-c3ccccc3)cc21 ; CC1(C)c2ccccc2-c2ccc(N(c3ccc(-c4cc5ccccc5c5ccccc45)cc3)c3ccccc3-c3ccccc3-c3ccccc3-c3ccccc3)cc21]

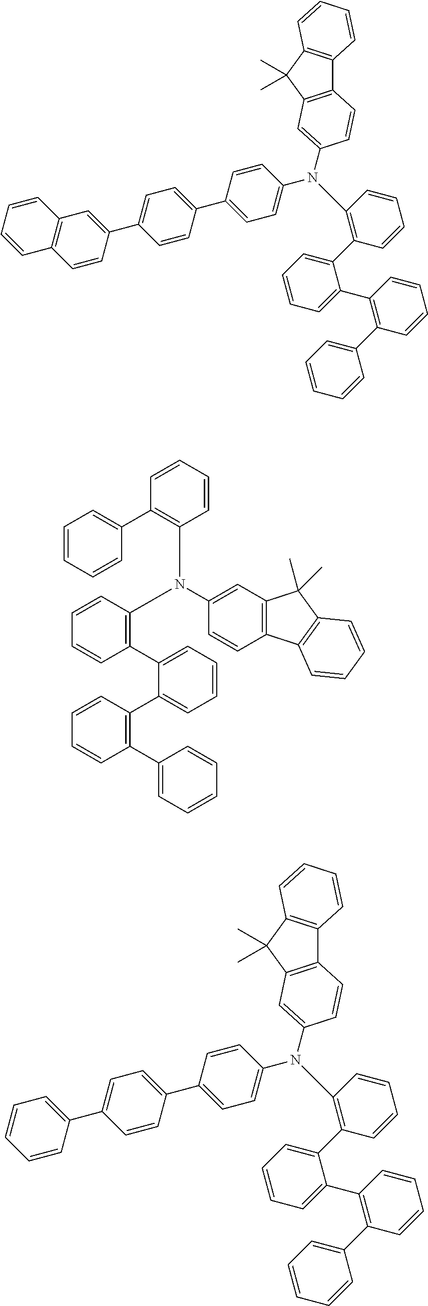 [SMILES: CC1(C)c2ccccc2-c2ccc(N(c3ccc(-c4ccc(-c5ccc6ccccc6c5)cc4)cc3)c3ccccc3-c3ccccc3-c3ccccc3-c3ccccc3)cc21 ; CC1(C)c2ccccc2-c2ccc(N(c3ccccc3-c3ccccc3)c3ccccc3-c3ccccc3-c3ccccc3-c3ccccc3)cc21 ; CC1(C)c2ccccc2-c2ccc(N(c3ccc(-c4ccc(-c5ccccc5)cc4)cc3)c3ccccc3-c3ccccc3-c3ccccc3-c3ccccc3)cc21]

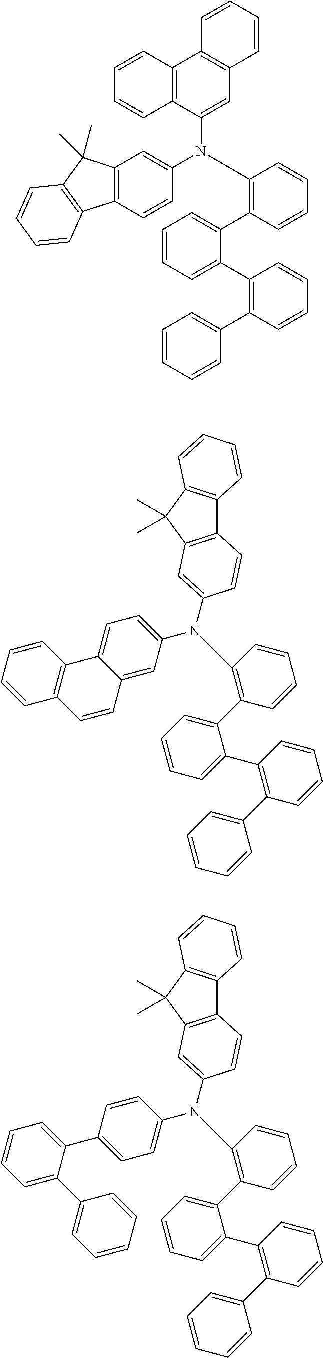

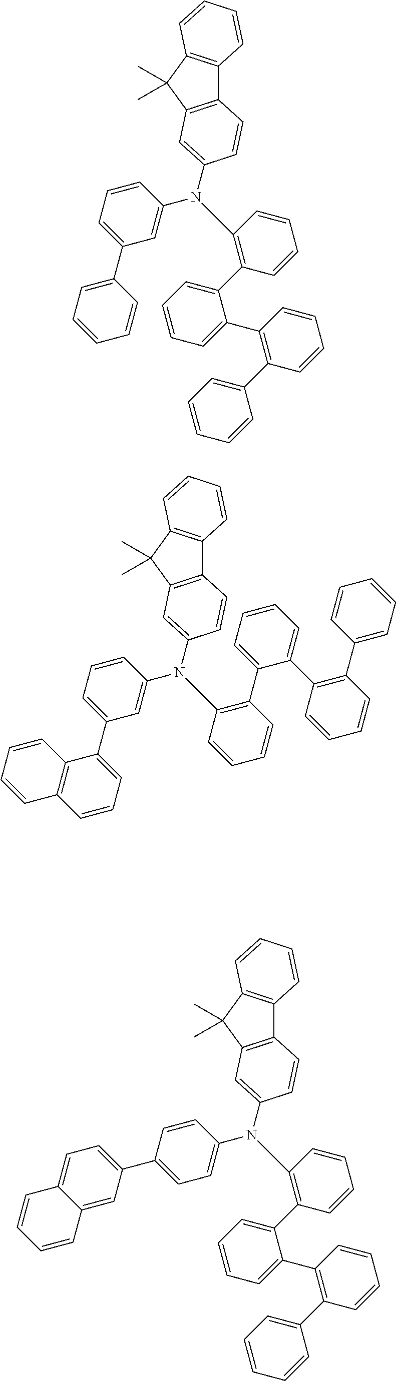

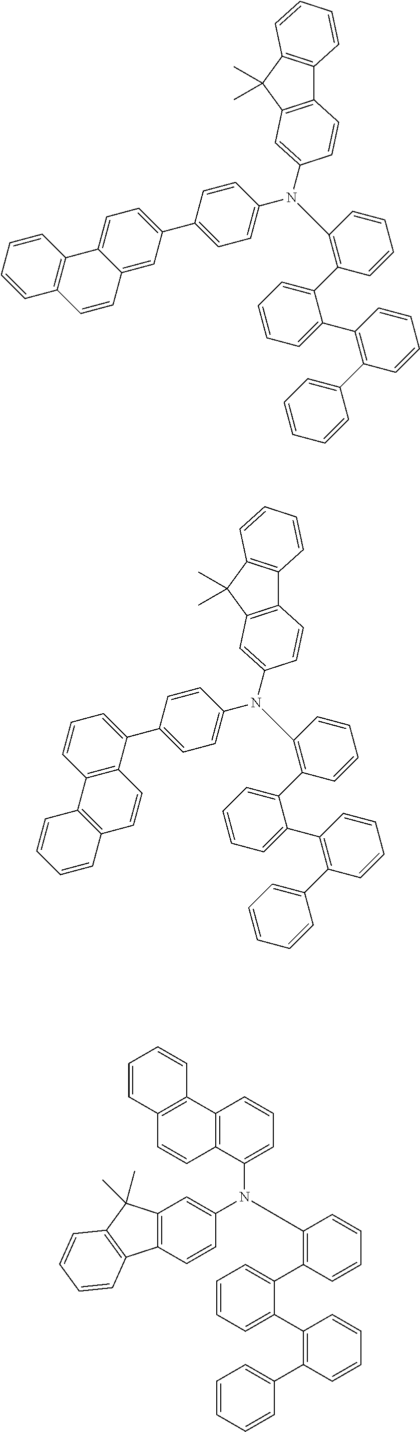 [SMILES: CC1(C)c2ccccc2-c2ccc(N(c3ccc(-c4ccc5c(ccc6ccccc65)c4)cc3)c3ccccc3-c3ccccc3-c3ccccc3-c3ccccc3)cc21 ; CC1(C)c2ccccc2-c2ccc(N(c3ccc(-c4cccc5c4ccc4ccccc45)cc3)c3ccccc3-c3ccccc3-c3ccccc3-c3ccccc3)cc21 ; CC1(C)c2ccccc2-c2ccc(N(c3ccccc3-c3ccccc3-c3ccccc3-c3ccccc3)c3cccc4c3ccc3ccccc34)cc21]

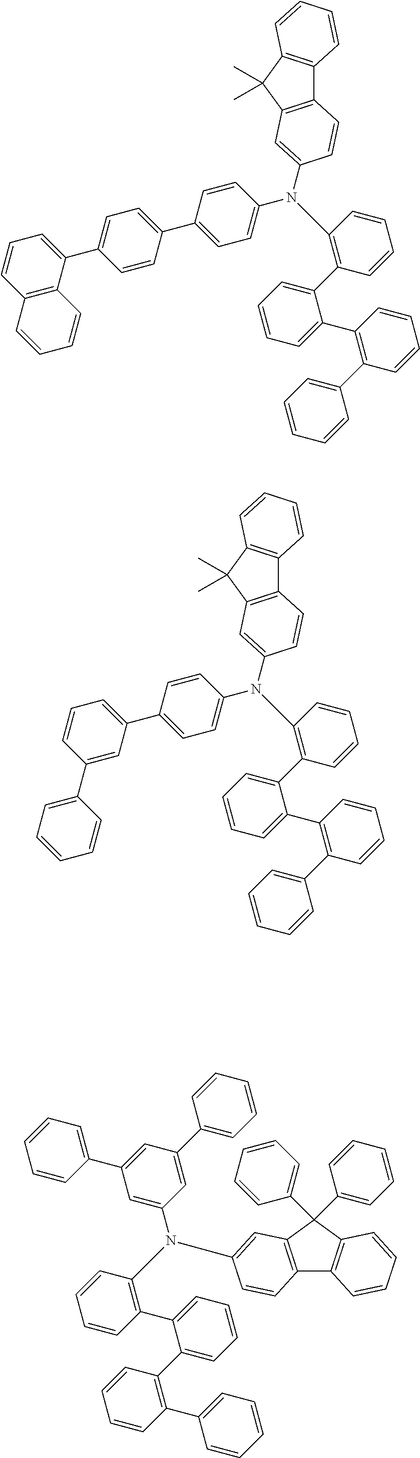 [SMILES: CC1(C)c2ccccc2-c2ccc(N(c3ccc(-c4ccc(-c5cccc6ccccc56)cc4)cc3)c3ccccc3-c3ccccc3-c3ccccc3-c3ccccc3)cc21 ; CC1(C)c2ccccc2-c2ccc(N(c3ccc(-c4cccc(-c5ccccc5)c4)cc3)c3ccccc3-c3ccccc3-c3ccccc3-c3ccccc3)cc21 ; c1ccc(-c2cc(-c3ccccc3)cc(N(c3ccc4c(c3)C(c3ccccc3)(c3ccccc3)c3ccccc3-4)c3ccccc3-c3ccccc3-c3ccccc3-c3ccccc3)c2)cc1]

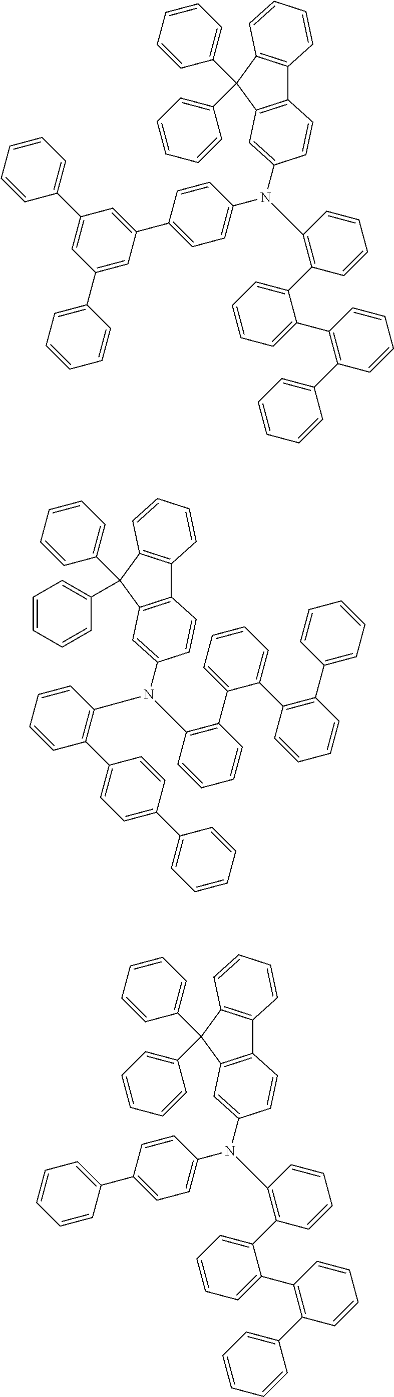 [SMILES: c1ccc(-c2cc(-c3ccccc3)cc(-c3ccc(N(c4ccc5c(c4)C(c4ccccc4)(c4ccccc4)c4ccccc4-5)c4ccccc4-c4ccccc4-c4ccccc4-c4ccccc4)cc3)c2)cc1 ; c1ccc(-c2ccc(-c3ccccc3N(c3ccc4c(c3)C(c3ccccc3)(c3ccccc3)c3ccccc3-4)c3ccccc3-c3ccccc3-c3ccccc3-c3ccccc3)cc2)cc1 ; c1ccc(-c2ccc(N(c3ccc4c(c3)C(c3ccccc3)(c3ccccc3)c3ccccc3-4)c3ccccc3-c3ccccc3-c3ccccc3-c3ccccc3)cc2)cc1]

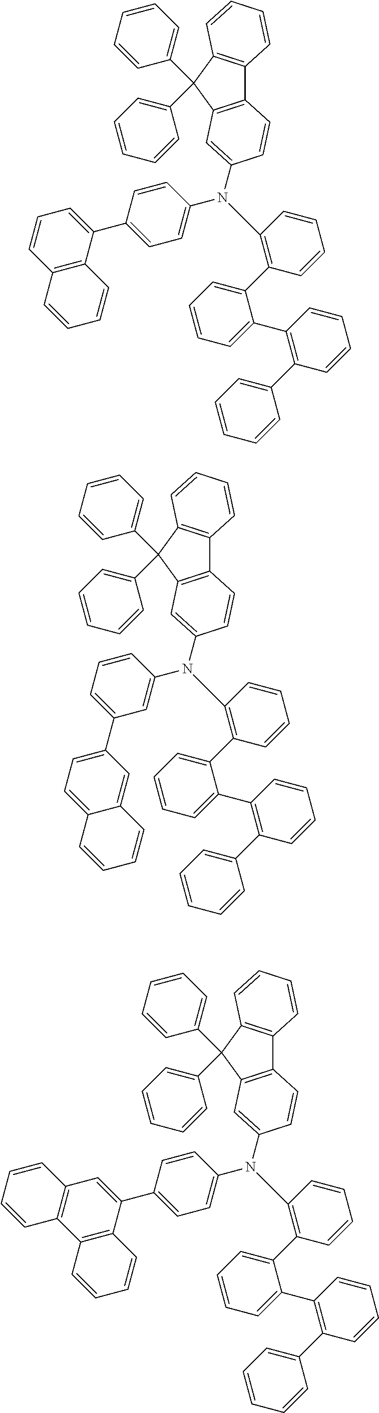 [SMILES: c1ccc(-c2ccccc2-c2ccccc2-c2ccccc2N(c2ccc(-c3cccc4ccccc34)cc2)c2ccc3c(c2)C(c2ccccc2)(c2ccccc2)c2ccccc2-3)cc1 ; c1ccc(-c2ccccc2-c2ccccc2-c2ccccc2N(c2cccc(-c3ccc4ccccc4c3)c2)c2ccc3c(c2)C(c2ccccc2)(c2ccccc2)c2ccccc2-3)cc1 ; c1ccc(-c2ccccc2-c2ccccc2-c2ccccc2N(c2ccc(-c3cc4ccccc4c4ccccc34)cc2)c2ccc3c(c2)C(c2ccccc2)(c2ccccc2)c2ccccc2-3)cc1]

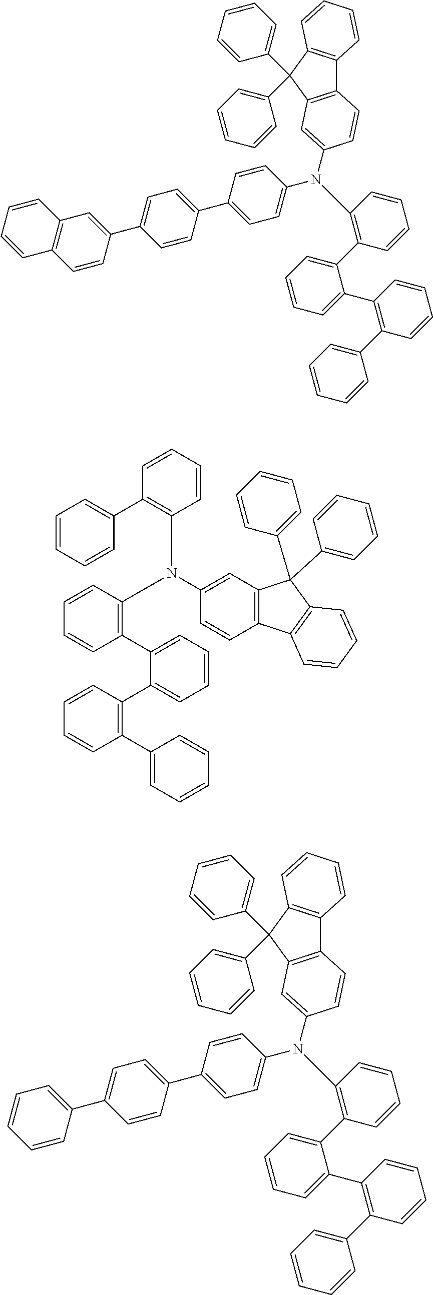 [SMILES: c1ccc(-c2ccccc2-c2ccccc2-c2ccccc2N(c2ccc(-c3ccc(-c4ccc5ccccc5c4)cc3)cc2)c2ccc3c(c2)C(c2ccccc2)(c2ccccc2)c2ccccc2-3)cc1 ; c1ccc(-c2ccccc2-c2ccccc2-c2ccccc2N(c2ccc3c(c2)C(c2ccccc2)(c2ccccc2)c2ccccc2-3)c2ccccc2-c2ccccc2)cc1 ; c1ccc(-c2ccc(-c3ccc(N(c4ccc5c(c4)C(c4ccccc4)(c4ccccc4)c4ccccc4-5)c4ccccc4-c4ccccc4-c4ccccc4-c4ccccc4)cc3)cc2)cc1]

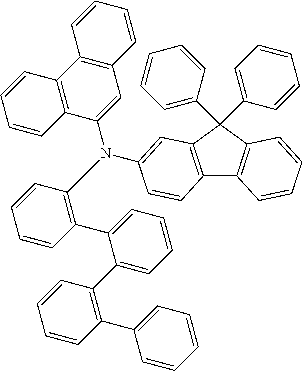 [SMILES: c1ccc(-c2ccccc2-c2ccccc2-c2ccccc2N(c2ccc3c(c2)C(c2ccccc2)(c2ccccc2)c2ccccc2-3)c2cc3ccccc3c3ccccc23)cc1]

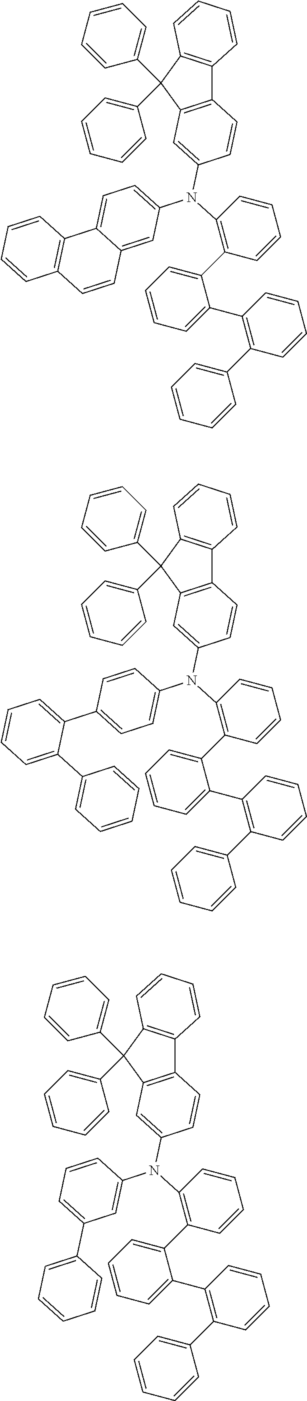 [SMILES: c1ccc(-c2ccccc2-c2ccccc2-c2ccccc2N(c2ccc3c(c2)C(c2ccccc2)(c2ccccc2)c2ccccc2-3)c2ccc3c(ccc4ccccc43)c2)cc1 ; c1ccc(-c2ccccc2-c2ccc(N(c3ccc4c(c3)C(c3ccccc3)(c3ccccc3)c3ccccc3-4)c3ccccc3-c3ccccc3-c3ccccc3-c3ccccc3)cc2)cc1 ; c1ccc(-c2cccc(N(c3ccc4c(c3)C(c3ccccc3)(c3ccccc3)c3ccccc3-4)c3ccccc3-c3ccccc3-c3ccccc3-c3ccccc3)c2)cc1]

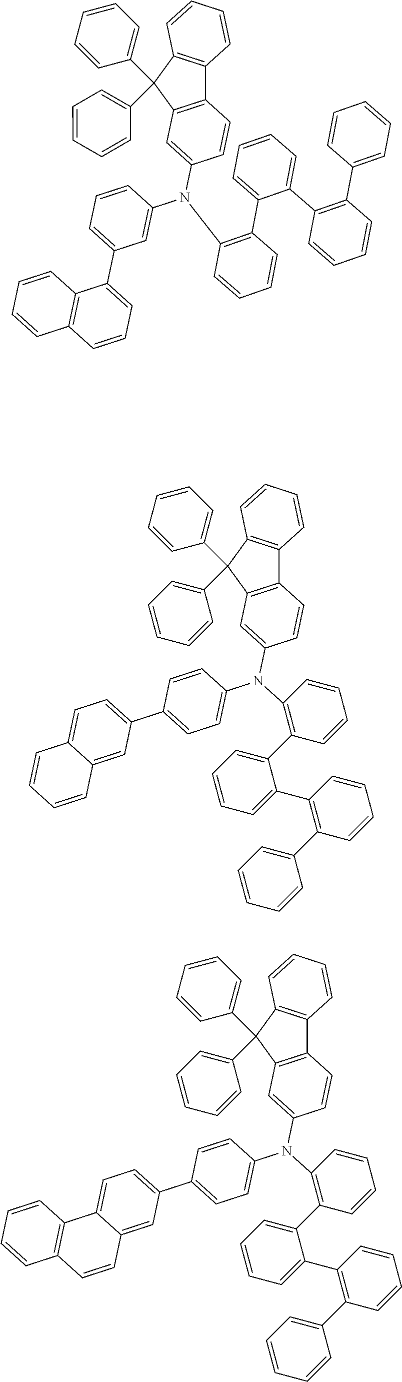

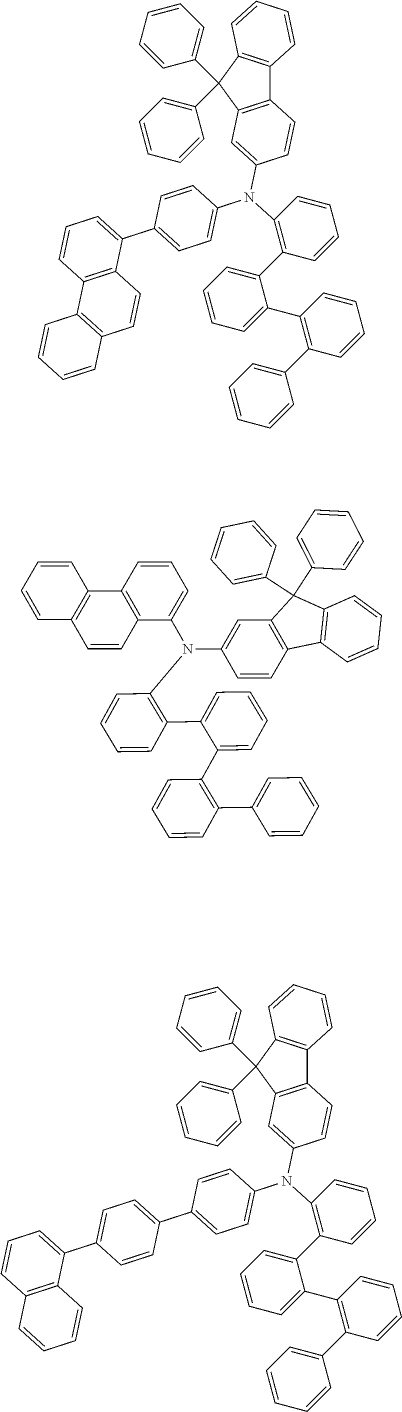 [SMILES: c1ccc(-c2ccccc2-c2ccccc2-c2ccccc2N(c2ccc(-c3cccc4c3ccc3ccccc34)cc2)c2ccc3c(c2)C(c2ccccc2)(c2ccccc2)c2ccccc2-3)cc1 ; c1ccc(-c2ccccc2-c2ccccc2-c2ccccc2N(c2ccc3c(c2)C(c2ccccc2)(c2ccccc2)c2ccccc2-3)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C(c2ccccc2)(c2ccccc2)c2ccccc2-3)cc1]

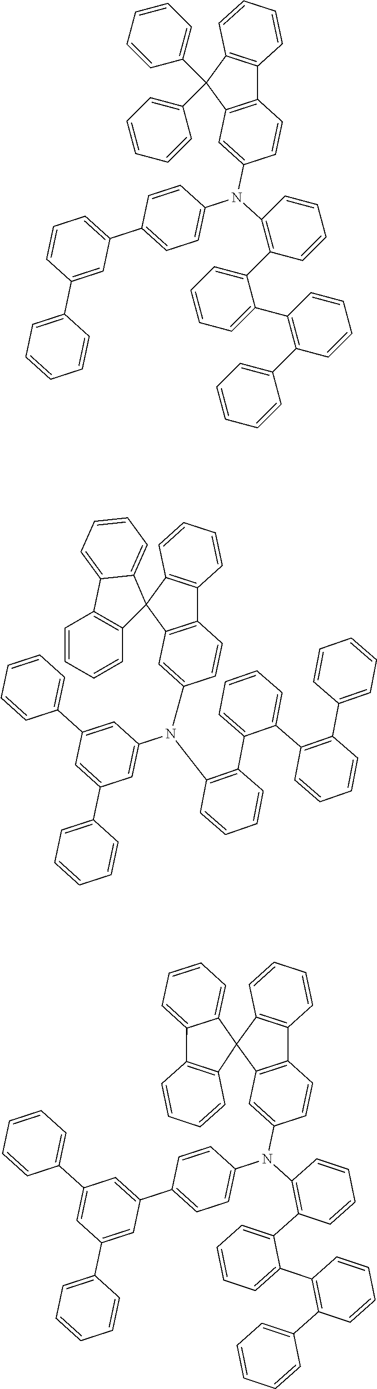 [SMILES: c1ccc(-c2cccc(-c3ccc(N(c4ccc5c(c4)C(c4ccccc4)(c4ccccc4)c4ccccc4-5)c4ccccc4-c4ccccc4-c4ccccc4-c4ccccc4)cc3)c2)cc1 ; c1ccc(-c2cc(-c3ccccc3)cc(N(c3ccc4c(c3)C3(c5ccccc5-c5ccccc53)c3ccccc3-4)c3ccccc3-c3ccccc3-c3ccccc3-c3ccccc3)c2)cc1 ; c1ccc(-c2cc(-c3ccccc3)cc(-c3ccc(N(c4ccc5c(c4)C4(c6ccccc6-c6ccccc64)c4ccccc4-5)c4ccccc4-c4ccccc4-c4ccccc4-c4ccccc4)cc3)c2)cc1]

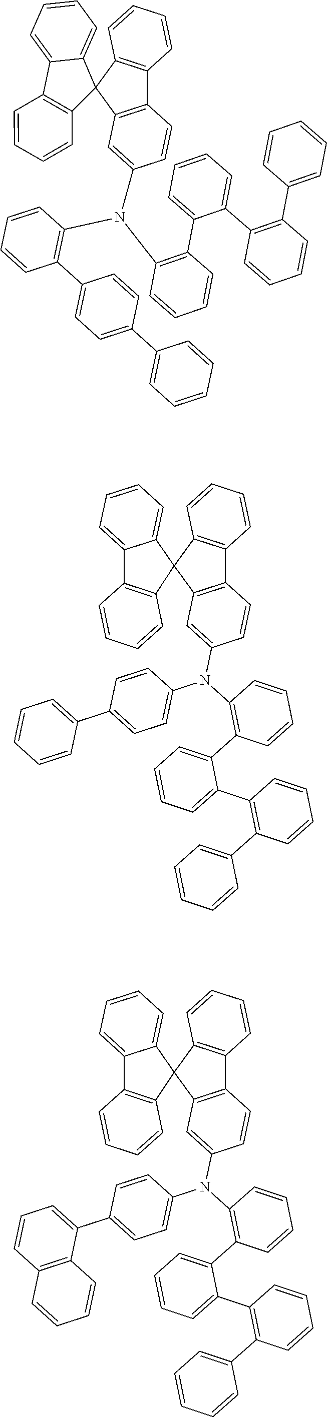 [SMILES: c1ccc(-c2ccc(-c3ccccc3N(c3ccc4c(c3)C3(c5ccccc5-c5ccccc53)c3ccccc3-4)c3ccccc3-c3ccccc3-c3ccccc3-c3ccccc3)cc2)cc1 ; c1ccc(-c2ccc(N(c3ccc4c(c3)C3(c5ccccc5-c5ccccc53)c3ccccc3-4)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(c4ccccc4-c4ccccc42)c2ccccc2-3)cc1]

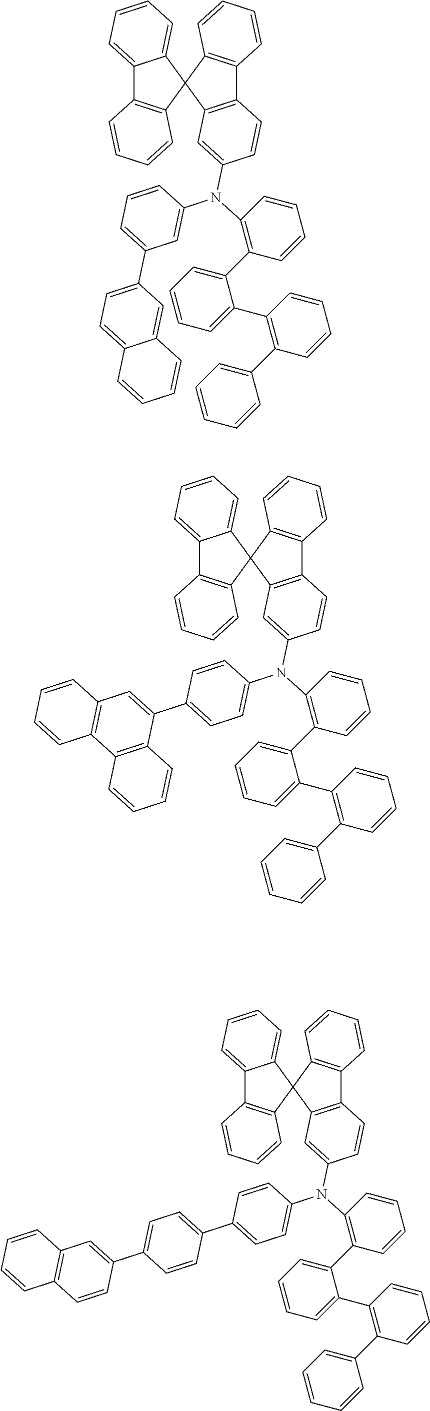 [SMILES: c1ccc(-c2ccccc2-c2ccccc2-c2ccccc2N(c2cccc(-c3ccc4ccccc4c3)c2)c2ccc3c(c2)C2(c4ccccc4-c4ccccc42)c2ccccc2-3)cc1 ; c1ccc(-c2ccccc2-c2ccccc2-c2ccccc2N(c2ccc(-c3cc4ccccc4c4ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C2(c4ccccc4-c4ccccc42)c2ccccc2-3)cc1]

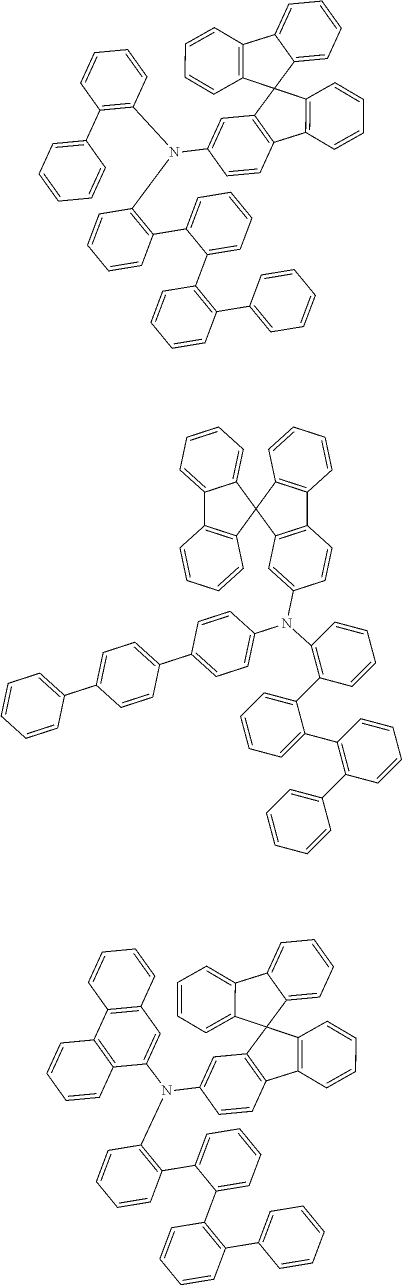 [SMILES: c1ccc(-c2ccccc2-c2ccccc2-c2ccccc2N(c2ccc3c(c2)C2(c4ccccc4-c4ccccc42)c2ccccc2-3)c2ccccc2-c2ccccc2)cc1 ; c1ccc(-c2ccc(-c3ccc(N(c4ccc5c(c4)C4(c6ccccc6-c6ccccc64)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(c4ccccc4-c4ccccc42)c2ccccc2-3)c2cc3ccccc3c3ccccc23)cc1]

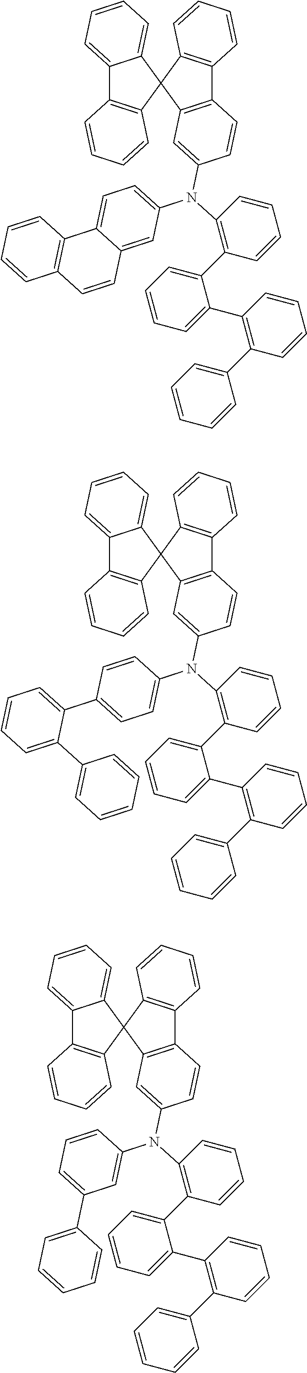

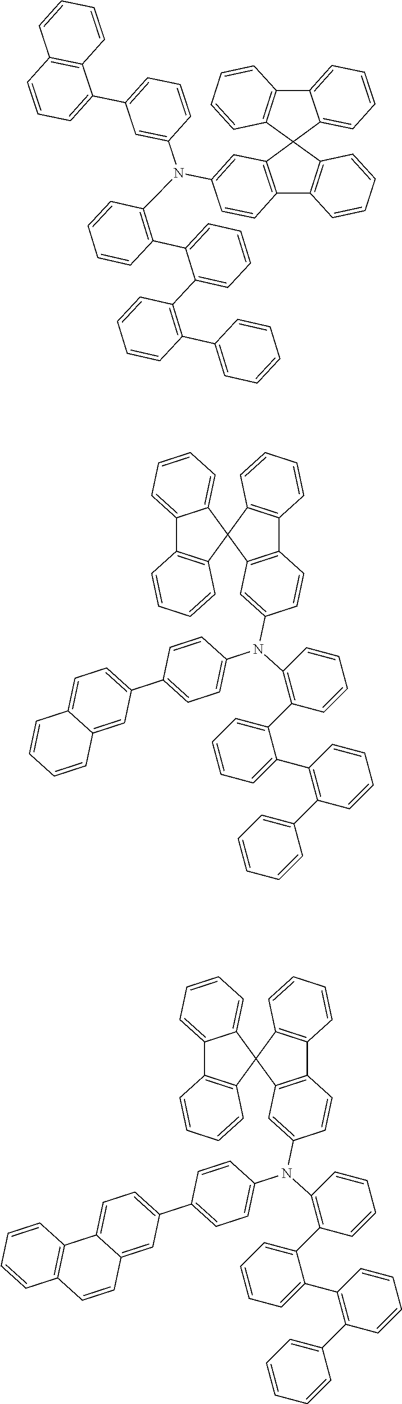 [SMILES: c1ccc(-c2ccccc2-c2ccccc2-c2ccccc2N(c2cccc(-c3cccc4ccccc34)c2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc4ccccc4c3)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C2(c4ccccc4-c4ccccc42)c2ccccc2-3)cc1]

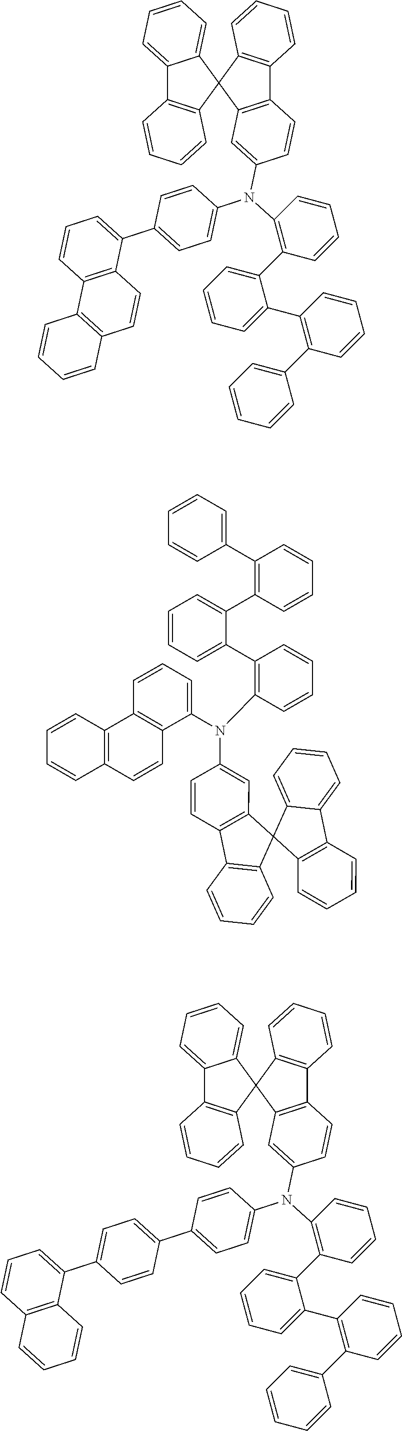 [SMILES: c1ccc(-c2ccccc2-c2ccccc2-c2ccccc2N(c2ccc(-c3cccc4c3ccc3ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc3c(c2)C2(c4ccccc4-c4ccccc42)c2ccccc2-3)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C2(c4ccccc4-c4ccccc42)c2ccccc2-3)cc1]

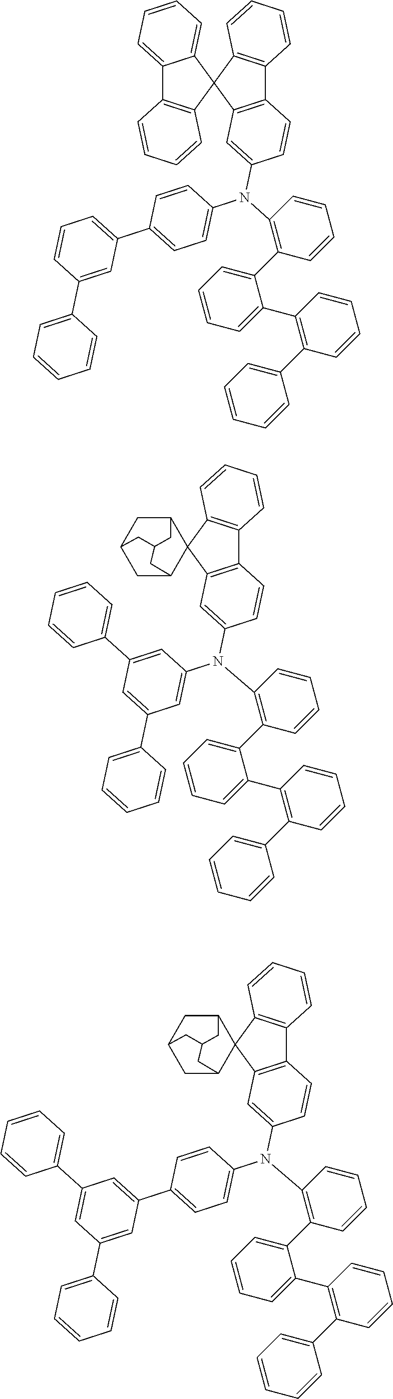

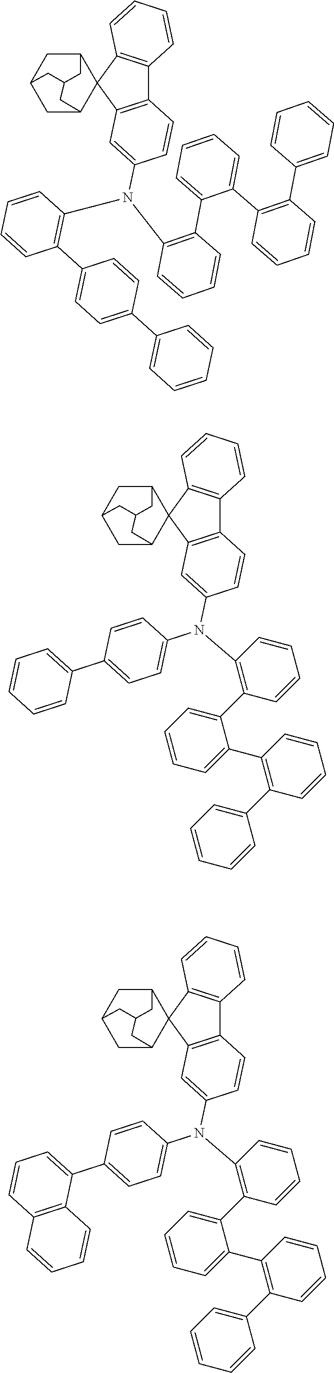 [SMILES: c1ccc(-c2ccc(-c3ccccc3N(c3ccc4c(c3)C3(c5ccccc5-4)C4CC5CC(C4)CC3C5)c3ccccc3-c3ccccc3-c3ccccc3-c3ccccc3)cc2)cc1 ; c1ccc(-c2ccc(N(c3ccc4c(c3)C3(c5ccccc5-4)C4CC5CC(C4)CC3C5)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(c4ccccc4-3)C3CC4CC(C3)CC2C4)cc1]

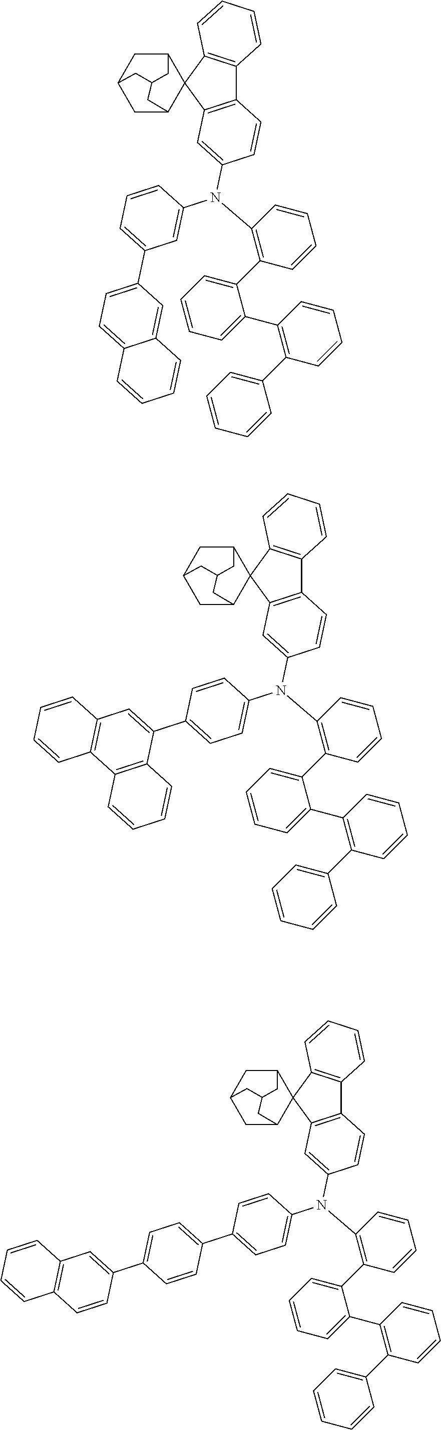 [SMILES: c1ccc(-c2ccccc2-c2ccccc2-c2ccccc2N(c2cccc(-c3ccc4ccccc4c3)c2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3cc4ccccc4c4ccccc34)cc2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3ccc(-c4ccc5ccccc5c4)cc3)cc2)c2ccc3c(c2)C2(c4ccccc4-3)C3CC4CC(C3)CC2C4)cc1]

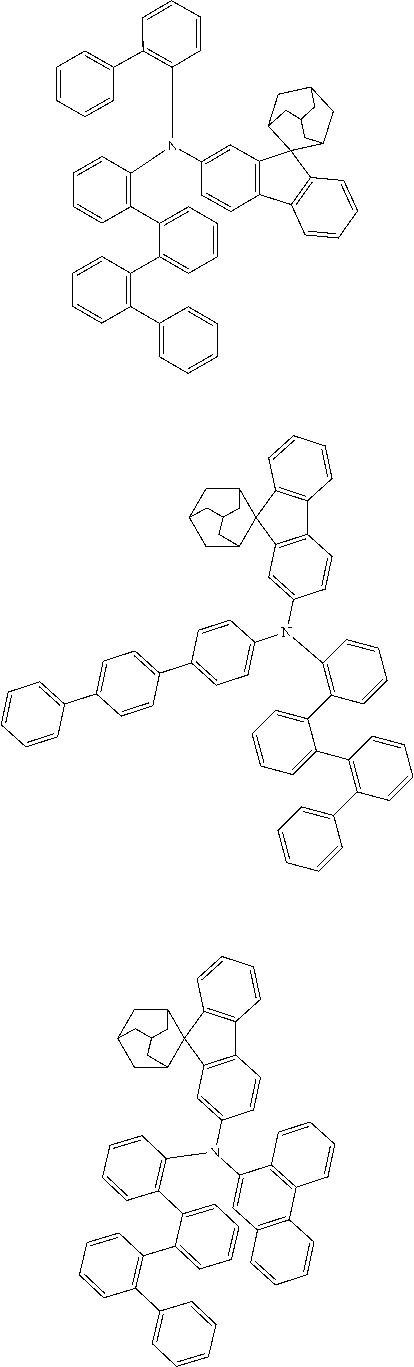 [SMILES: c1ccc(-c2ccccc2-c2ccccc2-c2ccccc2N(c2ccc3c(c2)C2(c4ccccc4-3)C3CC4CC(C3)CC2C4)c2ccccc2-c2ccccc2)cc1 ; c1ccc(-c2ccc(-c3ccc(N(c4ccc5c(c4)C4(c6ccccc6-5)C5CC6CC(C5)CC4C6)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(c4ccccc4-3)C3CC4CC(C3)CC2C4)c2cc3ccccc3c3ccccc23)cc1]

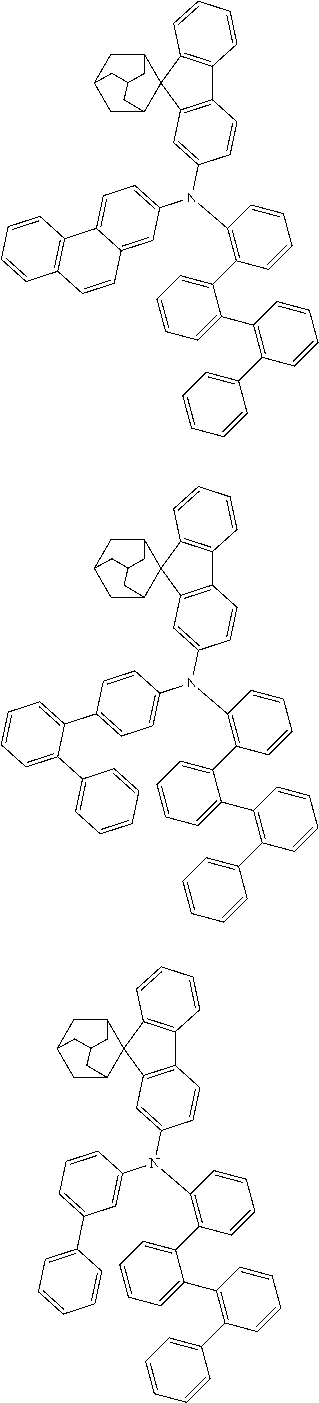 [SMILES: c1ccc(-c2ccccc2-c2ccccc2-c2ccccc2N(c2ccc3c(c2)C2(c4ccccc4-3)C3CC4CC(C3)CC2C4)c2ccc3c(ccc4ccccc43)c2)cc1 ; c1ccc(-c2ccccc2-c2ccc(N(c3ccc4c(c3)C3(c5ccccc5-4)C4CC5CC(C4)CC3C5)c3ccccc3-c3ccccc3-c3ccccc3-c3ccccc3)cc2)cc1 ; c1ccc(-c2cccc(N(c3ccc4c(c3)C3(c5ccccc5-4)C4CC5CC(C4)CC3C5)c3ccccc3-c3ccccc3-c3ccccc3-c3ccccc3)c2)cc1]

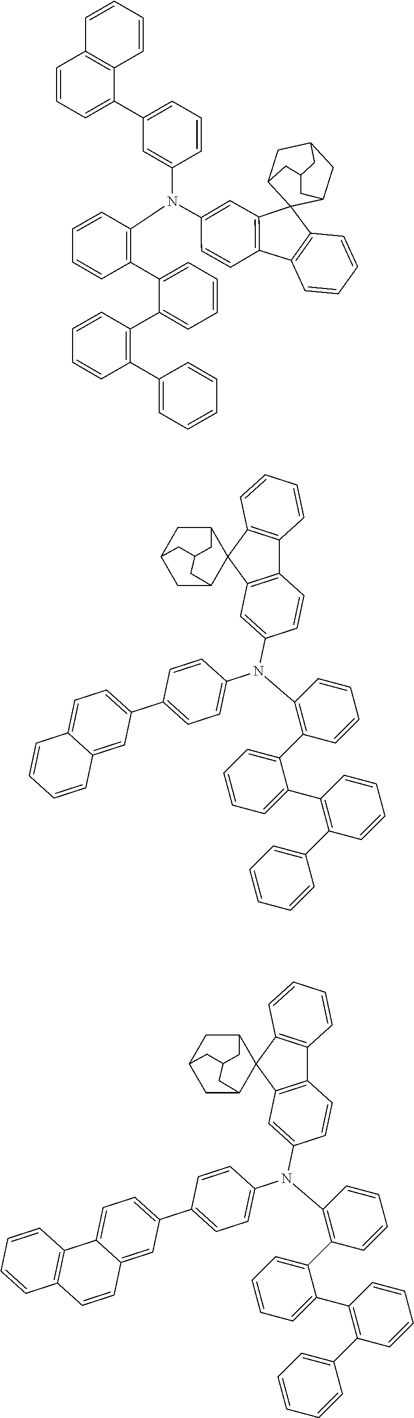 [SMILES: c1ccc(-c2ccccc2-c2ccccc2-c2ccccc2N(c2cccc(-c3cccc4ccccc34)c2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3ccc4ccccc4c3)cc2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3ccc4c(ccc5ccccc54)c3)cc2)c2ccc3c(c2)C2(c4ccccc4-3)C3CC4CC(C3)CC2C4)cc1]

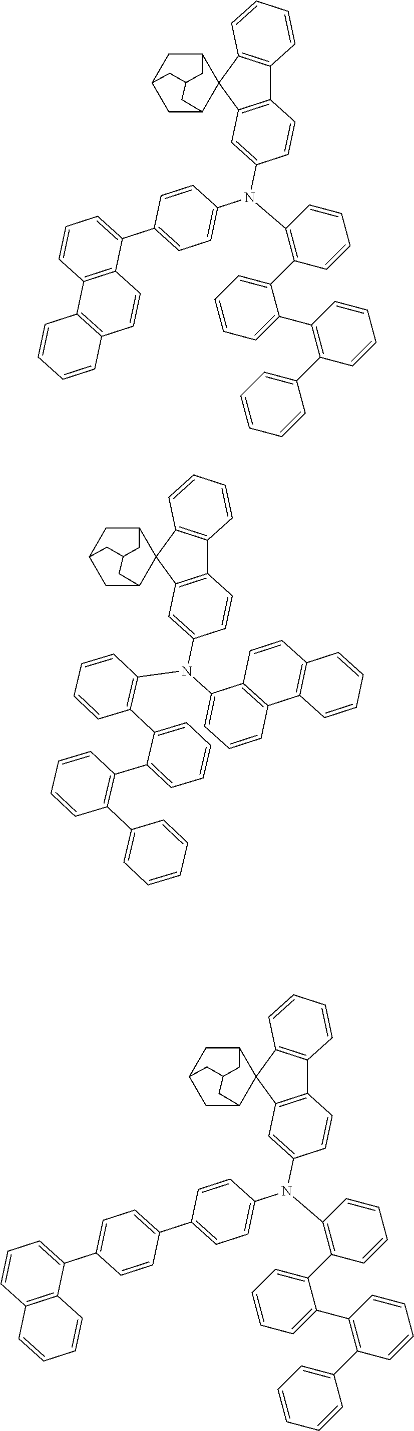 [SMILES: c1ccc(-c2ccccc2-c2ccccc2-c2ccccc2N(c2ccc(-c3cccc4c3ccc3ccccc34)cc2)c2ccc3c(c2)C2(c4ccccc4-3)C3CC4CC(C3)CC2C4)cc1 ; c1ccc(-c2ccccc2-c2ccccc2-c2ccccc2N(c2ccc3c(c2)C2(c4ccccc4-3)C3CC4CC(C3)CC2C4)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C2(c4ccccc4-3)C3CC4CC(C3)CC2C4)cc1]

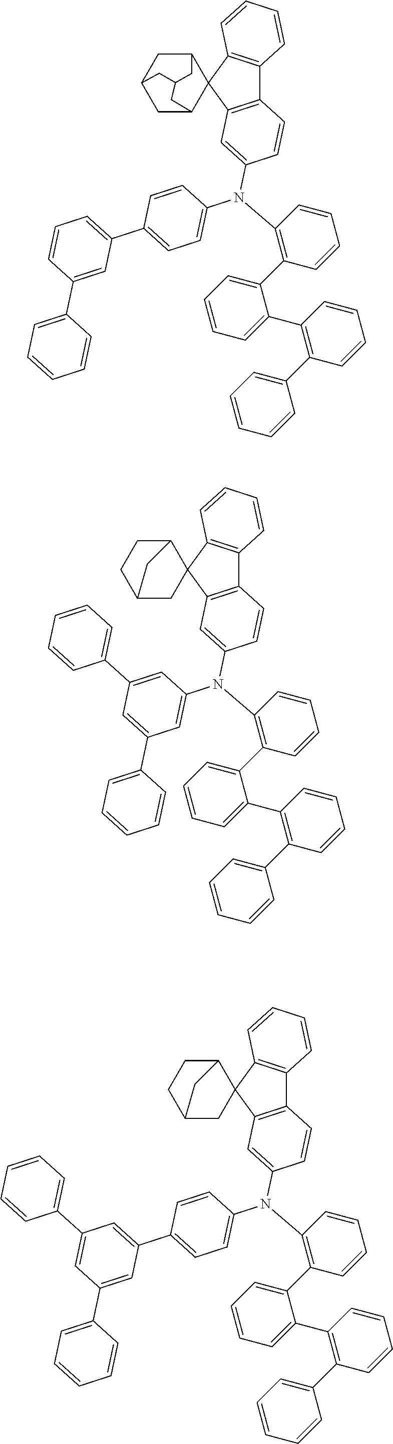 [SMILES: c1ccc(-c2cccc(-c3ccc(N(c4ccc5c(c4)C4(c6ccccc6-5)C5CC6CC(C5)CC4C6)c4ccccc4-c4ccccc4-c4ccccc4-c4ccccc4)cc3)c2)cc1 ; c1ccc(-c2cc(-c3ccccc3)cc(N(c3ccc4c(c3)C3(CC5CCC3C5)c3ccccc3-4)c3ccccc3-c3ccccc3-c3ccccc3-c3ccccc3)c2)cc1 ; c1ccc(-c2cc(-c3ccccc3)cc(-c3ccc(N(c4ccc5c(c4)C4(CC6CCC4C6)c4ccccc4-5)c4ccccc4-c4ccccc4-c4ccccc4-c4ccccc4)cc3)c2)cc1]

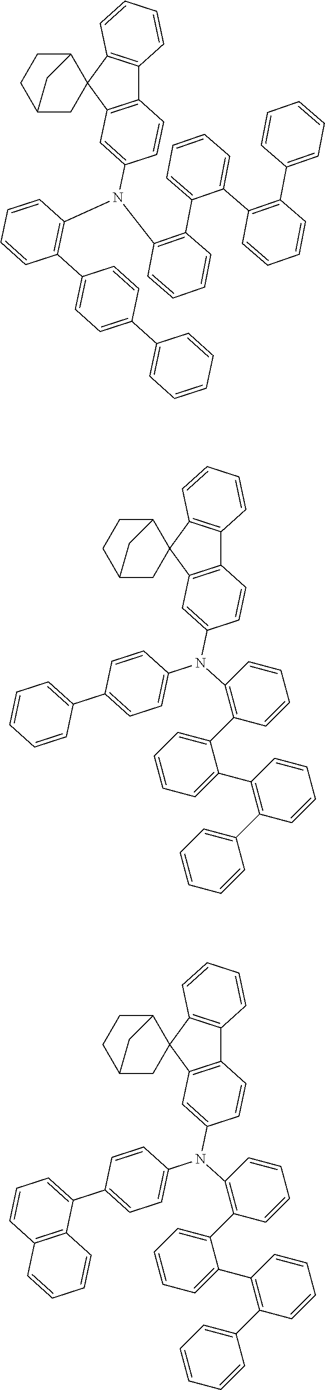 [SMILES: c1ccc(-c2ccc(-c3ccccc3N(c3ccc4c(c3)C3(CC5CCC3C5)c3ccccc3-4)c3ccccc3-c3ccccc3-c3ccccc3-c3ccccc3)cc2)cc1 ; c1ccc(-c2ccc(N(c3ccc4c(c3)C3(CC5CCC3C5)c3ccccc3-4)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(CC4CCC2C4)c2ccccc2-3)cc1]

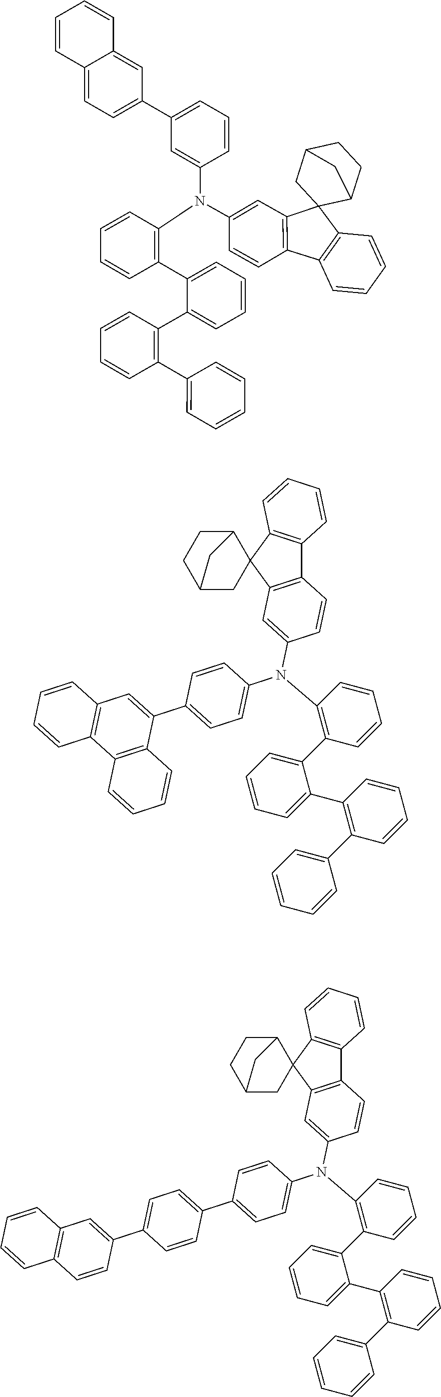 [SMILES: c1ccc(-c2ccccc2-c2ccccc2-c2ccccc2N(c2cccc(-c3ccc4ccccc4c3)c2)c2ccc3c(c2)C2(CC4CCC2C4)c2ccccc2-3)cc1 ; c1ccc(-c2ccccc2-c2ccccc2-c2ccccc2N(c2ccc(-c3cc4ccccc4c4ccccc34)cc2)c2ccc3c(c2)C2(CC4CCC2C4)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C2(CC4CCC2C4)c2ccccc2-3)cc1]

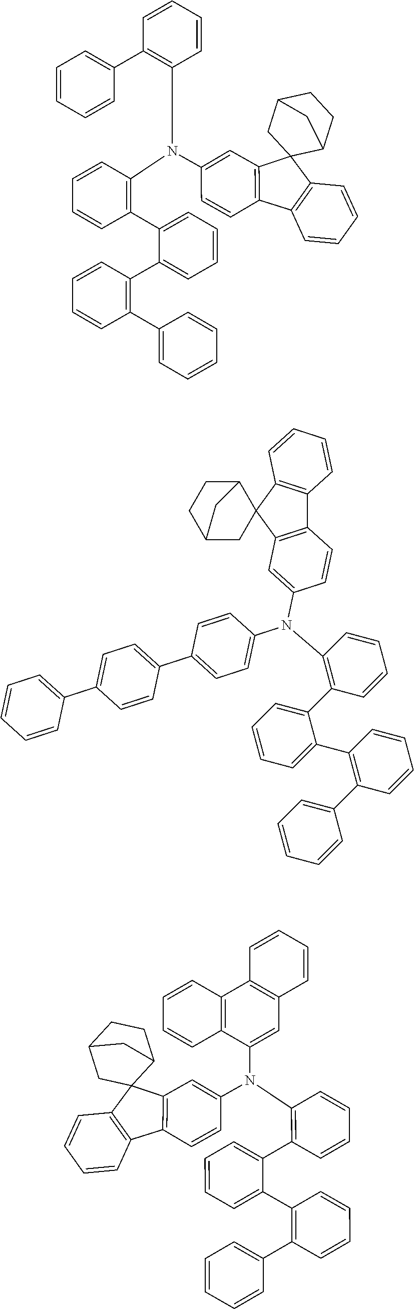 [SMILES: c1ccc(-c2ccccc2-c2ccccc2-c2ccccc2N(c2ccc3c(c2)C2(CC4CCC2C4)c2ccccc2-3)c2ccccc2-c2ccccc2)cc1 ; c1ccc(-c2ccc(-c3ccc(N(c4ccc5c(c4)C4(CC6CCC4C6)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(CC4CCC2C4)c2ccccc2-3)c2cc3ccccc3c3ccccc23)cc1]

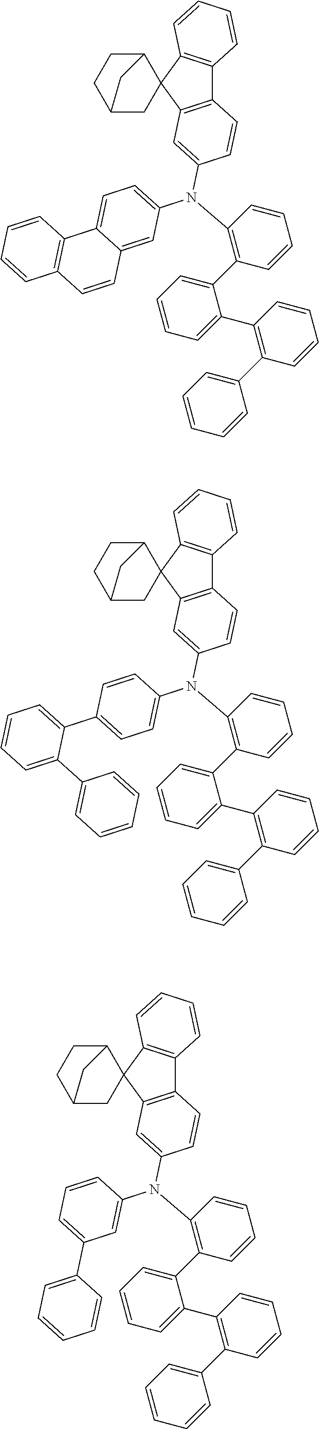 [SMILES: c1ccc(-c2ccccc2-c2ccccc2-c2ccccc2N(c2ccc3c(c2)C2(CC4CCC2C4)c2ccccc2-3)c2ccc3c(ccc4ccccc43)c2)cc1 ; c1ccc(-c2ccccc2-c2ccc(N(c3ccc4c(c3)C3(CC5CCC3C5)c3ccccc3-4)c3ccccc3-c3ccccc3-c3ccccc3-c3ccccc3)cc2)cc1 ; c1ccc(-c2cccc(N(c3ccc4c(c3)C3(CC5CCC3C5)c3ccccc3-4)c3ccccc3-c3ccccc3-c3ccccc3-c3ccccc3)c2)cc1]

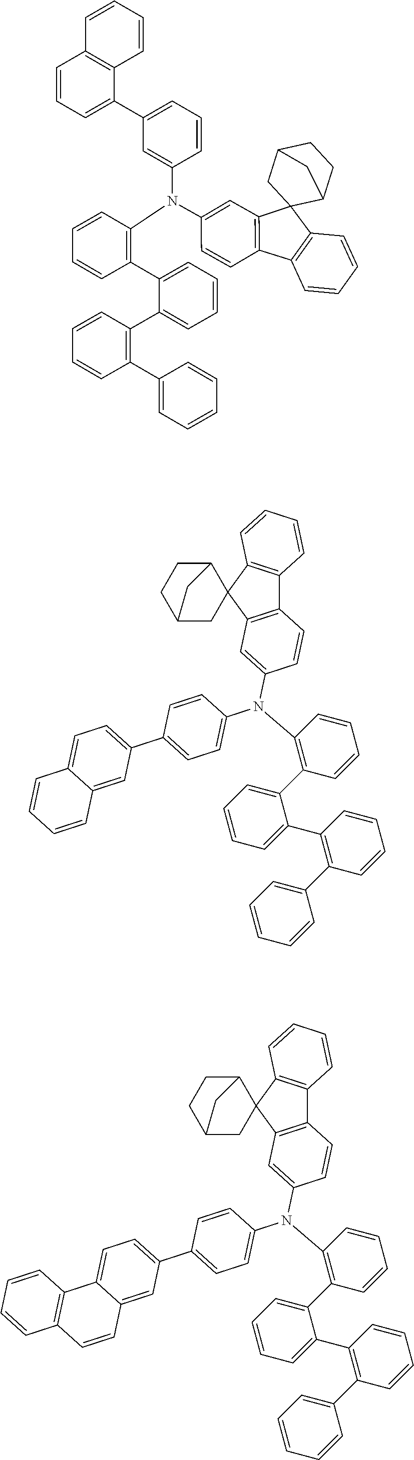 [SMILES: c1ccc(-c2ccccc2-c2ccccc2-c2ccccc2N(c2cccc(-c3cccc4ccccc34)c2)c2ccc3c(c2)C2(CC4CCC2C4)c2ccccc2-3)cc1 ; c1ccc(-c2ccccc2-c2ccccc2-c2ccccc2N(c2ccc(-c3ccc4ccccc4c3)cc2)c2ccc3c(c2)C2(CC4CCC2C4)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C2(CC4CCC2C4)c2ccccc2-3)cc1]

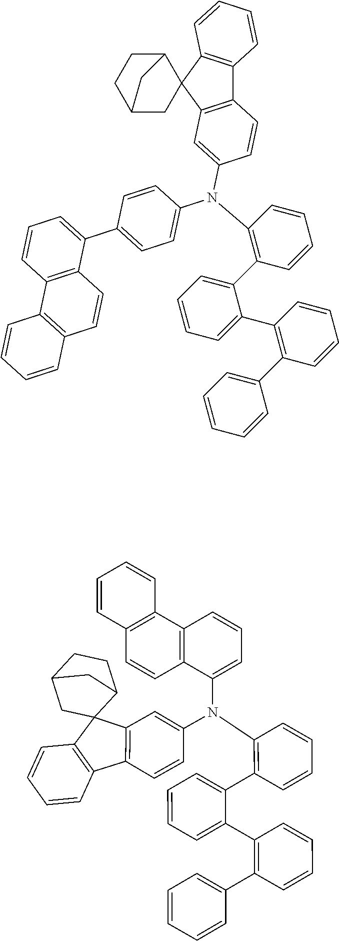 [SMILES: c1ccc(-c2ccccc2-c2ccccc2-c2ccccc2N(c2ccc(-c3cccc4c3ccc3ccccc34)cc2)c2ccc3c(c2)C2(CC4CCC2C4)c2ccccc2-3)cc1 ; c1ccc(-c2ccccc2-c2ccccc2-c2ccccc2N(c2ccc3c(c2)C2(CC4CCC2C4)c2ccccc2-3)c2cccc3c2ccc2ccccc23)cc1]

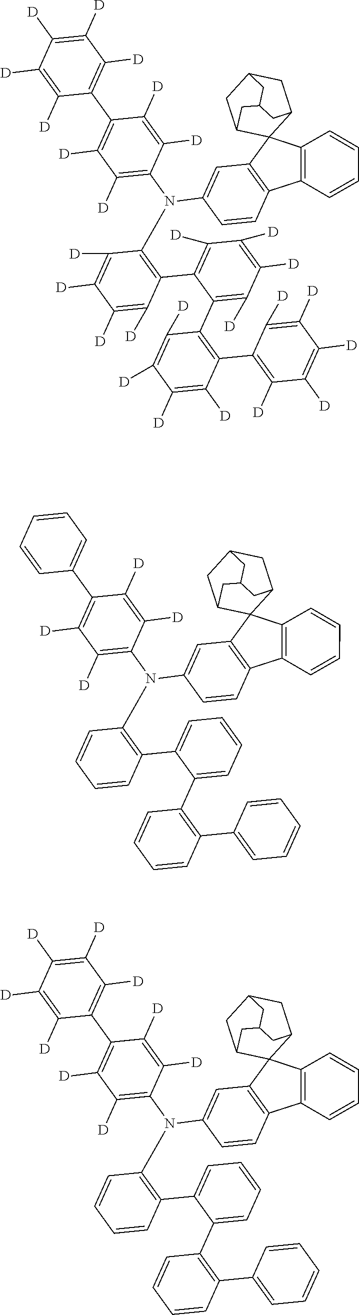

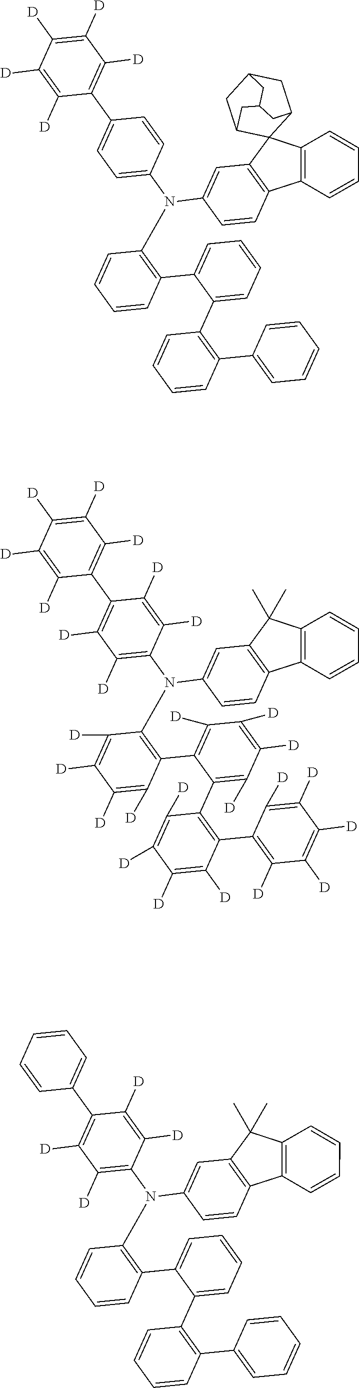 [SMILES: [2H]c1c([2H])c([2H])c(-c2ccc(N(c3ccc4c(c3)C3(c5ccccc5-4)C4CC5CC(C4)CC3C5)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C(C)(C)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C(C)(C)c2ccccc2-3)c2ccccc2-c2ccccc2-c2ccccc2-c2ccccc2)c([2H])c([2H])c1-c1ccccc1]

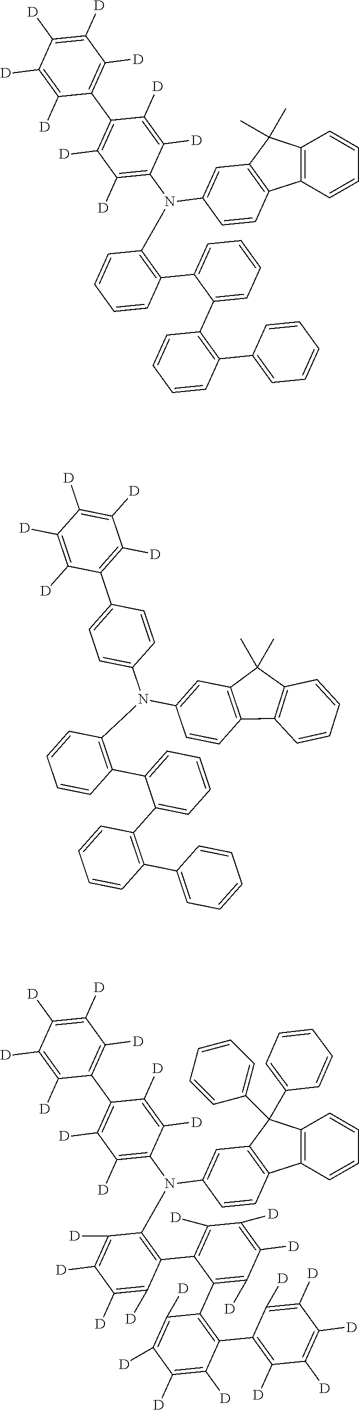

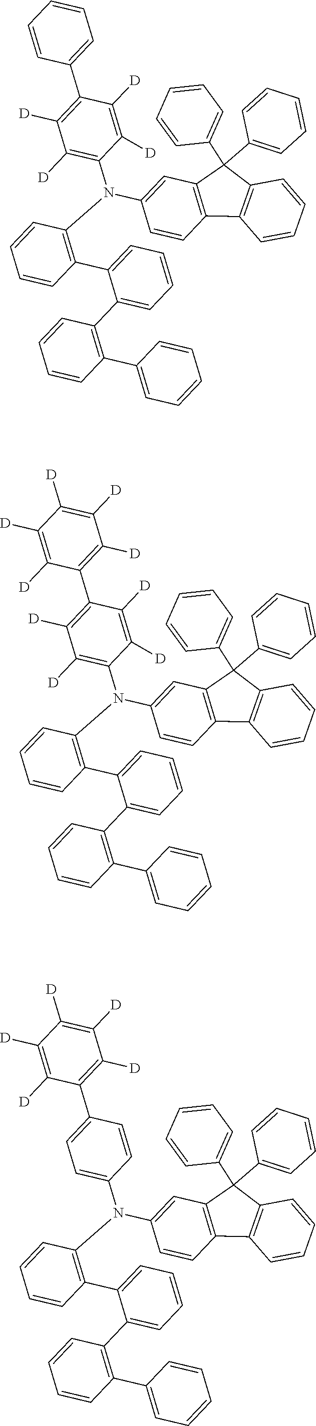 [SMILES: [2H]c1c([2H])c(N(c2ccc3c(c2)C(c2ccccc2)(c2ccccc2)c2ccccc2-3)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C(c3ccccc3)(c3ccccc3)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C(c3ccccc3)(c3ccccc3)c3ccccc3-4)c3ccccc3-c3ccccc3-c3ccccc3-c3ccccc3)cc2)c([2H])c1[2H]]

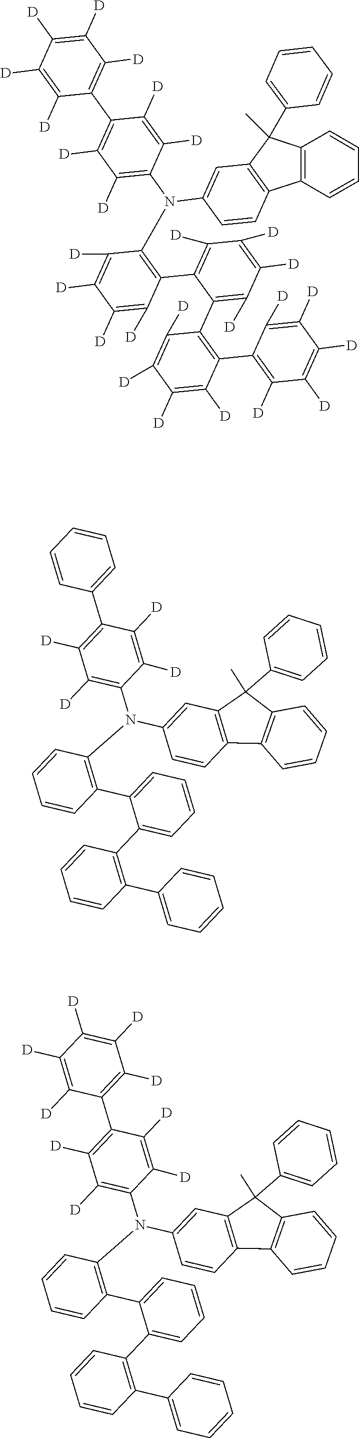

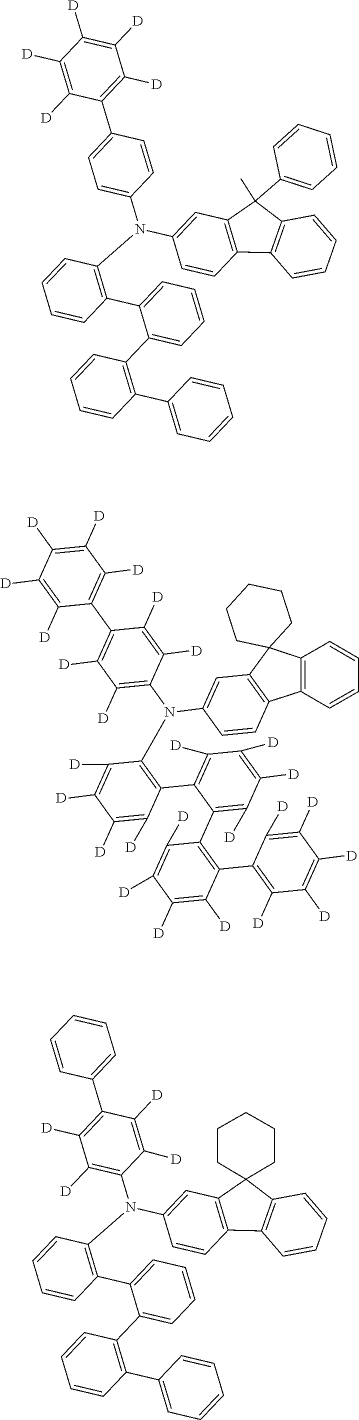 [SMILES: [2H]c1c([2H])c([2H])c(-c2ccc(N(c3ccc4c(c3)C(C)(c3ccccc3)c3ccccc3-4)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C3(CCCCC3)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C2(CCCCC2)c2ccccc2-3)c2ccccc2-c2ccccc2-c2ccccc2-c2ccccc2)c([2H])c([2H])c1-c1ccccc1]

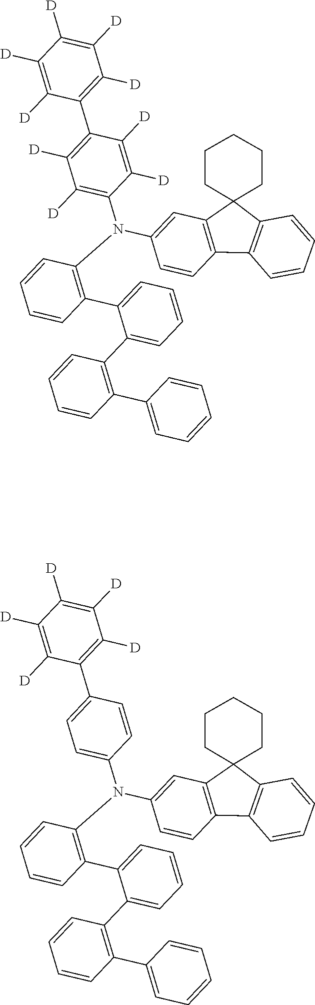 [SMILES: [2H]c1c([2H])c([2H])c(-c2c([2H])c([2H])c(N(c3ccc4c(c3)C3(CCCCC3)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(CCCCC3)c3ccccc3-4)c3ccccc3-c3ccccc3-c3ccccc3-c3ccccc3)cc2)c([2H])c1[2H]]

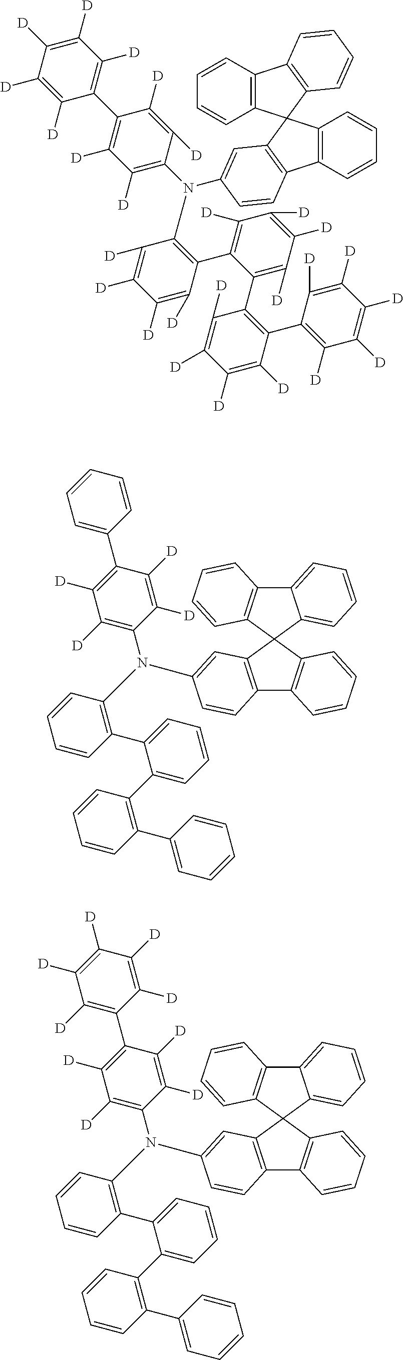

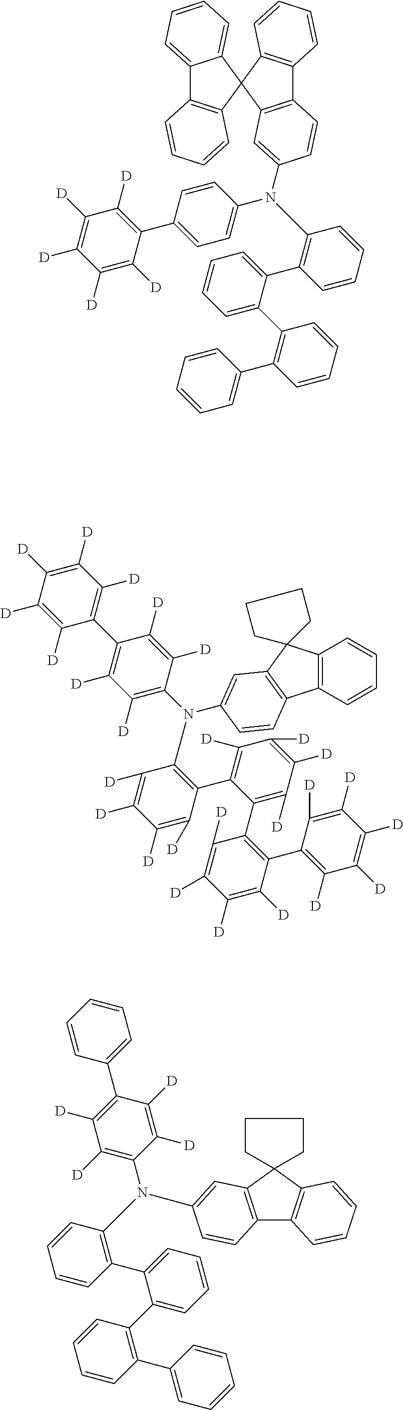 [SMILES: [2H]c1c([2H])c([2H])c(-c2ccc(N(c3ccc4c(c3)C3(c5ccccc5-c5ccccc53)c3ccccc3-4)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C3(CCCC3)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C2(CCCC2)c2ccccc2-3)c2ccccc2-c2ccccc2-c2ccccc2-c2ccccc2)c([2H])c([2H])c1-c1ccccc1]

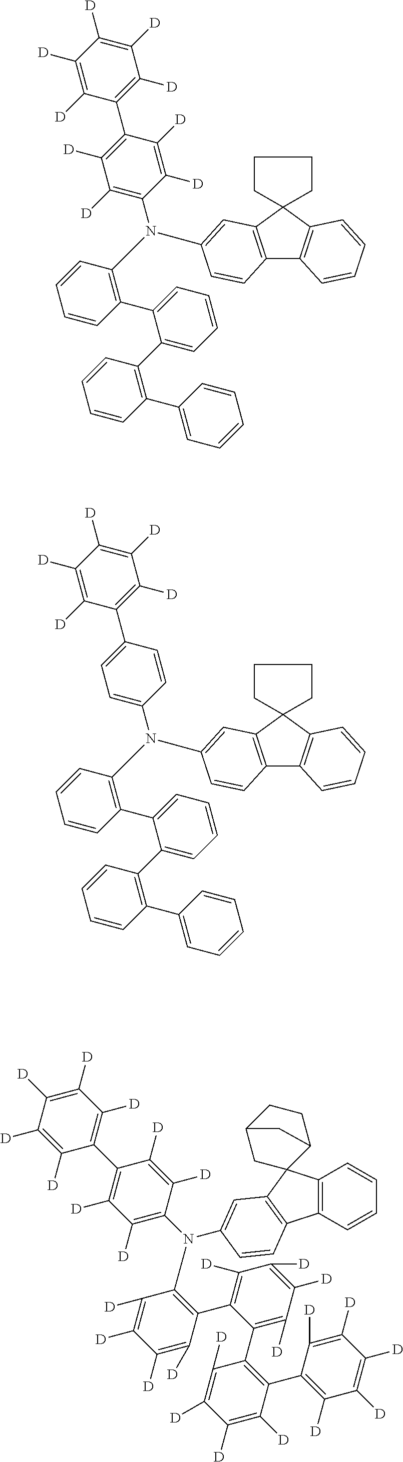 [SMILES: [2H]c1c([2H])c([2H])c(-c2c([2H])c([2H])c(N(c3ccc4c(c3)C3(CCCC3)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(CCCC3)c3ccccc3-4)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C3(CC5CCC3C5)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H]]

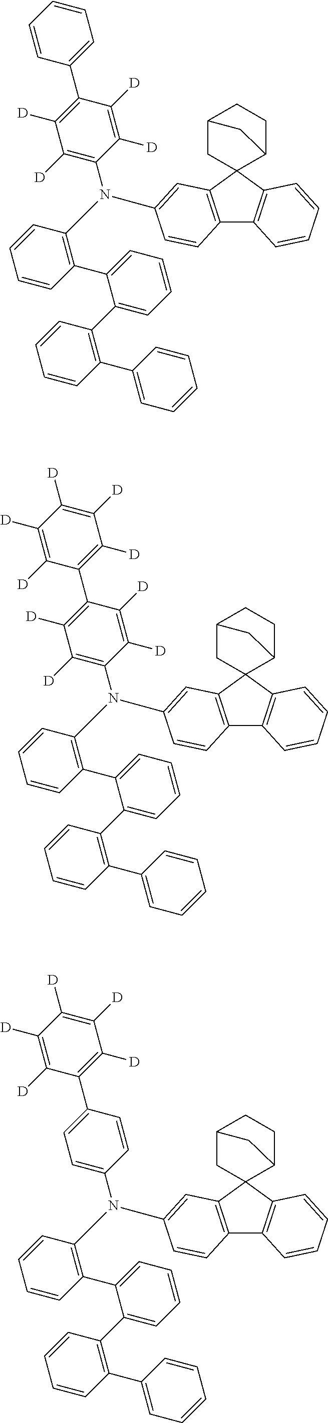 [SMILES: [2H]c1c([2H])c(N(c2ccc3c(c2)C2(CC4CCC2C4)c2ccccc2-3)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C3(CC5CCC3C5)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(CC5CCC3C5)c3ccccc3-4)c3ccccc3-c3ccccc3-c3ccccc3-c3ccccc3)cc2)c([2H])c1[2H]]

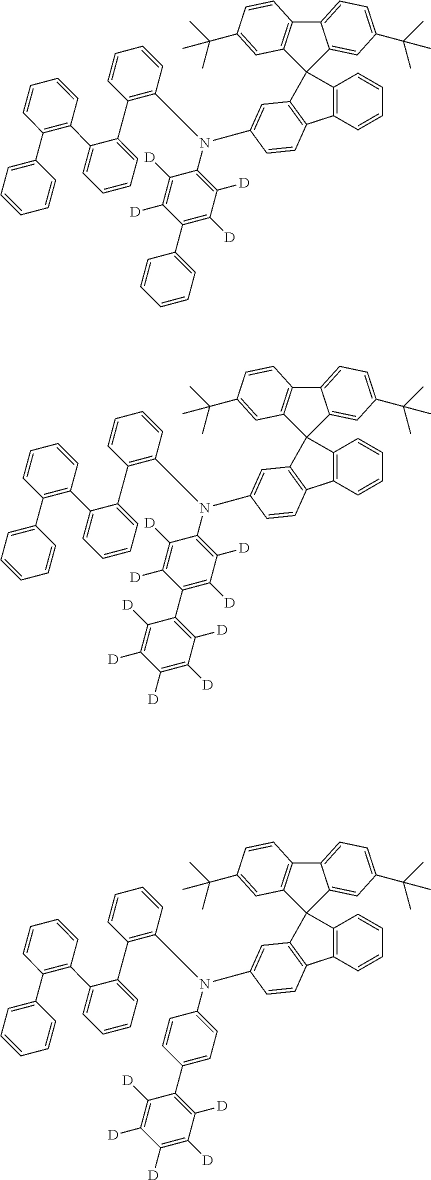 [SMILES: [2H]c1c([2H])c(N(c2ccc3c(c2)C2(c4ccccc4-3)c3cc(C(C)(C)C)ccc3-c3ccc(C(C)(C)C)cc32)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C3(c5ccccc5-4)c4cc(C(C)(C)C)ccc4-c4ccc(C(C)(C)C)cc43)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(c5ccccc5-4)c4cc(C(C)(C)C)ccc4-c4ccc(C(C)(C)C)cc43)c3ccccc3-c3ccccc3-c3ccccc3-c3ccccc3)cc2)c([2H])c1[2H]]

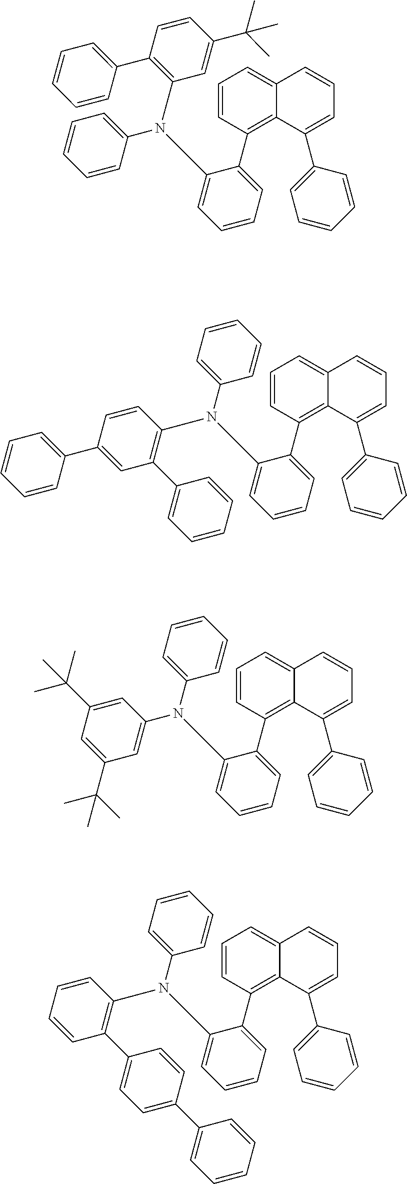 [SMILES: CC(C)(C)c1ccc(-c2ccccc2)c(N(c2ccccc2)c2ccccc2-c2cccc3cccc(-c4ccccc4)c23)c1 ; c1ccc(-c2ccc(N(c3ccccc3)c3ccccc3-c3cccc4cccc(-c5ccccc5)c34)c(-c3ccccc3)c2)cc1 ; CC(C)(C)c1cc(N(c2ccccc2)c2ccccc2-c2cccc3cccc(-c4ccccc4)c23)cc(C(C)(C)C)c1 ; c1ccc(-c2ccc(-c3ccccc3N(c3ccccc3)c3ccccc3-c3cccc4cccc(-c5ccccc5)c34)cc2)cc1]

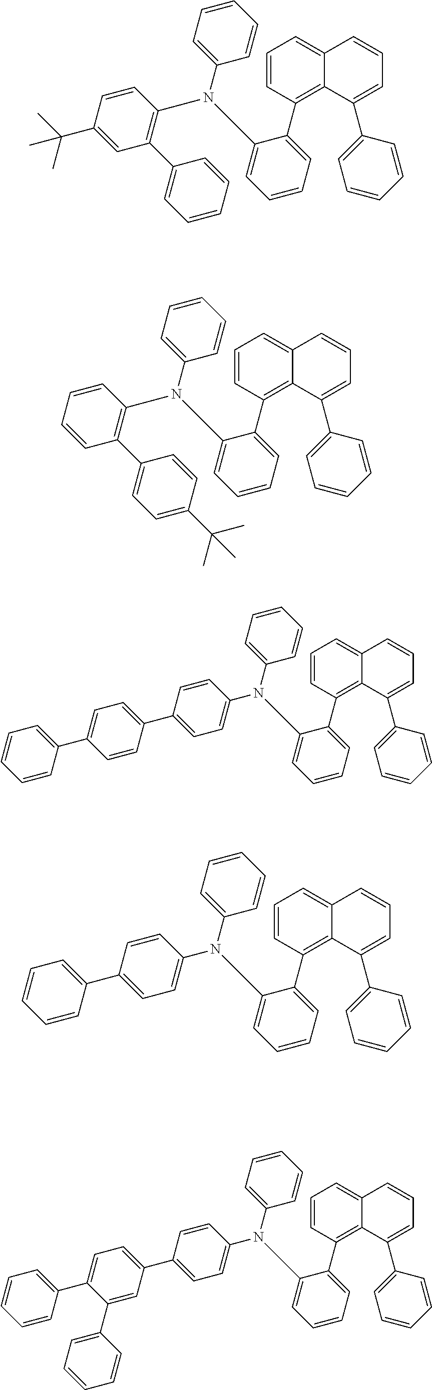 [SMILES: CC(C)(C)c1ccc(N(c2ccccc2)c2ccccc2-c2cccc3cccc(-c4ccccc4)c23)c(-c2ccccc2)c1 ; CC(C)(C)c1ccc(-c2ccccc2N(c2ccccc2)c2ccccc2-c2cccc3cccc(-c4ccccc4)c23)cc1 ; c1ccc(-c2ccc(-c3ccc(N(c4ccccc4)c4ccccc4-c4cccc5cccc(-c6ccccc6)c45)cc3)cc2)cc1 ; c1ccc(-c2ccc(N(c3ccccc3)c3ccccc3-c3cccc4cccc(-c5ccccc5)c34)cc2)cc1 ; c1ccc(-c2ccc(-c3ccc(N(c4ccccc4)c4ccccc4-c4cccc5cccc(-c6ccccc6)c45)cc3)cc2-c2ccccc2)cc1]

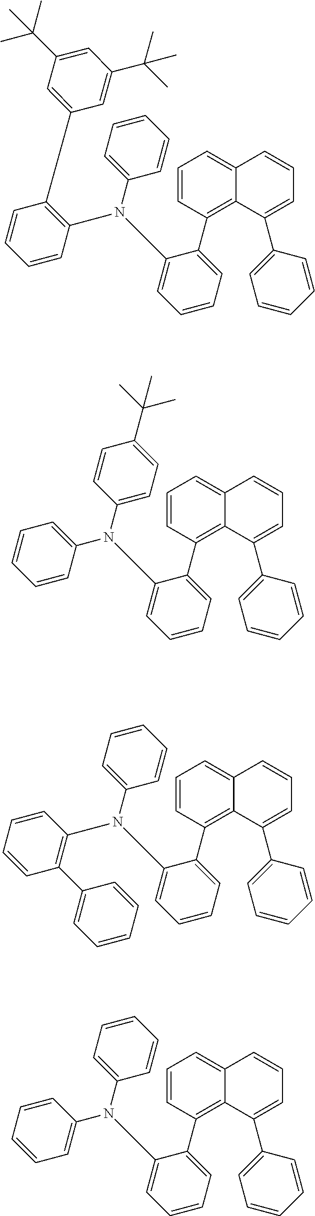 [SMILES: CC(C)(C)c1cc(-c2ccccc2N(c2ccccc2)c2ccccc2-c2cccc3cccc(-c4ccccc4)c23)cc(C(C)(C)C)c1 ; CC(C)(C)c1ccc(N(c2ccccc2)c2ccccc2-c2cccc3cccc(-c4ccccc4)c23)cc1 ; c1ccc(-c2ccccc2N(c2ccccc2)c2ccccc2-c2cccc3cccc(-c4ccccc4)c23)cc1 ; c1ccc(-c2cccc3cccc(-c4ccccc4N(c4ccccc4)c4ccccc4)c23)cc1]

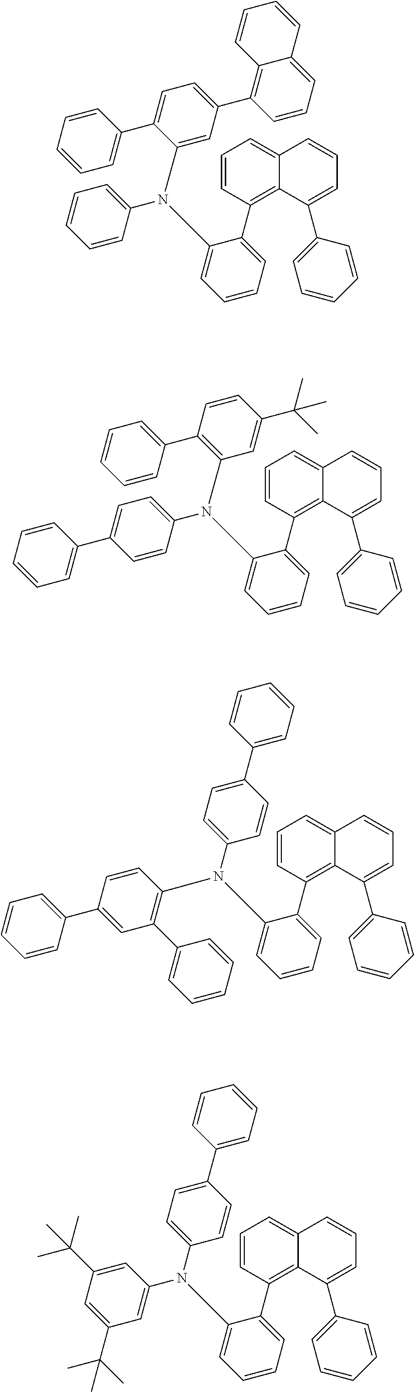 [SMILES: c1ccc(-c2ccc(-c3cccc4ccccc34)cc2N(c2ccccc2)c2ccccc2-c2cccc3cccc(-c4ccccc4)c23)cc1 ; CC(C)(C)c1ccc(-c2ccccc2)c(N(c2ccc(-c3ccccc3)cc2)c2ccccc2-c2cccc3cccc(-c4ccccc4)c23)c1 ; c1ccc(-c2ccc(N(c3ccc(-c4ccccc4)cc3-c3ccccc3)c3ccccc3-c3cccc4cccc(-c5ccccc5)c34)cc2)cc1 ; CC(C)(C)c1cc(N(c2ccc(-c3ccccc3)cc2)c2ccccc2-c2cccc3cccc(-c4ccccc4)c23)cc(C(C)(C)C)c1]

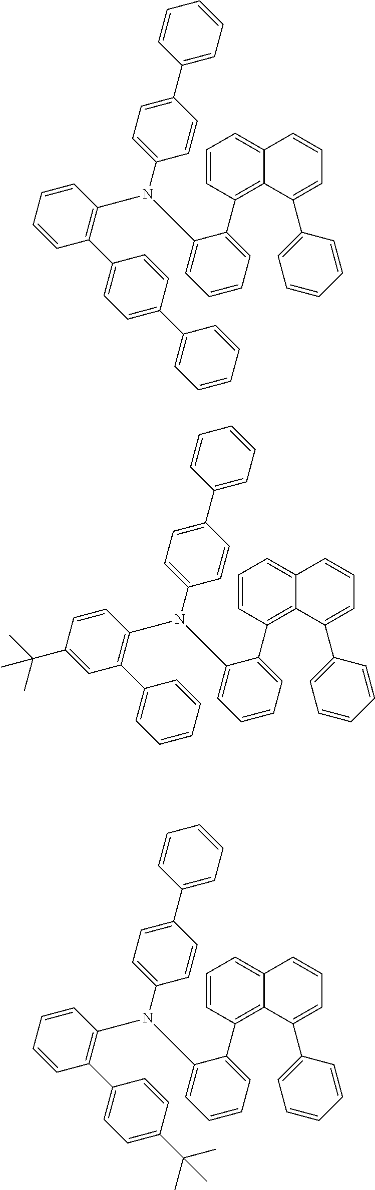

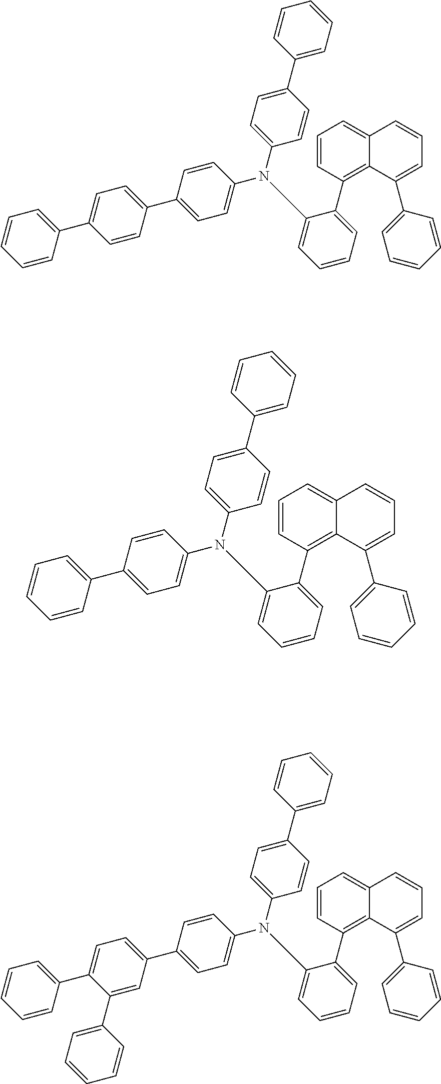 [SMILES: c1ccc(-c2ccc(-c3ccc(N(c4ccc(-c5ccccc5)cc4)c4ccccc4-c4cccc5cccc(-c6ccccc6)c45)cc3)cc2)cc1 ; c1ccc(-c2ccc(N(c3ccc(-c4ccccc4)cc3)c3ccccc3-c3cccc4cccc(-c5ccccc5)c34)cc2)cc1 ; c1ccc(-c2ccc(N(c3ccc(-c4ccc(-c5ccccc5)c(-c5ccccc5)c4)cc3)c3ccccc3-c3cccc4cccc(-c5ccccc5)c34)cc2)cc1]

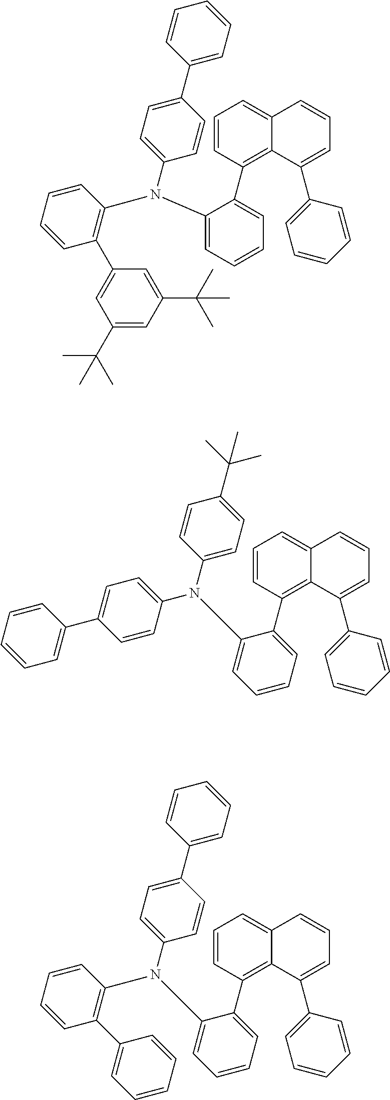 [SMILES: CC(C)(C)c1cc(-c2ccccc2N(c2ccc(-c3ccccc3)cc2)c2ccccc2-c2cccc3cccc(-c4ccccc4)c23)cc(C(C)(C)C)c1 ; CC(C)(C)c1ccc(N(c2ccc(-c3ccccc3)cc2)c2ccccc2-c2cccc3cccc(-c4ccccc4)c23)cc1 ; c1ccc(-c2ccc(N(c3ccccc3-c3ccccc3)c3ccccc3-c3cccc4cccc(-c5ccccc5)c34)cc2)cc1]

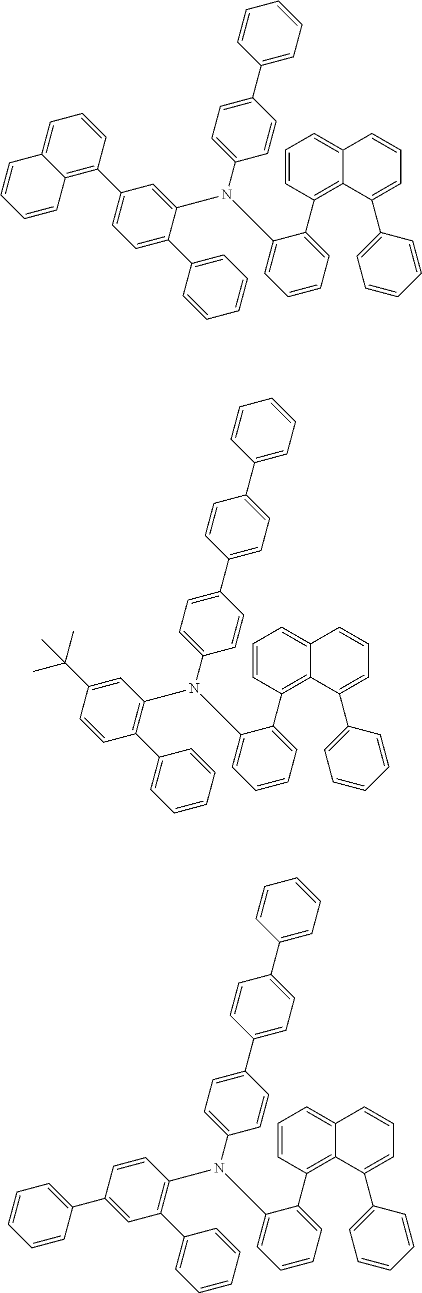 [SMILES: c1ccc(-c2ccc(N(c3cc(-c4cccc5ccccc45)ccc3-c3ccccc3)c3ccccc3-c3cccc4cccc(-c5ccccc5)c34)cc2)cc1 ; CC(C)(C)c1ccc(-c2ccccc2)c(N(c2ccc(-c3ccc(-c4ccccc4)cc3)cc2)c2ccccc2-c2cccc3cccc(-c4ccccc4)c23)c1 ; c1ccc(-c2ccc(-c3ccc(N(c4ccc(-c5ccccc5)cc4-c4ccccc4)c4ccccc4-c4cccc5cccc(-c6ccccc6)c45)cc3)cc2)cc1]

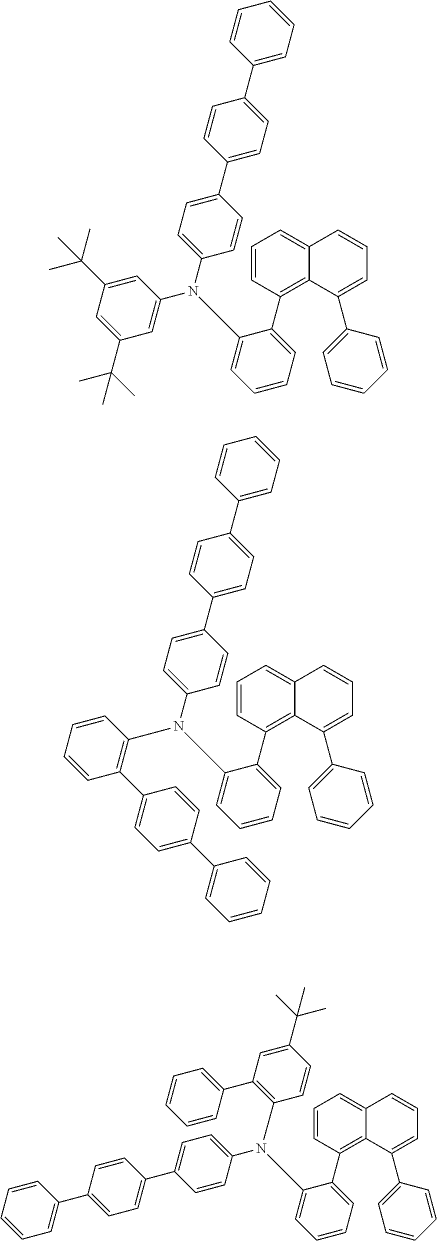

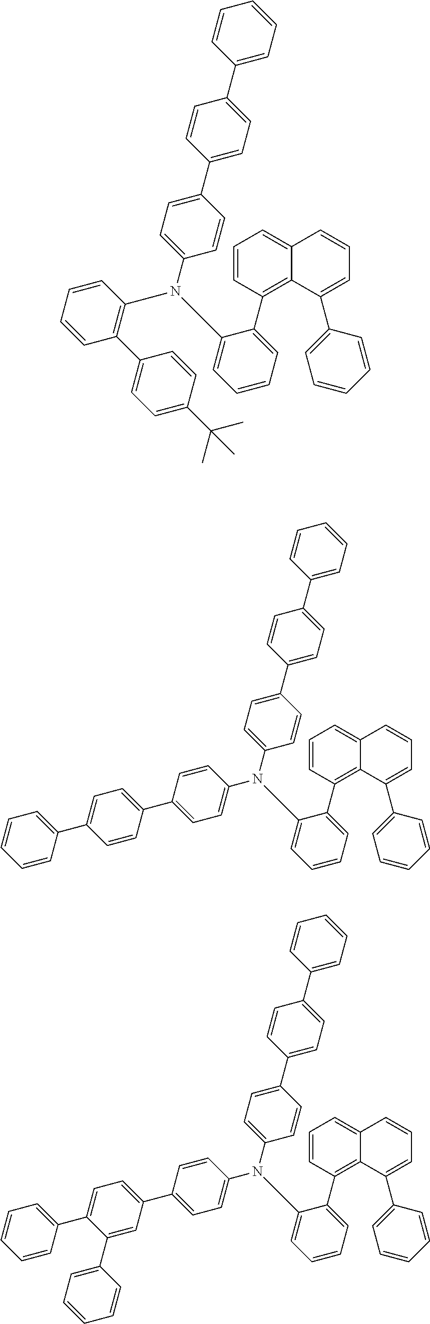 [SMILES: CC(C)(C)c1ccc(-c2ccccc2N(c2ccc(-c3ccc(-c4ccccc4)cc3)cc2)c2ccccc2-c2cccc3cccc(-c4ccccc4)c23)cc1 ; c1ccc(-c2ccc(-c3ccc(N(c4ccc(-c5ccc(-c6ccccc6)cc5)cc4)c4ccccc4-c4cccc5cccc(-c6ccccc6)c45)cc3)cc2)cc1 ; c1ccc(-c2ccc(-c3ccc(N(c4ccc(-c5ccc(-c6ccccc6)c(-c6ccccc6)c5)cc4)c4ccccc4-c4cccc5cccc(-c6ccccc6)c45)cc3)cc2)cc1]

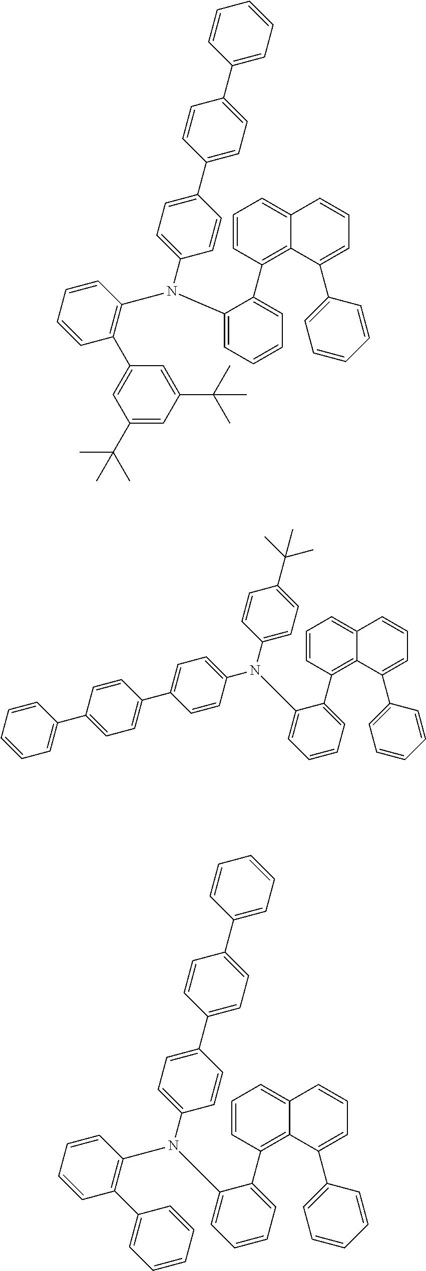 [SMILES: CC(C)(C)c1cc(-c2ccccc2N(c2ccc(-c3ccc(-c4ccccc4)cc3)cc2)c2ccccc2-c2cccc3cccc(-c4ccccc4)c23)cc(C(C)(C)C)c1 ; CC(C)(C)c1ccc(N(c2ccc(-c3ccc(-c4ccccc4)cc3)cc2)c2ccccc2-c2cccc3cccc(-c4ccccc4)c23)cc1 ; c1ccc(-c2ccc(-c3ccc(N(c4ccccc4-c4ccccc4)c4ccccc4-c4cccc5cccc(-c6ccccc6)c45)cc3)cc2)cc1]

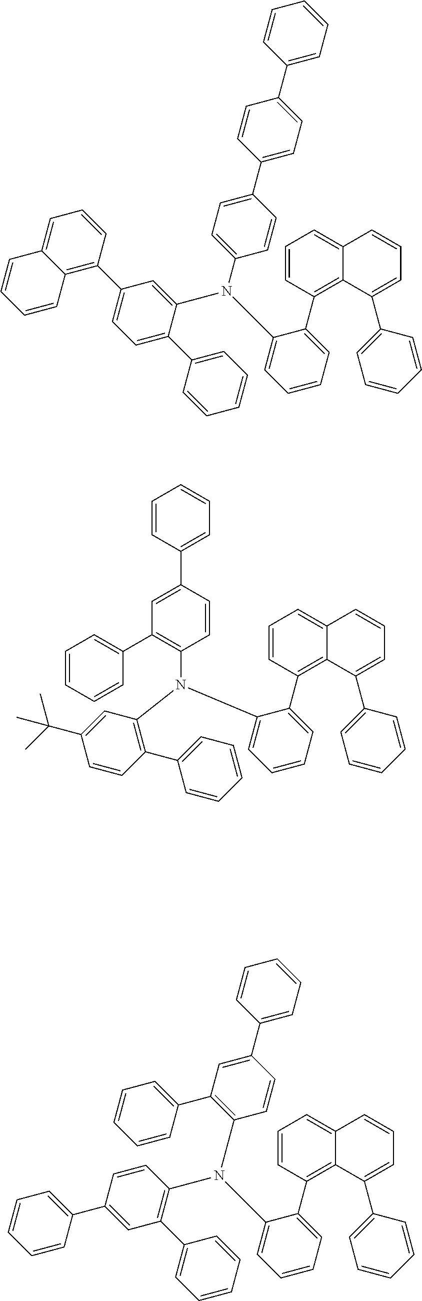 [SMILES: c1ccc(-c2ccc(-c3ccc(N(c4cc(-c5cccc6ccccc56)ccc4-c4ccccc4)c4ccccc4-c4cccc5cccc(-c6ccccc6)c45)cc3)cc2)cc1 ; CC(C)(C)c1ccc(-c2ccccc2)c(N(c2ccc(-c3ccccc3)cc2-c2ccccc2)c2ccccc2-c2cccc3cccc(-c4ccccc4)c23)c1 ; c1ccc(-c2ccc(N(c3ccc(-c4ccccc4)cc3-c3ccccc3)c3ccccc3-c3cccc4cccc(-c5ccccc5)c34)c(-c3ccccc3)c2)cc1]

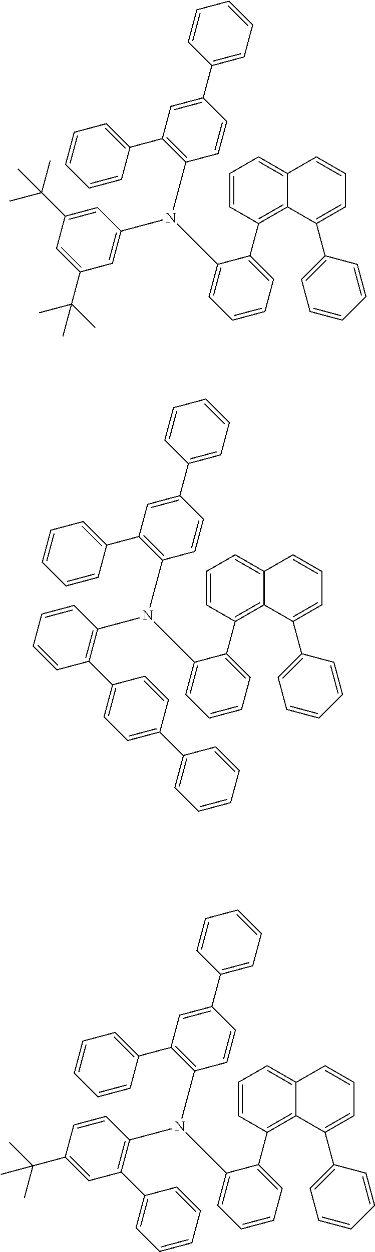 [SMILES: CC(C)(C)c1cc(N(c2ccc(-c3ccccc3)cc2-c2ccccc2)c2ccccc2-c2cccc3cccc(-c4ccccc4)c23)cc(C(C)(C)C)c1 ; c1ccc(-c2ccc(-c3ccccc3N(c3ccc(-c4ccccc4)cc3-c3ccccc3)c3ccccc3-c3cccc4cccc(-c5ccccc5)c34)cc2)cc1 ; CC(C)(C)c1ccc(N(c2ccc(-c3ccccc3)cc2-c2ccccc2)c2ccccc2-c2cccc3cccc(-c4ccccc4)c23)c(-c2ccccc2)c1]

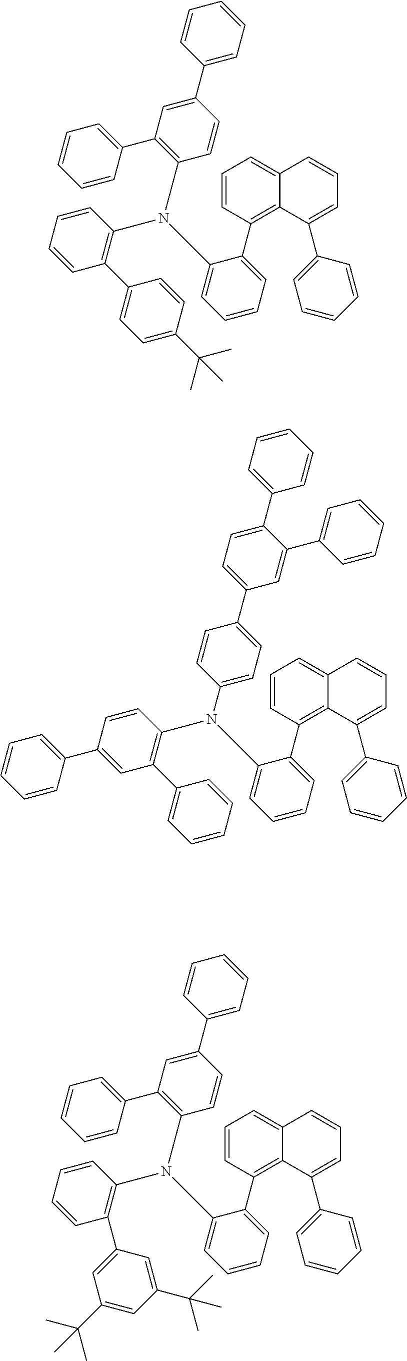 [SMILES: CC(C)(C)c1ccc(-c2ccccc2N(c2ccc(-c3ccccc3)cc2-c2ccccc2)c2ccccc2-c2cccc3cccc(-c4ccccc4)c23)cc1 ; c1ccc(-c2ccc(N(c3ccc(-c4ccc(-c5ccccc5)c(-c5ccccc5)c4)cc3)c3ccccc3-c3cccc4cccc(-c5ccccc5)c34)c(-c3ccccc3)c2)cc1 ; CC(C)(C)c1cc(-c2ccccc2N(c2ccc(-c3ccccc3)cc2-c2ccccc2)c2ccccc2-c2cccc3cccc(-c4ccccc4)c23)cc(C(C)(C)C)c1]

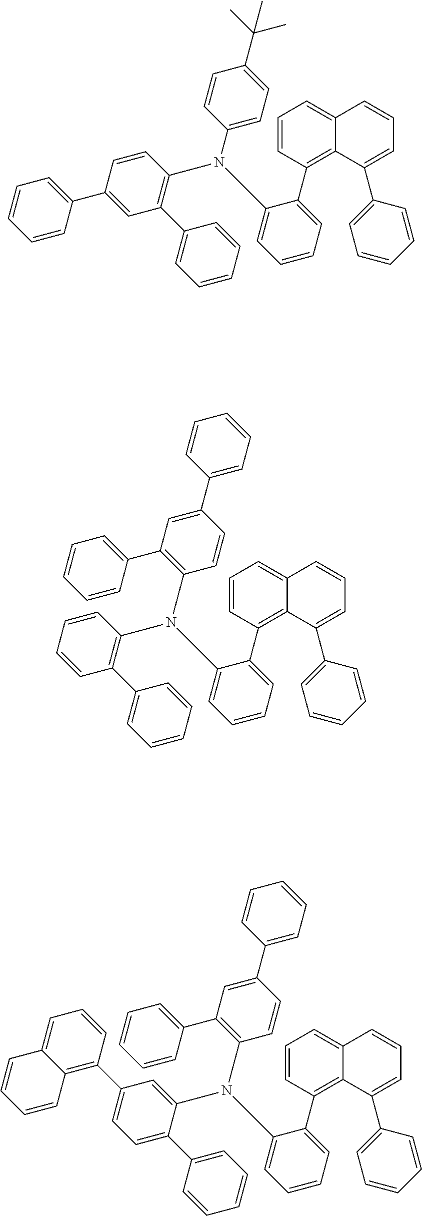 [SMILES: CC(C)(C)c1ccc(N(c2ccc(-c3ccccc3)cc2-c2ccccc2)c2ccccc2-c2cccc3cccc(-c4ccccc4)c23)cc1 ; c1ccc(-c2ccc(N(c3ccccc3-c3ccccc3)c3ccccc3-c3cccc4cccc(-c5ccccc5)c34)c(-c3ccccc3)c2)cc1 ; c1ccc(-c2ccc(N(c3cc(-c4cccc5ccccc45)ccc3-c3ccccc3)c3ccccc3-c3cccc4cccc(-c5ccccc5)c34)c(-c3ccccc3)c2)cc1]

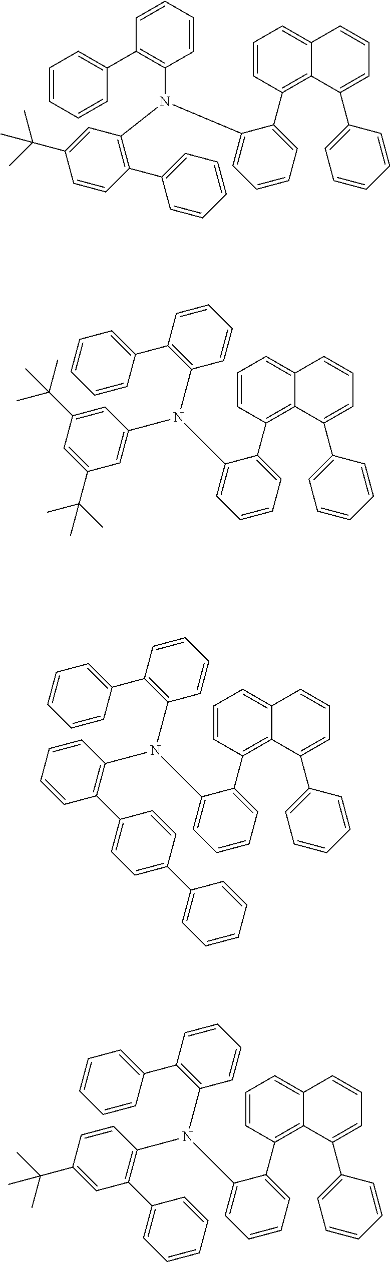 [SMILES: CC(C)(C)c1ccc(-c2ccccc2)c(N(c2ccccc2-c2ccccc2)c2ccccc2-c2cccc3cccc(-c4ccccc4)c23)c1 ; CC(C)(C)c1cc(N(c2ccccc2-c2ccccc2)c2ccccc2-c2cccc3cccc(-c4ccccc4)c23)cc(C(C)(C)C)c1 ; c1ccc(-c2ccc(-c3ccccc3N(c3ccccc3-c3ccccc3)c3ccccc3-c3cccc4cccc(-c5ccccc5)c34)cc2)cc1 ; CC(C)(C)c1ccc(N(c2ccccc2-c2ccccc2)c2ccccc2-c2cccc3cccc(-c4ccccc4)c23)c(-c2ccccc2)c1]

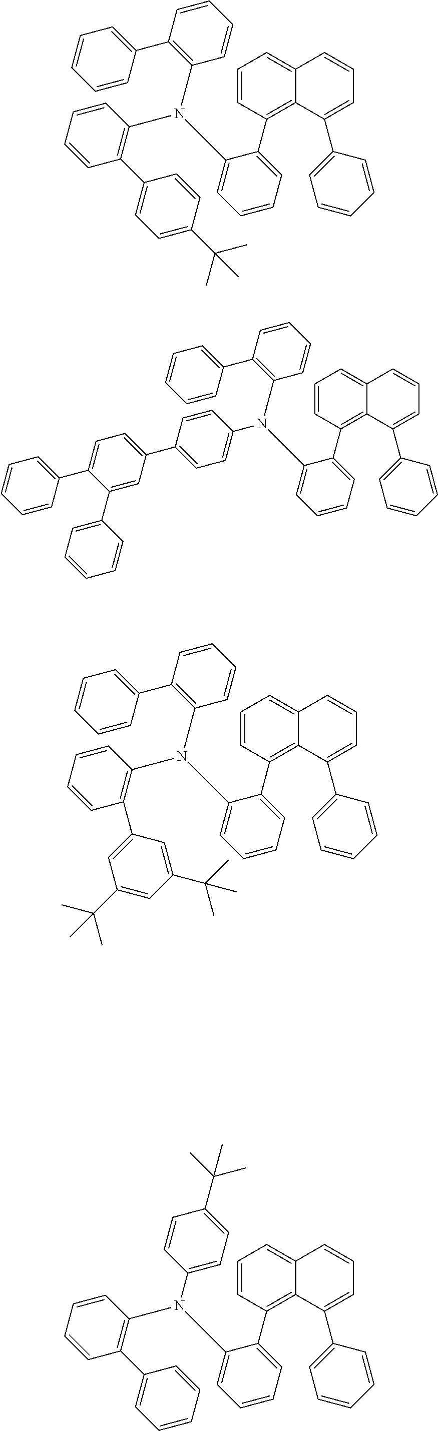 [SMILES: CC(C)(C)c1ccc(-c2ccccc2N(c2ccccc2-c2ccccc2)c2ccccc2-c2cccc3cccc(-c4ccccc4)c23)cc1 ; c1ccc(-c2ccc(-c3ccc(N(c4ccccc4-c4ccccc4)c4ccccc4-c4cccc5cccc(-c6ccccc6)c45)cc3)cc2-c2ccccc2)cc1 ; CC(C)(C)c1cc(-c2ccccc2N(c2ccccc2-c2ccccc2)c2ccccc2-c2cccc3cccc(-c4ccccc4)c23)cc(C(C)(C)C)c1 ; CC(C)(C)c1ccc(N(c2ccccc2-c2ccccc2)c2ccccc2-c2cccc3cccc(-c4ccccc4)c23)cc1]

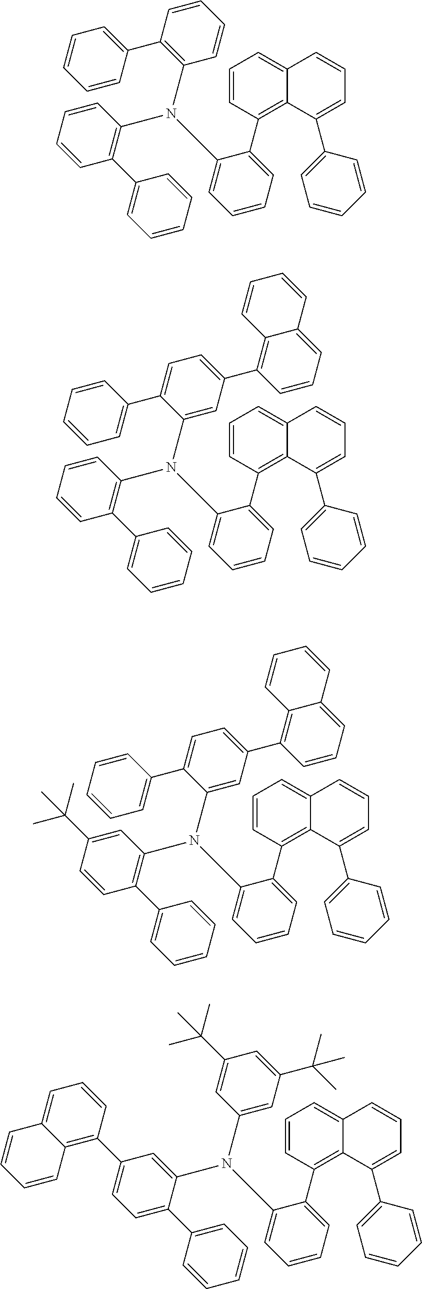 [SMILES: c1ccc(-c2ccccc2N(c2ccccc2-c2ccccc2)c2ccccc2-c2cccc3cccc(-c4ccccc4)c23)cc1 ; c1ccc(-c2ccccc2N(c2cc(-c3cccc4ccccc34)ccc2-c2ccccc2)c2ccccc2-c2cccc3cccc(-c4ccccc4)c23)cc1 ; CC(C)(C)c1ccc(-c2ccccc2)c(N(c2cc(-c3cccc4ccccc34)ccc2-c2ccccc2)c2ccccc2-c2cccc3cccc(-c4ccccc4)c23)c1 ; CC(C)(C)c1cc(N(c2cc(-c3cccc4ccccc34)ccc2-c2ccccc2)c2ccccc2-c2cccc3cccc(-c4ccccc4)c23)cc(C(C)(C)C)c1]

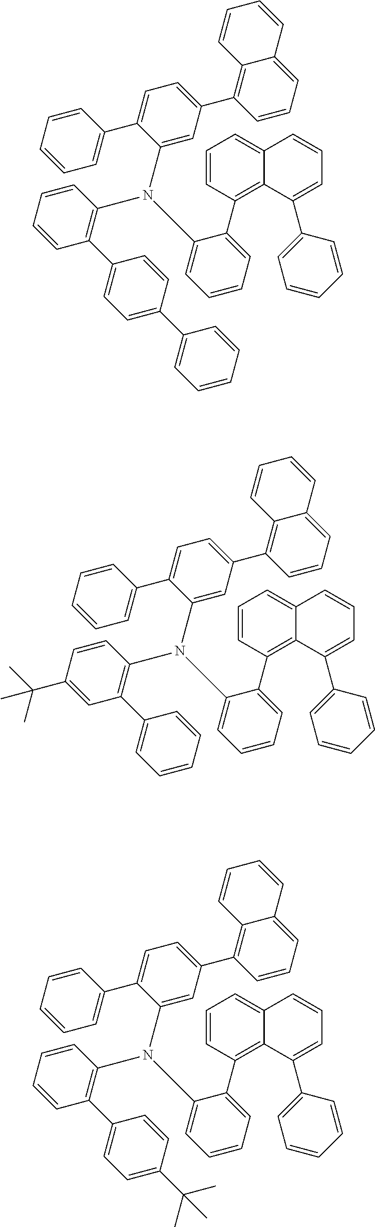 [SMILES: c1ccc(-c2ccc(-c3ccccc3N(c3cc(-c4cccc5ccccc45)ccc3-c3ccccc3)c3ccccc3-c3cccc4cccc(-c5ccccc5)c34)cc2)cc1 ; CC(C)(C)c1ccc(N(c2cc(-c3cccc4ccccc34)ccc2-c2ccccc2)c2ccccc2-c2cccc3cccc(-c4ccccc4)c23)c(-c2ccccc2)c1 ; CC(C)(C)c1ccc(-c2ccccc2N(c2cc(-c3cccc4ccccc34)ccc2-c2ccccc2)c2ccccc2-c2cccc3cccc(-c4ccccc4)c23)cc1]

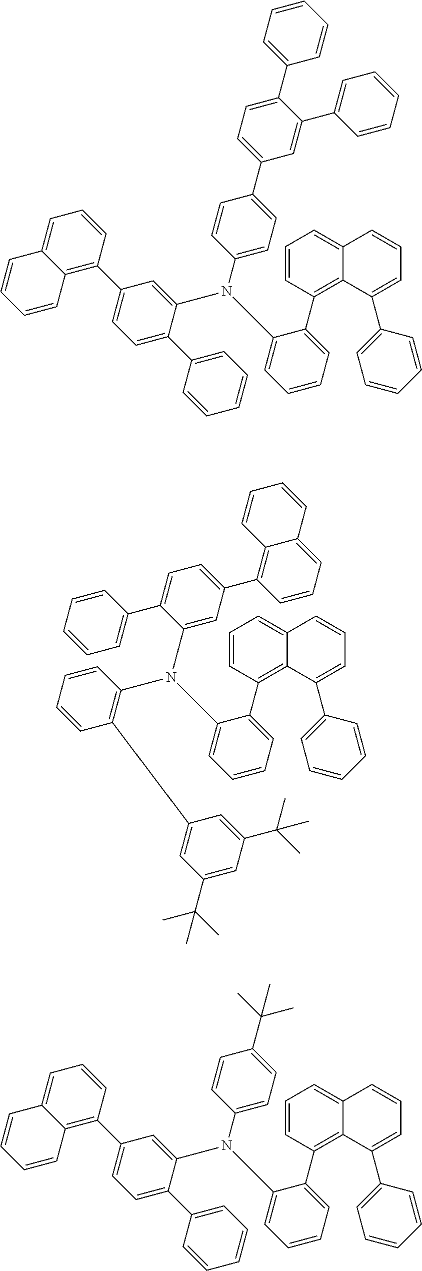 [SMILES: c1ccc(-c2ccc(-c3ccc(N(c4cc(-c5cccc6ccccc56)ccc4-c4ccccc4)c4ccccc4-c4cccc5cccc(-c6ccccc6)c45)cc3)cc2-c2ccccc2)cc1 ; CC(C)(C)c1cc(-c2ccccc2N(c2cc(-c3cccc4ccccc34)ccc2-c2ccccc2)c2ccccc2-c2cccc3cccc(-c4ccccc4)c23)cc(C(C)(C)C)c1 ; CC(C)(C)c1ccc(N(c2cc(-c3cccc4ccccc34)ccc2-c2ccccc2)c2ccccc2-c2cccc3cccc(-c4ccccc4)c23)cc1]

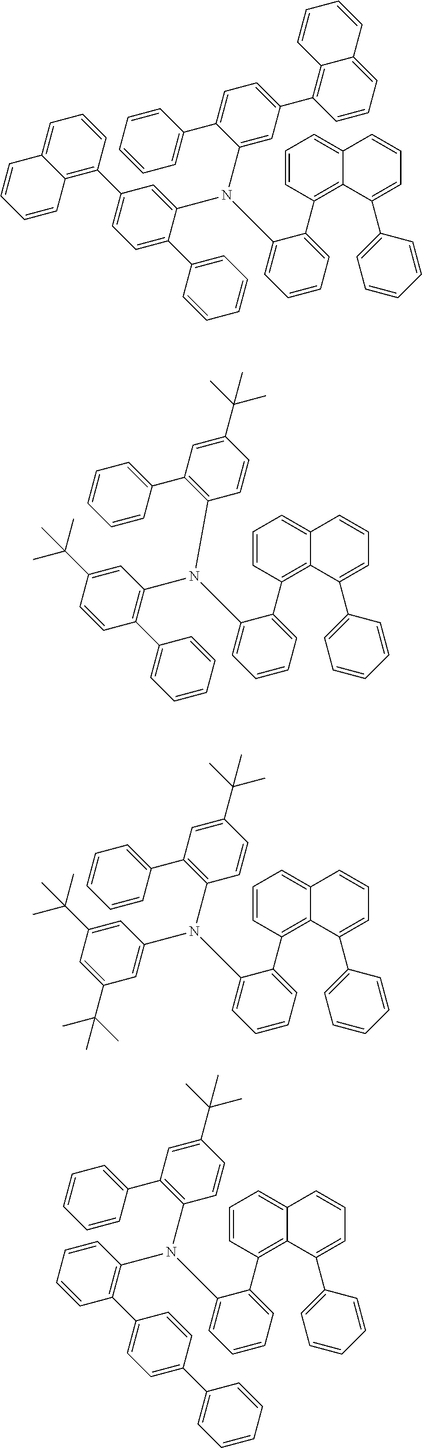 [SMILES: c1ccc(-c2ccc(-c3cccc4ccccc34)cc2N(c2cc(-c3cccc4ccccc34)ccc2-c2ccccc2)c2ccccc2-c2cccc3cccc(-c4ccccc4)c23)cc1 ; CC(C)(C)c1ccc(N(c2cc(C(C)(C)C)ccc2-c2ccccc2)c2ccccc2-c2cccc3cccc(-c4ccccc4)c23)c(-c2ccccc2)c1 ; CC(C)(C)c1cc(N(c2ccc(C(C)(C)C)cc2-c2ccccc2)c2ccccc2-c2cccc3cccc(-c4ccccc4)c23)cc(C(C)(C)C)c1 ; CC(C)(C)c1ccc(N(c2ccccc2-c2ccc(-c3ccccc3)cc2)c2ccccc2-c2cccc3cccc(-c4ccccc4)c23)c(-c2ccccc2)c1]

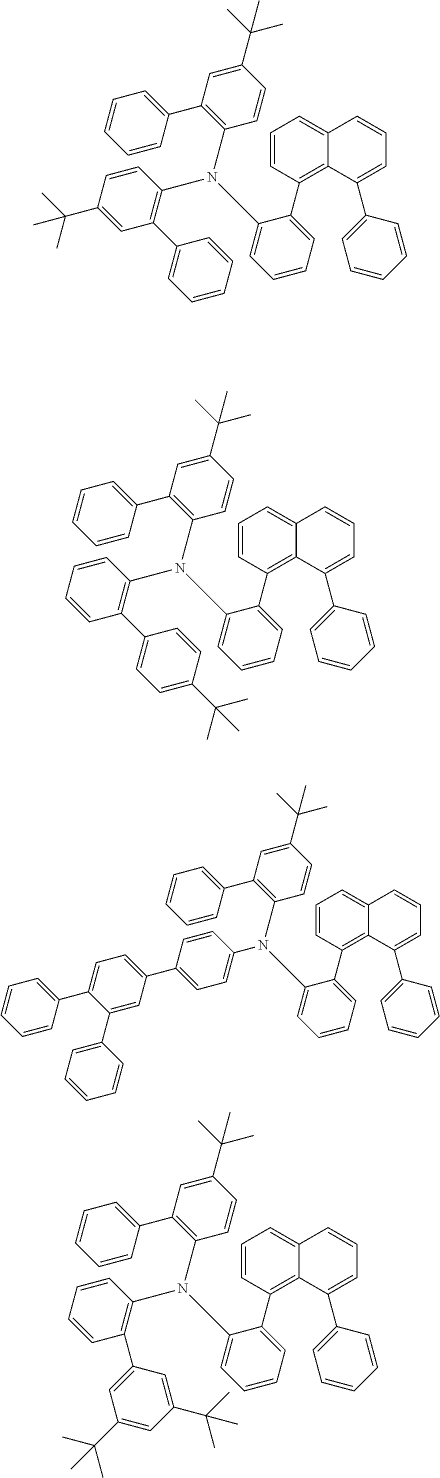 [SMILES: CC(C)(C)c1ccc(N(c2ccc(C(C)(C)C)cc2-c2ccccc2)c2ccccc2-c2cccc3cccc(-c4ccccc4)c23)c(-c2ccccc2)c1 ; CC(C)(C)c1ccc(-c2ccccc2N(c2ccc(C(C)(C)C)cc2-c2ccccc2)c2ccccc2-c2cccc3cccc(-c4ccccc4)c23)cc1 ; CC(C)(C)c1ccc(N(c2ccc(-c3ccc(-c4ccccc4)c(-c4ccccc4)c3)cc2)c2ccccc2-c2cccc3cccc(-c4ccccc4)c23)c(-c2ccccc2)c1 ; CC(C)(C)c1cc(-c2ccccc2N(c2ccc(C(C)(C)C)cc2-c2ccccc2)c2ccccc2-c2cccc3cccc(-c4ccccc4)c23)cc(C(C)(C)C)c1]

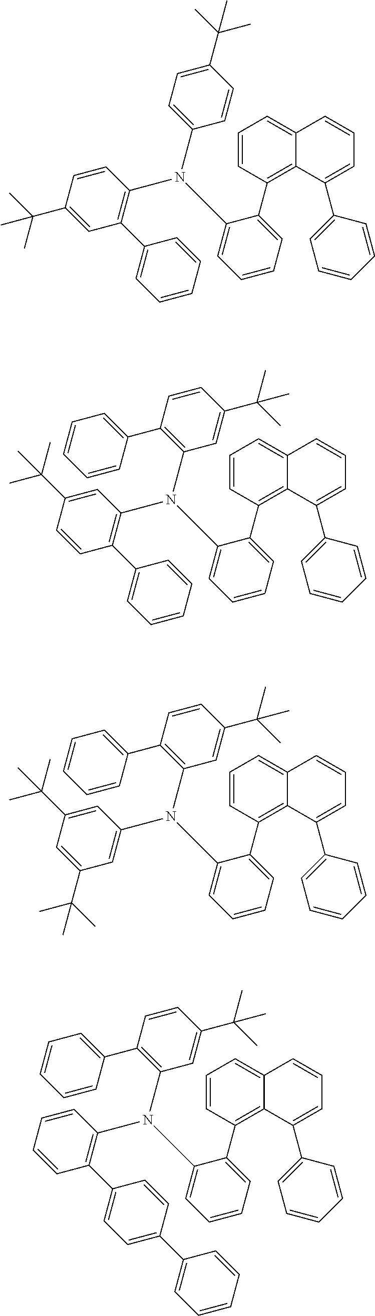 [SMILES: CC(C)(C)c1ccc(N(c2ccc(C(C)(C)C)cc2-c2ccccc2)c2ccccc2-c2cccc3cccc(-c4ccccc4)c23)cc1 ; CC(C)(C)c1ccc(-c2ccccc2)c(N(c2cc(C(C)(C)C)ccc2-c2ccccc2)c2ccccc2-c2cccc3cccc(-c4ccccc4)c23)c1 ; CC(C)(C)c1cc(N(c2cc(C(C)(C)C)ccc2-c2ccccc2)c2ccccc2-c2cccc3cccc(-c4ccccc4)c23)cc(C(C)(C)C)c1 ; CC(C)(C)c1ccc(-c2ccccc2)c(N(c2ccccc2-c2ccc(-c3ccccc3)cc2)c2ccccc2-c2cccc3cccc(-c4ccccc4)c23)c1]

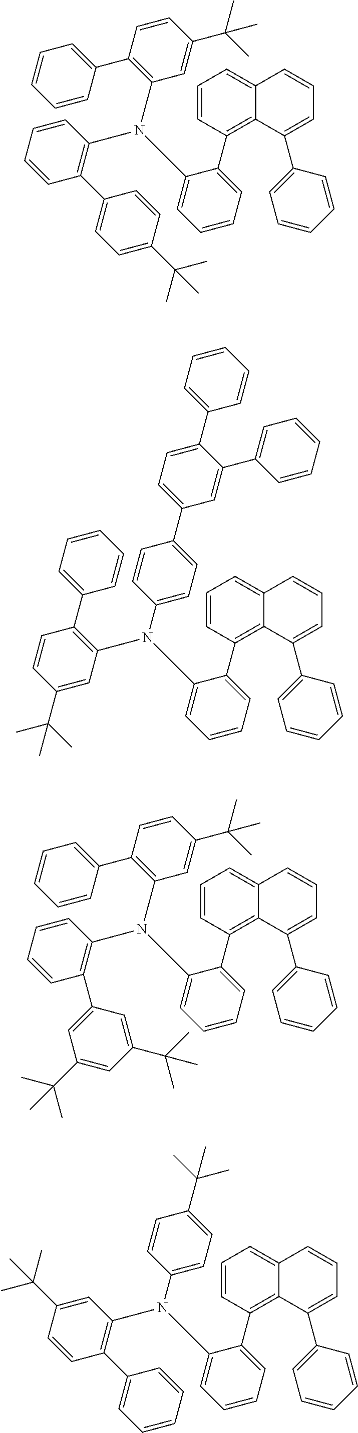 [SMILES: CC(C)(C)c1ccc(-c2ccccc2N(c2cc(C(C)(C)C)ccc2-c2ccccc2)c2ccccc2-c2cccc3cccc(-c4ccccc4)c23)cc1 ; CC(C)(C)c1ccc(-c2ccccc2)c(N(c2ccc(-c3ccc(-c4ccccc4)c(-c4ccccc4)c3)cc2)c2ccccc2-c2cccc3cccc(-c4ccccc4)c23)c1 ; CC(C)(C)c1cc(-c2ccccc2N(c2cc(C(C)(C)C)ccc2-c2ccccc2)c2ccccc2-c2cccc3cccc(-c4ccccc4)c23)cc(C(C)(C)C)c1 ; CC(C)(C)c1ccc(N(c2cc(C(C)(C)C)ccc2-c2ccccc2)c2ccccc2-c2cccc3cccc(-c4ccccc4)c23)cc1]

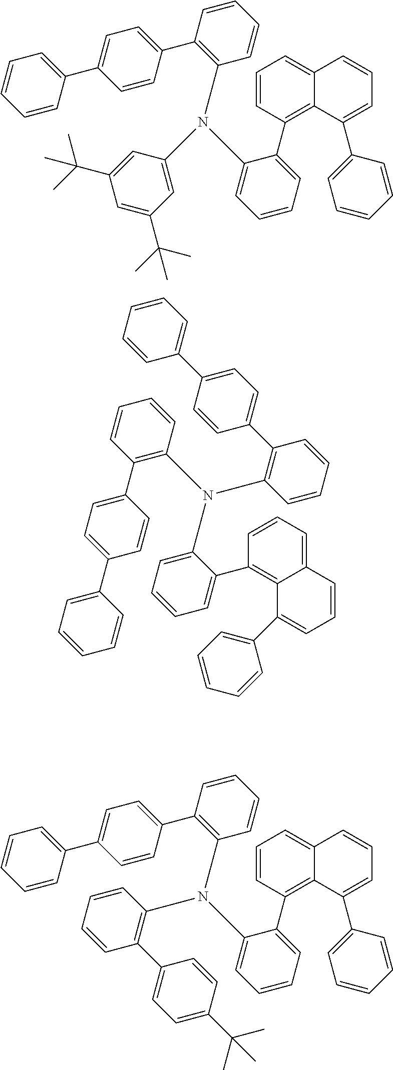

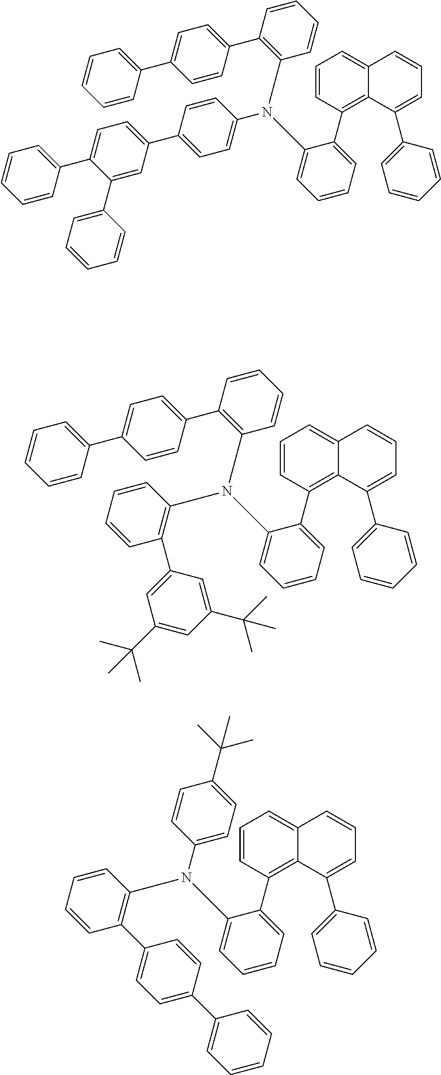 [SMILES: c1ccc(-c2ccc(-c3ccccc3N(c3ccc(-c4ccc(-c5ccccc5)c(-c5ccccc5)c4)cc3)c3ccccc3-c3cccc4cccc(-c5ccccc5)c34)cc2)cc1 ; CC(C)(C)c1cc(-c2ccccc2N(c2ccccc2-c2ccc(-c3ccccc3)cc2)c2ccccc2-c2cccc3cccc(-c4ccccc4)c23)cc(C(C)(C)C)c1 ; CC(C)(C)c1ccc(N(c2ccccc2-c2ccc(-c3ccccc3)cc2)c2ccccc2-c2cccc3cccc(-c4ccccc4)c23)cc1]

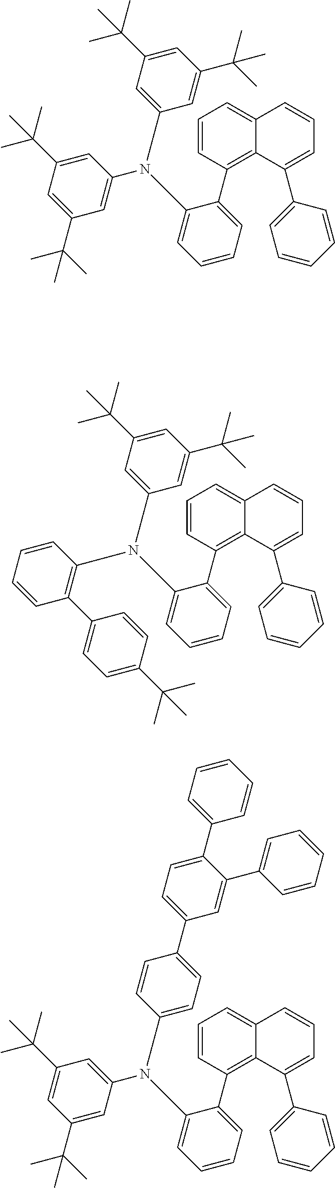 [SMILES: CC(C)(C)c1cc(N(c2cc(C(C)(C)C)cc(C(C)(C)C)c2)c2ccccc2-c2cccc3cccc(-c4ccccc4)c23)cc(C(C)(C)C)c1 ; CC(C)(C)c1ccc(-c2ccccc2N(c2cc(C(C)(C)C)cc(C(C)(C)C)c2)c2ccccc2-c2cccc3cccc(-c4ccccc4)c23)cc1 ; CC(C)(C)c1cc(N(c2ccc(-c3ccc(-c4ccccc4)c(-c4ccccc4)c3)cc2)c2ccccc2-c2cccc3cccc(-c4ccccc4)c23)cc(C(C)(C)C)c1]

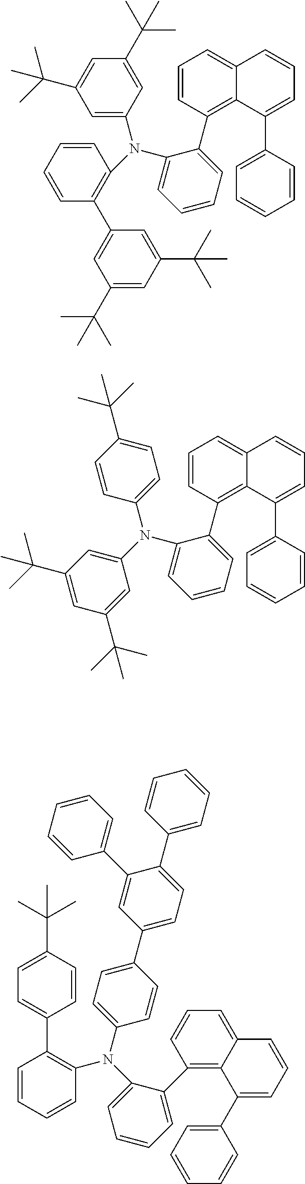

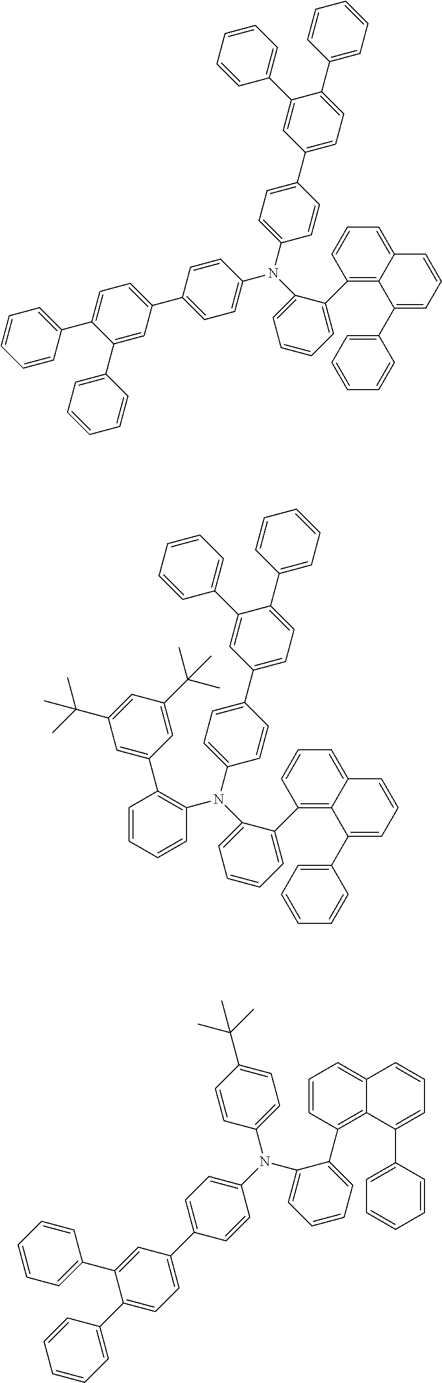 [SMILES: c1ccc(-c2ccc(-c3ccc(N(c4ccc(-c5ccc(-c6ccccc6)c(-c6ccccc6)c5)cc4)c4ccccc4-c4cccc5cccc(-c6ccccc6)c45)cc3)cc2-c2ccccc2)cc1 ; CC(C)(C)c1cc(-c2ccccc2N(c2ccc(-c3ccc(-c4ccccc4)c(-c4ccccc4)c3)cc2)c2ccccc2-c2cccc3cccc(-c4ccccc4)c23)cc(C(C)(C)C)c1 ; CC(C)(C)c1ccc(N(c2ccc(-c3ccc(-c4ccccc4)c(-c4ccccc4)c3)cc2)c2ccccc2-c2cccc3cccc(-c4ccccc4)c23)cc1]

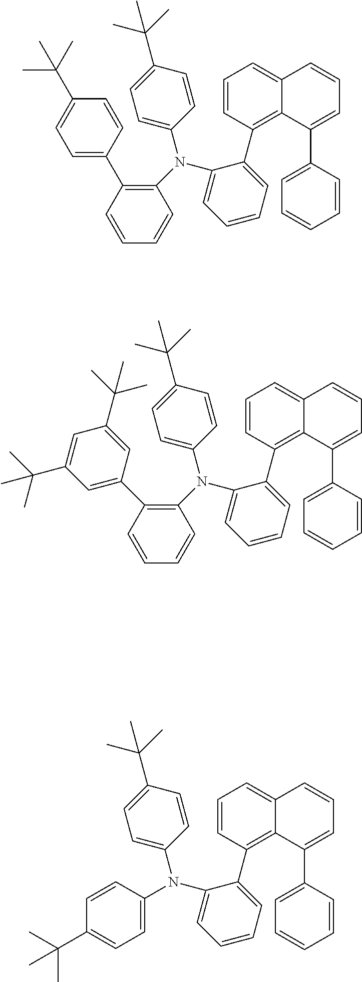 [SMILES: CC(C)(C)c1ccc(-c2ccccc2N(c2ccc(C(C)(C)C)cc2)c2ccccc2-c2cccc3cccc(-c4ccccc4)c23)cc1 ; CC(C)(C)c1ccc(N(c2ccccc2-c2cc(C(C)(C)C)cc(C(C)(C)C)c2)c2ccccc2-c2cccc3cccc(-c4ccccc4)c23)cc1 ; CC(C)(C)c1ccc(N(c2ccc(C(C)(C)C)cc2)c2ccccc2-c2cccc3cccc(-c4ccccc4)c23)cc1]

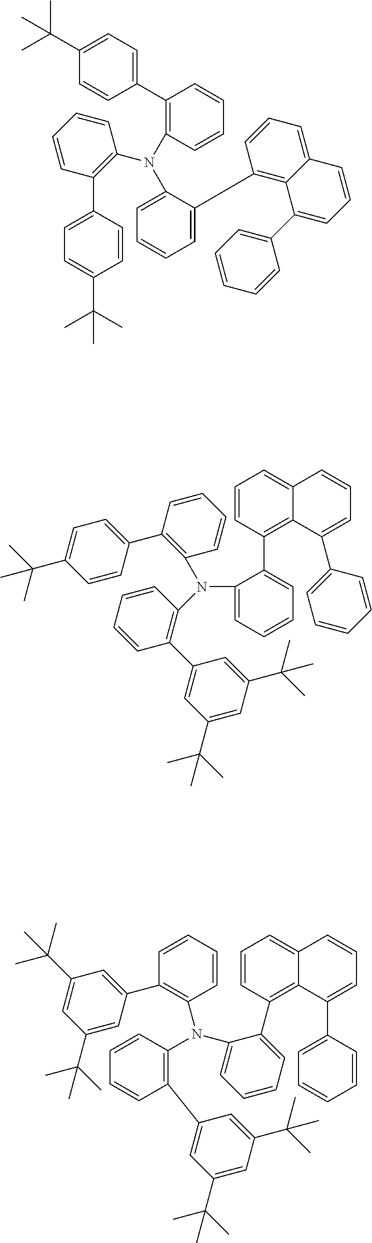 [SMILES: CC(C)(C)c1ccc(-c2ccccc2N(c2ccccc2-c2ccc(C(C)(C)C)cc2)c2ccccc2-c2cccc3cccc(-c4ccccc4)c23)cc1 ; CC(C)(C)c1ccc(-c2ccccc2N(c2ccccc2-c2cc(C(C)(C)C)cc(C(C)(C)C)c2)c2ccccc2-c2cccc3cccc(-c4ccccc4)c23)cc1 ; CC(C)(C)c1cc(-c2ccccc2N(c2ccccc2-c2cc(C(C)(C)C)cc(C(C)(C)C)c2)c2ccccc2-c2cccc3cccc(-c4ccccc4)c23)cc(C(C)(C)C)c1]

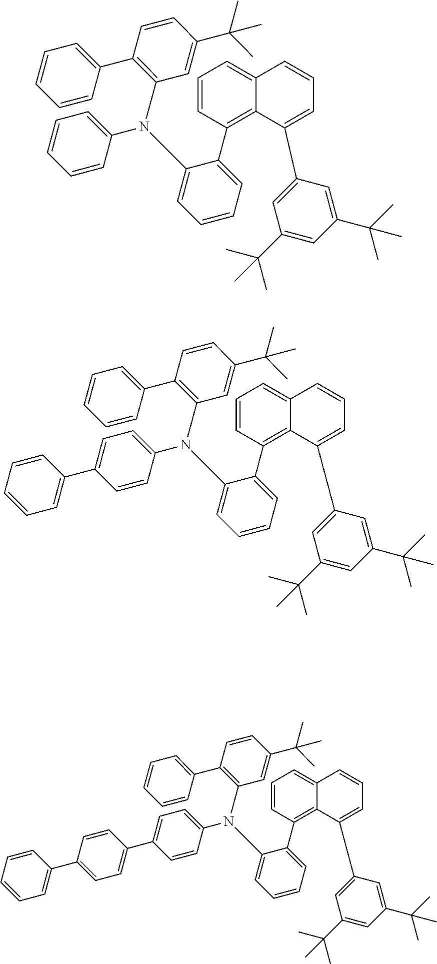

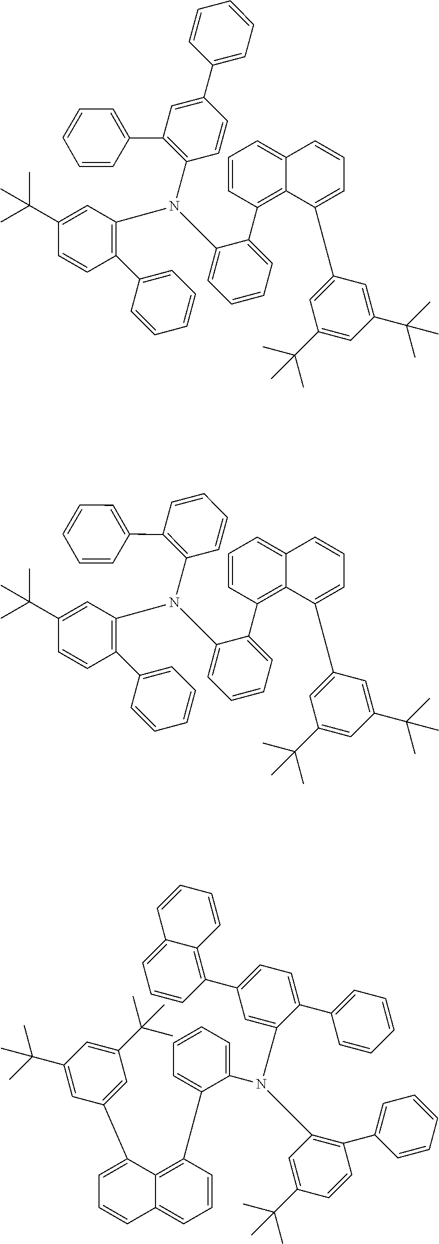

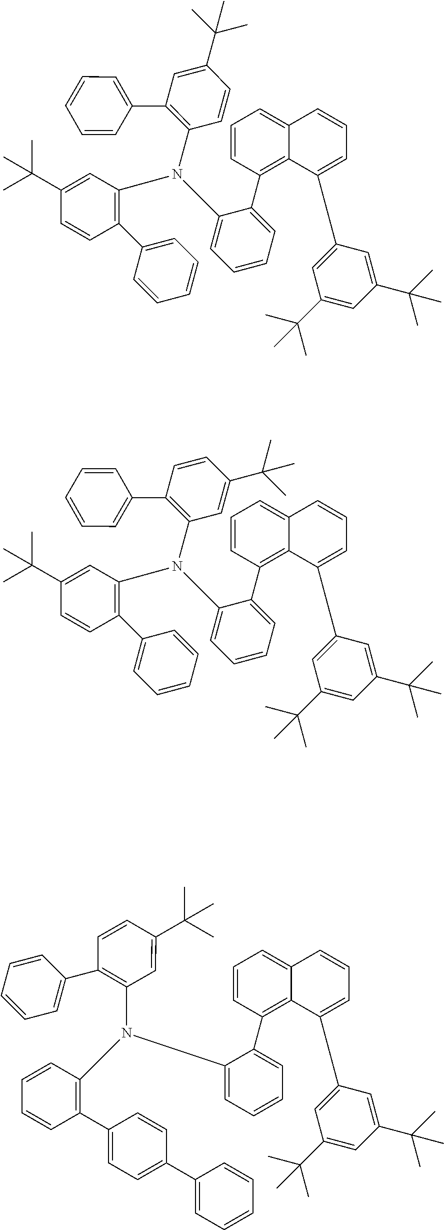

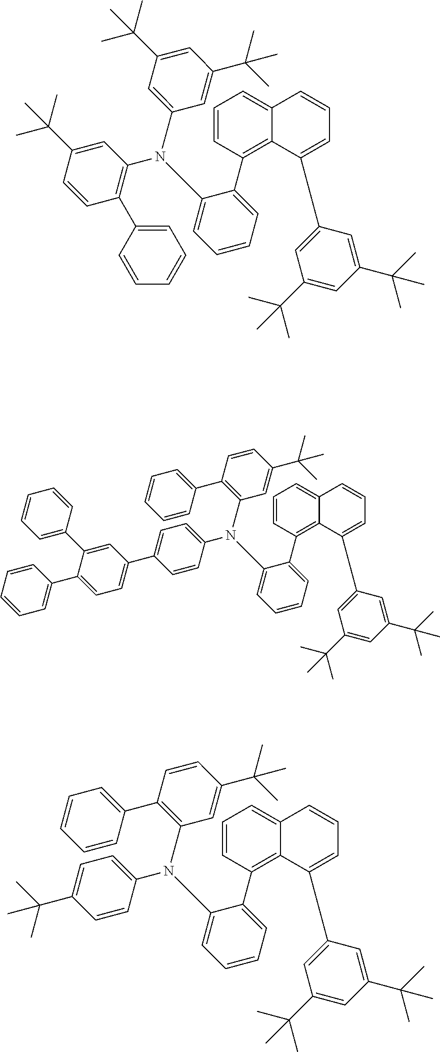

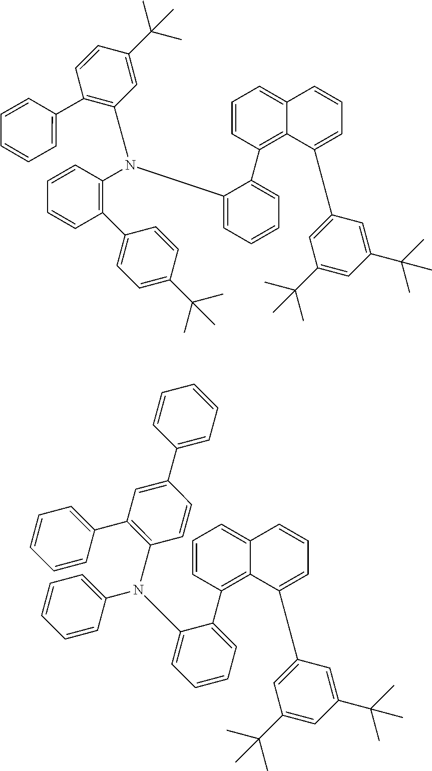 [SMILES: CC(C)(C)c1ccc(-c2ccccc2N(c2cc(C(C)(C)C)ccc2-c2ccccc2)c2ccccc2-c2cccc3cccc(-c4cc(C(C)(C)C)cc(C(C)(C)C)c4)c23)cc1 ; CC(C)(C)c1cc(-c2cccc3cccc(-c4ccccc4N(c4ccccc4)c4ccc(-c5ccccc5)cc4-c4ccccc4)c23)cc(C(C)(C)C)c1]

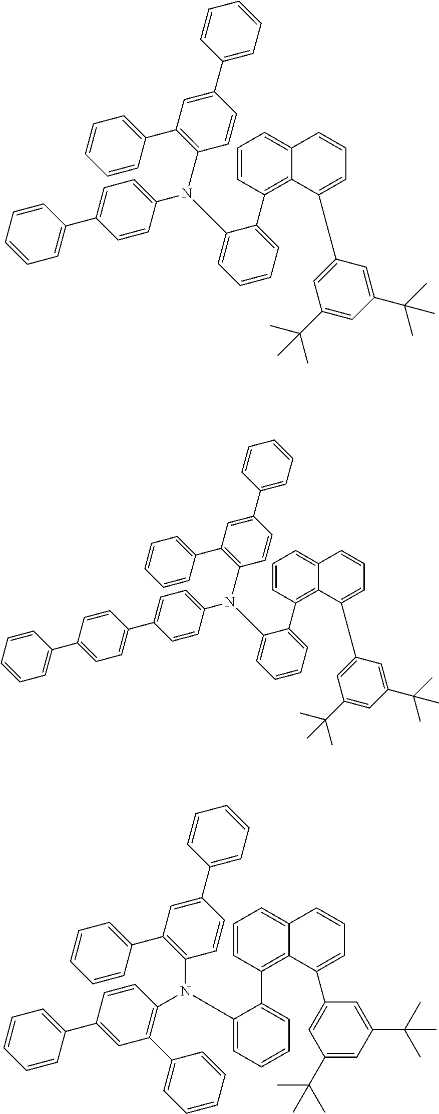 [SMILES: CC(C)(C)c1cc(-c2cccc3cccc(-c4ccccc4N(c4ccc(-c5ccccc5)cc4)c4ccc(-c5ccccc5)cc4-c4ccccc4)c23)cc(C(C)(C)C)c1 ; CC(C)(C)c1cc(-c2cccc3cccc(-c4ccccc4N(c4ccc(-c5ccc(-c6ccccc6)cc5)cc4)c4ccc(-c5ccccc5)cc4-c4ccccc4)c23)cc(C(C)(C)C)c1 ; CC(C)(C)c1cc(-c2cccc3cccc(-c4ccccc4N(c4ccc(-c5ccccc5)cc4-c4ccccc4)c4ccc(-c5ccccc5)cc4-c4ccccc4)c23)cc(C(C)(C)C)c1]

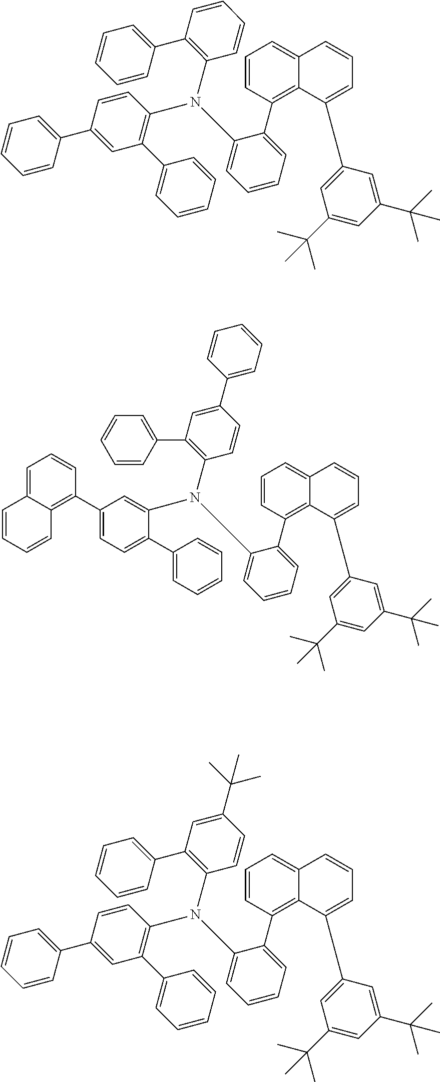 [SMILES: CC(C)(C)c1cc(-c2cccc3cccc(-c4ccccc4N(c4ccccc4-c4ccccc4)c4ccc(-c5ccccc5)cc4-c4ccccc4)c23)cc(C(C)(C)C)c1 ; CC(C)(C)c1cc(-c2cccc3cccc(-c4ccccc4N(c4ccc(-c5ccccc5)cc4-c4ccccc4)c4cc(-c5cccc6ccccc56)ccc4-c4ccccc4)c23)cc(C(C)(C)C)c1 ; CC(C)(C)c1cc(-c2cccc3cccc(-c4ccccc4N(c4ccc(-c5ccccc5)cc4-c4ccccc4)c4ccc(C(C)(C)C)cc4-c4ccccc4)c23)cc(C(C)(C)C)c1]

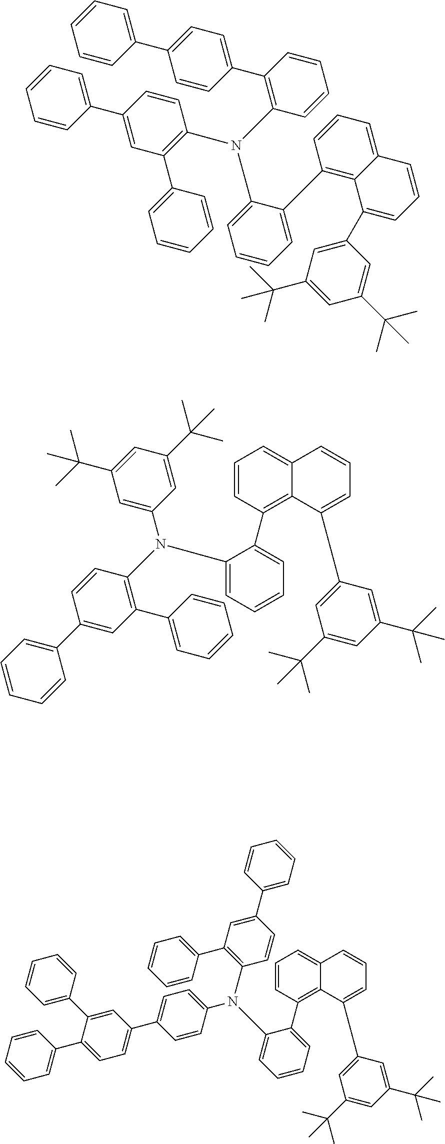 [SMILES: CC(C)(C)c1cc(-c2cccc3cccc(-c4ccccc4N(c4ccccc4-c4ccc(-c5ccccc5)cc4)c4ccc(-c5ccccc5)cc4-c4ccccc4)c23)cc(C(C)(C)C)c1 ; CC(C)(C)c1cc(-c2cccc3cccc(-c4ccccc4N(c4cc(C(C)(C)C)cc(C(C)(C)C)c4)c4ccc(-c5ccccc5)cc4-c4ccccc4)c23)cc(C(C)(C)C)c1 ; CC(C)(C)c1cc(-c2cccc3cccc(-c4ccccc4N(c4ccc(-c5ccc(-c6ccccc6)c(-c6ccccc6)c5)cc4)c4ccc(-c5ccccc5)cc4-c4ccccc4)c23)cc(C(C)(C)C)c1]

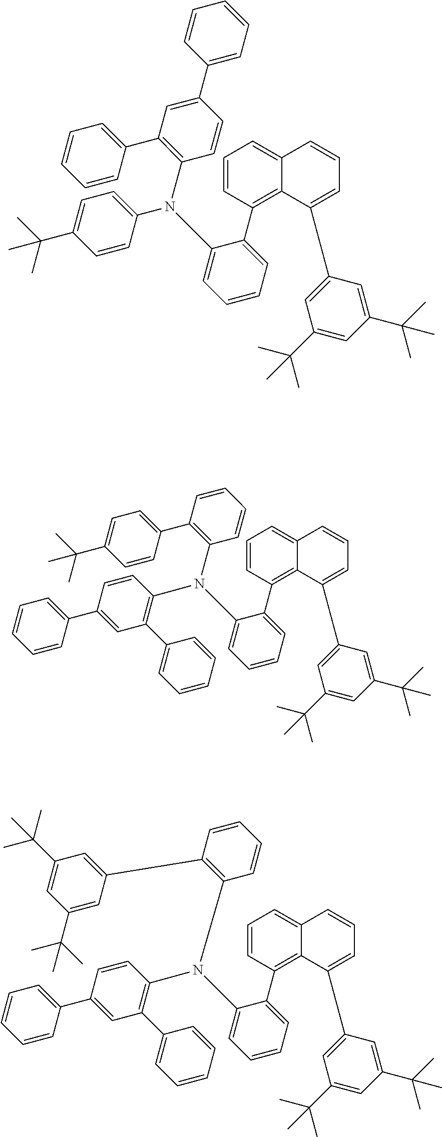 [SMILES: CC(C)(C)c1ccc(N(c2ccc(-c3ccccc3)cc2-c2ccccc2)c2ccccc2-c2cccc3cccc(-c4cc(C(C)(C)C)cc(C(C)(C)C)c4)c23)cc1 ; CC(C)(C)c1ccc(-c2ccccc2N(c2ccc(-c3ccccc3)cc2-c2ccccc2)c2ccccc2-c2cccc3cccc(-c4cc(C(C)(C)C)cc(C(C)(C)C)c4)c23)cc1 ; CC(C)(C)c1cc(-c2ccccc2N(c2ccc(-c3ccccc3)cc2-c2ccccc2)c2ccccc2-c2cccc3cccc(-c4cc(C(C)(C)C)cc(C(C)(C)C)c4)c23)cc(C(C)(C)C)c1]

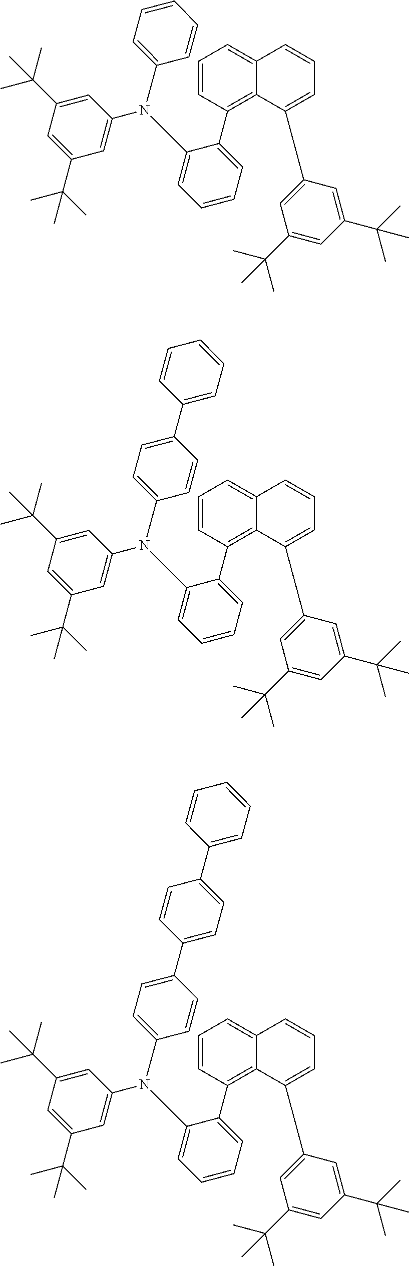

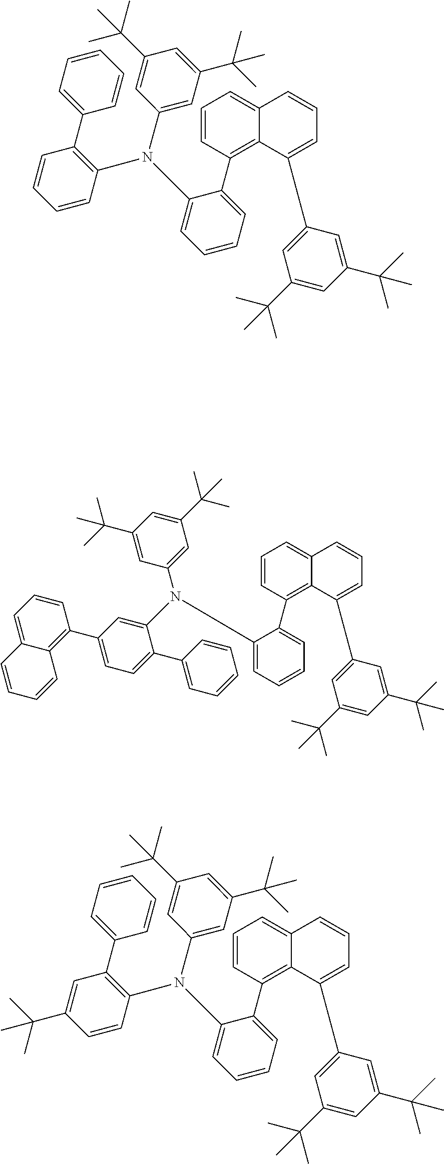

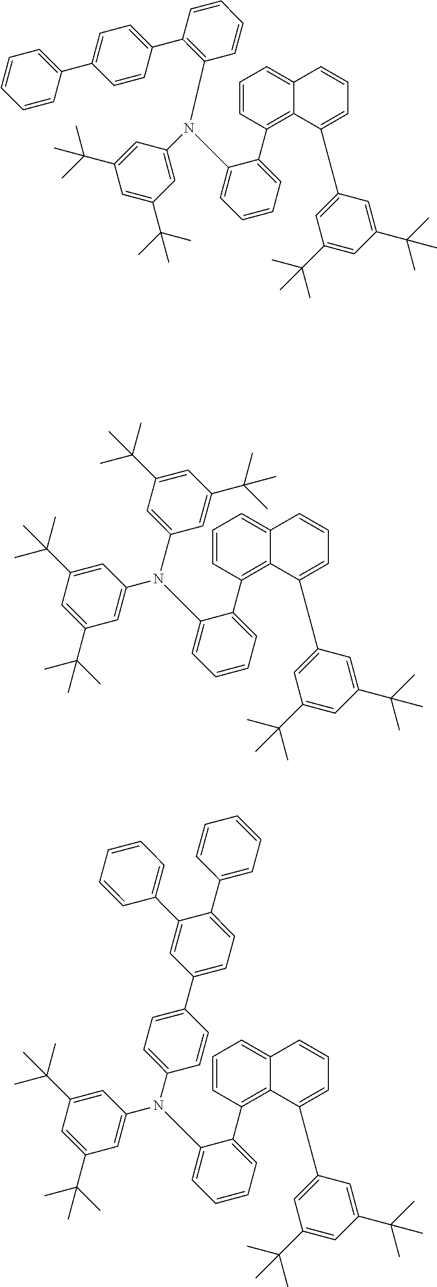

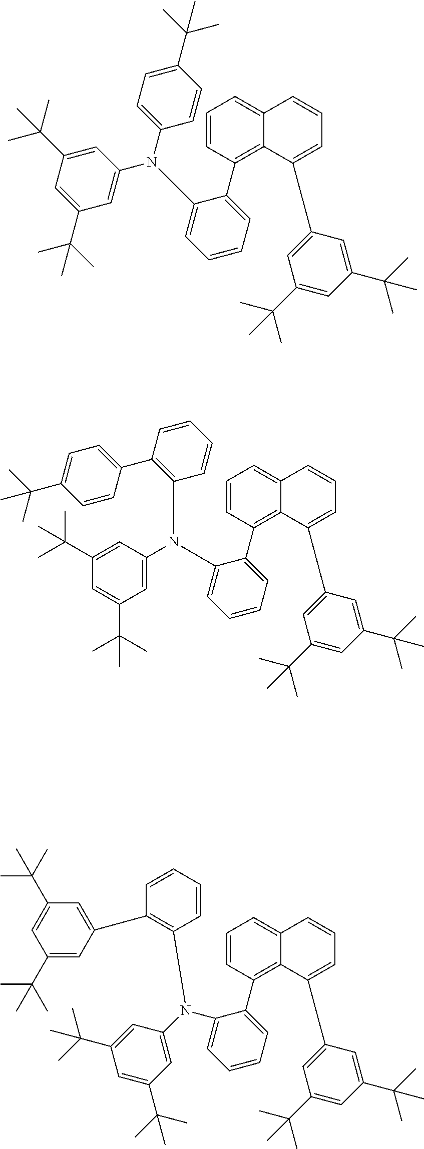

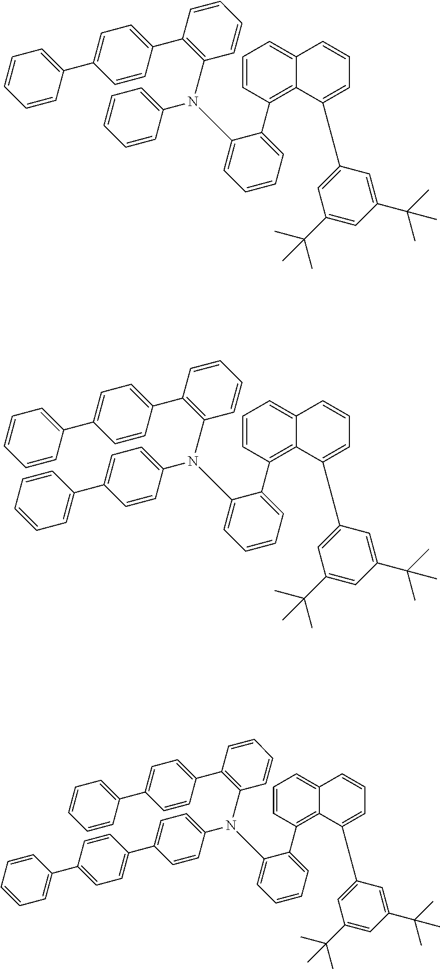 [SMILES: CC(C)(C)c1cc(-c2cccc3cccc(-c4ccccc4N(c4ccccc4)c4ccccc4-c4ccc(-c5ccccc5)cc4)c23)cc(C(C)(C)C)c1 ; CC(C)(C)c1cc(-c2cccc3cccc(-c4ccccc4N(c4ccc(-c5ccccc5)cc4)c4ccccc4-c4ccc(-c5ccccc5)cc4)c23)cc(C(C)(C)C)c1 ; CC(C)(C)c1cc(-c2cccc3cccc(-c4ccccc4N(c4ccc(-c5ccc(-c6ccccc6)cc5)cc4)c4ccccc4-c4ccc(-c5ccccc5)cc4)c23)cc(C(C)(C)C)c1]

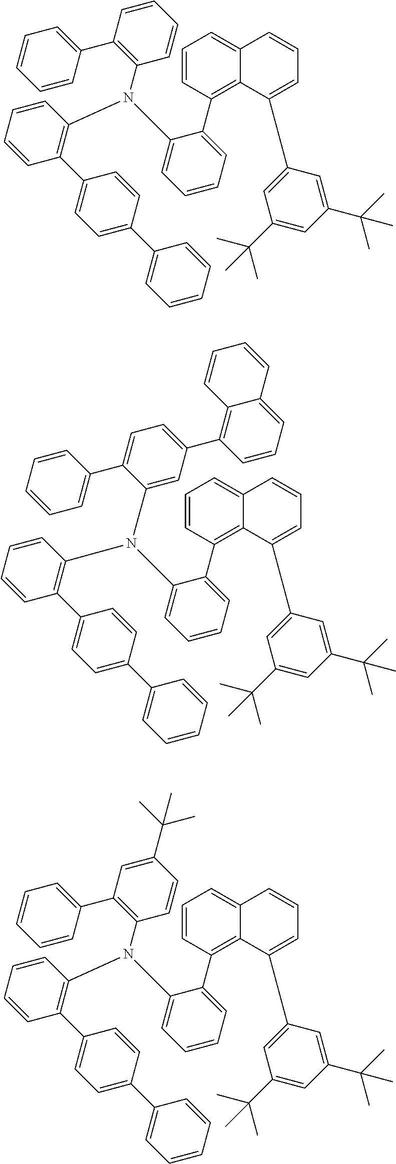 [SMILES: CC(C)(C)c1cc(-c2cccc3cccc(-c4ccccc4N(c4ccccc4-c4ccccc4)c4ccccc4-c4ccc(-c5ccccc5)cc4)c23)cc(C(C)(C)C)c1 ; CC(C)(C)c1cc(-c2cccc3cccc(-c4ccccc4N(c4ccccc4-c4ccc(-c5ccccc5)cc4)c4cc(-c5cccc6ccccc56)ccc4-c4ccccc4)c23)cc(C(C)(C)C)c1 ; CC(C)(C)c1cc(-c2cccc3cccc(-c4ccccc4N(c4ccccc4-c4ccc(-c5ccccc5)cc4)c4ccc(C(C)(C)C)cc4-c4ccccc4)c23)cc(C(C)(C)C)c1]

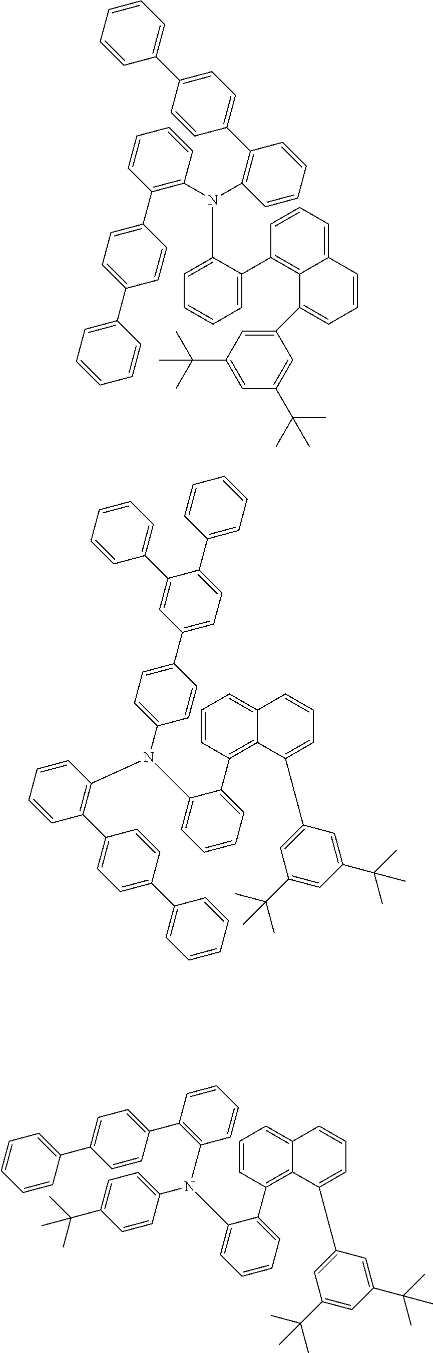 [SMILES: CC(C)(C)c1cc(-c2cccc3cccc(-c4ccccc4N(c4ccccc4-c4ccc(-c5ccccc5)cc4)c4ccccc4-c4ccc(-c5ccccc5)cc4)c23)cc(C(C)(C)C)c1 ; CC(C)(C)c1cc(-c2cccc3cccc(-c4ccccc4N(c4ccc(-c5ccc(-c6ccccc6)c(-c6ccccc6)c5)cc4)c4ccccc4-c4ccc(-c5ccccc5)cc4)c23)cc(C(C)(C)C)c1 ; CC(C)(C)c1ccc(N(c2ccccc2-c2ccc(-c3ccccc3)cc2)c2ccccc2-c2cccc3cccc(-c4cc(C(C)(C)C)cc(C(C)(C)C)c4)c23)cc1]

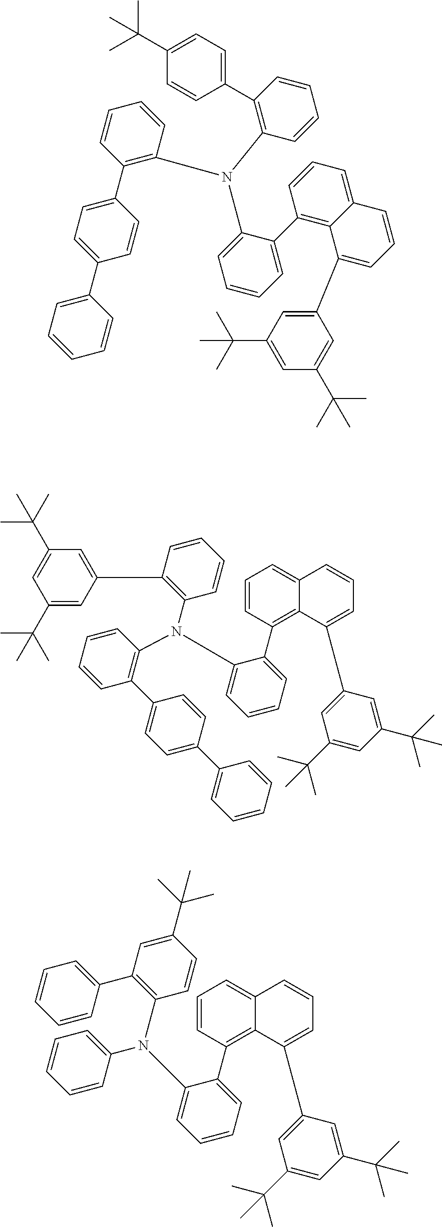 [SMILES: CC(C)(C)c1ccc(-c2ccccc2N(c2ccccc2-c2ccc(-c3ccccc3)cc2)c2ccccc2-c2cccc3cccc(-c4cc(C(C)(C)C)cc(C(C)(C)C)c4)c23)cc1 ; CC(C)(C)c1cc(-c2ccccc2N(c2ccccc2-c2ccc(-c3ccccc3)cc2)c2ccccc2-c2cccc3cccc(-c4cc(C(C)(C)C)cc(C(C)(C)C)c4)c23)cc(C(C)(C)C)c1 ; CC(C)(C)c1cc(-c2cccc3cccc(-c4ccccc4N(c4ccccc4)c4ccc(C(C)(C)C)cc4-c4ccccc4)c23)cc(C(C)(C)C)c1]

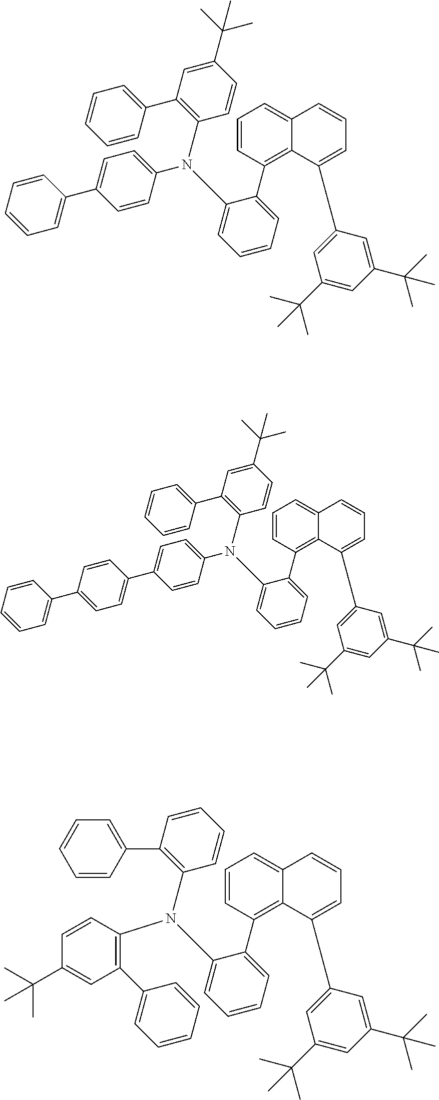

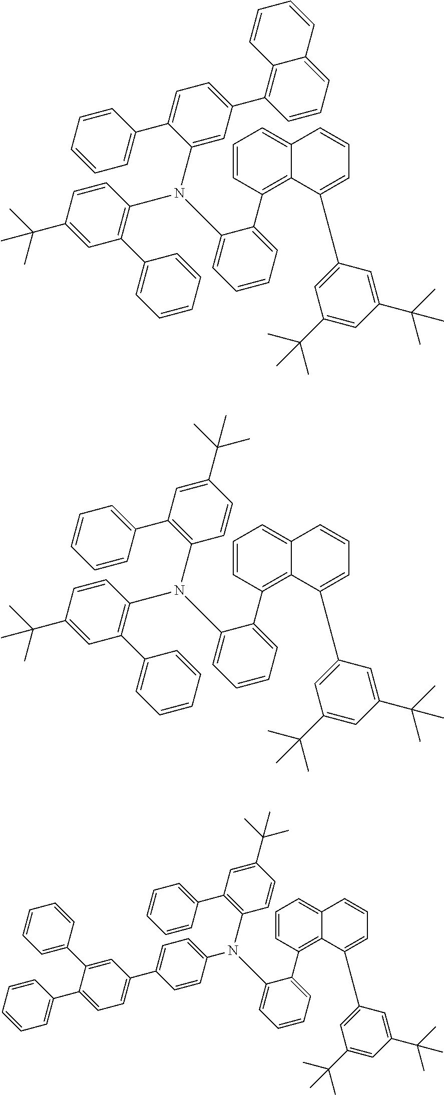

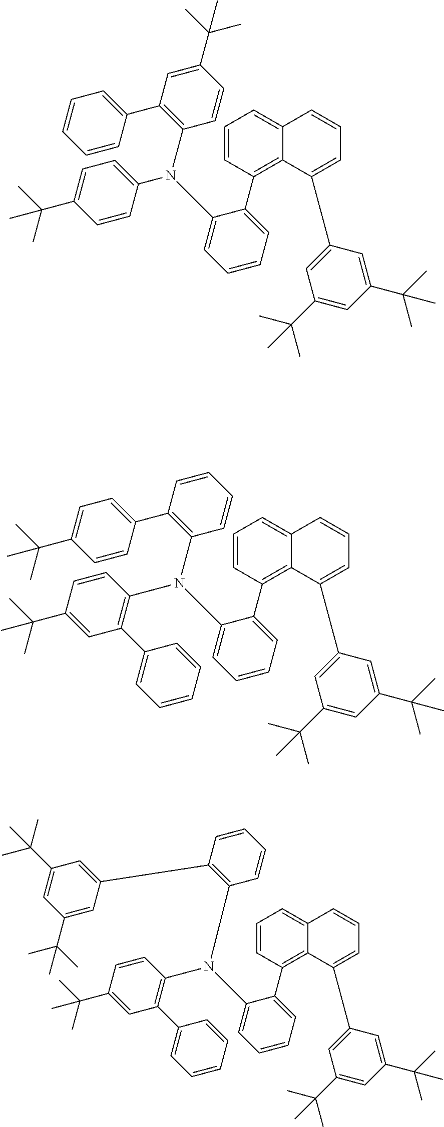

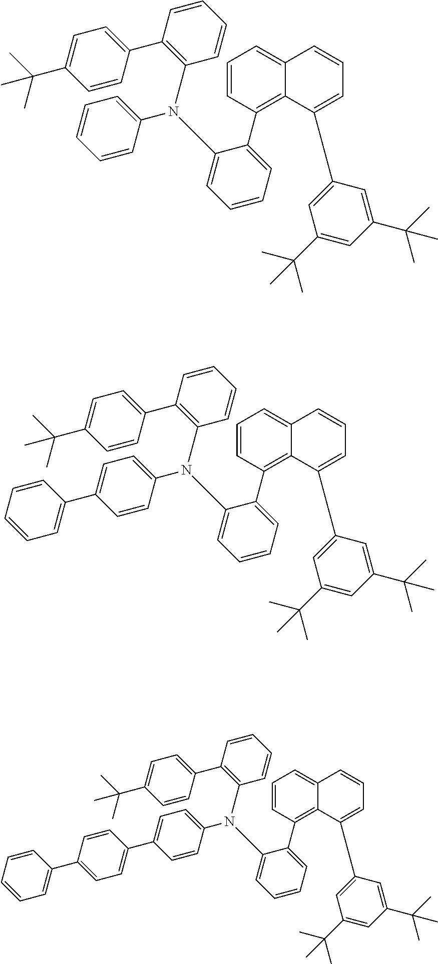 [SMILES: CC(C)(C)c1ccc(-c2ccccc2N(c2ccccc2)c2ccccc2-c2cccc3cccc(-c4cc(C(C)(C)C)cc(C(C)(C)C)c4)c23)cc1 ; CC(C)(C)c1ccc(-c2ccccc2N(c2ccc(-c3ccccc3)cc2)c2ccccc2-c2cccc3cccc(-c4cc(C(C)(C)C)cc(C(C)(C)C)c4)c23)cc1 ; CC(C)(C)c1ccc(-c2ccccc2N(c2ccc(-c3ccc(-c4ccccc4)cc3)cc2)c2ccccc2-c2cccc3cccc(-c4cc(C(C)(C)C)cc(C(C)(C)C)c4)c23)cc1]

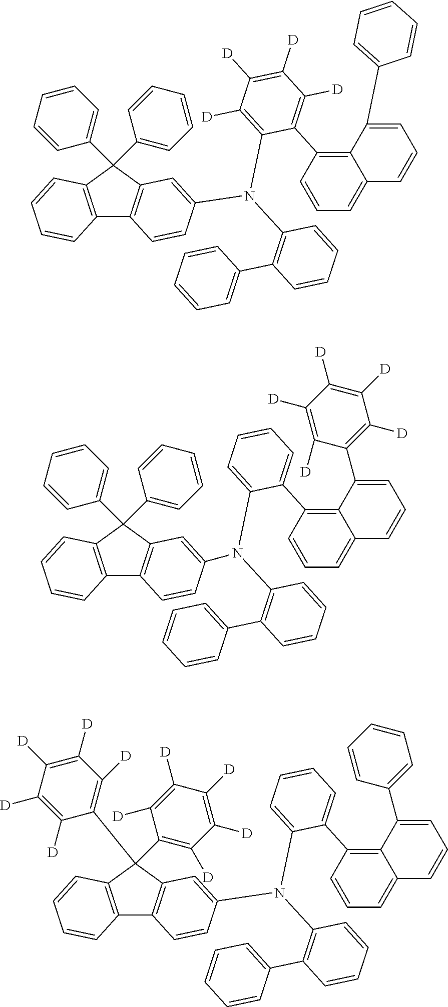 [SMILES: [2H]c1c([2H])c([2H])c(N(c2ccc3c(c2)C(c2ccccc2)(c2ccccc2)c2ccccc2-3)c2ccccc2-c2ccccc2)c(-c2cccc3cccc(-c4ccccc4)c23)c1[2H] ; [2H]c1c([2H])c([2H])c(-c2cccc3cccc(-c4ccccc4N(c4ccc5c(c4)C(c4ccccc4)(c4ccccc4)c4ccccc4-5)c4ccccc4-c4ccccc4)c23)c([2H])c1[2H] ; [2H]c1c([2H])c([2H])c(C2(c3c([2H])c([2H])c([2H])c([2H])c3[2H])c3ccccc3-c3ccc(N(c4ccccc4-c4ccccc4)c4ccccc4-c4cccc5cccc(-c6ccccc6)c45)cc32)c([2H])c1[2H]]

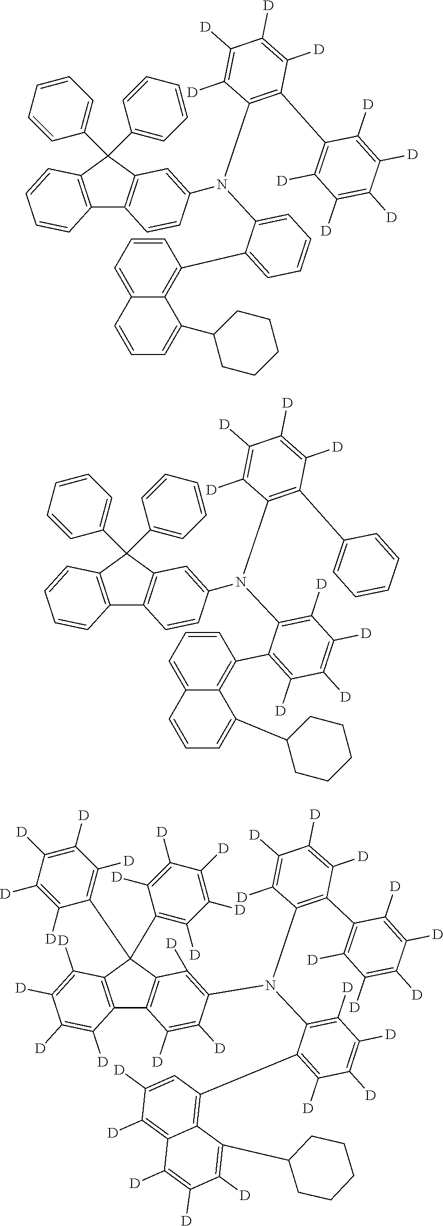

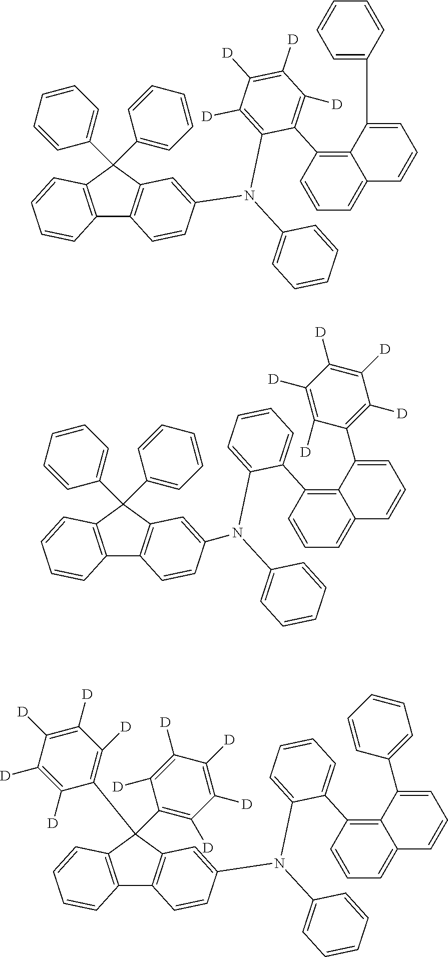 [SMILES: [2H]c1c([2H])c([2H])c(N(c2ccccc2)c2ccc3c(c2)C(c2ccccc2)(c2ccccc2)c2ccccc2-3)c(-c2cccc3cccc(-c4ccccc4)c23)c1[2H] ; [2H]c1c([2H])c([2H])c(-c2cccc3cccc(-c4ccccc4N(c4ccccc4)c4ccc5c(c4)C(c4ccccc4)(c4ccccc4)c4ccccc4-5)c23)c([2H])c1[2H] ; [2H]c1c([2H])c([2H])c(C2(c3c([2H])c([2H])c([2H])c([2H])c3[2H])c3ccccc3-c3ccc(N(c4ccccc4)c4ccccc4-c4cccc5cccc(-c6ccccc6)c45)cc32)c([2H])c1[2H]]

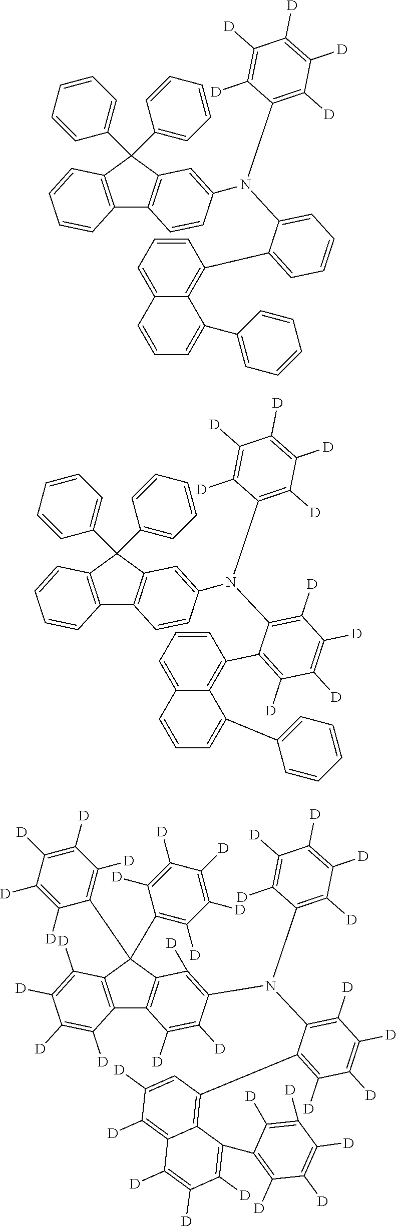

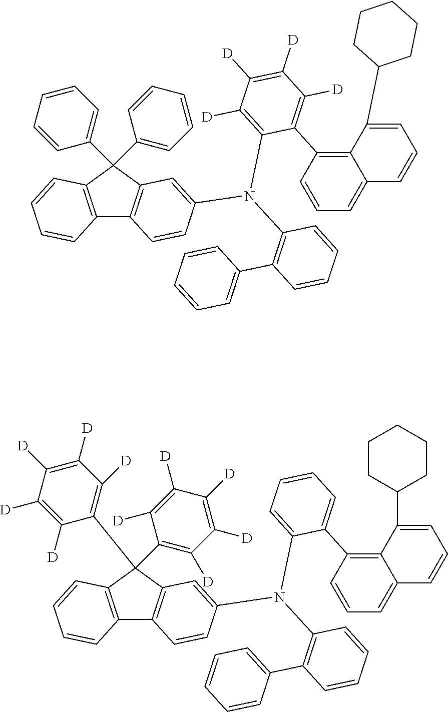 [SMILES: [2H]c1c([2H])c([2H])c(N(c2ccc3c(c2)C(c2ccccc2)(c2ccccc2)c2ccccc2-3)c2ccccc2-c2ccccc2)c(-c2cccc3cccc(C4CCCCC4)c23)c1[2H] ; [2H]c1c([2H])c([2H])c(C2(c3c([2H])c([2H])c([2H])c([2H])c3[2H])c3ccccc3-c3ccc(N(c4ccccc4-c4ccccc4)c4ccccc4-c4cccc5cccc(C6CCCCC6)c45)cc32)c([2H])c1[2H]]

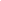

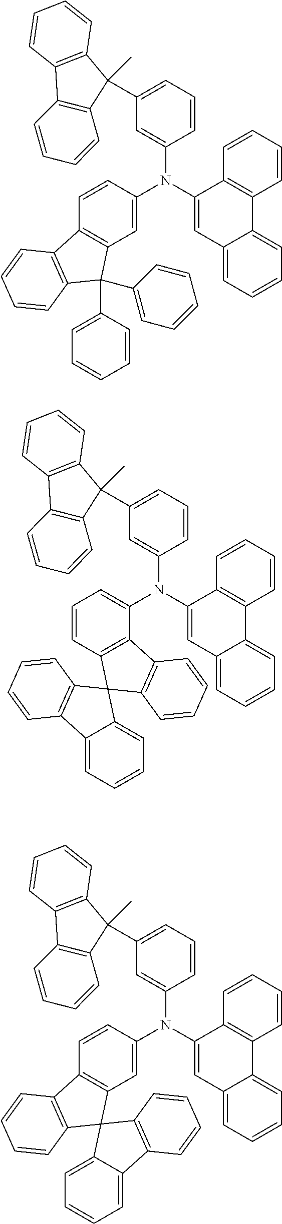 [SMILES: CC1(c2cccc(N(c3ccc4c(c3)C(c3ccccc3)(c3ccccc3)c3ccccc3-4)c3cc4ccccc4c4ccccc34)c2)c2ccccc2-c2ccccc21 ; CC1(c2cccc(N(c3cccc4c3-c3ccccc3C43c4ccccc4-c4ccccc43)c3cc4ccccc4c4ccccc34)c2)c2ccccc2-c2ccccc21 ; CC1(c2cccc(N(c3ccc4c(c3)C3(c5ccccc5-c5ccccc53)c3ccccc3-4)c3cc4ccccc4c4ccccc34)c2)c2ccccc2-c2ccccc21]

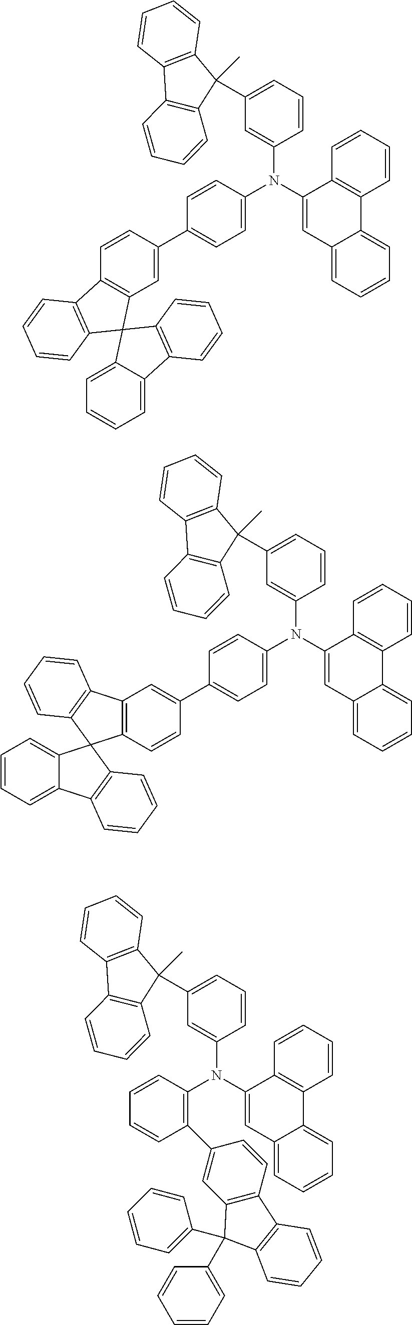 [SMILES: CC1(c2cccc(N(c3ccc(-c4ccc5c(c4)C4(c6ccccc6-c6ccccc64)c4ccccc4-5)cc3)c3cc4ccccc4c4ccccc34)c2)c2ccccc2-c2ccccc21 ; CC1(c2cccc(N(c3ccc(-c4ccc5c(c4)-c4ccccc4C54c5ccccc5-c5ccccc54)cc3)c3cc4ccccc4c4ccccc34)c2)c2ccccc2-c2ccccc21 ; CC1(c2cccc(N(c3ccccc3-c3ccc4c(c3)C(c3ccccc3)(c3ccccc3)c3ccccc3-4)c3cc4ccccc4c4ccccc34)c2)c2ccccc2-c2ccccc21]

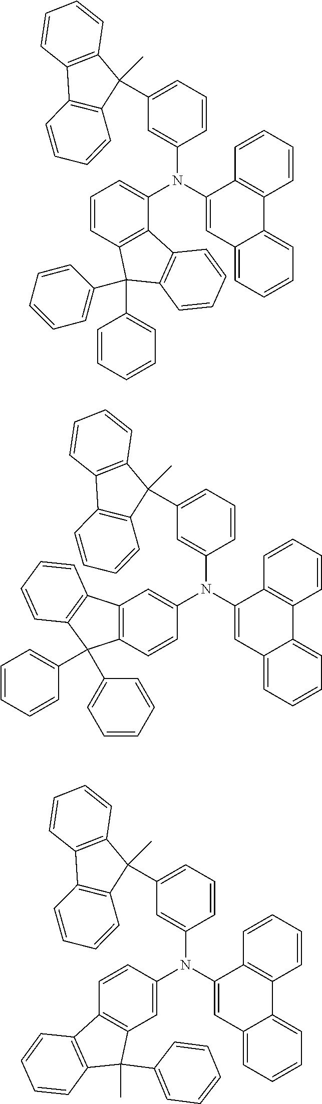

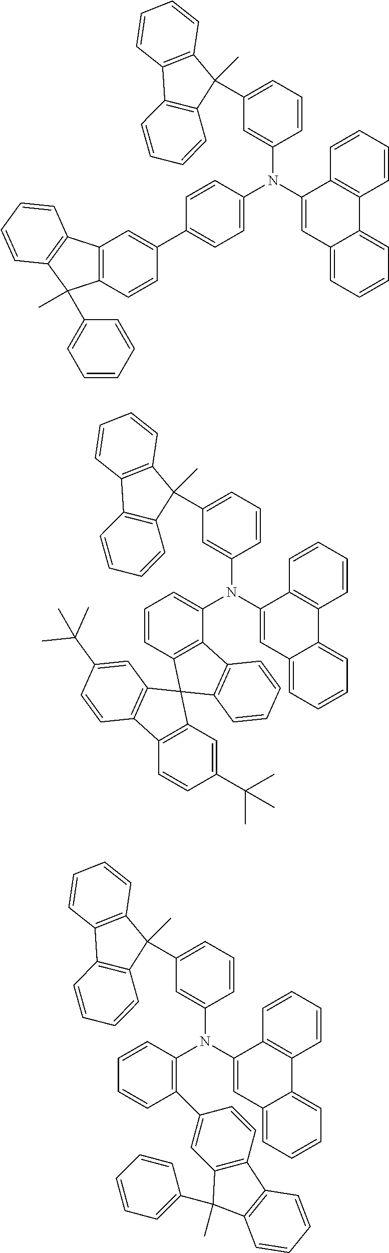

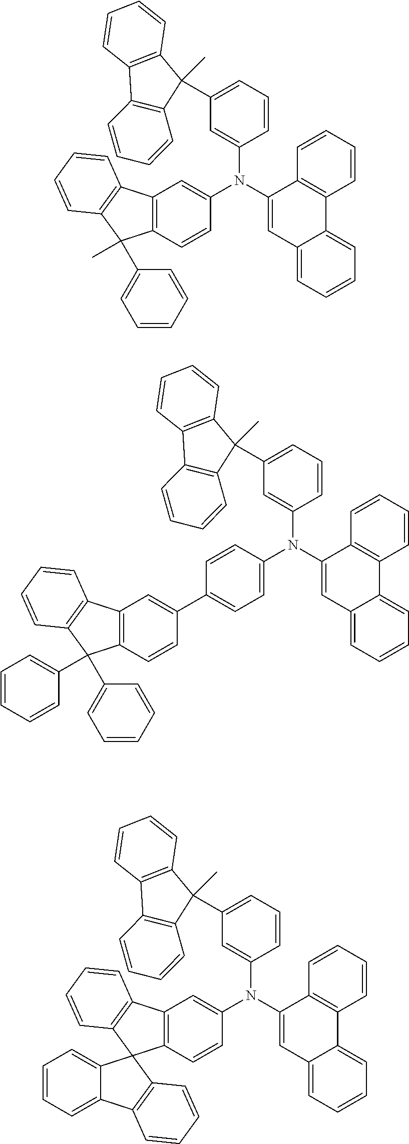

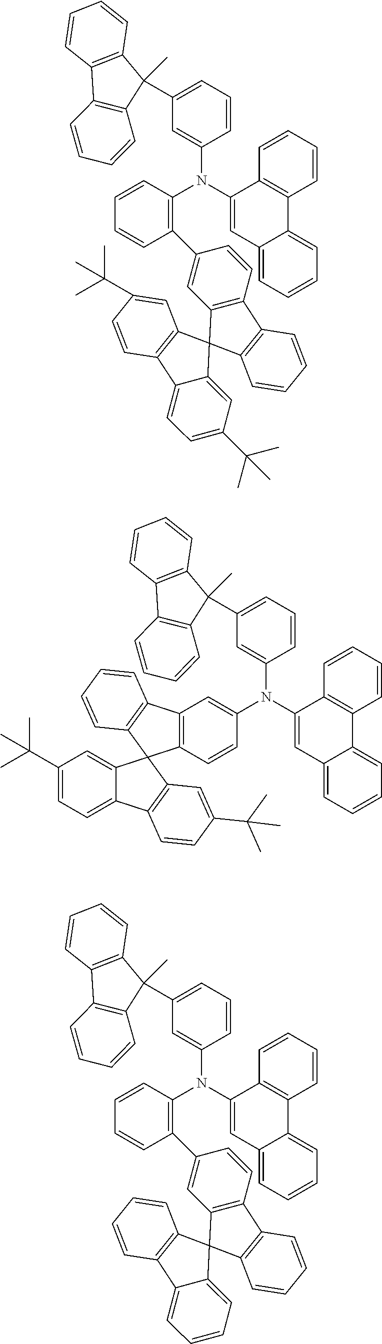 [SMILES: CC(C)(C)c1ccc2c(c1)C1(c3ccccc3-c3ccc(-c4ccccc4N(c4cccc(C5(C)c6ccccc6-c6ccccc65)c4)c4cc5ccccc5c5ccccc45)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4cc5ccccc5c5ccccc45)ccc31)c1cc(C(C)(C)C)ccc1-2 ; CC1(c2cccc(N(c3ccccc3-c3ccc4c(c3)C3(c5ccccc5-c5ccccc53)c3ccccc3-4)c3cc4ccccc4c4ccccc34)c2)c2ccccc2-c2ccccc21]

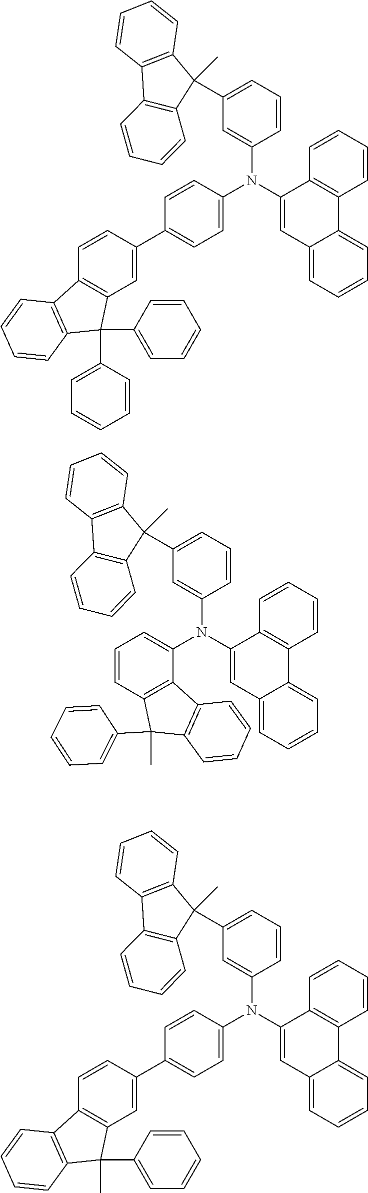

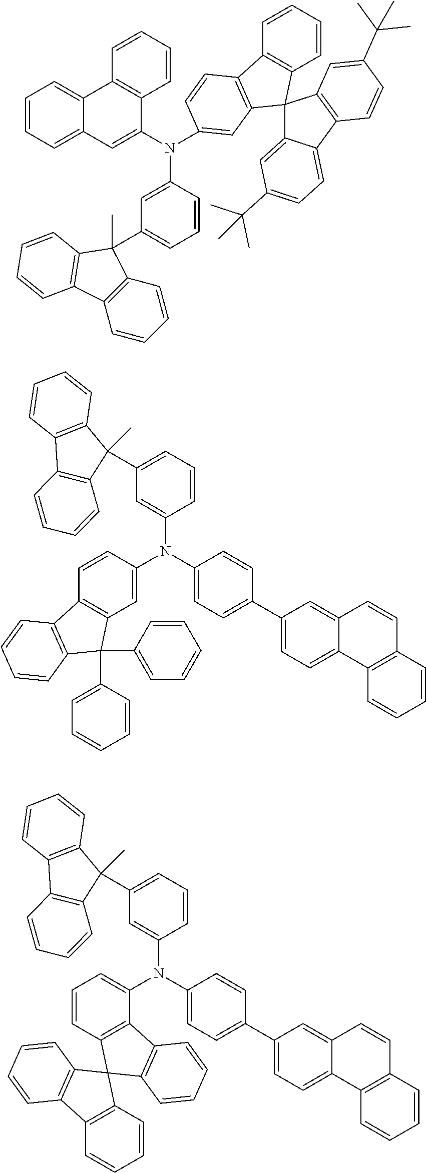 [SMILES: CC(C)(C)c1ccc2c(c1)C1(c3ccccc3-c3ccc(N(c4cccc(C5(C)c6ccccc6-c6ccccc65)c4)c4cc5ccccc5c5ccccc45)cc31)c1cc(C(C)(C)C)ccc1-2 ; CC1(c2cccc(N(c3ccc(-c4ccc5c(ccc6ccccc65)c4)cc3)c3ccc4c(c3)C(c3ccccc3)(c3ccccc3)c3ccccc3-4)c2)c2ccccc2-c2ccccc21 ; CC1(c2cccc(N(c3ccc(-c4ccc5c(ccc6ccccc65)c4)cc3)c3cccc4c3-c3ccccc3C43c4ccccc4-c4ccccc43)c2)c2ccccc2-c2ccccc21]

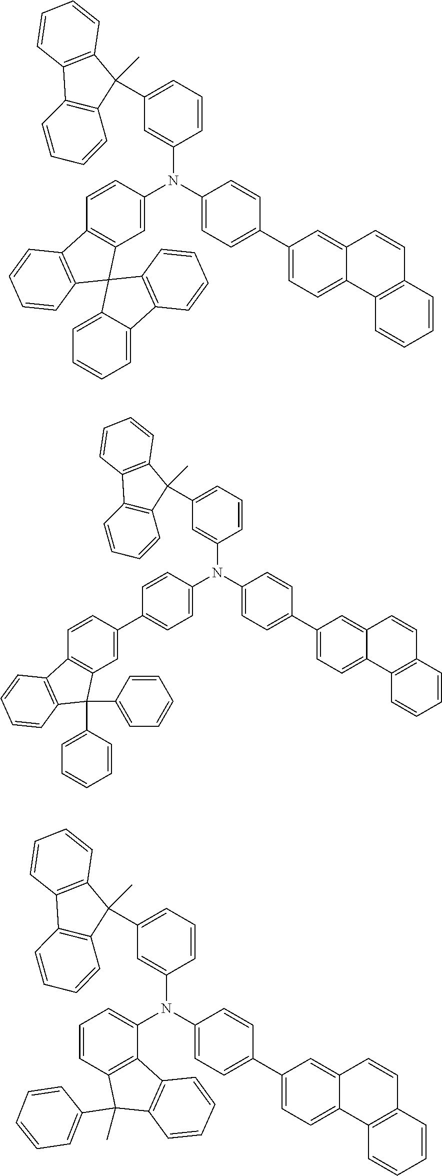

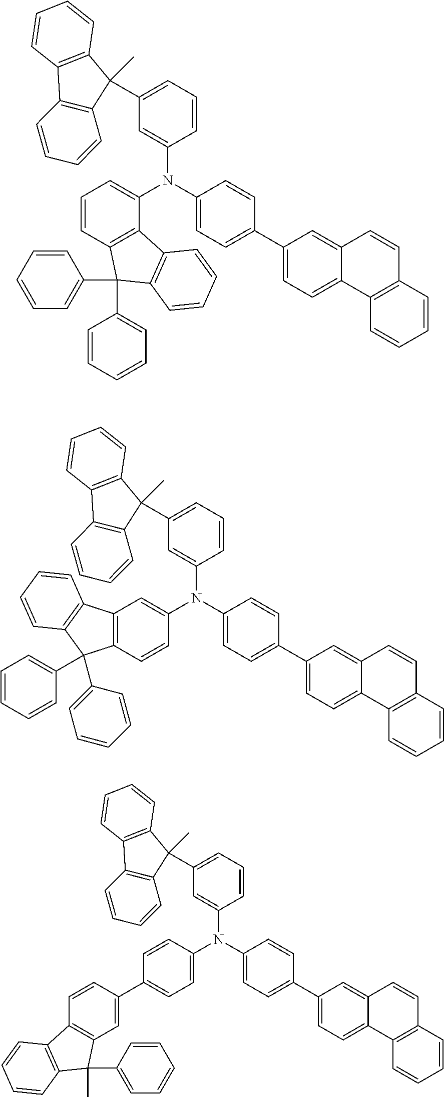

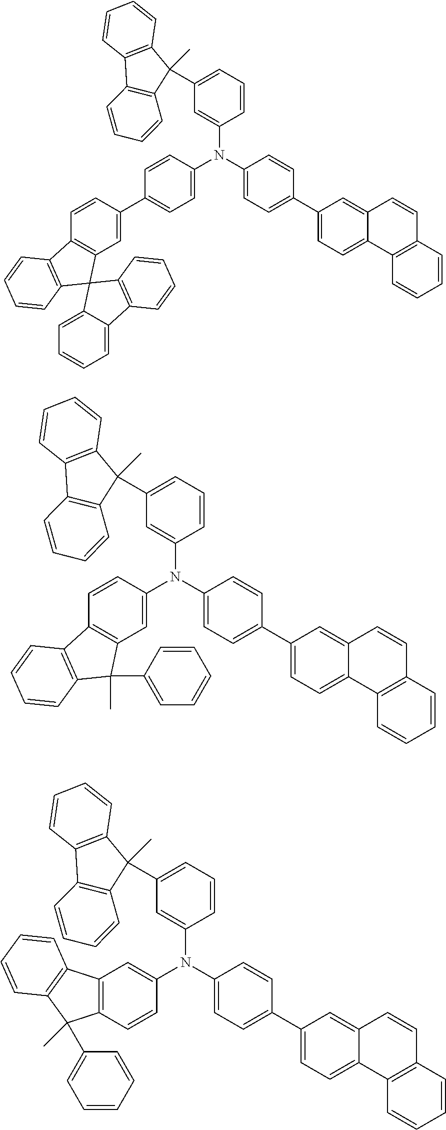

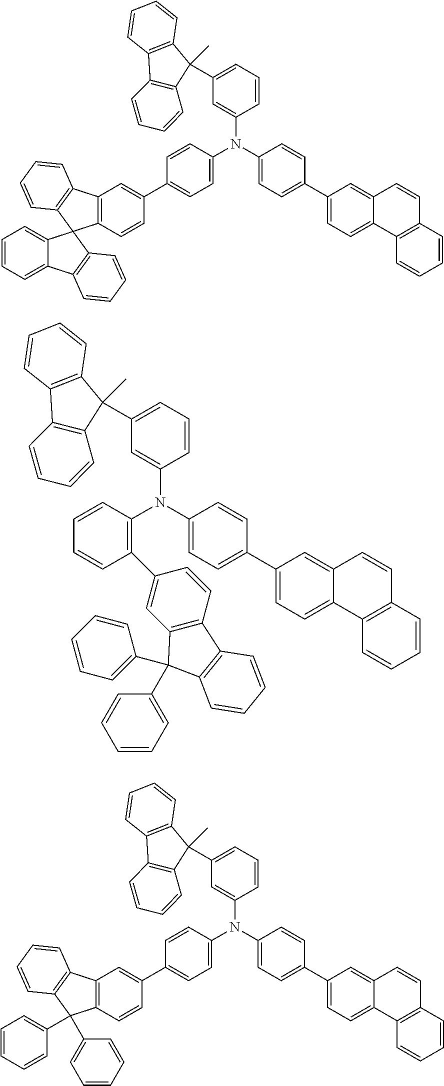

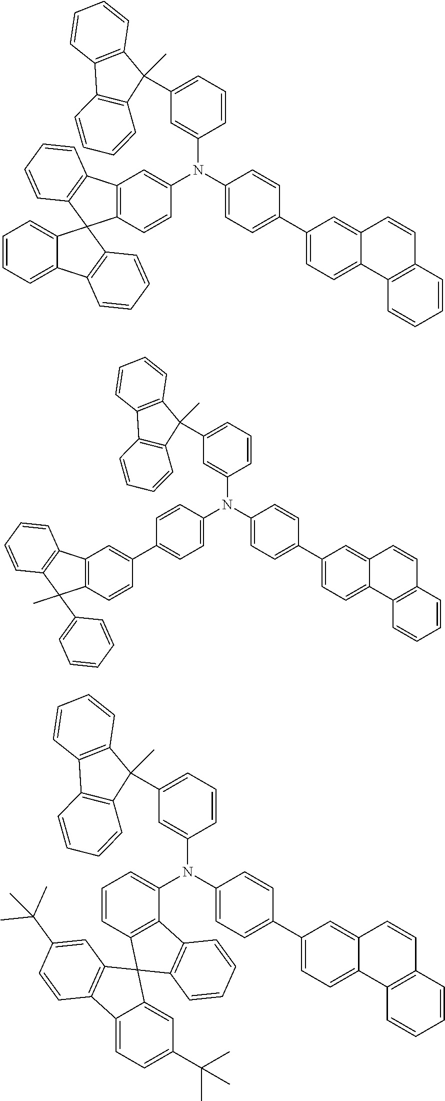

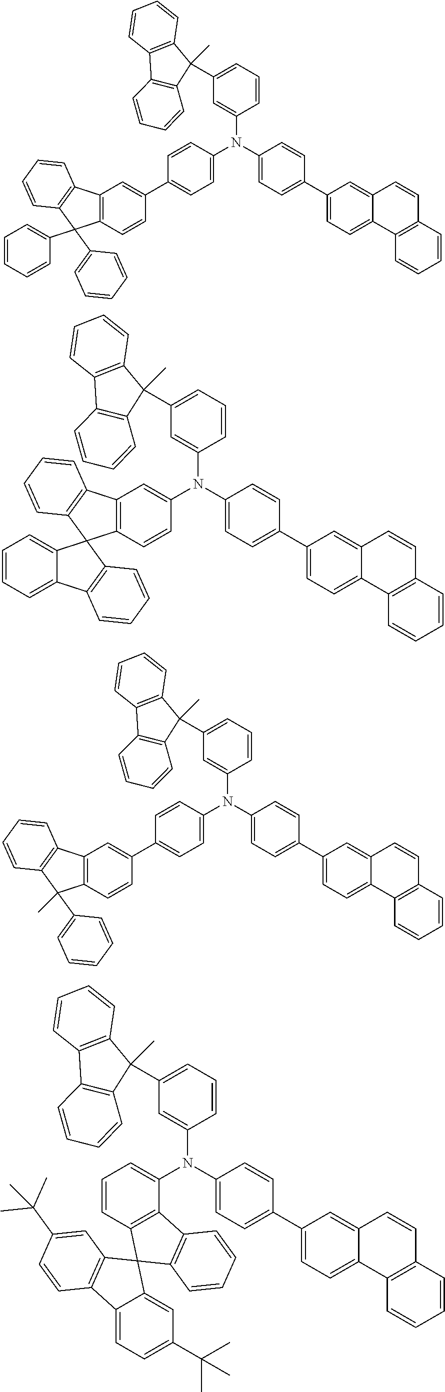

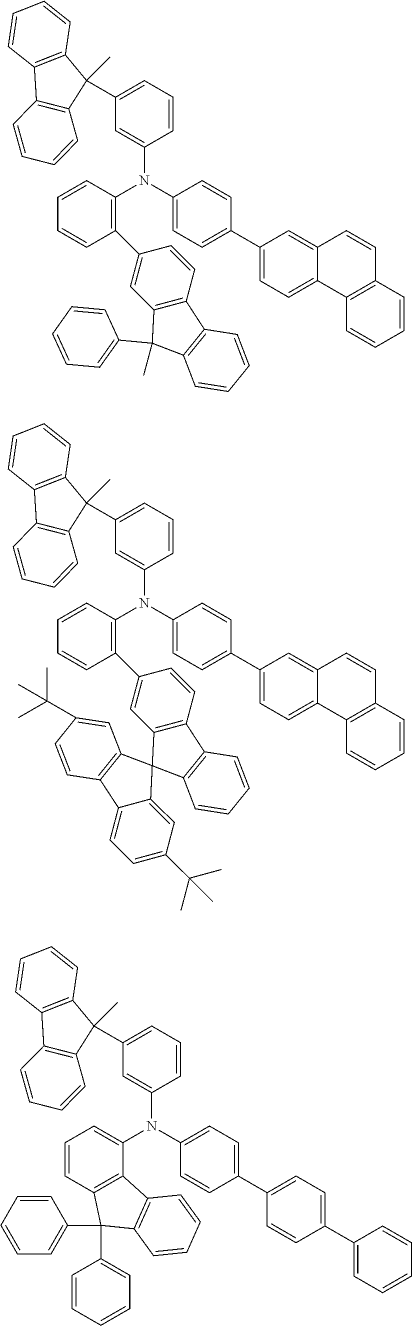 [SMILES: CC1(c2cccc(N(c3ccc(-c4ccc5c(ccc6ccccc65)c4)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4ccc(-c5ccc6c(ccc7ccccc76)c5)cc4)c4cccc(C5(C)c6ccccc6-c6ccccc65)c4)cc31)c1cc(C(C)(C)C)ccc1-2 ; CC1(c2cccc(N(c3ccc(-c4ccc(-c5ccccc5)cc4)cc3)c3cccc4c3-c3ccccc3C4(c3ccccc3)c3ccccc3)c2)c2ccccc2-c2ccccc21]

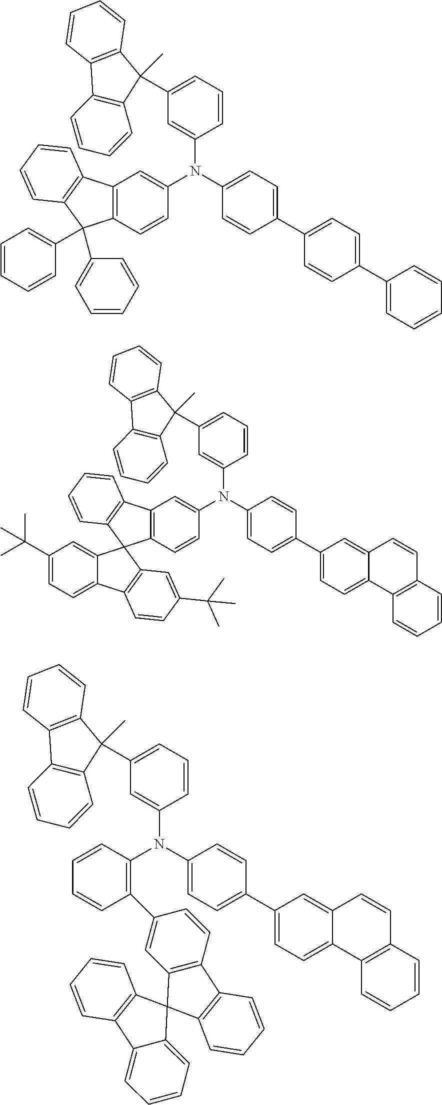

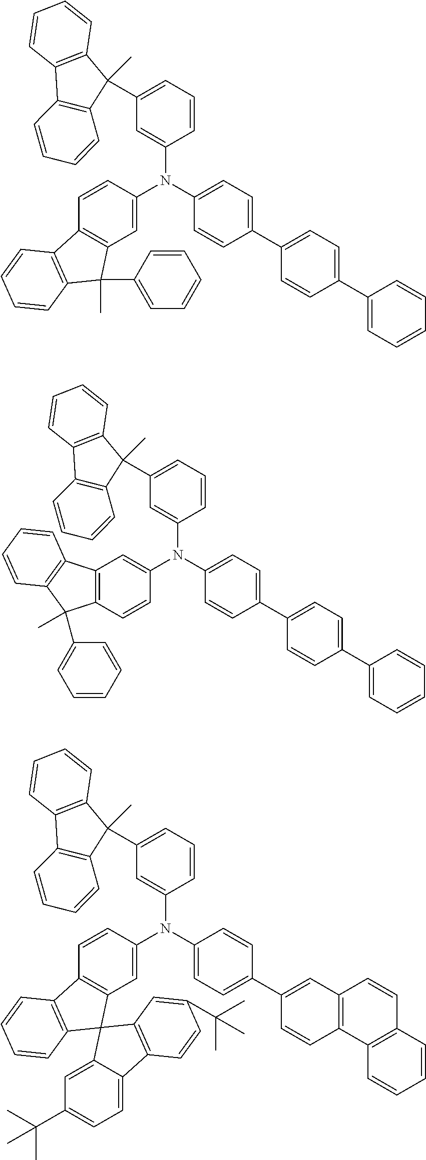 [SMILES: CC1(c2cccc(N(c3ccc(-c4ccc(-c5ccccc5)cc4)cc3)c3ccc4c(c3)C(C)(c3ccccc3)c3ccccc3-4)c2)c2ccccc2-c2ccccc21 ; CC1(c2cccc(N(c3ccc(-c4ccc(-c5ccccc5)cc4)cc3)c3ccc4c(c3)-c3ccccc3C4(C)c3ccccc3)c2)c2ccccc2-c2ccccc21 ; CC(C)(C)c1ccc2c(c1)C1(c3ccccc3-c3ccc(N(c4ccc(-c5ccc6c(ccc7ccccc76)c5)cc4)c4cccc(C5(C)c6ccccc6-c6ccccc65)c4)cc31)c1cc(C(C)(C)C)ccc1-2]

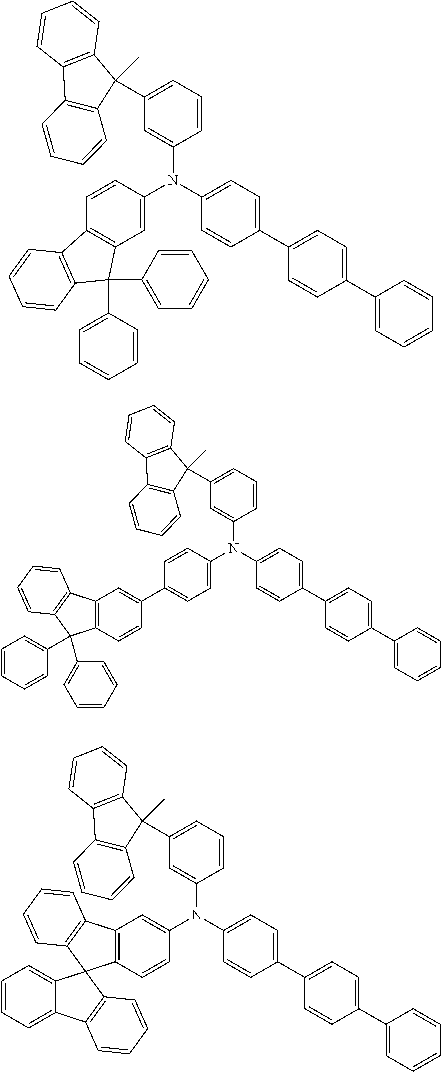

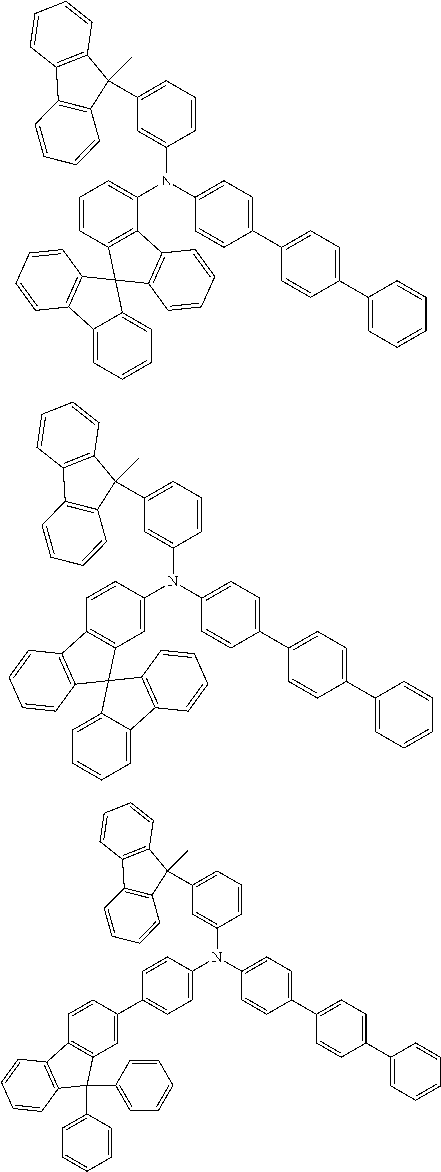

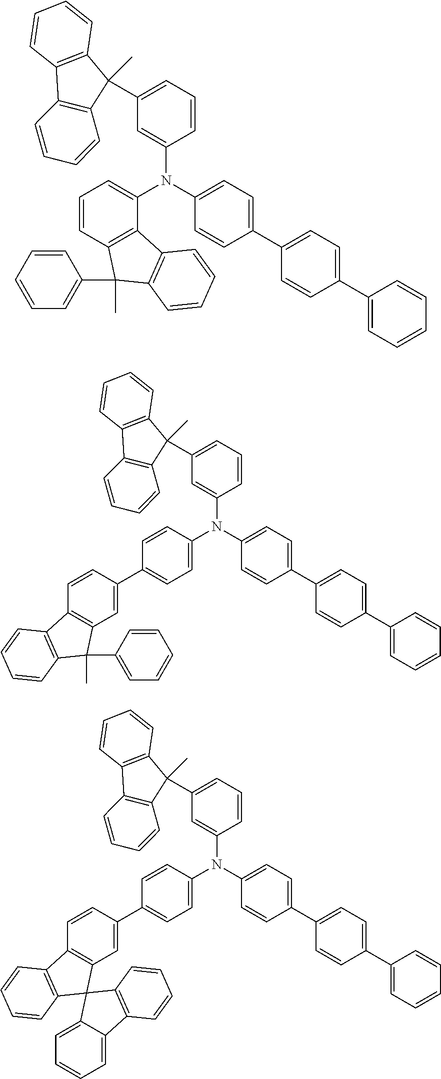

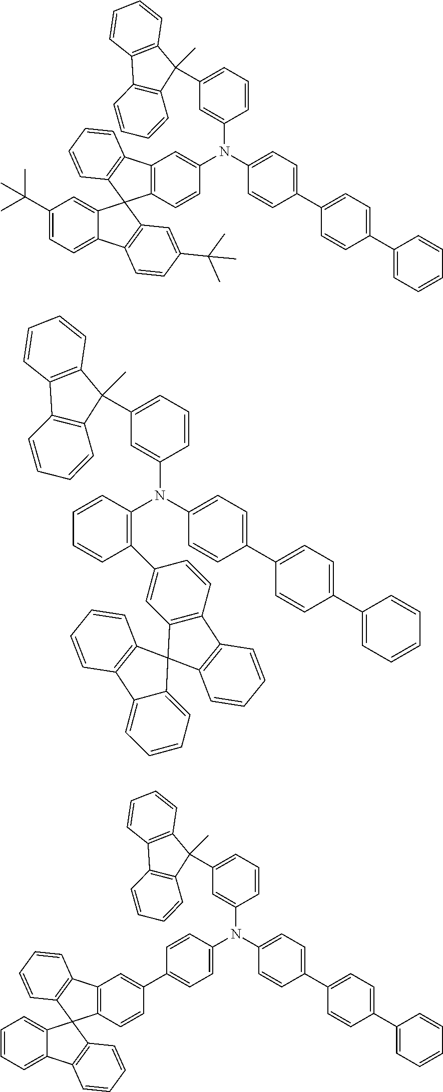

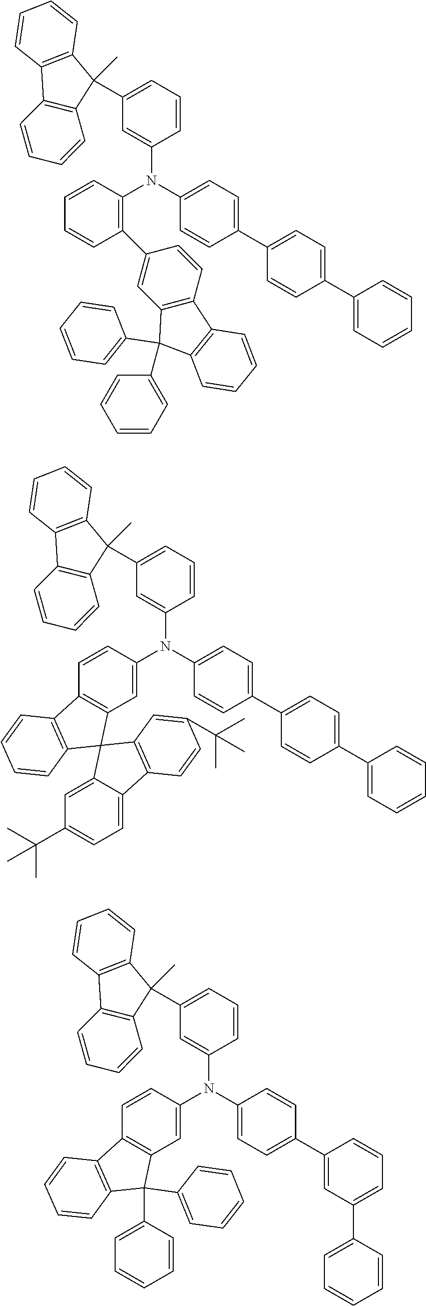 [SMILES: CC1(c2cccc(N(c3ccc(-c4ccc(-c5ccccc5)cc4)cc3)c3ccccc3-c3ccc4c(c3)C(c3ccccc3)(c3ccccc3)c3ccccc3-4)c2)c2ccccc2-c2ccccc21 ; CC(C)(C)c1ccc2c(c1)C1(c3ccccc3-c3ccc(N(c4ccc(-c5ccc(-c6ccccc6)cc5)cc4)c4cccc(C5(C)c6ccccc6-c6ccccc65)c4)cc31)c1cc(C(C)(C)C)ccc1-2 ; CC1(c2cccc(N(c3ccc(-c4cccc(-c5ccccc5)c4)cc3)c3ccc4c(c3)C(c3ccccc3)(c3ccccc3)c3ccccc3-4)c2)c2ccccc2-c2ccccc21]

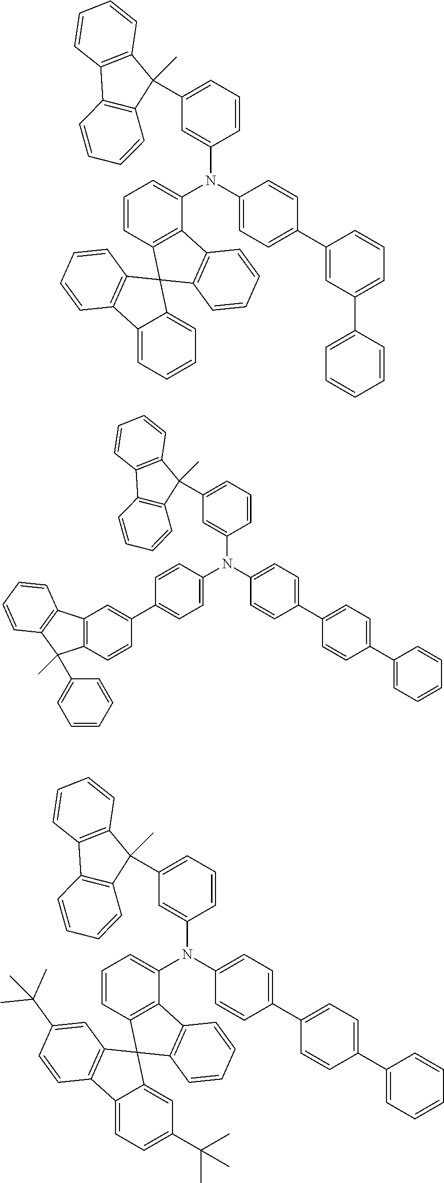

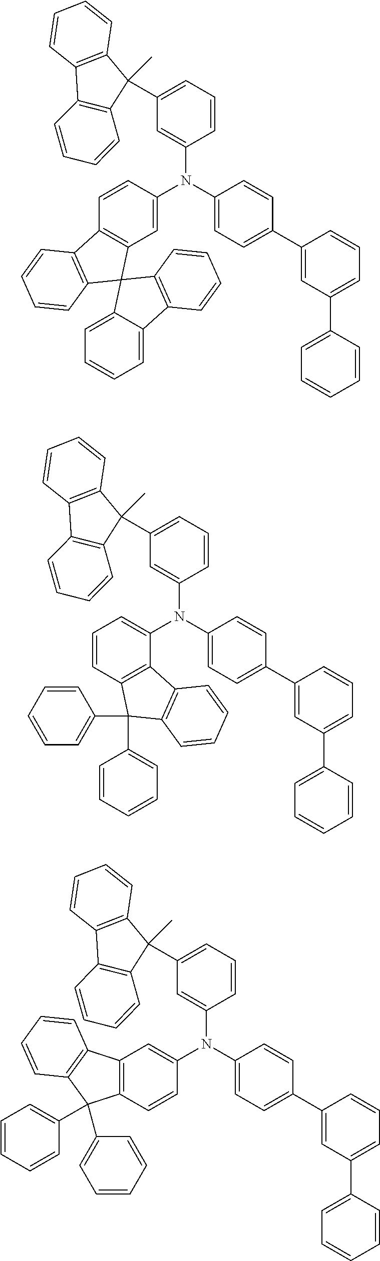 [SMILES: CC1(c2cccc(N(c3ccc(-c4cccc(-c5ccccc5)c4)cc3)c3ccc4c(c3)C3(c5ccccc5-c5ccccc53)c3ccccc3-4)c2)c2ccccc2-c2ccccc21 ; CC1(c2cccc(N(c3ccc(-c4cccc(-c5ccccc5)c4)cc3)c3cccc4c3-c3ccccc3C4(c3ccccc3)c3ccccc3)c2)c2ccccc2-c2ccccc21 ; CC1(c2cccc(N(c3ccc(-c4cccc(-c5ccccc5)c4)cc3)c3ccc4c(c3)-c3ccccc3C4(c3ccccc3)c3ccccc3)c2)c2ccccc2-c2ccccc21]

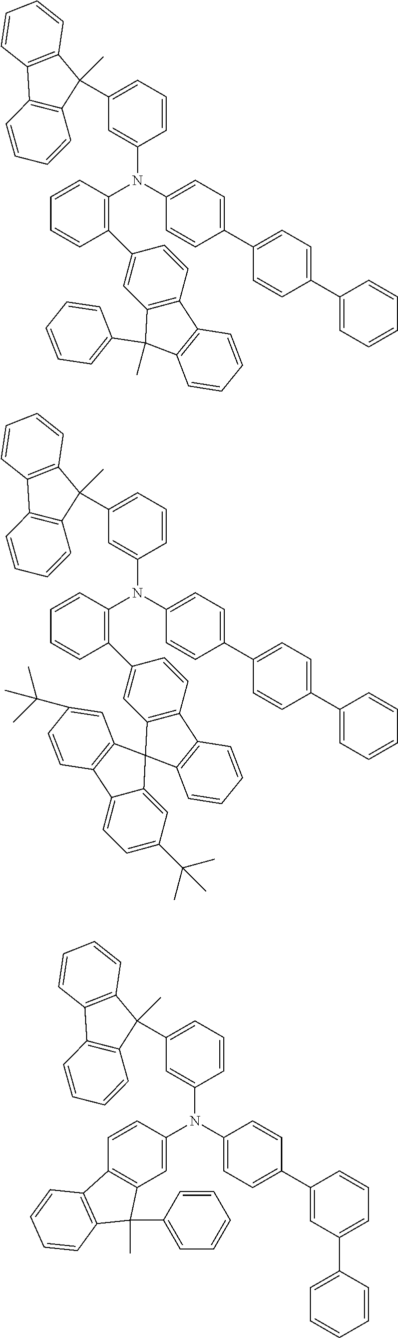 [SMILES: CC1(c2cccc(N(c3ccc(-c4ccc(-c5ccccc5)cc4)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4ccc(-c5ccc(-c6ccccc6)cc5)cc4)c4cccc(C5(C)c6ccccc6-c6ccccc65)c4)cc31)c1cc(C(C)(C)C)ccc1-2 ; CC1(c2cccc(N(c3ccc(-c4cccc(-c5ccccc5)c4)cc3)c3ccc4c(c3)C(C)(c3ccccc3)c3ccccc3-4)c2)c2ccccc2-c2ccccc21]

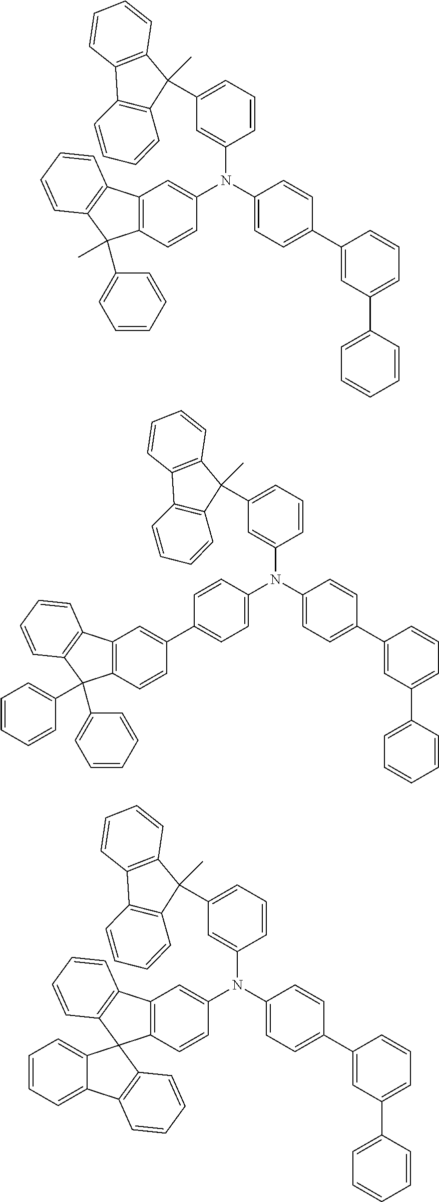

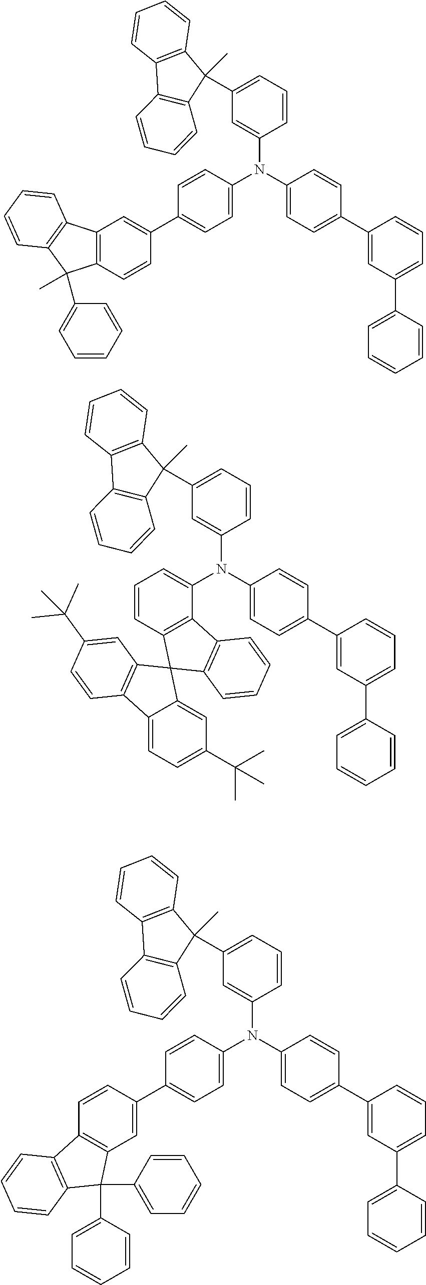

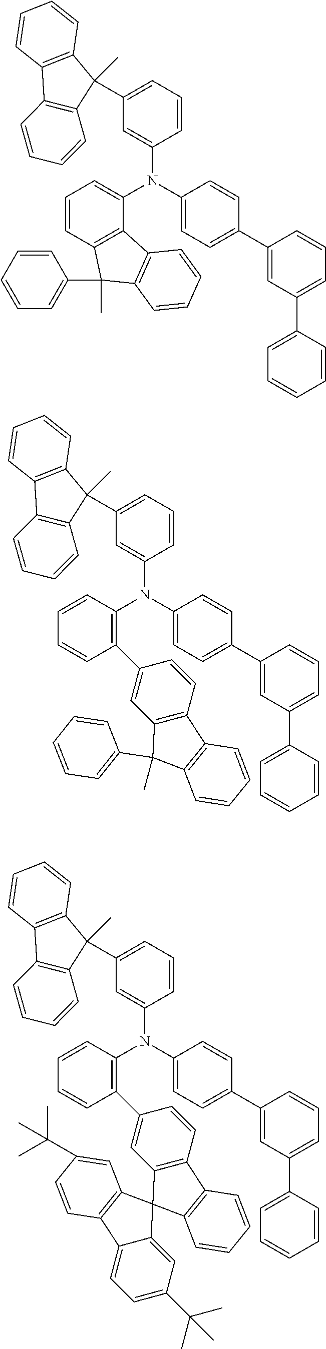 [SMILES: CC1(c2cccc(N(c3ccc(-c4cccc(-c5ccccc5)c4)cc3)c3cccc4c3-c3ccccc3C4(C)c3ccccc3)c2)c2ccccc2-c2ccccc21 ; CC1(c2cccc(N(c3ccc(-c4cccc(-c5ccccc5)c4)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4ccc(-c5cccc(-c6ccccc6)c5)cc4)c4cccc(C5(C)c6ccccc6-c6ccccc65)c4)cc31)c1cc(C(C)(C)C)ccc1-2]

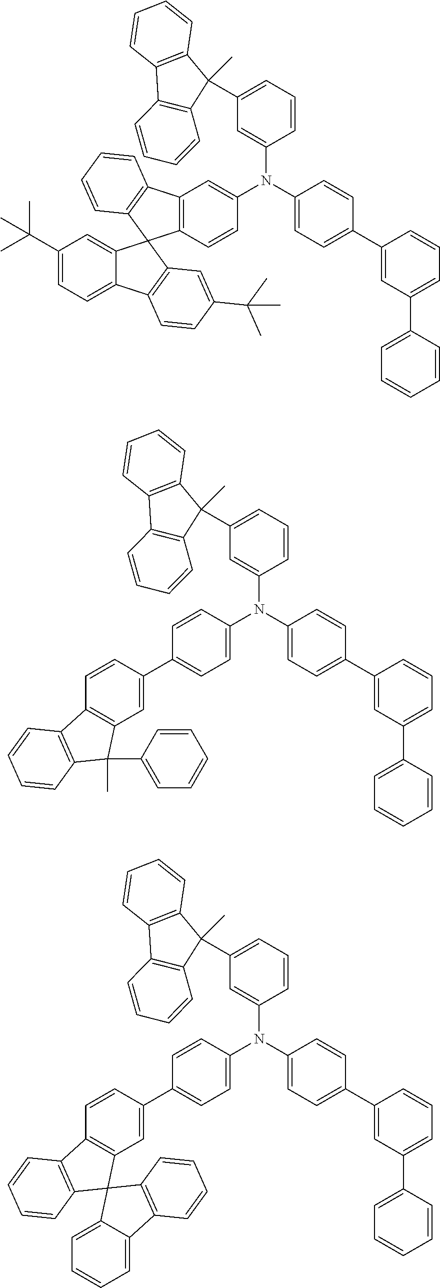 [SMILES: CC(C)(C)c1ccc2c(c1)C1(c3ccccc3-c3cc(N(c4ccc(-c5cccc(-c6ccccc6)c5)cc4)c4cccc(C5(C)c6ccccc6-c6ccccc65)c4)ccc31)c1cc(C(C)(C)C)ccc1-2 ; CC1(c2cccc(N(c3ccc(-c4cccc(-c5ccccc5)c4)cc3)c3ccc(-c4ccc5c(c4)C(C)(c4ccccc4)c4ccccc4-5)cc3)c2)c2ccccc2-c2ccccc21 ; CC1(c2cccc(N(c3ccc(-c4cccc(-c5ccccc5)c4)cc3)c3ccc(-c4ccc5c(c4)C4(c6ccccc6-c6ccccc64)c4ccccc4-5)cc3)c2)c2ccccc2-c2ccccc21]

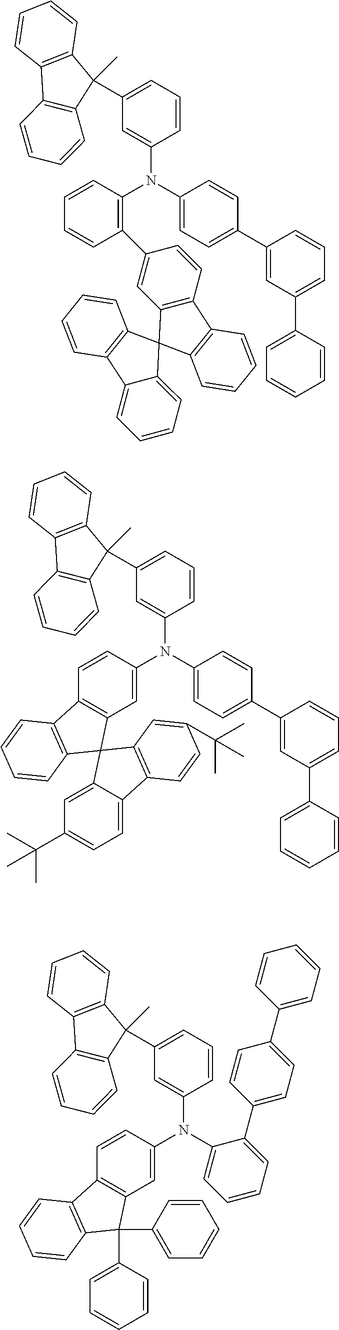 [SMILES: CC1(c2cccc(N(c3ccc(-c4cccc(-c5ccccc5)c4)cc3)c3ccccc3-c3ccc4c(c3)C3(c5ccccc5-c5ccccc53)c3ccccc3-4)c2)c2ccccc2-c2ccccc21 ; CC(C)(C)c1ccc2c(c1)C1(c3ccccc3-c3ccc(N(c4ccc(-c5cccc(-c6ccccc6)c5)cc4)c4cccc(C5(C)c6ccccc6-c6ccccc65)c4)cc31)c1cc(C(C)(C)C)ccc1-2 ; CC1(c2cccc(N(c3ccc4c(c3)C(c3ccccc3)(c3ccccc3)c3ccccc3-4)c3ccccc3-c3ccc(-c4ccccc4)cc3)c2)c2ccccc2-c2ccccc21]

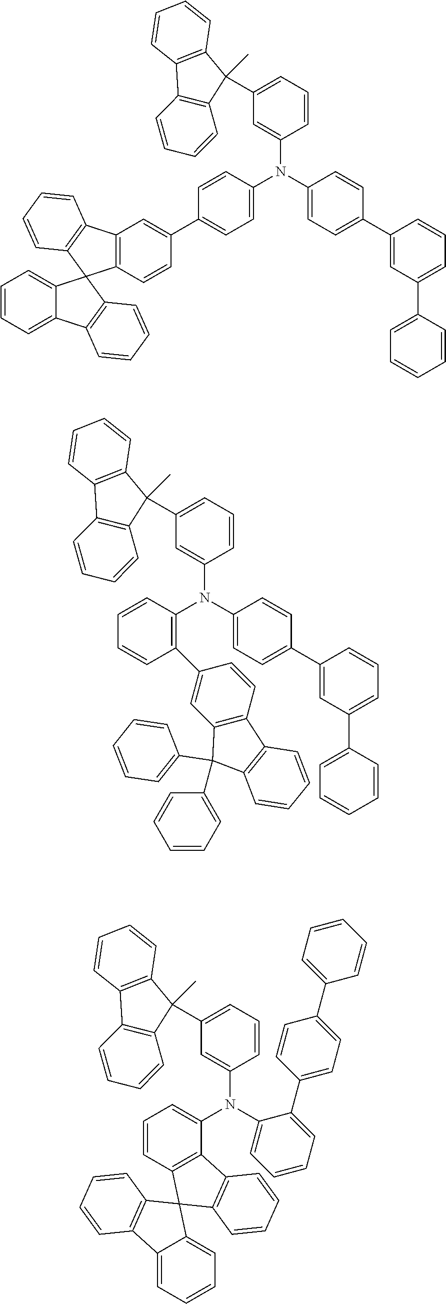 [SMILES: CC1(c2cccc(N(c3ccc(-c4cccc(-c5ccccc5)c4)cc3)c3ccc(-c4ccc5c(c4)-c4ccccc4C54c5ccccc5-c5ccccc54)cc3)c2)c2ccccc2-c2ccccc21 ; CC1(c2cccc(N(c3ccc(-c4cccc(-c5ccccc5)c4)cc3)c3ccccc3-c3ccc4c(c3)C(c3ccccc3)(c3ccccc3)c3ccccc3-4)c2)c2ccccc2-c2ccccc21 ; CC1(c2cccc(N(c3ccccc3-c3ccc(-c4ccccc4)cc3)c3cccc4c3-c3ccccc3C43c4ccccc4-c4ccccc43)c2)c2ccccc2-c2ccccc21]

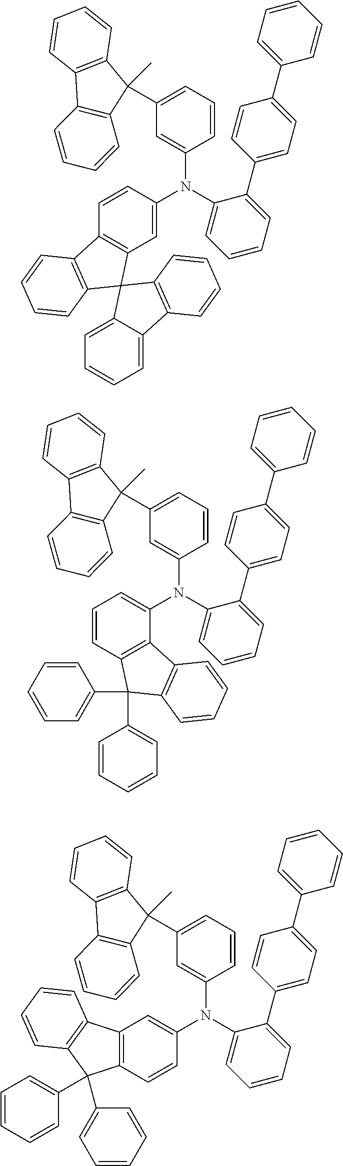

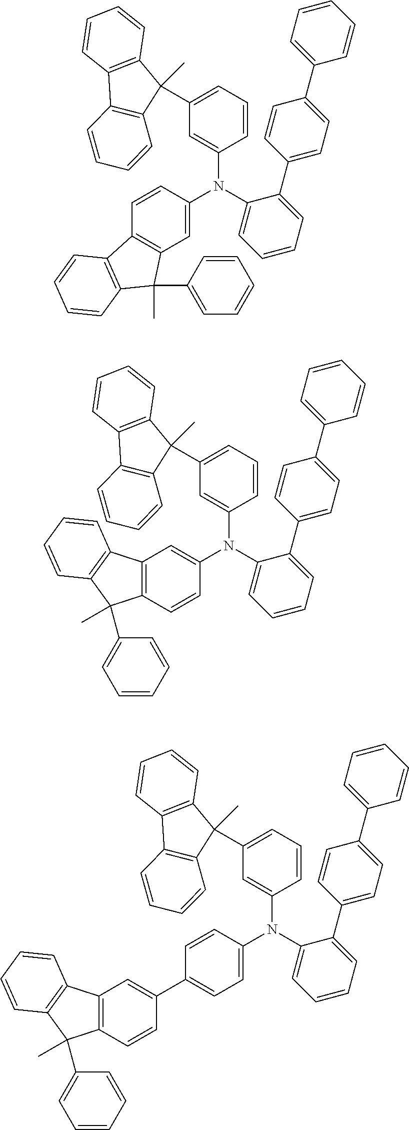 [SMILES: CC1(c2cccc(N(c3ccc4c(c3)C(C)(c3ccccc3)c3ccccc3-4)c3ccccc3-c3ccc(-c4ccccc4)cc3)c2)c2ccccc2-c2ccccc21 ; CC1(c2cccc(N(c3ccc4c(c3)-c3ccccc3C4(C)c3ccccc3)c3ccccc3-c3ccc(-c4ccccc4)cc3)c2)c2ccccc2-c2ccccc21 ; CC1(c2cccc(N(c3ccc(-c4ccc5c(c4)-c4ccccc4C5(C)c4ccccc4)cc3)c3ccccc3-c3ccc(-c4ccccc4)cc3)c2)c2ccccc2-c2ccccc21]

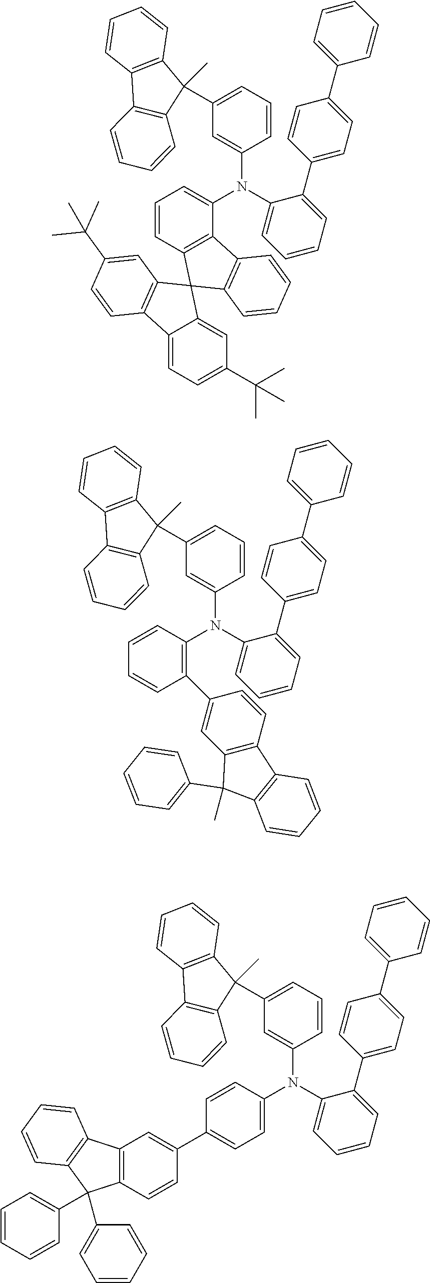 [SMILES: CC(C)(C)c1ccc2c(c1)C1(c3cc(C(C)(C)C)ccc3-2)c2ccccc2-c2c(N(c3cccc(C4(C)c5ccccc5-c5ccccc54)c3)c3ccccc3-c3ccc(-c4ccccc4)cc3)cccc21 ; CC1(c2cccc(N(c3ccccc3-c3ccc(-c4ccccc4)cc3)c3ccccc3-c3ccc4c(c3)C(C)(c3ccccc3)c3ccccc3-4)c2)c2ccccc2-c2ccccc21 ; CC1(c2cccc(N(c3ccc(-c4ccc5c(c4)-c4ccccc4C5(c4ccccc4)c4ccccc4)cc3)c3ccccc3-c3ccc(-c4ccccc4)cc3)c2)c2ccccc2-c2ccccc21]

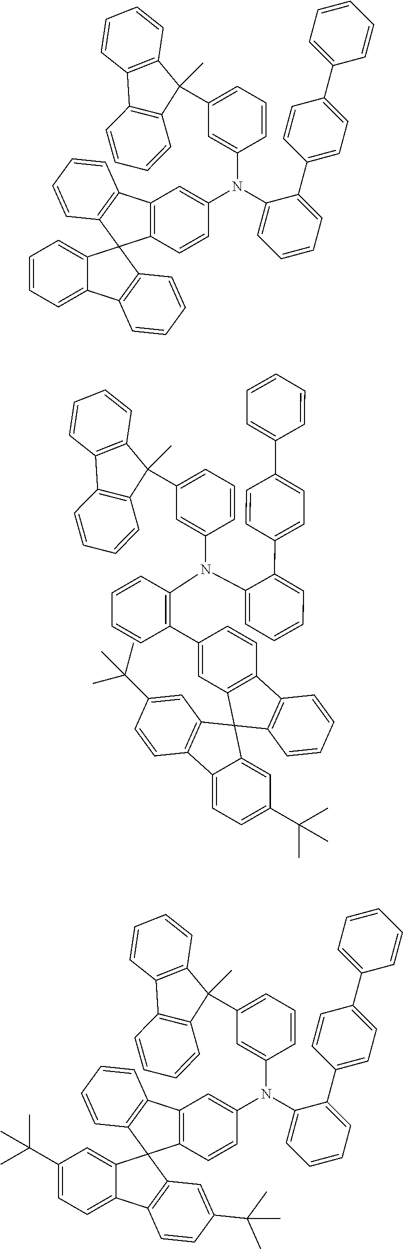 [SMILES: CC1(c2cccc(N(c3ccc4c(c3)-c3ccccc3C43c4ccccc4-c4ccccc43)c3ccccc3-c3ccc(-c4ccccc4)cc3)c2)c2ccccc2-c2ccccc21 ; CC(C)(C)c1ccc2c(c1)C1(c3ccccc3-c3ccc(-c4ccccc4N(c4cccc(C5(C)c6ccccc6-c6ccccc65)c4)c4ccccc4-c4ccc(-c5ccccc5)cc4)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4ccccc4-c4ccc(-c5ccccc5)cc4)ccc31)c1cc(C(C)(C)C)ccc1-2]

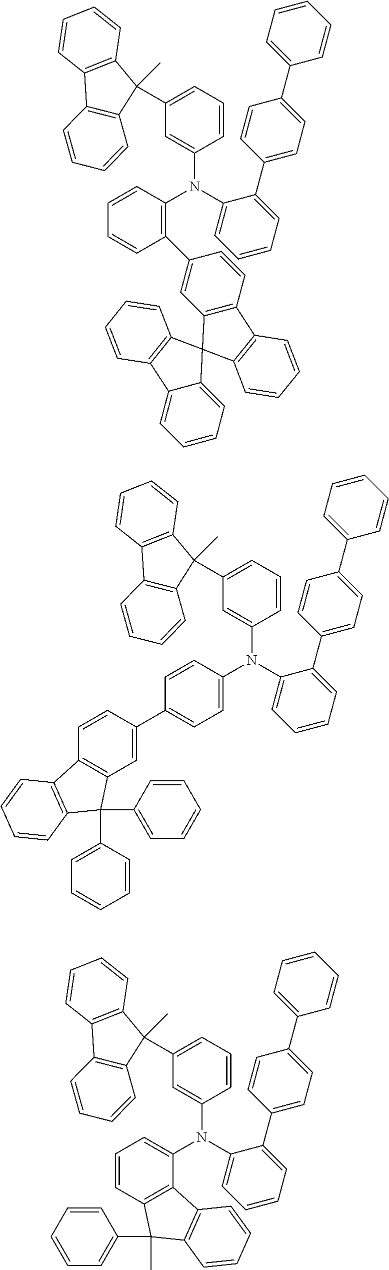 [SMILES: CC1(c2cccc(N(c3ccccc3-c3ccc(-c4ccccc4)cc3)c3ccccc3-c3ccc4c(c3)C3(c5ccccc5-c5ccccc53)c3ccccc3-4)c2)c2ccccc2-c2ccccc21 ; CC1(c2cccc(N(c3ccc(-c4ccc5c(c4)C(c4ccccc4)(c4ccccc4)c4ccccc4-5)cc3)c3ccccc3-c3ccc(-c4ccccc4)cc3)c2)c2ccccc2-c2ccccc21 ; CC1(c2cccc(N(c3ccccc3-c3ccc(-c4ccccc4)cc3)c3cccc4c3-c3ccccc3C4(C)c3ccccc3)c2)c2ccccc2-c2ccccc21]

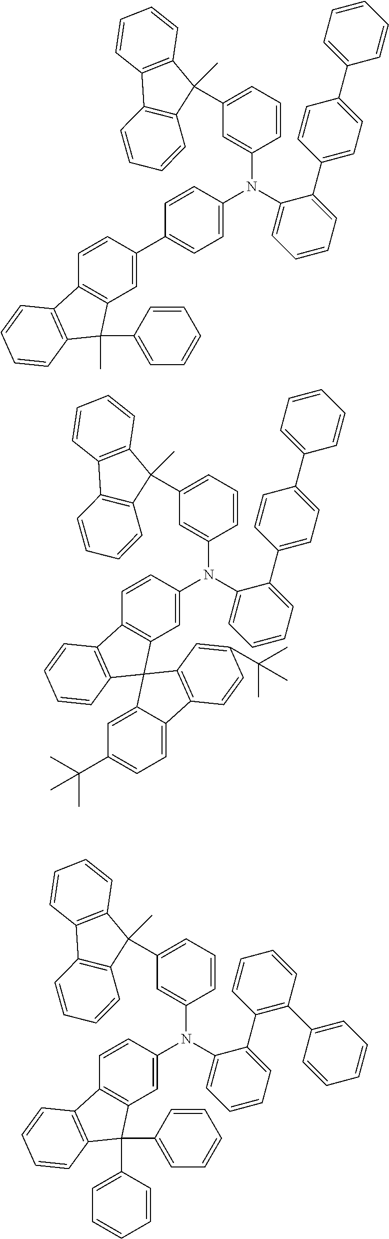

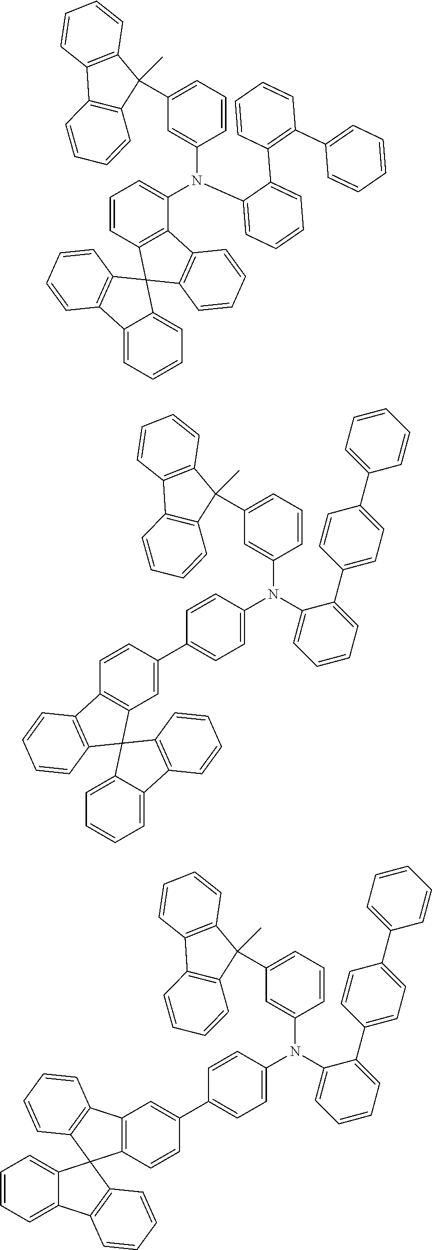

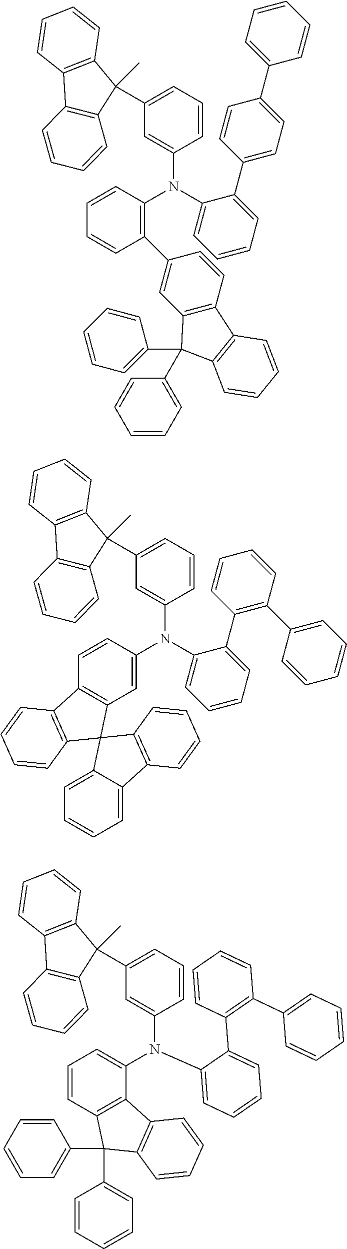 [SMILES: CC1(c2cccc(N(c3ccccc3-c3ccc(-c4ccccc4)cc3)c3ccccc3-c3ccc4c(c3)C(c3ccccc3)(c3ccccc3)c3ccccc3-4)c2)c2ccccc2-c2ccccc21 ; CC1(c2cccc(N(c3ccc4c(c3)C3(c5ccccc5-c5ccccc53)c3ccccc3-4)c3ccccc3-c3ccccc3-c3ccccc3)c2)c2ccccc2-c2ccccc21 ; CC1(c2cccc(N(c3ccccc3-c3ccccc3-c3ccccc3)c3cccc4c3-c3ccccc3C4(c3ccccc3)c3ccccc3)c2)c2ccccc2-c2ccccc21]

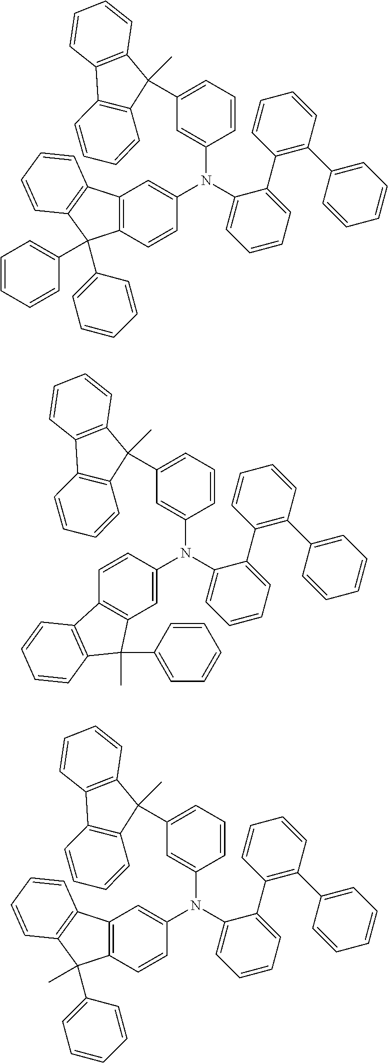

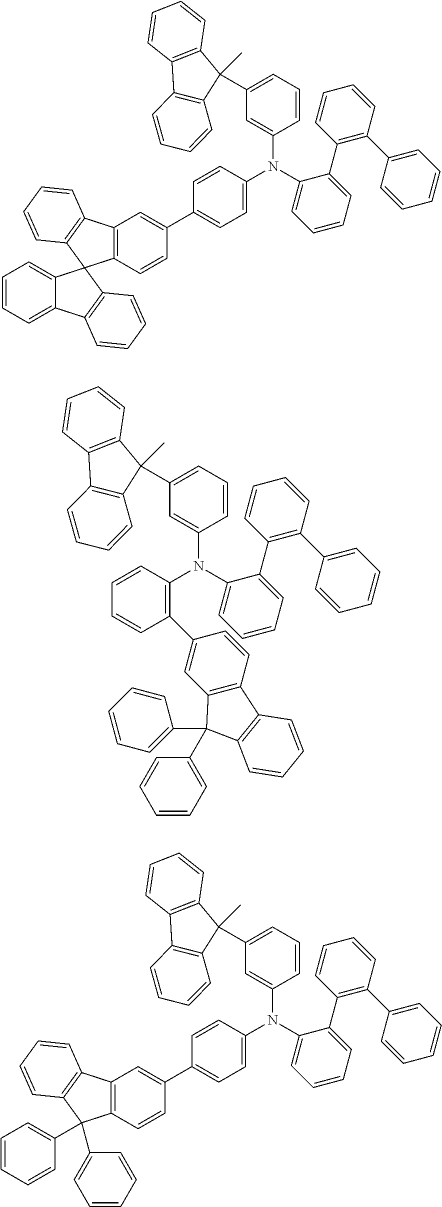

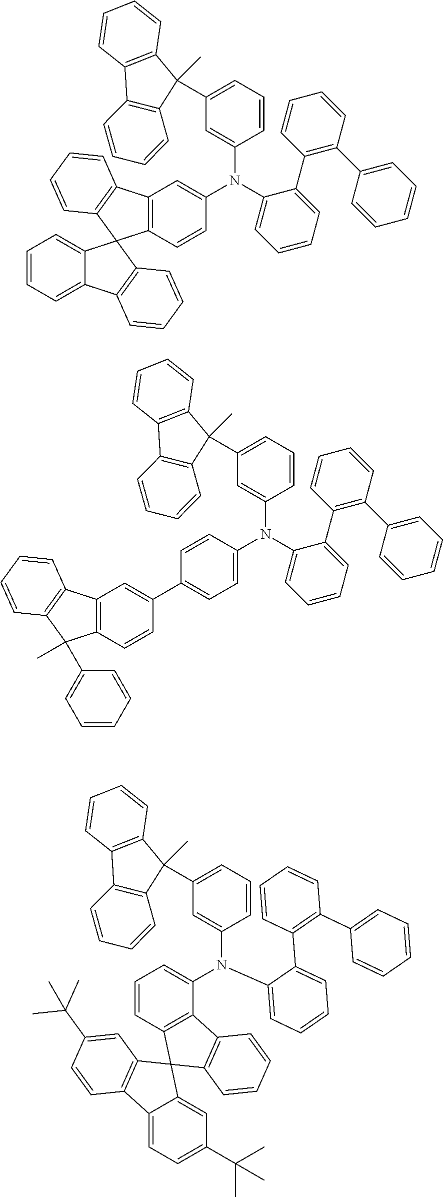

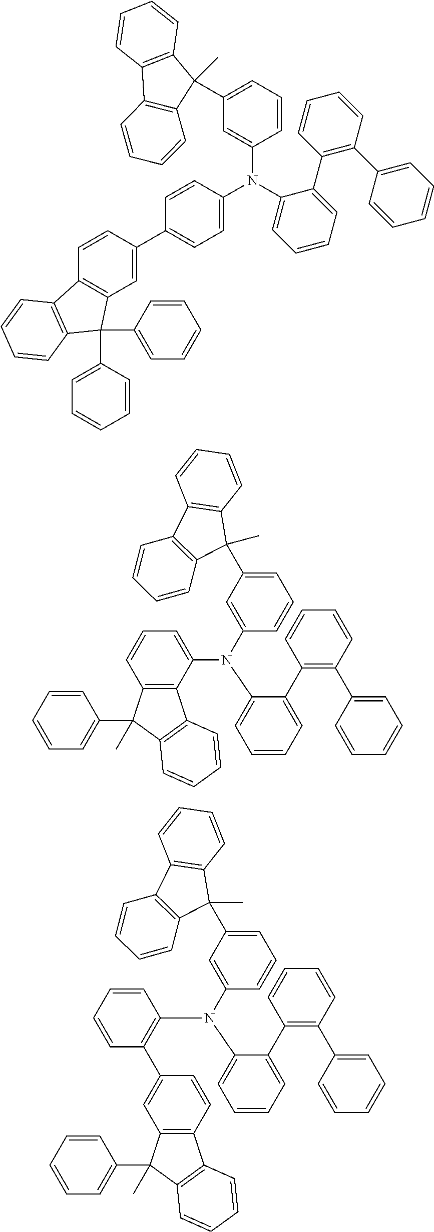

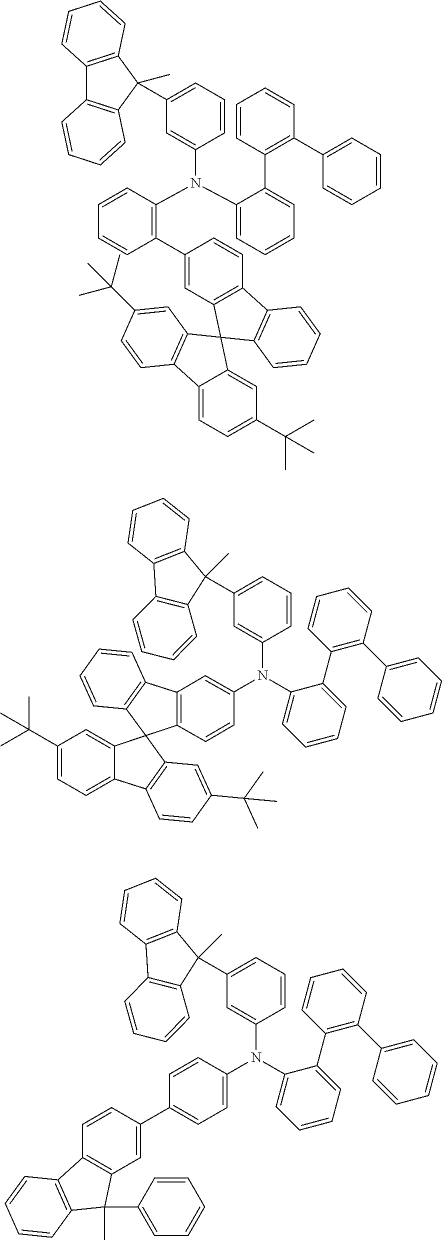 [SMILES: CC(C)(C)c1ccc2c(c1)C1(c3ccccc3-c3ccc(-c4ccccc4N(c4cccc(C5(C)c6ccccc6-c6ccccc65)c4)c4ccccc4-c4ccccc4-c4ccccc4)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4ccccc4-c4ccccc4-c4ccccc4)ccc31)c1cc(C(C)(C)C)ccc1-2 ; CC1(c2cccc(N(c3ccc(-c4ccc5c(c4)C(C)(c4ccccc4)c4ccccc4-5)cc3)c3ccccc3-c3ccccc3-c3ccccc3)c2)c2ccccc2-c2ccccc21]

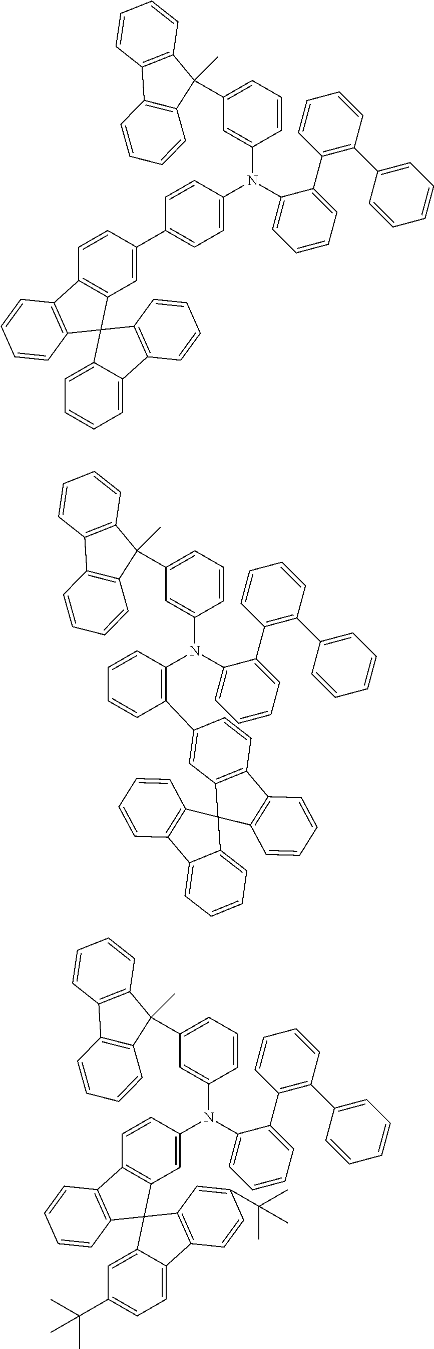

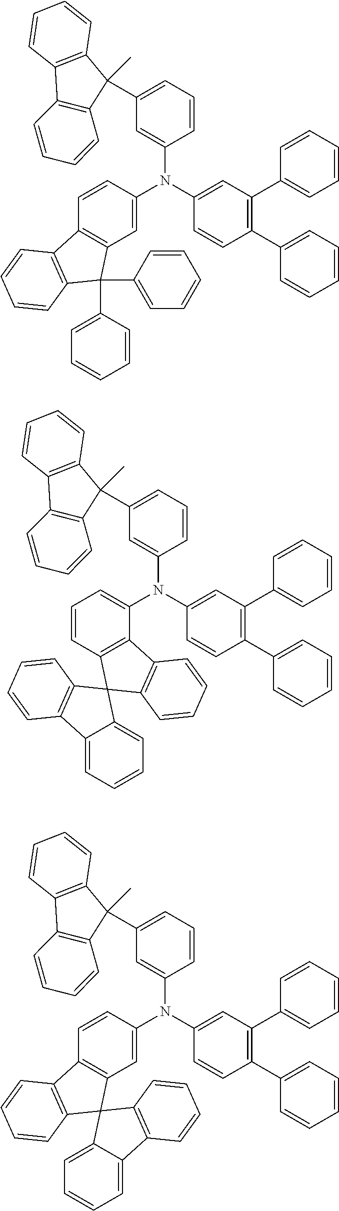 [SMILES: CC1(c2cccc(N(c3ccc(-c4ccccc4)c(-c4ccccc4)c3)c3ccc4c(c3)C(c3ccccc3)(c3ccccc3)c3ccccc3-4)c2)c2ccccc2-c2ccccc21 ; CC1(c2cccc(N(c3ccc(-c4ccccc4)c(-c4ccccc4)c3)c3cccc4c3-c3ccccc3C43c4ccccc4-c4ccccc43)c2)c2ccccc2-c2ccccc21 ; CC1(c2cccc(N(c3ccc(-c4ccccc4)c(-c4ccccc4)c3)c3ccc4c(c3)C3(c5ccccc5-c5ccccc53)c3ccccc3-4)c2)c2ccccc2-c2ccccc21]

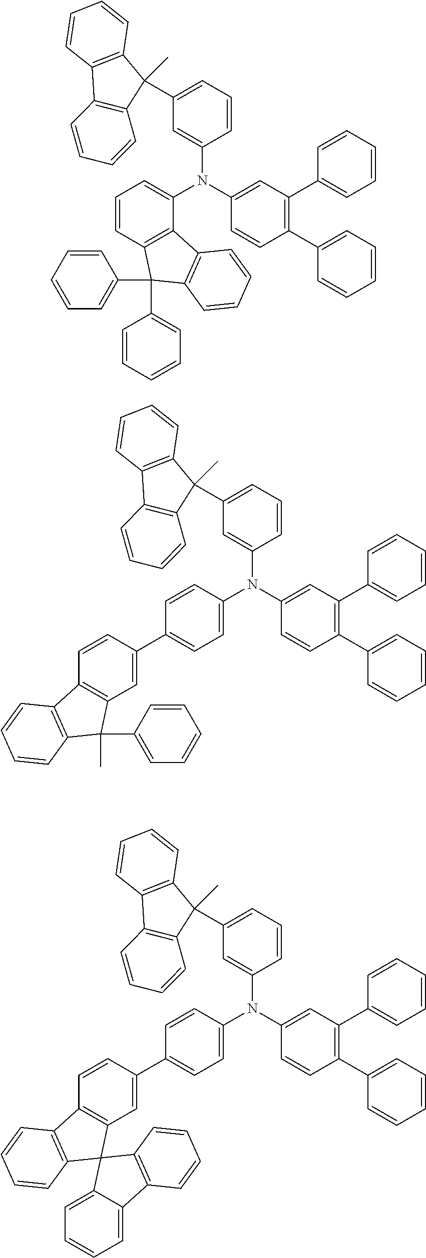

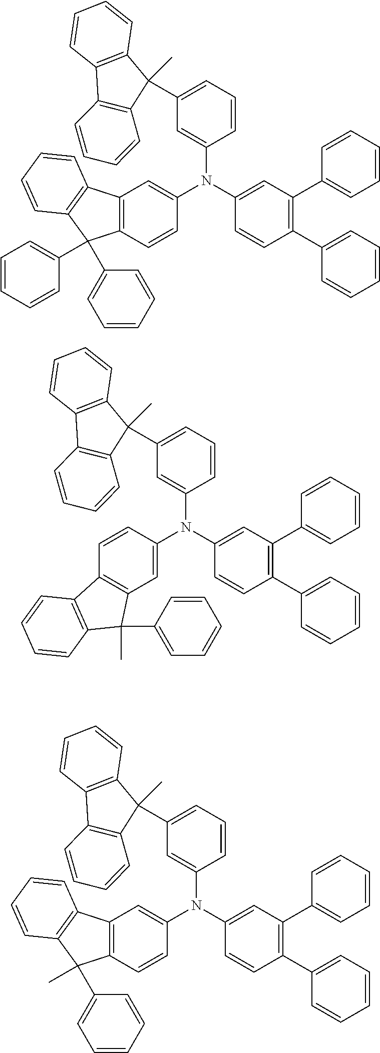

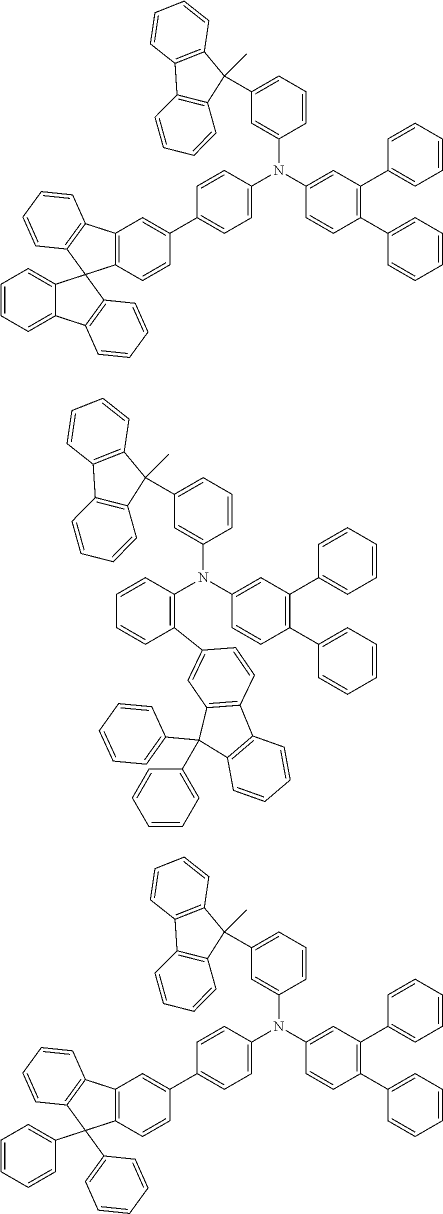

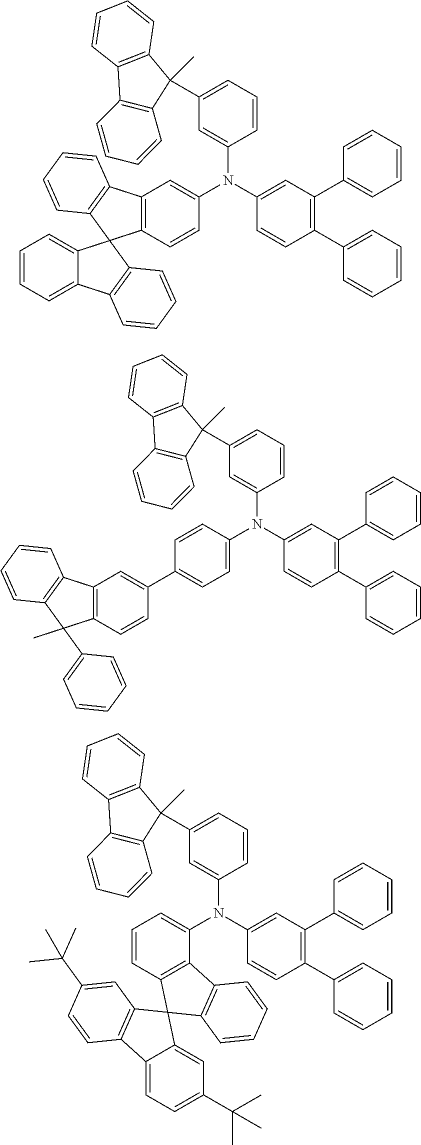

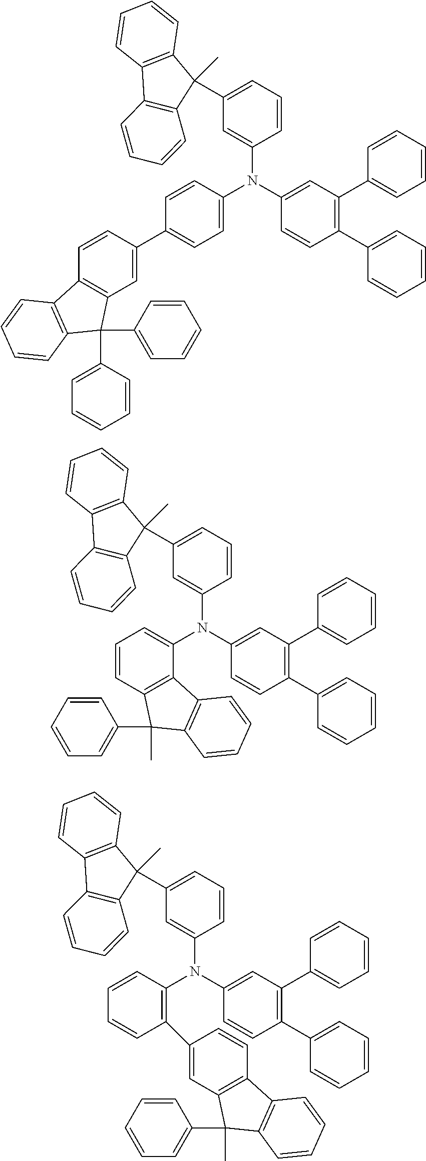

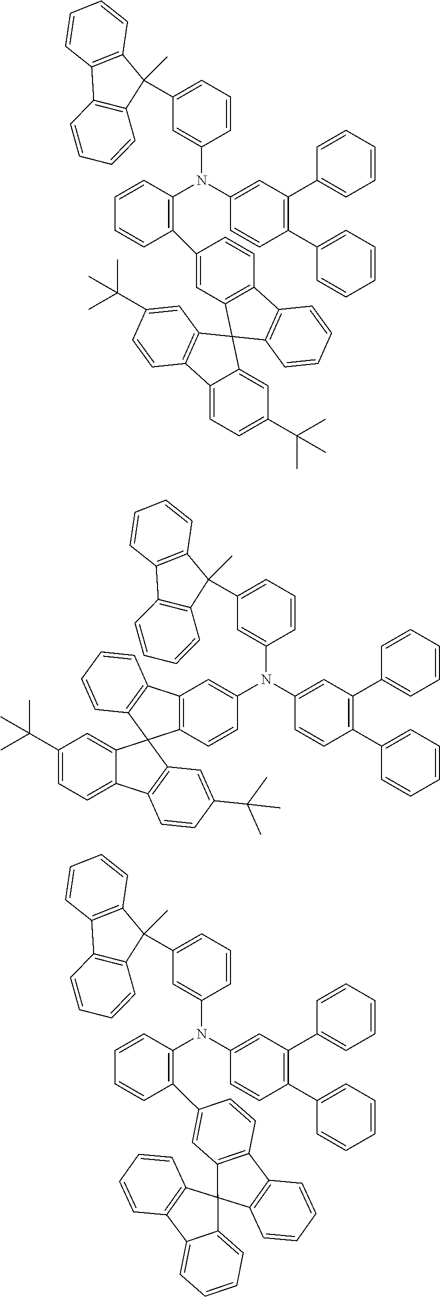 [SMILES: CC(C)(C)c1ccc2c(c1)C1(c3ccccc3-c3ccc(-c4ccccc4N(c4cccc(C5(C)c6ccccc6-c6ccccc65)c4)c4ccc(-c5ccccc5)c(-c5ccccc5)c4)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4ccc(-c5ccccc5)c(-c5ccccc5)c4)ccc31)c1cc(C(C)(C)C)ccc1-2 ; CC1(c2cccc(N(c3ccc(-c4ccccc4)c(-c4ccccc4)c3)c3ccccc3-c3ccc4c(c3)C3(c5ccccc5-c5ccccc53)c3ccccc3-4)c2)c2ccccc2-c2ccccc21]

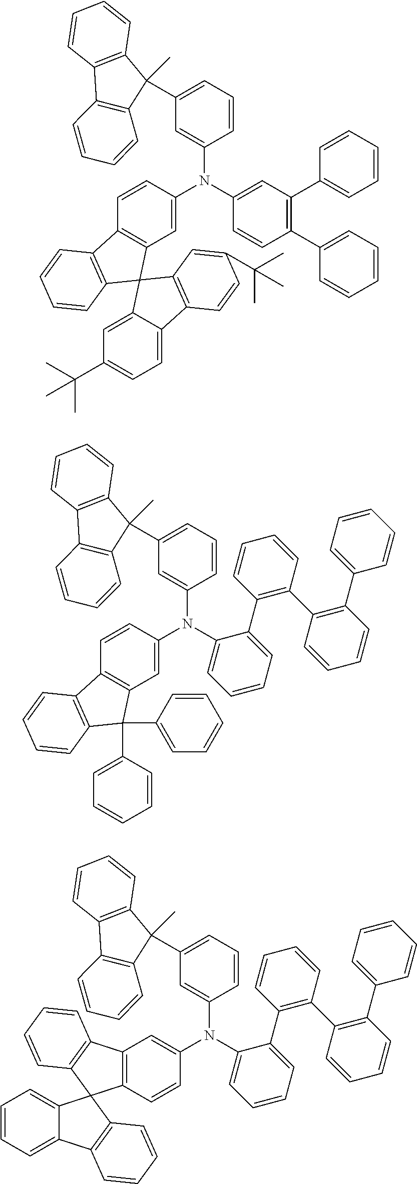

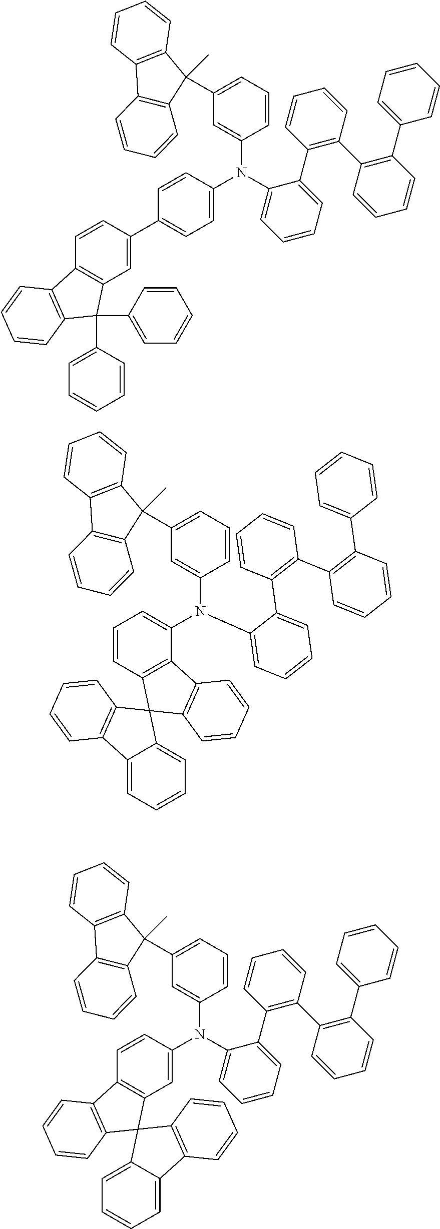

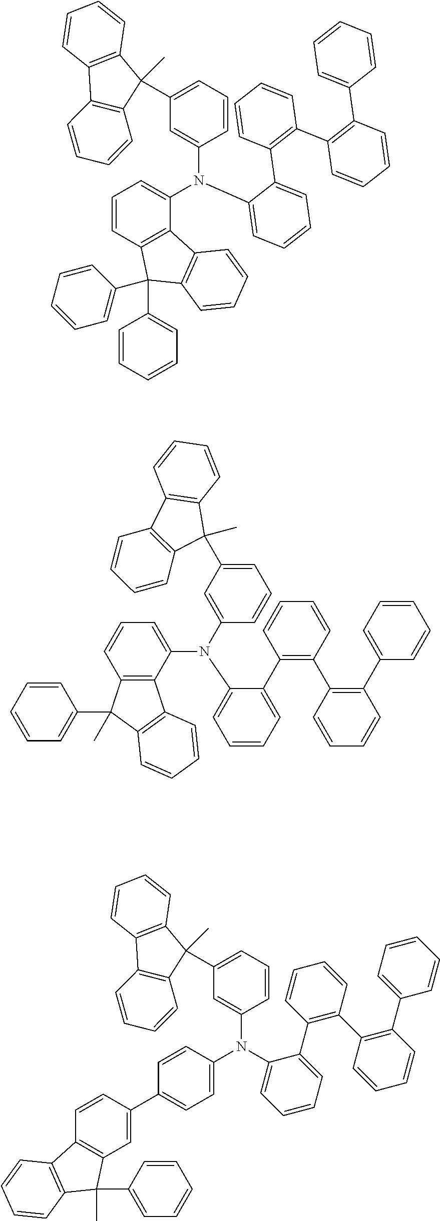 [SMILES: CC1(c2cccc(N(c3ccccc3-c3ccccc3-c3ccccc3-c3ccccc3)c3cccc4c3-c3ccccc3C4(c3ccccc3)c3ccccc3)c2)c2ccccc2-c2ccccc21 ; CC1(c2cccc(N(c3ccccc3-c3ccccc3-c3ccccc3-c3ccccc3)c3cccc4c3-c3ccccc3C4(C)c3ccccc3)c2)c2ccccc2-c2ccccc21 ; CC1(c2cccc(N(c3ccc(-c4ccc5c(c4)C(C)(c4ccccc4)c4ccccc4-5)cc3)c3ccccc3-c3ccccc3-c3ccccc3-c3ccccc3)c2)c2ccccc2-c2ccccc21]

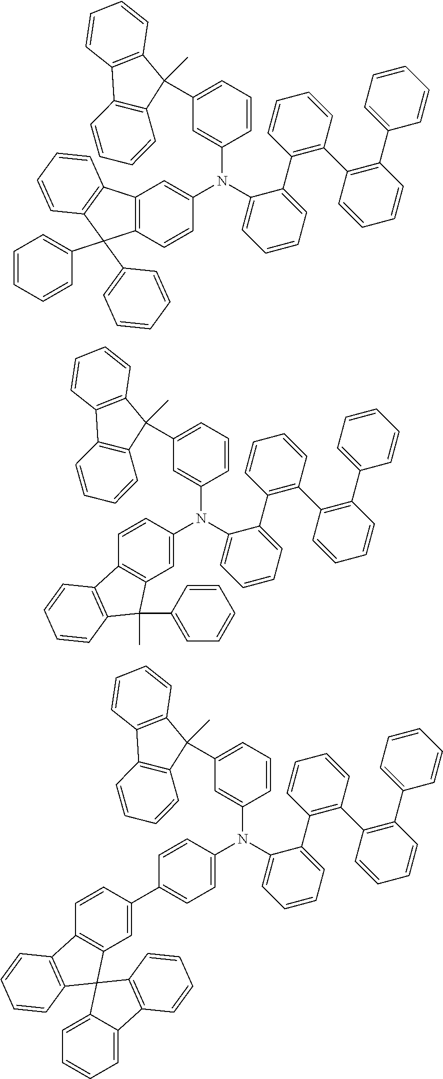

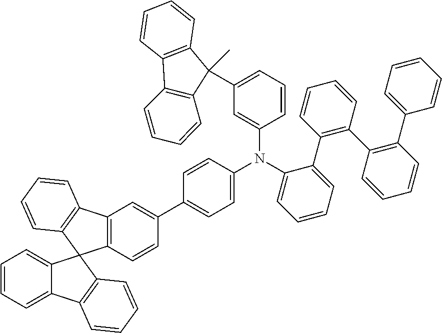 [SMILES: CC1(c2cccc(N(c3ccc(-c4ccc5c(c4)-c4ccccc4C54c5ccccc5-c5ccccc54)cc3)c3ccccc3-c3ccccc3-c3ccccc3-c3ccccc3)c2)c2ccccc2-c2ccccc21]

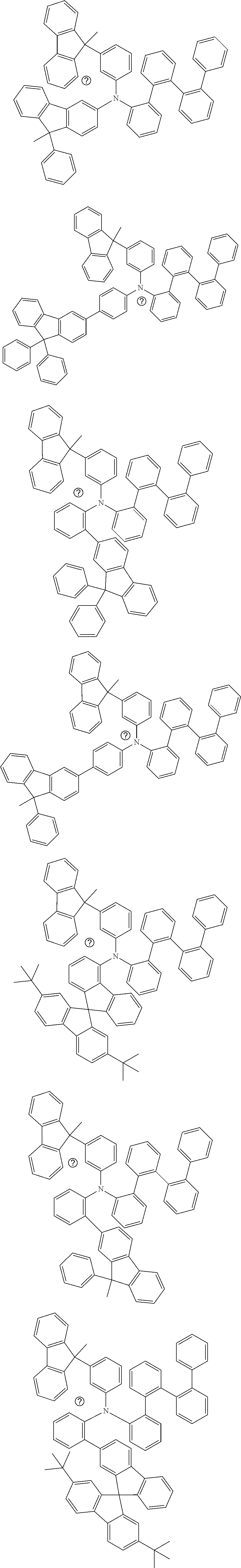

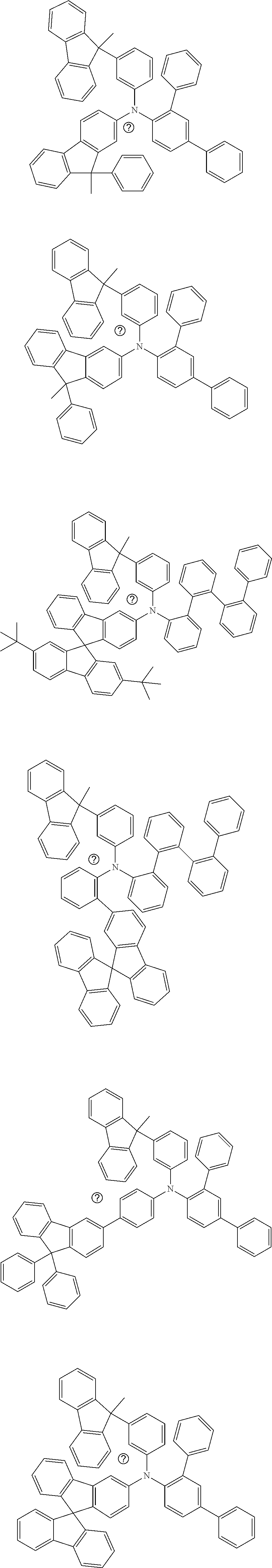

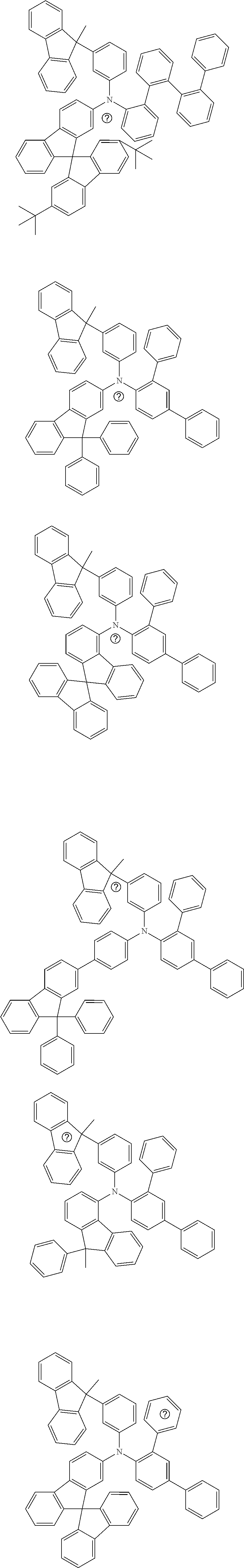

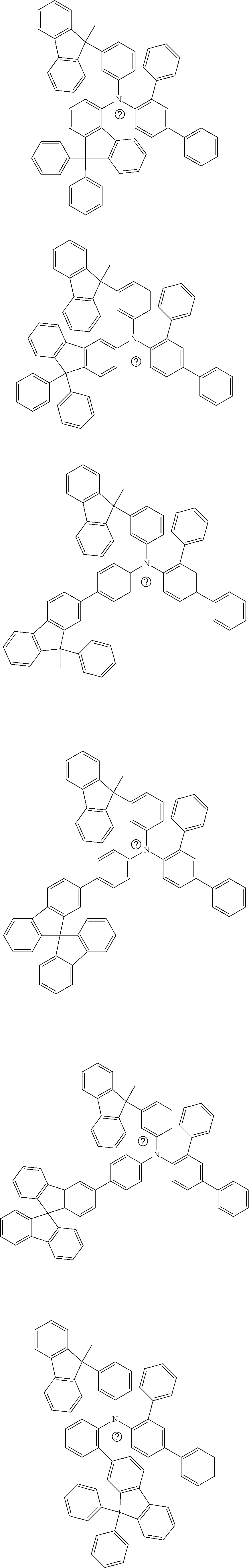

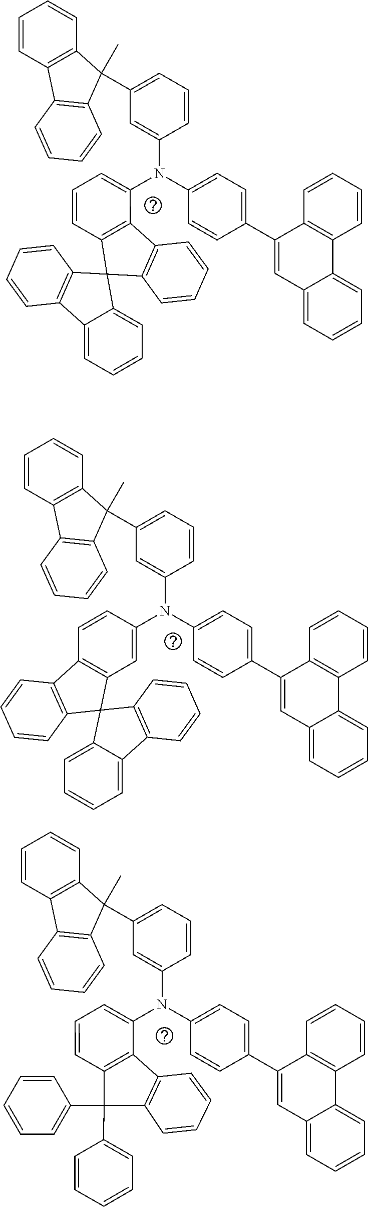

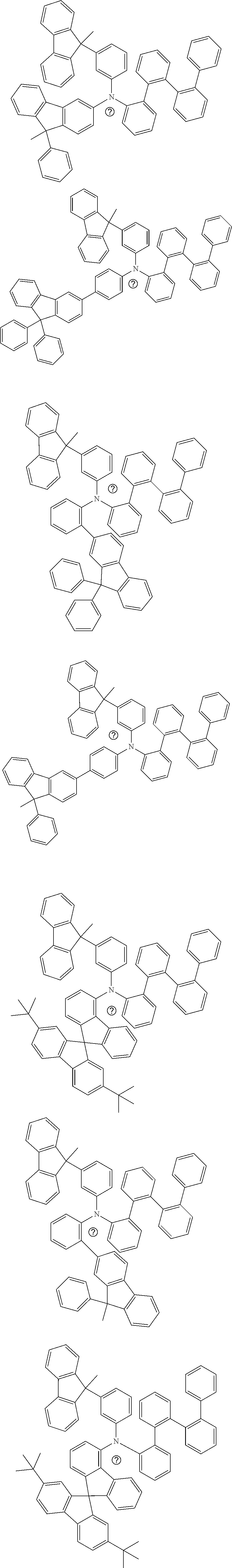

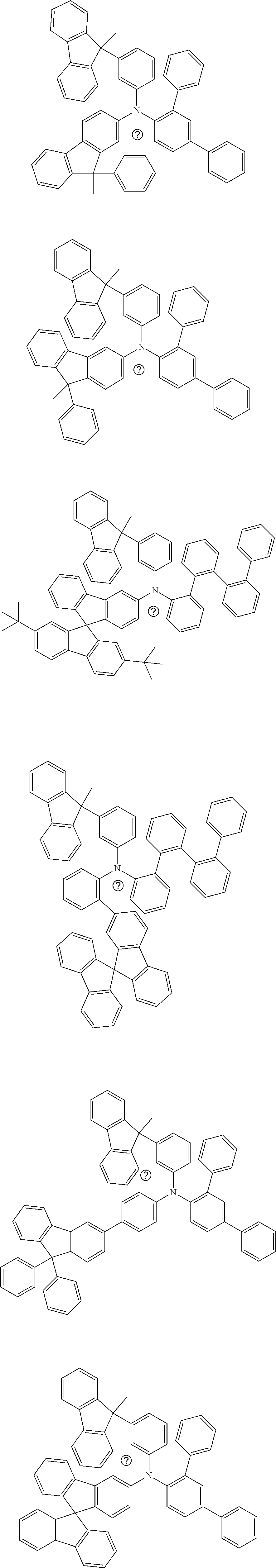

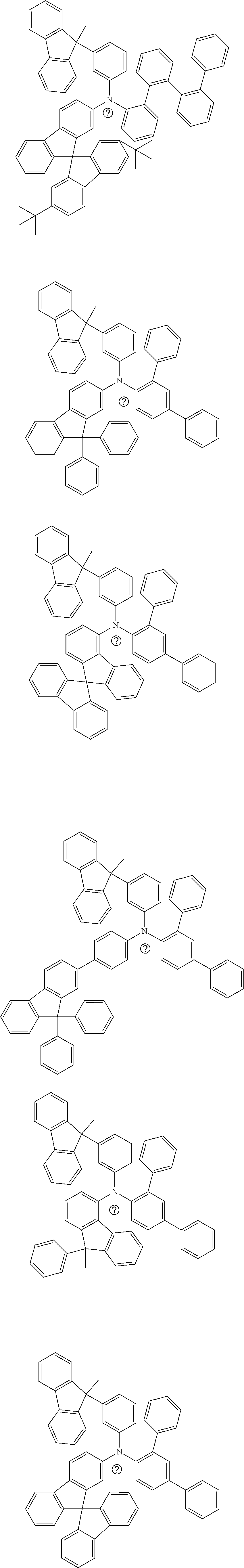

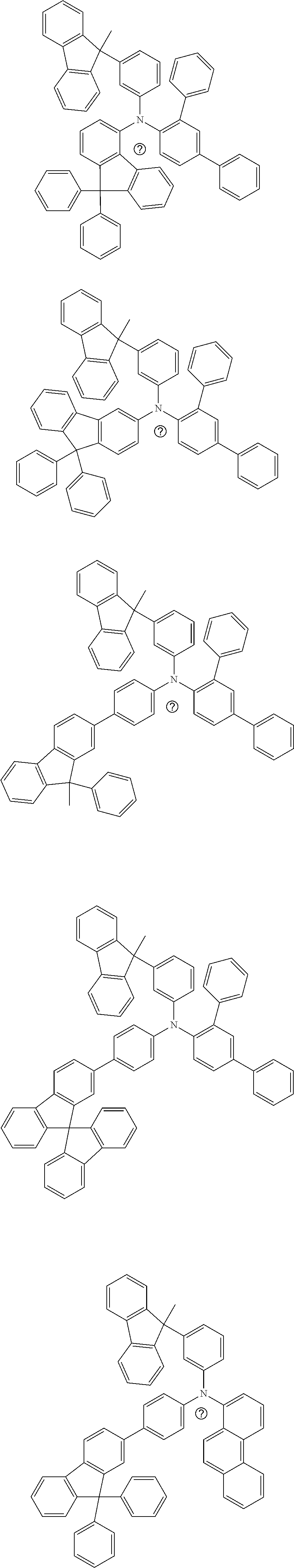

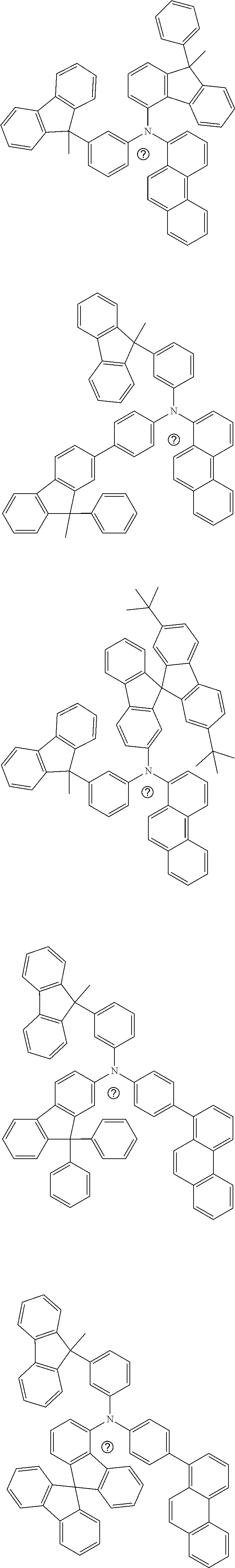

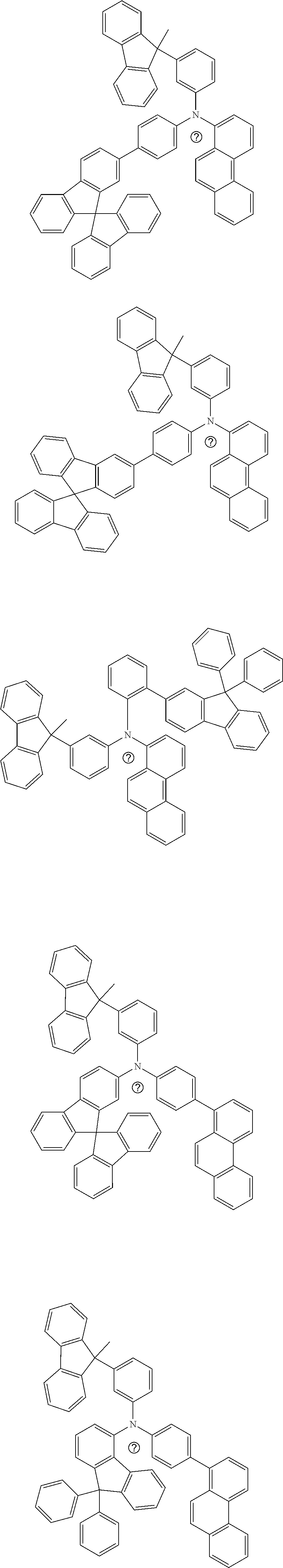

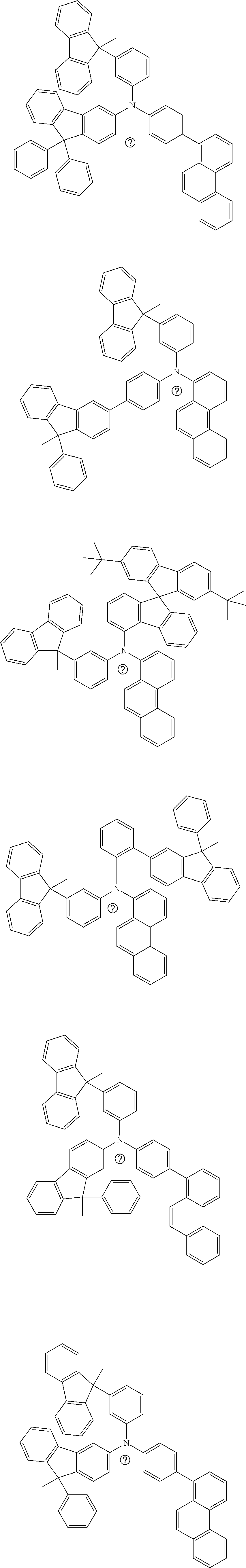

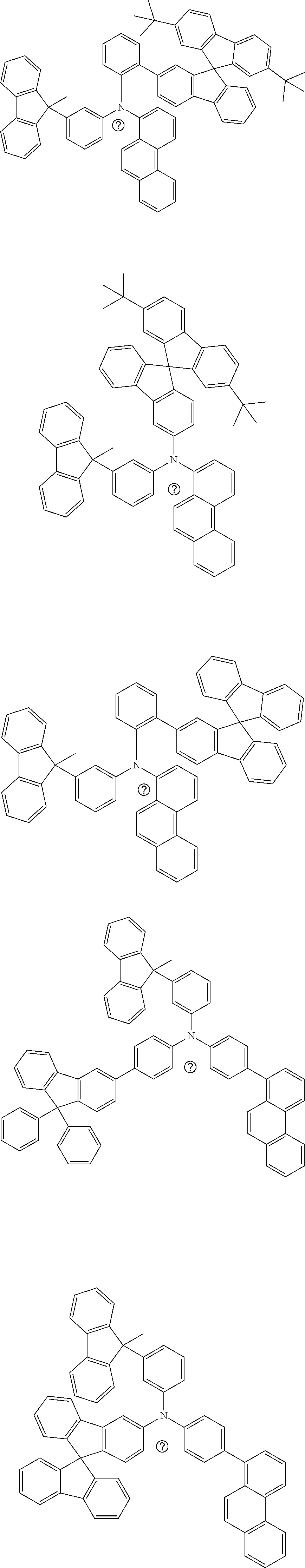

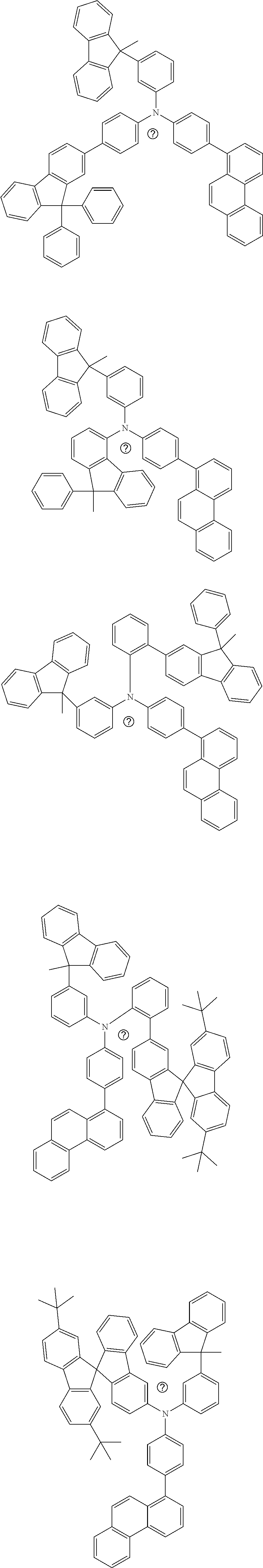

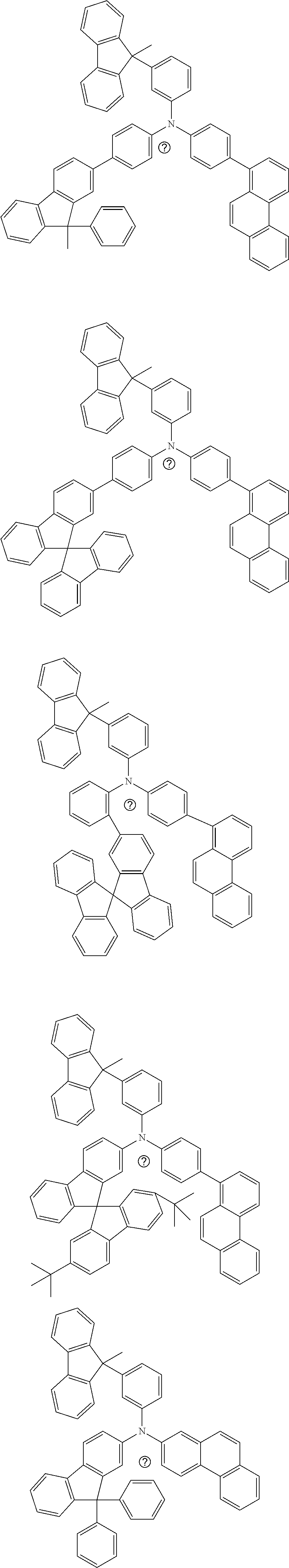

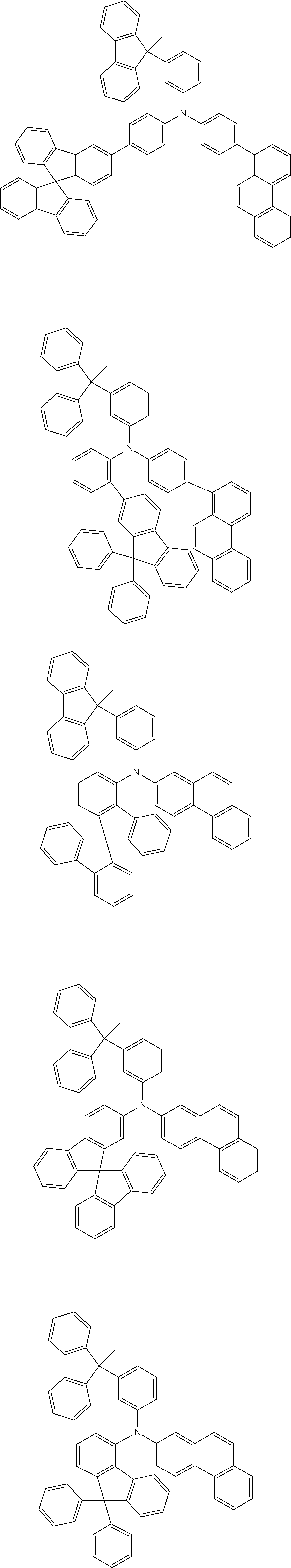

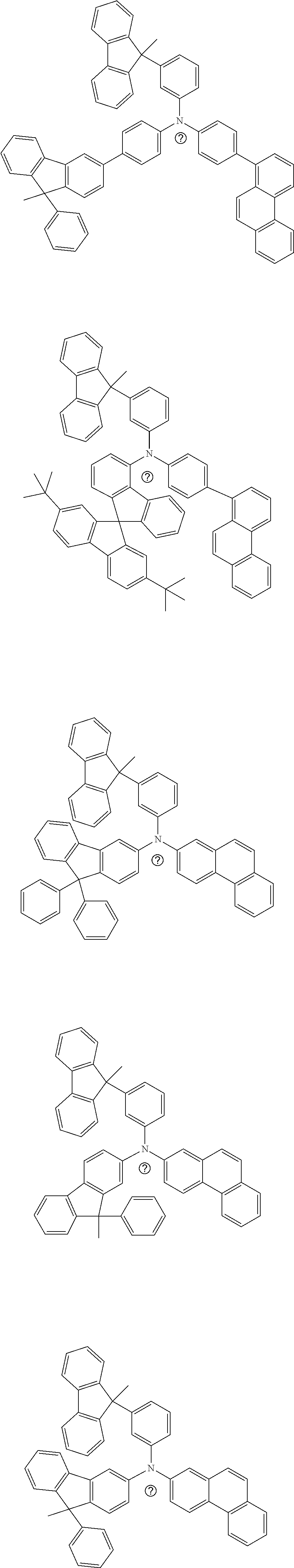

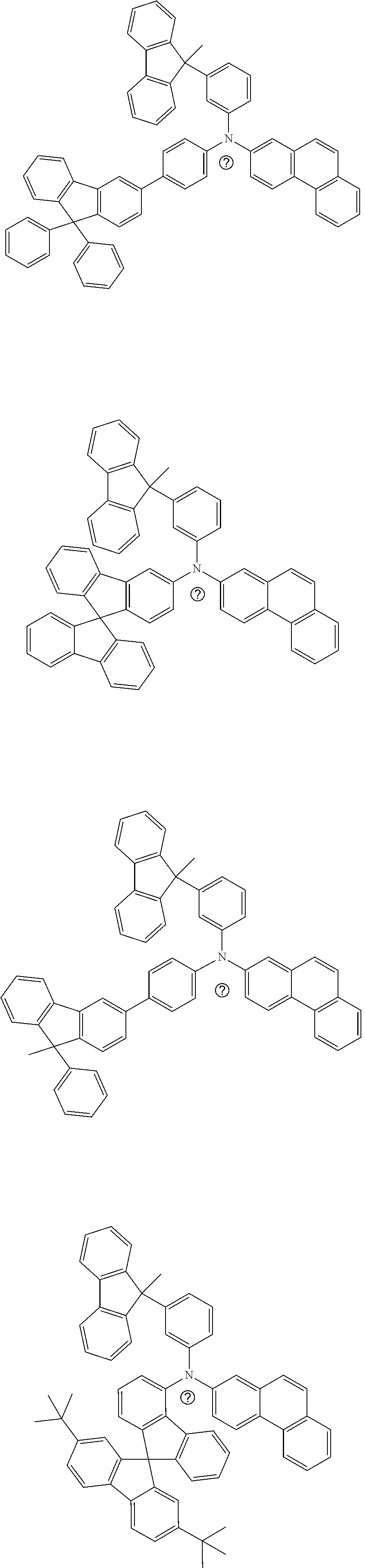

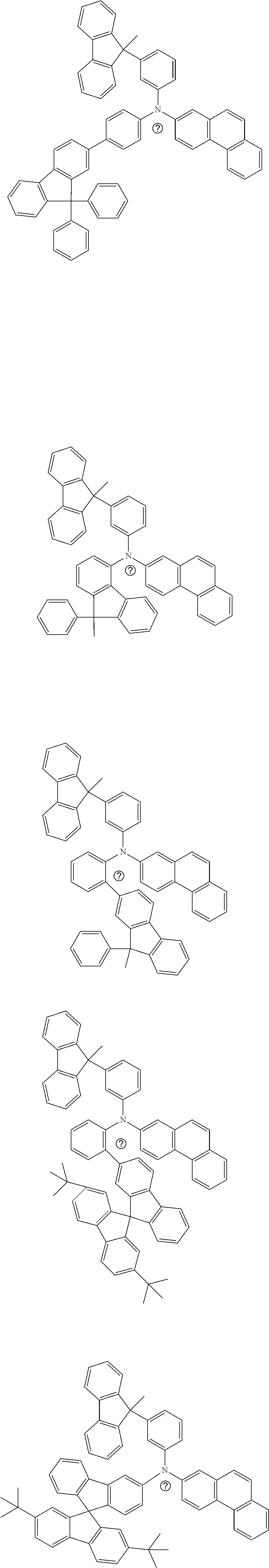

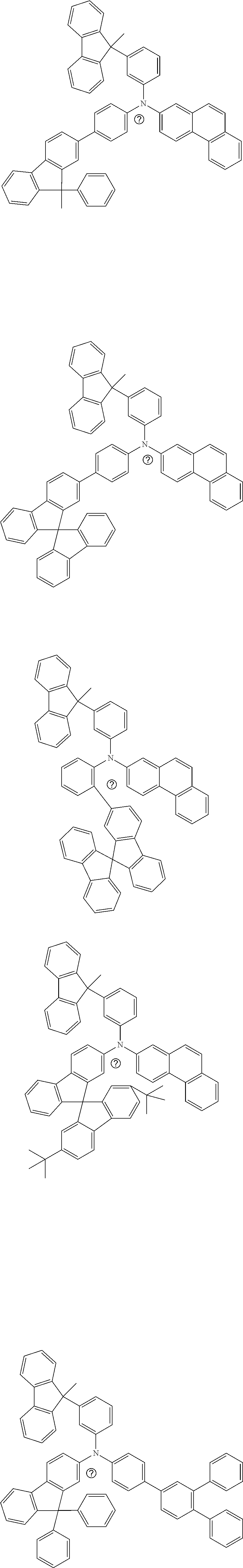

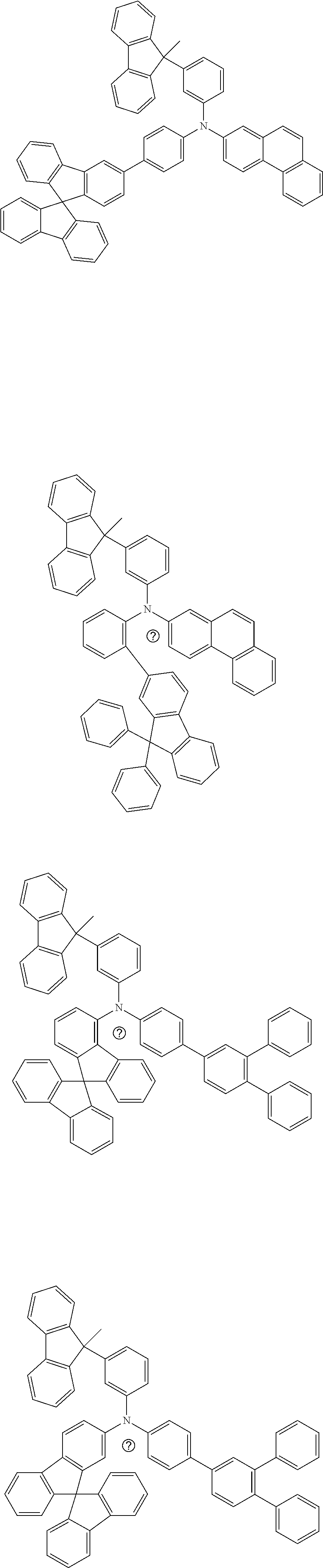 [SMILES: CC1(c2cccc(N(c3ccc(-c4ccc5c(c4)-c4ccccc4C54c5ccccc5-c5ccccc54)cc3)c3ccc4c(ccc5ccccc54)c3)c2)c2ccccc2-c2ccccc21 ; CC1(c2cccc(N(c3ccc4c(ccc5ccccc54)c3)c3ccccc3-c3ccc4c(c3)C(c3ccccc3)(c3ccccc3)c3ccccc3-4)c2)c2ccccc2-c2ccccc21 ; CC1(c2cccc(N(c3ccc(-c4ccc(-c5ccccc5)c(-c5ccccc5)c4)cc3)c3cccc4c3-c3ccccc3C43c4ccccc4-c4ccccc43)c2)c2ccccc2-c2ccccc21 ; CC1(c2cccc(N(c3ccc(-c4ccc(-c5ccccc5)c(-c5ccccc5)c4)cc3)c3ccc4c(c3)C3(c5ccccc5-c5ccccc53)c3ccccc3-4)c2)c2ccccc2-c2ccccc21]

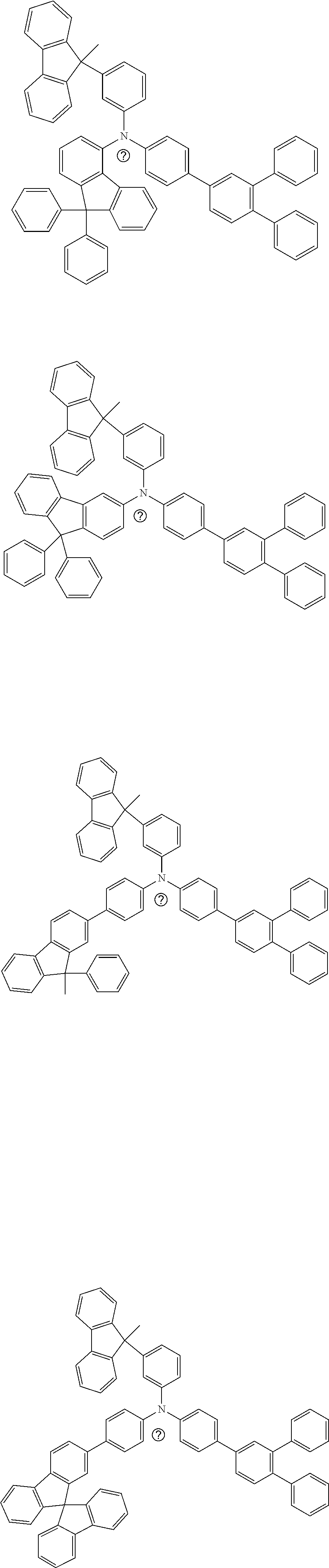 [SMILES: CC1(c2cccc(N(c3ccc(-c4ccc(-c5ccccc5)c(-c5ccccc5)c4)cc3)c3cccc4c3-c3ccccc3C4(c3ccccc3)c3ccccc3)c2)c2ccccc2-c2ccccc21 ; CC1(c2cccc(N(c3ccc(-c4ccc(-c5ccccc5)c(-c5ccccc5)c4)cc3)c3ccc4c(c3)-c3ccccc3C4(c3ccccc3)c3ccccc3)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)C(C)(c4ccccc4)c4ccccc4-5)cc3)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)C4(c6ccccc6-c6ccccc64)c4ccccc4-5)cc3)c2)c2ccccc2-c2ccccc21]

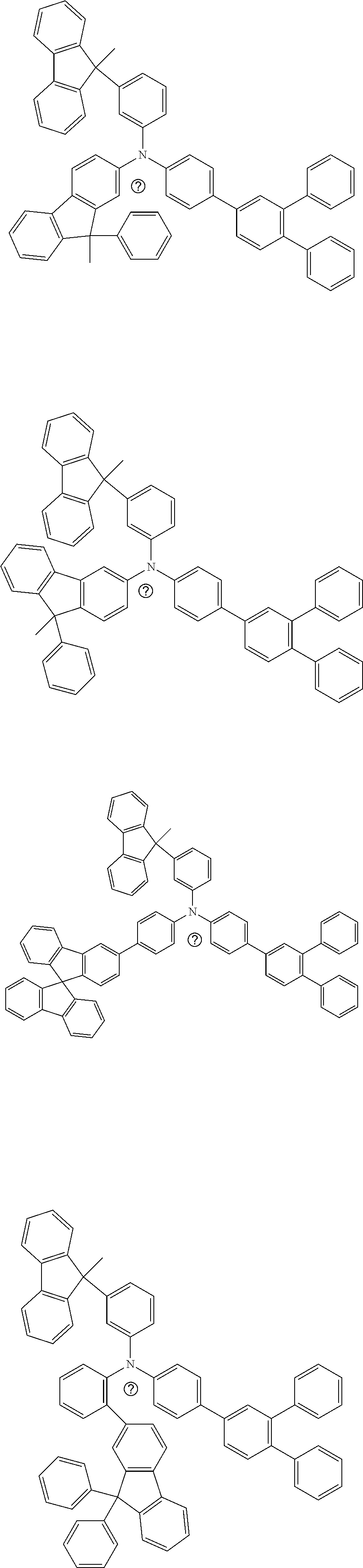 [SMILES: CC1(c2cccc(N(c3ccc(-c4ccc(-c5ccccc5)c(-c5ccccc5)c4)cc3)c3ccc4c(c3)C(C)(c3ccccc3)c3ccccc3-4)c2)c2ccccc2-c2ccccc21 ; CC1(c2cccc(N(c3ccc(-c4ccc(-c5ccccc5)c(-c5ccccc5)c4)cc3)c3ccc4c(c3)-c3ccccc3C4(C)c3ccccc3)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)-c4ccccc4C54c5ccccc5-c5ccccc54)cc3)c2)c2ccccc2-c2ccccc21 ; CC1(c2cccc(N(c3ccc(-c4ccc(-c5ccccc5)c(-c5ccccc5)c4)cc3)c3ccccc3-c3ccc4c(c3)C(c3ccccc3)(c3ccccc3)c3ccccc3-4)c2)c2ccccc2-c2ccccc21]

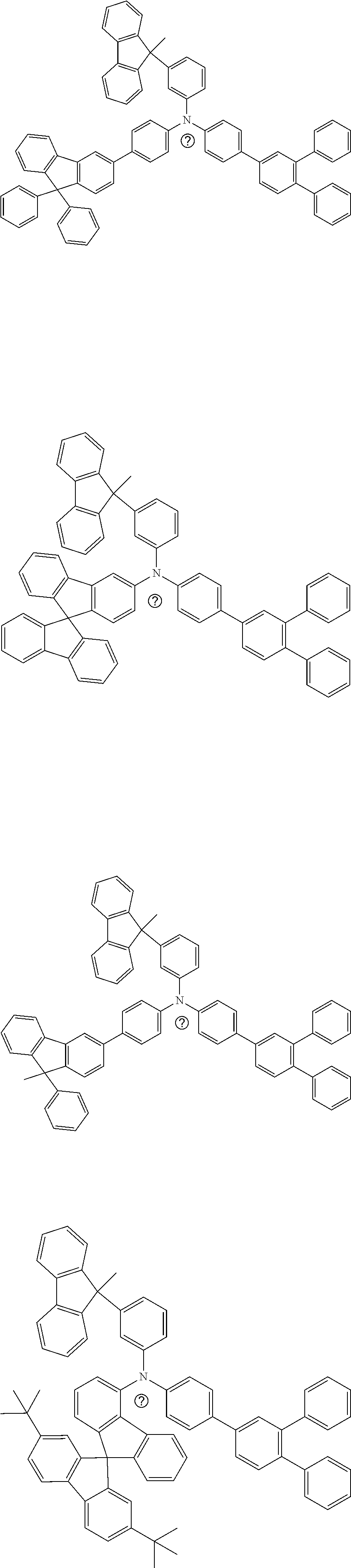

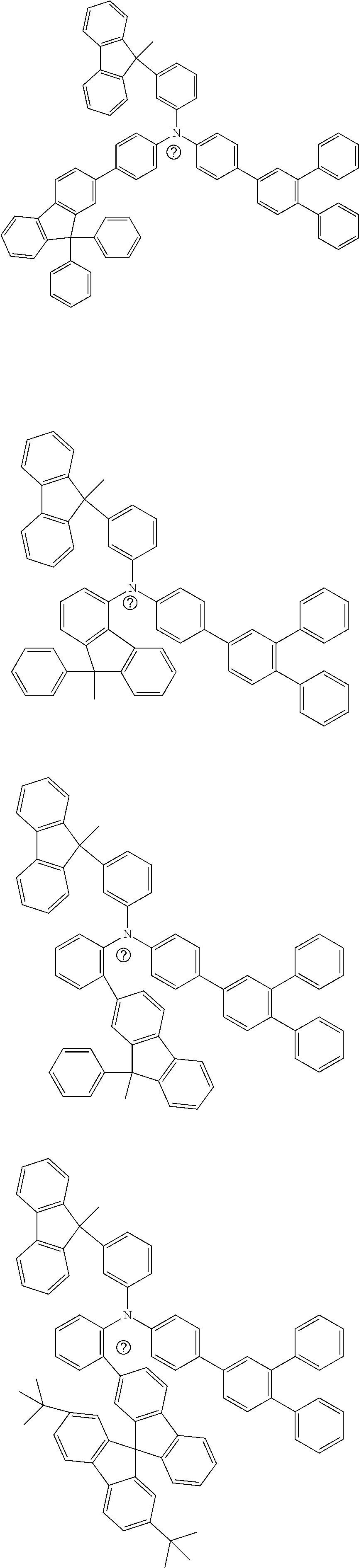

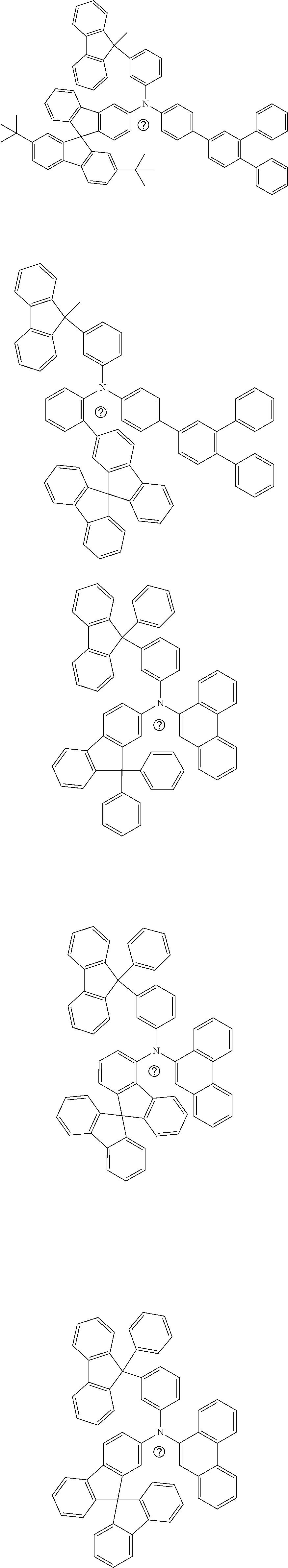

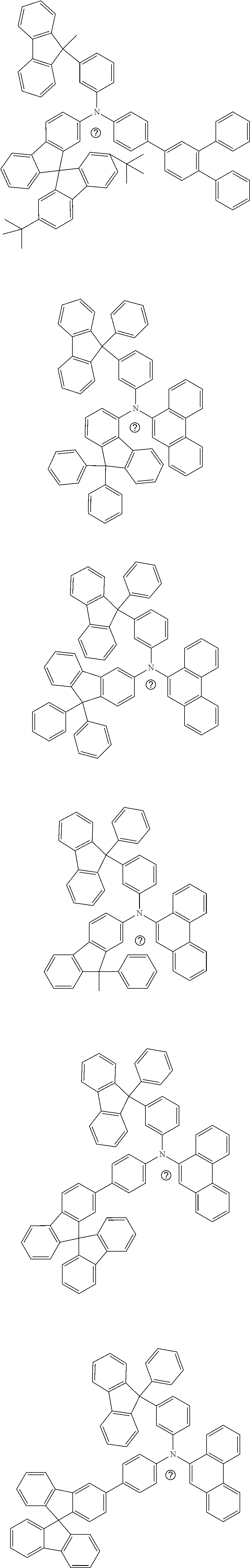

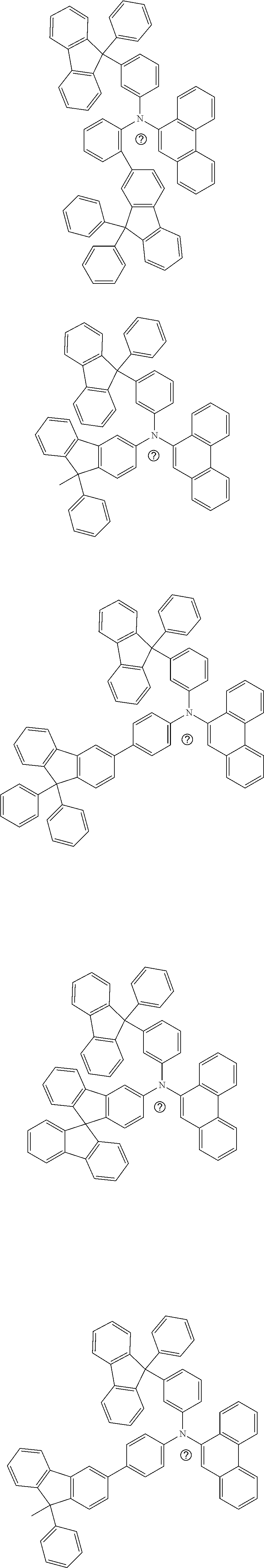

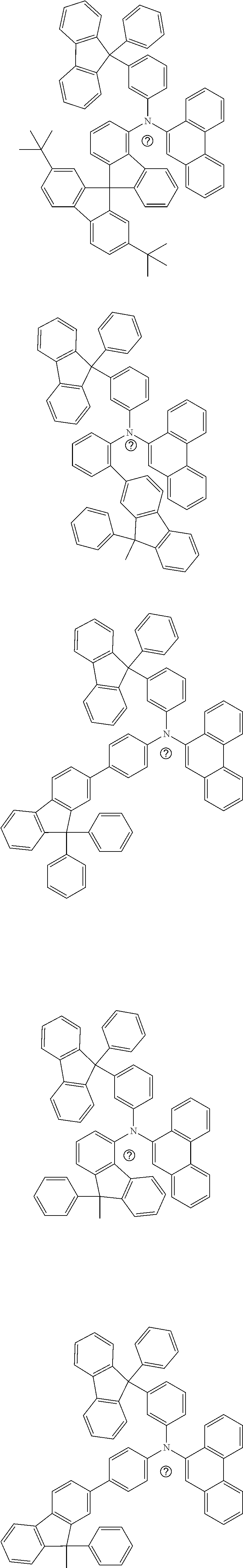

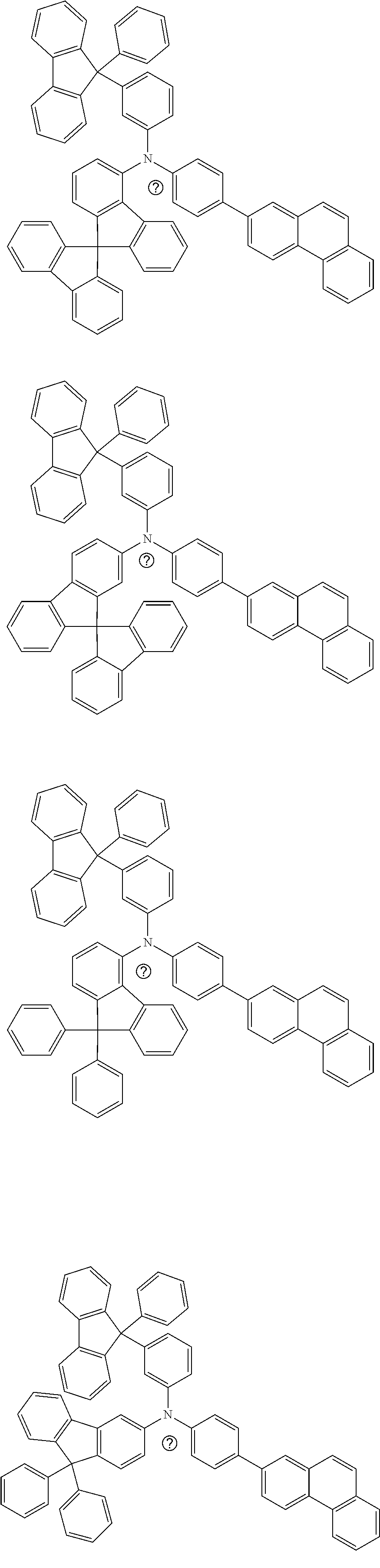

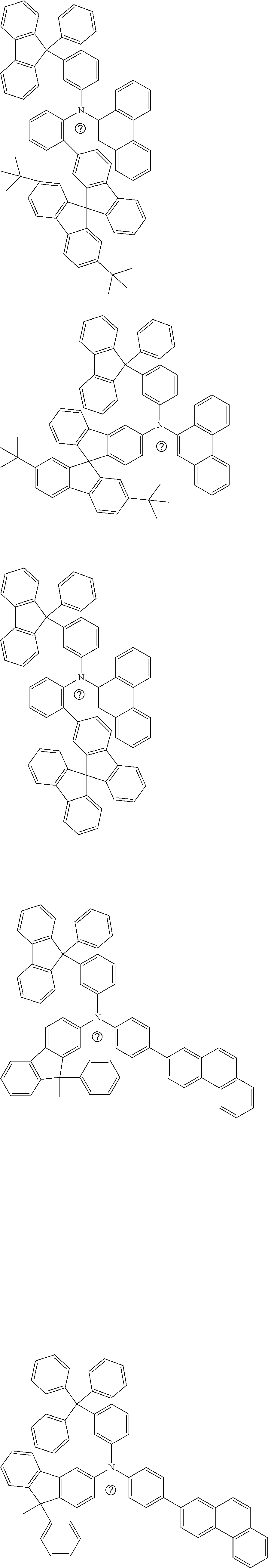

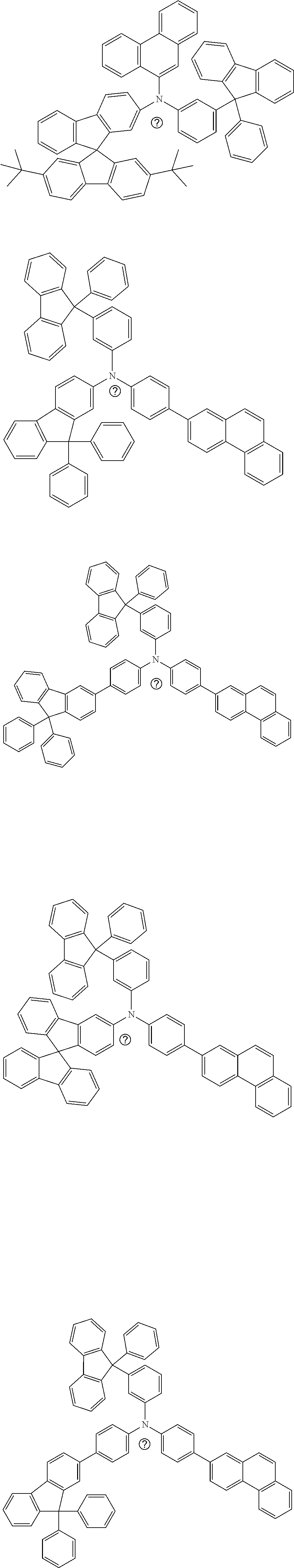

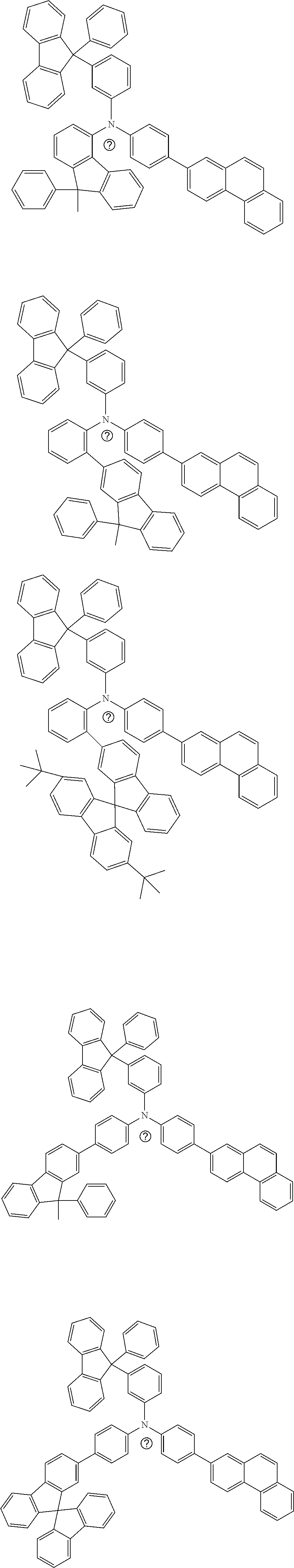

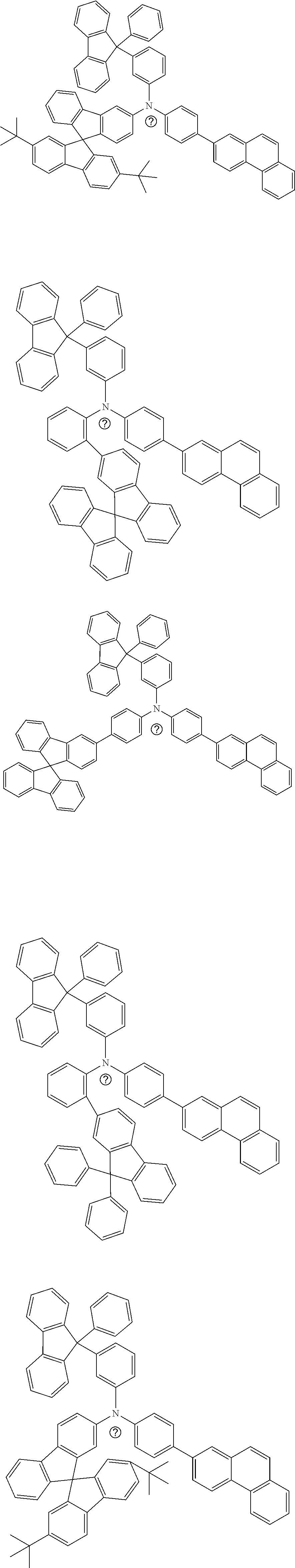

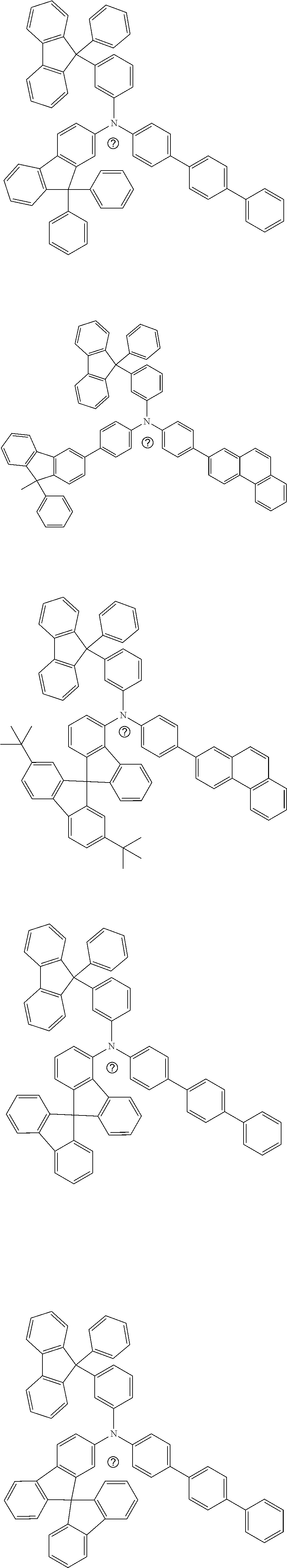

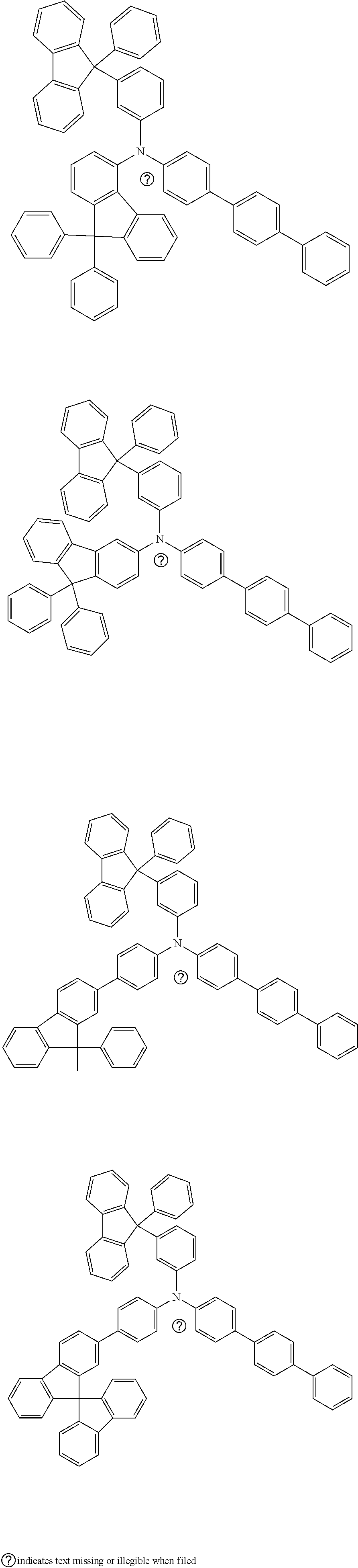 [SMILES: c1ccc(-c2ccc(-c3ccc(N(c4cccc(C5(c6ccccc6)c6ccccc6-c6ccccc65)c4)c4cccc5c4-c4ccccc4C5(c4ccccc4)c4ccccc4)cc3)cc2)cc1 ; c1ccc(-c2ccc(-c3ccc(N(c4cccc(C5(c6ccccc6)c6ccccc6-c6ccccc65)c4)c4ccc5c(c4)-c4ccccc4C5(c4ccccc4)c4ccccc4)cc3)cc2)cc1 ; CC1(c2ccccc2)c2ccccc2-c2ccc(-c3ccc(N(c4ccc(-c5ccc(-c6ccccc6)cc5)cc4)c4cccc(C5(c6ccccc6)c6ccccc6-c6ccccc65)c4)cc3)cc21 ; c1ccc(-c2ccc(-c3ccc(N(c4ccc(-c5ccc6c(c5)C5(c7ccccc7-c7ccccc75)c5ccccc5-6)cc4)c4cccc(C5(c6ccccc6)c6ccccc6-c6ccccc65)c4)cc3)cc2)cc1]

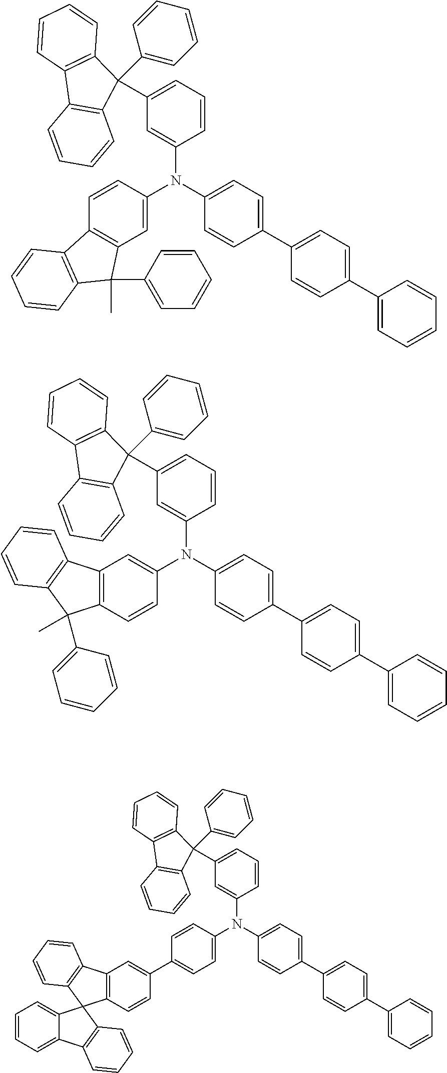 [SMILES: CC1(c2ccccc2)c2ccccc2-c2ccc(N(c3ccc(-c4ccc(-c5ccccc5)cc4)cc3)c3cccc(C4(c5ccccc5)c5ccccc5-c5ccccc54)c3)cc21 ; CC1(c2ccccc2)c2ccccc2-c2cc(N(c3ccc(-c4ccc(-c5ccccc5)cc4)cc3)c3cccc(C4(c5ccccc5)c5ccccc5-c5ccccc54)c3)ccc21 ; c1ccc(-c2ccc(-c3ccc(N(c4ccc(-c5ccc6c(c5)-c5ccccc5C65c6ccccc6-c6ccccc65)cc4)c4cccc(C5(c6ccccc6)c6ccccc6-c6ccccc65)c4)cc3)cc2)cc1]

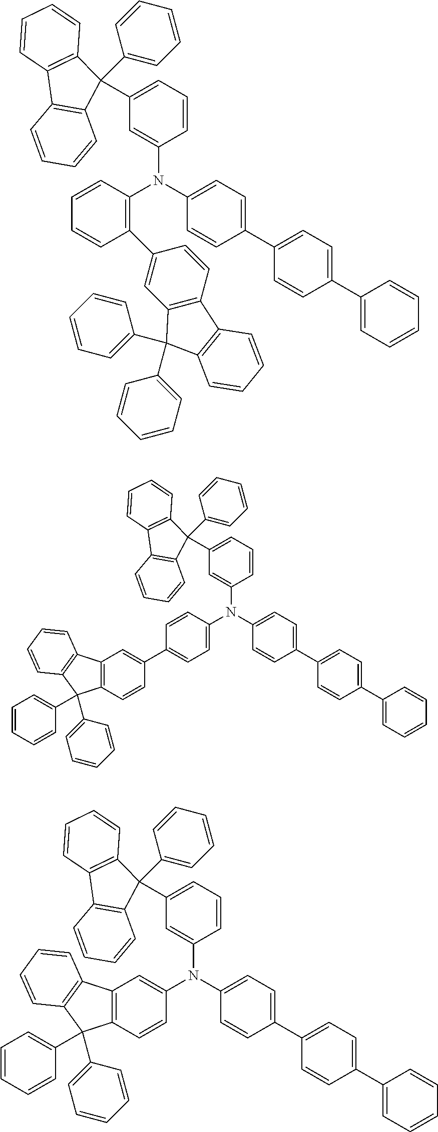

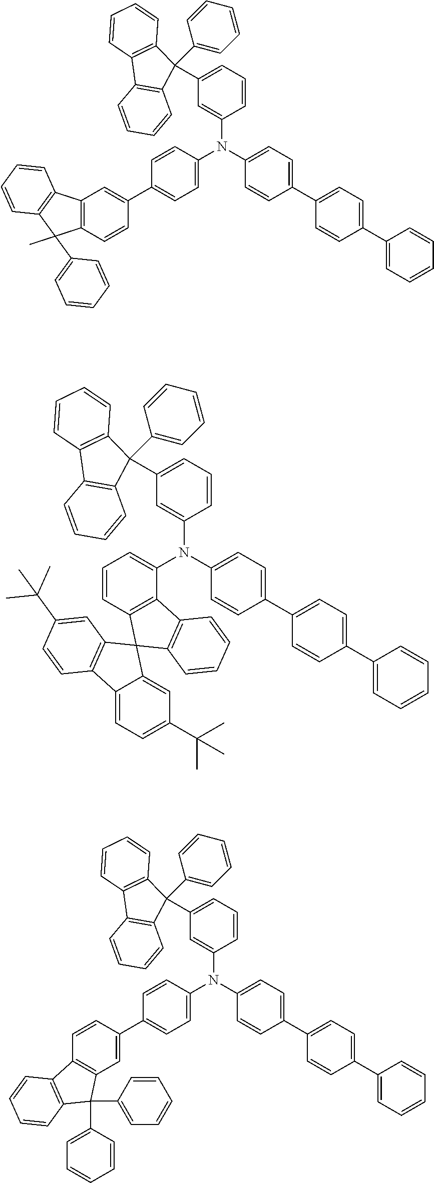 [SMILES: CC1(c2ccccc2)c2ccccc2-c2cc(-c3ccc(N(c4ccc(-c5ccc(-c6ccccc6)cc5)cc4)c4cccc(C5(c6ccccc6)c6ccccc6-c6ccccc65)c4)cc3)ccc21 ; CC(C)(C)c1ccc2c(c1)C1(c3cc(C(C)(C)C)ccc3-2)c2ccccc2-c2c(N(c3ccc(-c4ccc(-c5ccccc5)cc4)cc3)c3cccc(C4(c5ccccc5)c5ccccc5-c5ccccc54)c3)cccc21 ; c1ccc(-c2ccc(-c3ccc(N(c4ccc(-c5ccc6c(c5)C(c5ccccc5)(c5ccccc5)c5ccccc5-6)cc4)c4cccc(C5(c6ccccc6)c6ccccc6-c6ccccc65)c4)cc3)cc2)cc1]

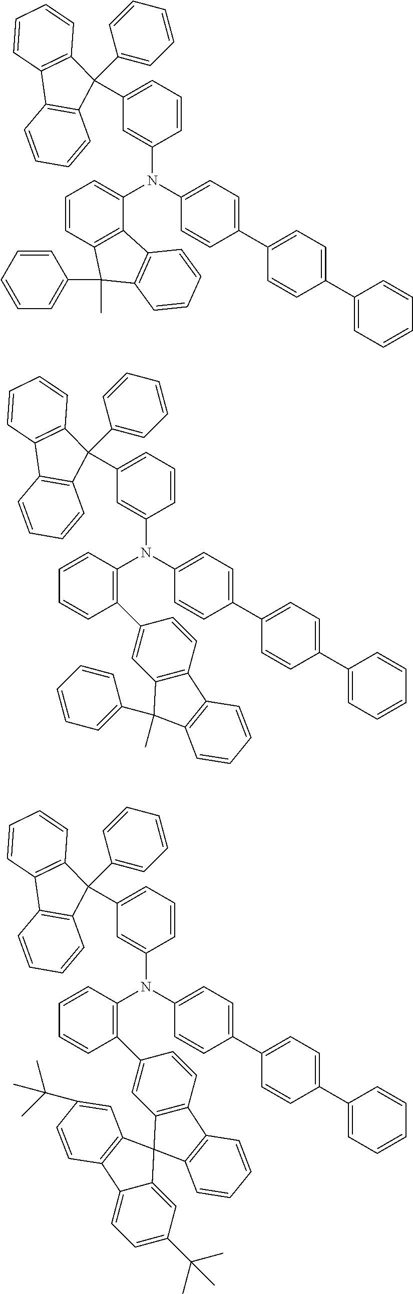 [SMILES: CC1(c2ccccc2)c2ccccc2-c2c(N(c3ccc(-c4ccc(-c5ccccc5)cc4)cc3)c3cccc(C4(c5ccccc5)c5ccccc5-c5ccccc54)c3)cccc21 ; CC1(c2ccccc2)c2ccccc2-c2ccc(-c3ccccc3N(c3ccc(-c4ccc(-c5ccccc5)cc4)cc3)c3cccc(C4(c5ccccc5)c5ccccc5-c5ccccc54)c3)cc21 ; CC(C)(C)c1ccc2c(c1)C1(c3ccccc3-c3ccc(-c4ccccc4N(c4ccc(-c5ccc(-c6ccccc6)cc5)cc4)c4cccc(C5(c6ccccc6)c6ccccc6-c6ccccc65)c4)cc31)c1cc(C(C)(C)C)ccc1-2]

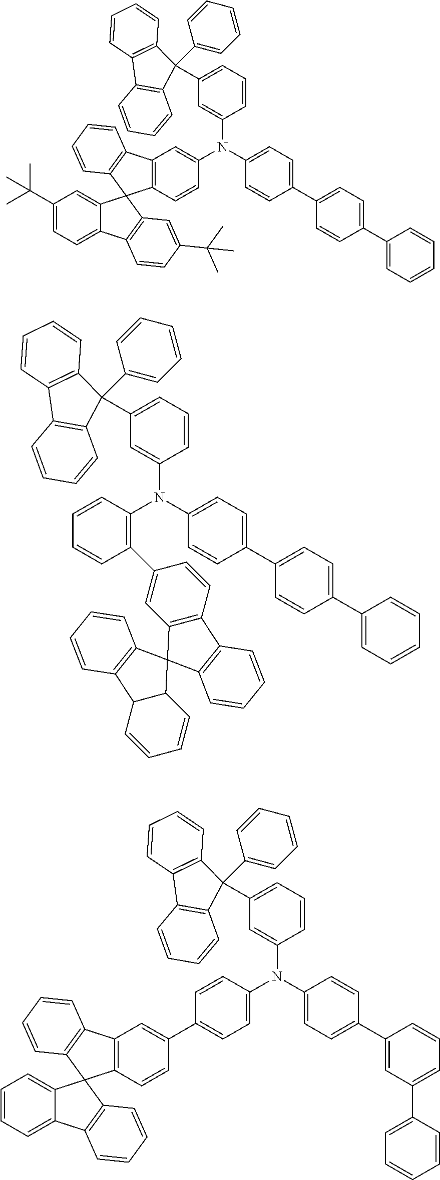 [SMILES: CC(C)(C)c1ccc2c(c1)C1(c3ccccc3-c3cc(N(c4ccc(-c5ccc(-c6ccccc6)cc5)cc4)c4cccc(C5(c6ccccc6)c6ccccc6-c6ccccc65)c4)ccc31)c1cc(C(C)(C)C)ccc1-2 ; C1=CC2c3ccccc3C3(c4ccccc4-c4ccc(-c5ccccc5N(c5ccc(-c6ccc(-c7ccccc7)cc6)cc5)c5cccc(C6(c7ccccc7)c7ccccc7-c7ccccc76)c5)cc43)C2C=C1 ; c1ccc(-c2cccc(-c3ccc(N(c4ccc(-c5ccc6c(c5)-c5ccccc5C65c6ccccc6-c6ccccc65)cc4)c4cccc(C5(c6ccccc6)c6ccccc6-c6ccccc65)c4)cc3)c2)cc1]

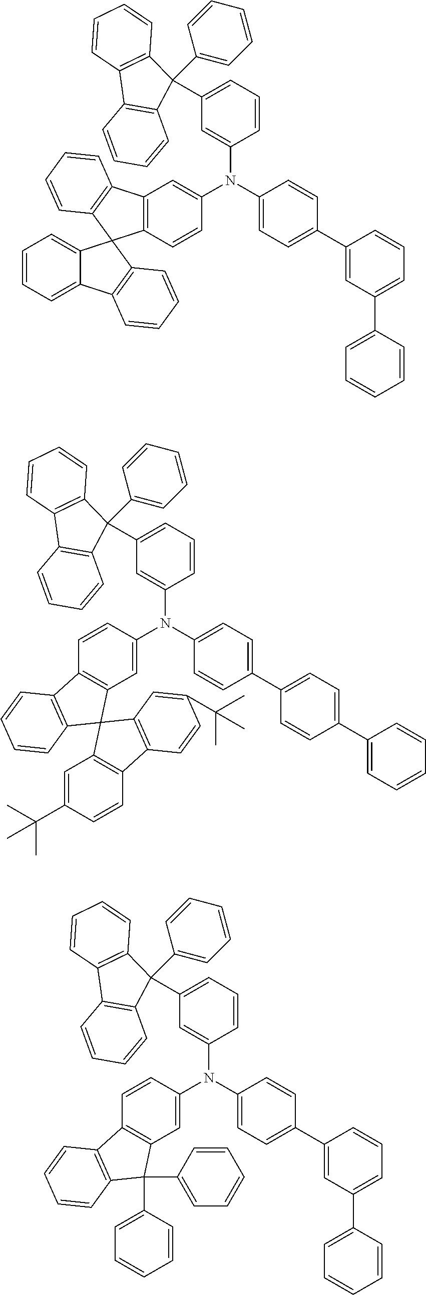 [SMILES: c1ccc(-c2cccc(-c3ccc(N(c4cccc(C5(c6ccccc6)c6ccccc6-c6ccccc65)c4)c4ccc5c(c4)-c4ccccc4C54c5ccccc5-c5ccccc54)cc3)c2)cc1 ; CC(C)(C)c1ccc2c(c1)C1(c3ccccc3-c3ccc(N(c4ccc(-c5ccc(-c6ccccc6)cc5)cc4)c4cccc(C5(c6ccccc6)c6ccccc6-c6ccccc65)c4)cc31)c1cc(C(C)(C)C)ccc1-2 ; c1ccc(-c2cccc(-c3ccc(N(c4cccc(C5(c6ccccc6)c6ccccc6-c6ccccc65)c4)c4ccc5c(c4)C(c4ccccc4)(c4ccccc4)c4ccccc4-5)cc3)c2)cc1]

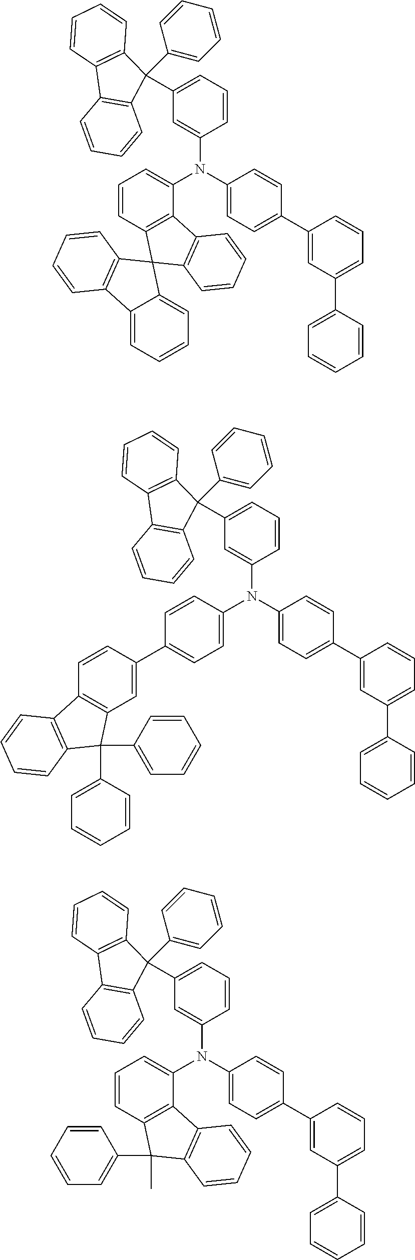 [SMILES: c1ccc(-c2cccc(-c3ccc(N(c4cccc(C5(c6ccccc6)c6ccccc6-c6ccccc65)c4)c4cccc5c4-c4ccccc4C54c5ccccc5-c5ccccc54)cc3)c2)cc1 ; c1ccc(-c2cccc(-c3ccc(N(c4ccc(-c5ccc6c(c5)C(c5ccccc5)(c5ccccc5)c5ccccc5-6)cc4)c4cccc(C5(c6ccccc6)c6ccccc6-c6ccccc65)c4)cc3)c2)cc1 ; CC1(c2ccccc2)c2ccccc2-c2c(N(c3ccc(-c4cccc(-c5ccccc5)c4)cc3)c3cccc(C4(c5ccccc5)c5ccccc5-c5ccccc54)c3)cccc21]

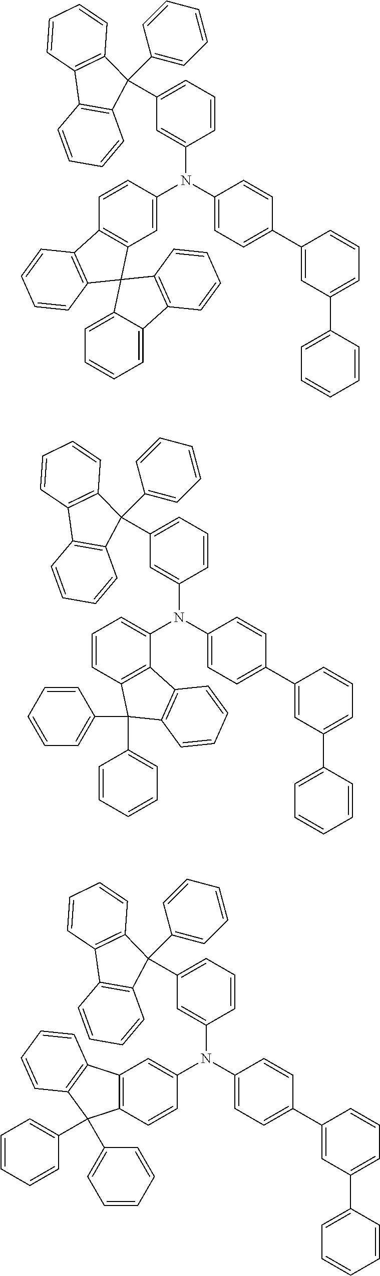 [SMILES: c1ccc(-c2cccc(-c3ccc(N(c4cccc(C5(c6ccccc6)c6ccccc6-c6ccccc65)c4)c4ccc5c(c4)C4(c6ccccc6-c6ccccc64)c4ccccc4-5)cc3)c2)cc1 ; c1ccc(-c2cccc(-c3ccc(N(c4cccc(C5(c6ccccc6)c6ccccc6-c6ccccc65)c4)c4cccc5c4-c4ccccc4C5(c4ccccc4)c4ccccc4)cc3)c2)cc1 ; c1ccc(-c2cccc(-c3ccc(N(c4cccc(C5(c6ccccc6)c6ccccc6-c6ccccc65)c4)c4ccc5c(c4)-c4ccccc4C5(c4ccccc4)c4ccccc4)cc3)c2)cc1]

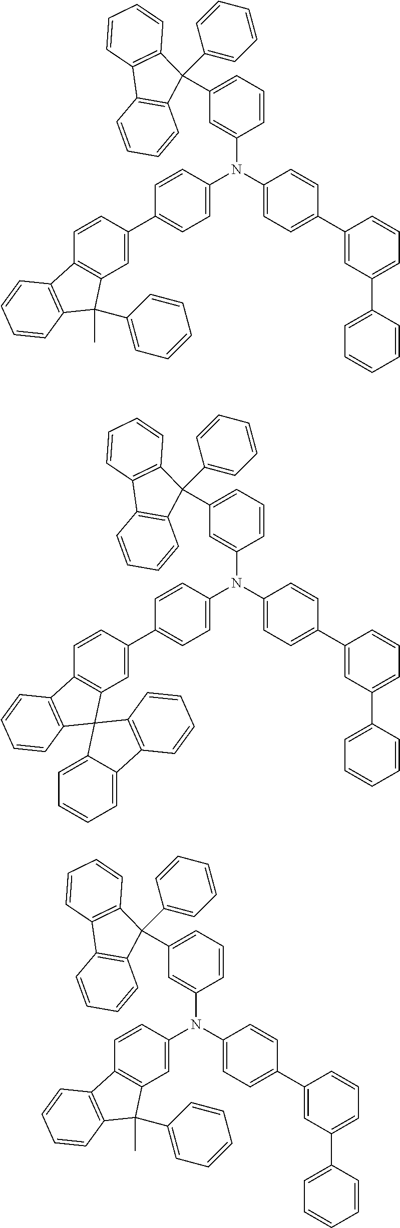

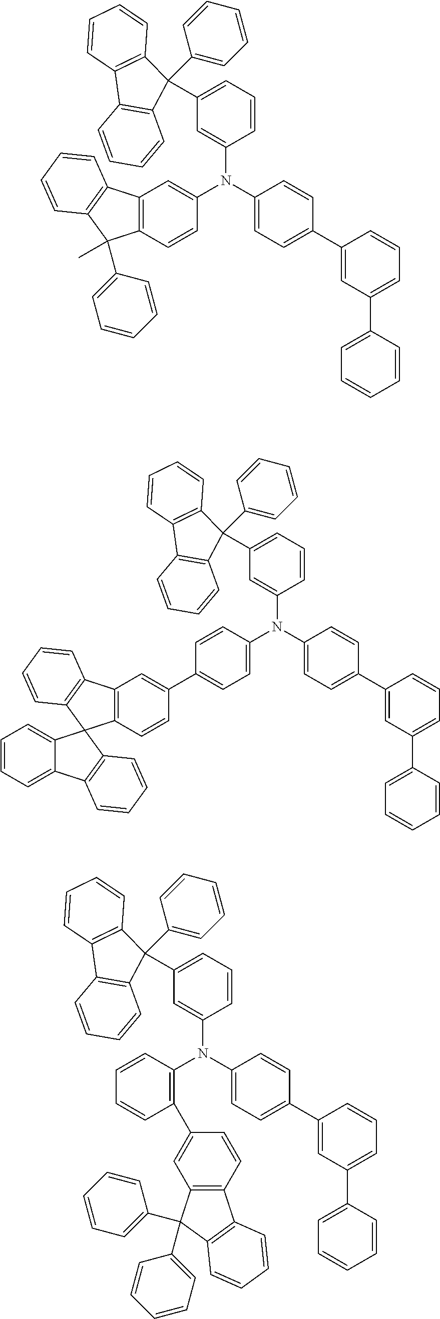 [SMILES: CC1(c2ccccc2)c2ccccc2-c2cc(N(c3ccc(-c4cccc(-c5ccccc5)c4)cc3)c3cccc(C4(c5ccccc5)c5ccccc5-c5ccccc54)c3)ccc21 ; c1ccc(-c2cccc(-c3ccc(N(c4ccc(-c5ccc6c(c5)-c5ccccc5C65c6ccccc6-c6ccccc65)cc4)c4cccc(C5(c6ccccc6)c6ccccc6-c6ccccc65)c4)cc3)c2)cc1 ; c1ccc(-c2cccc(-c3ccc(N(c4cccc(C5(c6ccccc6)c6ccccc6-c6ccccc65)c4)c4ccccc4-c4ccc5c(c4)C(c4ccccc4)(c4ccccc4)c4ccccc4-5)cc3)c2)cc1]

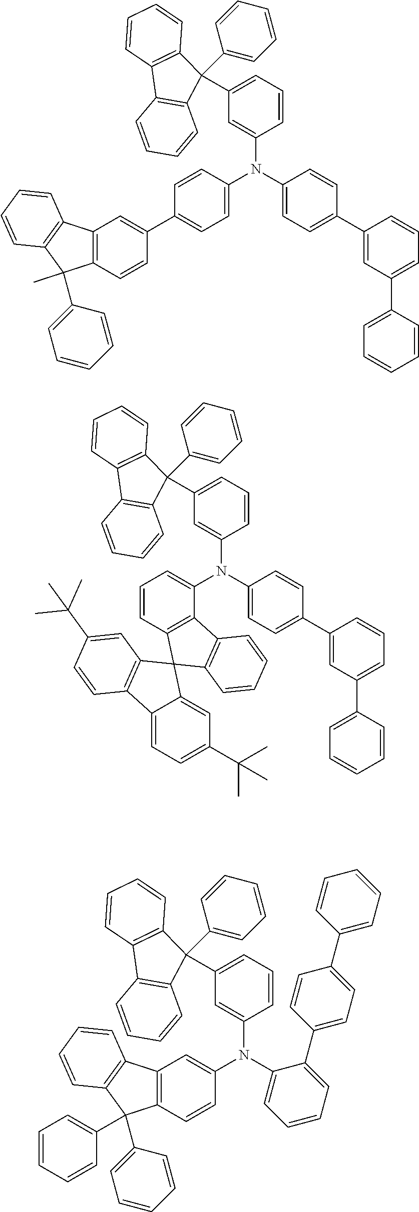 [SMILES: CC1(c2ccccc2)c2ccccc2-c2cc(-c3ccc(N(c4ccc(-c5cccc(-c6ccccc6)c5)cc4)c4cccc(C5(c6ccccc6)c6ccccc6-c6ccccc65)c4)cc3)ccc21 ; CC(C)(C)c1ccc2c(c1)C1(c3cc(C(C)(C)C)ccc3-2)c2ccccc2-c2c(N(c3ccc(-c4cccc(-c5ccccc5)c4)cc3)c3cccc(C4(c5ccccc5)c5ccccc5-c5ccccc54)c3)cccc21 ; c1ccc(-c2ccc(-c3ccccc3N(c3cccc(C4(c5ccccc5)c5ccccc5-c5ccccc54)c3)c3ccc4c(c3)-c3ccccc3C4(c3ccccc3)c3ccccc3)cc2)cc1]

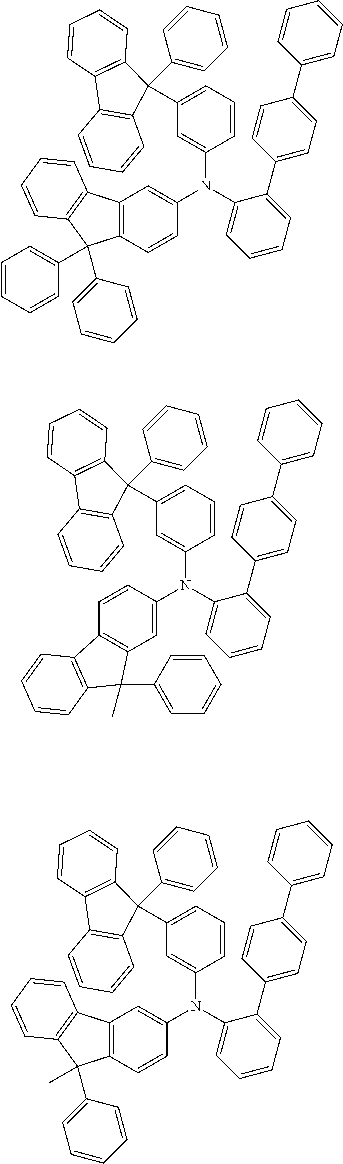 [SMILES: c1ccc(-c2ccc(-c3ccccc3N(c3cccc(C4(c5ccccc5)c5ccccc5-c5ccccc54)c3)c3ccc4c(c3)-c3ccccc3C4(c3ccccc3)c3ccccc3)cc2)cc1 ; CC1(c2ccccc2)c2ccccc2-c2ccc(N(c3cccc(C4(c5ccccc5)c5ccccc5-c5ccccc54)c3)c3ccccc3-c3ccc(-c4ccccc4)cc3)cc21 ; CC1(c2ccccc2)c2ccccc2-c2cc(N(c3cccc(C4(c5ccccc5)c5ccccc5-c5ccccc54)c3)c3ccccc3-c3ccc(-c4ccccc4)cc3)ccc21]

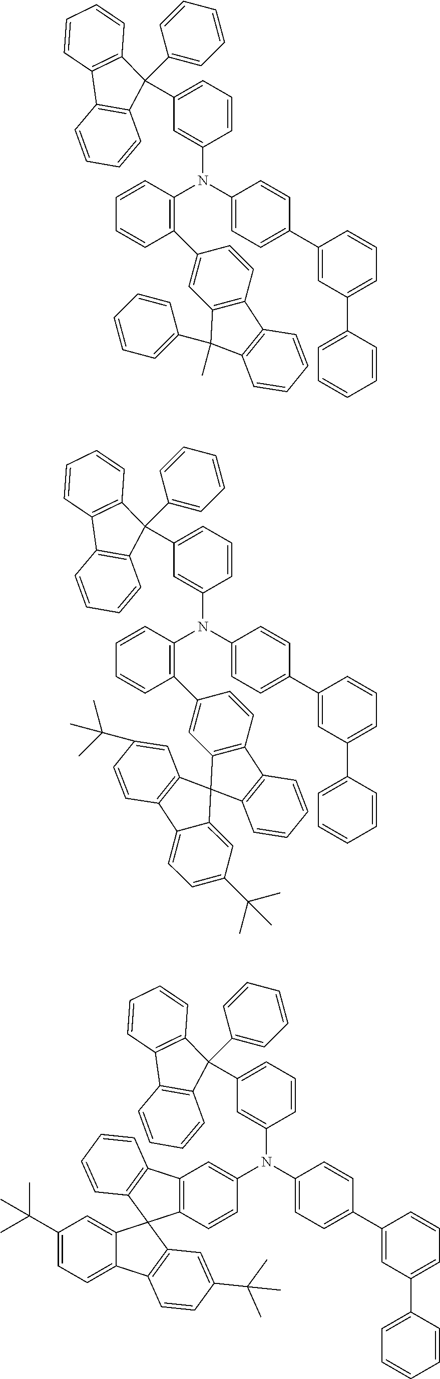 [SMILES: CC1(c2ccccc2)c2ccccc2-c2ccc(-c3ccccc3N(c3ccc(-c4cccc(-c5ccccc5)c4)cc3)c3cccc(C4(c5ccccc5)c5ccccc5-c5ccccc54)c3)cc21 ; CC(C)(C)c1ccc2c(c1)C1(c3ccccc3-c3ccc(-c4ccccc4N(c4ccc(-c5cccc(-c6ccccc6)c5)cc4)c4cccc(C5(c6ccccc6)c6ccccc6-c6ccccc65)c4)cc31)c1cc(C(C)(C)C)ccc1-2 ; CC(C)(C)c1ccc2c(c1)C1(c3ccccc3-c3cc(N(c4ccc(-c5cccc(-c6ccccc6)c5)cc4)c4cccc(C5(c6ccccc6)c6ccccc6-c6ccccc65)c4)ccc31)c1cc(C(C)(C)C)ccc1-2]

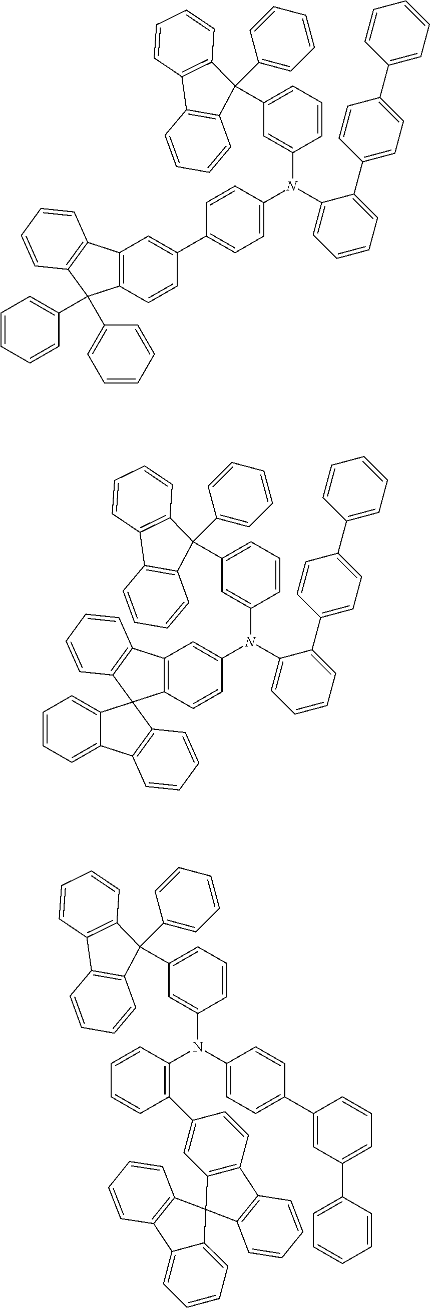 [SMILES: c1ccc(-c2ccc(-c3ccccc3N(c3ccc(-c4ccc5c(c4)-c4ccccc4C5(c4ccccc4)c4ccccc4)cc3)c3cccc(C4(c5ccccc5)c5ccccc5-c5ccccc54)c3)cc2)cc1 ; c1ccc(-c2ccc(-c3ccccc3N(c3cccc(C4(c5ccccc5)c5ccccc5-c5ccccc54)c3)c3ccc4c(c3)-c3ccccc3C43c4ccccc4-c4ccccc43)cc2)cc1 ; c1ccc(-c2cccc(-c3ccc(N(c4cccc(C5(c6ccccc6)c6ccccc6-c6ccccc65)c4)c4ccccc4-c4ccc5c(c4)C4(c6ccccc6-c6ccccc64)c4ccccc4-5)cc3)c2)cc1]

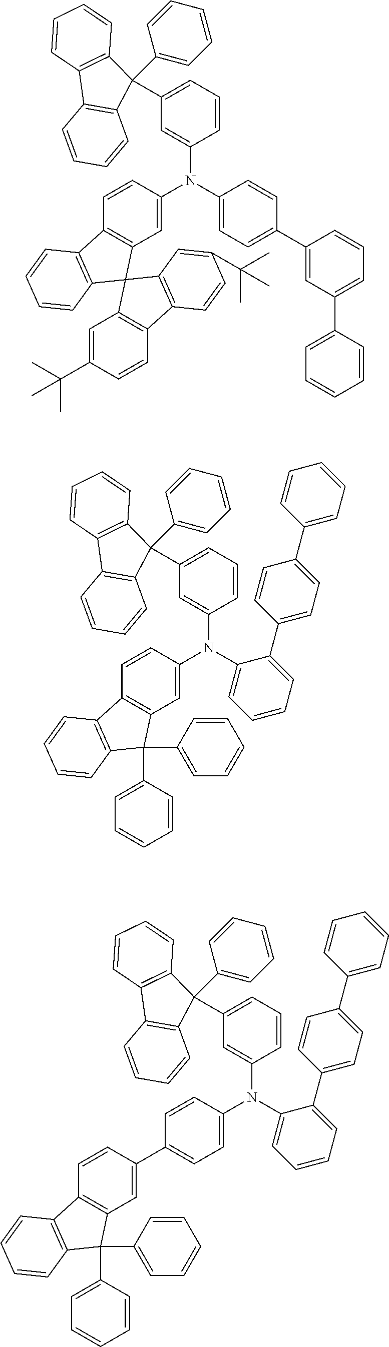 [SMILES: CC(C)(C)c1ccc2c(c1)C1(c3ccccc3-c3ccc(N(c4ccc(-c5cccc(-c6ccccc6)c5)cc4)c4cccc(C5(c6ccccc6)c6ccccc6-c6ccccc65)c4)cc31)c1cc(C(C)(C)C)ccc1-2 ; c1ccc(-c2ccc(-c3ccccc3N(c3cccc(C4(c5ccccc5)c5ccccc5-c5ccccc54)c3)c3ccc4c(c3)C(c3ccccc3)(c3ccccc3)c3ccccc3-4)cc2)cc1 ; c1ccc(-c2ccc(-c3ccccc3N(c3ccc(-c4ccc5c(c4)C(c4ccccc4)(c4ccccc4)c4ccccc4-5)cc3)c3cccc(C4(c5ccccc5)c5ccccc5-c5ccccc54)c3)cc2)cc1]

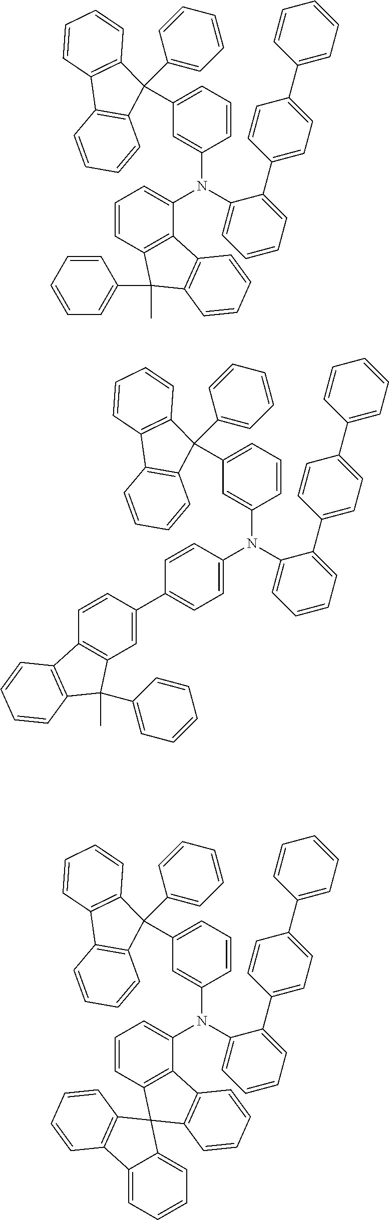 [SMILES: CC1(c2ccccc2)c2ccccc2-c2c(N(c3cccc(C4(c5ccccc5)c5ccccc5-c5ccccc54)c3)c3ccccc3-c3ccc(-c4ccccc4)cc3)cccc21 ; CC1(c2ccccc2)c2ccccc2-c2ccc(-c3ccc(N(c4cccc(C5(c6ccccc6)c6ccccc6-c6ccccc65)c4)c4ccccc4-c4ccc(-c5ccccc5)cc4)cc3)cc21 ; c1ccc(-c2ccc(-c3ccccc3N(c3cccc(C4(c5ccccc5)c5ccccc5-c5ccccc54)c3)c3cccc4c3-c3ccccc3C43c4ccccc4-c4ccccc43)cc2)cc1]

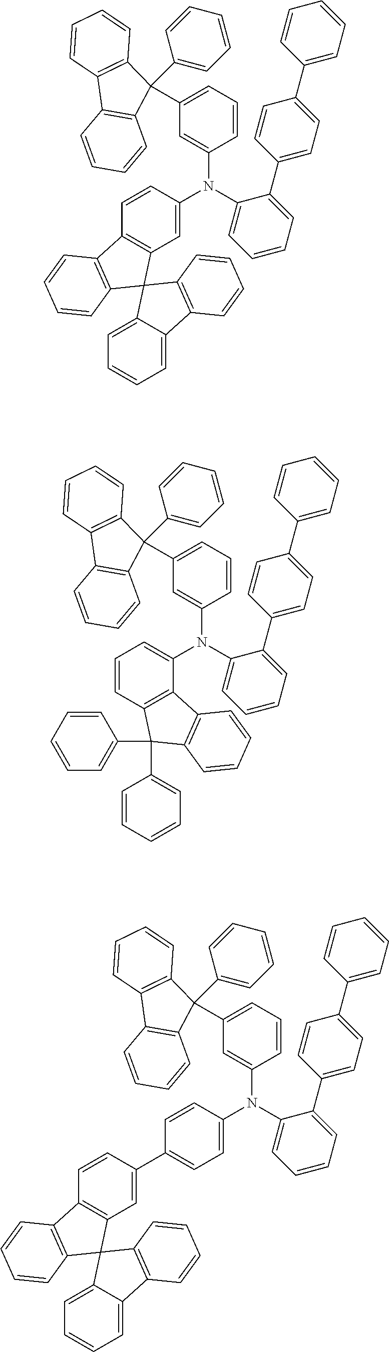 [SMILES: c1ccc(-c2ccc(-c3ccccc3N(c3cccc(C4(c5ccccc5)c5ccccc5-c5ccccc54)c3)c3ccc4c(c3)C3(c5ccccc5-c5ccccc53)c3ccccc3-4)cc2)cc1 ; c1ccc(-c2ccc(-c3ccccc3N(c3cccc(C4(c5ccccc5)c5ccccc5-c5ccccc54)c3)c3cccc4c3-c3ccccc3C4(c3ccccc3)c3ccccc3)cc2)cc1 ; c1ccc(-c2ccc(-c3ccccc3N(c3ccc(-c4ccc5c(c4)C4(c6ccccc6-c6ccccc64)c4ccccc4-5)cc3)c3cccc(C4(c5ccccc5)c5ccccc5-c5ccccc54)c3)cc2)cc1]

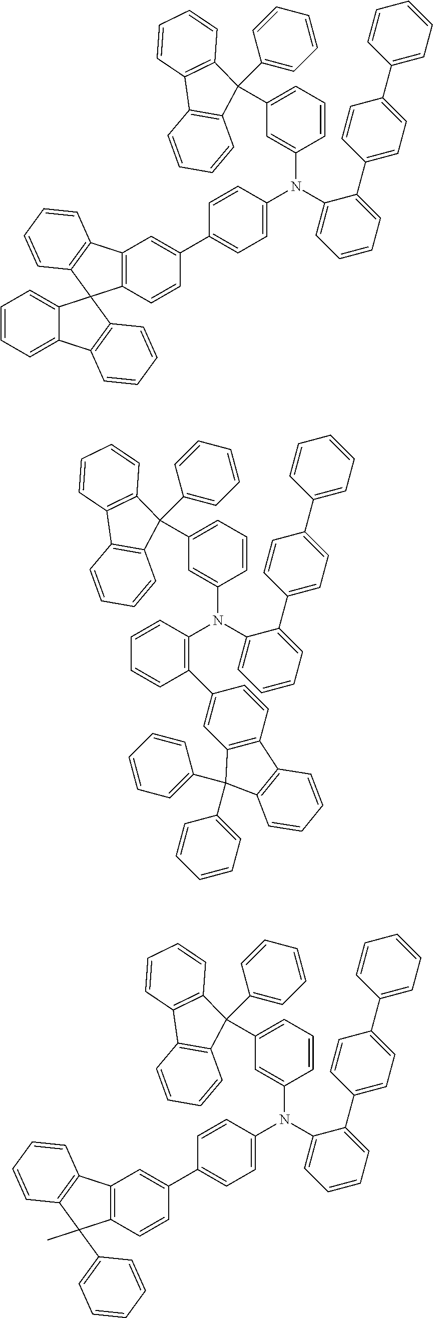 [SMILES: c1ccc(-c2ccc(-c3ccccc3N(c3ccc(-c4ccc5c(c4)-c4ccccc4C54c5ccccc5-c5ccccc54)cc3)c3cccc(C4(c5ccccc5)c5ccccc5-c5ccccc54)c3)cc2)cc1 ; c1ccc(-c2ccc(-c3ccccc3N(c3cccc(C4(c5ccccc5)c5ccccc5-c5ccccc54)c3)c3ccccc3-c3ccc4c(c3)C(c3ccccc3)(c3ccccc3)c3ccccc3-4)cc2)cc1 ; CC1(c2ccccc2)c2ccccc2-c2cc(-c3ccc(N(c4cccc(C5(c6ccccc6)c6ccccc6-c6ccccc65)c4)c4ccccc4-c4ccc(-c5ccccc5)cc4)cc3)ccc21]

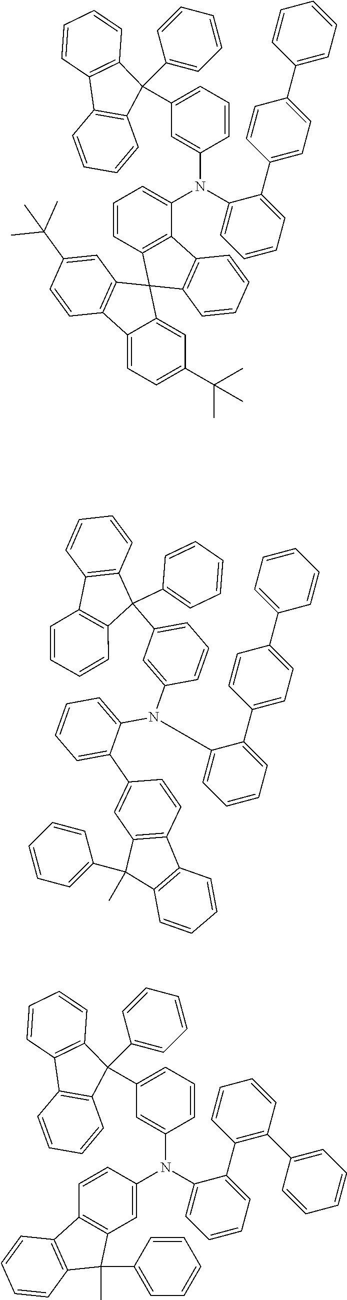 [SMILES: CC(C)(C)c1ccc2c(c1)C1(c3cc(C(C)(C)C)ccc3-2)c2ccccc2-c2c(N(c3cccc(C4(c5ccccc5)c5ccccc5-c5ccccc54)c3)c3ccccc3-c3ccc(-c4ccccc4)cc3)cccc21 ; CC1(c2ccccc2)c2ccccc2-c2ccc(-c3ccccc3N(Cc3ccccc3-c3ccc(-c4ccccc4)cc3)c3cccc(C4(c5ccccc5)c5ccccc5-c5ccccc54)c3)cc21 ; CC1(c2ccccc2)c2ccccc2-c2ccc(N(c3cccc(C4(c5ccccc5)c5ccccc5-c5ccccc54)c3)c3ccccc3-c3ccccc3-c3ccccc3)cc21]

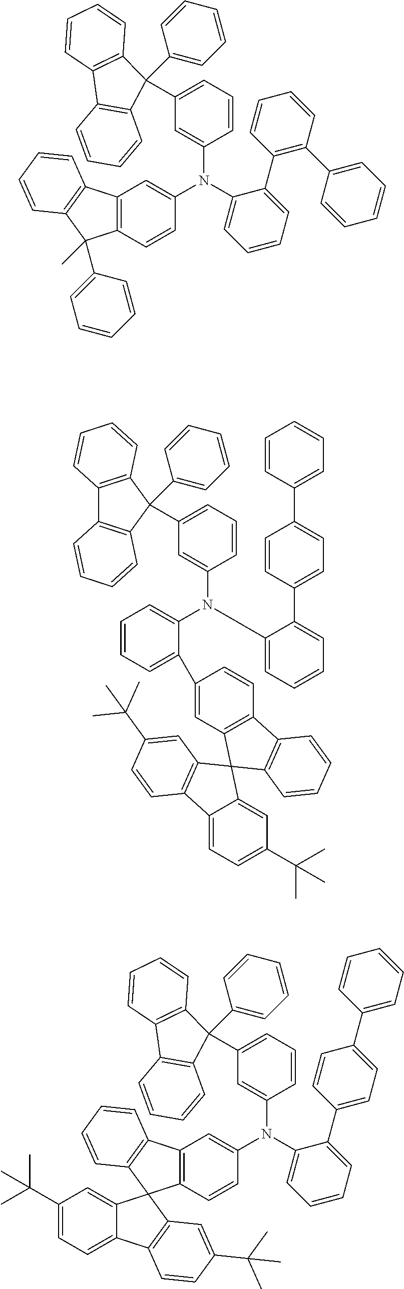 [SMILES: CC1(c2ccccc2)c2ccccc2-c2cc(N(c3cccc(C4(c5ccccc5)c5ccccc5-c5ccccc54)c3)c3ccccc3-c3ccccc3-c3ccccc3)ccc21 ; CC(C)(C)c1ccc2c(c1)C1(c3ccccc3-c3ccc(-c4ccccc4N(Cc4ccccc4-c4ccc(-c5ccccc5)cc4)c4cccc(C5(c6ccccc6)c6ccccc6-c6ccccc65)c4)cc31)c1cc(C(C)(C)C)ccc1-2 ; CC(C)(C)c1ccc2c(c1)C1(c3ccccc3-c3cc(N(c4cccc(C5(c6ccccc6)c6ccccc6-c6ccccc65)c4)c4ccccc4-c4ccc(-c5ccccc5)cc4)ccc31)c1cc(C(C)(C)C)ccc1-2]

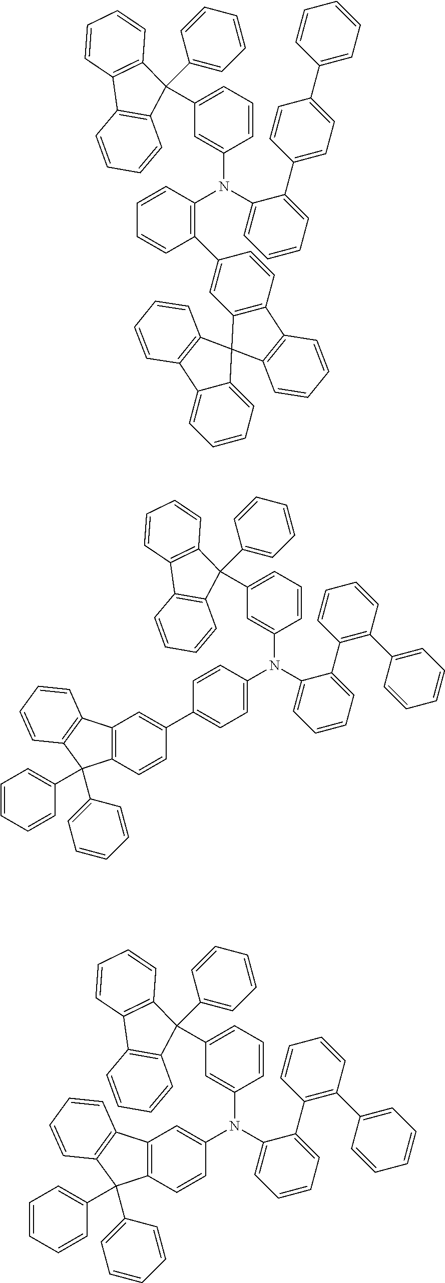 [SMILES: c1ccc(-c2ccc(-c3ccccc3N(c3cccc(C4(c5ccccc5)c5ccccc5-c5ccccc54)c3)c3ccccc3-c3ccc4c(c3)C3(c5ccccc5-c5ccccc53)c3ccccc3-4)cc2)cc1 ; c1ccc(-c2ccccc2-c2ccccc2N(c2ccc(-c3ccc4c(c3)-c3ccccc3C4(c3ccccc3)c3ccccc3)cc2)c2cccc(C3(c4ccccc4)c4ccccc4-c4ccccc43)c2)cc1 ; c1ccc(-c2ccccc2-c2ccccc2N(c2cccc(C3(c4ccccc4)c4ccccc4-c4ccccc43)c2)c2ccc3c(c2)-c2ccccc2C3(c2ccccc2)c2ccccc2)cc1]

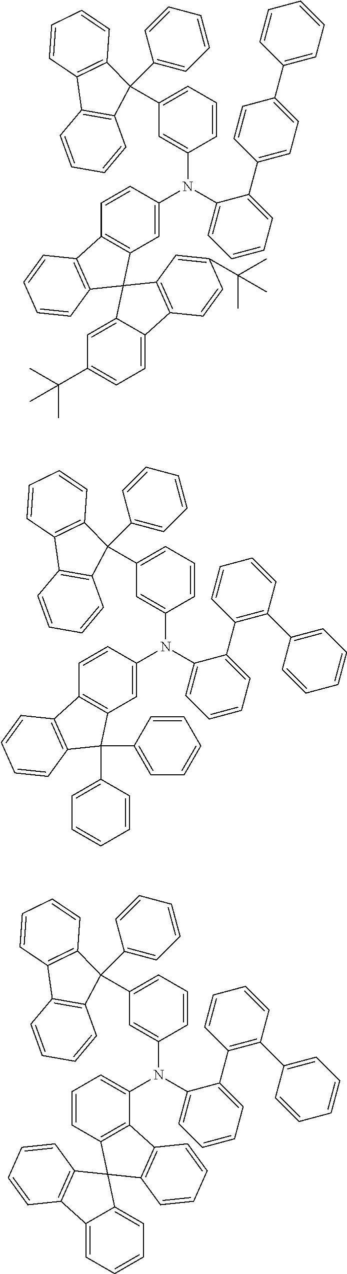 [SMILES: CC(C)(C)c1ccc2c(c1)C1(c3ccccc3-c3ccc(N(c4cccc(C5(c6ccccc6)c6ccccc6-c6ccccc65)c4)c4ccccc4-c4ccc(-c5ccccc5)cc4)cc31)c1cc(C(C)(C)C)ccc1-2 ; c1ccc(-c2ccccc2-c2ccccc2N(c2cccc(C3(c4ccccc4)c4ccccc4-c4ccccc43)c2)c2ccc3c(c2)C(c2ccccc2)(c2ccccc2)c2ccccc2-3)cc1 ; c1ccc(-c2ccccc2-c2ccccc2N(c2cccc(C3(c4ccccc4)c4ccccc4-c4ccccc43)c2)c2cccc3c2-c2ccccc2C32c3ccccc3-c3ccccc32)cc1]

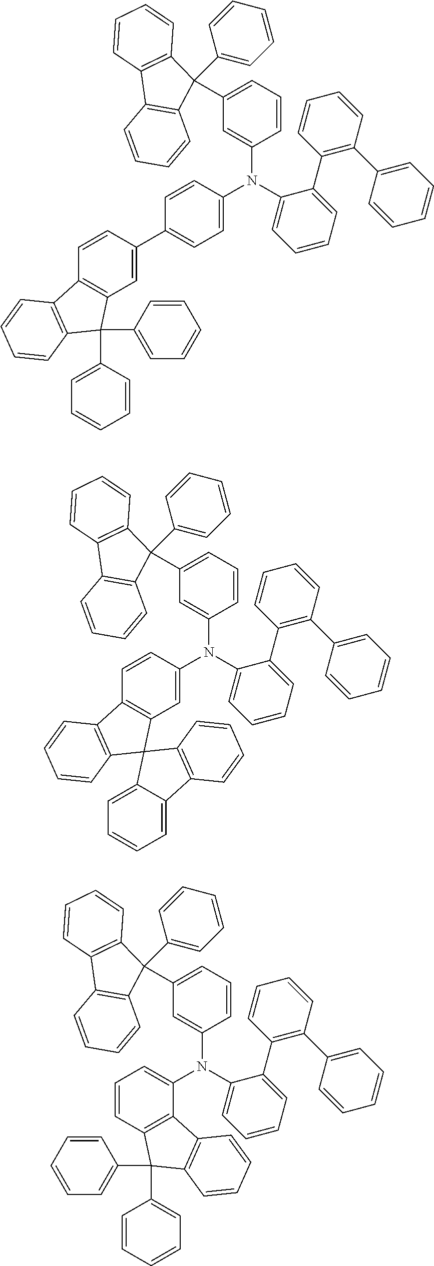

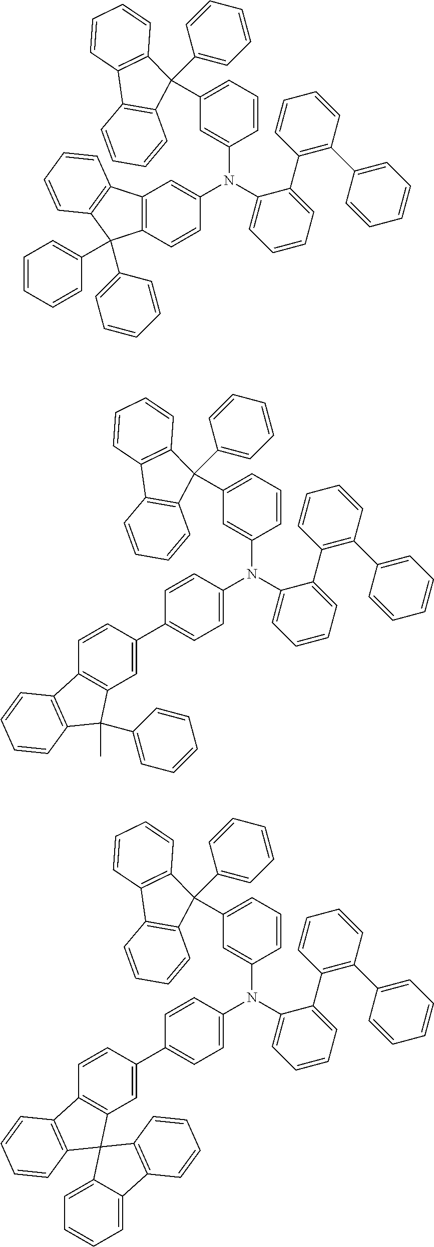 [SMILES: c1ccc(-c2ccccc2-c2ccccc2N(c2cccc(C3(c4ccccc4)c4ccccc4-c4ccccc43)c2)c2ccc3c(c2)-c2ccccc2C3(c2ccccc2)c2ccccc2)cc1 ; CC1(c2ccccc2)c2ccccc2-c2ccc(-c3ccc(N(c4cccc(C5(c6ccccc6)c6ccccc6-c6ccccc65)c4)c4ccccc4-c4ccccc4-c4ccccc4)cc3)cc21 ; c1ccc(-c2ccccc2-c2ccccc2N(c2ccc(-c3ccc4c(c3)C3(c5ccccc5-c5ccccc53)c3ccccc3-4)cc2)c2cccc(C3(c4ccccc4)c4ccccc4-c4ccccc43)c2)cc1]

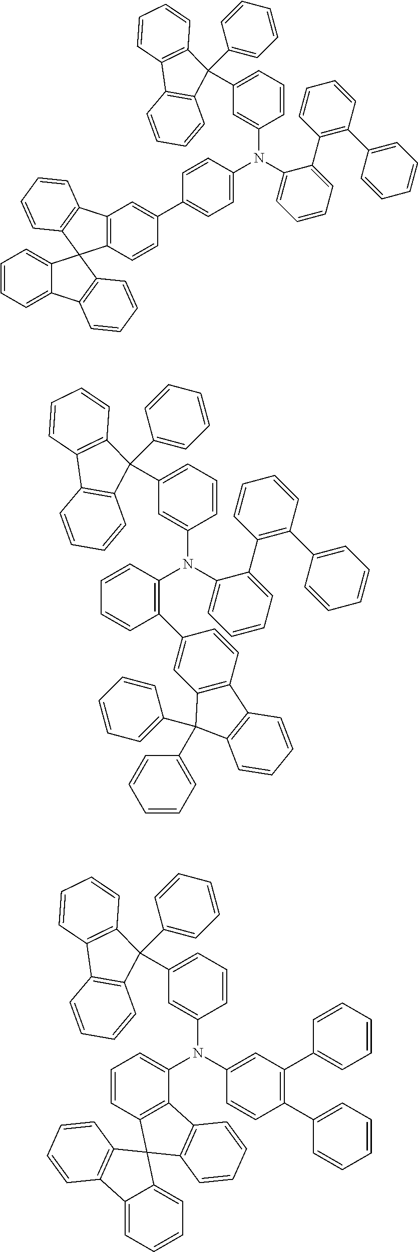 [SMILES: c1ccc(-c2ccccc2-c2ccccc2N(c2ccc(-c3ccc4c(c3)-c3ccccc3C43c4ccccc4-c4ccccc43)cc2)c2cccc(C3(c4ccccc4)c4ccccc4-c4ccccc43)c2)cc1 ; c1ccc(-c2ccccc2-c2ccccc2N(c2cccc(C3(c4ccccc4)c4ccccc4-c4ccccc43)c2)c2ccccc2-c2ccc3c(c2)C(c2ccccc2)(c2ccccc2)c2ccccc2-3)cc1 ; c1ccc(-c2ccc(N(c3cccc(C4(c5ccccc5)c5ccccc5-c5ccccc54)c3)c3cccc4c3-c3ccccc3C43c4ccccc4-c4ccccc43)cc2-c2ccccc2)cc1]

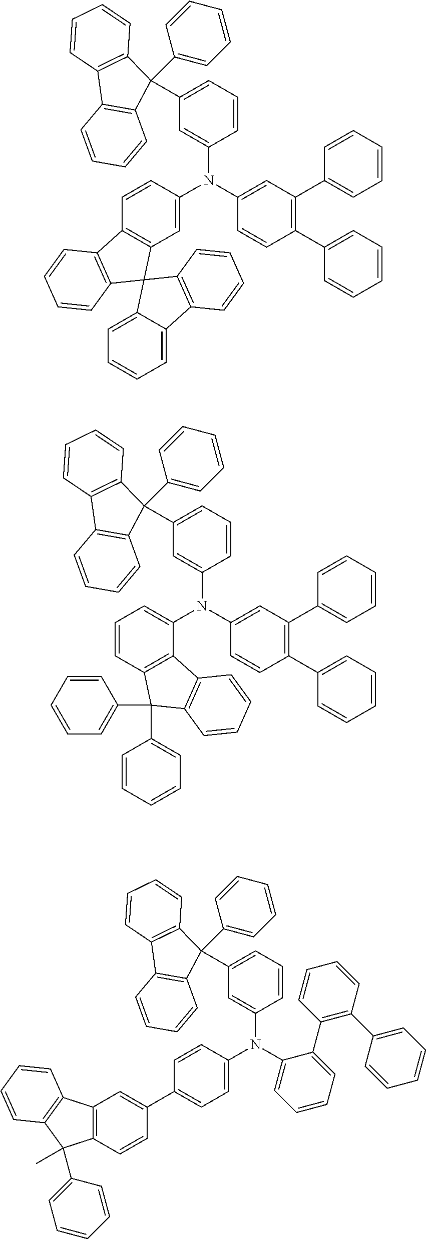 [SMILES: c1ccc(-c2ccc(N(c3cccc(C4(c5ccccc5)c5ccccc5-c5ccccc54)c3)c3ccc4c(c3)C3(c5ccccc5-c5ccccc53)c3ccccc3-4)cc2-c2ccccc2)cc1 ; c1ccc(-c2ccc(N(c3cccc(C4(c5ccccc5)c5ccccc5-c5ccccc54)c3)c3cccc4c3-c3ccccc3C4(c3ccccc3)c3ccccc3)cc2-c2ccccc2)cc1 ; CC1(c2ccccc2)c2ccccc2-c2cc(-c3ccc(N(c4cccc(C5(c6ccccc6)c6ccccc6-c6ccccc65)c4)c4ccccc4-c4ccccc4-c4ccccc4)cc3)ccc21]

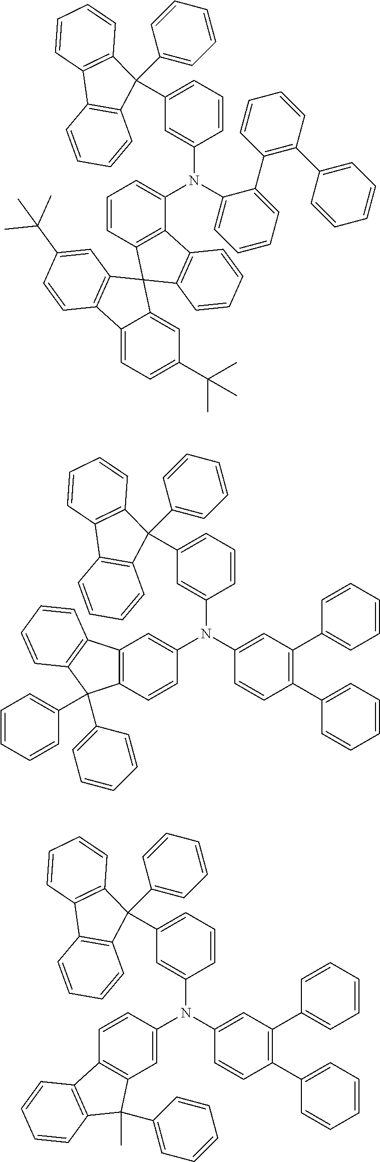

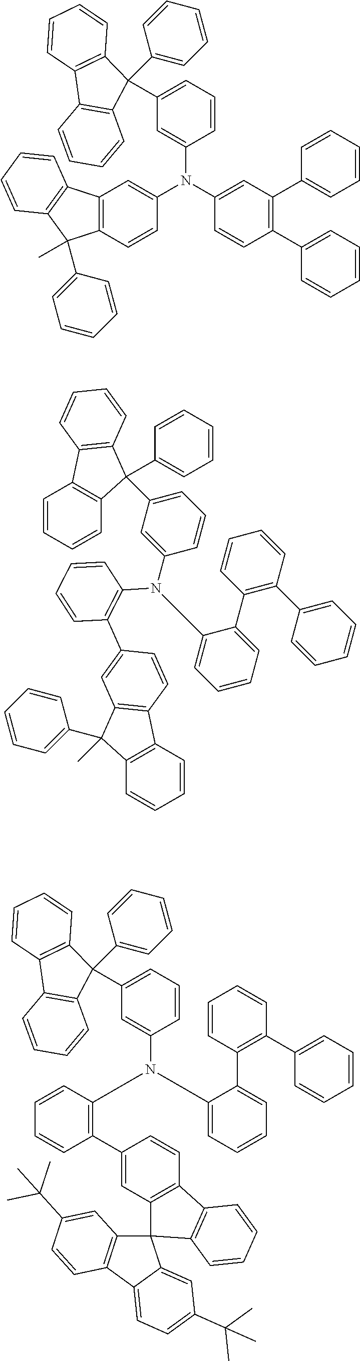 [SMILES: CC1(c2ccccc2)c2ccccc2-c2cc(N(c3cccc(C4(c5ccccc5)c5ccccc5-c5ccccc54)c3)c3ccc(-c4ccccc4)c(-c4ccccc4)c3)ccc21 ; CC1(c2ccccc2)c2ccccc2-c2ccc(-c3ccccc3N(Cc3ccccc3-c3ccccc3-c3ccccc3)c3cccc(C4(c5ccccc5)c5ccccc5-c5ccccc54)c3)cc21 ; CC(C)(C)c1ccc2c(c1)C1(c3ccccc3-c3ccc(-c4ccccc4CN(Cc4ccccc4-c4ccccc4-c4ccccc4)c4cccc(C5(c6ccccc6)c6ccccc6-c6ccccc65)c4)cc31)c1cc(C(C)(C)C)ccc1-2]

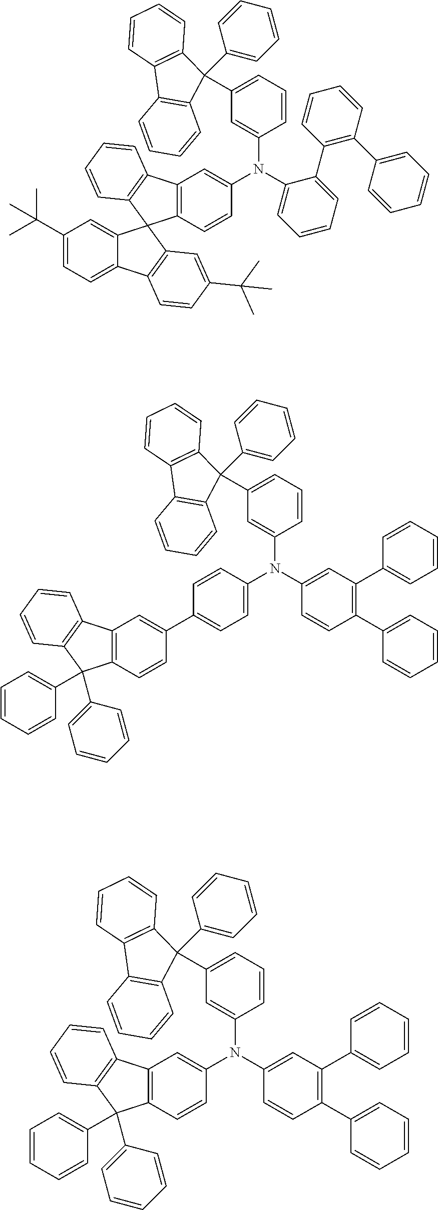 [SMILES: CC(C)(C)c1ccc2c(c1)C1(c3ccccc3-c3cc(N(c4cccc(C5(c6ccccc6)c6ccccc6-c6ccccc65)c4)c4ccccc4-c4ccccc4-c4ccccc4)ccc31)c1cc(C(C)(C)C)ccc1-2 ; c1ccc(-c2ccc(N(c3ccc(-c4ccc5c(c4)-c4ccccc4C5(c4ccccc4)c4ccccc4)cc3)c3cccc(C4(c5ccccc5)c5ccccc5-c5ccccc54)c3)cc2-c2ccccc2)cc1 ; c1ccc(-c2ccc(N(c3cccc(C4(c5ccccc5)c5ccccc5-c5ccccc54)c3)c3ccc4c(c3)-c3ccccc3C4(c3ccccc3)c3ccccc3)cc2-c2ccccc2)cc1]

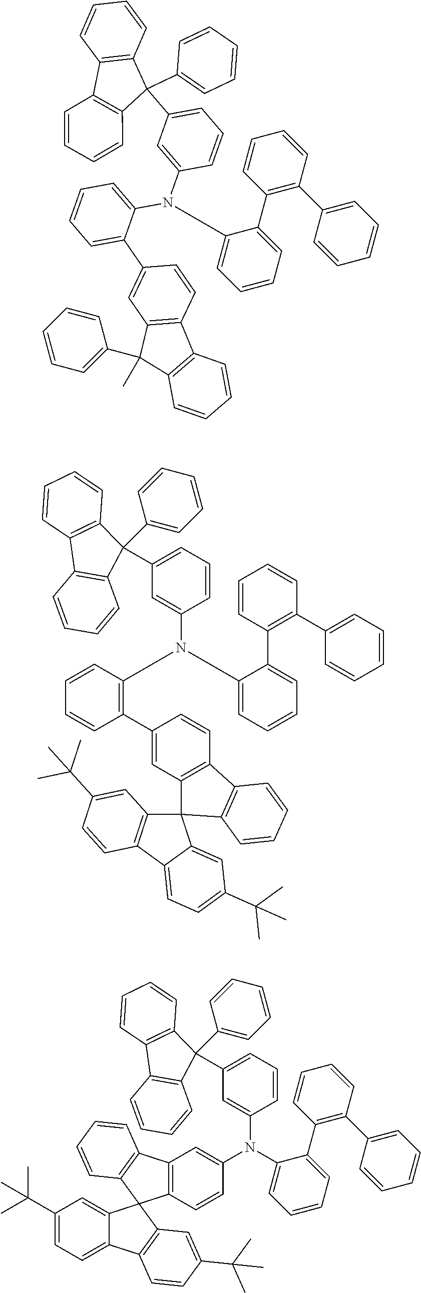 [SMILES: CC1(c2ccccc2)c2ccccc2-c2ccc(-c3ccccc3N(Cc3ccccc3-c3ccccc3-c3ccccc3)c3cccc(C4(c5ccccc5)c5ccccc5-c5ccccc54)c3)cc21 ; CC(C)(C)c1ccc2c(c1)C1(c3ccccc3-c3ccc(-c4ccccc4CN(Cc4ccccc4-c4ccccc4-c4ccccc4)c4cccc(C5(c6ccccc6)c6ccccc6-c6ccccc65)c4)cc31)c1cc(C(C)(C)C)ccc1-2 ; CC(C)(C)c1ccc2c(c1)C1(c3ccccc3-c3cc(N(c4cccc(C5(c6ccccc6)c6ccccc6-c6ccccc65)c4)c4ccccc4-c4ccccc4-c4ccccc4)ccc31)c1cc(C(C)(C)C)ccc1-2]

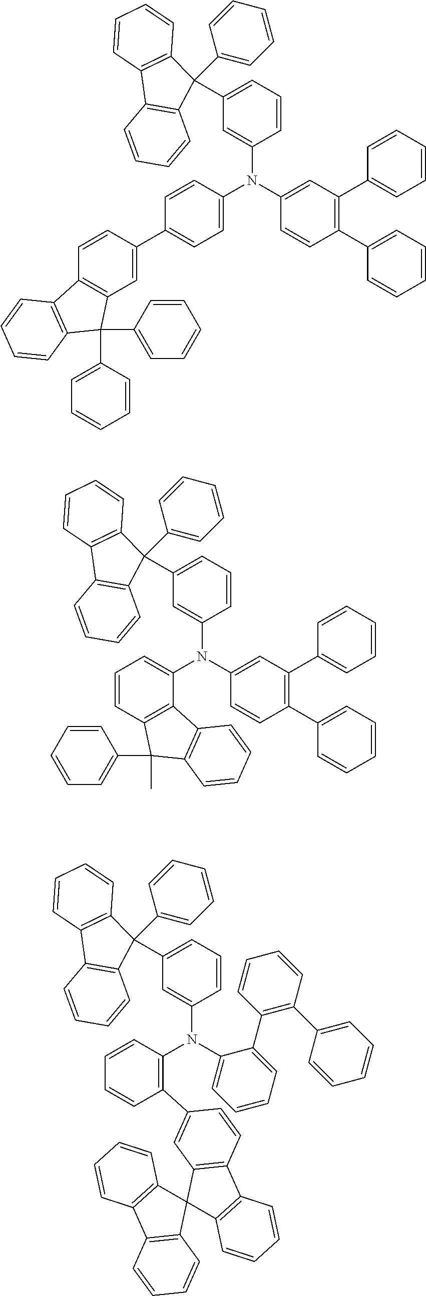 [SMILES: c1ccc(-c2ccc(N(c3ccc(-c4ccc5c(c4)C(c4ccccc4)(c4ccccc4)c4ccccc4-5)cc3)c3cccc(C4(c5ccccc5)c5ccccc5-c5ccccc54)c3)cc2-c2ccccc2)cc1 ; CC1(c2ccccc2)c2ccccc2-c2c(N(c3cccc(C4(c5ccccc5)c5ccccc5-c5ccccc54)c3)c3ccc(-c4ccccc4)c(-c4ccccc4)c3)cccc21 ; c1ccc(-c2ccccc2-c2ccccc2N(c2cccc(C3(c4ccccc4)c4ccccc4-c4ccccc43)c2)c2ccccc2-c2ccc3c(c2)C2(c4ccccc4-c4ccccc42)c2ccccc2-3)cc1]

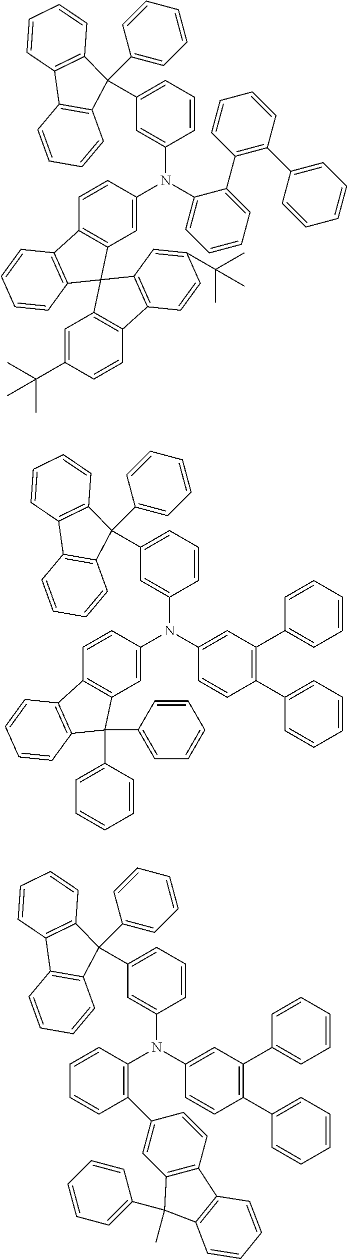 [SMILES: CC(C)(C)c1ccc2c(c1)C1(c3ccccc3-c3ccc(N(c4cccc(C5(c6ccccc6)c6ccccc6-c6ccccc65)c4)c4ccccc4-c4ccccc4-c4ccccc4)cc31)c1cc(C(C)(C)C)ccc1-2 ; c1ccc(-c2ccc(N(c3cccc(C4(c5ccccc5)c5ccccc5-c5ccccc54)c3)c3ccc4c(c3)C(c3ccccc3)(c3ccccc3)c3ccccc3-4)cc2-c2ccccc2)cc1 ; CC1(c2ccccc2)c2ccccc2-c2ccc(-c3ccccc3N(c3cccc(C4(c5ccccc5)c5ccccc5-c5ccccc54)c3)c3ccc(-c4ccccc4)c(-c4ccccc4)c3)cc21]

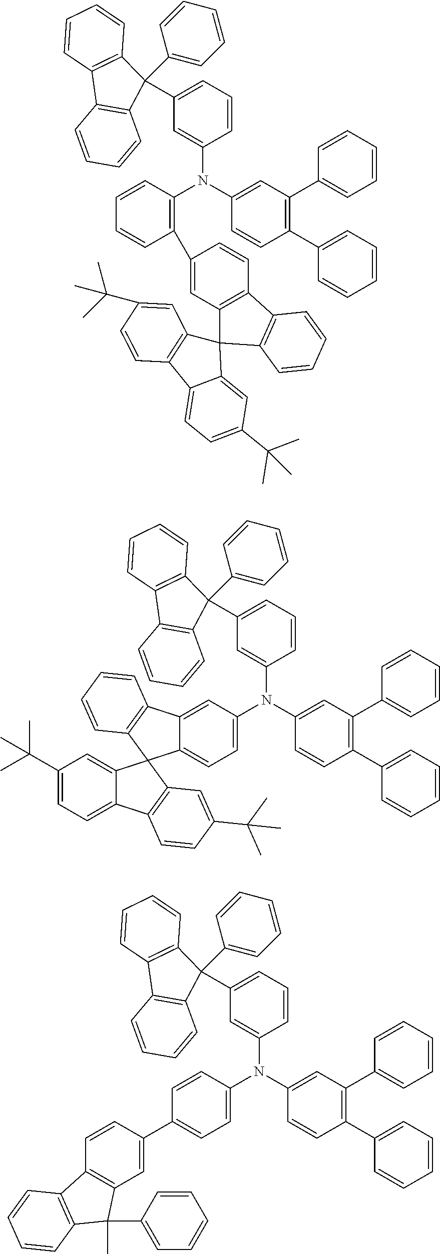

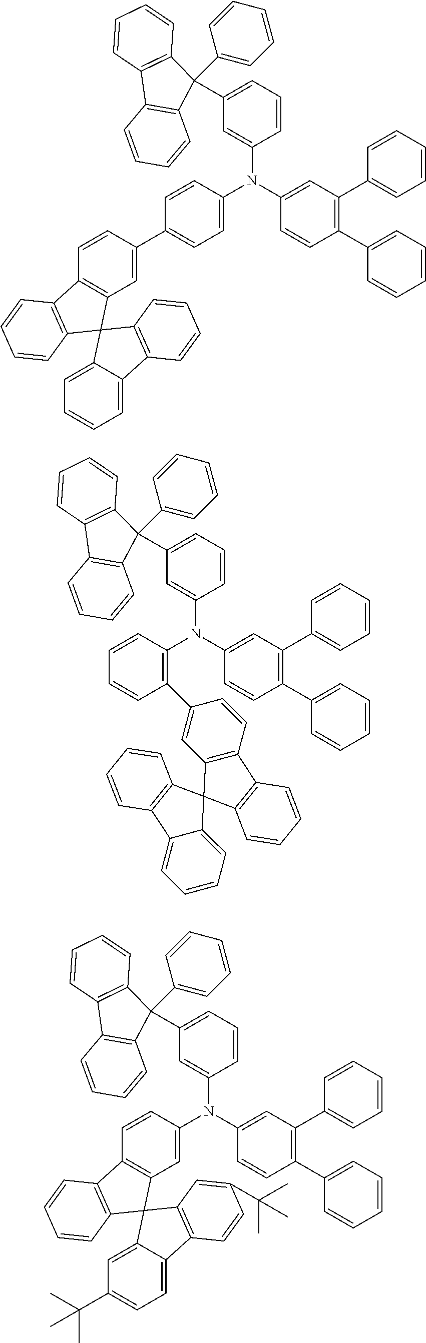

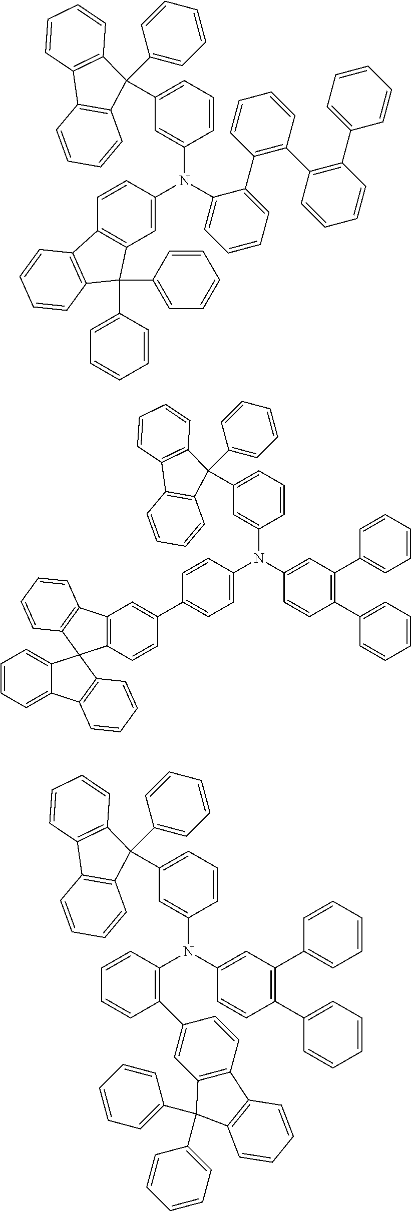

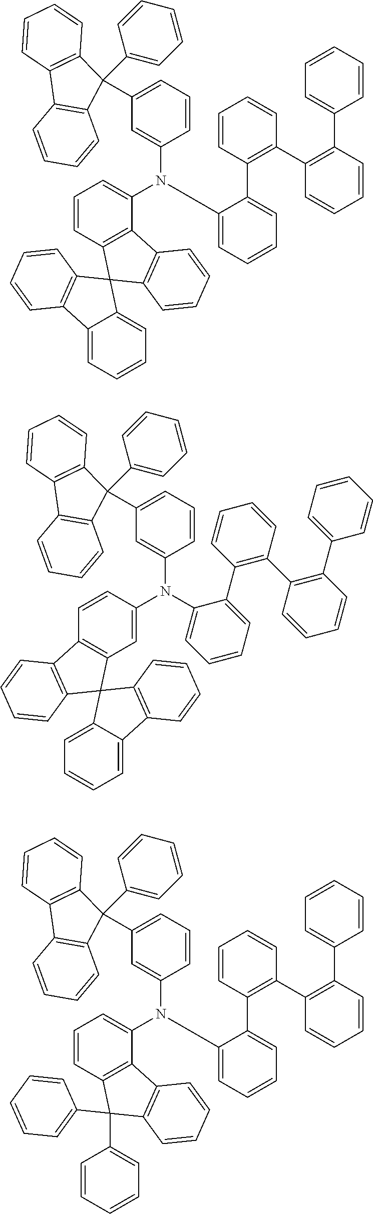

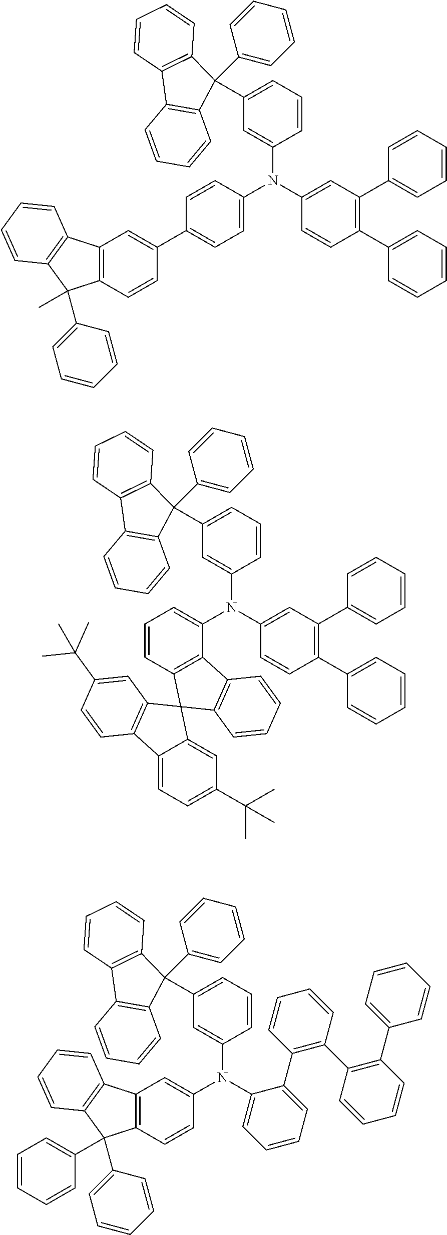 [SMILES: CC1(c2ccccc2)c2ccccc2-c2cc(-c3ccc(N(c4cccc(C5(c6ccccc6)c6ccccc6-c6ccccc65)c4)c4ccc(-c5ccccc5)c(-c5ccccc5)c4)cc3)ccc21 ; CC(C)(C)c1ccc2c(c1)C1(c3cc(C(C)(C)C)ccc3-2)c2ccccc2-c2c(N(c3cccc(C4(c5ccccc5)c5ccccc5-c5ccccc54)c3)c3ccc(-c4ccccc4)c(-c4ccccc4)c3)cccc21 ; c1ccc(-c2ccccc2-c2ccccc2-c2ccccc2N(c2cccc(C3(c4ccccc4)c4ccccc4-c4ccccc43)c2)c2ccc3c(c2)-c2ccccc2C3(c2ccccc2)c2ccccc2)cc1]

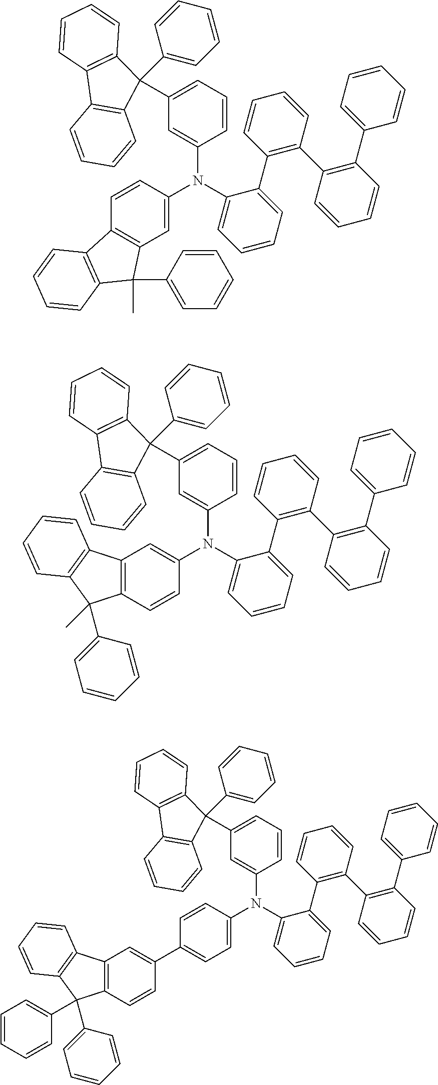 [SMILES: CC1(c2ccccc2)c2ccccc2-c2ccc(N(c3cccc(C4(c5ccccc5)c5ccccc5-c5ccccc54)c3)c3ccccc3-c3ccccc3-c3ccccc3-c3ccccc3)cc21 ; CC1(c2ccccc2)c2ccccc2-c2cc(N(c3cccc(C4(c5ccccc5)c5ccccc5-c5ccccc54)c3)c3ccccc3-c3ccccc3-c3ccccc3-c3ccccc3)ccc21 ; c1ccc(-c2ccccc2-c2ccccc2-c2ccccc2N(c2ccc(-c3ccc4c(c3)-c3ccccc3C4(c3ccccc3)c3ccccc3)cc2)c2cccc(C3(c4ccccc4)c4ccccc4-c4ccccc43)c2)cc1]

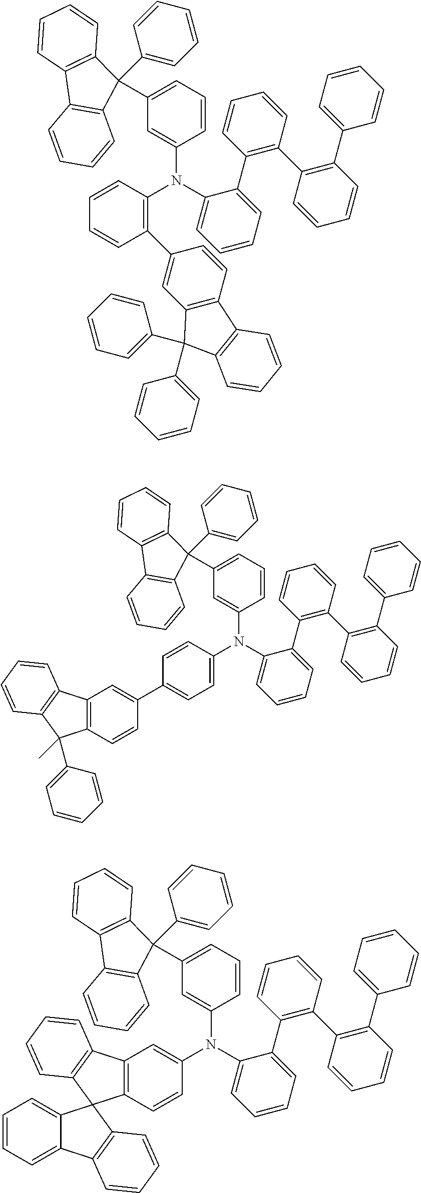 [SMILES: c1ccc(-c2ccccc2-c2ccccc2-c2ccccc2N(c2cccc(C3(c4ccccc4)c4ccccc4-c4ccccc43)c2)c2ccccc2-c2ccc3c(c2)C(c2ccccc2)(c2ccccc2)c2ccccc2-3)cc1 ; CC1(c2ccccc2)c2ccccc2-c2cc(-c3ccc(N(c4cccc(C5(c6ccccc6)c6ccccc6-c6ccccc65)c4)c4ccccc4-c4ccccc4-c4ccccc4-c4ccccc4)cc3)ccc21 ; c1ccc(-c2ccccc2-c2ccccc2-c2ccccc2N(c2cccc(C3(c4ccccc4)c4ccccc4-c4ccccc43)c2)c2ccc3c(c2)-c2ccccc2C32c3ccccc3-c3ccccc32)cc1]

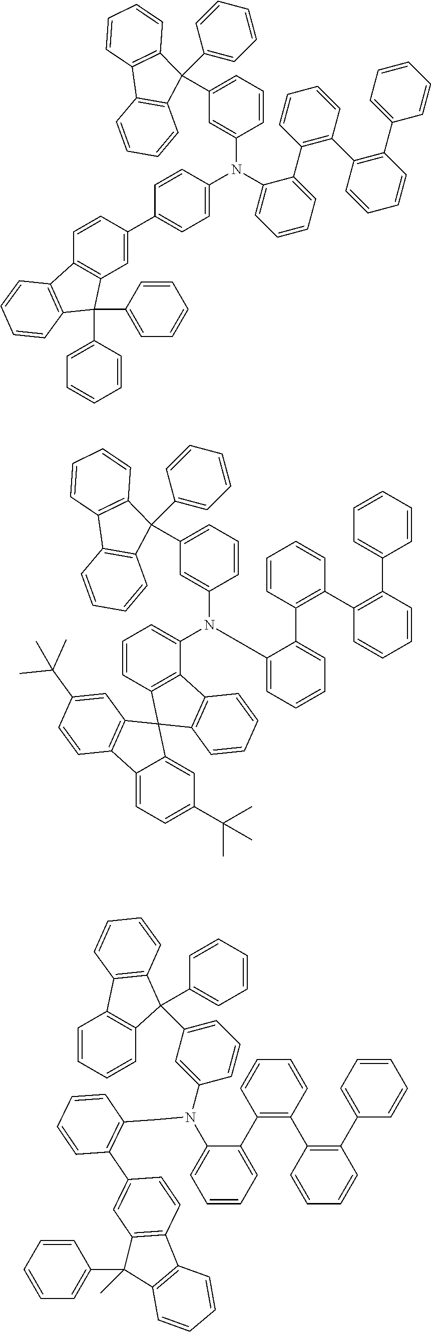

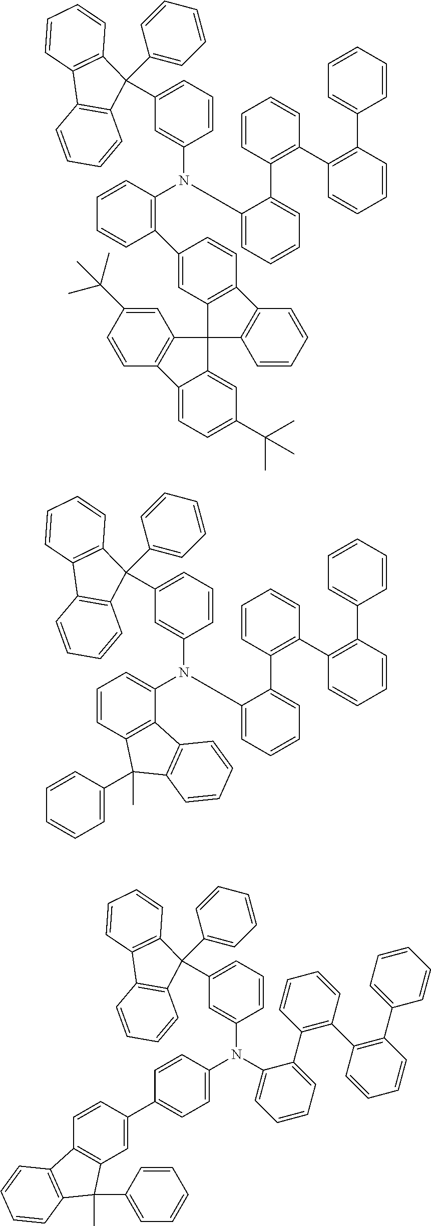 [SMILES: CC(C)(C)c1ccc2c(c1)C1(c3ccccc3-c3ccc(-c4ccccc4N(Cc4ccccc4-c4ccccc4-c4ccccc4-c4ccccc4)c4cccc(C5(c6ccccc6)c6ccccc6-c6ccccc65)c4)cc31)c1cc(C(C)(C)C)ccc1-2 ; CC1(c2ccccc2)c2ccccc2-c2c(N(Cc3ccccc3-c3ccccc3-c3ccccc3-c3ccccc3)c3cccc(C4(c5ccccc5)c5ccccc5-c5ccccc54)c3)cccc21 ; CC1(c2ccccc2)c2ccccc2-c2ccc(-c3ccc(N(c4cccc(C5(c6ccccc6)c6ccccc6-c6ccccc65)c4)c4ccccc4-c4ccccc4-c4ccccc4-c4ccccc4)cc3)cc21]

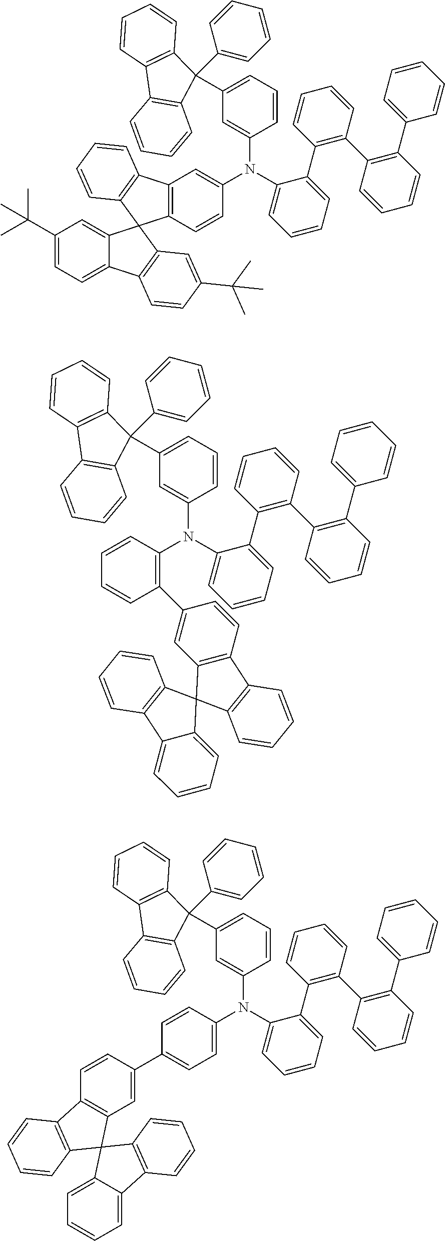 [SMILES: CC(C)(C)c1ccc2c(c1)C1(c3ccccc3-c3cc(N(c4cccc(C5(c6ccccc6)c6ccccc6-c6ccccc65)c4)c4ccccc4-c4ccccc4-c4ccccc4-c4ccccc4)ccc31)c1cc(C(C)(C)C)ccc1-2 ; c1ccc(-c2ccccc2-c2ccccc2-c2ccccc2N(c2cccc(C3(c4ccccc4)c4ccccc4-c4ccccc43)c2)c2ccccc2-c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc4c(c3)C3(c5ccccc5-c5ccccc53)c3ccccc3-4)cc2)c2cccc(C3(c4ccccc4)c4ccccc4-c4ccccc43)c2)cc1]

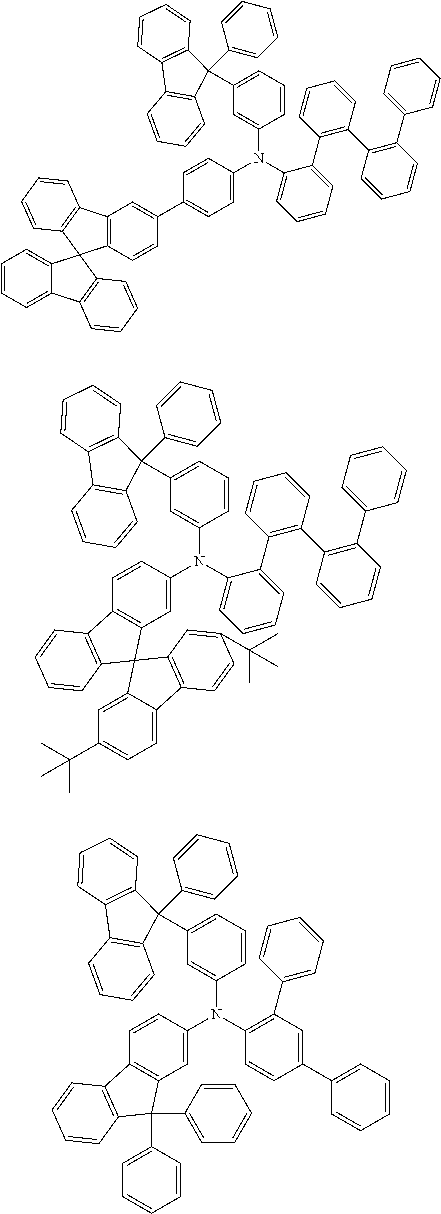 [SMILES: c1ccc(-c2ccccc2-c2ccccc2-c2ccccc2N(c2ccc(-c3ccc4c(c3)-c3ccccc3C43c4ccccc4-c4ccccc43)cc2)c2cccc(C3(c4ccccc4)c4ccccc4-c4ccccc43)c2)cc1 ; CC(C)(C)c1ccc2c(c1)C1(c3ccccc3-c3ccc(N(c4cccc(C5(c6ccccc6)c6ccccc6-c6ccccc65)c4)c4ccccc4-c4ccccc4-c4ccccc4-c4ccccc4)cc31)c1cc(C(C)(C)C)ccc1-2 ; c1ccc(-c2ccc(N(c3cccc(C4(c5ccccc5)c5ccccc5-c5ccccc54)c3)c3ccc4c(c3)C(c3ccccc3)(c3ccccc3)c3ccccc3-4)c(-c3ccccc3)c2)cc1]

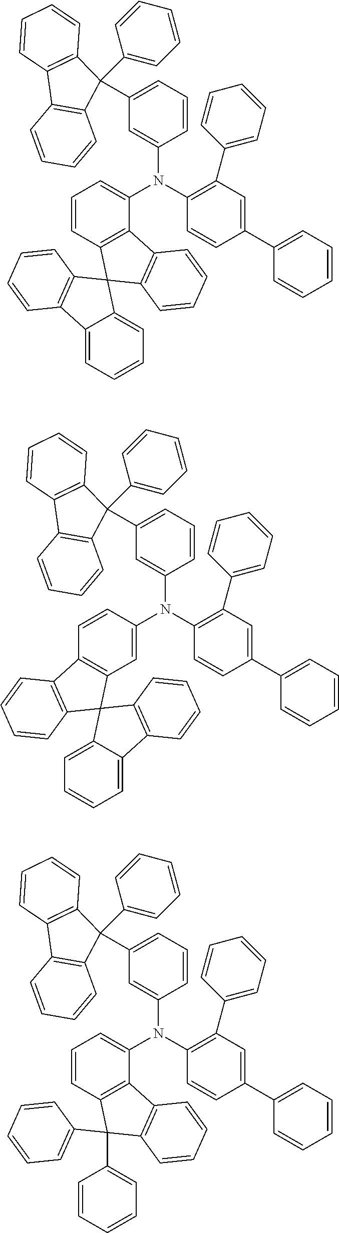 [SMILES: c1ccc(-c2ccc(N(c3cccc(C4(c5ccccc5)c5ccccc5-c5ccccc54)c3)c3cccc4c3-c3ccccc3C43c4ccccc4-c4ccccc43)c(-c3ccccc3)c2)cc1 ; c1ccc(-c2ccc(N(c3cccc(C4(c5ccccc5)c5ccccc5-c5ccccc54)c3)c3ccc4c(c3)C3(c5ccccc5-c5ccccc53)c3ccccc3-4)c(-c3ccccc3)c2)cc1 ; c1ccc(-c2ccc(N(c3cccc(C4(c5ccccc5)c5ccccc5-c5ccccc54)c3)c3cccc4c3-c3ccccc3C4(c3ccccc3)c3ccccc3)c(-c3ccccc3)c2)cc1]

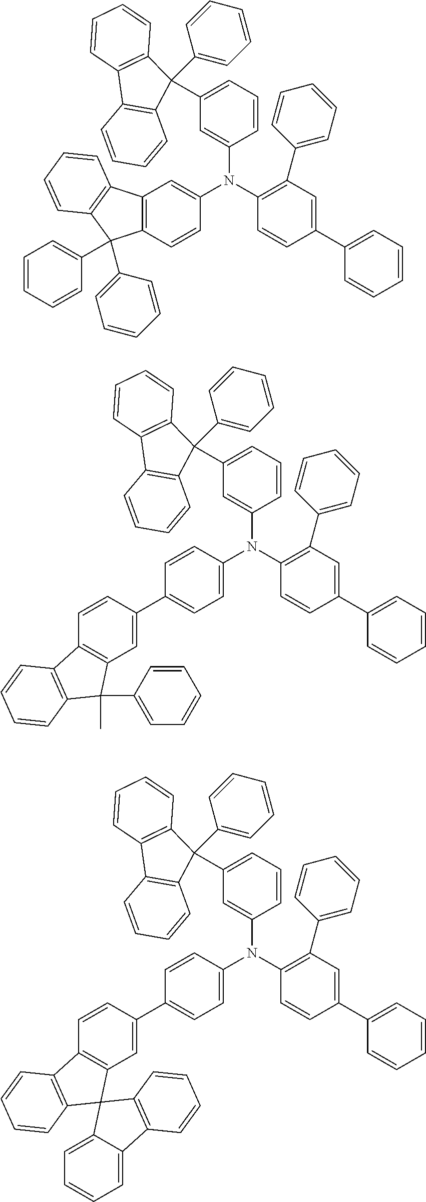

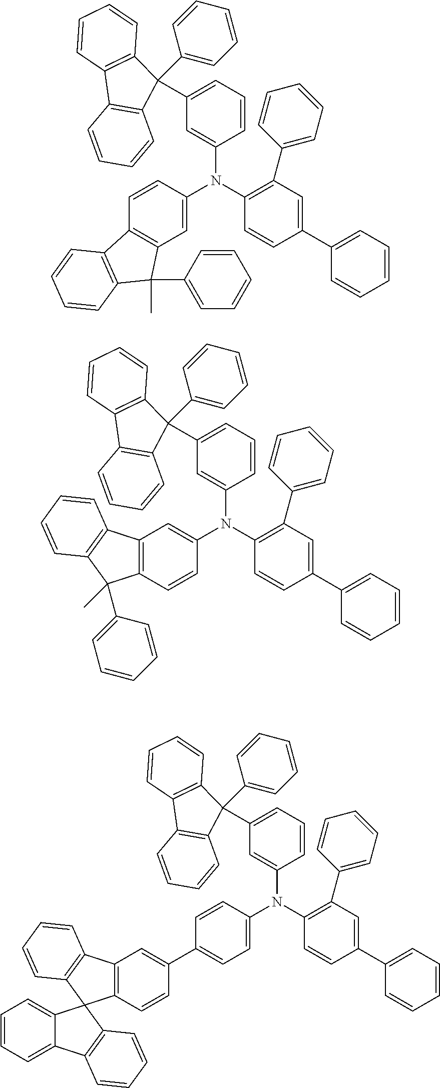

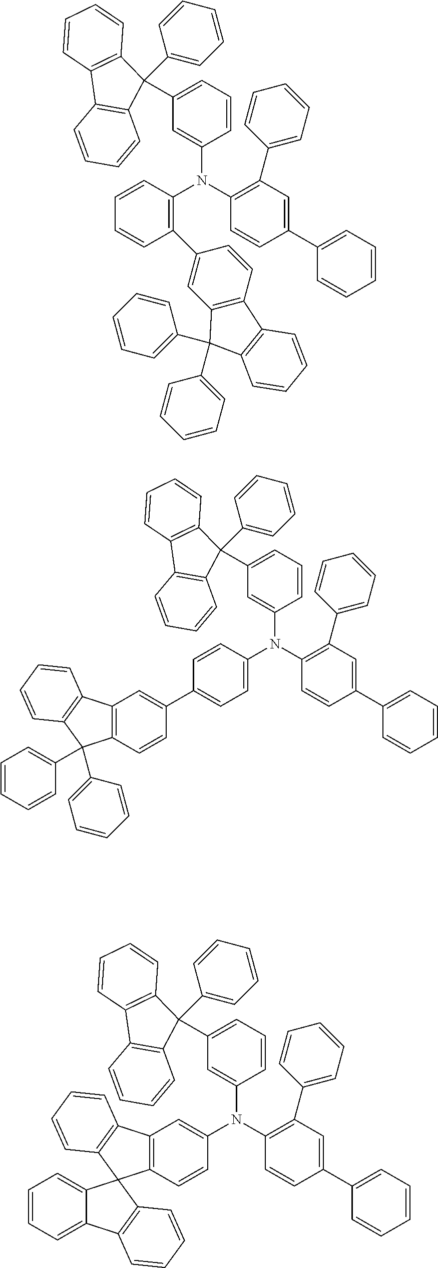

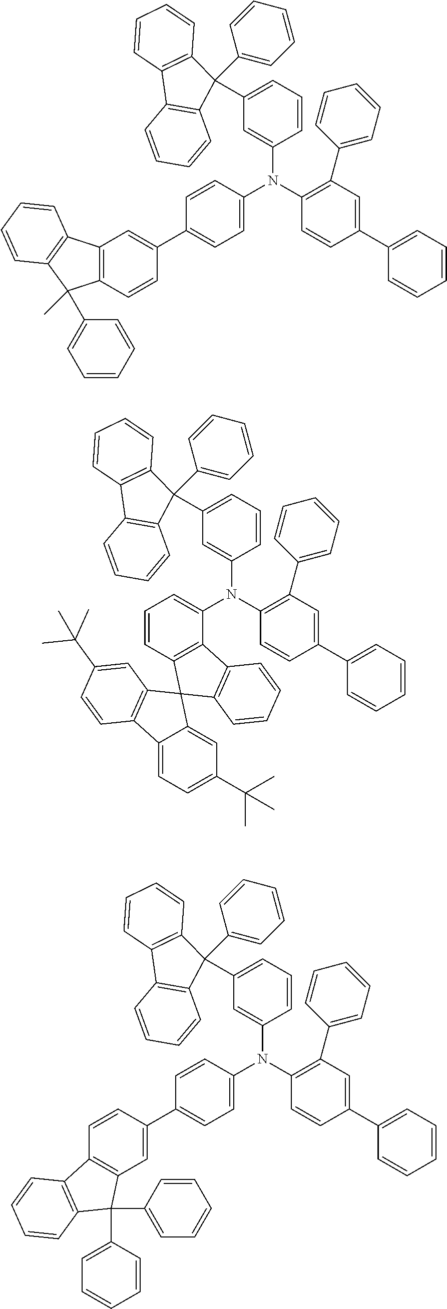

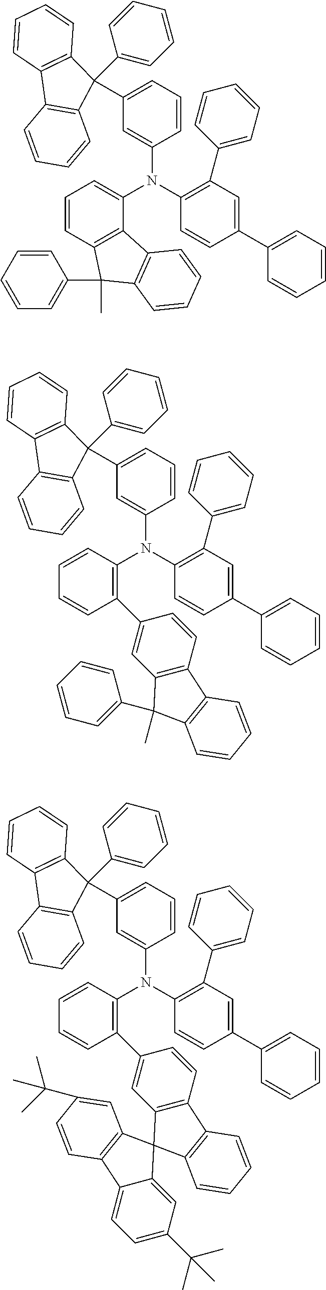 [SMILES: CC1(c2ccccc2)c2ccccc2-c2c(N(c3cccc(C4(c5ccccc5)c5ccccc5-c5ccccc54)c3)c3ccc(-c4ccccc4)cc3-c3ccccc3)cccc21 ; CC1(c2ccccc2)c2ccccc2-c2ccc(-c3ccccc3N(c3cccc(C4(c5ccccc5)c5ccccc5-c5ccccc54)c3)c3ccc(-c4ccccc4)cc3-c3ccccc3)cc21 ; CC(C)(C)c1ccc2c(c1)C1(c3ccccc3-c3ccc(-c4ccccc4N(c4cccc(C5(c6ccccc6)c6ccccc6-c6ccccc65)c4)c4ccc(-c5ccccc5)cc4-c4ccccc4)cc31)c1cc(C(C)(C)C)ccc1-2]

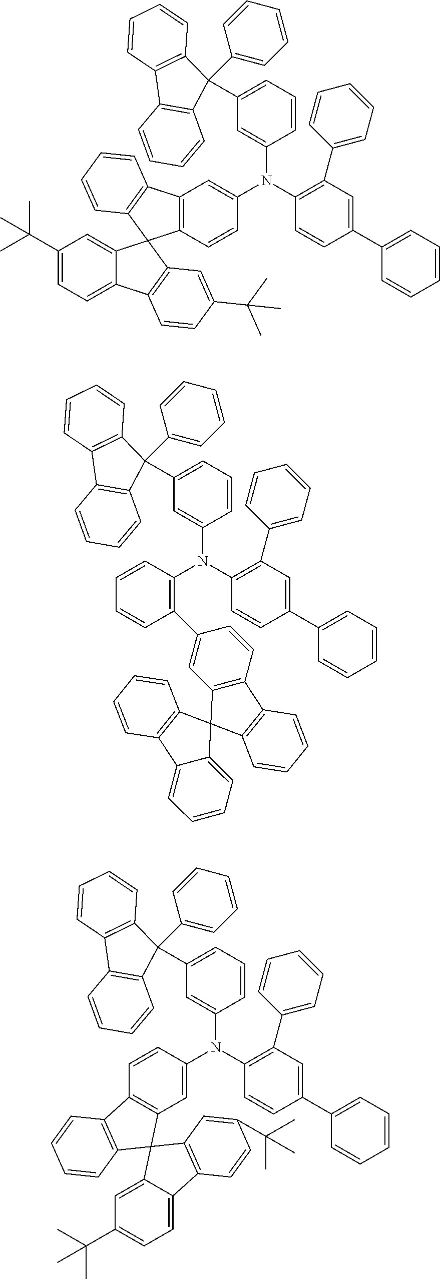

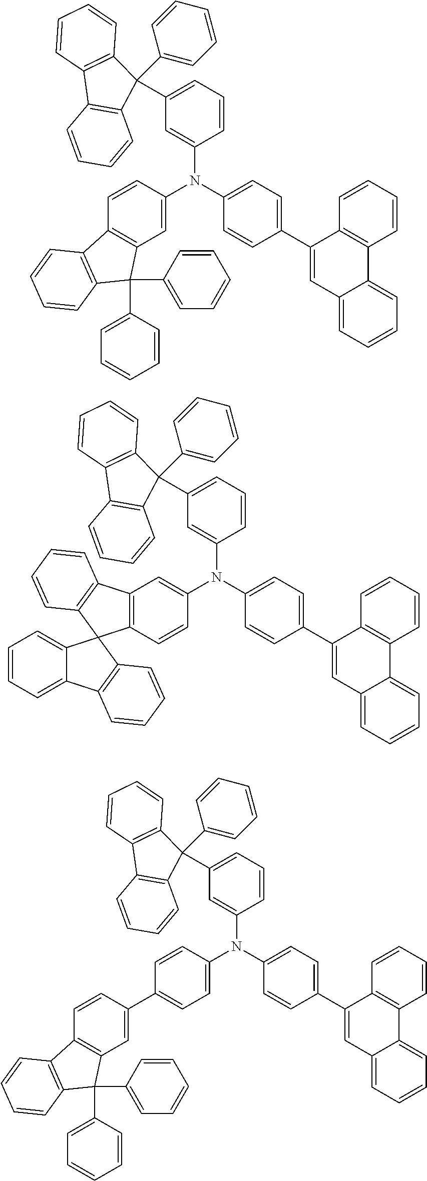

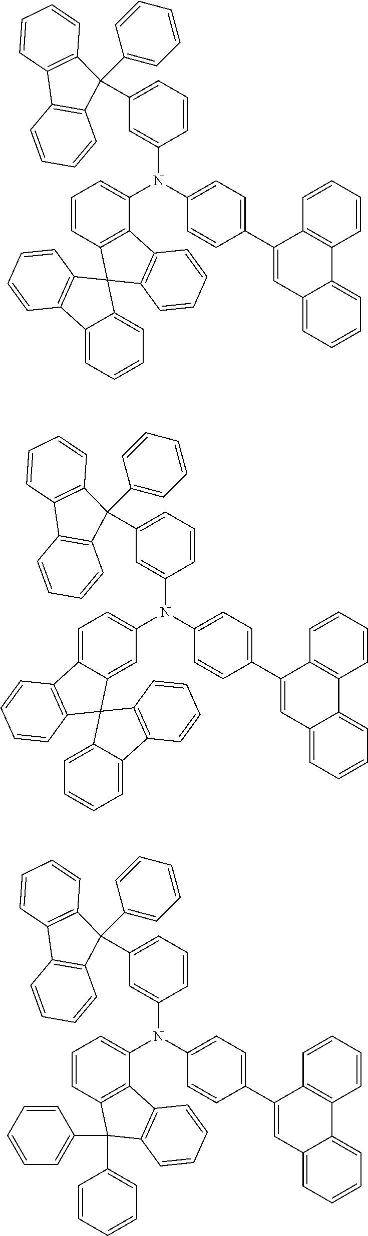 [SMILES: c1ccc(C2(c3cccc(N(c4ccc(-c5cc6ccccc6c6ccccc56)cc4)c4cccc5c4-c4ccccc4C54c5ccccc5-c5ccccc54)c3)c3ccccc3-c3ccccc32)cc1 ; c1ccc(C2(c3cccc(N(c4ccc(-c5cc6ccccc6c6ccccc56)cc4)c4ccc5c(c4)C4(c6ccccc6-c6ccccc64)c4ccccc4-5)c3)c3ccccc3-c3ccccc32)cc1 ; c1ccc(C2(c3cccc(N(c4ccc(-c5cc6ccccc6c6ccccc56)cc4)c4cccc5c4-c4ccccc4C5(c4ccccc4)c4ccccc4)c3)c3ccccc3-c3ccccc32)cc1]

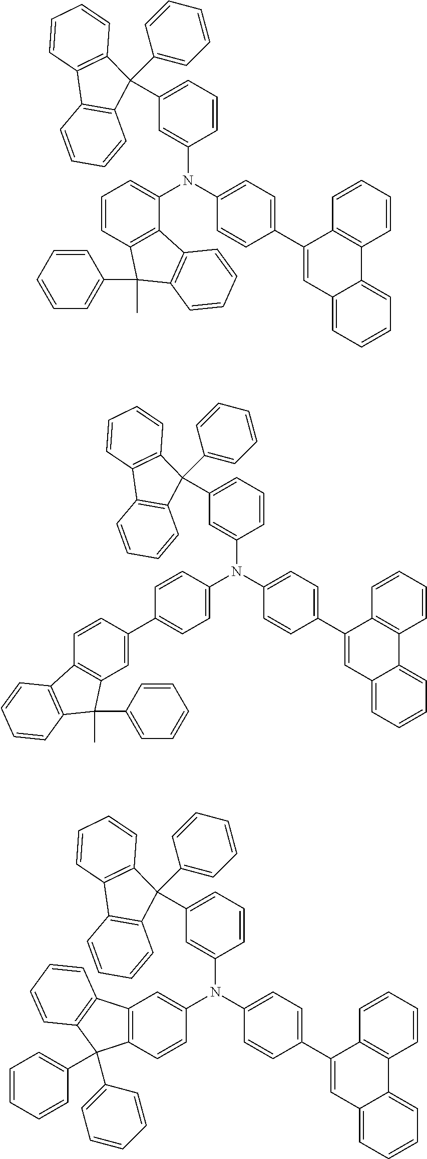 [SMILES: CC1(c2ccccc2)c2ccccc2-c2c(N(c3ccc(-c4cc5ccccc5c5ccccc45)cc3)c3cccc(C4(c5ccccc5)c5ccccc5-c5ccccc54)c3)cccc21 ; CC1(c2ccccc2)c2ccccc2-c2ccc(-c3ccc(N(c4ccc(-c5cc6ccccc6c6ccccc56)cc4)c4cccc(C5(c6ccccc6)c6ccccc6-c6ccccc65)c4)cc3)cc21 ; c1ccc(C2(c3cccc(N(c4ccc(-c5cc6ccccc6c6ccccc56)cc4)c4ccc5c(c4)-c4ccccc4C5(c4ccccc4)c4ccccc4)c3)c3ccccc3-c3ccccc32)cc1]

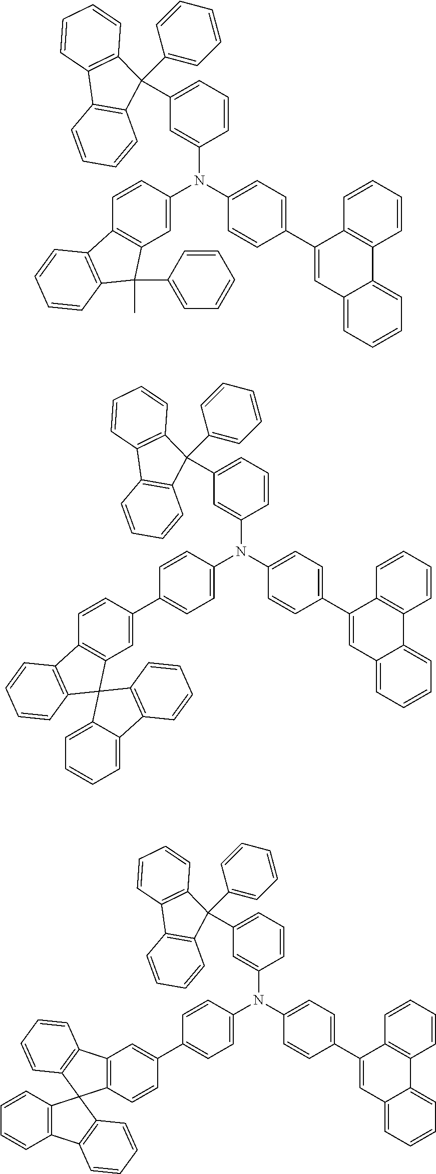 [SMILES: CC1(c2ccccc2)c2ccccc2-c2ccc(N(c3ccc(-c4cc5ccccc5c5ccccc45)cc3)c3cccc(C4(c5ccccc5)c5ccccc5-c5ccccc54)c3)cc21 ; c1ccc(C2(c3cccc(N(c4ccc(-c5ccc6c(c5)C5(c7ccccc7-c7ccccc75)c5ccccc5-6)cc4)c4ccc(-c5cc6ccccc6c6ccccc56)cc4)c3)c3ccccc3-c3ccccc32)cc1 ; c1ccc(C2(c3cccc(N(c4ccc(-c5ccc6c(c5)-c5ccccc5C65c6ccccc6-c6ccccc65)cc4)c4ccc(-c5cc6ccccc6c6ccccc56)cc4)c3)c3ccccc3-c3ccccc32)cc1]

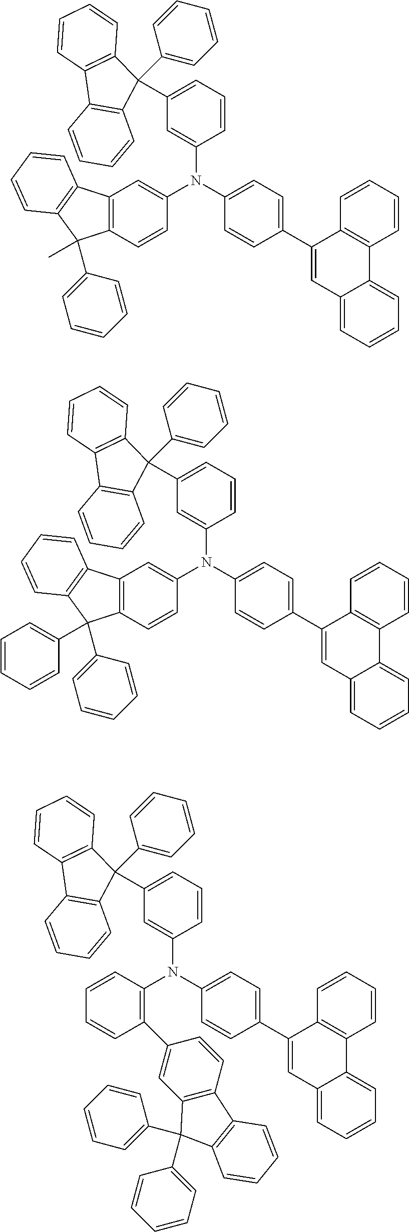 [SMILES: CC1(c2ccccc2)c2ccccc2-c2cc(N(c3ccc(-c4cc5ccccc5c5ccccc45)cc3)c3cccc(C4(c5ccccc5)c5ccccc5-c5ccccc54)c3)ccc21 ; c1ccc(C2(c3cccc(N(c4ccc(-c5cc6ccccc6c6ccccc56)cc4)c4ccc5c(c4)-c4ccccc4C5(c4ccccc4)c4ccccc4)c3)c3ccccc3-c3ccccc32)cc1 ; c1ccc(C2(c3cccc(N(c4ccc(-c5cc6ccccc6c6ccccc56)cc4)c4ccccc4-c4ccc5c(c4)C(c4ccccc4)(c4ccccc4)c4ccccc4-5)c3)c3ccccc3-c3ccccc32)cc1]

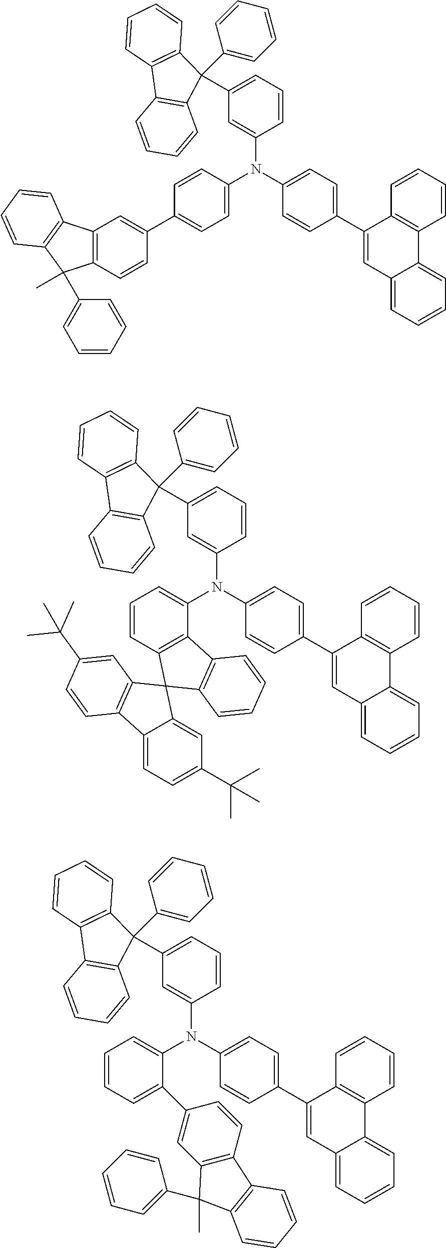 [SMILES: CC1(c2ccccc2)c2ccccc2-c2cc(-c3ccc(N(c4ccc(-c5cc6ccccc6c6ccccc56)cc4)c4cccc(C5(c6ccccc6)c6ccccc6-c6ccccc65)c4)cc3)ccc21 ; CC(C)(C)c1ccc2c(c1)C1(c3cc(C(C)(C)C)ccc3-2)c2ccccc2-c2c(N(c3ccc(-c4cc5ccccc5c5ccccc45)cc3)c3cccc(C4(c5ccccc5)c5ccccc5-c5ccccc54)c3)cccc21 ; CC1(c2ccccc2)c2ccccc2-c2ccc(-c3ccccc3N(c3ccc(-c4cc5ccccc5c5ccccc45)cc3)c3cccc(C4(c5ccccc5)c5ccccc5-c5ccccc54)c3)cc21]

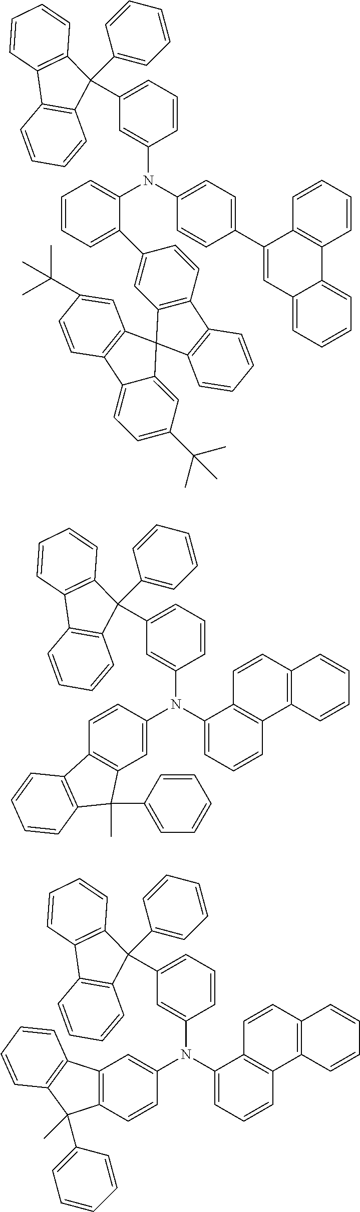

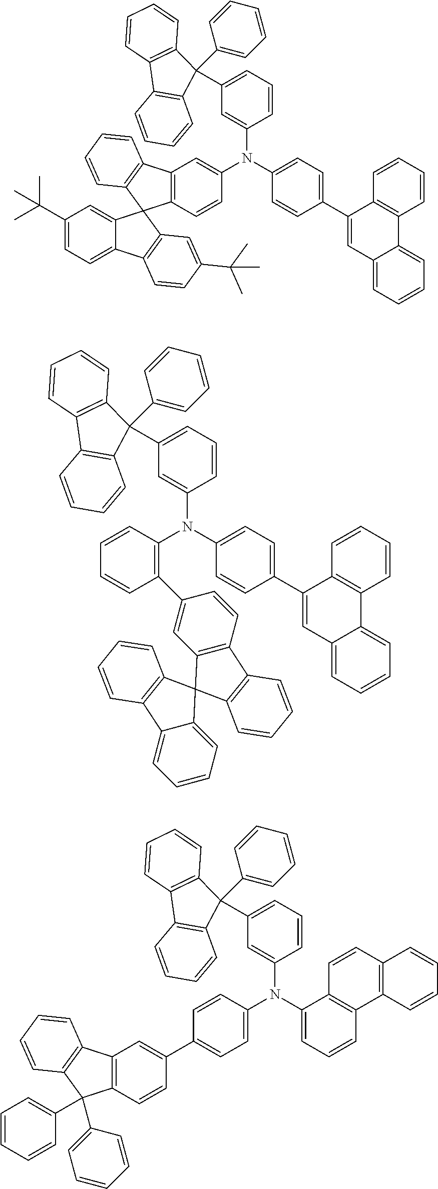

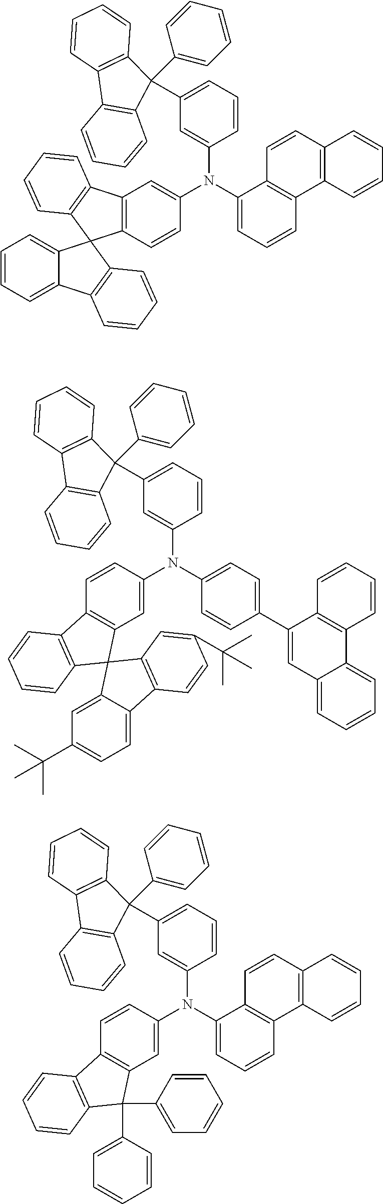 [SMILES: c1ccc(C2(c3cccc(N(c4ccc5c(c4)-c4ccccc4C54c5ccccc5-c5ccccc54)c4cccc5c4ccc4ccccc45)c3)c3ccccc3-c3ccccc32)cc1 ; CC(C)(C)c1ccc2c(c1)C1(c3ccccc3-c3ccc(N(c4ccc(-c5cc6ccccc6c6ccccc56)cc4)c4cccc(C5(c6ccccc6)c6ccccc6-c6ccccc65)c4)cc31)c1cc(C(C)(C)C)ccc1-2 ; c1ccc(C2(c3cccc(N(c4ccc5c(c4)C(c4ccccc4)(c4ccccc4)c4ccccc4-5)c4cccc5c4ccc4ccccc45)c3)c3ccccc3-c3ccccc32)cc1]

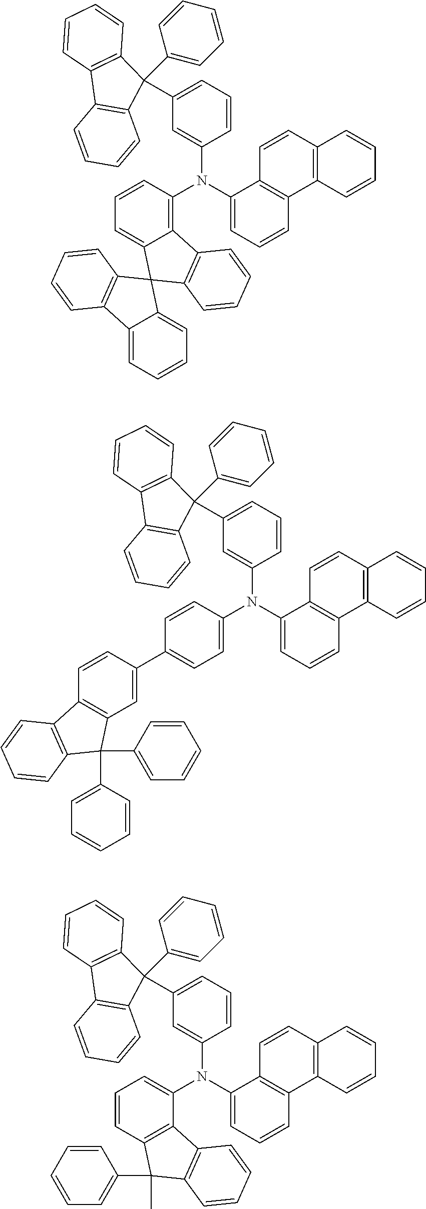 [SMILES: c1ccc(C2(c3cccc(N(c4cccc5c4-c4ccccc4C54c5ccccc5-c5ccccc54)c4cccc5c4ccc4ccccc45)c3)c3ccccc3-c3ccccc32)cc1 ; c1ccc(C2(c3cccc(N(c4ccc(-c5ccc6c(c5)C(c5ccccc5)(c5ccccc5)c5ccccc5-6)cc4)c4cccc5c4ccc4ccccc45)c3)c3ccccc3-c3ccccc32)cc1 ; CC1(c2ccccc2)c2ccccc2-c2c(N(c3cccc(C4(c5ccccc5)c5ccccc5-c5ccccc54)c3)c3cccc4c3ccc3ccccc34)cccc21]

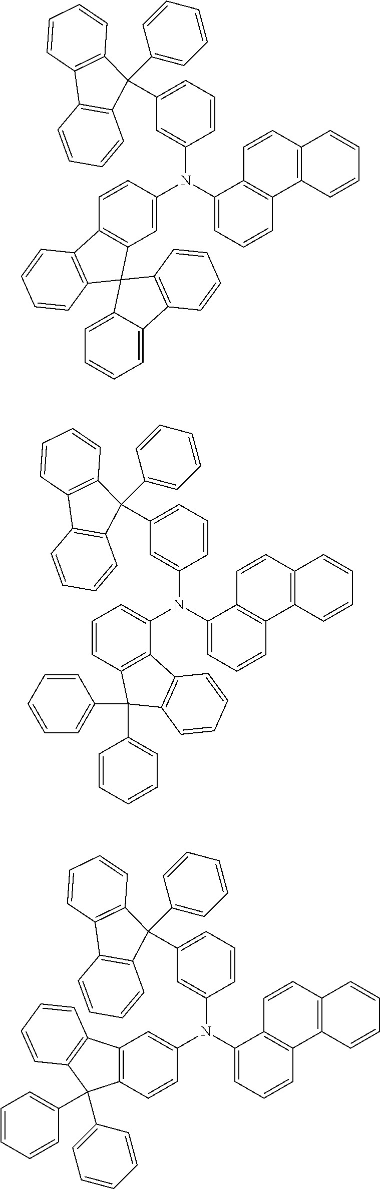 [SMILES: c1ccc(C2(c3cccc(N(c4ccc5c(c4)C4(c6ccccc6-c6ccccc64)c4ccccc4-5)c4cccc5c4ccc4ccccc45)c3)c3ccccc3-c3ccccc32)cc1 ; c1ccc(C2(c3cccc(N(c4cccc5c4-c4ccccc4C5(c4ccccc4)c4ccccc4)c4cccc5c4ccc4ccccc45)c3)c3ccccc3-c3ccccc32)cc1 ; c1ccc(C2(c3cccc(N(c4ccc5c(c4)-c4ccccc4C5(c4ccccc4)c4ccccc4)c4cccc5c4ccc4ccccc45)c3)c3ccccc3-c3ccccc32)cc1]

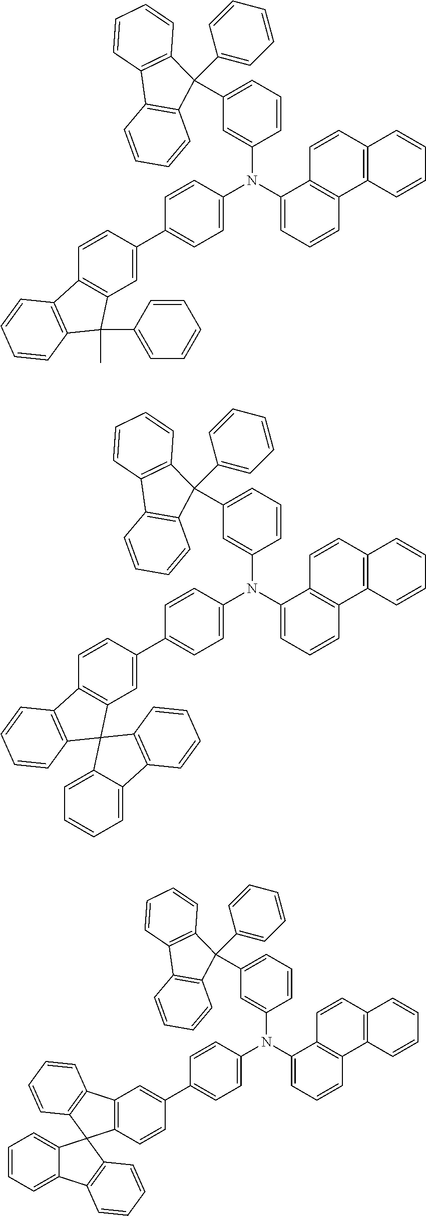 [SMILES: CC1(c2ccccc2)c2ccccc2-c2ccc(-c3ccc(N(c4cccc(C5(c6ccccc6)c6ccccc6-c6ccccc65)c4)c4cccc5c4ccc4ccccc45)cc3)cc21 ; c1ccc(C2(c3cccc(N(c4ccc(-c5ccc6c(c5)C5(c7ccccc7-c7ccccc75)c5ccccc5-6)cc4)c4cccc5c4ccc4ccccc45)c3)c3ccccc3-c3ccccc32)cc1 ; c1ccc(C2(c3cccc(N(c4ccc(-c5ccc6c(c5)-c5ccccc5C65c6ccccc6-c6ccccc65)cc4)c4cccc5c4ccc4ccccc45)c3)c3ccccc3-c3ccccc32)cc1]

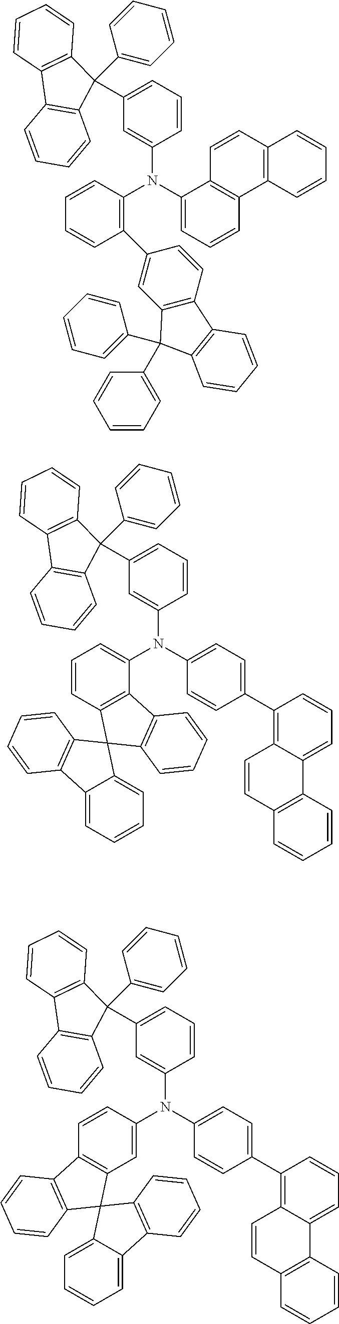

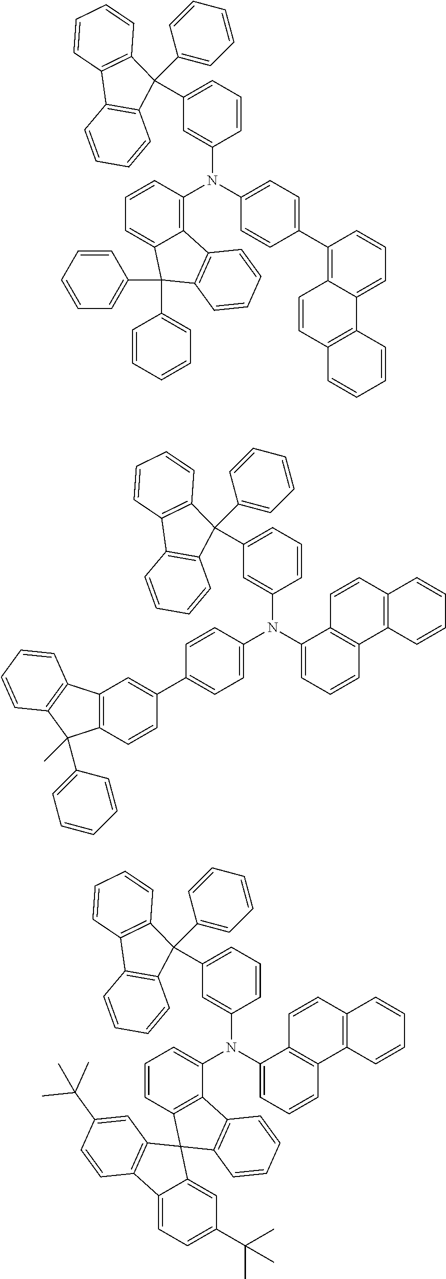 [SMILES: c1ccc(C2(c3cccc(N(c4ccc(-c5cccc6c5ccc5ccccc56)cc4)c4cccc5c4-c4ccccc4C5(c4ccccc4)c4ccccc4)c3)c3ccccc3-c3ccccc32)cc1 ; CC1(c2ccccc2)c2ccccc2-c2cc(-c3ccc(N(c4cccc(C5(c6ccccc6)c6ccccc6-c6ccccc65)c4)c4cccc5c4ccc4ccccc45)cc3)ccc21 ; CC(C)(C)c1ccc2c(c1)C1(c3cc(C(C)(C)C)ccc3-2)c2ccccc2-c2c(N(c3cccc(C4(c5ccccc5)c5ccccc5-c5ccccc54)c3)c3cccc4c3ccc3ccccc34)cccc21]

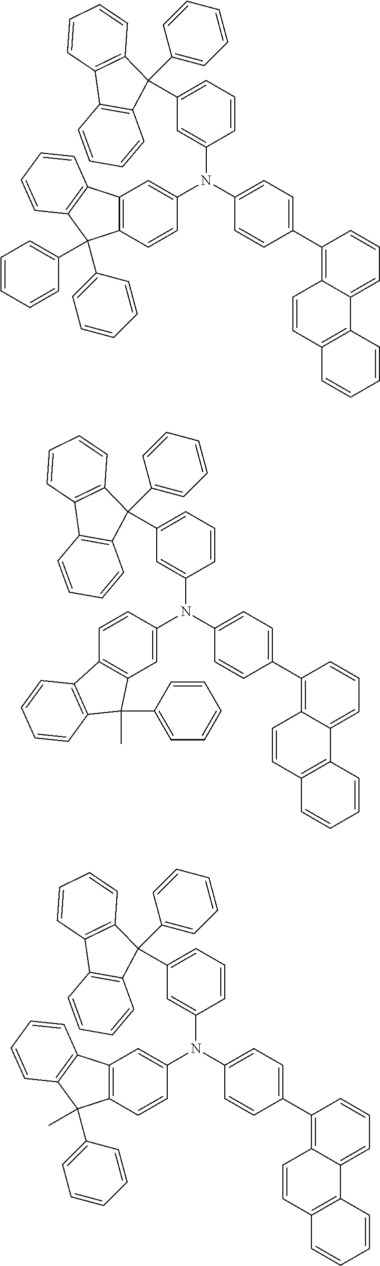 [SMILES: c1ccc(C2(c3cccc(N(c4ccc(-c5cccc6c5ccc5ccccc56)cc4)c4ccc5c(c4)-c4ccccc4C5(c4ccccc4)c4ccccc4)c3)c3ccccc3-c3ccccc32)cc1 ; CC1(c2ccccc2)c2ccccc2-c2ccc(N(c3ccc(-c4cccc5c4ccc4ccccc45)cc3)c3cccc(C4(c5ccccc5)c5ccccc5-c5ccccc54)c3)cc21 ; CC1(c2ccccc2)c2ccccc2-c2cc(N(c3ccc(-c4cccc5c4ccc4ccccc45)cc3)c3cccc(C4(c5ccccc5)c5ccccc5-c5ccccc54)c3)ccc21]

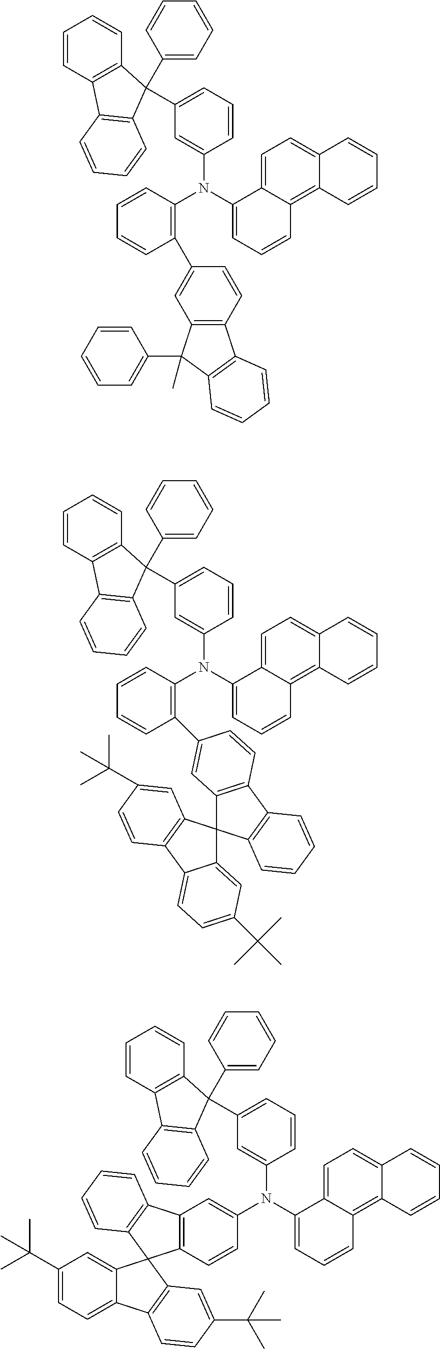 [SMILES: CC1(c2ccccc2)c2ccccc2-c2ccc(-c3ccccc3N(c3cccc(C4(c5ccccc5)c5ccccc5-c5ccccc54)c3)c3cccc4c3ccc3ccccc34)cc21 ; CC(C)(C)c1ccc2c(c1)C1(c3ccccc3-c3ccc(-c4ccccc4N(c4cccc(C5(c6ccccc6)c6ccccc6-c6ccccc65)c4)c4cccc5c4ccc4ccccc45)cc31)c1cc(C(C)(C)C)ccc1-2 ; CC(C)(C)c1ccc2c(c1)C1(c3ccccc3-c3cc(N(c4cccc(C5(c6ccccc6)c6ccccc6-c6ccccc65)c4)c4cccc5c4ccc4ccccc45)ccc31)c1cc(C(C)(C)C)ccc1-2]

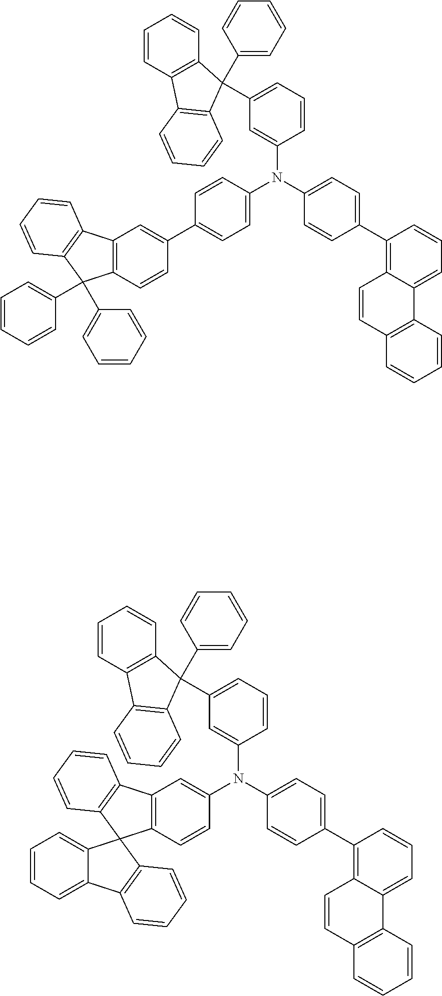 [SMILES: c1ccc(C2(c3cccc(N(c4ccc(-c5ccc6c(c5)-c5ccccc5C6(c5ccccc5)c5ccccc5)cc4)c4ccc(-c5cccc6c5ccc5ccccc56)cc4)c3)c3ccccc3-c3ccccc32)cc1 ; c1ccc(C2(c3cccc(N(c4ccc(-c5cccc6c5ccc5ccccc56)cc4)c4ccc5c(c4)-c4ccccc4C54c5ccccc5-c5ccccc54)c3)c3ccccc3-c3ccccc32)cc1]

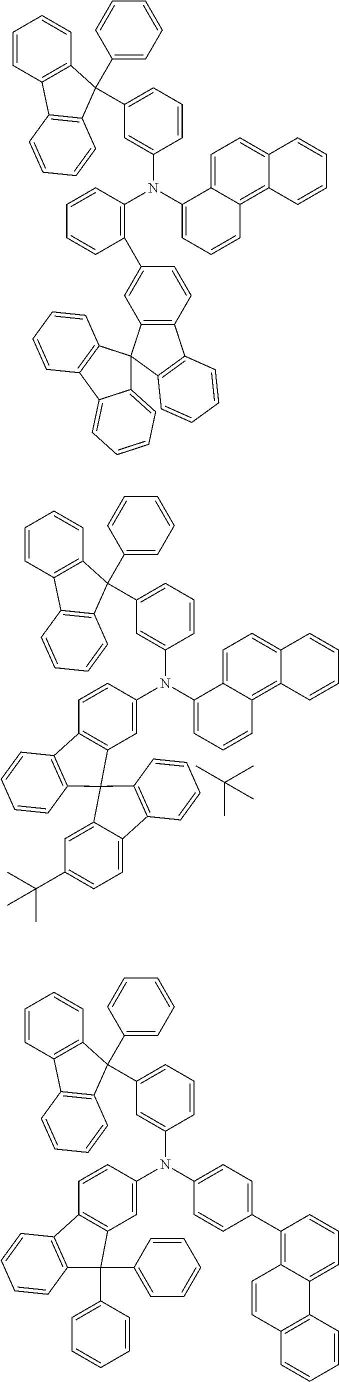

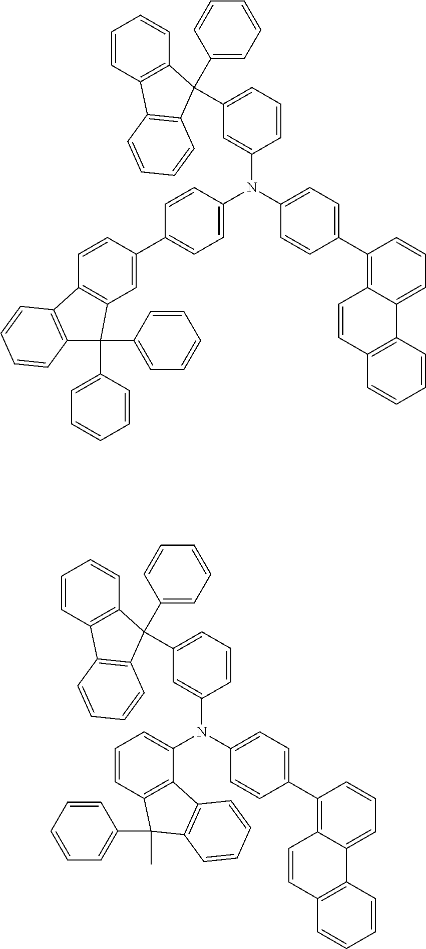 [SMILES: c1ccc(C2(c3cccc(N(c4ccc(-c5ccc6c(c5)C(c5ccccc5)(c5ccccc5)c5ccccc5-6)cc4)c4ccc(-c5cccc6c5ccc5ccccc56)cc4)c3)c3ccccc3-c3ccccc32)cc1 ; CC1(c2ccccc2)c2ccccc2-c2c(N(c3ccc(-c4cccc5c4ccc4ccccc45)cc3)c3cccc(C4(c5ccccc5)c5ccccc5-c5ccccc54)c3)cccc21]

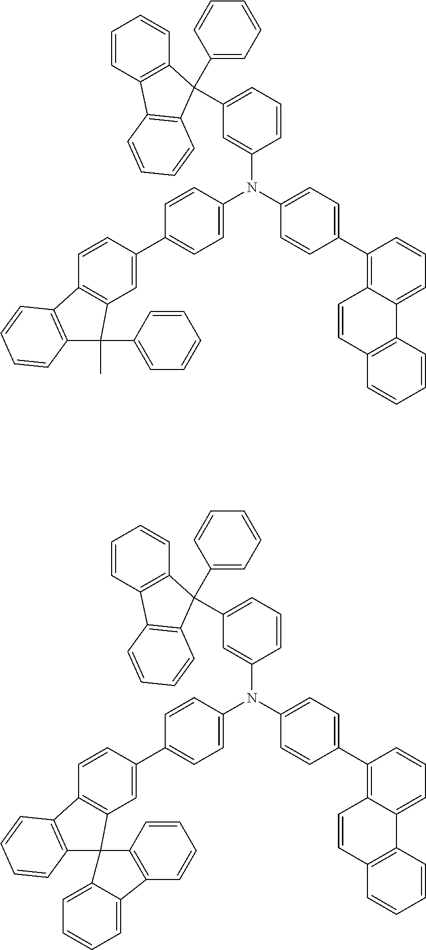 [SMILES: CC1(c2ccccc2)c2ccccc2-c2ccc(-c3ccc(N(c4ccc(-c5cccc6c5ccc5ccccc56)cc4)c4cccc(C5(c6ccccc6)c6ccccc6-c6ccccc65)c4)cc3)cc21 ; c1ccc(C2(c3cccc(N(c4ccc(-c5ccc6c(c5)C5(c7ccccc7-c7ccccc75)c5ccccc5-6)cc4)c4ccc(-c5cccc6c5ccc5ccccc56)cc4)c3)c3ccccc3-c3ccccc32)cc1]

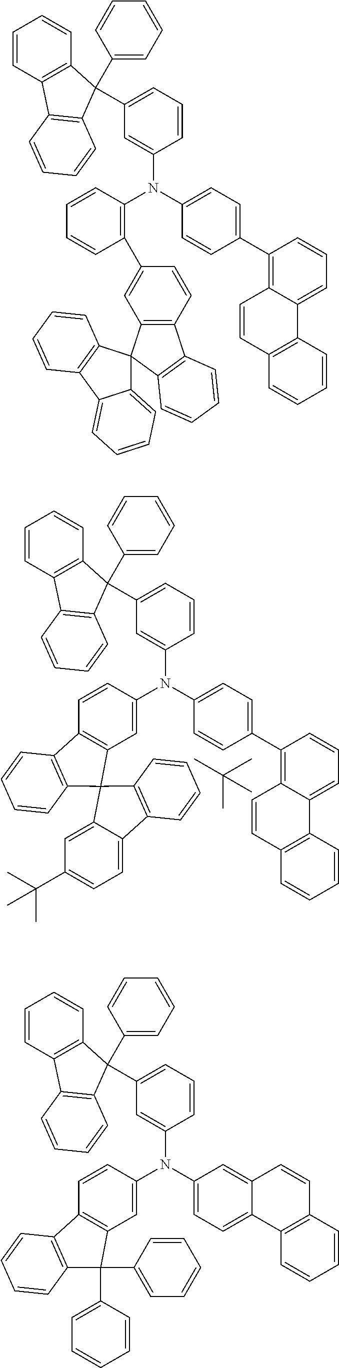

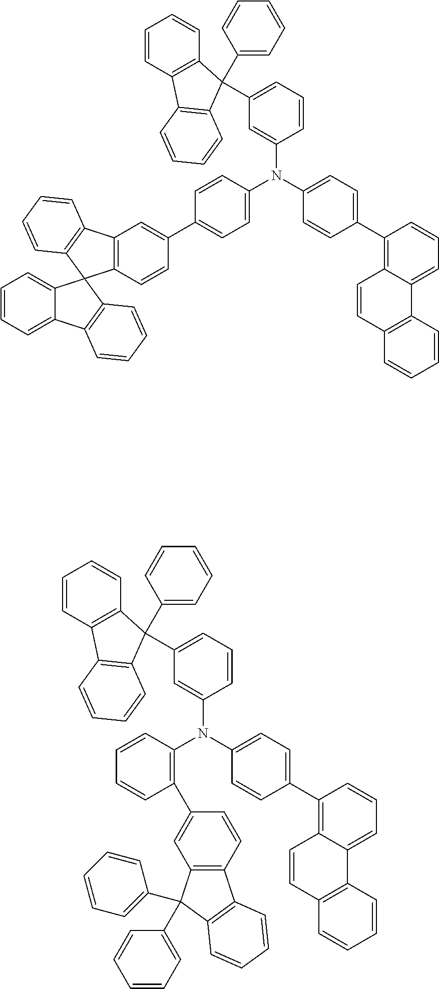 [SMILES: c1ccc(C2(c3cccc(N(c4ccc(-c5ccc6c(c5)-c5ccccc5C65c6ccccc6-c6ccccc65)cc4)c4ccc(-c5cccc6c5ccc5ccccc56)cc4)c3)c3ccccc3-c3ccccc32)cc1 ; c1ccc(C2(c3cccc(N(c4ccc(-c5cccc6c5ccc5ccccc56)cc4)c4ccccc4-c4ccc5c(c4)C(c4ccccc4)(c4ccccc4)c4ccccc4-5)c3)c3ccccc3-c3ccccc32)cc1]

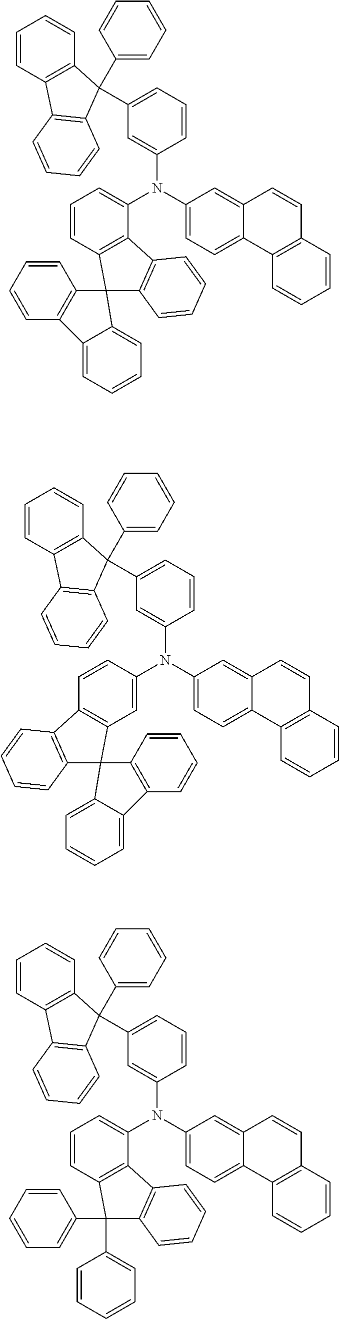 [SMILES: c1ccc(C2(c3cccc(N(c4ccc5c(ccc6ccccc65)c4)c4cccc5c4-c4ccccc4C54c5ccccc5-c5ccccc54)c3)c3ccccc3-c3ccccc32)cc1 ; c1ccc(C2(c3cccc(N(c4ccc5c(c4)C4(c6ccccc6-c6ccccc64)c4ccccc4-5)c4ccc5c(ccc6ccccc65)c4)c3)c3ccccc3-c3ccccc32)cc1 ; c1ccc(C2(c3cccc(N(c4ccc5c(ccc6ccccc65)c4)c4cccc5c4-c4ccccc4C5(c4ccccc4)c4ccccc4)c3)c3ccccc3-c3ccccc32)cc1]

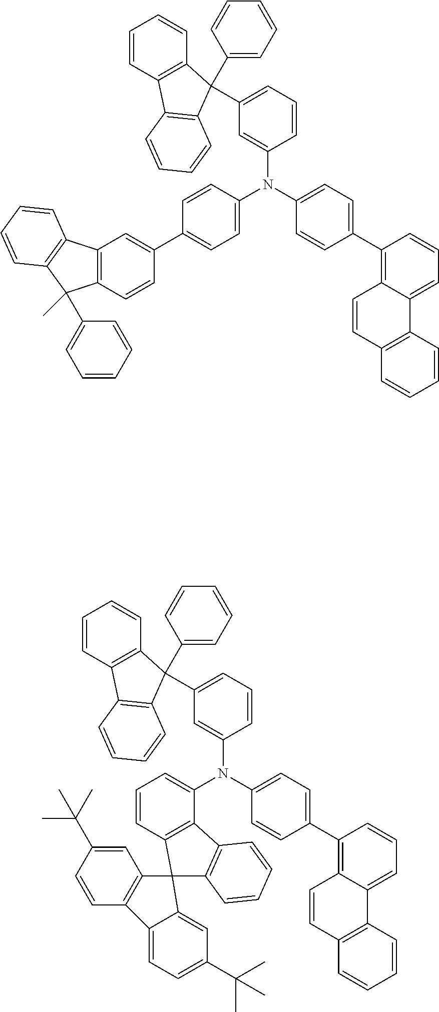 [SMILES: CC1(c2ccccc2)c2ccccc2-c2cc(-c3ccc(N(c4ccc(-c5cccc6c5ccc5ccccc56)cc4)c4cccc(C5(c6ccccc6)c6ccccc6-c6ccccc65)c4)cc3)ccc21 ; CC(C)(C)c1ccc2c(c1)C1(c3cc(C(C)(C)C)ccc3-2)c2ccccc2-c2c(N(c3ccc(-c4cccc5c4ccc4ccccc45)cc3)c3cccc(C4(c5ccccc5)c5ccccc5-c5ccccc54)c3)cccc21]

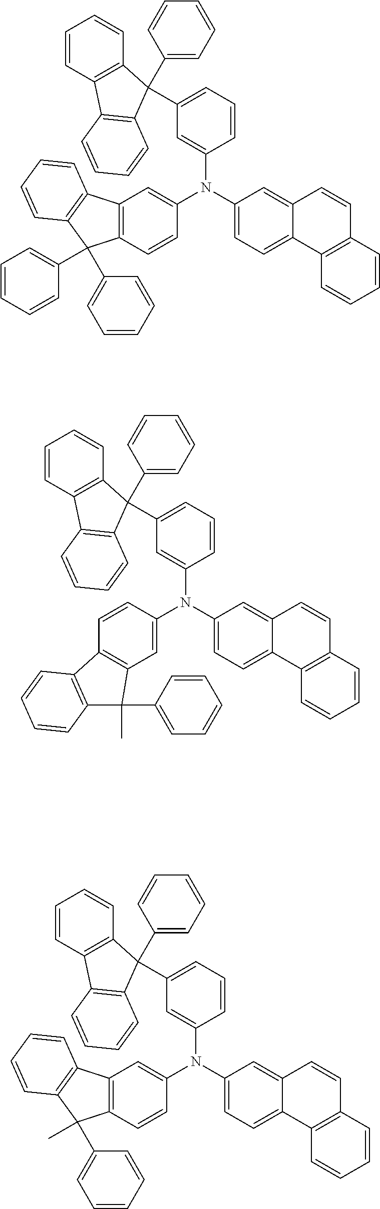 [SMILES: c1ccc(C2(c3cccc(N(c4ccc5c(c4)-c4ccccc4C5(c4ccccc4)c4ccccc4)c4ccc5c(ccc6ccccc65)c4)c3)c3ccccc3-c3ccccc32)cc1 ; CC1(c2ccccc2)c2ccccc2-c2ccc(N(c3cccc(C4(c5ccccc5)c5ccccc5-c5ccccc54)c3)c3ccc4c(ccc5ccccc54)c3)cc21 ; CC1(c2ccccc2)c2ccccc2-c2cc(N(c3cccc(C4(c5ccccc5)c5ccccc5-c5ccccc54)c3)c3ccc4c(ccc5ccccc54)c3)ccc21]

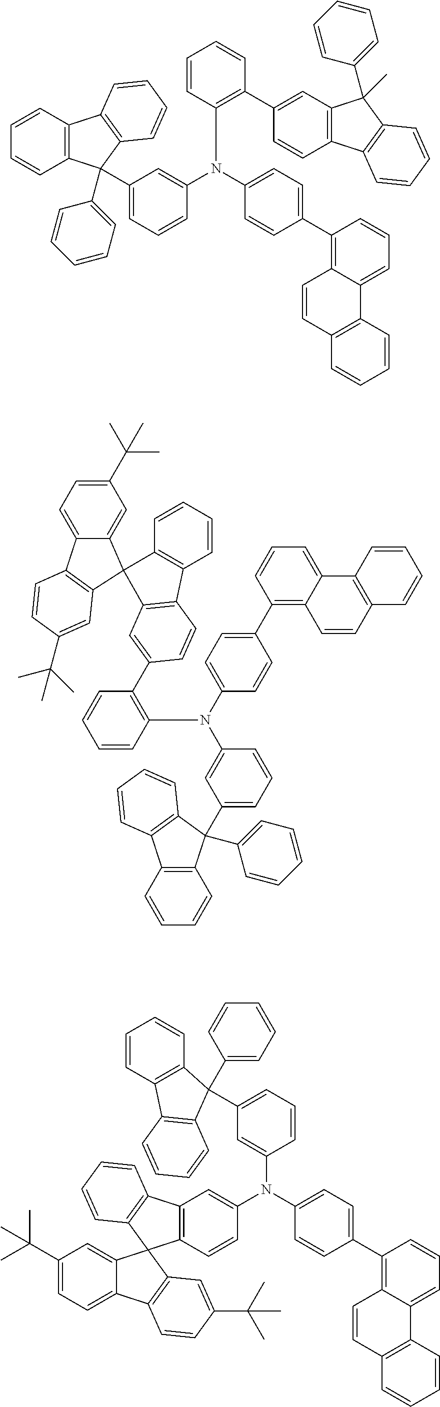 [SMILES: CC1(c2ccccc2)c2ccccc2-c2ccc(-c3ccccc3N(c3ccc(-c4cccc5c4ccc4ccccc45)cc3)c3cccc(C4(c5ccccc5)c5ccccc5-c5ccccc54)c3)cc21 ; CC(C)(C)c1ccc2c(c1)C1(c3ccccc3-c3ccc(-c4ccccc4N(c4ccc(-c5cccc6c5ccc5ccccc56)cc4)c4cccc(C5(c6ccccc6)c6ccccc6-c6ccccc65)c4)cc31)c1cc(C(C)(C)C)ccc1-2 ; CC(C)(C)c1ccc2c(c1)C1(c3ccccc3-c3cc(N(c4ccc(-c5cccc6c5ccc5ccccc56)cc4)c4cccc(C5(c6ccccc6)c6ccccc6-c6ccccc65)c4)ccc31)c1cc(C(C)(C)C)ccc1-2]

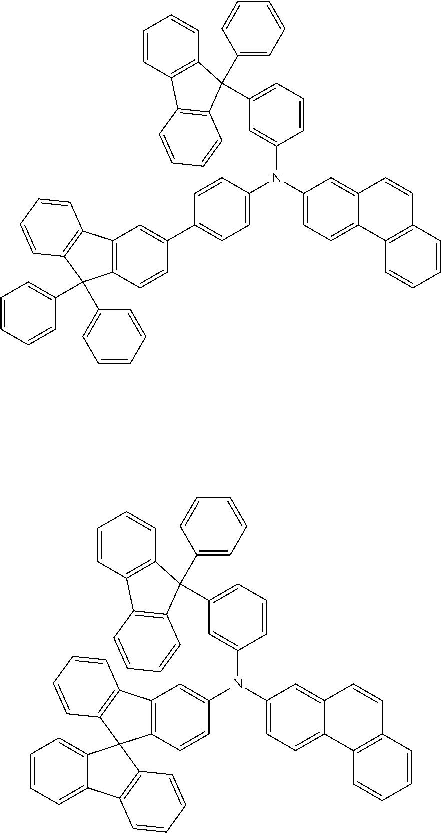 [SMILES: c1ccc(C2(c3cccc(N(c4ccc(-c5ccc6c(c5)-c5ccccc5C6(c5ccccc5)c5ccccc5)cc4)c4ccc5c(ccc6ccccc65)c4)c3)c3ccccc3-c3ccccc32)cc1 ; c1ccc(C2(c3cccc(N(c4ccc5c(c4)-c4ccccc4C54c5ccccc5-c5ccccc54)c4ccc5c(ccc6ccccc65)c4)c3)c3ccccc3-c3ccccc32)cc1]

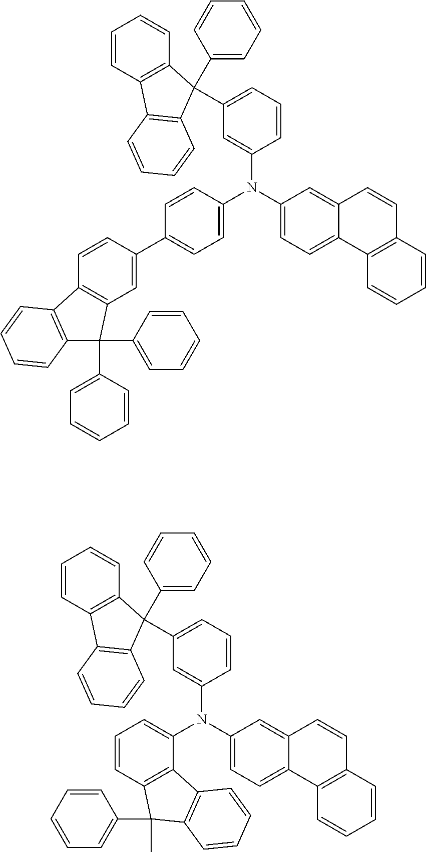 [SMILES: c1ccc(C2(c3cccc(N(c4ccc(-c5ccc6c(c5)C(c5ccccc5)(c5ccccc5)c5ccccc5-6)cc4)c4ccc5c(ccc6ccccc65)c4)c3)c3ccccc3-c3ccccc32)cc1 ; CC1(c2ccccc2)c2ccccc2-c2c(N(c3cccc(C4(c5ccccc5)c5ccccc5-c5ccccc54)c3)c3ccc4c(ccc5ccccc54)c3)cccc21]

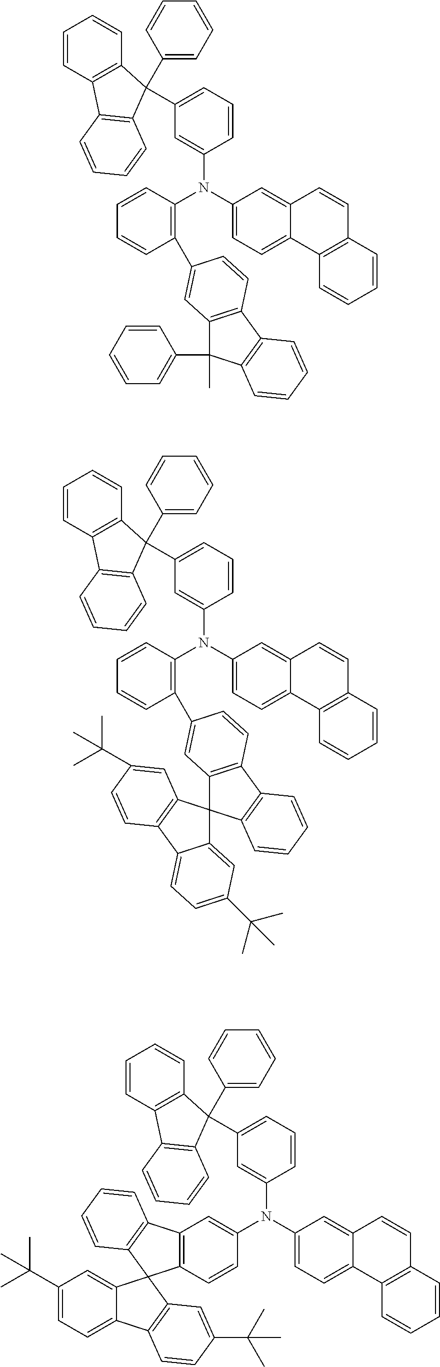 [SMILES: CC1(c2ccccc2)c2ccccc2-c2ccc(-c3ccccc3N(c3cccc(C4(c5ccccc5)c5ccccc5-c5ccccc54)c3)c3ccc4c(ccc5ccccc54)c3)cc21 ; CC(C)(C)c1ccc2c(c1)C1(c3ccccc3-c3ccc(-c4ccccc4N(c4cccc(C5(c6ccccc6)c6ccccc6-c6ccccc65)c4)c4ccc5c(ccc6ccccc65)c4)cc31)c1cc(C(C)(C)C)ccc1-2 ; CC(C)(C)c1ccc2c(c1)C1(c3ccccc3-c3cc(N(c4cccc(C5(c6ccccc6)c6ccccc6-c6ccccc65)c4)c4ccc5c(ccc6ccccc65)c4)ccc31)c1cc(C(C)(C)C)ccc1-2]

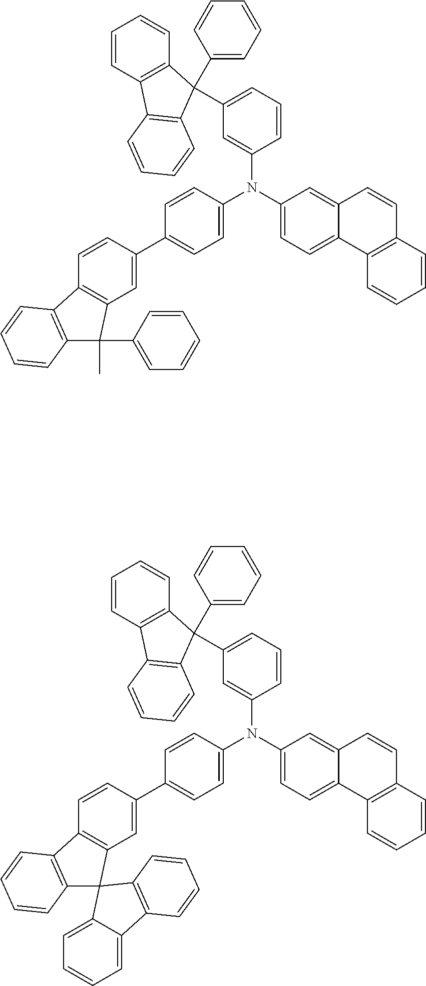 [SMILES: CC1(c2ccccc2)c2ccccc2-c2ccc(-c3ccc(N(c4cccc(C5(c6ccccc6)c6ccccc6-c6ccccc65)c4)c4ccc5c(ccc6ccccc65)c4)cc3)cc21 ; c1ccc(C2(c3cccc(N(c4ccc(-c5ccc6c(c5)C5(c7ccccc7-c7ccccc75)c5ccccc5-6)cc4)c4ccc5c(ccc6ccccc65)c4)c3)c3ccccc3-c3ccccc32)cc1]

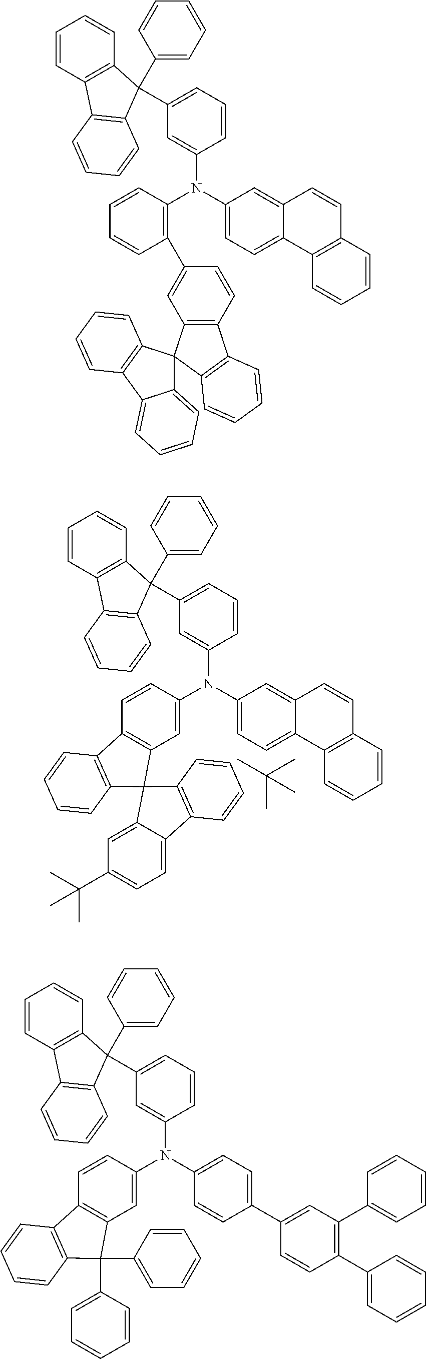

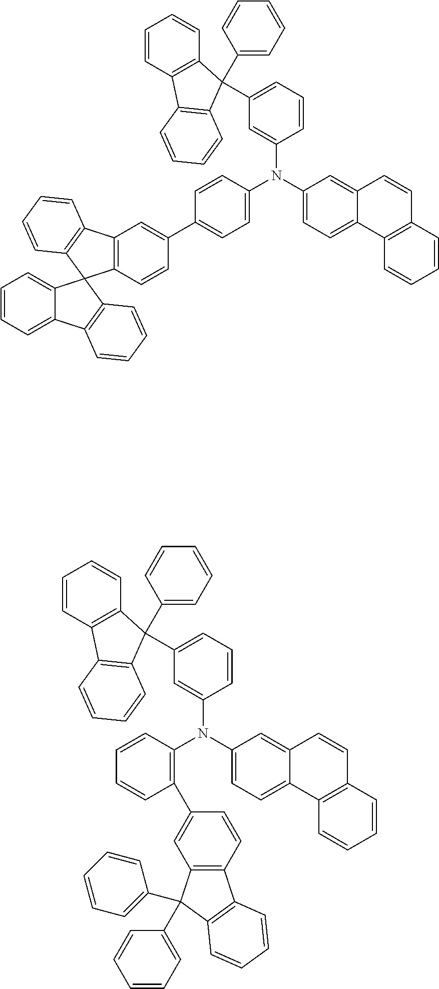 [SMILES: c1ccc(C2(c3cccc(N(c4ccc(-c5ccc6c(c5)-c5ccccc5C65c6ccccc6-c6ccccc65)cc4)c4ccc5c(ccc6ccccc65)c4)c3)c3ccccc3-c3ccccc32)cc1 ; c1ccc(C2(c3cccc(N(c4ccc5c(ccc6ccccc65)c4)c4ccccc4-c4ccc5c(c4)C(c4ccccc4)(c4ccccc4)c4ccccc4-5)c3)c3ccccc3-c3ccccc32)cc1]

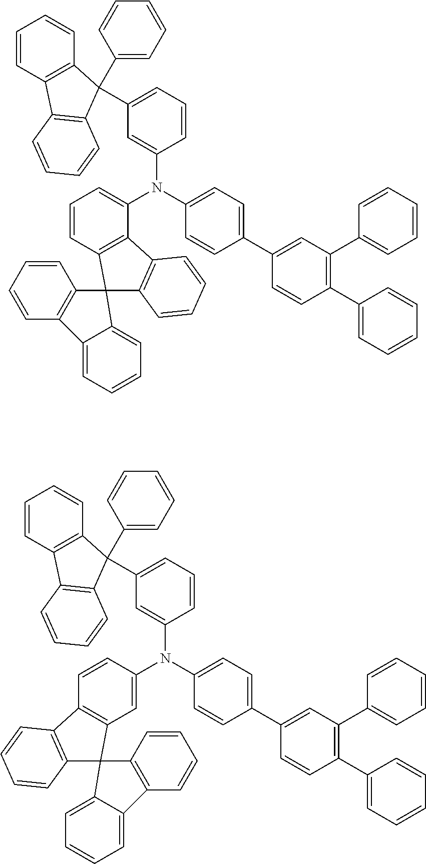 [SMILES: c1ccc(-c2ccc(-c3ccc(N(c4cccc(C5(c6ccccc6)c6ccccc6-c6ccccc65)c4)c4cccc5c4-c4ccccc4C54c5ccccc5-c5ccccc54)cc3)cc2-c2ccccc2)cc1 ; c1ccc(-c2ccc(-c3ccc(N(c4cccc(C5(c6ccccc6)c6ccccc6-c6ccccc65)c4)c4ccc5c(c4)C4(c6ccccc6-c6ccccc64)c4ccccc4-5)cc3)cc2-c2ccccc2)cc1]

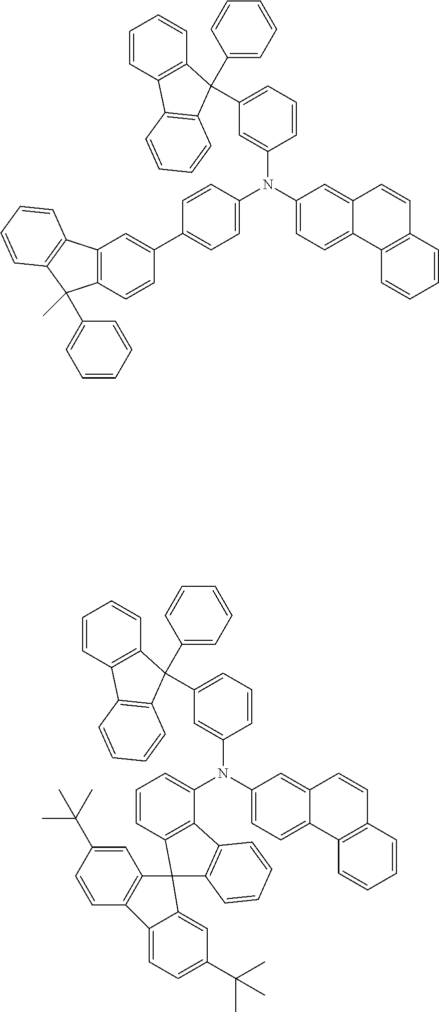 [SMILES: CC1(c2ccccc2)c2ccccc2-c2cc(-c3ccc(N(c4cccc(C5(c6ccccc6)c6ccccc6-c6ccccc65)c4)c4ccc5c(ccc6ccccc65)c4)cc3)ccc21 ; CC(C)(C)c1ccc2c(c1)C1(c3cc(C(C)(C)C)ccc3-2)c2ccccc2-c2c(N(c3cccc(C4(c5ccccc5)c5ccccc5-c5ccccc54)c3)c3ccc4c(ccc5ccccc54)c3)cccc21]

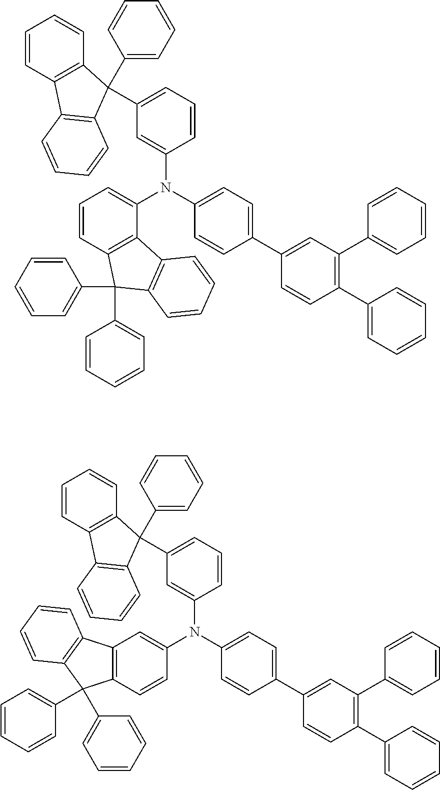 [SMILES: c1ccc(-c2ccc(-c3ccc(N(c4cccc(C5(c6ccccc6)c6ccccc6-c6ccccc65)c4)c4cccc5c4-c4ccccc4C5(c4ccccc4)c4ccccc4)cc3)cc2-c2ccccc2)cc1 ; c1ccc(-c2ccc(-c3ccc(N(c4cccc(C5(c6ccccc6)c6ccccc6-c6ccccc65)c4)c4ccc5c(c4)-c4ccccc4C5(c4ccccc4)c4ccccc4)cc3)cc2-c2ccccc2)cc1]

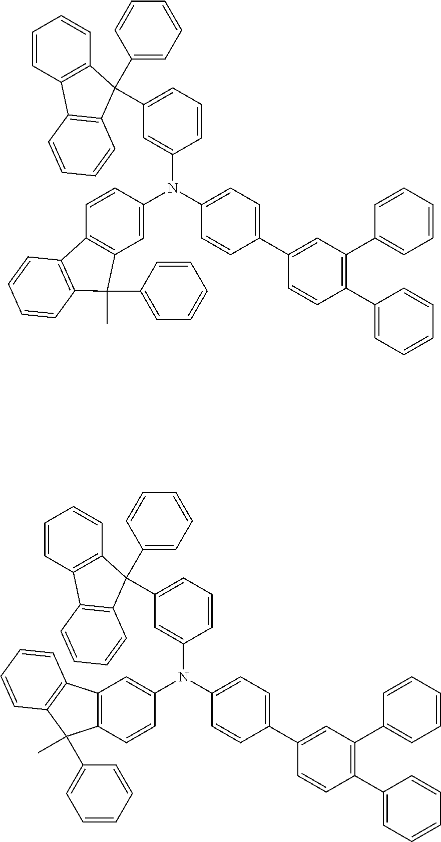 [SMILES: CC1(c2ccccc2)c2ccccc2-c2ccc(N(c3ccc(-c4ccc(-c5ccccc5)c(-c5ccccc5)c4)cc3)c3cccc(C4(c5ccccc5)c5ccccc5-c5ccccc54)c3)cc21 ; CC1(c2ccccc2)c2ccccc2-c2cc(N(c3ccc(-c4ccc(-c5ccccc5)c(-c5ccccc5)c4)cc3)c3cccc(C4(c5ccccc5)c5ccccc5-c5ccccc54)c3)ccc21]

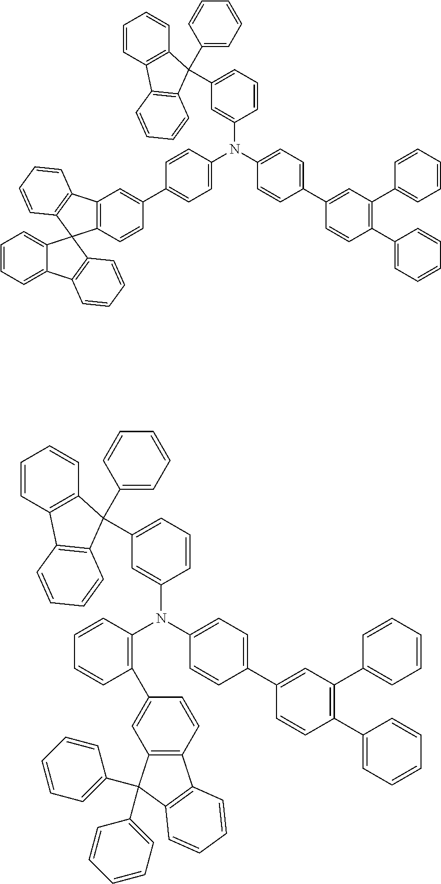 [SMILES: c1ccc(-c2ccc(-c3ccc(N(c4ccc(-c5ccc6c(c5)-c5ccccc5C65c6ccccc6-c6ccccc65)cc4)c4cccc(C5(c6ccccc6)c6ccccc6-c6ccccc65)c4)cc3)cc2-c2ccccc2)cc1 ; c1ccc(-c2ccc(-c3ccc(N(c4cccc(C5(c6ccccc6)c6ccccc6-c6ccccc65)c4)c4ccccc4-c4ccc5c(c4)C(c4ccccc4)(c4ccccc4)c4ccccc4-5)cc3)cc2-c2ccccc2)cc1]

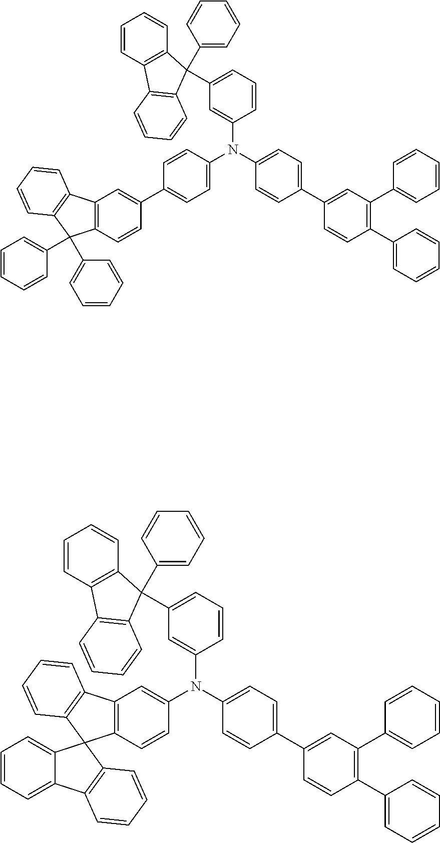 [SMILES: c1ccc(-c2ccc(-c3ccc(N(c4ccc(-c5ccc6c(c5)-c5ccccc5C6(c5ccccc5)c5ccccc5)cc4)c4cccc(C5(c6ccccc6)c6ccccc6-c6ccccc65)c4)cc3)cc2-c2ccccc2)cc1 ; c1ccc(-c2ccc(-c3ccc(N(c4cccc(C5(c6ccccc6)c6ccccc6-c6ccccc65)c4)c4ccc5c(c4)-c4ccccc4C54c5ccccc5-c5ccccc54)cc3)cc2-c2ccccc2)cc1]

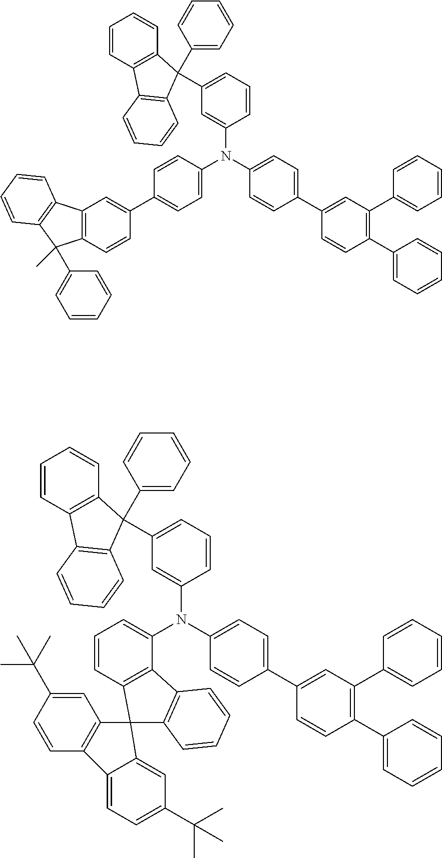 [SMILES: CC1(c2ccccc2)c2ccccc2-c2cc(-c3ccc(N(c4ccc(-c5ccc(-c6ccccc6)c(-c6ccccc6)c5)cc4)c4cccc(C5(c6ccccc6)c6ccccc6-c6ccccc65)c4)cc3)ccc21 ; CC(C)(C)c1ccc2c(c1)C1(c3cc(C(C)(C)C)ccc3-2)c2ccccc2-c2c(N(c3ccc(-c4ccc(-c5ccccc5)c(-c5ccccc5)c4)cc3)c3cccc(C4(c5ccccc5)c5ccccc5-c5ccccc54)c3)cccc21]

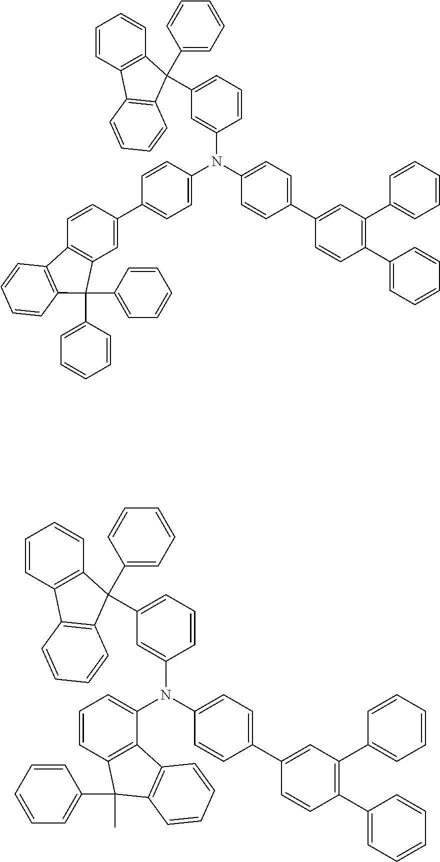 [SMILES: c1ccc(-c2ccc(-c3ccc(N(c4ccc(-c5ccc6c(c5)C(c5ccccc5)(c5ccccc5)c5ccccc5-6)cc4)c4cccc(C5(c6ccccc6)c6ccccc6-c6ccccc65)c4)cc3)cc2-c2ccccc2)cc1 ; CC1(c2ccccc2)c2ccccc2-c2c(N(c3ccc(-c4ccc(-c5ccccc5)c(-c5ccccc5)c4)cc3)c3cccc(C4(c5ccccc5)c5ccccc5-c5ccccc54)c3)cccc21]

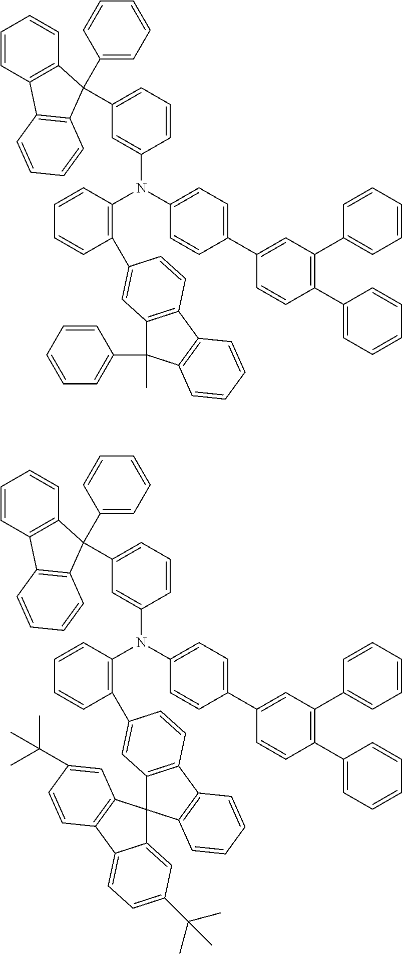 [SMILES: CC1(c2ccccc2)c2ccccc2-c2ccc(-c3ccccc3N(c3ccc(-c4ccc(-c5ccccc5)c(-c5ccccc5)c4)cc3)c3cccc(C4(c5ccccc5)c5ccccc5-c5ccccc54)c3)cc21 ; CC(C)(C)c1ccc2c(c1)C1(c3ccccc3-c3ccc(-c4ccccc4N(c4ccc(-c5ccc(-c6ccccc6)c(-c6ccccc6)c5)cc4)c4cccc(C5(c6ccccc6)c6ccccc6-c6ccccc65)c4)cc31)c1cc(C(C)(C)C)ccc1-2]

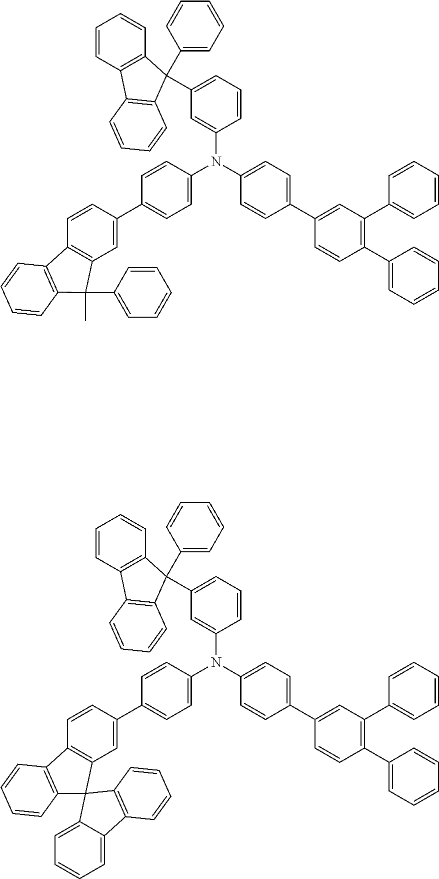 [SMILES: CC1(c2ccccc2)c2ccccc2-c2ccc(-c3ccc(N(c4ccc(-c5ccc(-c6ccccc6)c(-c6ccccc6)c5)cc4)c4cccc(C5(c6ccccc6)c6ccccc6-c6ccccc65)c4)cc3)cc21 ; c1ccc(-c2ccc(-c3ccc(N(c4ccc(-c5ccc6c(c5)C5(c7ccccc7-c7ccccc75)c5ccccc5-6)cc4)c4cccc(C5(c6ccccc6)c6ccccc6-c6ccccc65)c4)cc3)cc2-c2ccccc2)cc1]

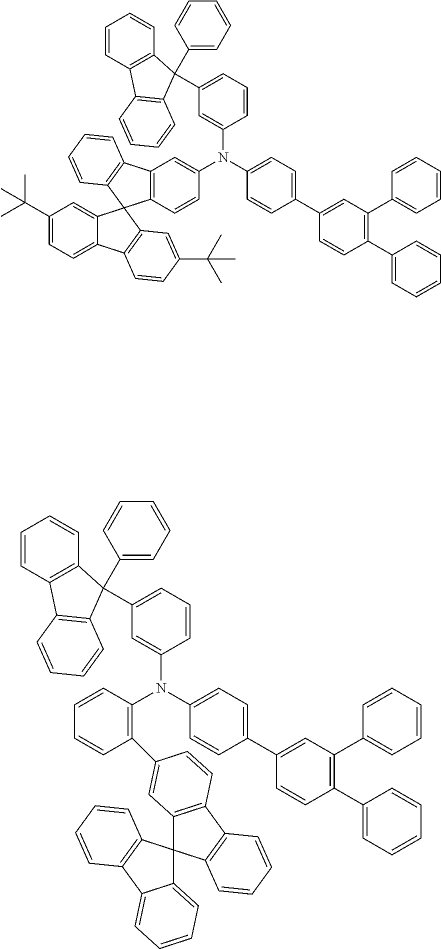 [SMILES: CC(C)(C)c1ccc2c(c1)C1(c3ccccc3-c3cc(N(c4ccc(-c5ccc(-c6ccccc6)c(-c6ccccc6)c5)cc4)c4cccc(C5(c6ccccc6)c6ccccc6-c6ccccc65)c4)ccc31)c1cc(C(C)(C)C)ccc1-2 ; c1ccc(-c2ccc(-c3ccc(N(c4cccc(C5(c6ccccc6)c6ccccc6-c6ccccc65)c4)c4ccccc4-c4ccc5c(c4)C4(c6ccccc6-c6ccccc64)c4ccccc4-5)cc3)cc2-c2ccccc2)cc1]

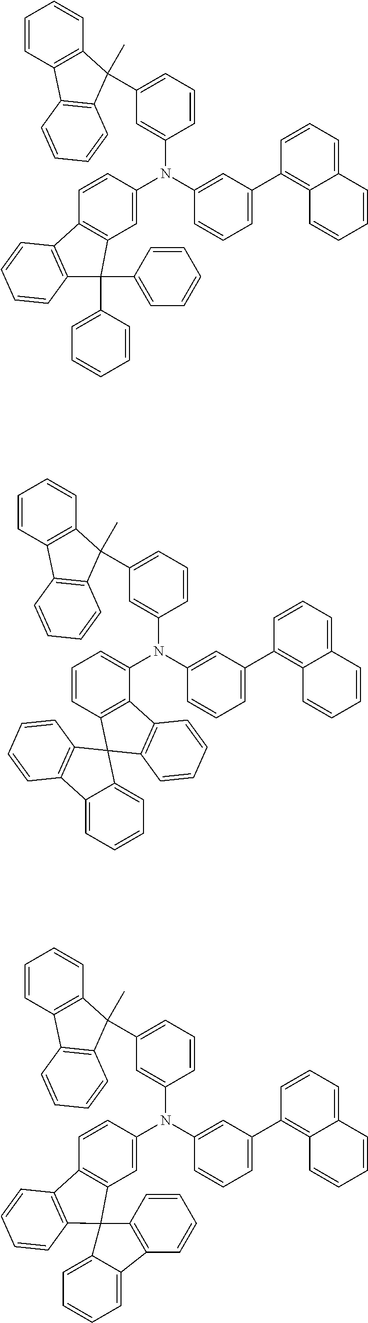 [SMILES: CC1(c2cccc(N(c3cccc(-c4cccc5ccccc45)c3)c3ccc4c(c3)C(c3ccccc3)(c3ccccc3)c3ccccc3-4)c2)c2ccccc2-c2ccccc21 ; CC1(c2cccc(N(c3cccc(-c4cccc5ccccc45)c3)c3cccc4c3-c3ccccc3C43c4ccccc4-c4ccccc43)c2)c2ccccc2-c2ccccc21 ; CC1(c2cccc(N(c3cccc(-c4cccc5ccccc45)c3)c3ccc4c(c3)C3(c5ccccc5-c5ccccc53)c3ccccc3-4)c2)c2ccccc2-c2ccccc21]

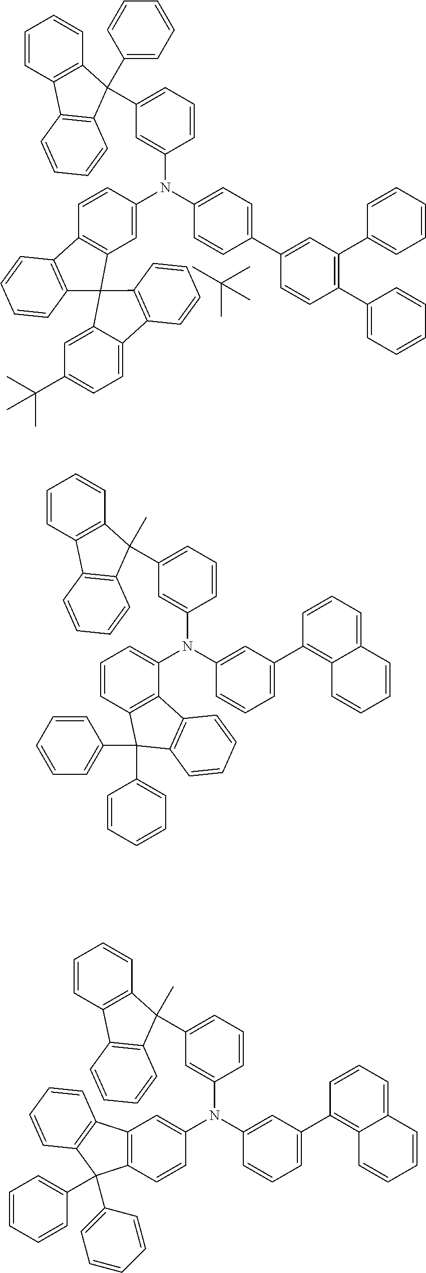

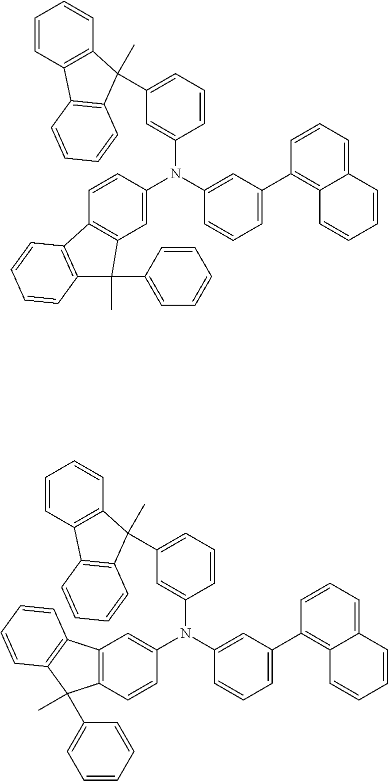 [SMILES: CC1(c2cccc(N(c3cccc(-c4cccc5ccccc45)c3)c3ccc4c(c3)C(C)(c3ccccc3)c3ccccc3-4)c2)c2ccccc2-c2ccccc21 ; CC1(c2cccc(N(c3cccc(-c4cccc5ccccc45)c3)c3ccc4c(c3)-c3ccccc3C4(C)c3ccccc3)c2)c2ccccc2-c2ccccc21]

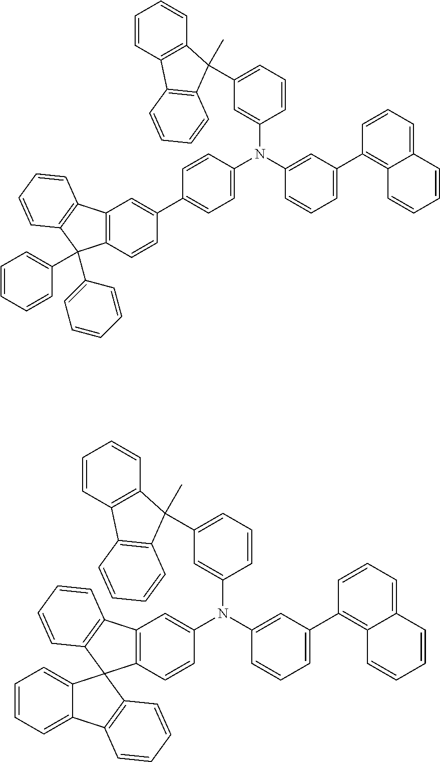 [SMILES: CC1(c2cccc(N(c3ccc(-c4ccc5c(c4)-c4ccccc4C5(c4ccccc4)c4ccccc4)cc3)c3cccc(-c4cccc5ccccc45)c3)c2)c2ccccc2-c2ccccc21 ; CC1(c2cccc(N(c3cccc(-c4cccc5ccccc45)c3)c3ccc4c(c3)-c3ccccc3C43c4ccccc4-c4ccccc43)c2)c2ccccc2-c2ccccc21]

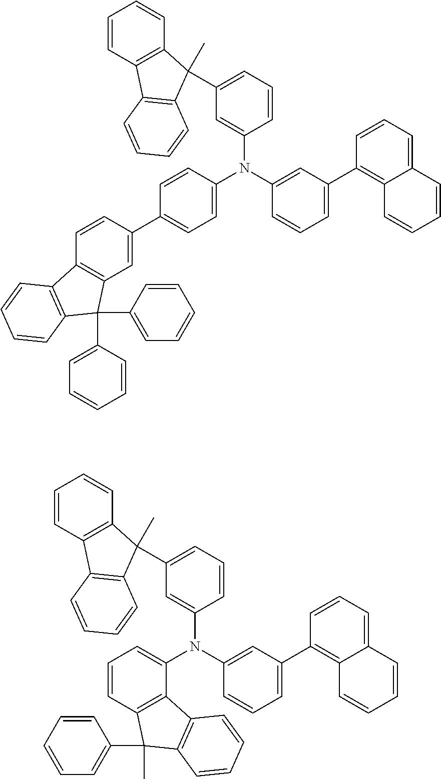 [SMILES: CC1(c2cccc(N(c3ccc(-c4ccc5c(c4)C(c4ccccc4)(c4ccccc4)c4ccccc4-5)cc3)c3cccc(-c4cccc5ccccc45)c3)c2)c2ccccc2-c2ccccc21 ; CC1(c2cccc(N(c3cccc(-c4cccc5ccccc45)c3)c3cccc4c3-c3ccccc3C4(C)c3ccccc3)c2)c2ccccc2-c2ccccc21]

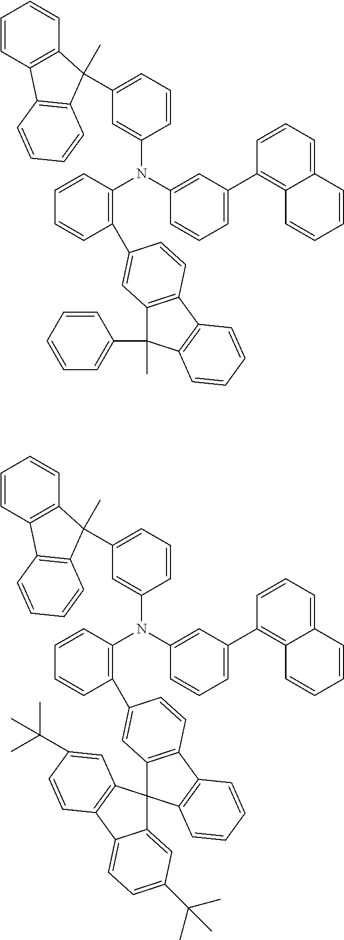 [SMILES: CC1(c2cccc(N(c3cccc(-c4cccc5ccccc45)c3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4cccc(-c5cccc6ccccc56)c4)c4cccc(C5(C)c6ccccc6-c6ccccc65)c4)cc31)c1cc(C(C)(C)C)ccc1-2]

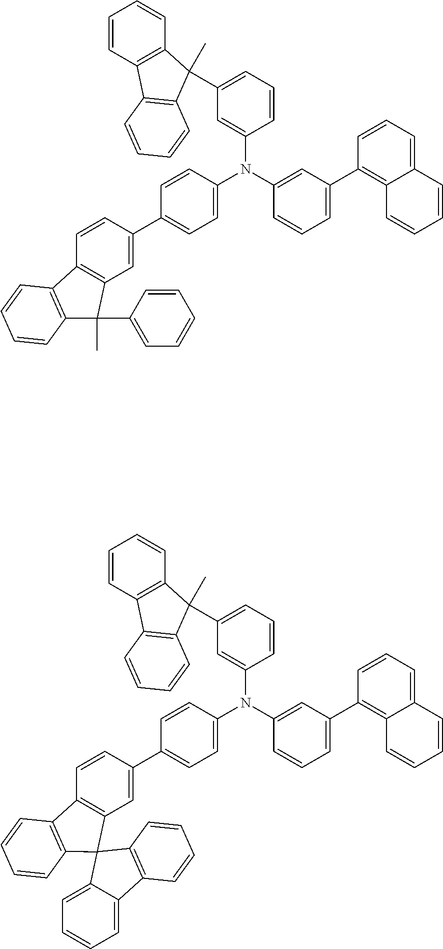 [SMILES: CC1(c2cccc(N(c3ccc(-c4ccc5c(c4)C(C)(c4ccccc4)c4ccccc4-5)cc3)c3cccc(-c4cccc5ccccc45)c3)c2)c2ccccc2-c2ccccc21 ; CC1(c2cccc(N(c3ccc(-c4ccc5c(c4)C4(c6ccccc6-c6ccccc64)c4ccccc4-5)cc3)c3cccc(-c4cccc5ccccc45)c3)c2)c2ccccc2-c2ccccc21]

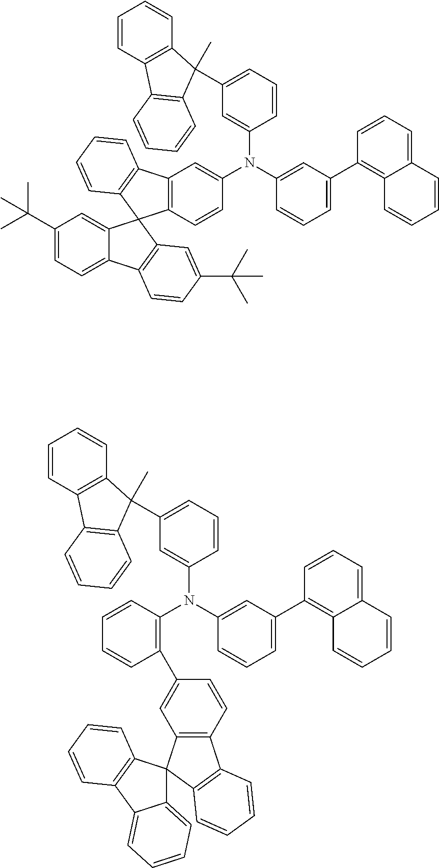 [SMILES: CC(C)(C)c1ccc2c(c1)C1(c3ccccc3-c3cc(N(c4cccc(-c5cccc6ccccc56)c4)c4cccc(C5(C)c6ccccc6-c6ccccc65)c4)ccc31)c1cc(C(C)(C)C)ccc1-2 ; CC1(c2cccc(N(c3cccc(-c4cccc5ccccc45)c3)c3ccccc3-c3ccc4c(c3)C3(c5ccccc5-c5ccccc53)c3ccccc3-4)c2)c2ccccc2-c2ccccc21]

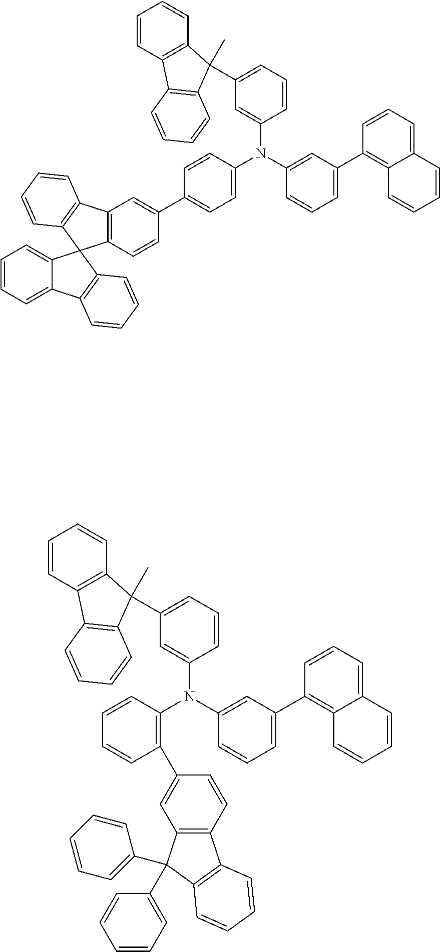 [SMILES: CC1(c2cccc(N(c3ccc(-c4ccc5c(c4)-c4ccccc4C54c5ccccc5-c5ccccc54)cc3)c3cccc(-c4cccc5ccccc45)c3)c2)c2ccccc2-c2ccccc21 ; CC1(c2cccc(N(c3cccc(-c4cccc5ccccc45)c3)c3ccccc3-c3ccc4c(c3)C(c3ccccc3)(c3ccccc3)c3ccccc3-4)c2)c2ccccc2-c2ccccc21]

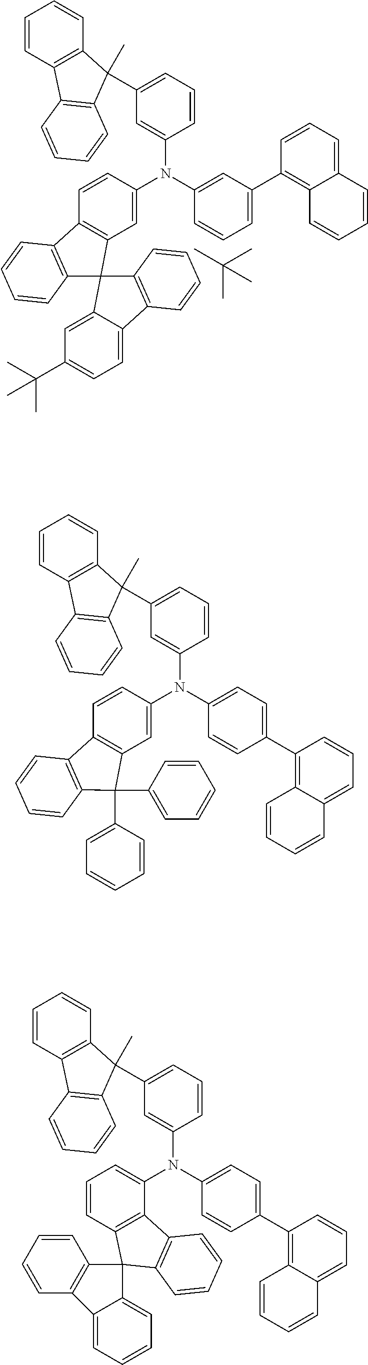

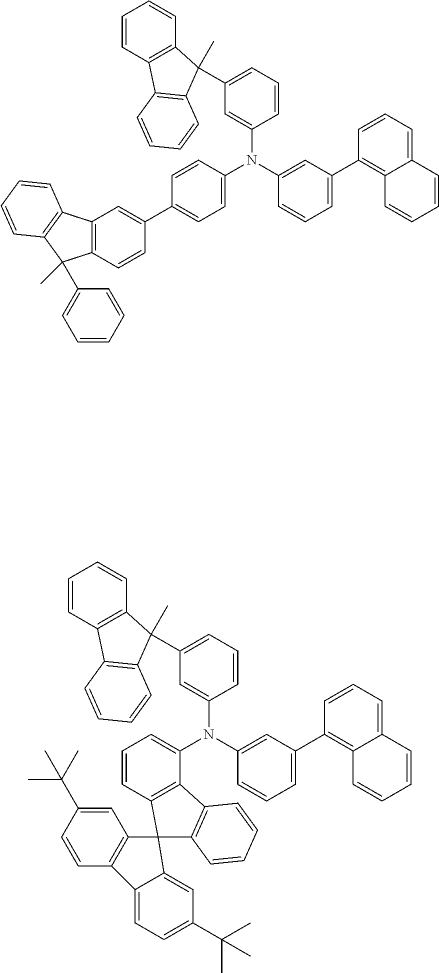 [SMILES: CC1(c2cccc(N(c3ccc(-c4ccc5c(c4)-c4ccccc4C5(C)c4ccccc4)cc3)c3cccc(-c4cccc5ccccc45)c3)c2)c2ccccc2-c2ccccc21 ; CC(C)(C)c1ccc2c(c1)C1(c3cc(C(C)(C)C)ccc3-2)c2ccccc2-c2c(N(c3cccc(-c4cccc5ccccc45)c3)c3cccc(C4(C)c5ccccc5-c5ccccc54)c3)cccc21]

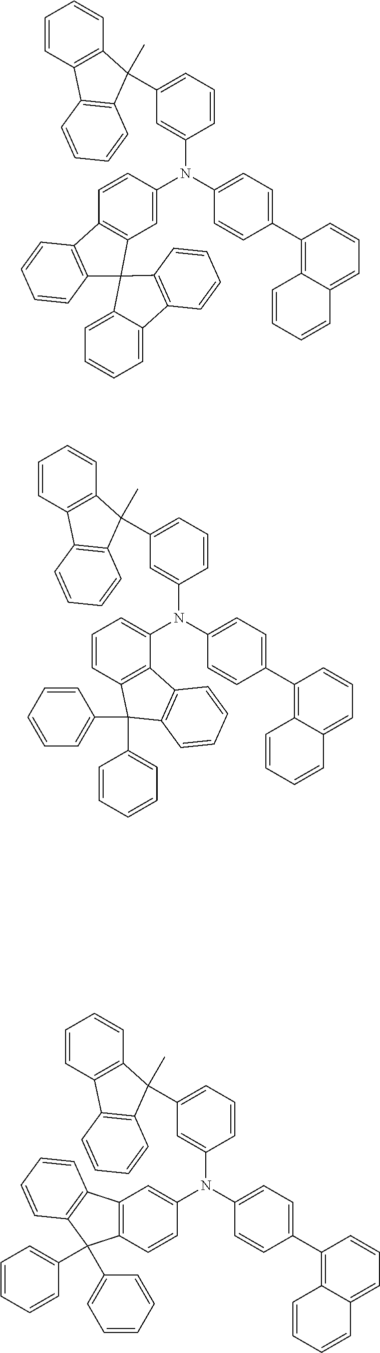 [SMILES: CC1(c2cccc(N(c3ccc(-c4cccc5ccccc45)cc3)c3ccc4c(c3)C3(c5ccccc5-c5ccccc53)c3ccccc3-4)c2)c2ccccc2-c2ccccc21 ; CC1(c2cccc(N(c3ccc(-c4cccc5ccccc45)cc3)c3cccc4c3-c3ccccc3C4(c3ccccc3)c3ccccc3)c2)c2ccccc2-c2ccccc21 ; CC1(c2cccc(N(c3ccc(-c4cccc5ccccc45)cc3)c3ccc4c(c3)-c3ccccc3C4(c3ccccc3)c3ccccc3)c2)c2ccccc2-c2ccccc21]

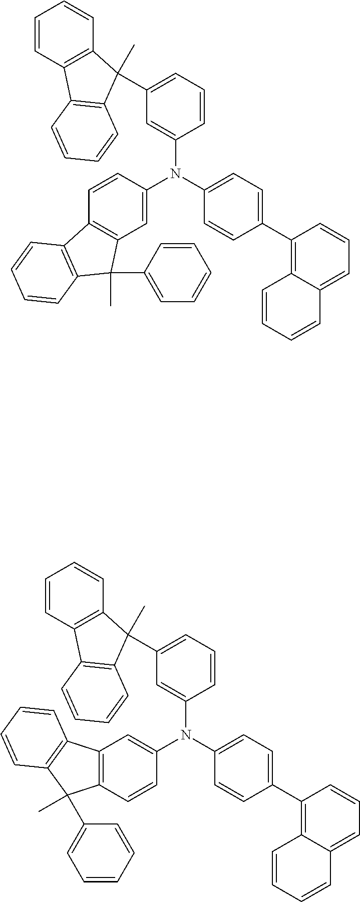 [SMILES: CC1(c2cccc(N(c3ccc(-c4cccc5ccccc45)cc3)c3ccc4c(c3)C(C)(c3ccccc3)c3ccccc3-4)c2)c2ccccc2-c2ccccc21 ; CC1(c2cccc(N(c3ccc(-c4cccc5ccccc45)cc3)c3ccc4c(c3)-c3ccccc3C4(C)c3ccccc3)c2)c2ccccc2-c2ccccc21]

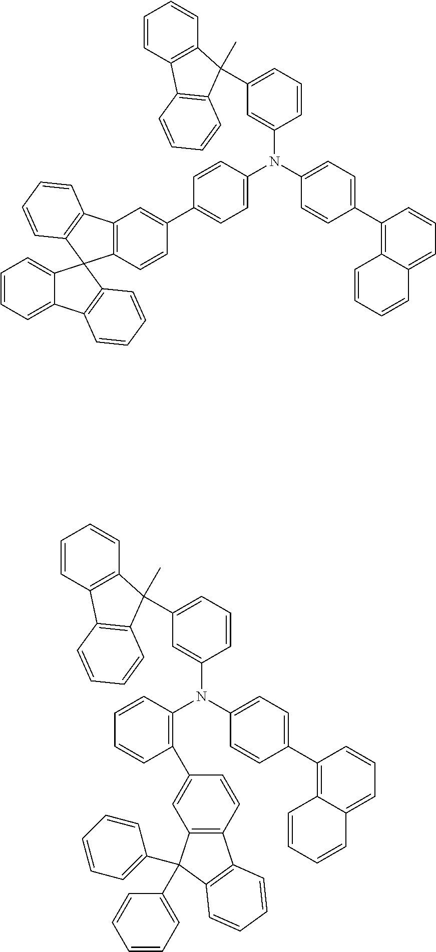 [SMILES: CC1(c2cccc(N(c3ccc(-c4ccc5c(c4)-c4ccccc4C54c5ccccc5-c5ccccc54)cc3)c3ccc(-c4cccc5ccccc45)cc3)c2)c2ccccc2-c2ccccc21 ; CC1(c2cccc(N(c3ccc(-c4cccc5ccccc45)cc3)c3ccccc3-c3ccc4c(c3)C(c3ccccc3)(c3ccccc3)c3ccccc3-4)c2)c2ccccc2-c2ccccc21]

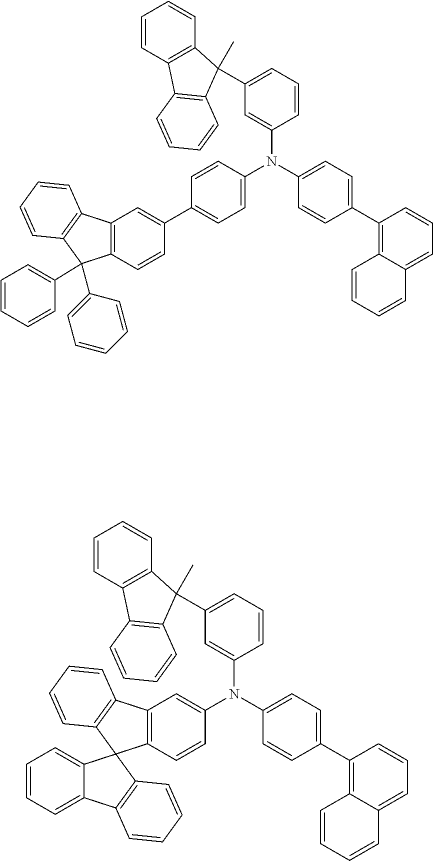 [SMILES: CC1(c2cccc(N(c3ccc(-c4ccc5c(c4)-c4ccccc4C5(c4ccccc4)c4ccccc4)cc3)c3ccc(-c4cccc5ccccc45)cc3)c2)c2ccccc2-c2ccccc21 ; CC1(c2cccc(N(c3ccc(-c4cccc5ccccc45)cc3)c3ccc4c(c3)-c3ccccc3C43c4ccccc4-c4ccccc43)c2)c2ccccc2-c2ccccc21]

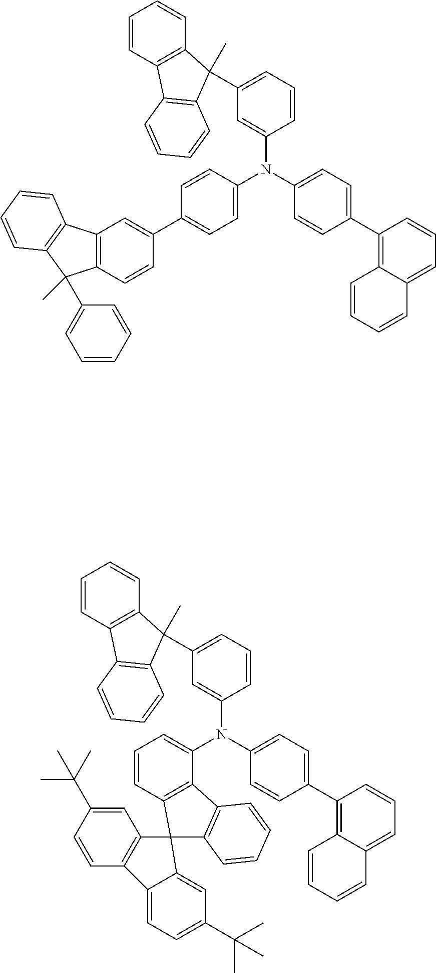 [SMILES: CC1(c2cccc(N(c3ccc(-c4ccc5c(c4)-c4ccccc4C5(C)c4ccccc4)cc3)c3ccc(-c4cccc5ccccc45)cc3)c2)c2ccccc2-c2ccccc21 ; CC(C)(C)c1ccc2c(c1)C1(c3cc(C(C)(C)C)ccc3-2)c2ccccc2-c2c(N(c3ccc(-c4cccc5ccccc45)cc3)c3cccc(C4(C)c5ccccc5-c5ccccc54)c3)cccc21]

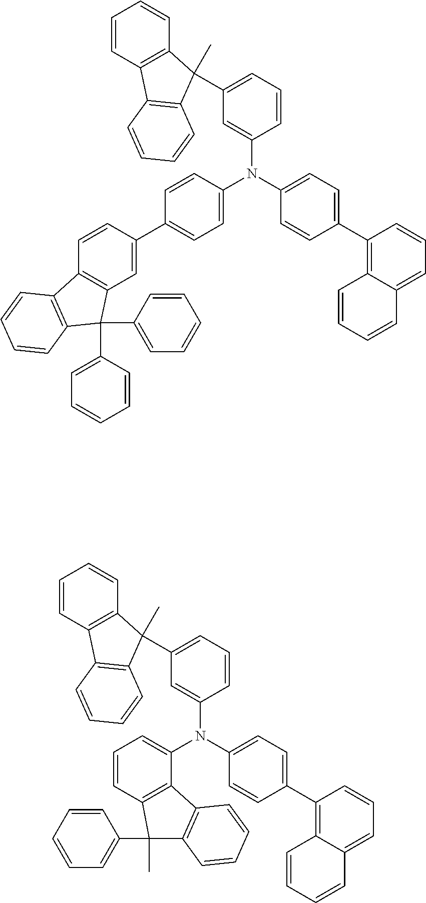 [SMILES: CC1(c2cccc(N(c3ccc(-c4ccc5c(c4)C(c4ccccc4)(c4ccccc4)c4ccccc4-5)cc3)c3ccc(-c4cccc5ccccc45)cc3)c2)c2ccccc2-c2ccccc21 ; CC1(c2cccc(N(c3ccc(-c4cccc5ccccc45)cc3)c3cccc4c3-c3ccccc3C4(C)c3ccccc3)c2)c2ccccc2-c2ccccc21]

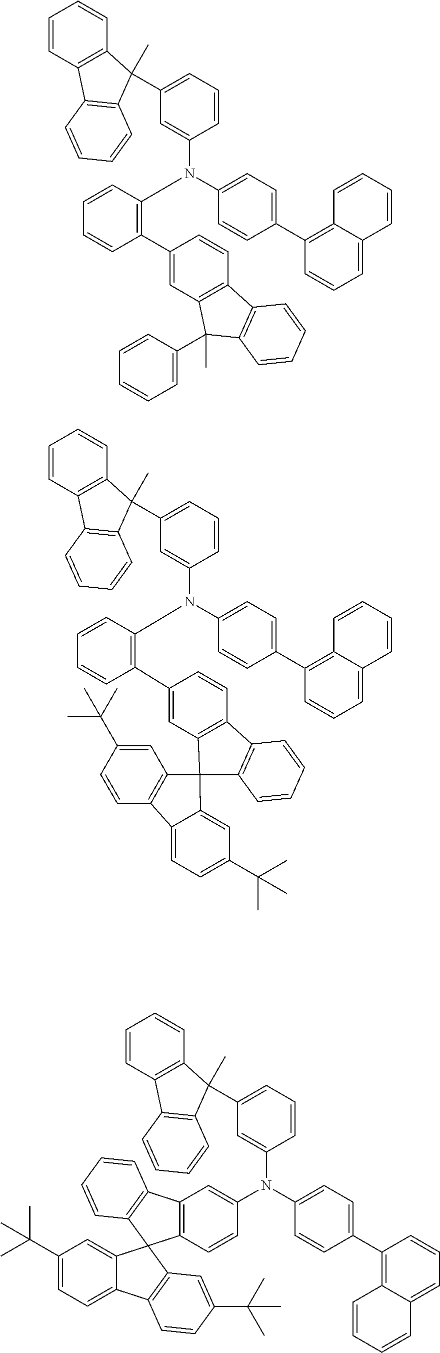 [SMILES: CC1(c2cccc(N(c3ccc(-c4cccc5ccccc45)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4ccc(-c5cccc6ccccc56)cc4)c4cccc(C5(C)c6ccccc6-c6ccccc65)c4)cc31)c1cc(C(C)(C)C)ccc1-2 ; CC(C)(C)c1ccc2c(c1)C1(c3ccccc3-c3cc(N(c4ccc(-c5cccc6ccccc56)cc4)c4cccc(C5(C)c6ccccc6-c6ccccc65)c4)ccc31)c1cc(C(C)(C)C)ccc1-2]

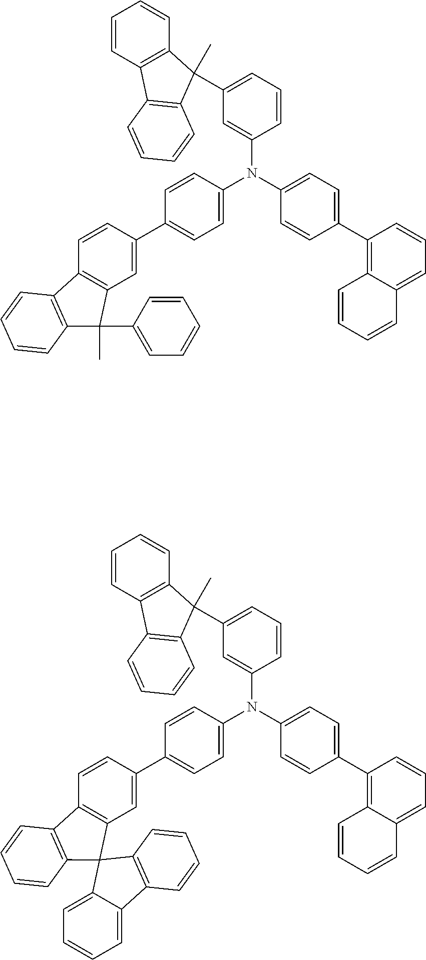 [SMILES: CC1(c2cccc(N(c3ccc(-c4ccc5c(c4)C(C)(c4ccccc4)c4ccccc4-5)cc3)c3ccc(-c4cccc5ccccc45)cc3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccc(-c4cccc5ccccc45)cc3)c2)c2ccccc2-c2ccccc21]

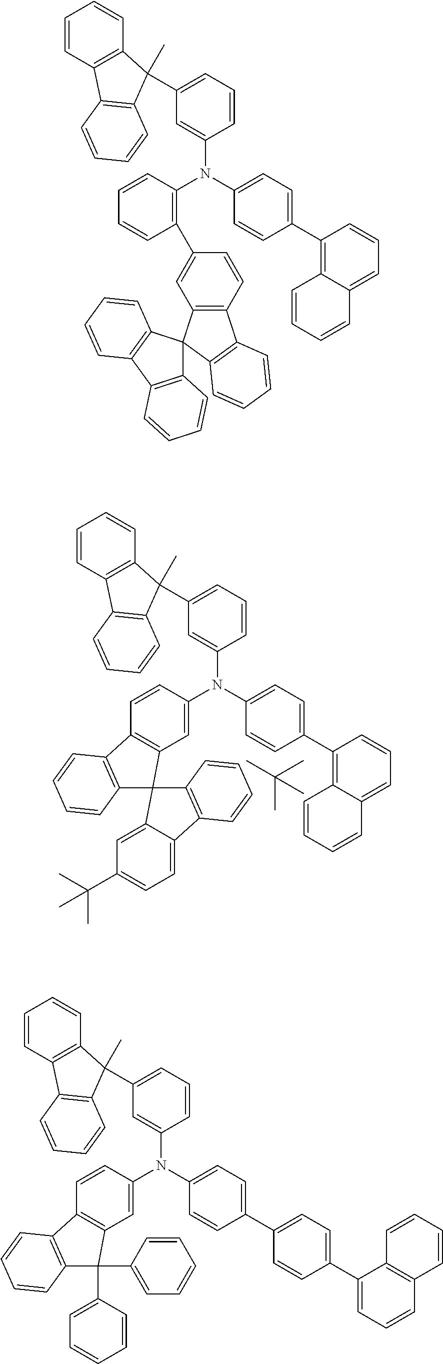

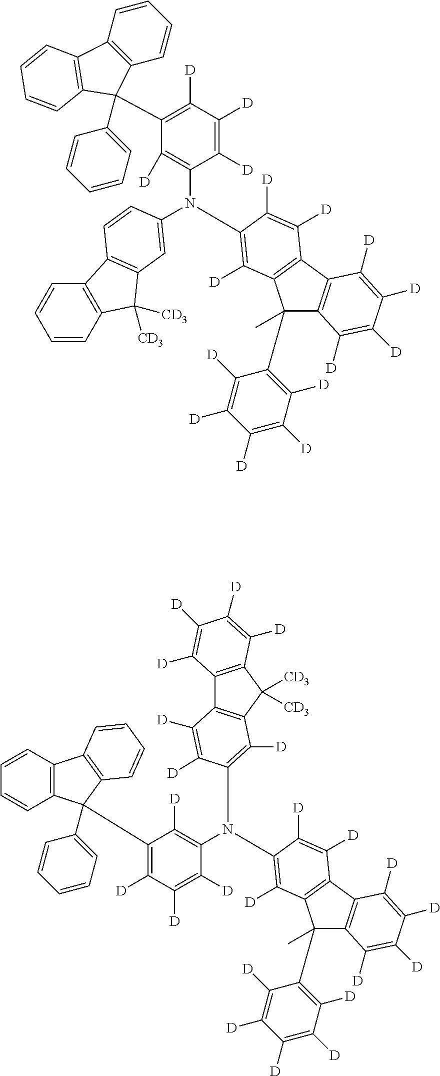 [SMILES: [2H]c1c([2H])c([2H])c(C2(C)c3c([2H])c([2H])c([2H])c([2H])c3-c3c([2H])c([2H])c(N(c4ccc5c(c4)C(C([2H])([2H])[2H])(C([2H])([2H])[2H])c4ccccc4-5)c4c([2H])c([2H])c([2H])c(C5(c6ccccc6)c6ccccc6-c6ccccc65)c4[2H])c([2H])c32)c([2H])c1[2H] ; [2H]c1c([2H])c([2H])c(C2(C)c3c([2H])c([2H])c([2H])c([2H])c3-c3c([2H])c([2H])c(N(c4c([2H])c([2H])c([2H])c(C5(c6ccccc6)c6ccccc6-c6ccccc65)c4[2H])c4c([2H])c([2H])c5c(c4[2H])C(C([2H])([2H])[2H])(C([2H])([2H])[2H])c4c([2H])c([2H])c([2H])c([2H])c4-5)c([2H])c32)c([2H])c1[2H]]

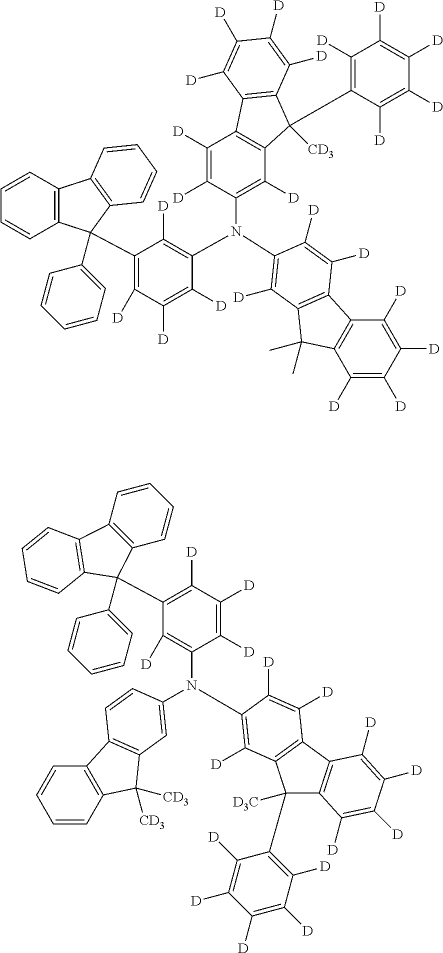 [SMILES: [2H]c1c([2H])c([2H])c(C2(C([2H])([2H])[2H])c3c([2H])c([2H])c([2H])c([2H])c3-c3c([2H])c([2H])c(N(c4c([2H])c([2H])c5c(c4[2H])C(C)(C)c4c([2H])c([2H])c([2H])c([2H])c4-5)c4c([2H])c([2H])c([2H])c(C5(c6ccccc6)c6ccccc6-c6ccccc65)c4[2H])c([2H])c32)c([2H])c1[2H] ; [2H]c1c([2H])c([2H])c(C2(C([2H])([2H])[2H])c3c([2H])c([2H])c([2H])c([2H])c3-c3c([2H])c([2H])c(N(c4ccc5c(c4)C(C([2H])([2H])[2H])(C([2H])([2H])[2H])c4ccccc4-5)c4c([2H])c([2H])c([2H])c(C5(c6ccccc6)c6ccccc6-c6ccccc65)c4[2H])c([2H])c32)c([2H])c1[2H]]

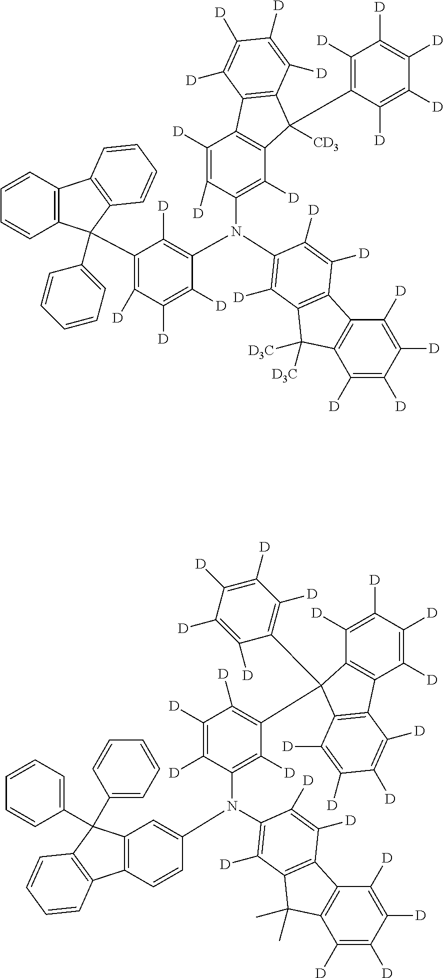

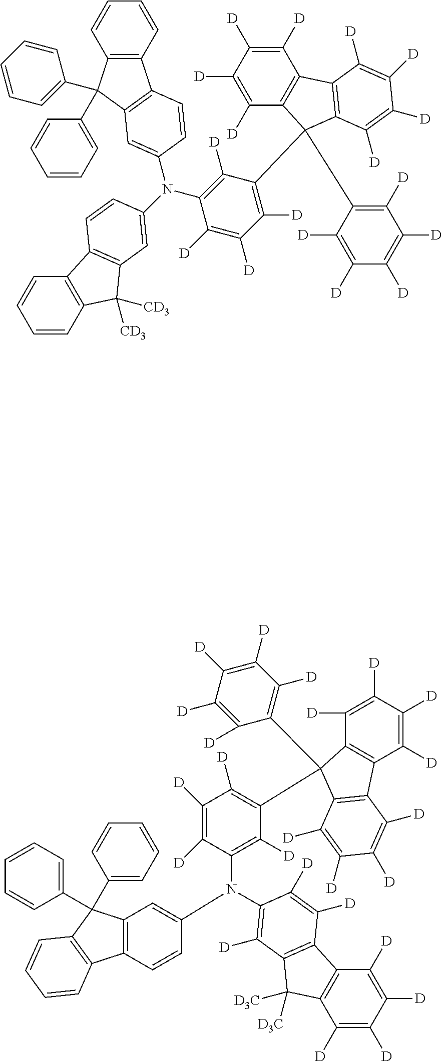

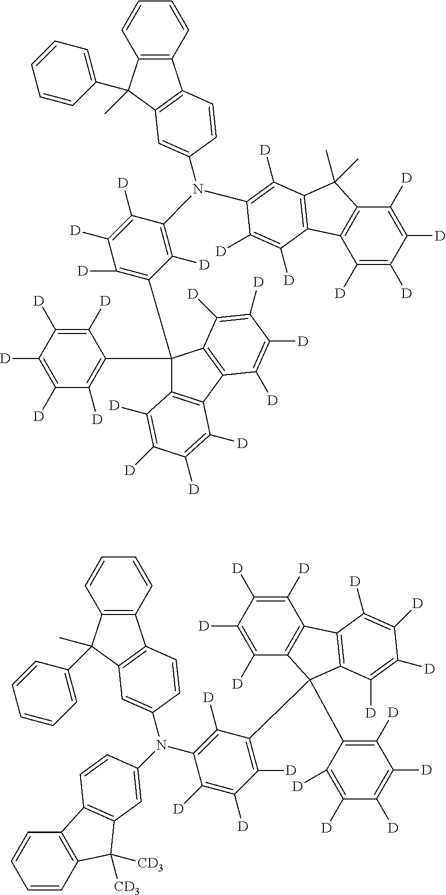 [SMILES: [2H]c1c([2H])c([2H])c(C2(c3c([2H])c([2H])c([2H])c(N(c4ccc5c(c4)C(C)(c4ccccc4)c4ccccc4-5)c4c([2H])c([2H])c5c(c4[2H])C(C)(C)c4c([2H])c([2H])c([2H])c([2H])c4-5)c3[2H])c3c([2H])c([2H])c([2H])c([2H])c3-c3c([2H])c([2H])c([2H])c([2H])c32)c([2H])c1[2H] ; [2H]c1c([2H])c([2H])c(C2(c3c([2H])c([2H])c([2H])c(N(c4ccc5c(c4)C(C)(c4ccccc4)c4ccccc4-5)c4ccc5c(c4)C(C([2H])([2H])[2H])(C([2H])([2H])[2H])c4ccccc4-5)c3[2H])c3c([2H])c([2H])c([2H])c([2H])c3-c3c([2H])c([2H])c([2H])c([2H])c32)c([2H])c1[2H]]

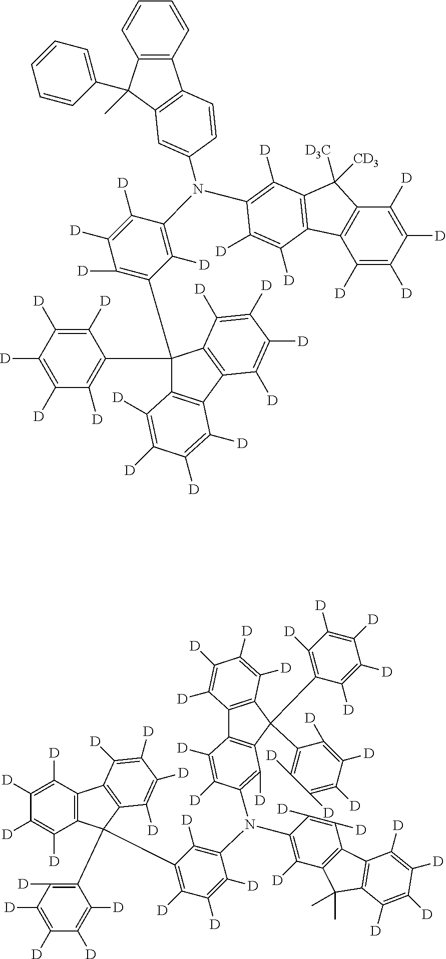

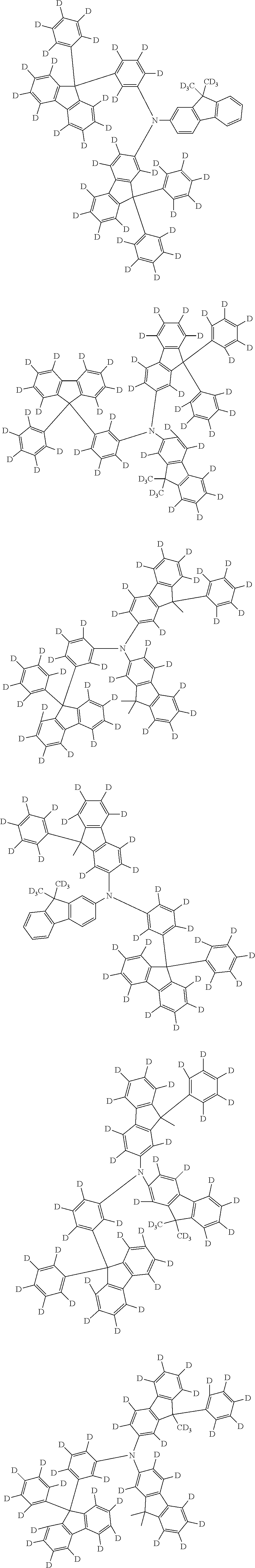

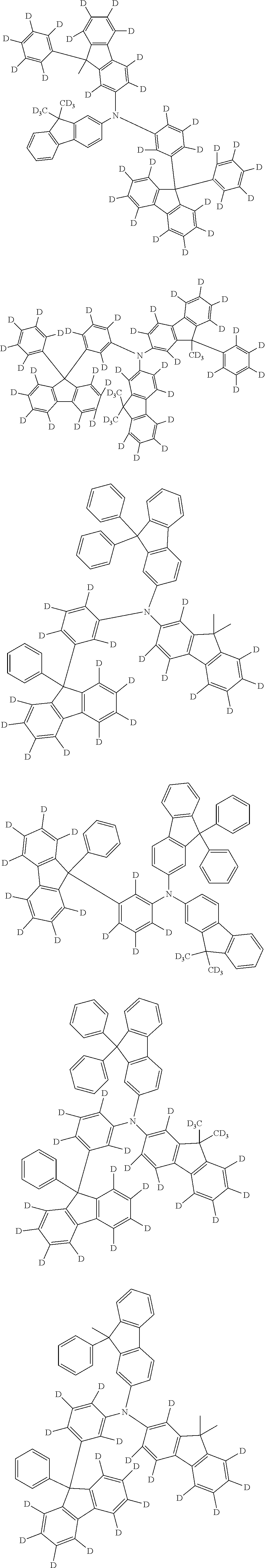

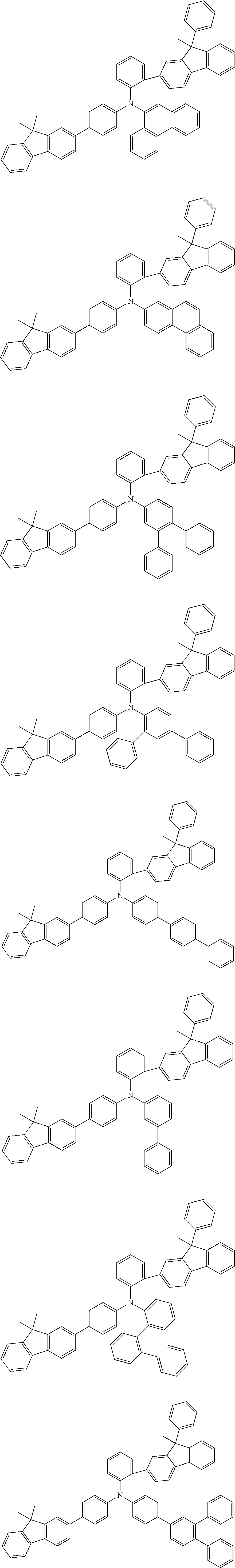

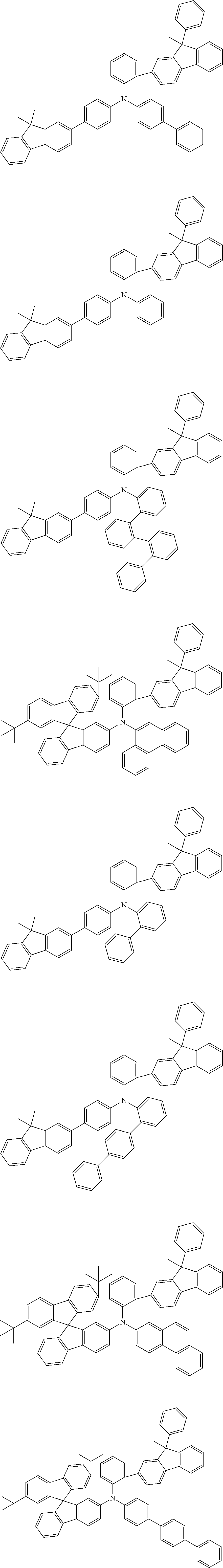

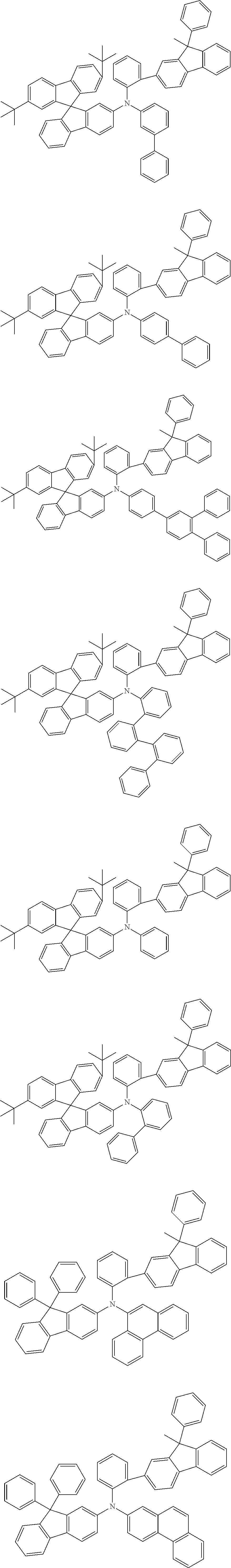

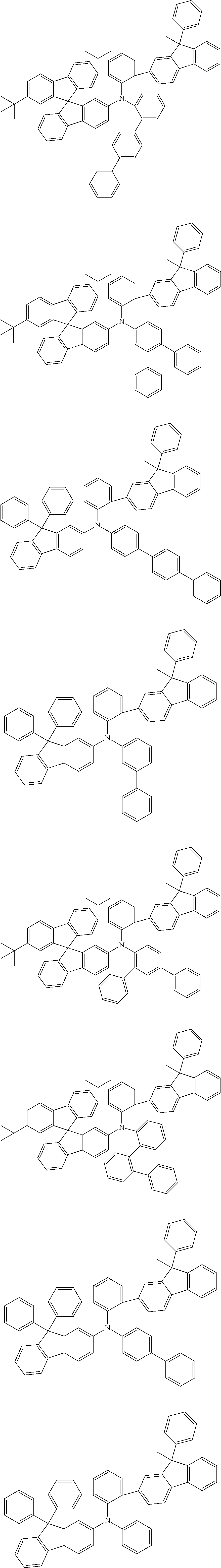

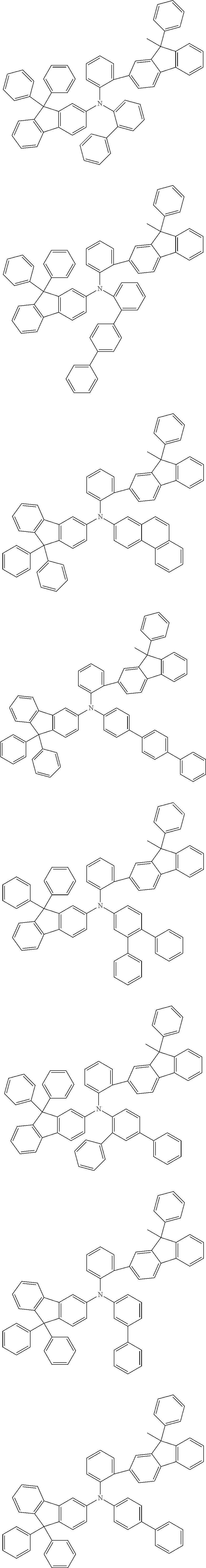

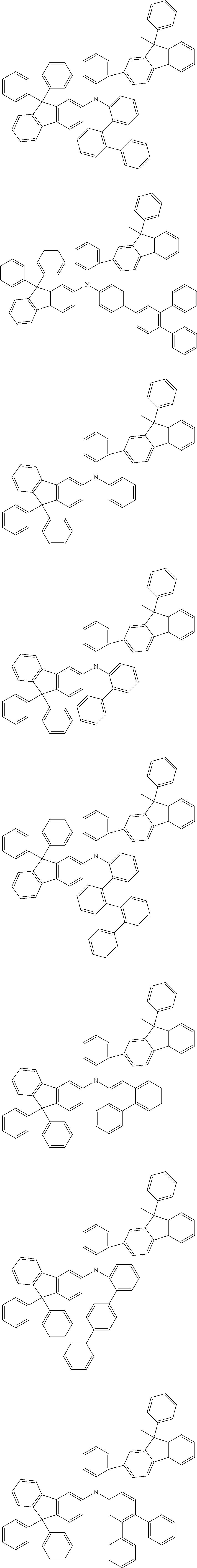

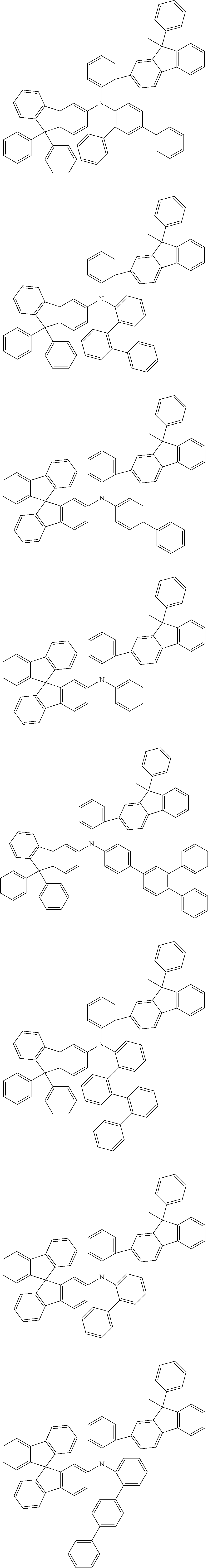

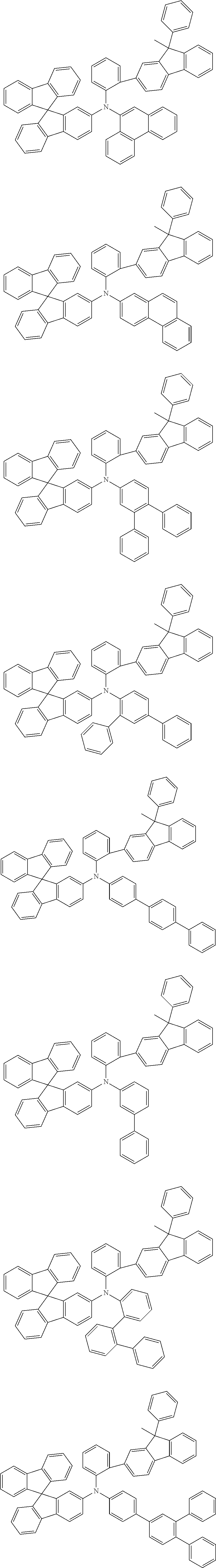

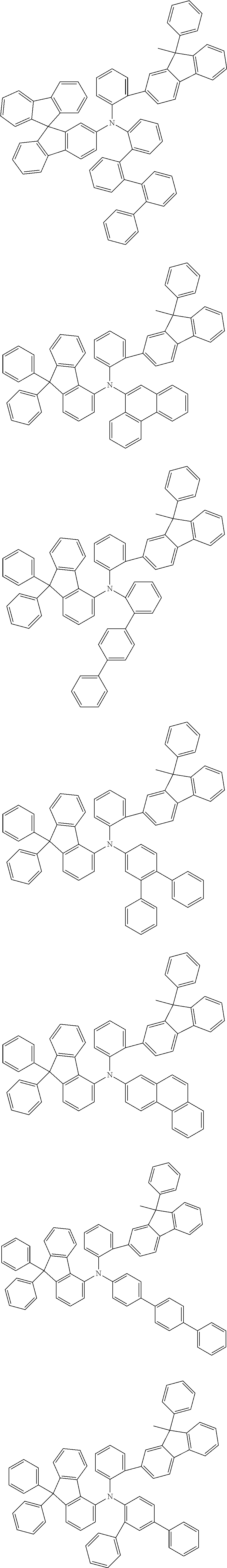

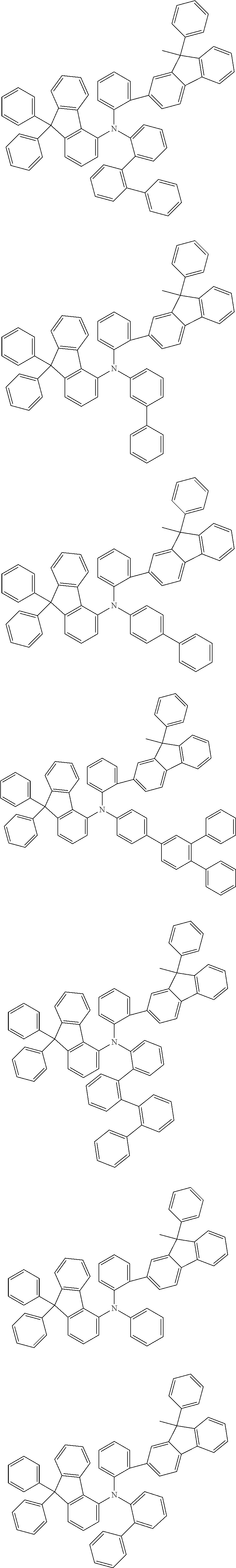

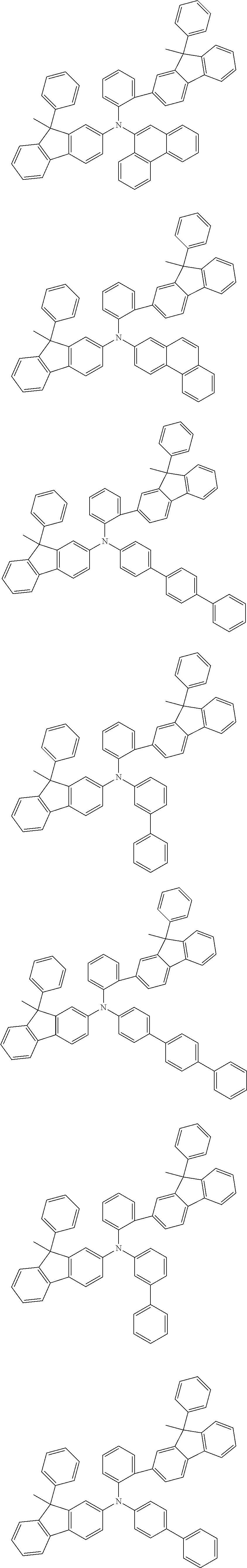

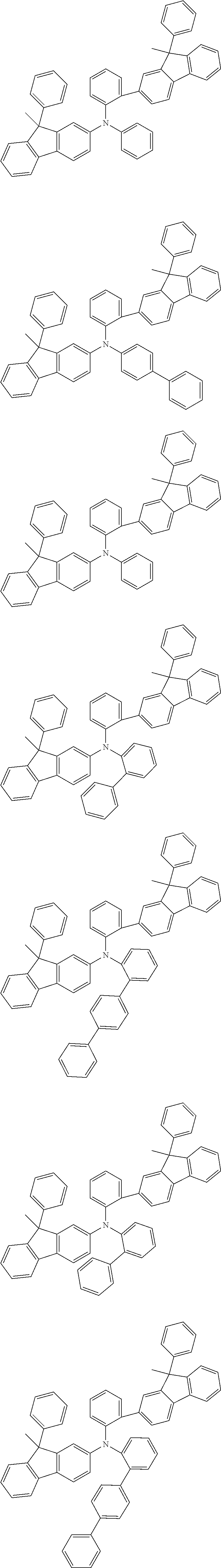

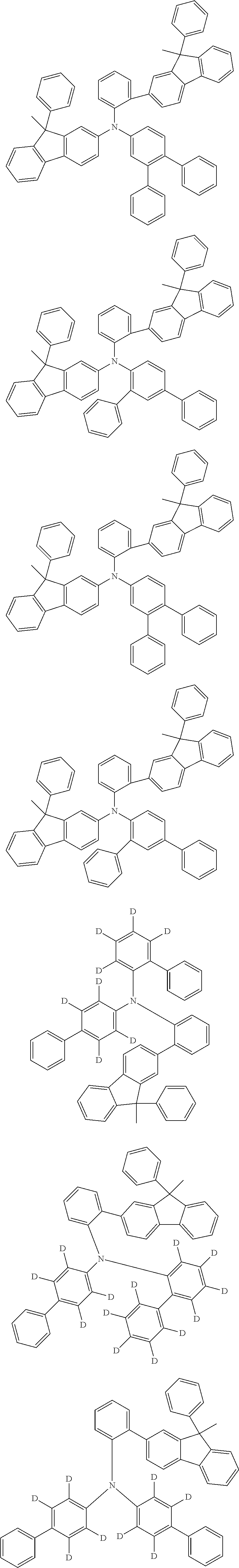

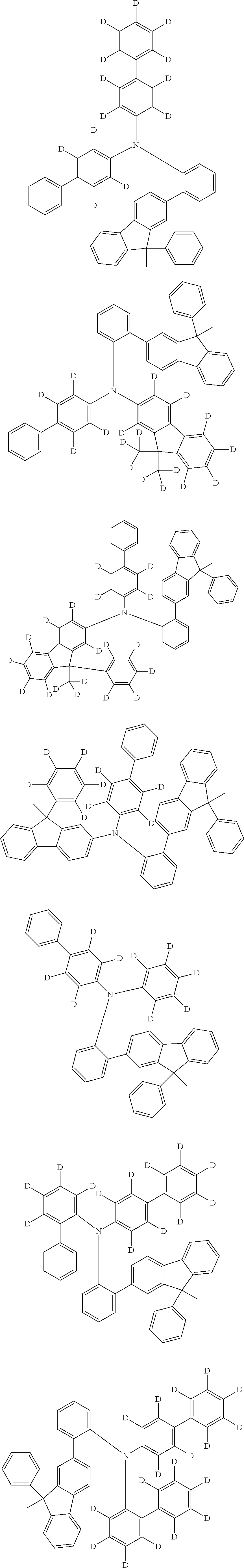

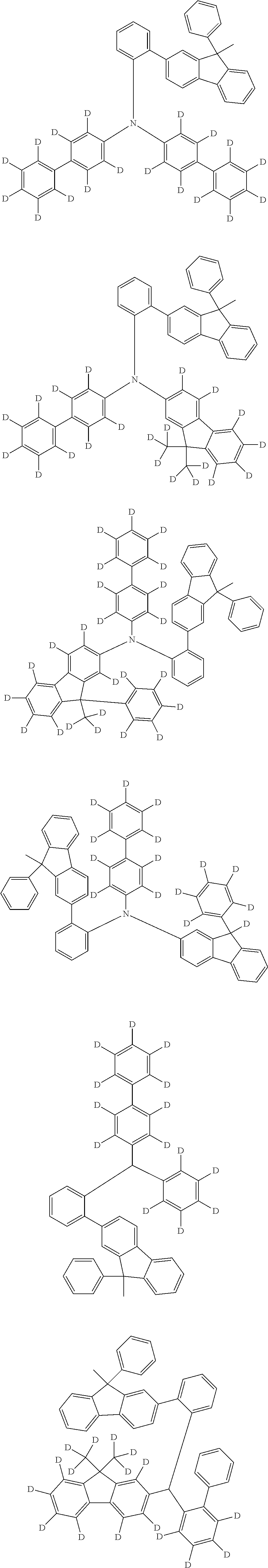

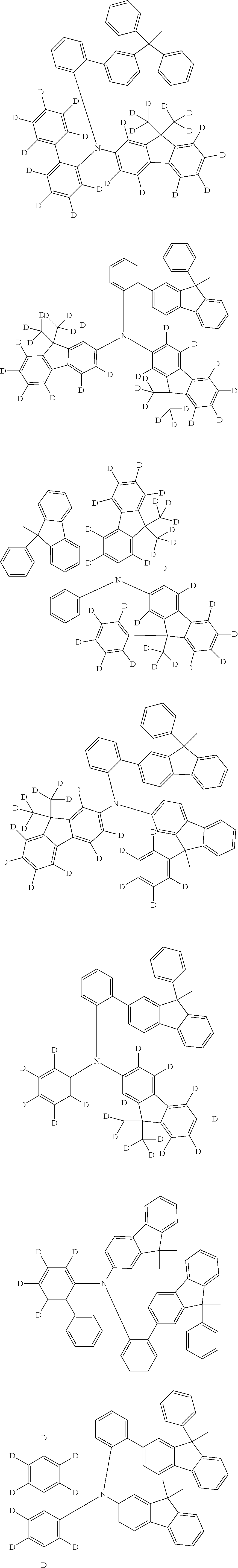

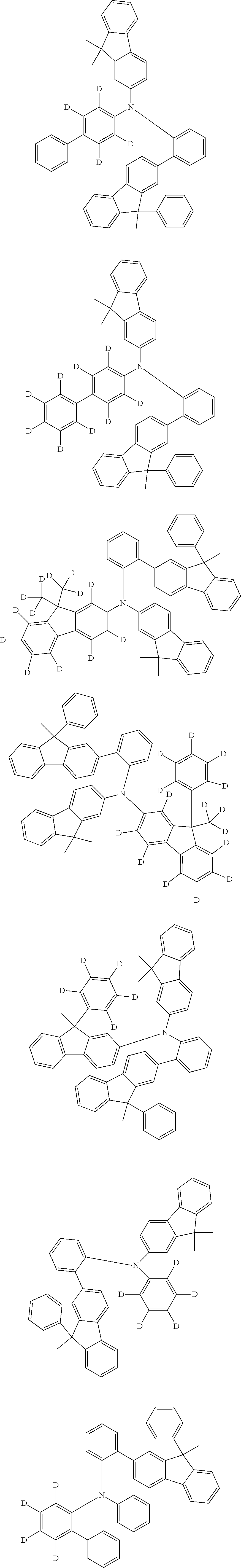

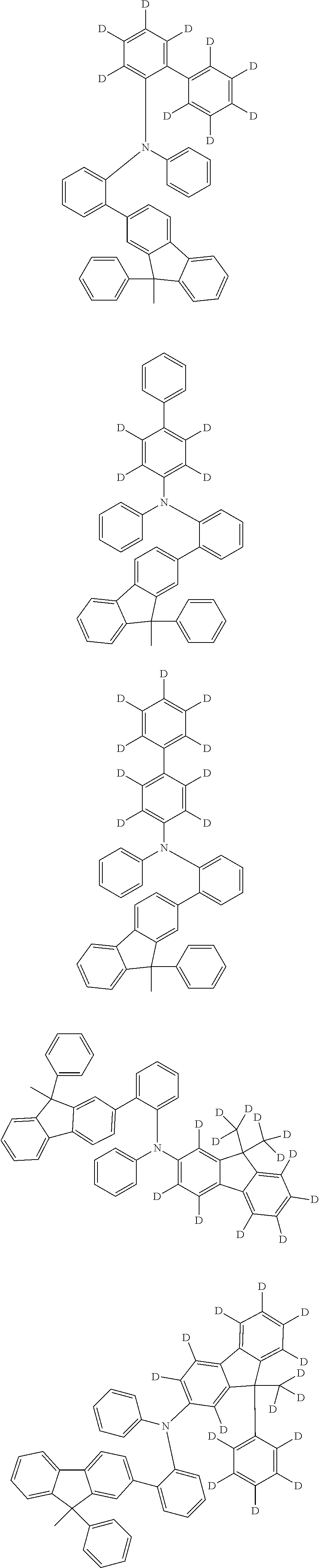

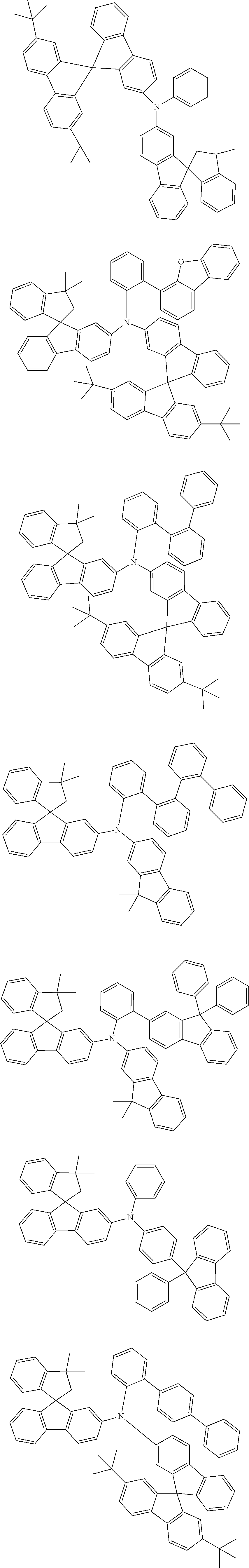

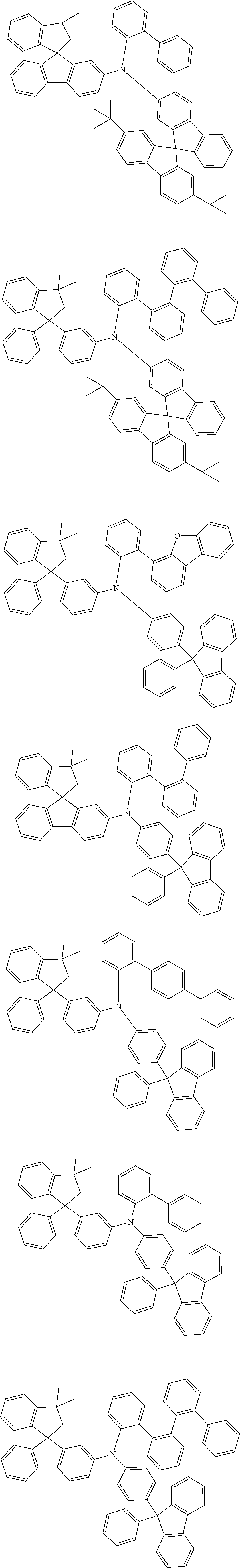

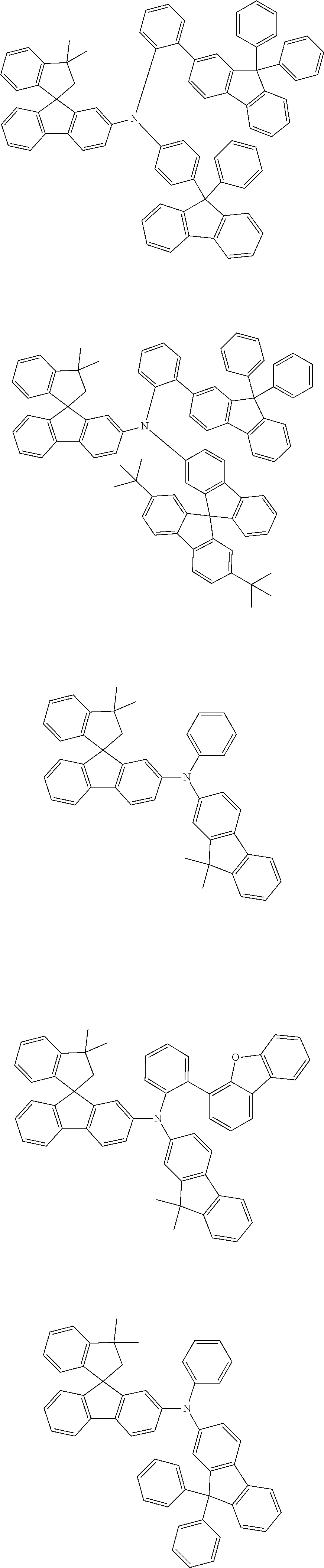

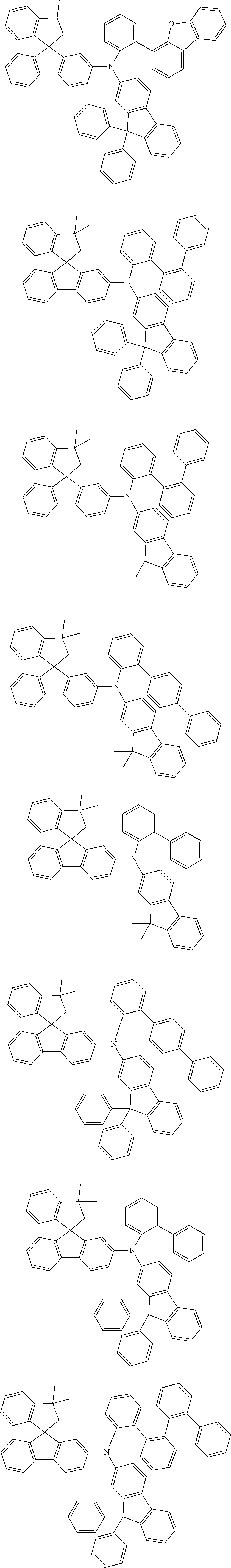

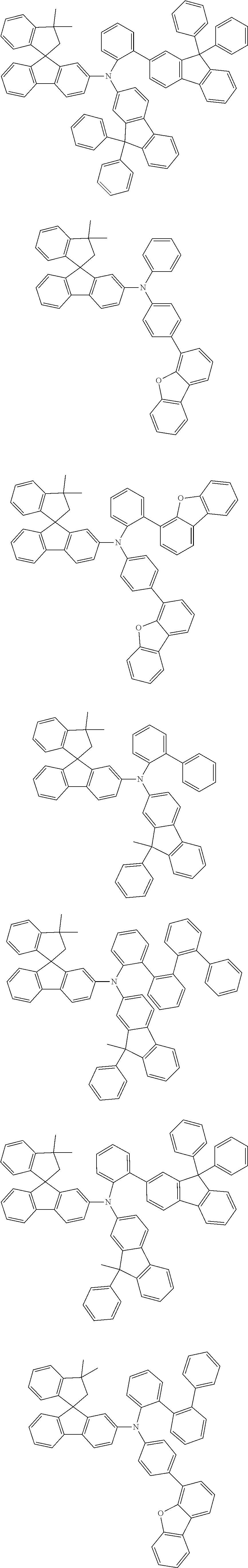

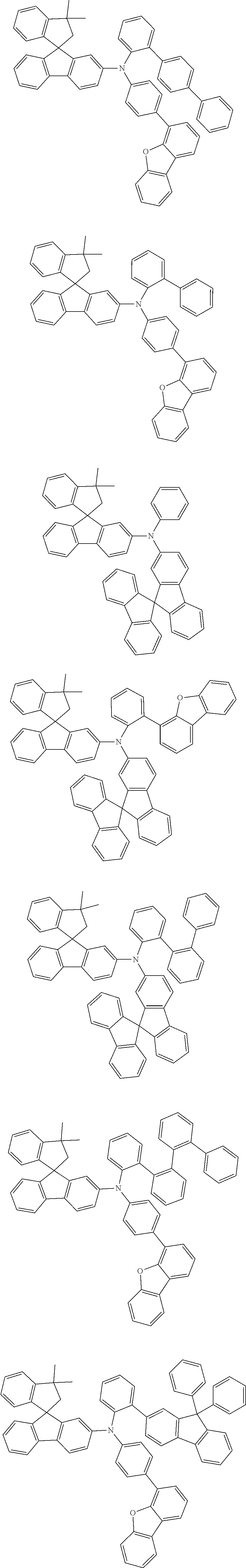

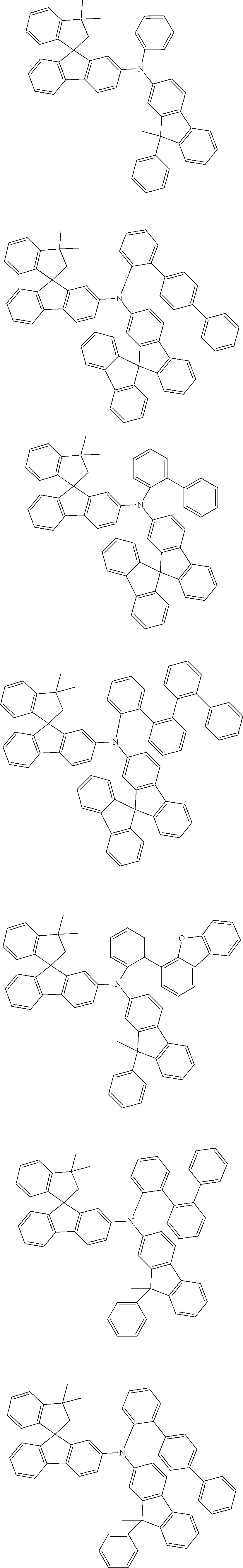

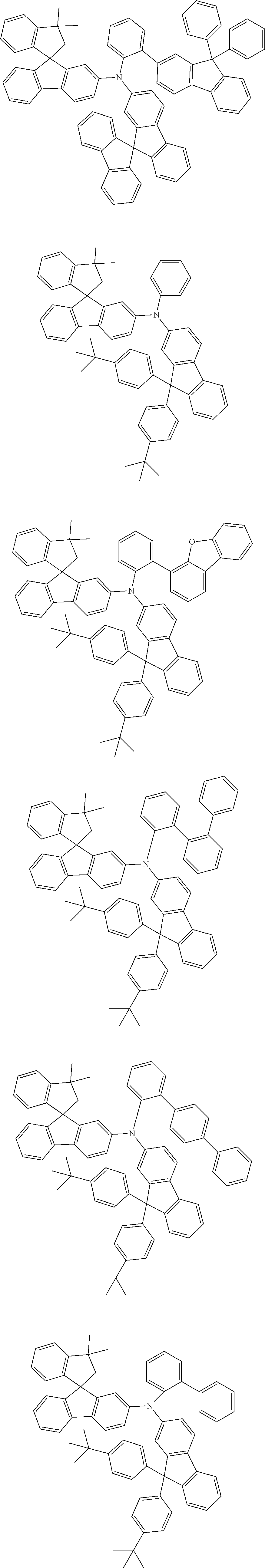

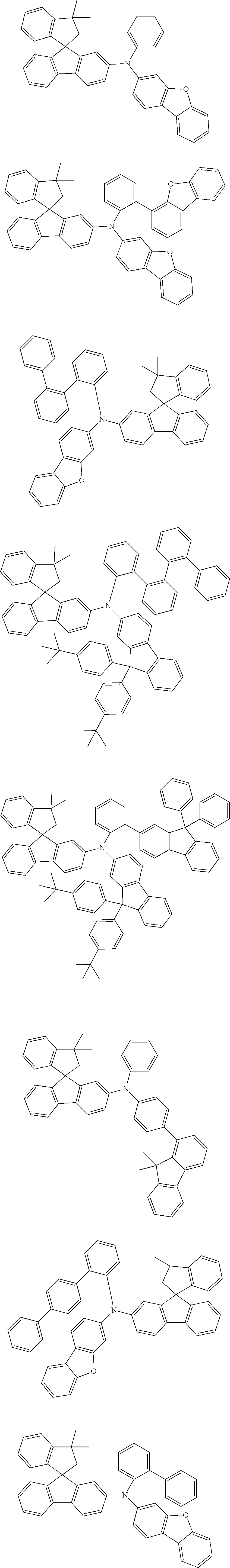

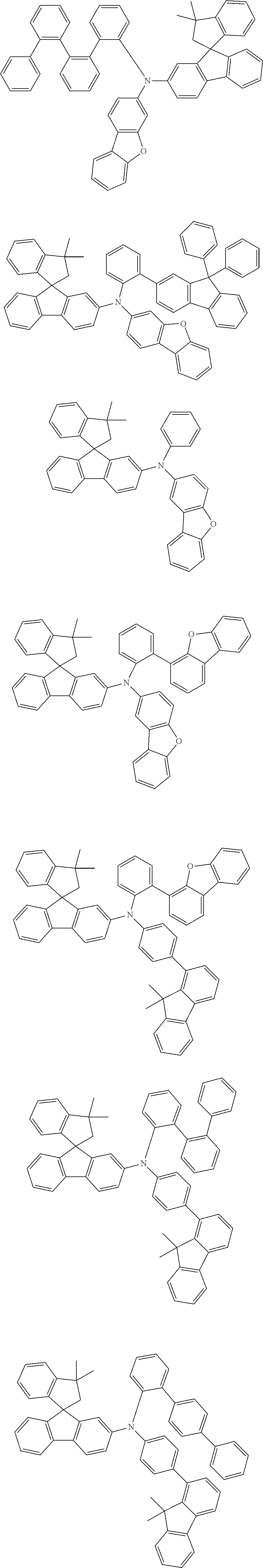

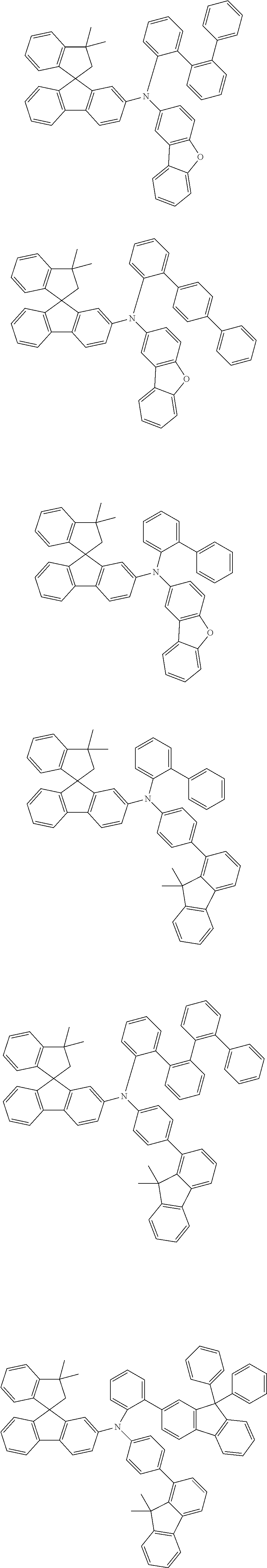

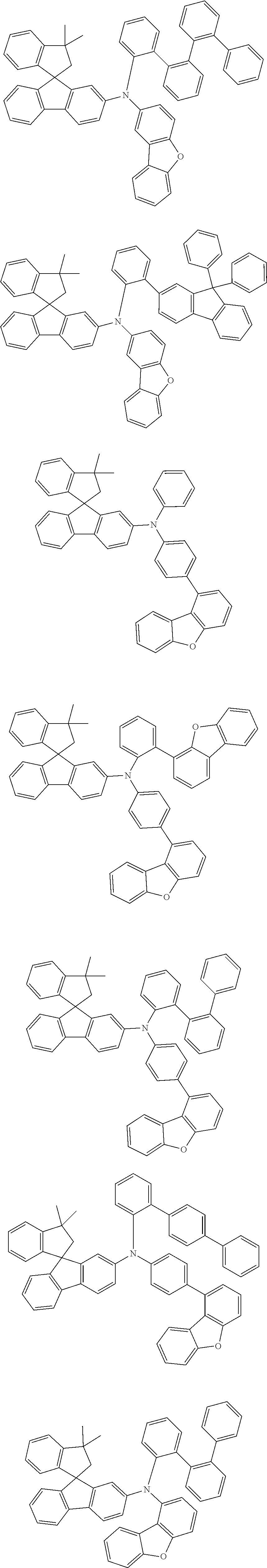

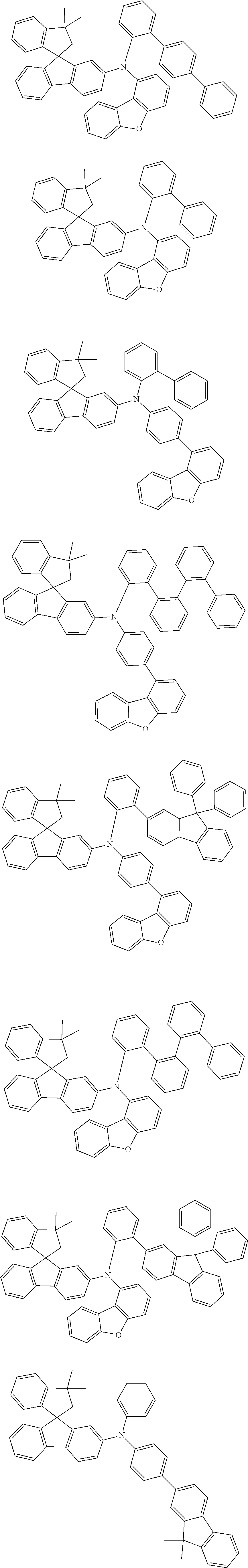

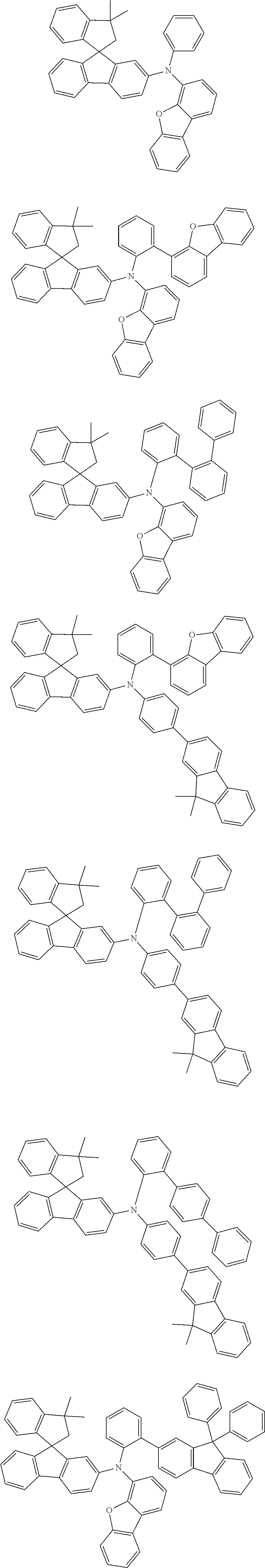

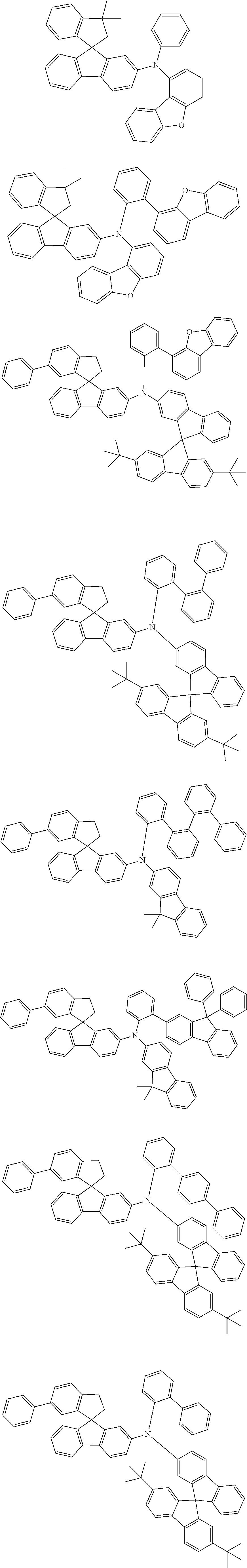

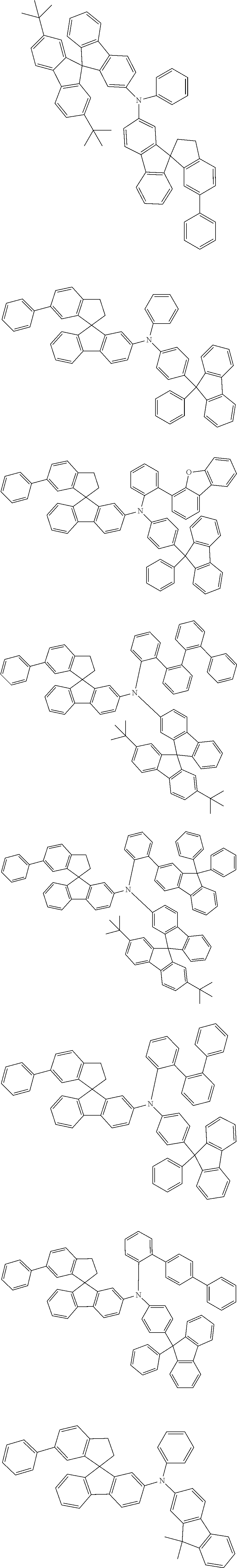

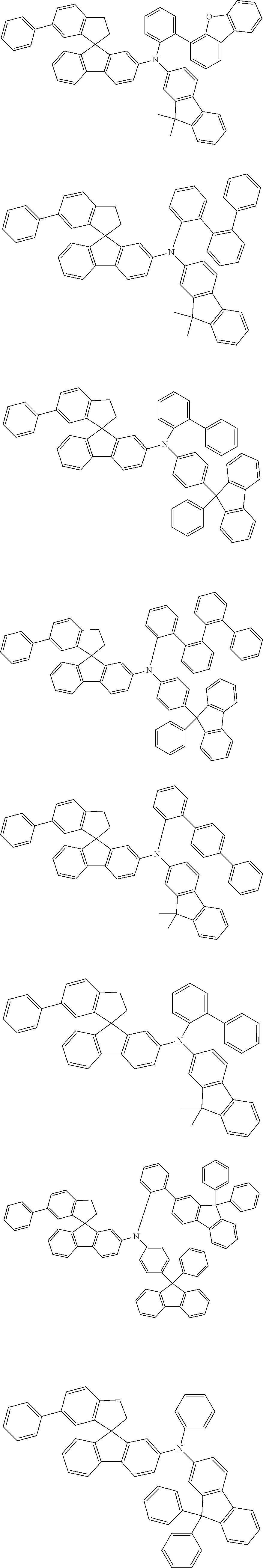

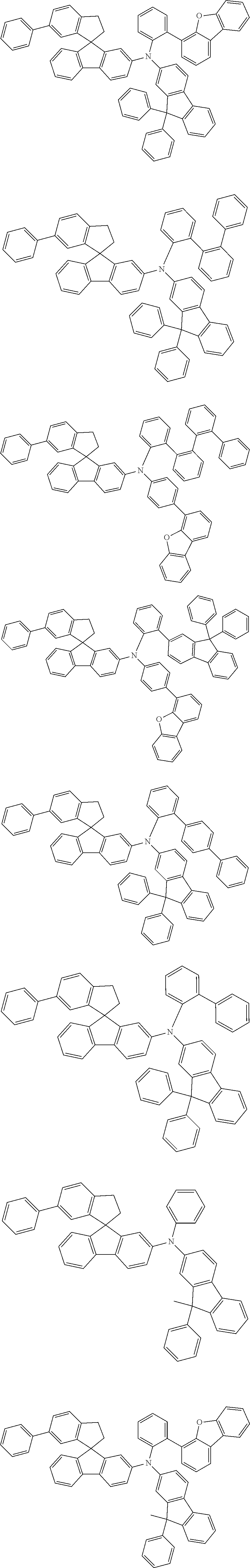

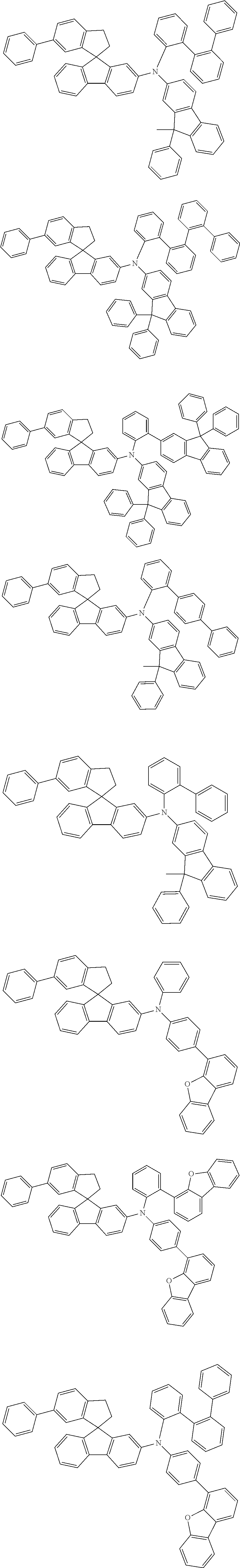

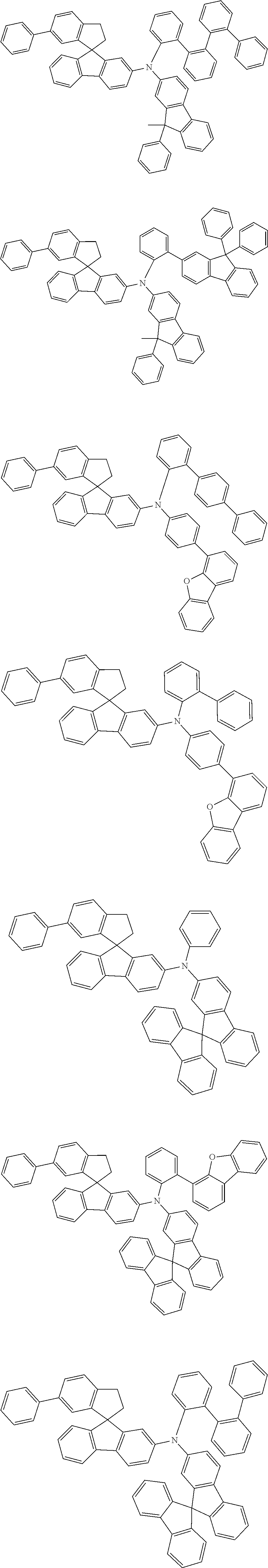

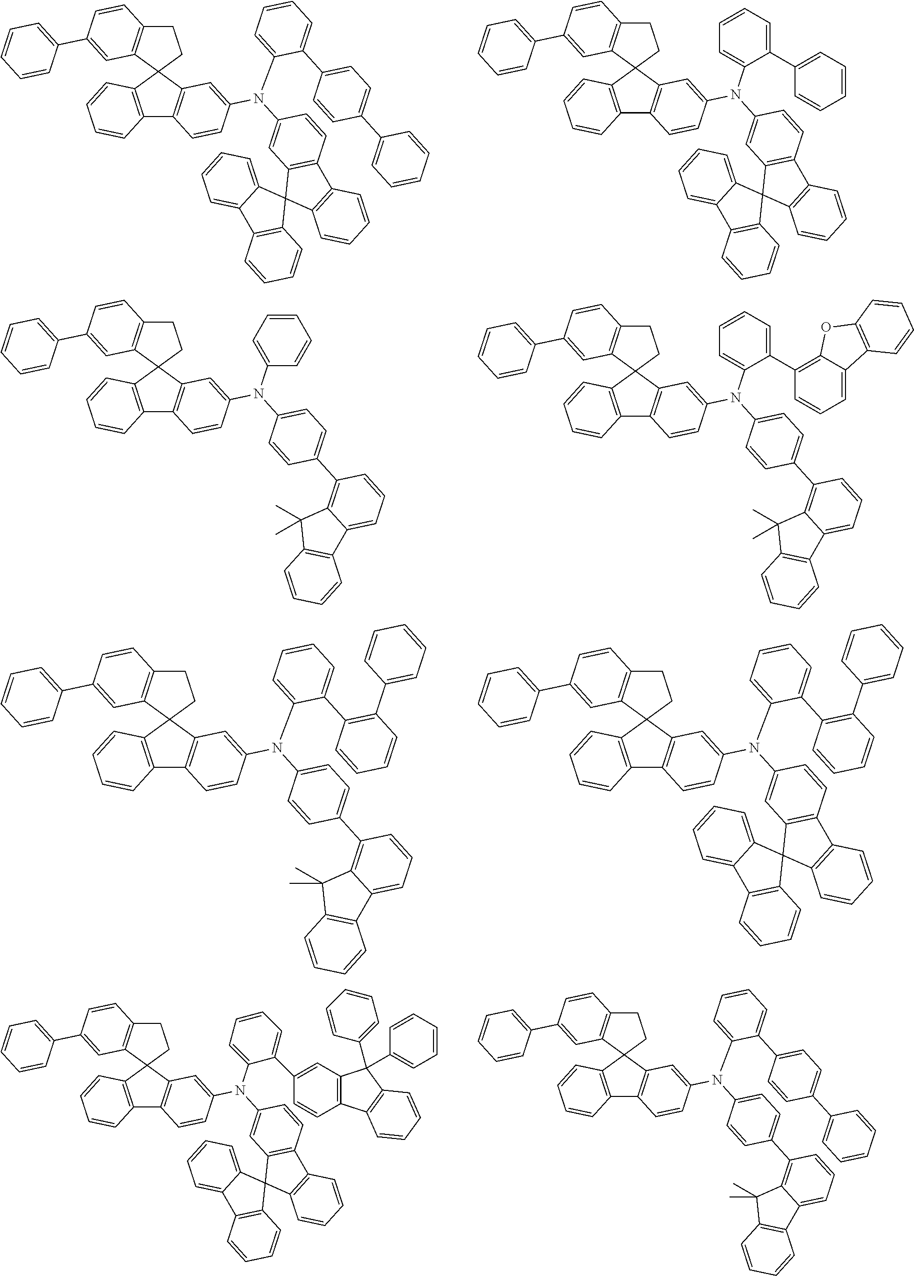

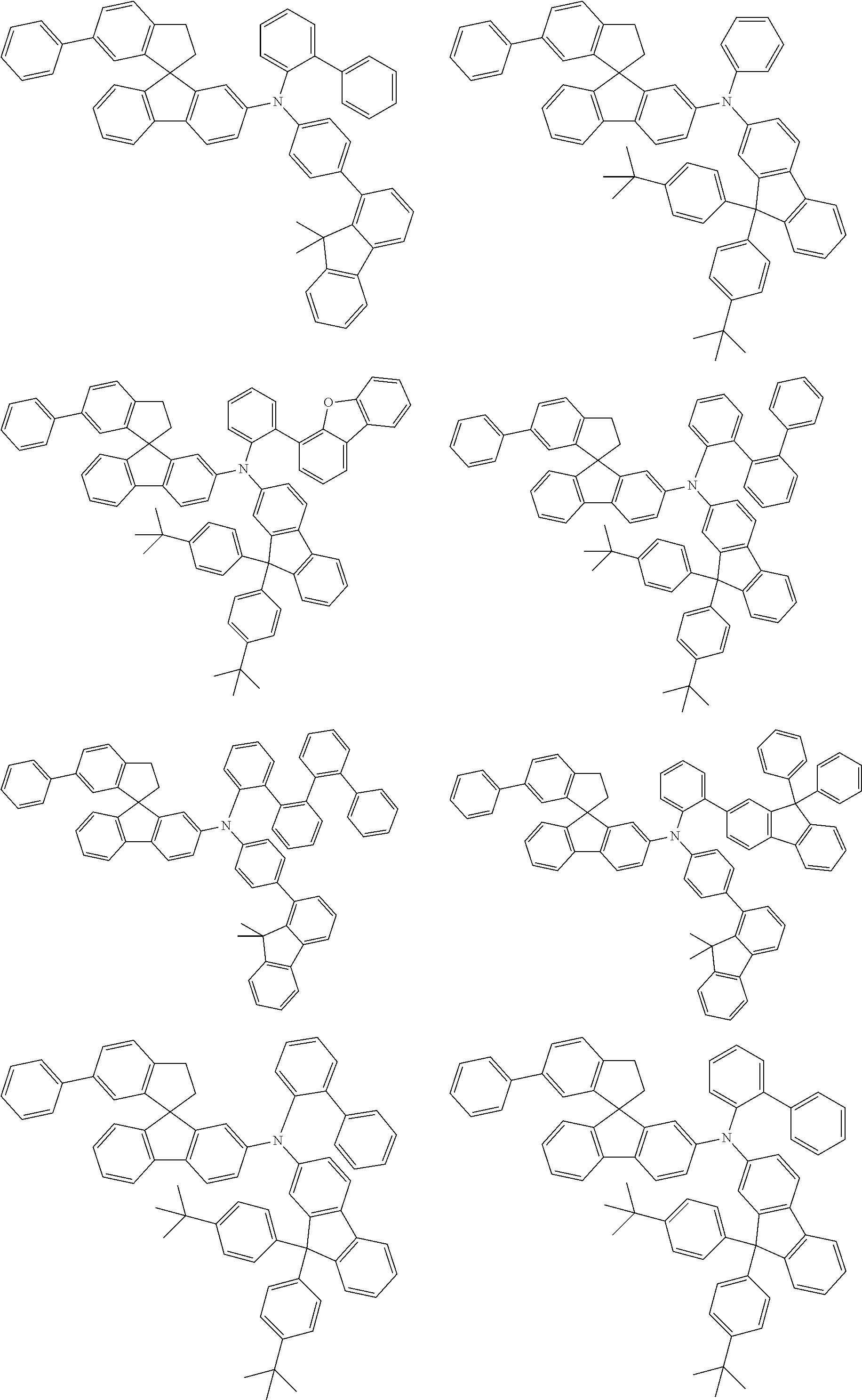

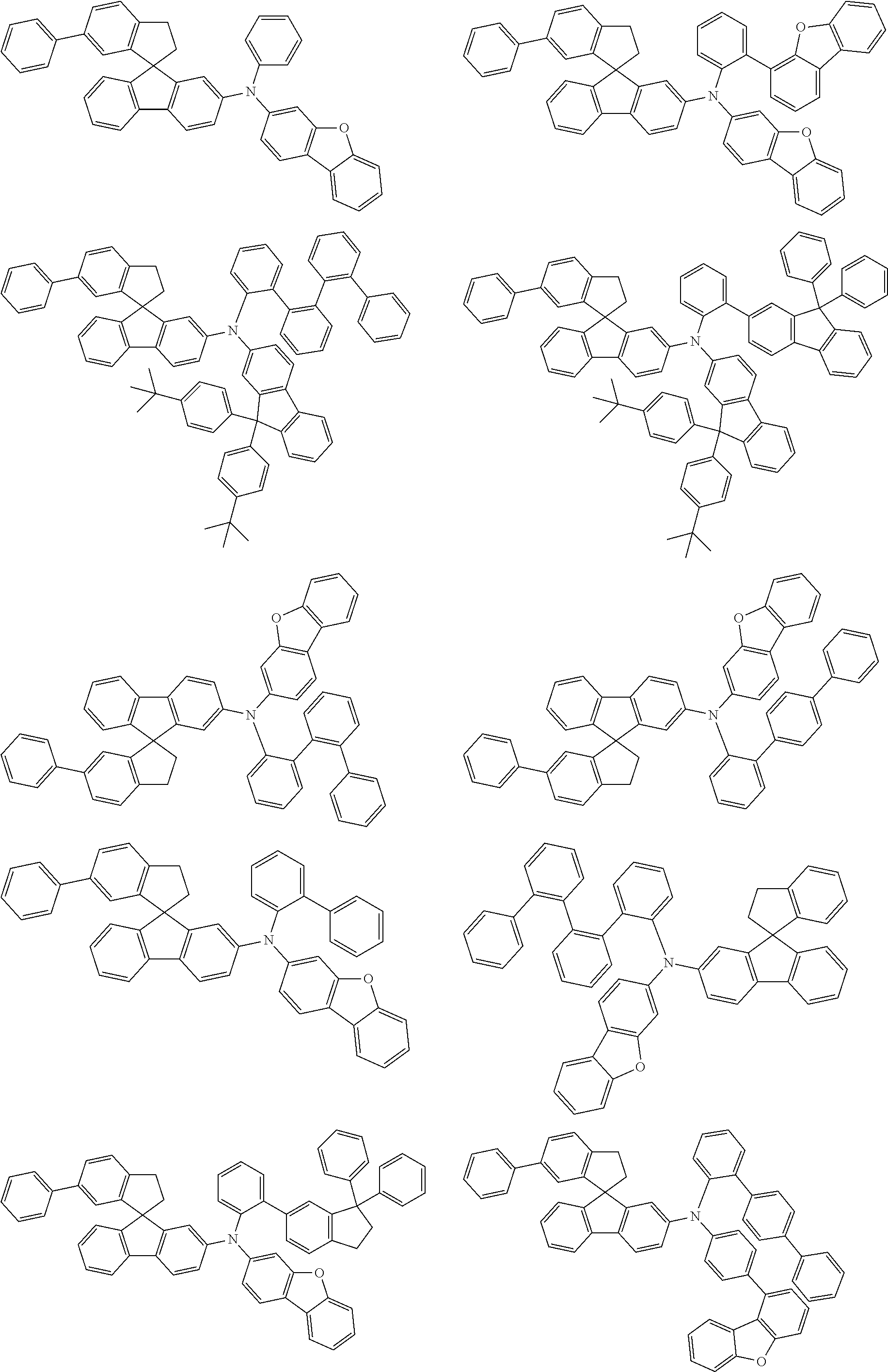

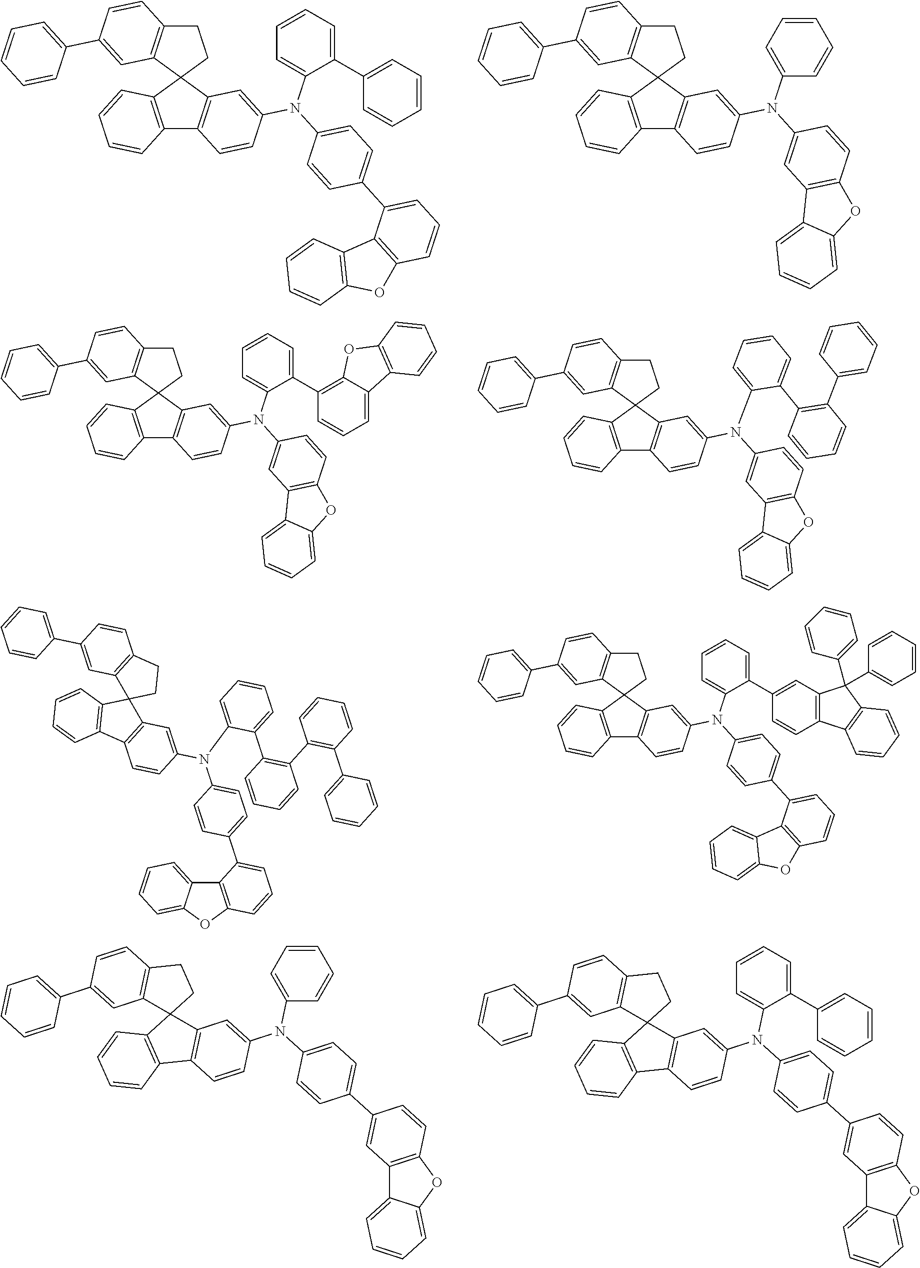

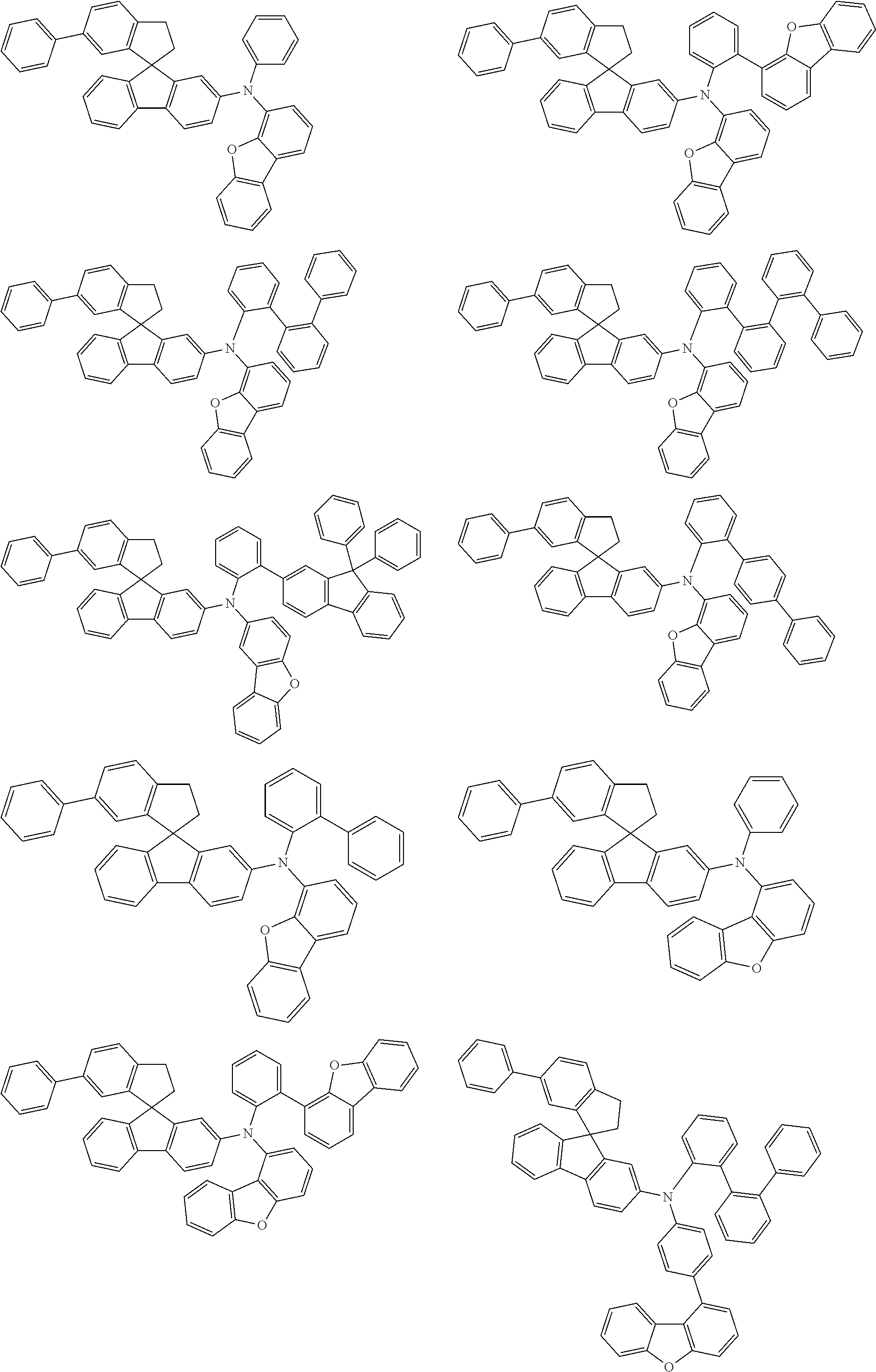

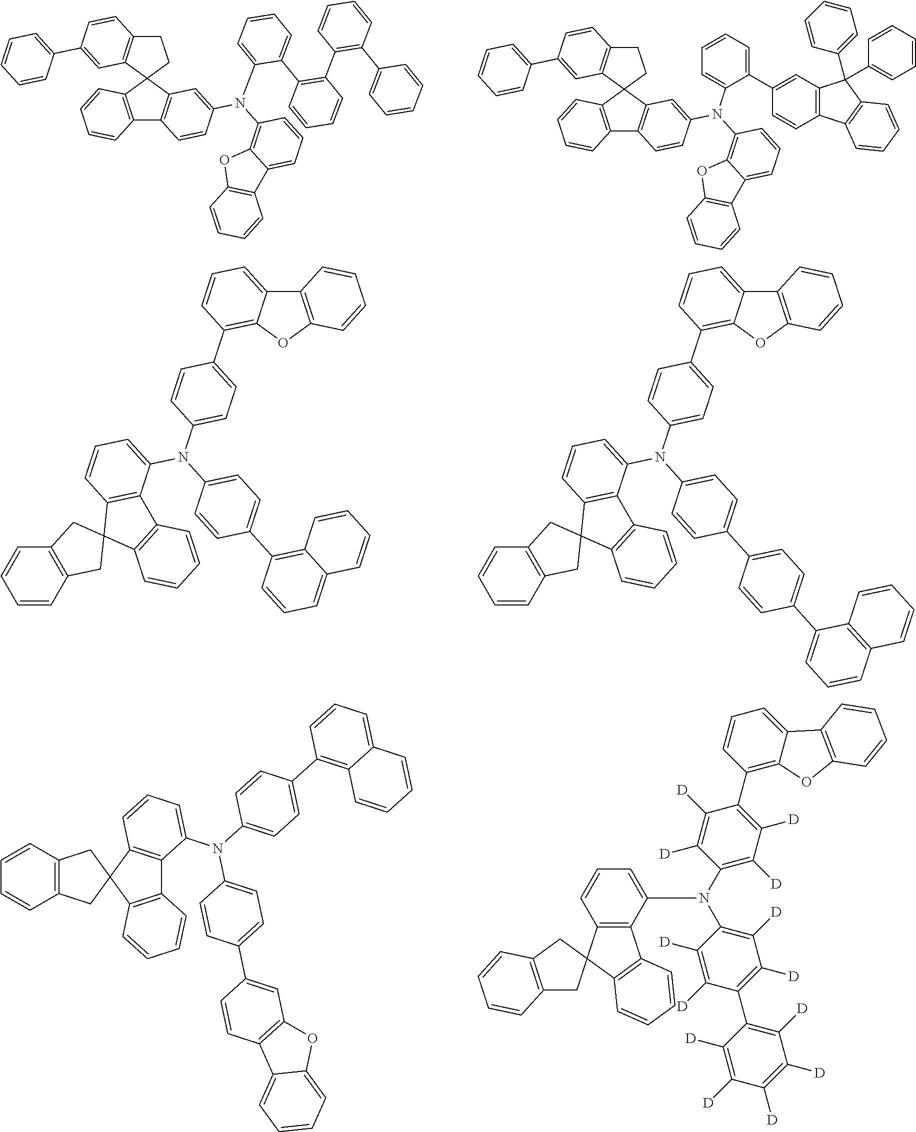

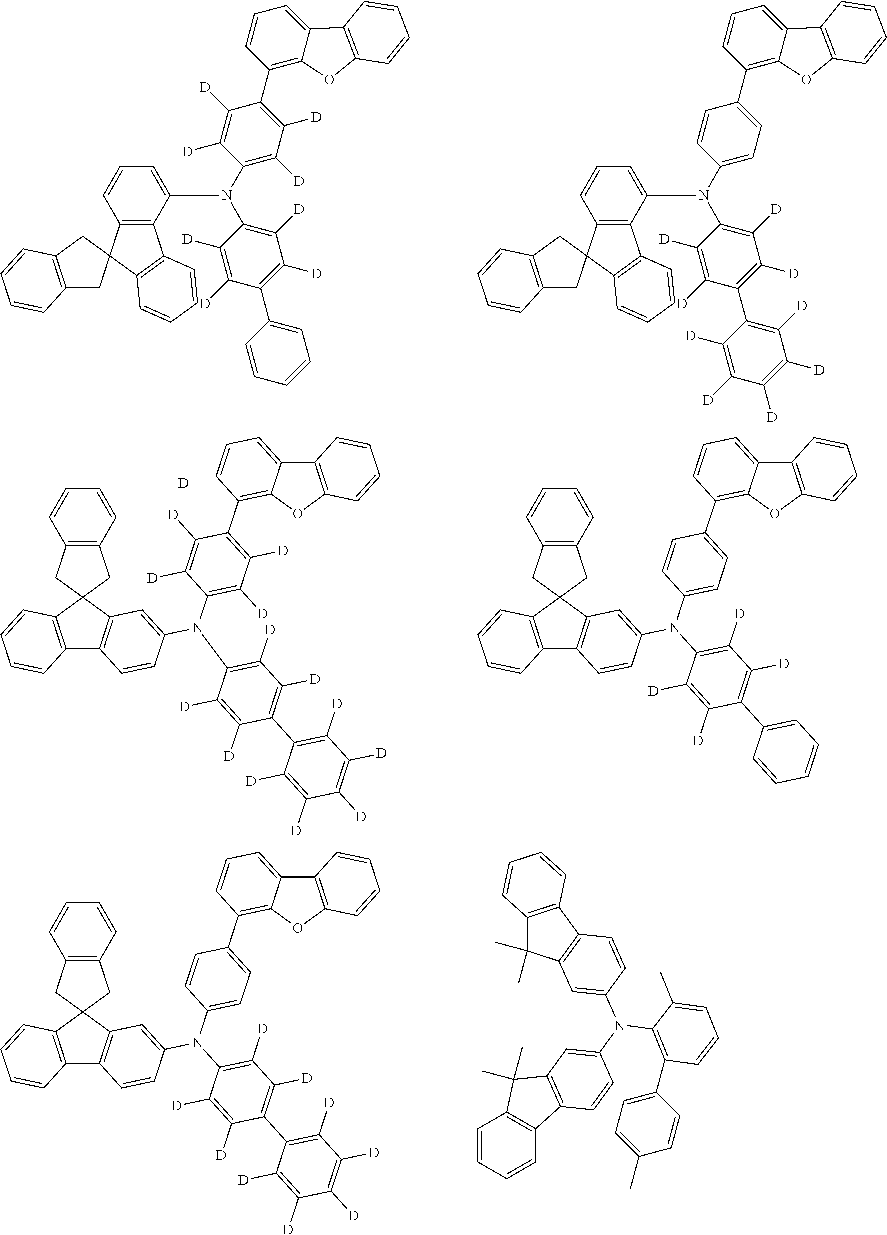

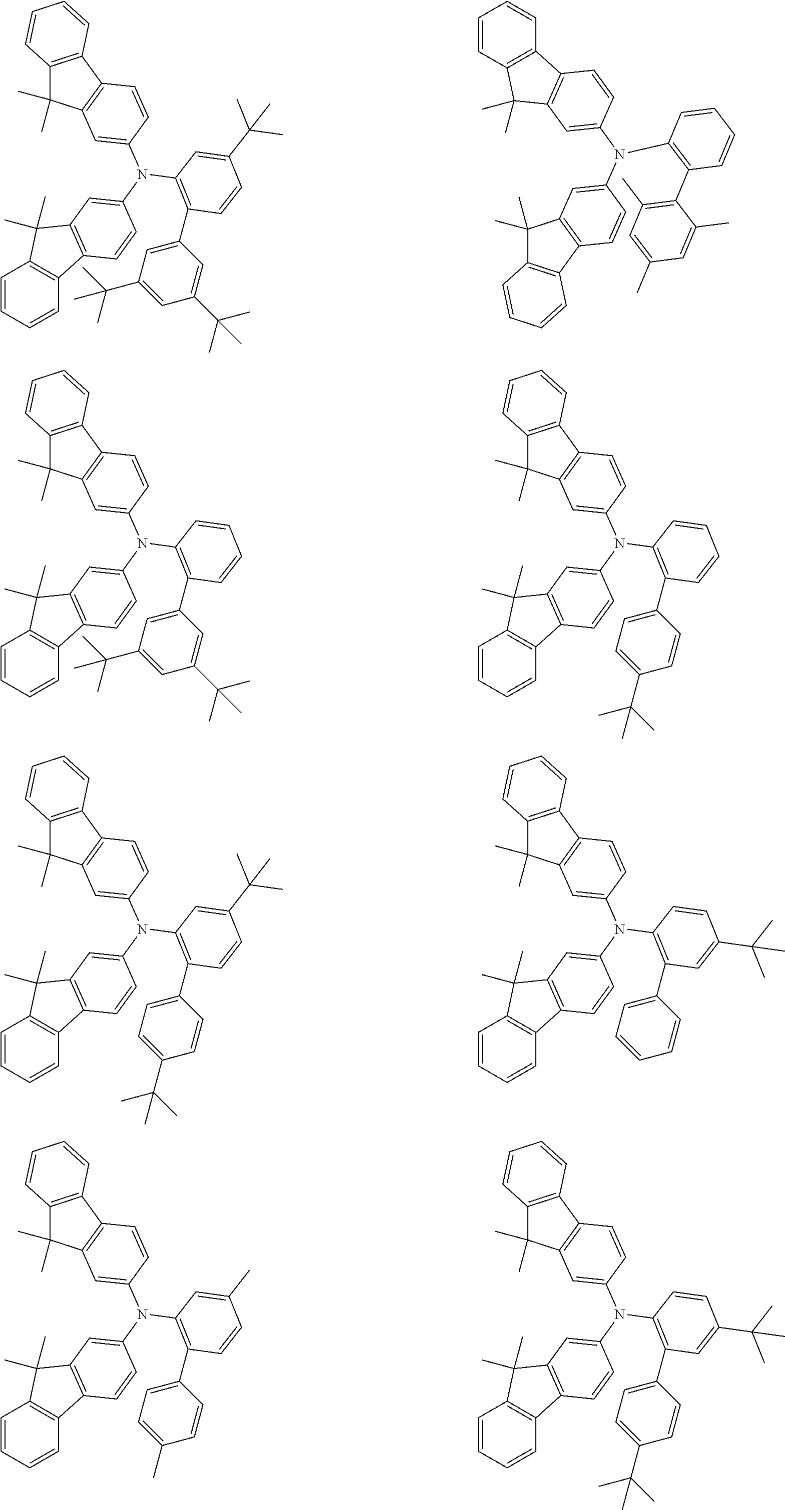

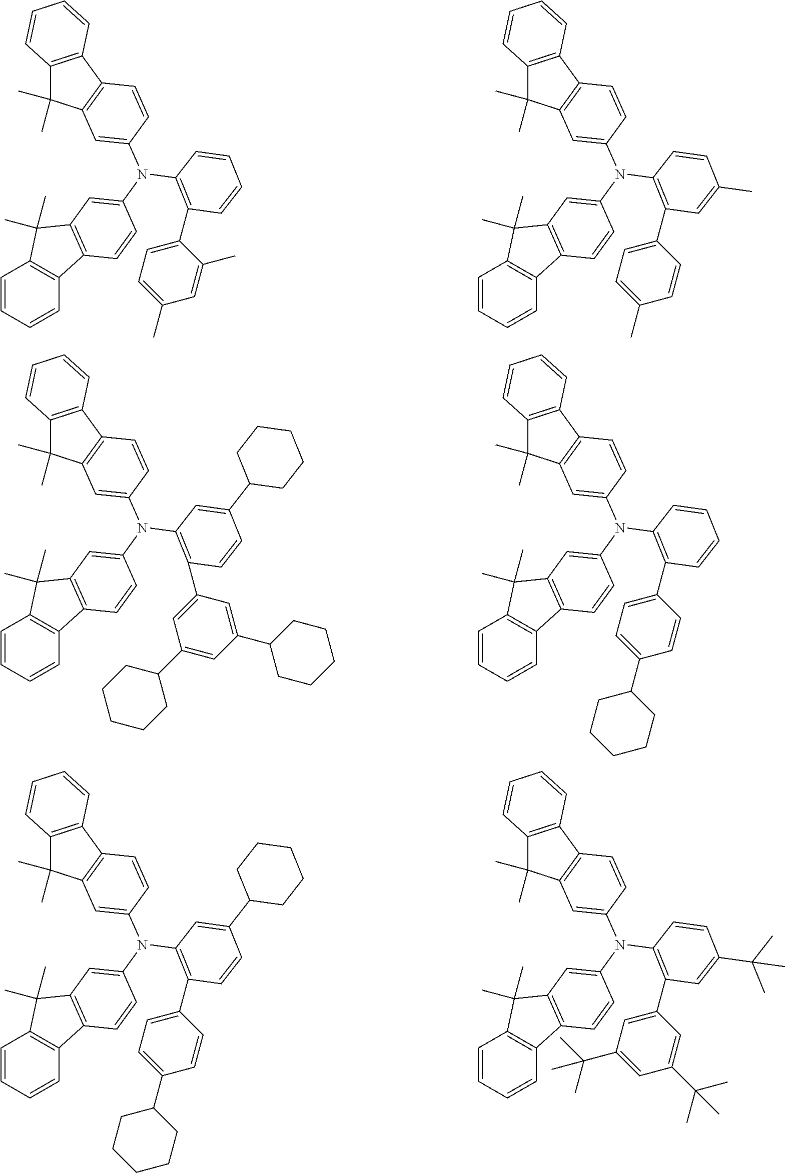

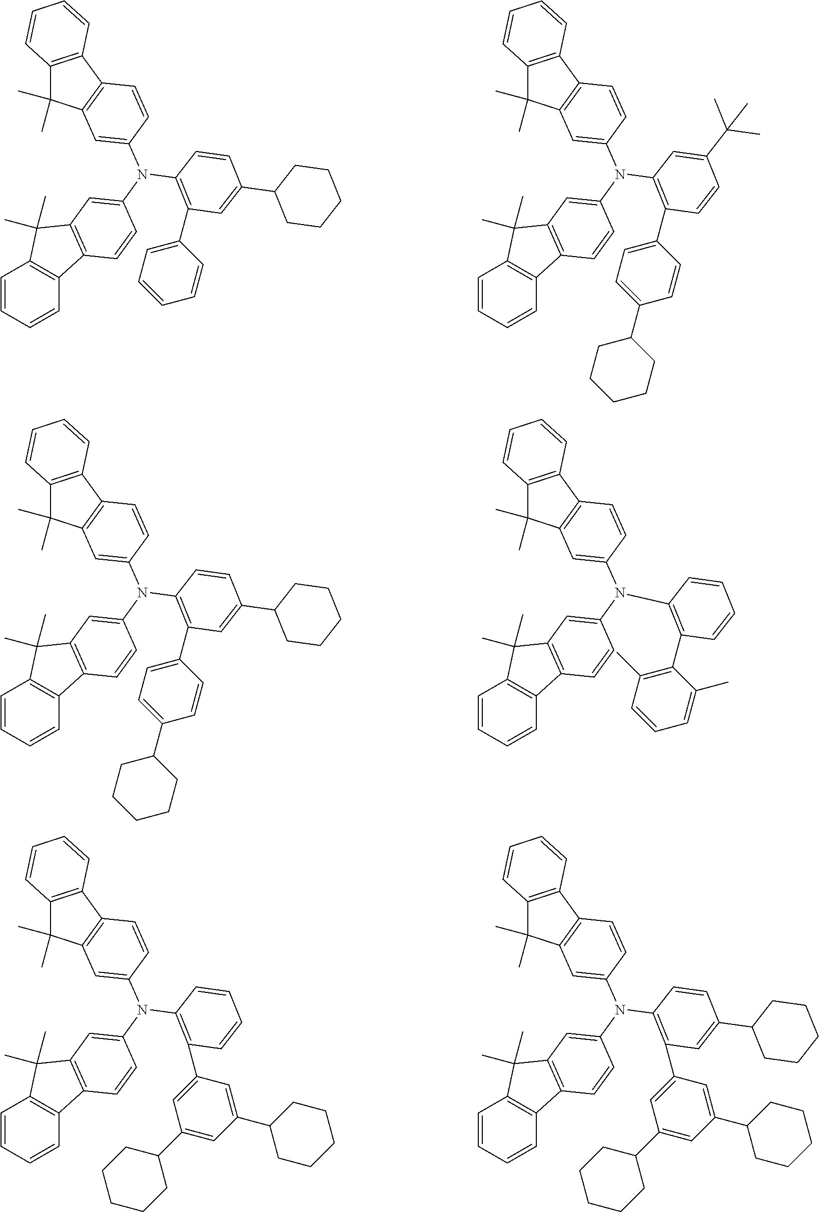

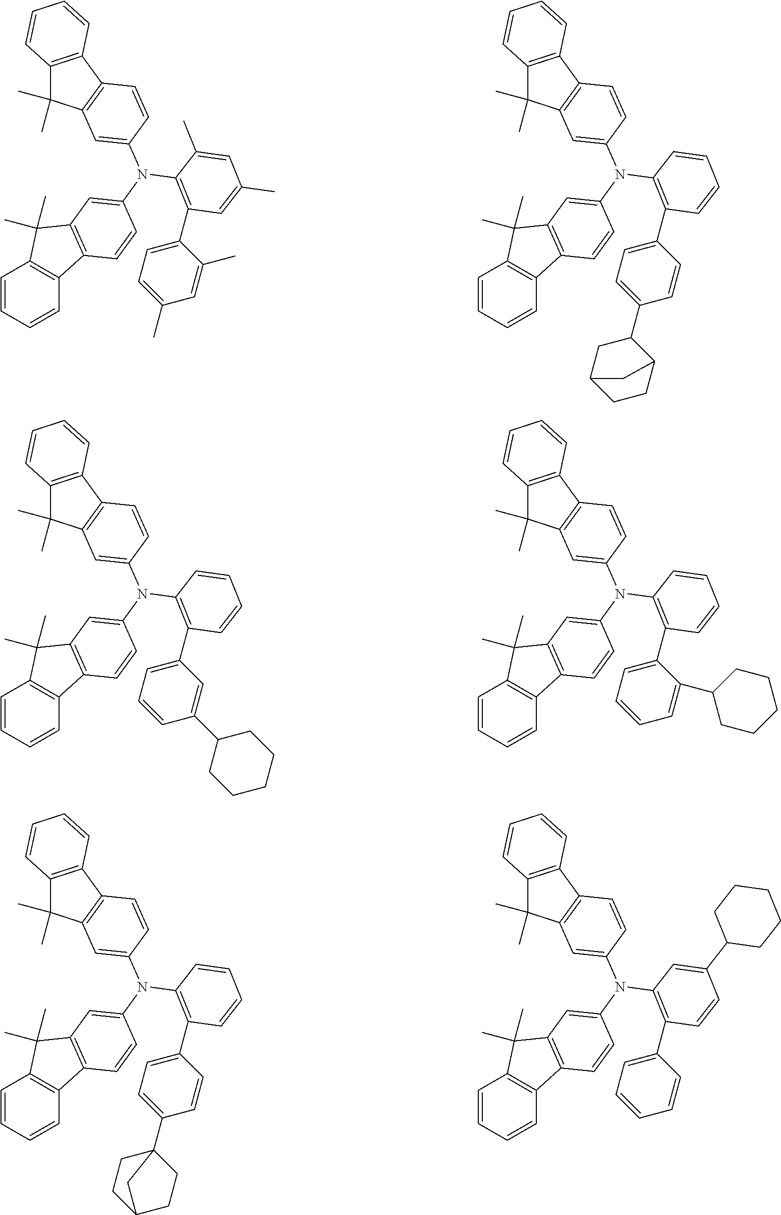

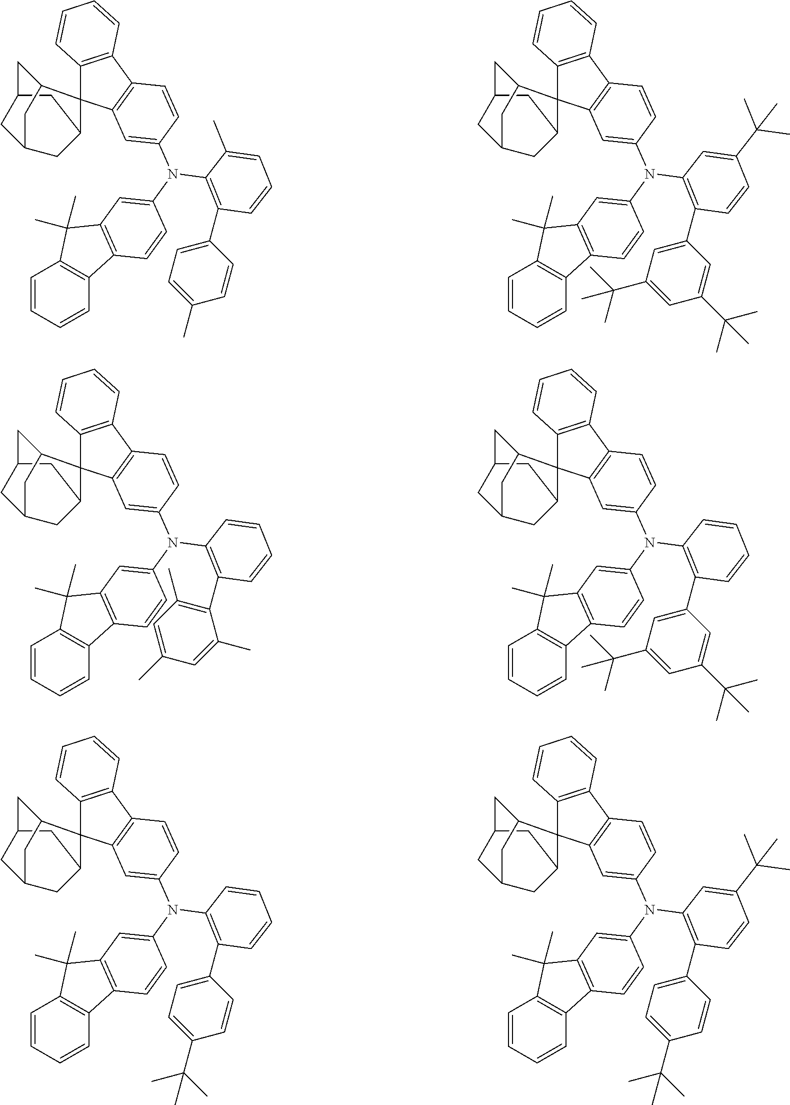

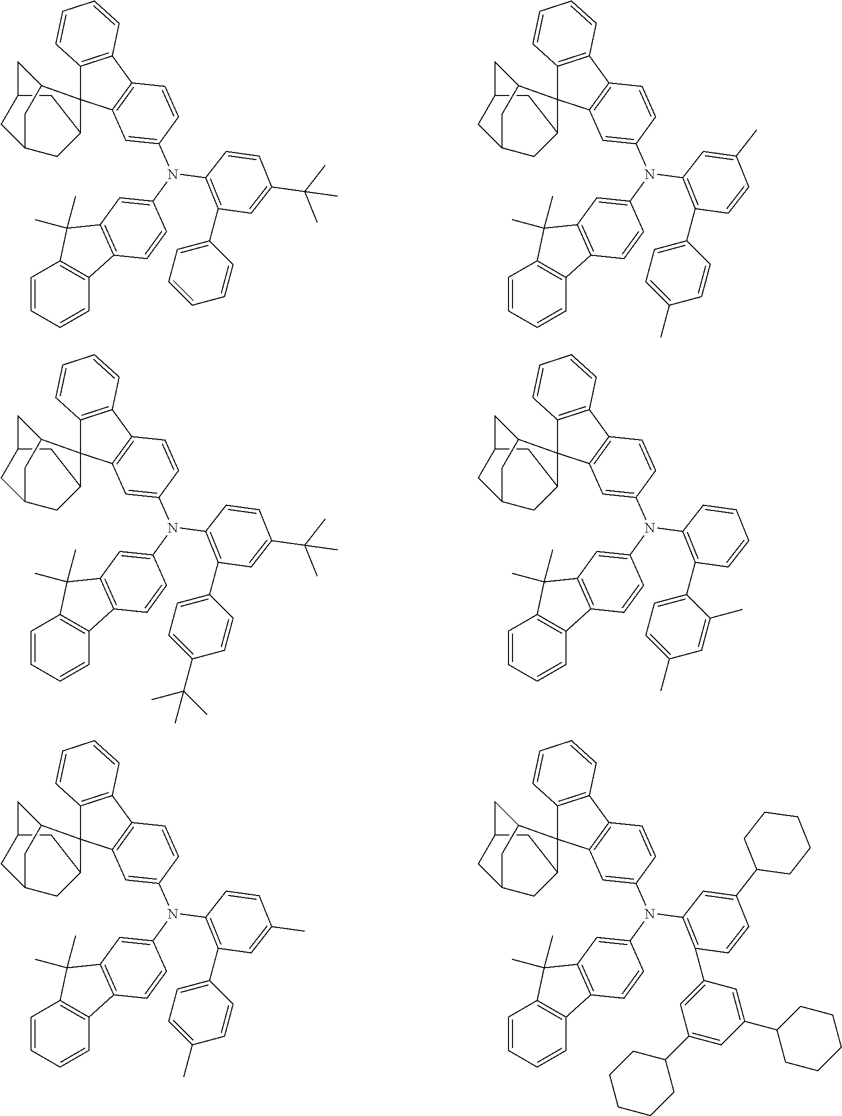

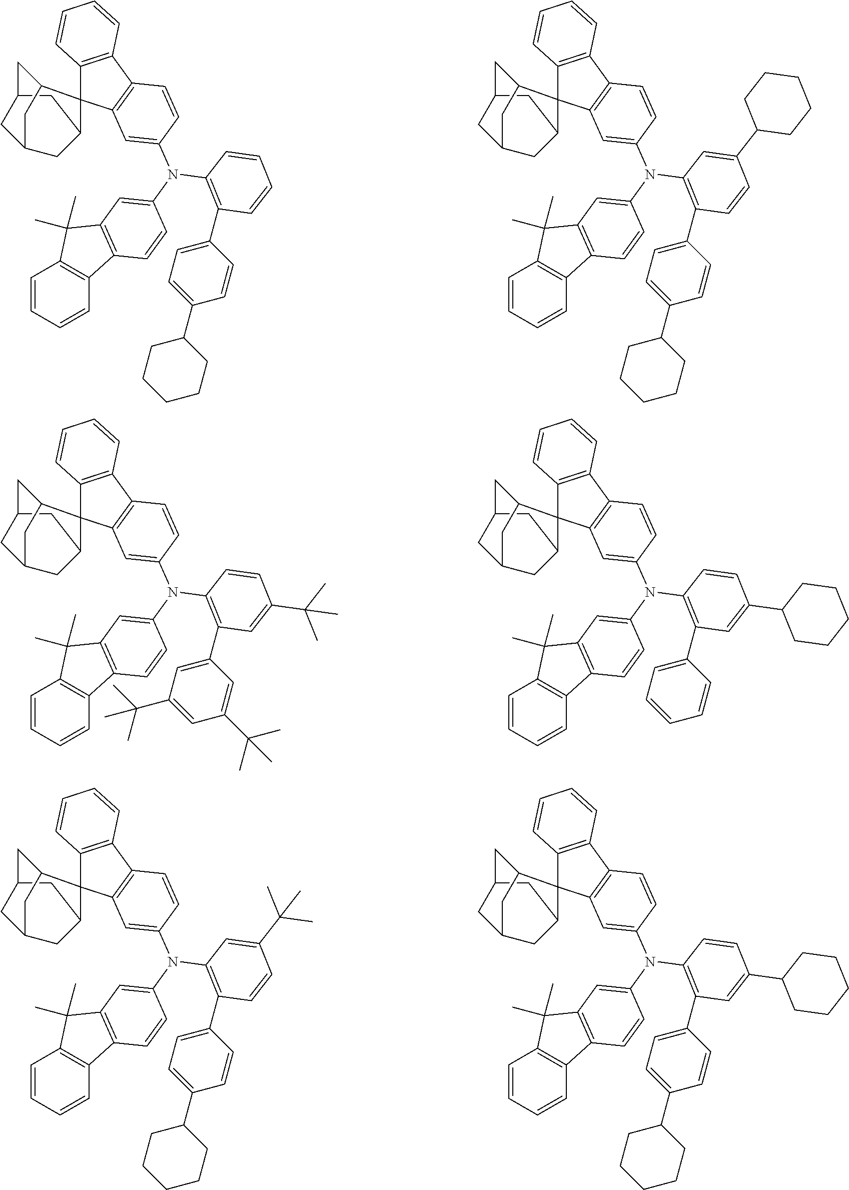

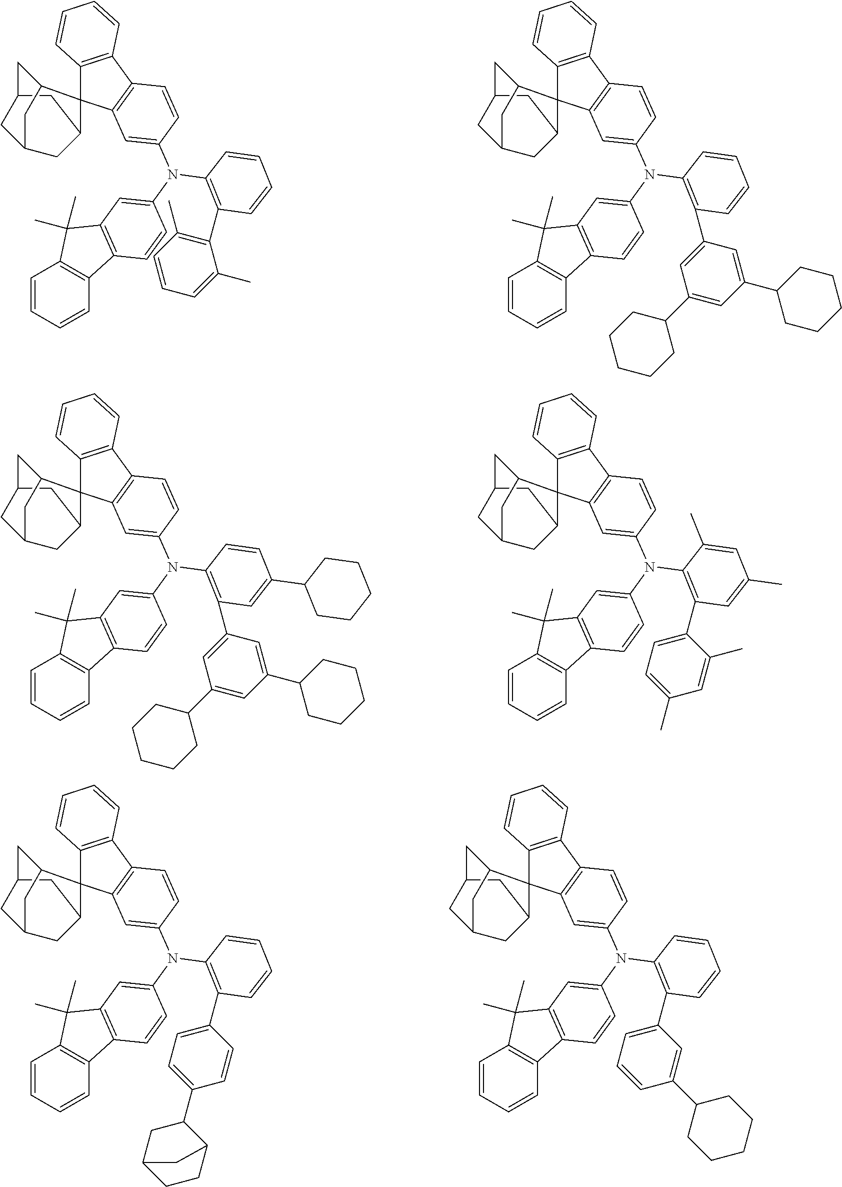

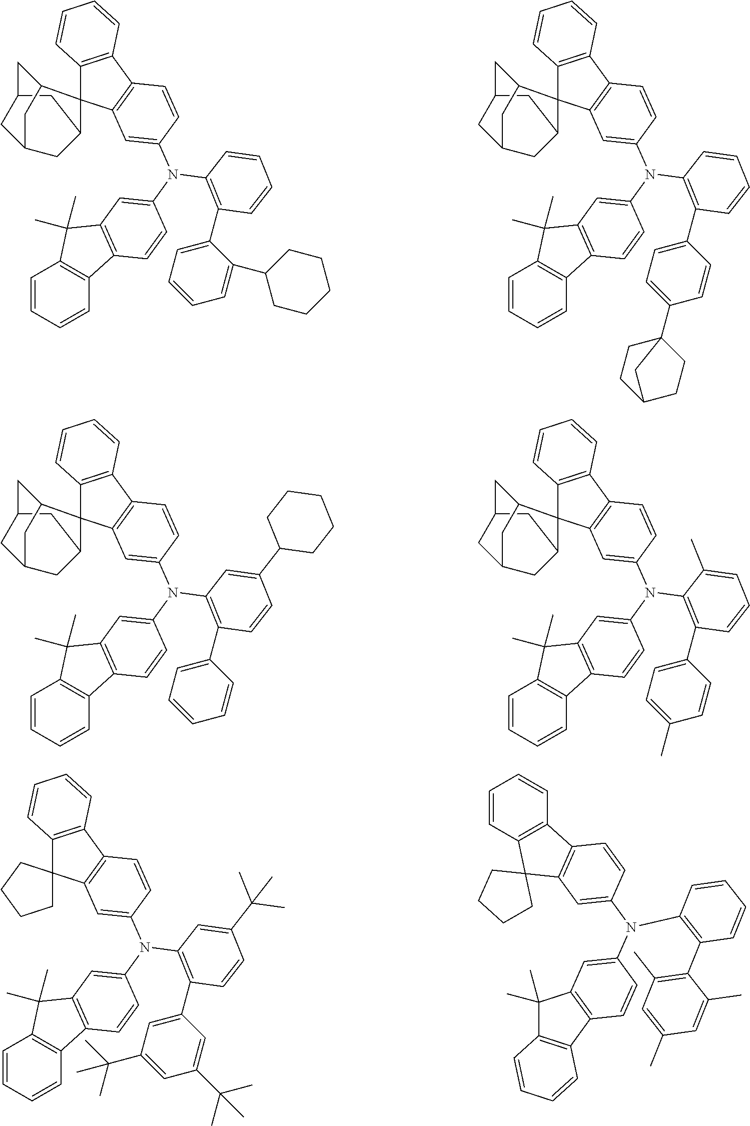

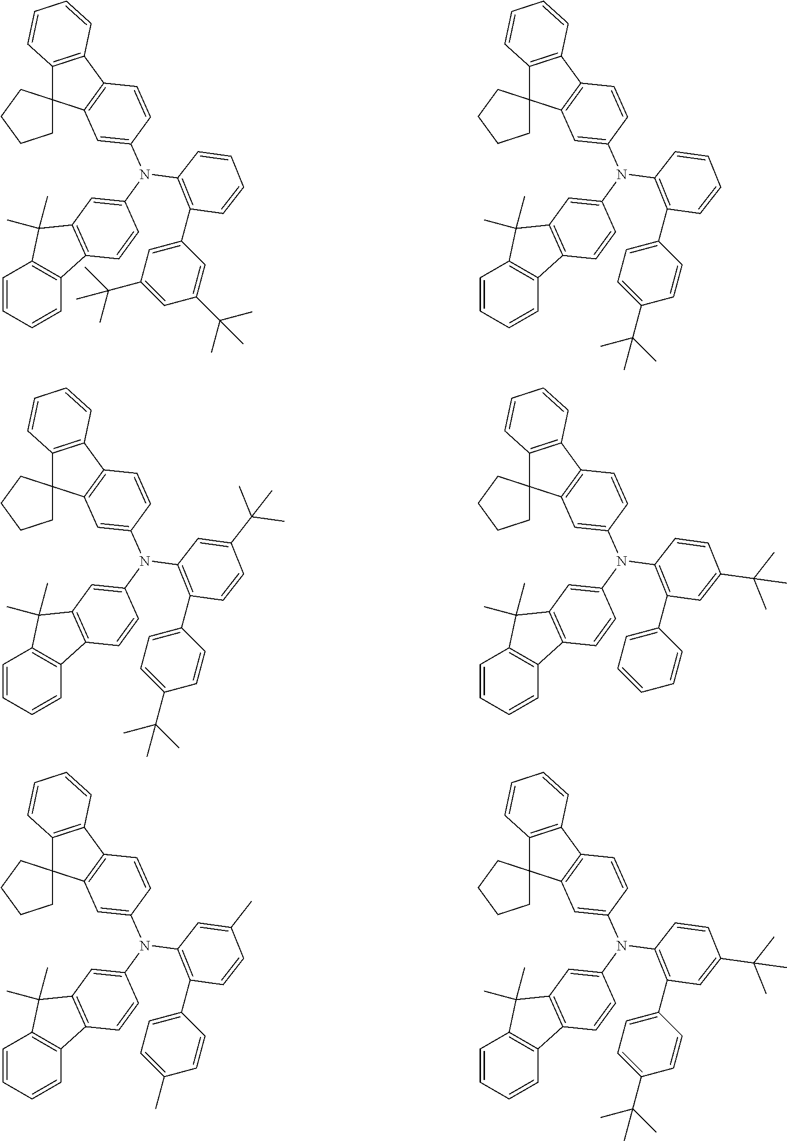

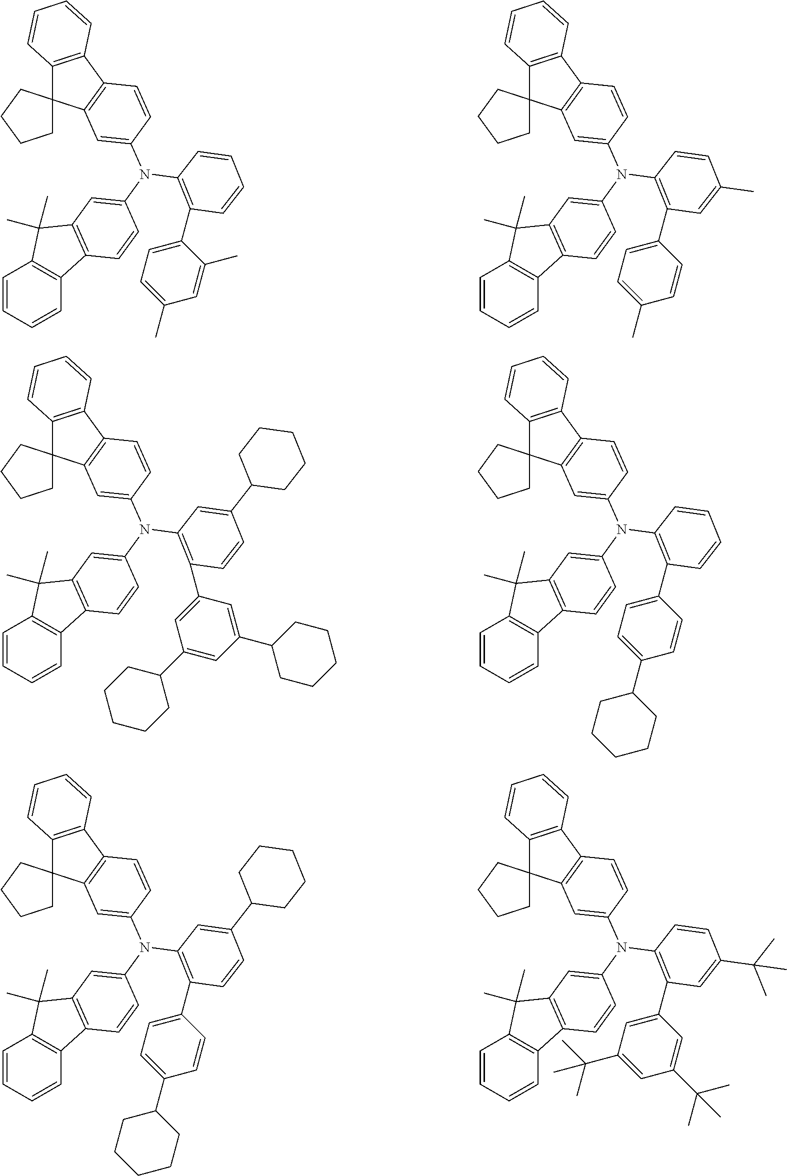

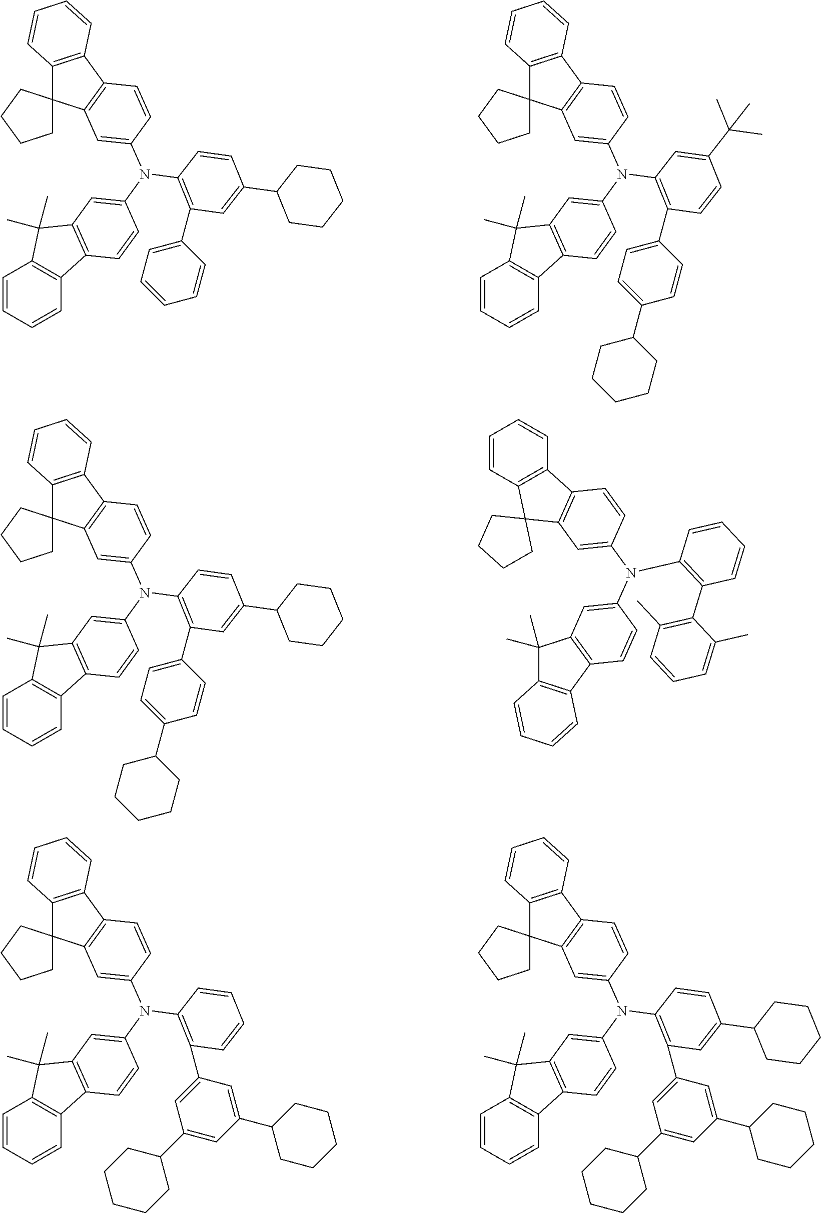

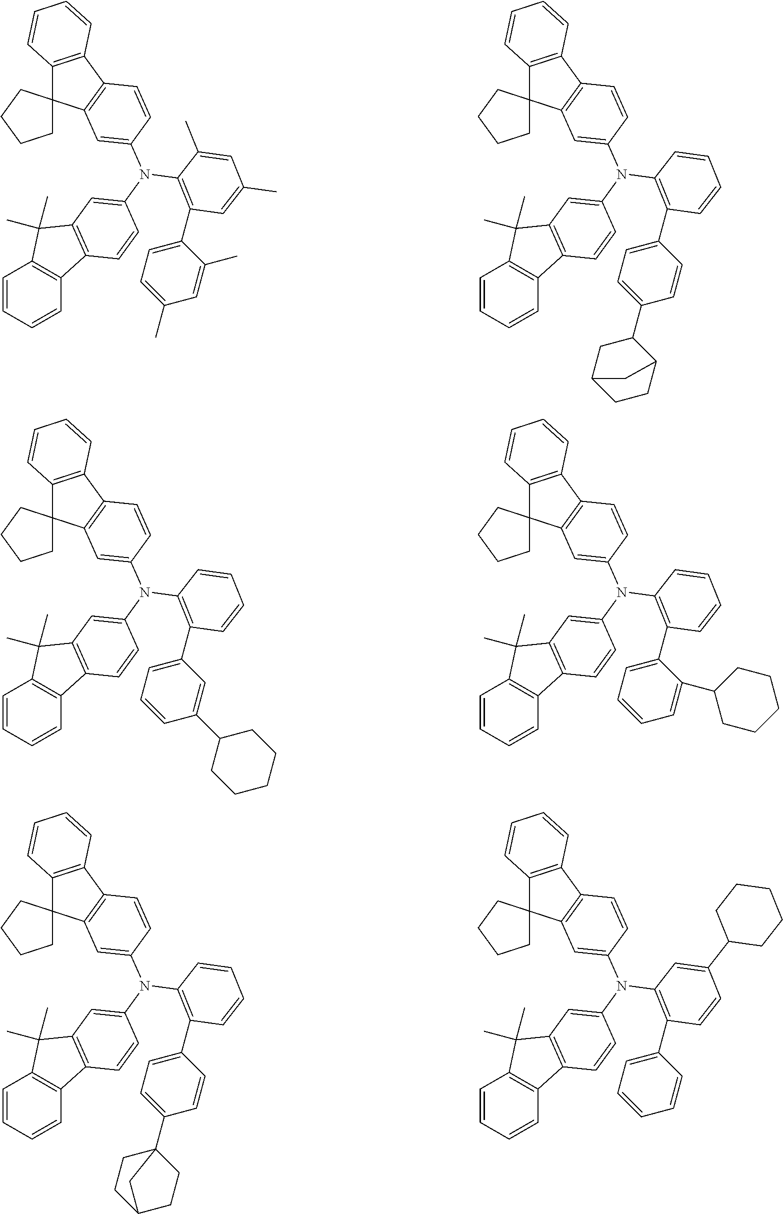

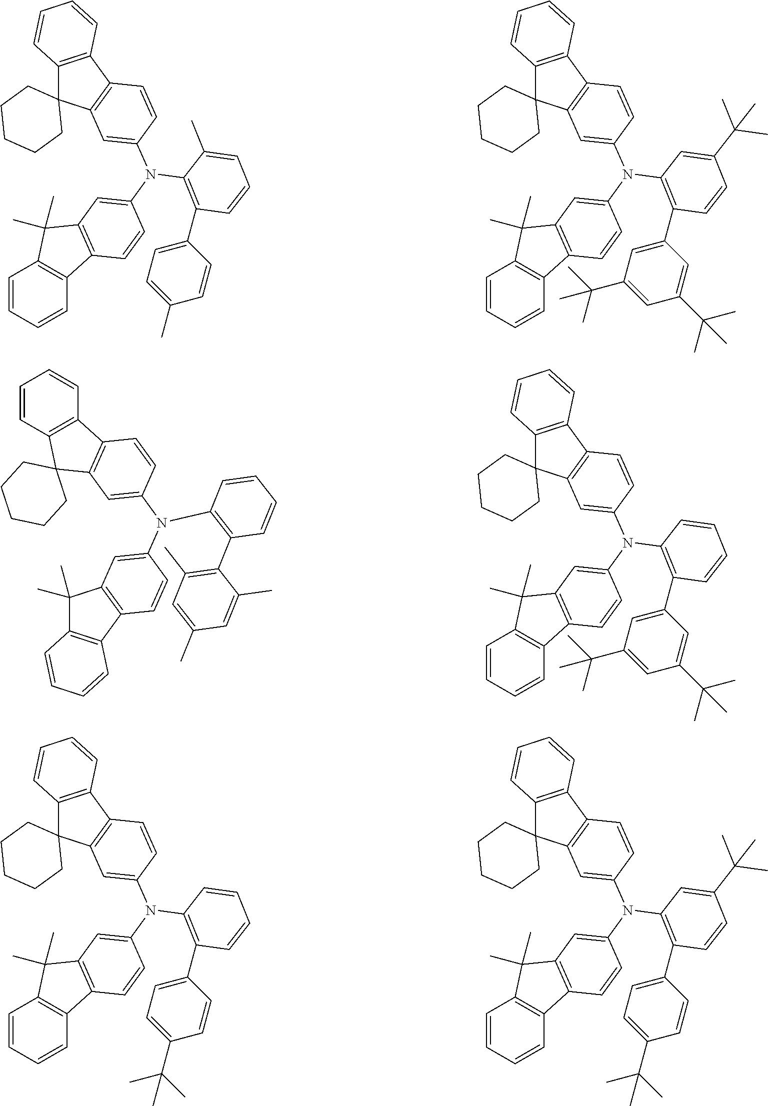

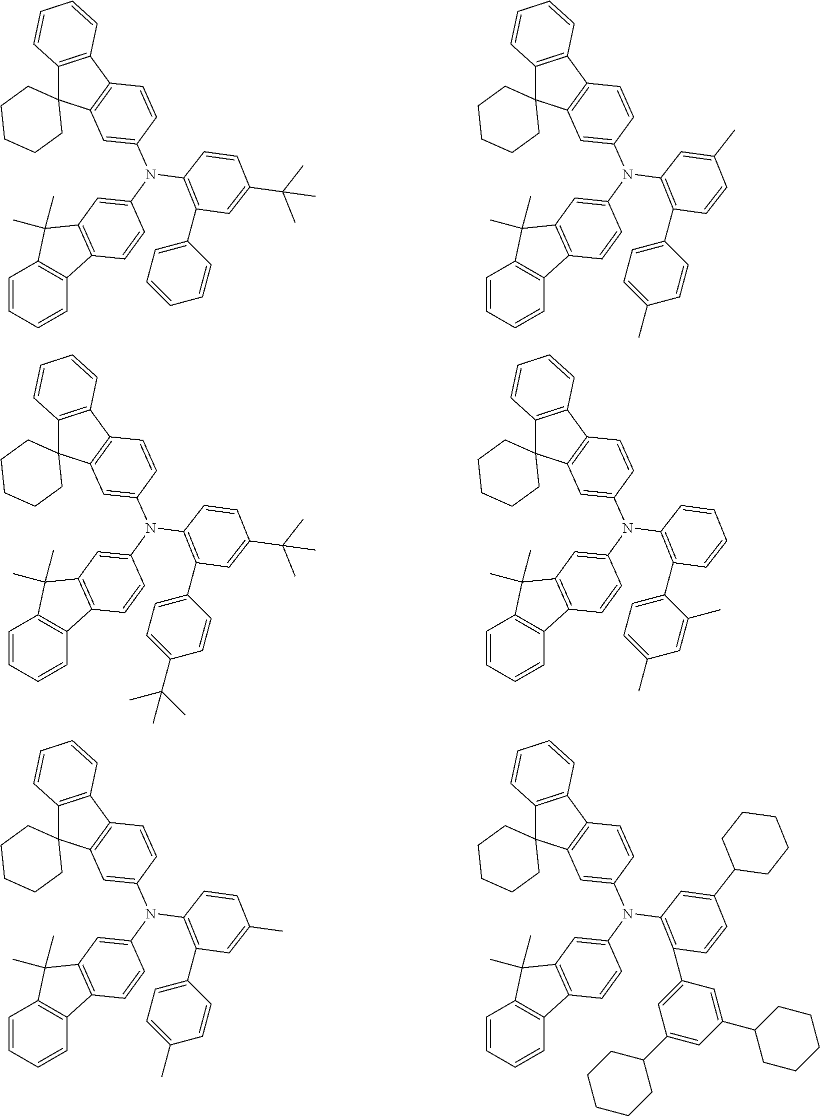

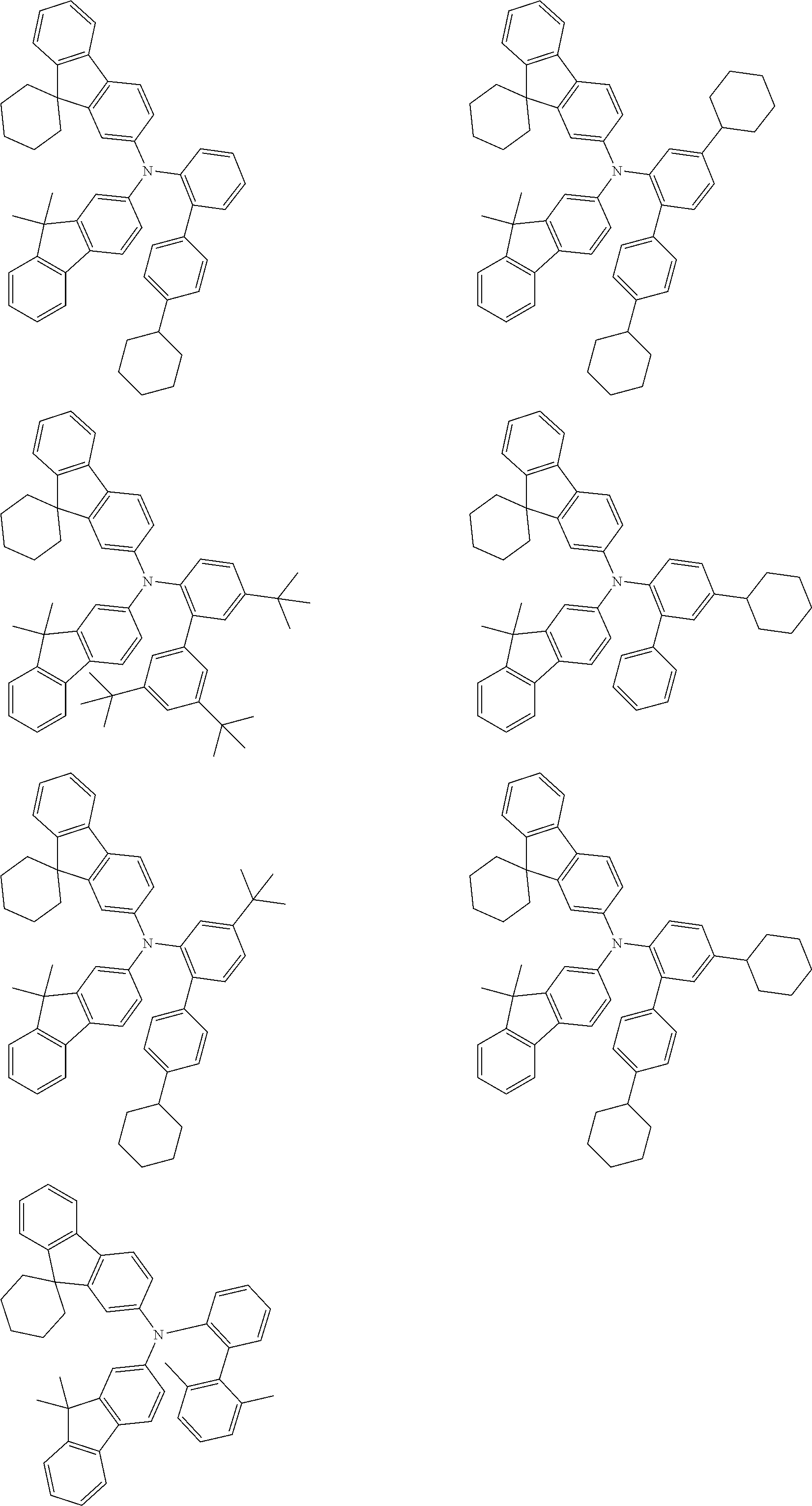

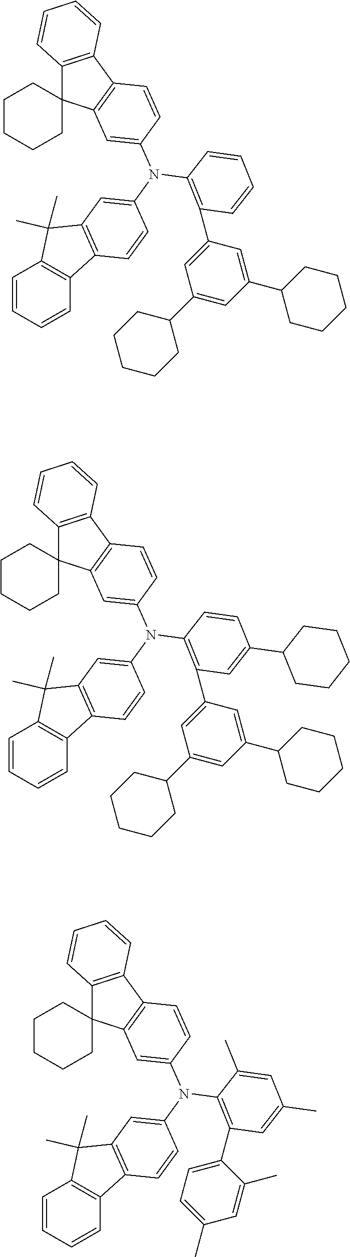 [SMILES: CC1(C)c2ccccc2-c2ccc(N(c3ccc4c(c3)C3(CCCCC3)c3ccccc3-4)c3ccccc3-c3cc(C4CCCCC4)cc(C4CCCCC4)c3)cc21 ; CC1(C)c2ccccc2-c2ccc(N(c3ccc4c(c3)C3(CCCCC3)c3ccccc3-4)c3ccc(C4CCCCC4)cc3-c3cc(C4CCCCC4)cc(C4CCCCC4)c3)cc21 ; Cc1ccc(-c2cc(C)cc(C)c2N(c2ccc3c(c2)C(C)(C)c2ccccc2-3)c2ccc3c(c2)C2(CCCCC2)c2ccccc2-3)c(C)c1]

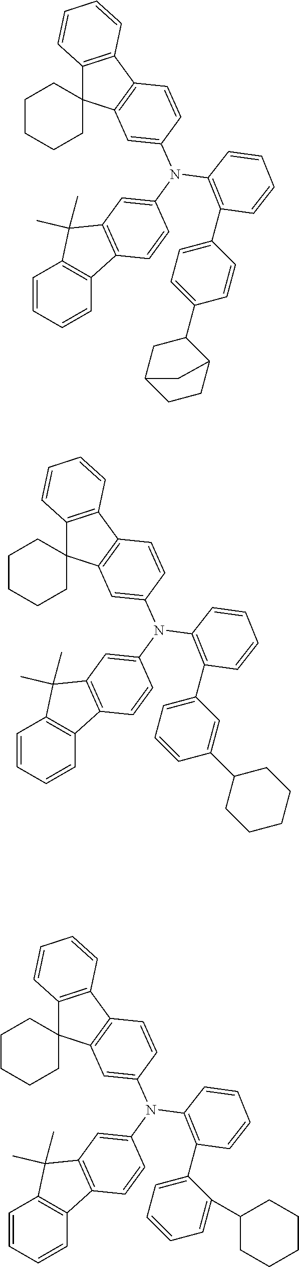 [SMILES: CC1(C)c2ccccc2-c2ccc(N(c3ccc4c(c3)C3(CCCCC3)c3ccccc3-4)c3ccccc3-c3ccc(C4CC5CCC4C5)cc3)cc21 ; CC1(C)c2ccccc2-c2ccc(N(c3ccc4c(c3)C3(CCCCC3)c3ccccc3-4)c3ccccc3-c3cccc(C4CCCCC4)c3)cc21 ; CC1(C)c2ccccc2-c2ccc(N(c3ccc4c(c3)C3(CCCCC3)c3ccccc3-4)c3ccccc3-c3ccccc3C3CCCCC3)cc21]

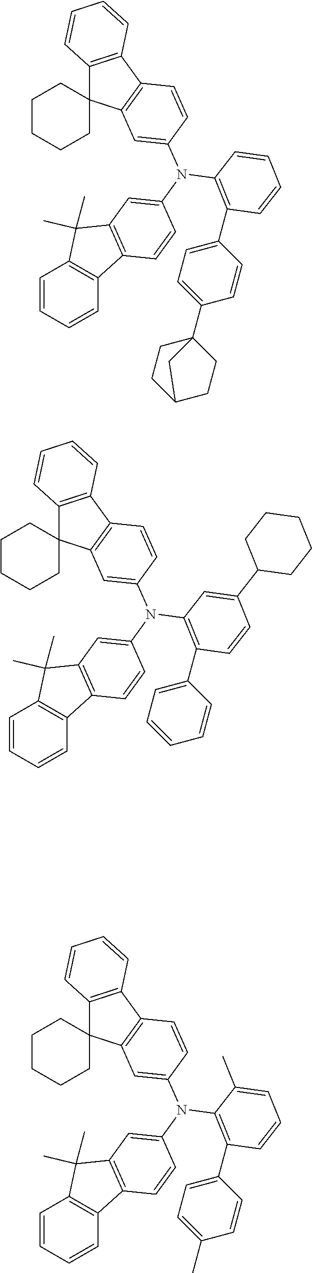 [SMILES: CC1(C)c2ccccc2-c2ccc(N(c3ccc4c(c3)C3(CCCCC3)c3ccccc3-4)c3ccccc3-c3ccc(C45CCC(CC4)C5)cc3)cc21 ; CC1(C)c2ccccc2-c2ccc(N(c3ccc4c(c3)C3(CCCCC3)c3ccccc3-4)c3cc(C4CCCCC4)ccc3-c3ccccc3)cc21 ; Cc1ccc(-c2cccc(C)c2N(c2ccc3c(c2)C(C)(C)c2ccccc2-3)c2ccc3c(c2)C2(CCCCC2)c2ccccc2-3)cc1]

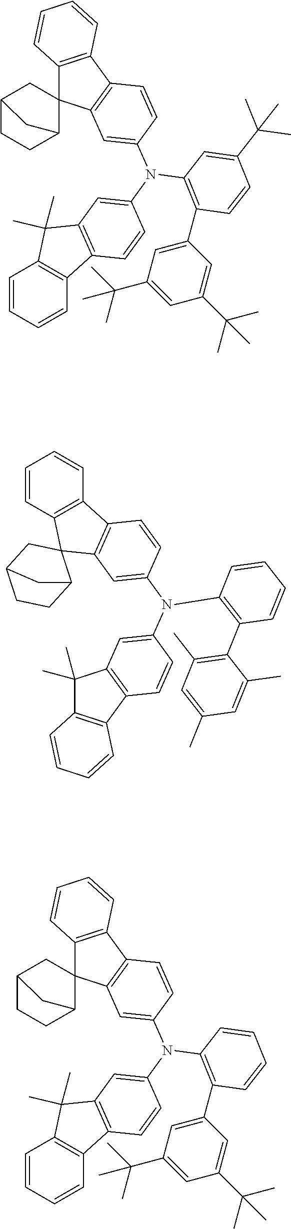 [SMILES: CC(C)(C)c1cc(-c2ccc(C(C)(C)C)cc2N(c2ccc3c(c2)C(C)(C)c2ccccc2-3)c2ccc3c(c2)C2(CC4CCC2C4)c2ccccc2-3)cc(C(C)(C)C)c1 ; Cc1cc(C)c(-c2ccccc2N(c2ccc3c(c2)C(C)(C)c2ccccc2-3)c2ccc3c(c2)C2(CC4CCC2C4)c2ccccc2-3)c(C)c1 ; CC(C)(C)c1cc(-c2ccccc2N(c2ccc3c(c2)C(C)(C)c2ccccc2-3)c2ccc3c(c2)C2(CC4CCC2C4)c2ccccc2-3)cc(C(C)(C)C)c1]

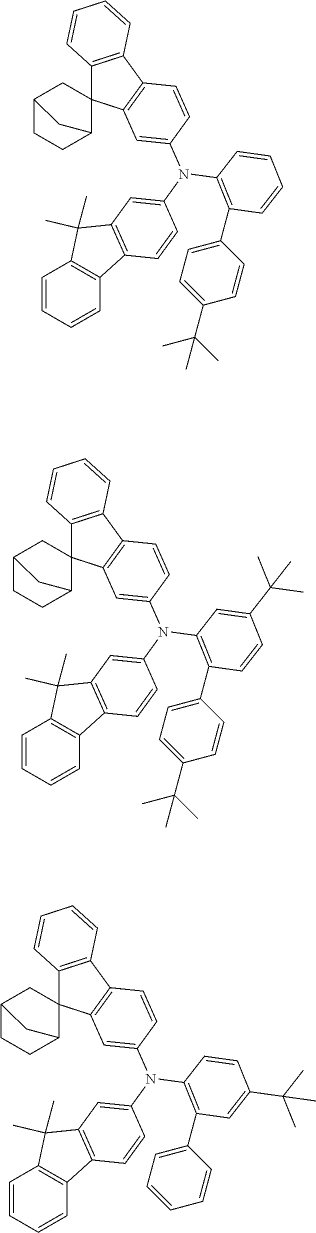 [SMILES: CC(C)(C)c1ccc(-c2ccccc2N(c2ccc3c(c2)C(C)(C)c2ccccc2-3)c2ccc3c(c2)C2(CC4CCC2C4)c2ccccc2-3)cc1 ; CC(C)(C)c1ccc(-c2ccc(C(C)(C)C)cc2N(c2ccc3c(c2)C(C)(C)c2ccccc2-3)c2ccc3c(c2)C2(CC4CCC2C4)c2ccccc2-3)cc1 ; CC(C)(C)c1ccc(N(c2ccc3c(c2)C(C)(C)c2ccccc2-3)c2ccc3c(c2)C2(CC4CCC2C4)c2ccccc2-3)c(-c2ccccc2)c1]

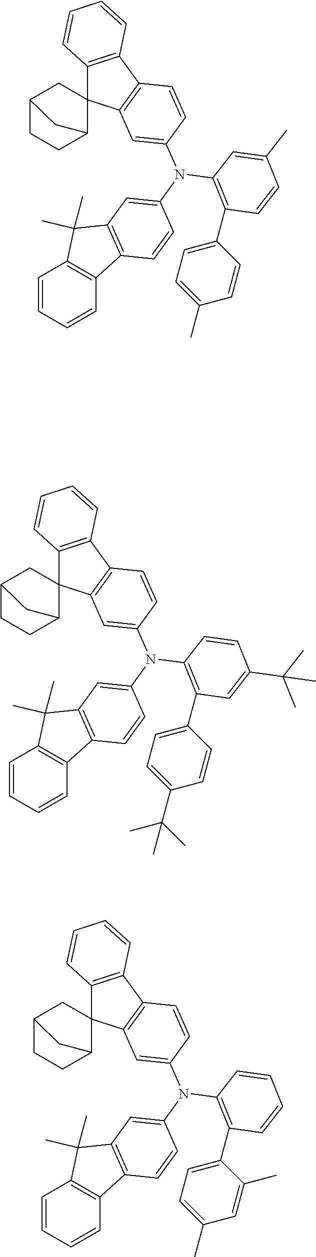 [SMILES: Cc1ccc(-c2ccc(C)cc2N(c2ccc3c(c2)C(C)(C)c2ccccc2-3)c2ccc3c(c2)C2(CC4CCC2C4)c2ccccc2-3)cc1 ; CC(C)(C)c1ccc(-c2cc(C(C)(C)C)ccc2N(c2ccc3c(c2)C(C)(C)c2ccccc2-3)c2ccc3c(c2)C2(CC4CCC2C4)c2ccccc2-3)cc1 ; Cc1ccc(-c2ccccc2N(c2ccc3c(c2)C(C)(C)c2ccccc2-3)c2ccc3c(c2)C2(CC4CCC2C4)c2ccccc2-3)c(C)c1]

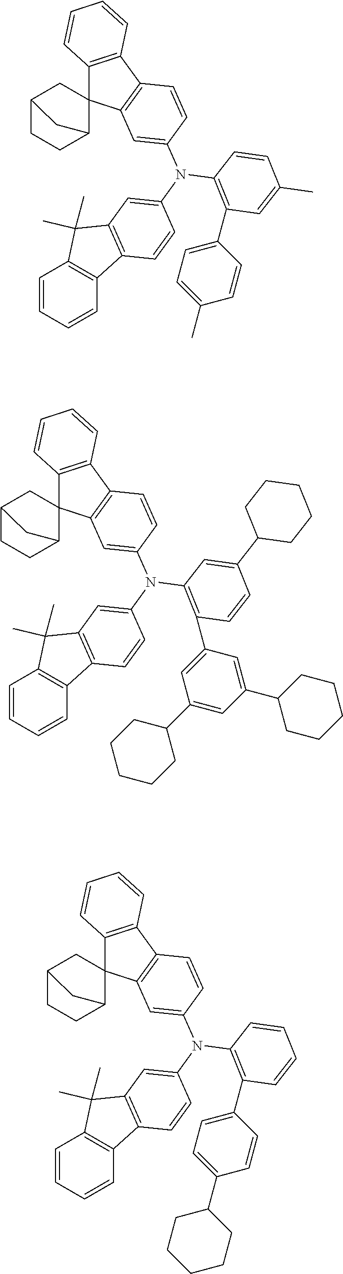 [SMILES: Cc1ccc(-c2cc(C)ccc2N(c2ccc3c(c2)C(C)(C)c2ccccc2-3)c2ccc3c(c2)C2(CC4CCC2C4)c2ccccc2-3)cc1 ; CC1(C)c2ccccc2-c2ccc(N(c3ccc4c(c3)C3(CC5CCC3C5)c3ccccc3-4)c3cc(C4CCCCC4)ccc3-c3cc(C4CCCCC4)cc(C4CCCCC4)c3)cc21 ; CC1(C)c2ccccc2-c2ccc(N(c3ccc4c(c3)C3(CC5CCC3C5)c3ccccc3-4)c3ccccc3-c3ccc(C4CCCCC4)cc3)cc21]

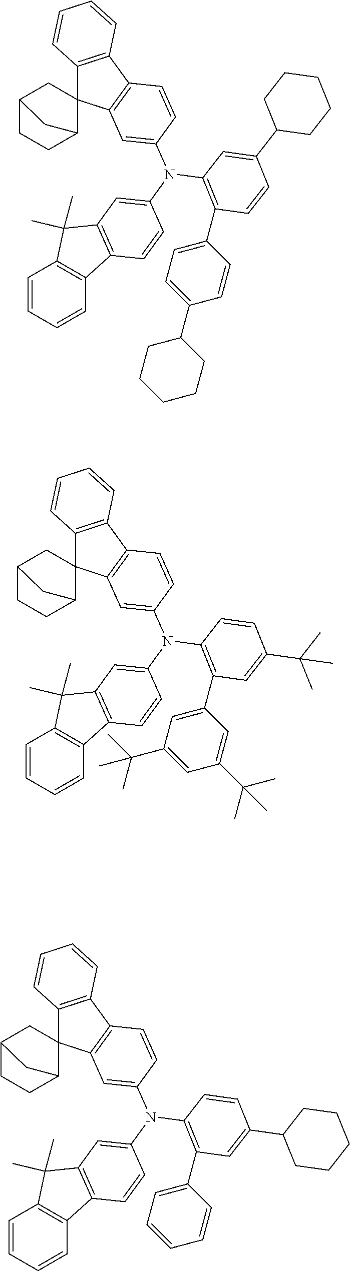 [SMILES: CC1(C)c2ccccc2-c2ccc(N(c3ccc4c(c3)C3(CC5CCC3C5)c3ccccc3-4)c3cc(C4CCCCC4)ccc3-c3ccc(C4CCCCC4)cc3)cc21 ; CC(C)(C)c1cc(-c2cc(C(C)(C)C)ccc2N(c2ccc3c(c2)C(C)(C)c2ccccc2-3)c2ccc3c(c2)C2(CC4CCC2C4)c2ccccc2-3)cc(C(C)(C)C)c1 ; CC1(C)c2ccccc2-c2ccc(N(c3ccc4c(c3)C3(CC5CCC3C5)c3ccccc3-4)c3ccc(C4CCCCC4)cc3-c3ccccc3)cc21]

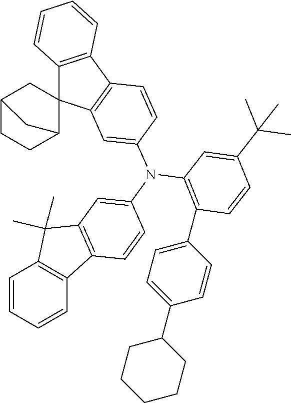 [SMILES: CC(C)(C)c1ccc(-c2ccc(C3CCCCC3)cc2)c(N(c2ccc3c(c2)C(C)(C)c2ccccc2-3)c2ccc3c(c2)C2(CC4CCC2C4)c2ccccc2-3)c1]

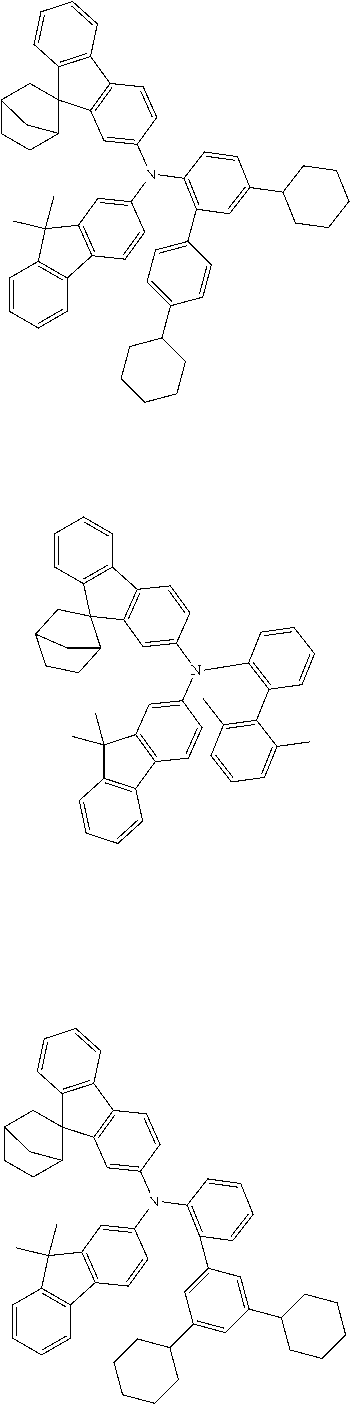 [SMILES: CC1(C)c2ccccc2-c2ccc(N(c3ccc4c(c3)C3(CC5CCC3C5)c3ccccc3-4)c3ccc(C4CCCCC4)cc3-c3ccc(C4CCCCC4)cc3)cc21 ; Cc1cccc(C)c1-c1ccccc1N(c1ccc2c(c1)C(C)(C)c1ccccc1-2)c1ccc2c(c1)C1(CC3CCC1C3)c1ccccc1-2 ; CC1(C)c2ccccc2-c2ccc(N(c3ccc4c(c3)C3(CC5CCC3C5)c3ccccc3-4)c3ccccc3-c3cc(C4CCCCC4)cc(C4CCCCC4)c3)cc21]

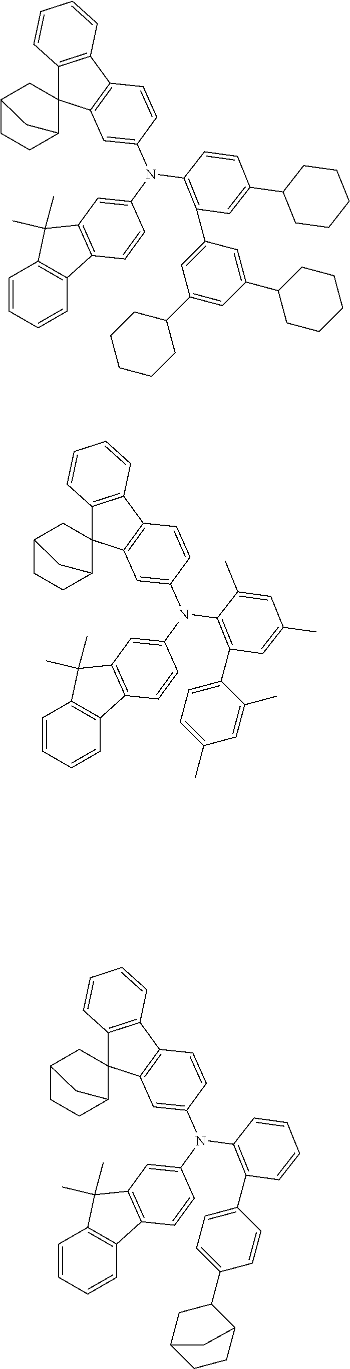 [SMILES: CC1(C)c2ccccc2-c2ccc(N(c3ccc4c(c3)C3(CC5CCC3C5)c3ccccc3-4)c3ccc(C4CCCCC4)cc3-c3cc(C4CCCCC4)cc(C4CCCCC4)c3)cc21 ; Cc1ccc(-c2cc(C)cc(C)c2N(c2ccc3c(c2)C(C)(C)c2ccccc2-3)c2ccc3c(c2)C2(CC4CCC2C4)c2ccccc2-3)c(C)c1 ; CC1(C)c2ccccc2-c2ccc(N(c3ccc4c(c3)C3(CC5CCC3C5)c3ccccc3-4)c3ccccc3-c3ccc(C4CC5CCC4C5)cc3)cc21]

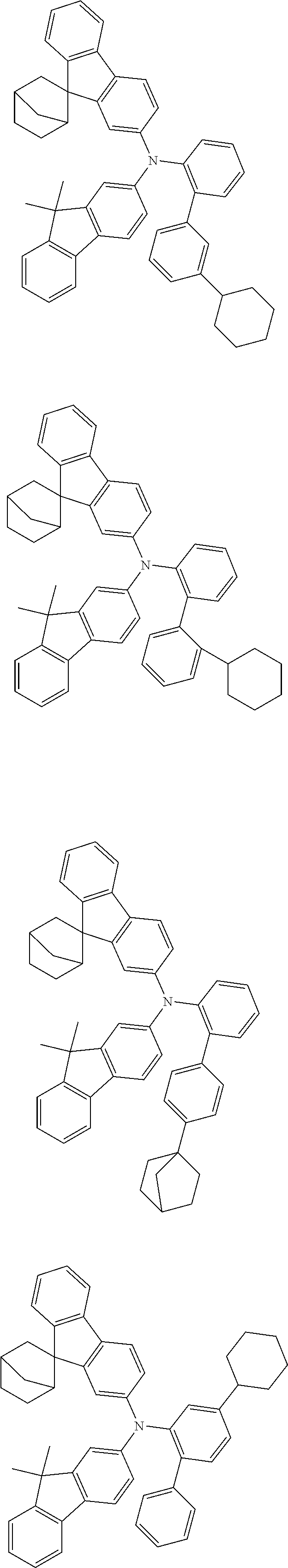 [SMILES: CC1(C)c2ccccc2-c2ccc(N(c3ccc4c(c3)C3(CC5CCC3C5)c3ccccc3-4)c3ccccc3-c3cccc(C4CCCCC4)c3)cc21 ; CC1(C)c2ccccc2-c2ccc(N(c3ccc4c(c3)C3(CC5CCC3C5)c3ccccc3-4)c3ccccc3-c3ccccc3C3CCCCC3)cc21 ; CC1(C)c2ccccc2-c2ccc(N(c3ccc4c(c3)C3(CC5CCC3C5)c3ccccc3-4)c3ccccc3-c3ccc(C45CCC(CC4)C5)cc3)cc21 ; CC1(C)c2ccccc2-c2ccc(N(c3ccc4c(c3)C3(CC5CCC3C5)c3ccccc3-4)c3cc(C4CCCCC4)ccc3-c3ccccc3)cc21]

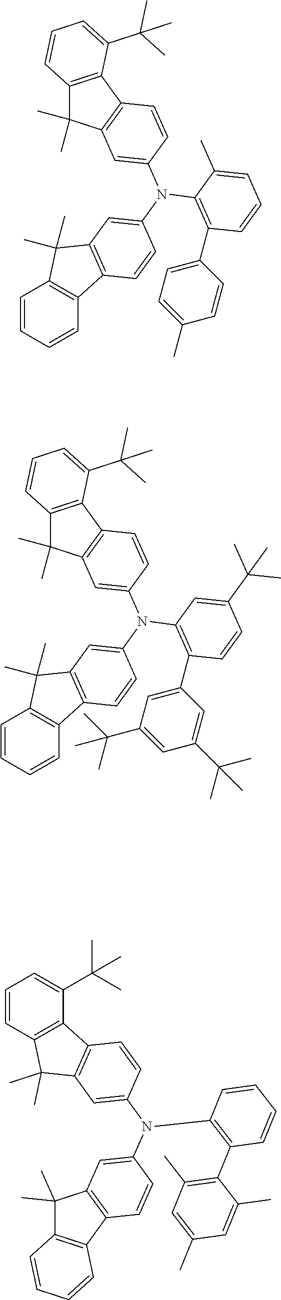 [SMILES: Cc1ccc(-c2cccc(C)c2N(c2ccc3c(c2)C(C)(C)c2ccccc2-3)c2ccc3c(c2)C(C)(C)c2cccc(C(C)(C)C)c2-3)cc1 ; CC(C)(C)c1cc(-c2ccc(C(C)(C)C)cc2N(c2ccc3c(c2)C(C)(C)c2ccccc2-3)c2ccc3c(c2)C(C)(C)c2cccc(C(C)(C)C)c2-3)cc(C(C)(C)C)c1 ; Cc1cc(C)c(-c2ccccc2N(c2ccc3c(c2)C(C)(C)c2ccccc2-3)c2ccc3c(c2)C(C)(C)c2cccc(C(C)(C)C)c2-3)c(C)c1]

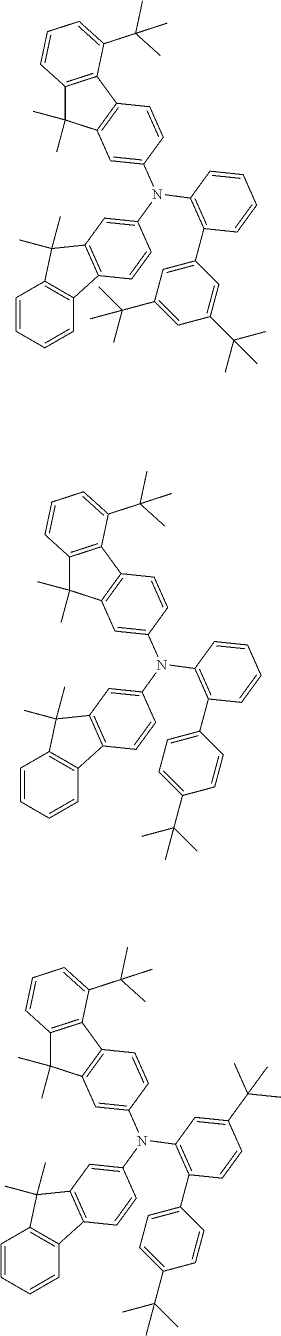 [SMILES: CC(C)(C)c1cc(-c2ccccc2N(c2ccc3c(c2)C(C)(C)c2ccccc2-3)c2ccc3c(c2)C(C)(C)c2cccc(C(C)(C)C)c2-3)cc(C(C)(C)C)c1 ; CC(C)(C)c1ccc(-c2ccccc2N(c2ccc3c(c2)C(C)(C)c2ccccc2-3)c2ccc3c(c2)C(C)(C)c2cccc(C(C)(C)C)c2-3)cc1 ; CC(C)(C)c1ccc(-c2ccc(C(C)(C)C)cc2N(c2ccc3c(c2)C(C)(C)c2ccccc2-3)c2ccc3c(c2)C(C)(C)c2cccc(C(C)(C)C)c2-3)cc1]

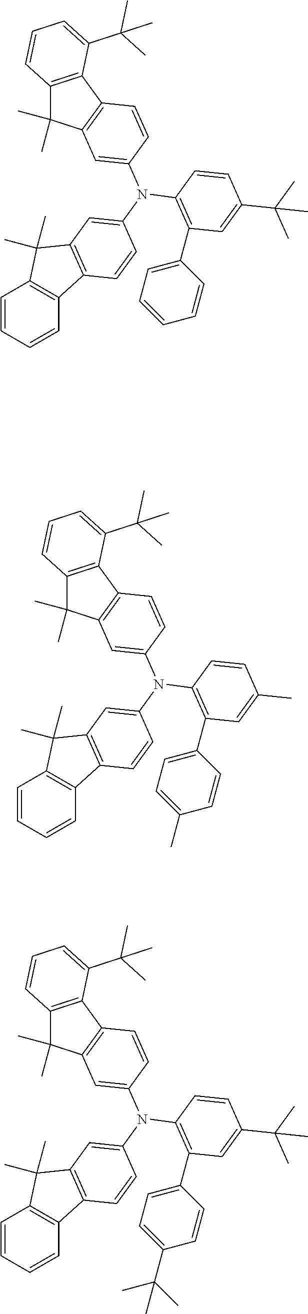 [SMILES: CC(C)(C)c1ccc(N(c2ccc3c(c2)C(C)(C)c2ccccc2-3)c2ccc3c(c2)C(C)(C)c2cccc(C(C)(C)C)c2-3)c(-c2ccccc2)c1 ; Cc1ccc(-c2cc(C)ccc2N(c2ccc3c(c2)C(C)(C)c2ccccc2-3)c2ccc3c(c2)C(C)(C)c2cccc(C(C)(C)C)c2-3)cc1 ; CC(C)(C)c1ccc(-c2cc(C(C)(C)C)ccc2N(c2ccc3c(c2)C(C)(C)c2ccccc2-3)c2ccc3c(c2)C(C)(C)c2cccc(C(C)(C)C)c2-3)cc1]

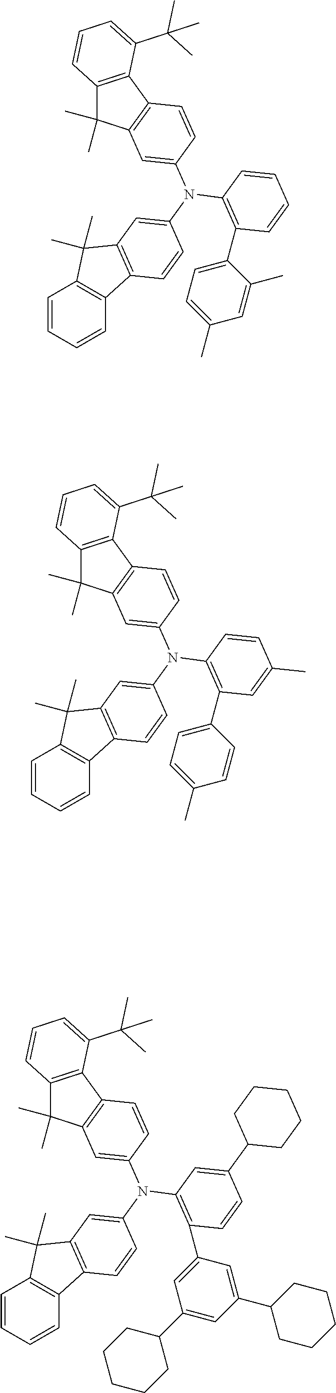 [SMILES: Cc1ccc(-c2ccccc2N(c2ccc3c(c2)C(C)(C)c2ccccc2-3)c2ccc3c(c2)C(C)(C)c2cccc(C(C)(C)C)c2-3)c(C)c1 ; Cc1ccc(-c2cc(C)ccc2N(c2ccc3c(c2)C(C)(C)c2ccccc2-3)c2ccc3c(c2)C(C)(C)c2cccc(C(C)(C)C)c2-3)cc1 ; CC(C)(C)c1cccc2c1-c1ccc(N(c3ccc4c(c3)C(C)(C)c3ccccc3-4)c3cc(C4CCCCC4)ccc3-c3cc(C4CCCCC4)cc(C4CCCCC4)c3)cc1C2(C)C]

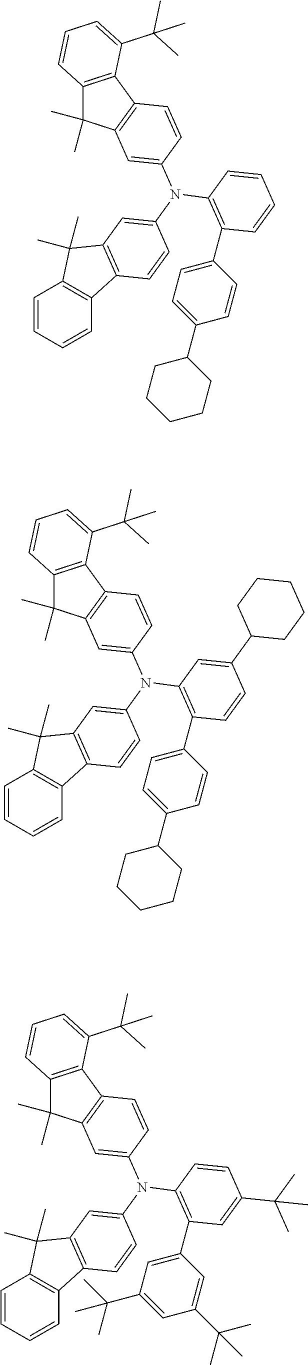 [SMILES: CC(C)(C)c1cccc2c1-c1ccc(N(c3ccc4c(c3)C(C)(C)c3ccccc3-4)c3ccccc3-c3ccc(C4CCCCC4)cc3)cc1C2(C)C ; CC(C)(C)c1cccc2c1-c1ccc(N(c3ccc4c(c3)C(C)(C)c3ccccc3-4)c3cc(C4CCCCC4)ccc3-c3ccc(C4CCCCC4)cc3)cc1C2(C)C ; CC(C)(C)c1cc(-c2cc(C(C)(C)C)ccc2N(c2ccc3c(c2)C(C)(C)c2ccccc2-3)c2ccc3c(c2)C(C)(C)c2cccc(C(C)(C)C)c2-3)cc(C(C)(C)C)c1]

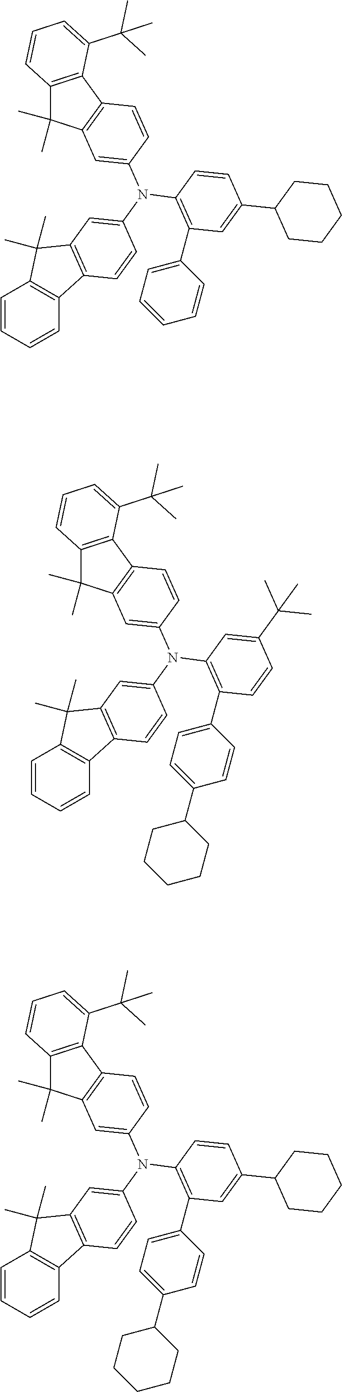 [SMILES: CC(C)(C)c1cccc2c1-c1ccc(N(c3ccc4c(c3)C(C)(C)c3ccccc3-4)c3ccc(C4CCCCC4)cc3-c3ccccc3)cc1C2(C)C ; CC(C)(C)c1ccc(-c2ccc(C3CCCCC3)cc2)c(N(c2ccc3c(c2)C(C)(C)c2ccccc2-3)c2ccc3c(c2)C(C)(C)c2cccc(C(C)(C)C)c2-3)c1 ; CC(C)(C)c1cccc2c1-c1ccc(N(c3ccc4c(c3)C(C)(C)c3ccccc3-4)c3ccc(C4CCCCC4)cc3-c3ccc(C4CCCCC4)cc3)cc1C2(C)C]

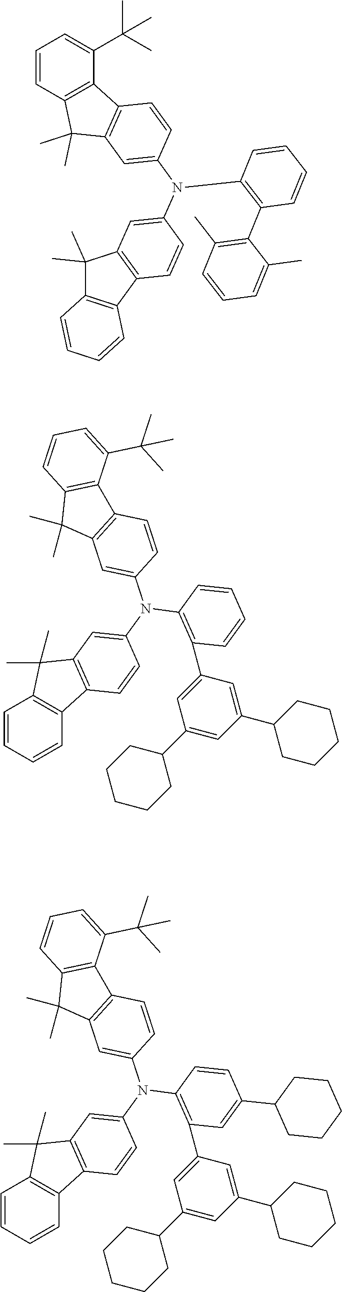 [SMILES: Cc1cccc(C)c1-c1ccccc1N(c1ccc2c(c1)C(C)(C)c1ccccc1-2)c1ccc2c(c1)C(C)(C)c1cccc(C(C)(C)C)c1-2 ; CC(C)(C)c1cccc2c1-c1ccc(N(c3ccc4c(c3)C(C)(C)c3ccccc3-4)c3ccccc3-c3cc(C4CCCCC4)cc(C4CCCCC4)c3)cc1C2(C)C ; CC(C)(C)c1cccc2c1-c1ccc(N(c3ccc4c(c3)C(C)(C)c3ccccc3-4)c3ccc(C4CCCCC4)cc3-c3cc(C4CCCCC4)cc(C4CCCCC4)c3)cc1C2(C)C]

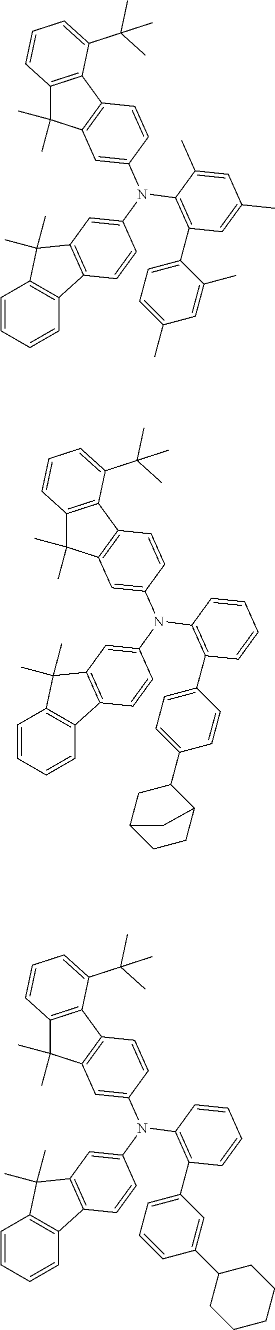 [SMILES: Cc1ccc(-c2cc(C)cc(C)c2N(c2ccc3c(c2)C(C)(C)c2ccccc2-3)c2ccc3c(c2)C(C)(C)c2cccc(C(C)(C)C)c2-3)c(C)c1 ; CC(C)(C)c1cccc2c1-c1ccc(N(c3ccc4c(c3)C(C)(C)c3ccccc3-4)c3ccccc3-c3ccc(C4CC5CCC4C5)cc3)cc1C2(C)C ; CC(C)(C)c1cccc2c1-c1ccc(N(c3ccc4c(c3)C(C)(C)c3ccccc3-4)c3ccccc3-c3cccc(C4CCCCC4)c3)cc1C2(C)C]

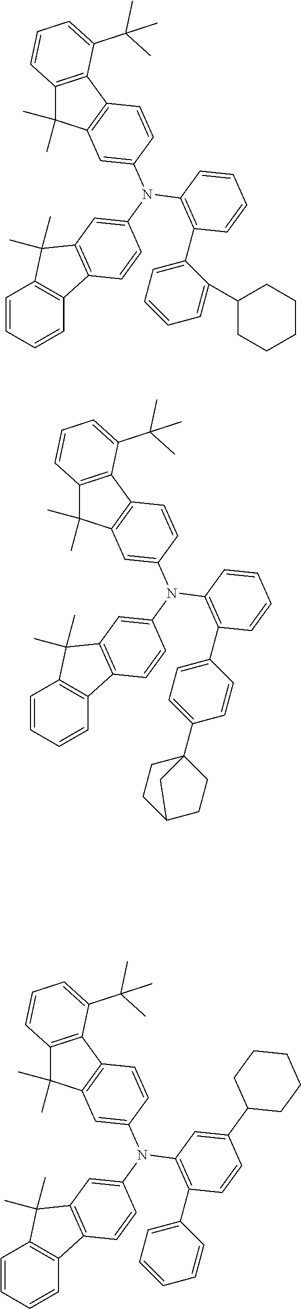 [SMILES: CC(C)(C)c1cccc2c1-c1ccc(N(c3ccc4c(c3)C(C)(C)c3ccccc3-4)c3ccccc3-c3ccccc3C3CCCCC3)cc1C2(C)C ; CC(C)(C)c1cccc2c1-c1ccc(N(c3ccc4c(c3)C(C)(C)c3ccccc3-4)c3ccccc3-c3ccc(C45CCC(CC4)C5)cc3)cc1C2(C)C ; CC(C)(C)c1cccc2c1-c1ccc(N(c3ccc4c(c3)C(C)(C)c3ccccc3-4)c3cc(C4CCCCC4)ccc3-c3ccccc3)cc1C2(C)C]

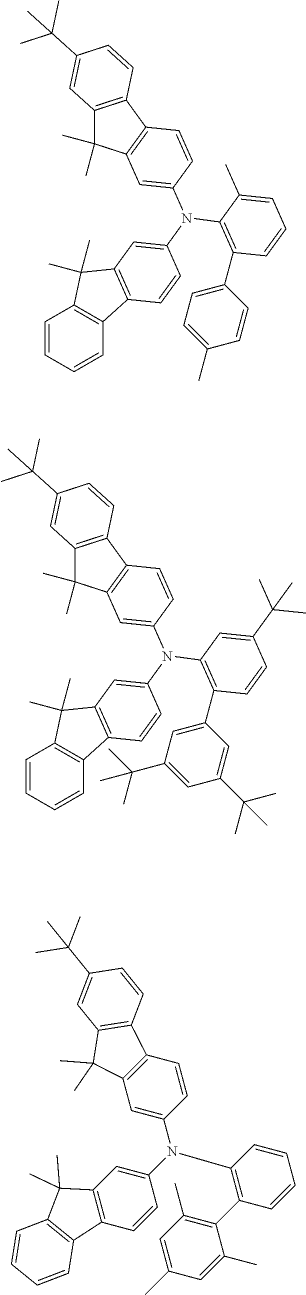 [SMILES: Cc1ccc(-c2cccc(C)c2N(c2ccc3c(c2)C(C)(C)c2ccccc2-3)c2ccc3c(c2)C(C)(C)c2cc(C(C)(C)C)ccc2-3)cc1 ; CC(C)(C)c1cc(-c2ccc(C(C)(C)C)cc2N(c2ccc3c(c2)C(C)(C)c2ccccc2-3)c2ccc3c(c2)C(C)(C)c2cc(C(C)(C)C)ccc2-3)cc(C(C)(C)C)c1 ; Cc1cc(C)c(-c2ccccc2N(c2ccc3c(c2)C(C)(C)c2ccccc2-3)c2ccc3c(c2)C(C)(C)c2cc(C(C)(C)C)ccc2-3)c(C)c1]

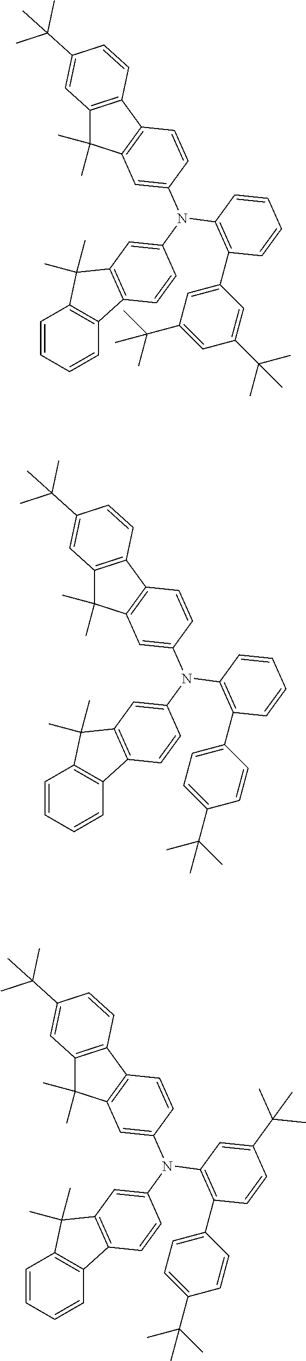

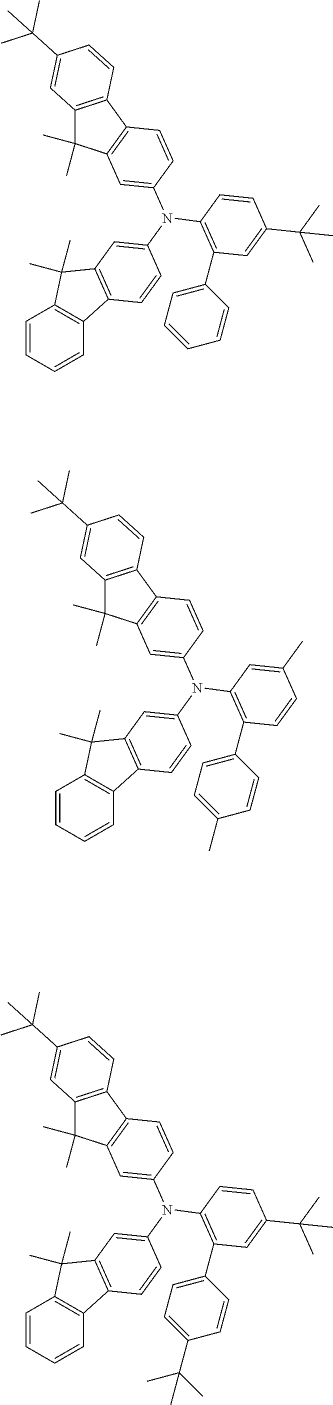

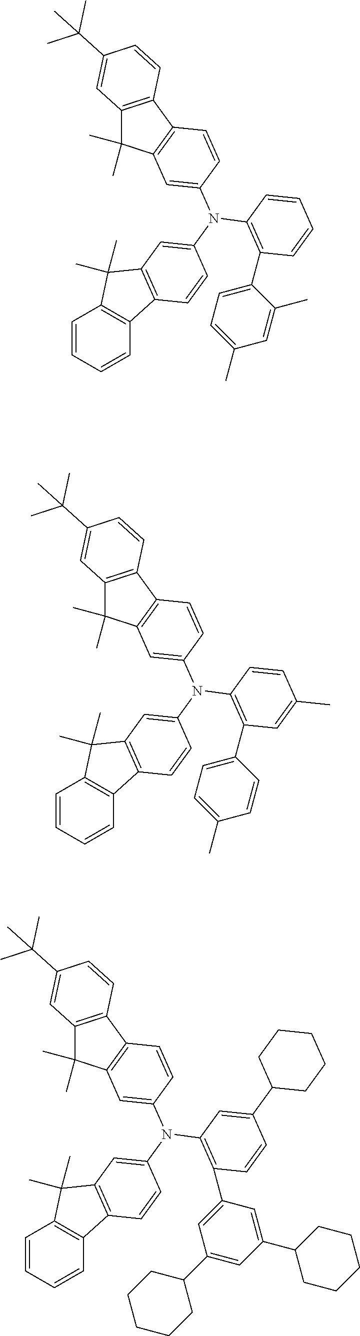

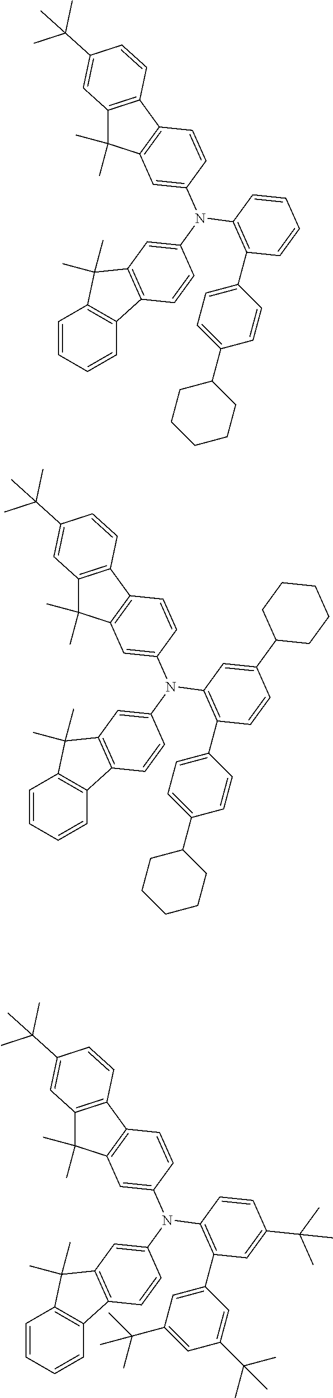 [SMILES: CC(C)(C)c1ccc2c(c1)C(C)(C)c1cc(N(c3ccc4c(c3)C(C)(C)c3ccccc3-4)c3ccccc3-c3ccc(C4CCCCC4)cc3)ccc1-2 ; CC(C)(C)c1ccc2c(c1)C(C)(C)c1cc(N(c3ccc4c(c3)C(C)(C)c3ccccc3-4)c3cc(C4CCCCC4)ccc3-c3ccc(C4CCCCC4)cc3)ccc1-2 ; CC(C)(C)c1cc(-c2cc(C(C)(C)C)ccc2N(c2ccc3c(c2)C(C)(C)c2ccccc2-3)c2ccc3c(c2)C(C)(C)c2cc(C(C)(C)C)ccc2-3)cc(C(C)(C)C)c1]

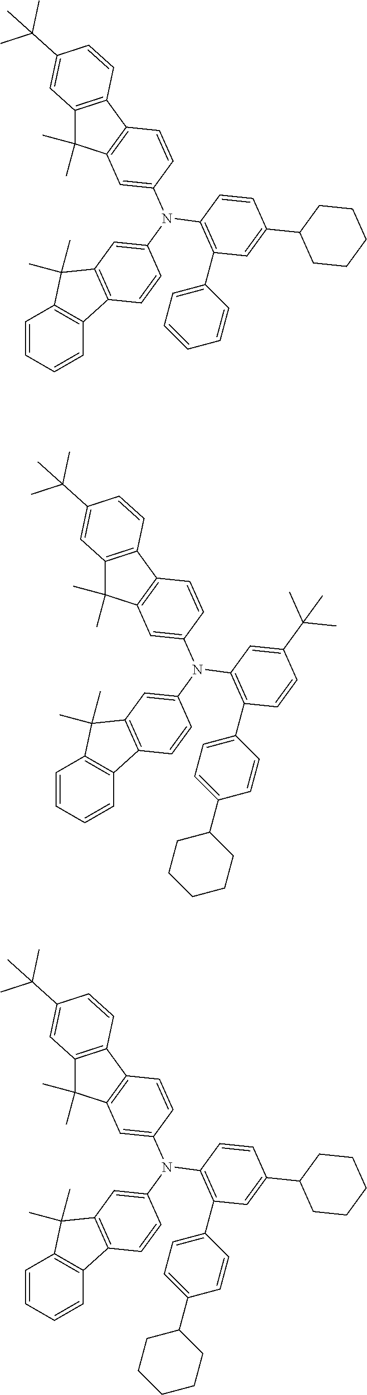

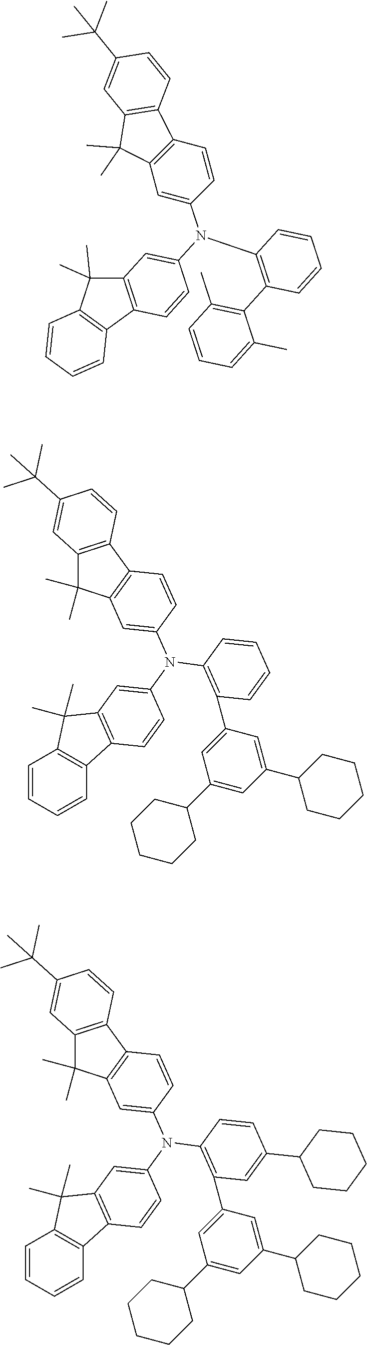 [SMILES: Cc1cccc(C)c1-c1ccccc1N(c1ccc2c(c1)C(C)(C)c1ccccc1-2)c1ccc2c(c1)C(C)(C)c1cc(C(C)(C)C)ccc1-2 ; CC(C)(C)c1ccc2c(c1)C(C)(C)c1cc(N(c3ccc4c(c3)C(C)(C)c3ccccc3-4)c3ccccc3-c3cc(C4CCCCC4)cc(C4CCCCC4)c3)ccc1-2 ; CC(C)(C)c1ccc2c(c1)C(C)(C)c1cc(N(c3ccc4c(c3)C(C)(C)c3ccccc3-4)c3ccc(C4CCCCC4)cc3-c3cc(C4CCCCC4)cc(C4CCCCC4)c3)ccc1-2]

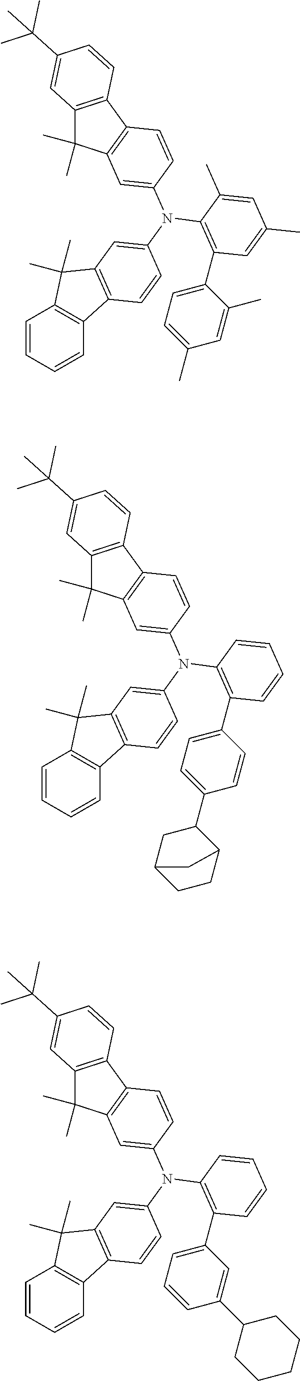

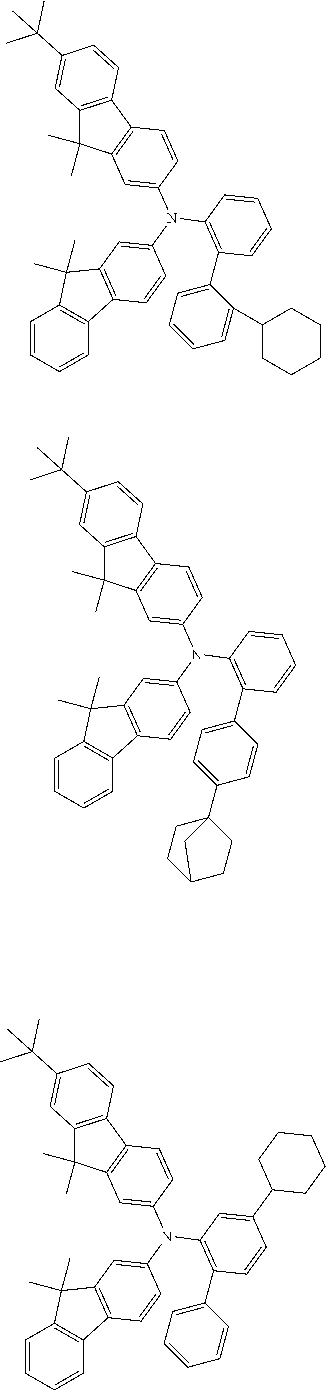 [SMILES: CC(C)(C)c1ccc2c(c1)C(C)(C)c1cc(N(c3ccc4c(c3)C(C)(C)c3ccccc3-4)c3ccccc3-c3ccccc3C3CCCCC3)ccc1-2 ; CC(C)(C)c1ccc2c(c1)C(C)(C)c1cc(N(c3ccc4c(c3)C(C)(C)c3ccccc3-4)c3ccccc3-c3ccc(C45CCC(CC4)C5)cc3)ccc1-2 ; CC(C)(C)c1ccc2c(c1)C(C)(C)c1cc(N(c3ccc4c(c3)C(C)(C)c3ccccc3-4)c3cc(C4CCCCC4)ccc3-c3ccccc3)ccc1-2]

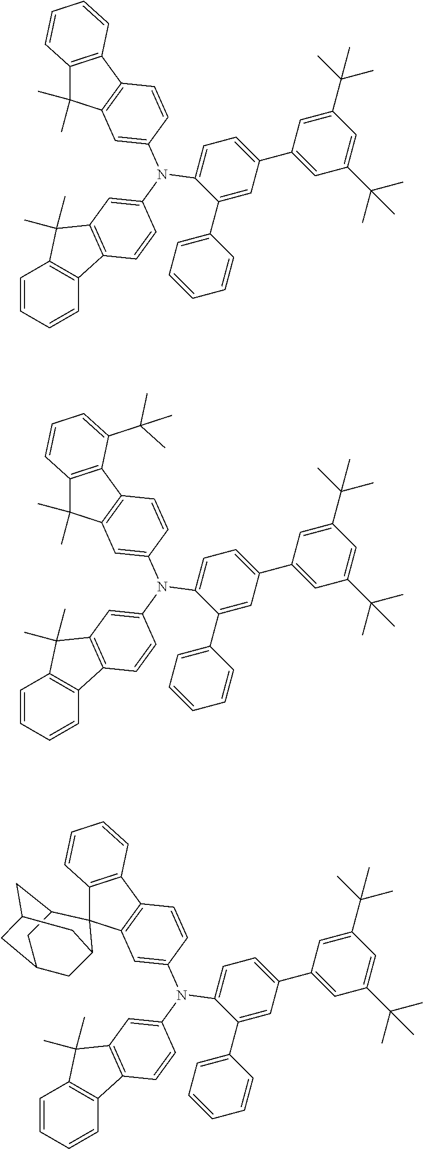 [SMILES: CC(C)(C)c1cc(-c2ccc(N(c3ccc4c(c3)C(C)(C)c3ccccc3-4)c3ccc4c(c3)C(C)(C)c3ccccc3-4)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C(C)(C)c3cccc(C(C)(C)C)c3-4)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C3(c5ccccc5-4)C4CC5CC(C4)CC3C5)c(-c3ccccc3)c2)cc(C(C)(C)C)c1]

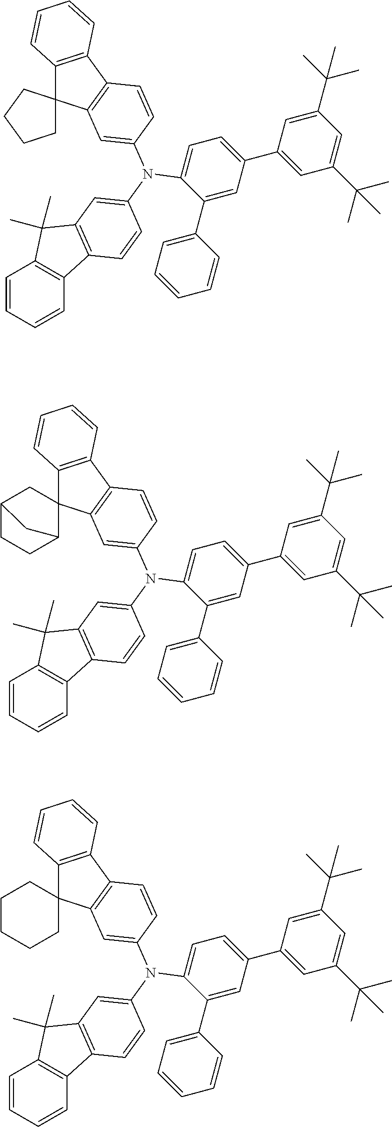 [SMILES: CC(C)(C)c1cc(-c2ccc(N(c3ccc4c(c3)C(C)(C)c3ccccc3-4)c3ccc4c(c3)C3(CCCC3)c3ccccc3-4)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C3(CC5CCC3C5)c3ccccc3-4)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C3(CCCCC3)c3ccccc3-4)c(-c3ccccc3)c2)cc(C(C)(C)C)c1]

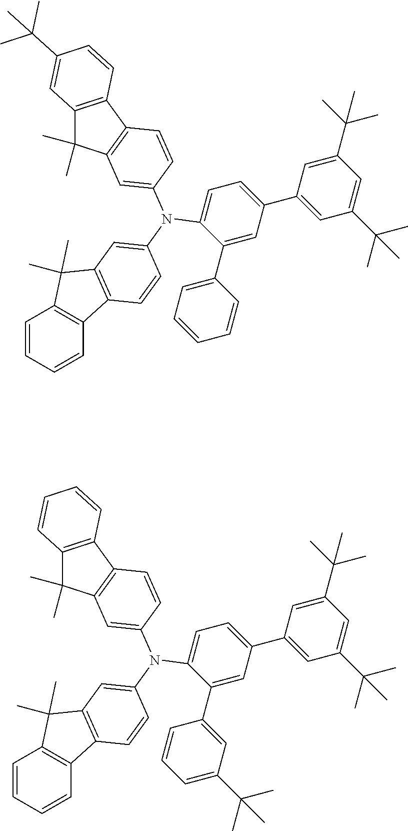 [SMILES: CC(C)(C)c1cc(-c2ccc(N(c3ccc4c(c3)C(C)(C)c3ccccc3-4)c3ccc4c(c3)C(C)(C)c3cc(C(C)(C)C)ccc3-4)c(-c3ccccc3)c2)cc(C(C)(C)C)c1 ; CC(C)(C)c1cccc(-c2cc(-c3cc(C(C)(C)C)cc(C(C)(C)C)c3)ccc2N(c2ccc3c(c2)C(C)(C)c2ccccc2-3)c2ccc3c(c2)C(C)(C)c2ccccc2-3)c1]

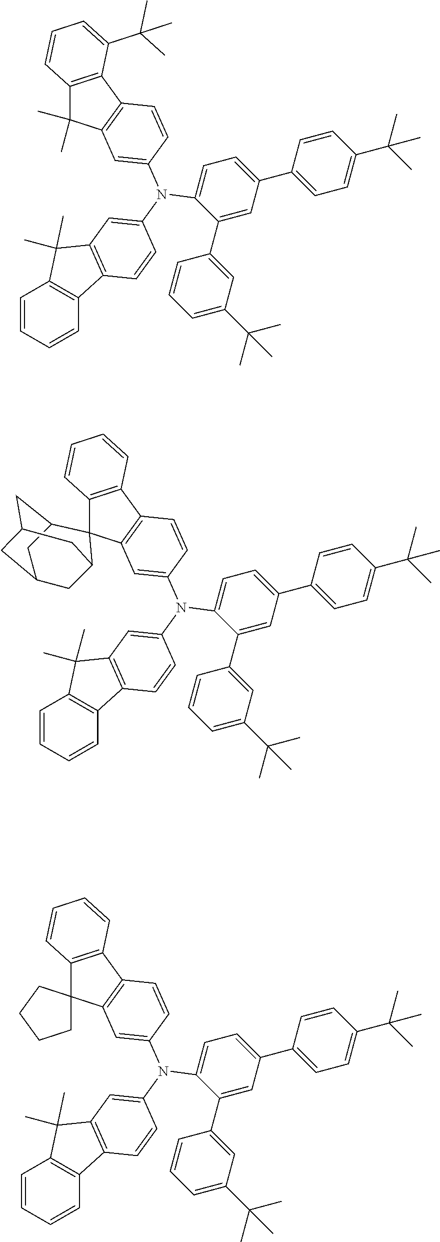 [SMILES: CC(C)(C)c1ccc(-c2ccc(N(c3ccc4c(c3)C(C)(C)c3ccccc3-4)c3ccc4c(c3)C(C)(C)c3cccc(C(C)(C)C)c3-4)c(-c3cccc(C(C)(C)C)c3)c2)cc1 ; CC(C)(C)c1ccc(-c2ccc(N(c3ccc4c(c3)C(C)(C)c3ccccc3-4)c3ccc4c(c3)C3(c5ccccc5-4)C4CC5CC(C4)CC3C5)c(-c3cccc(C(C)(C)C)c3)c2)cc1 ; CC(C)(C)c1ccc(-c2ccc(N(c3ccc4c(c3)C(C)(C)c3ccccc3-4)c3ccc4c(c3)C3(CCCC3)c3ccccc3-4)c(-c3cccc(C(C)(C)C)c3)c2)cc1]

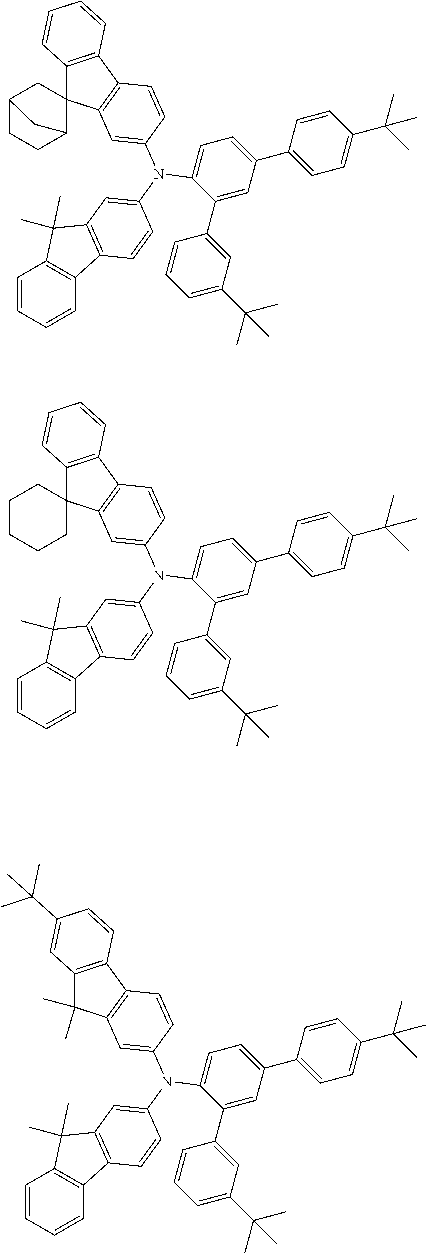

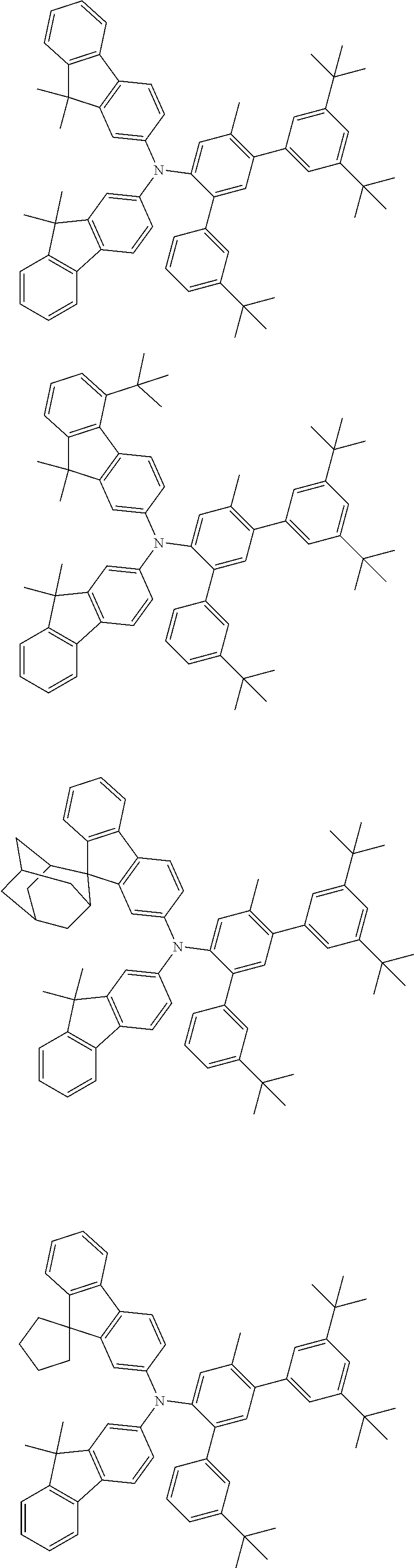

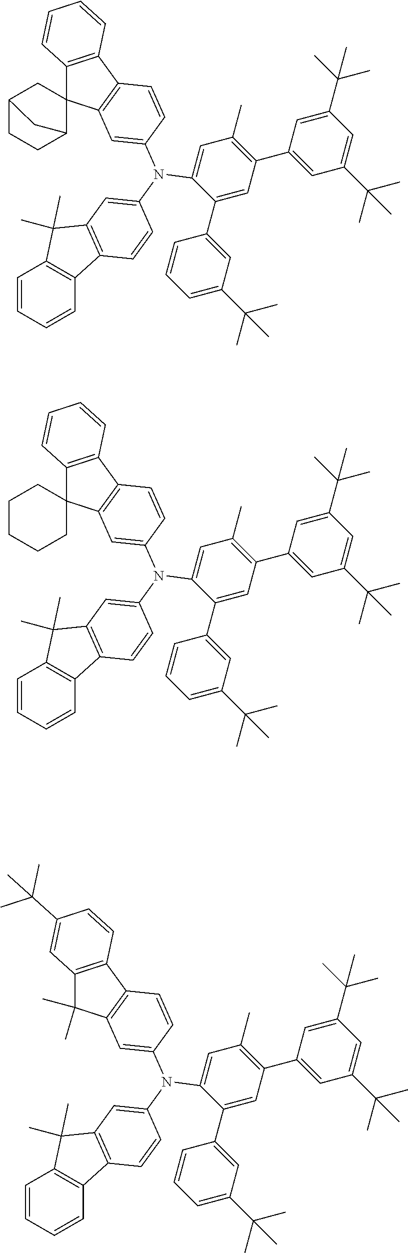

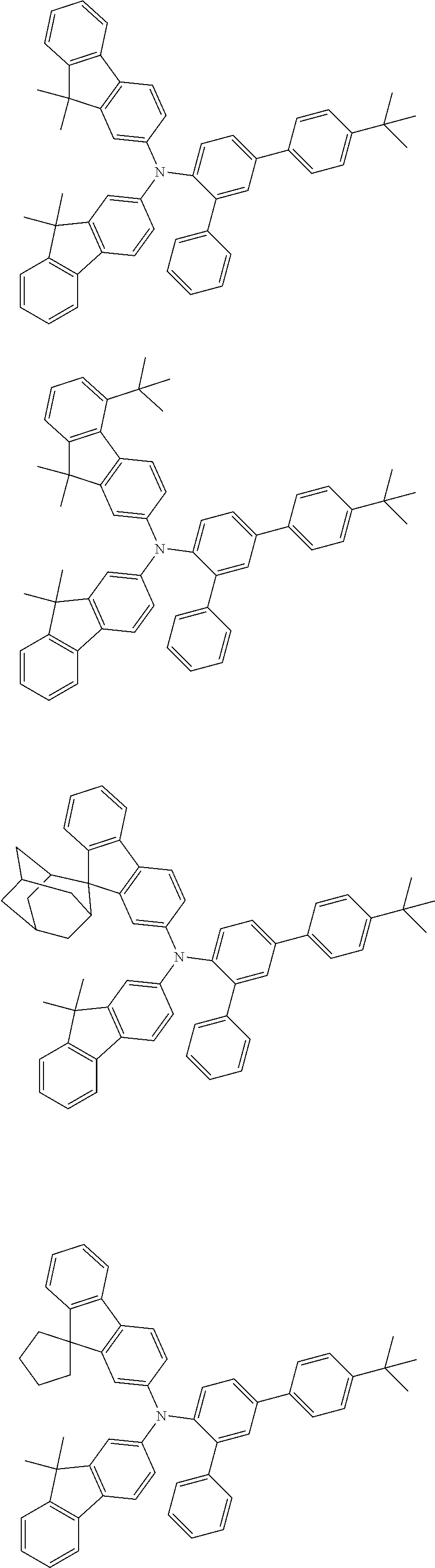 [SMILES: CC(C)(C)c1ccc(-c2ccc(N(c3ccc4c(c3)C(C)(C)c3ccccc3-4)c3ccc4c(c3)C(C)(C)c3ccccc3-4)c(-c3ccccc3)c2)cc1 ; CC(C)(C)c1ccc(-c2ccc(N(c3ccc4c(c3)C(C)(C)c3ccccc3-4)c3ccc4c(c3)C(C)(C)c3cccc(C(C)(C)C)c3-4)c(-c3ccccc3)c2)cc1 ; CC(C)(C)c1ccc(-c2ccc(N(c3ccc4c(c3)C(C)(C)c3ccccc3-4)c3ccc4c(c3)C3(c5ccccc5-4)C4CC5CC(C4)CC3C5)c(-c3ccccc3)c2)cc1 ; CC(C)(C)c1ccc(-c2ccc(N(c3ccc4c(c3)C(C)(C)c3ccccc3-4)c3ccc4c(c3)C3(CCCC3)c3ccccc3-4)c(-c3ccccc3)c2)cc1]

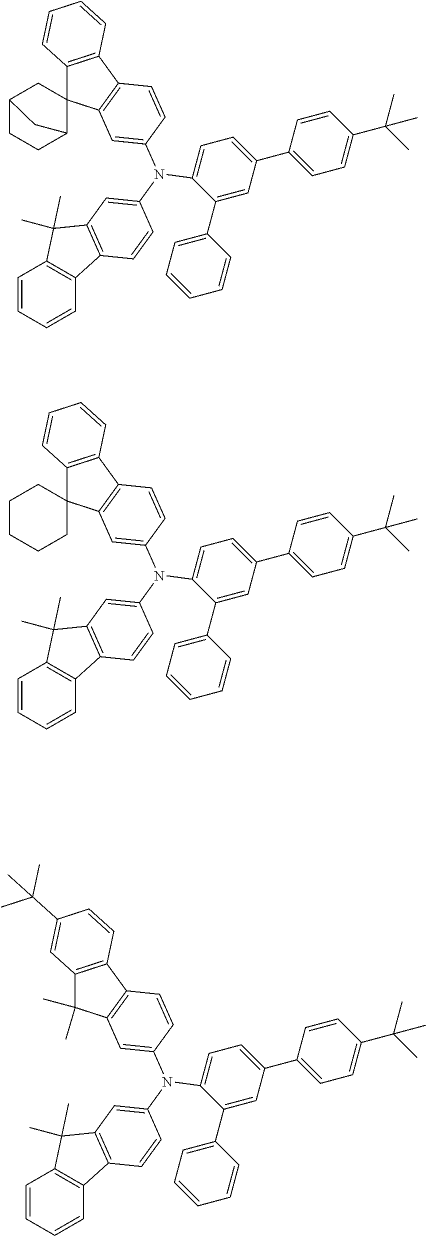

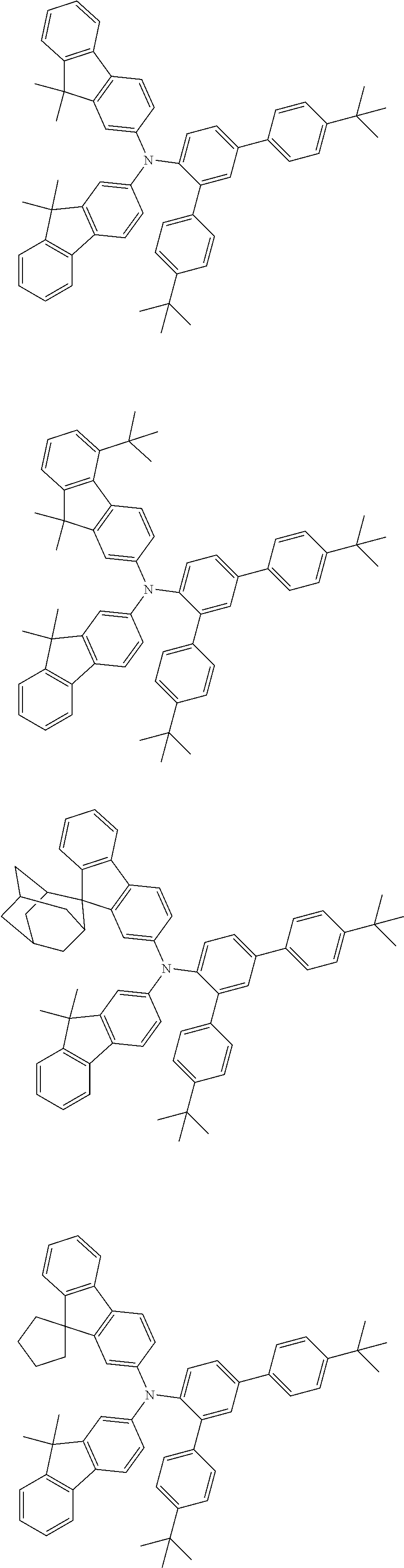 [SMILES: CC(C)(C)c1ccc(-c2ccc(N(c3ccc4c(c3)C(C)(C)c3ccccc3-4)c3ccc4c(c3)C(C)(C)c3ccccc3-4)c(-c3ccc(C(C)(C)C)cc3)c2)cc1 ; CC(C)(C)c1ccc(-c2ccc(N(c3ccc4c(c3)C(C)(C)c3ccccc3-4)c3ccc4c(c3)C(C)(C)c3cccc(C(C)(C)C)c3-4)c(-c3ccc(C(C)(C)C)cc3)c2)cc1 ; CC(C)(C)c1ccc(-c2ccc(N(c3ccc4c(c3)C(C)(C)c3ccccc3-4)c3ccc4c(c3)C3(c5ccccc5-4)C4CC5CC(C4)CC3C5)c(-c3ccc(C(C)(C)C)cc3)c2)cc1 ; CC(C)(C)c1ccc(-c2ccc(N(c3ccc4c(c3)C(C)(C)c3ccccc3-4)c3ccc4c(c3)C3(CCCC3)c3ccccc3-4)c(-c3ccc(C(C)(C)C)cc3)c2)cc1]

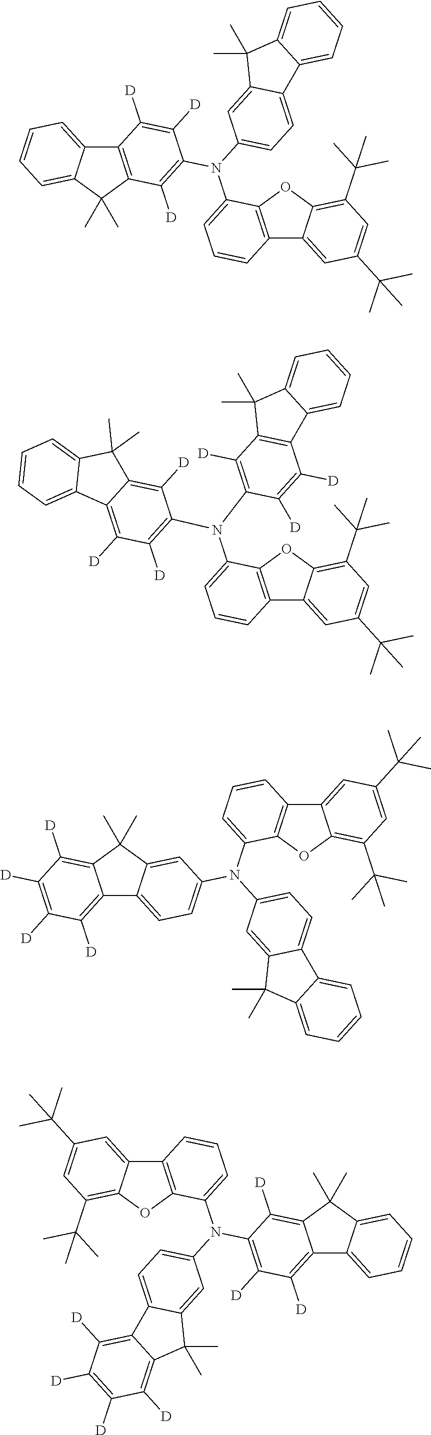

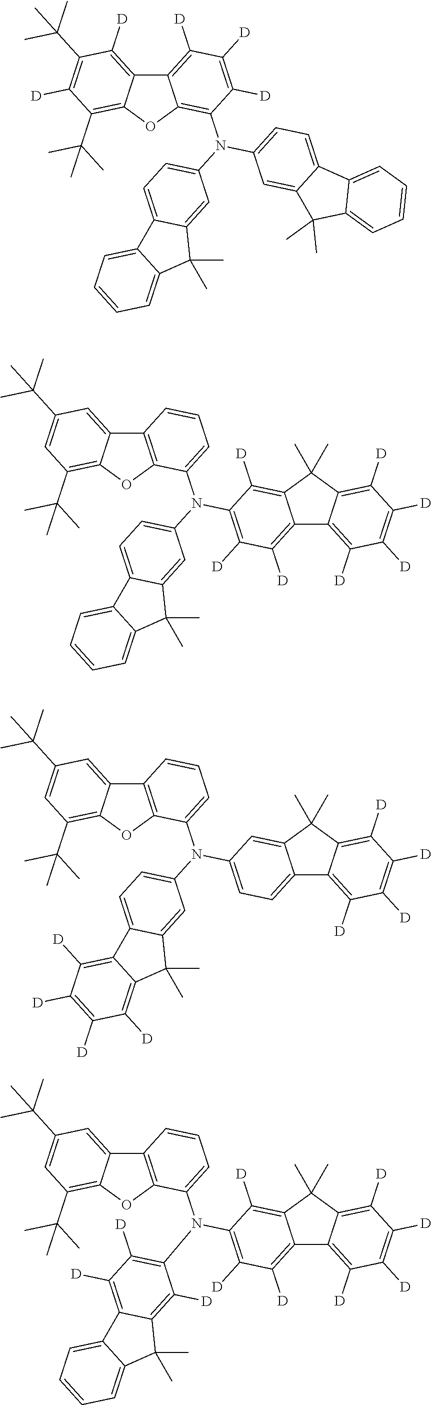

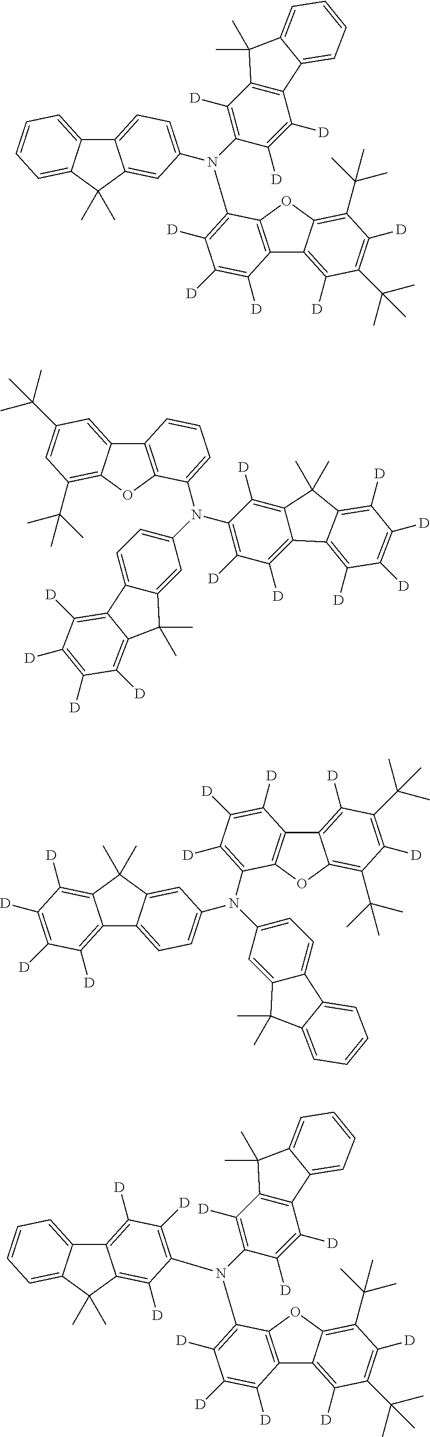

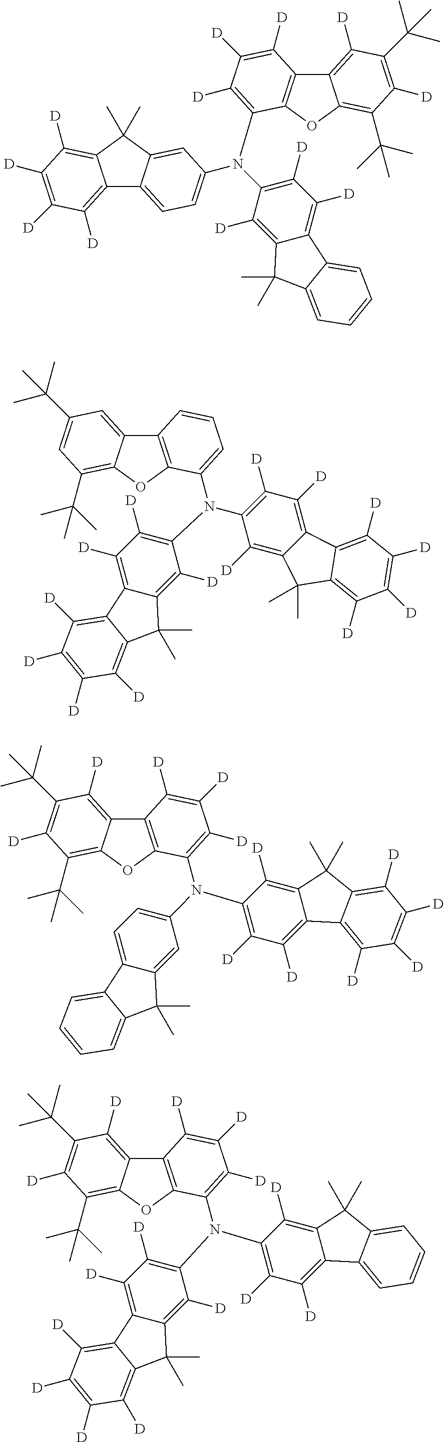

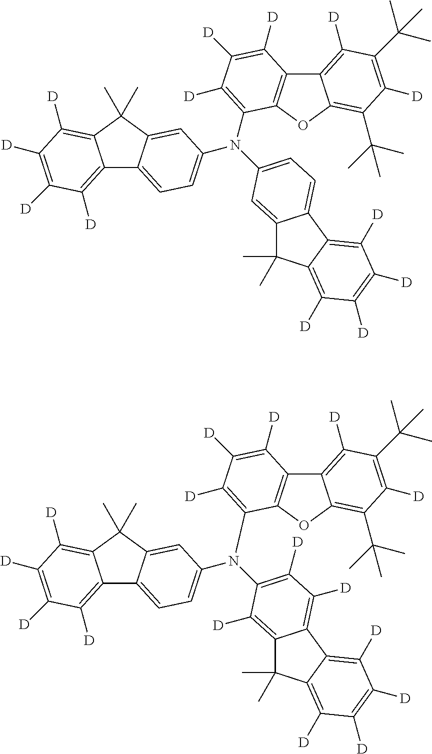 [SMILES: [2H]c1c([2H])c([2H])c2c(c1[2H])-c1ccc(N(c3ccc4c(c3)C(C)(C)c3c([2H])c([2H])c([2H])c([2H])c3-4)c3c([2H])c([2H])c([2H])c4c3oc3c(C(C)(C)C)c([2H])c(C(C)(C)C)c([2H])c34)cc1C2(C)C ; [2H]c1c([2H])c([2H])c2c(c1[2H])-c1ccc(N(c3c([2H])c([2H])c4c(c3[2H])C(C)(C)c3c([2H])c([2H])c([2H])c([2H])c3-4)c3c([2H])c([2H])c([2H])c4c3oc3c(C(C)(C)C)c([2H])c(C(C)(C)C)c([2H])c34)cc1C2(C)C]

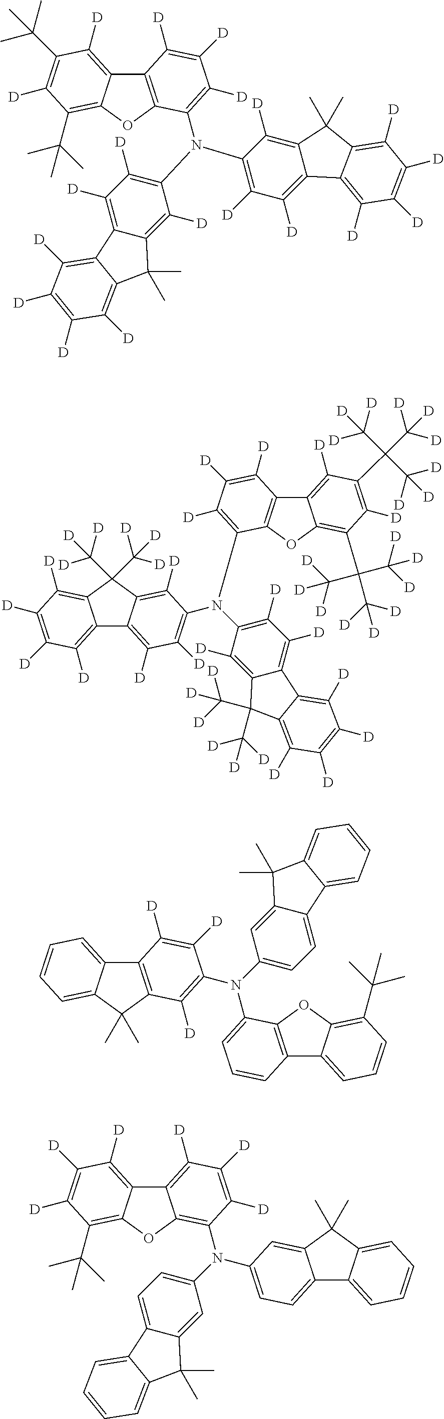

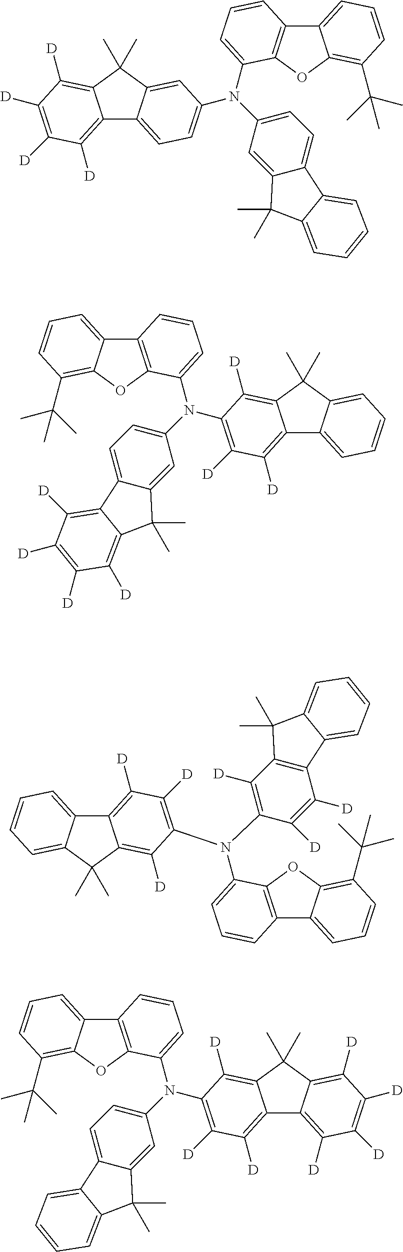

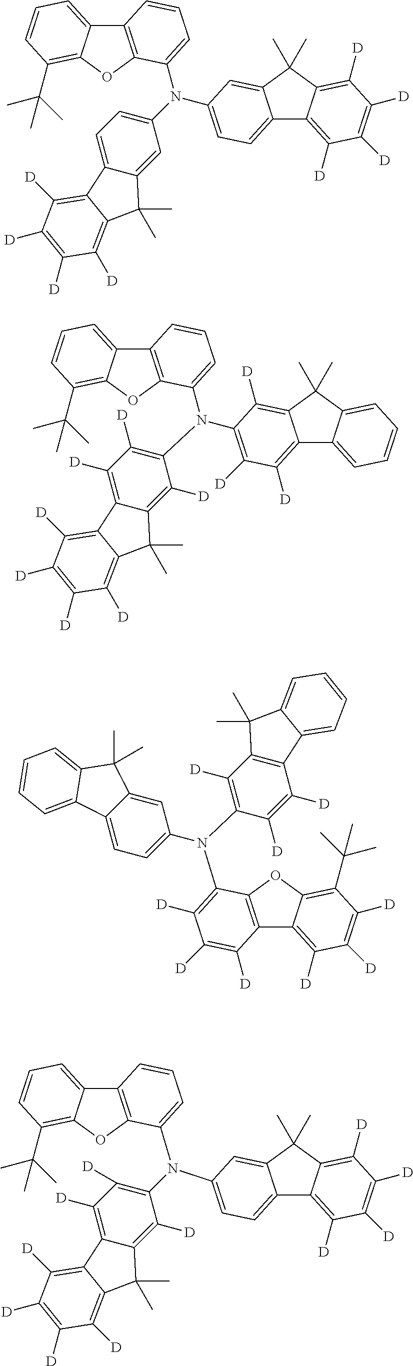

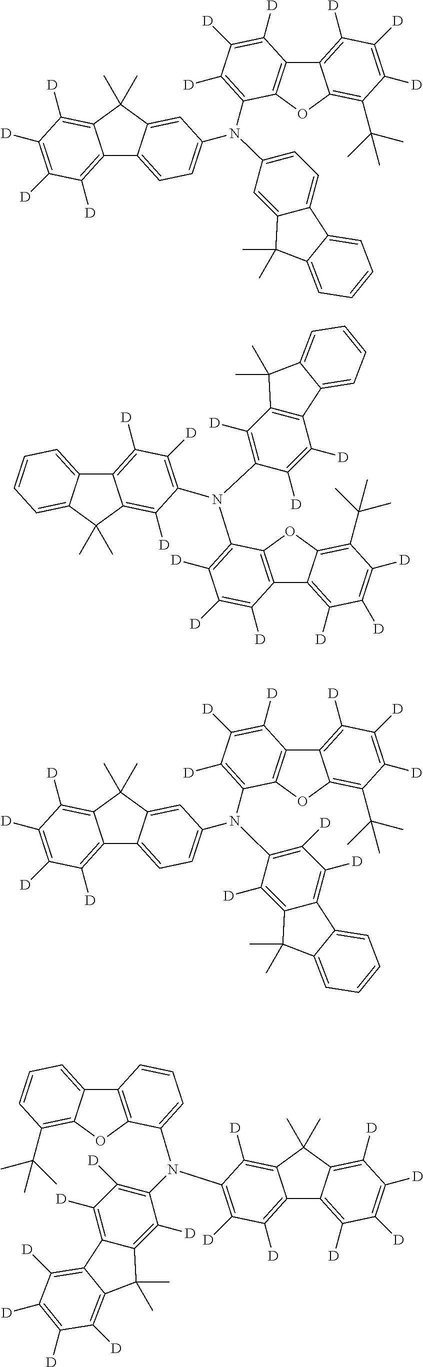

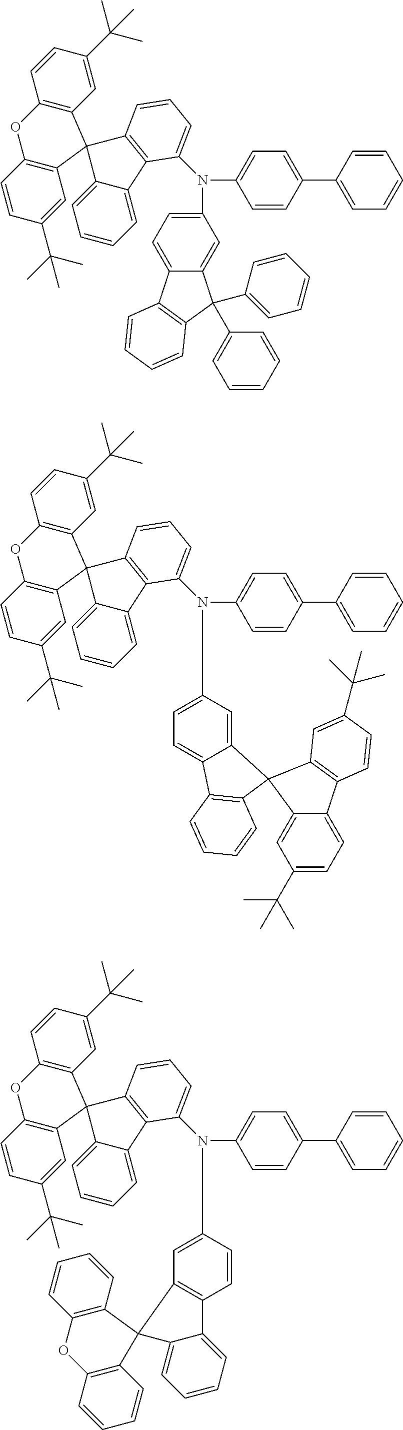 [SMILES: CC(C)(C)c1ccc2c(c1)C1(c3cc(C(C)(C)C)ccc3O2)c2ccccc2-c2c(N(c3ccc(-c4ccccc4)cc3)c3ccc4c(c3)C(c3ccccc3)(c3ccccc3)c3ccccc3-4)cccc21 ; CC(C)(C)c1ccc2c(c1)C1(c3cc(C(C)(C)C)ccc3O2)c2ccccc2-c2c(N(c3ccc(-c4ccccc4)cc3)c3ccc4c(c3)C3(c5ccccc5-4)c4cc(C(C)(C)C)ccc4-c4ccc(C(C)(C)C)cc43)cccc21 ; CC(C)(C)c1ccc2c(c1)C1(c3cc(C(C)(C)C)ccc3O2)c2ccccc2-c2c(N(c3ccc(-c4ccccc4)cc3)c3ccc4c(c3)C3(c5ccccc5Oc5ccccc53)c3ccccc3-4)cccc21]

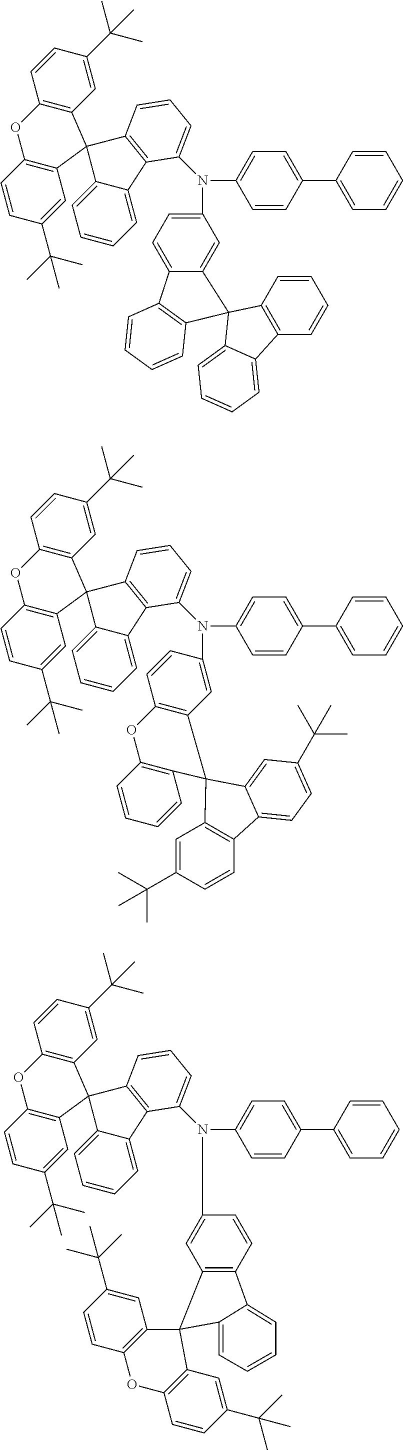

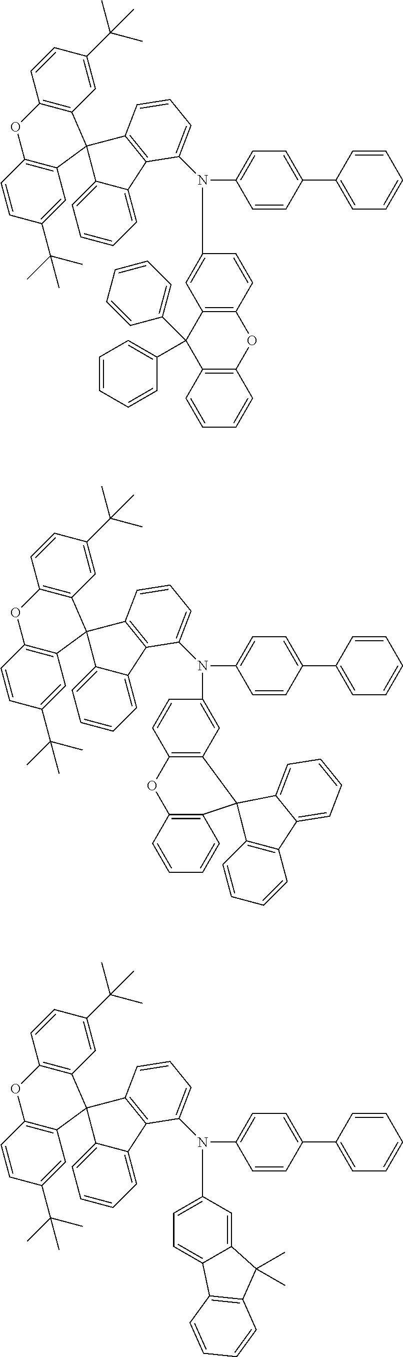 [SMILES: CC(C)(C)c1ccc2c(c1)C1(c3cc(C(C)(C)C)ccc3O2)c2ccccc2-c2c(N(c3ccc(-c4ccccc4)cc3)c3ccc4c(c3)C(c3ccccc3)(c3ccccc3)c3ccccc3O4)cccc21 ; CC(C)(C)c1ccc2c(c1)C1(c3cc(C(C)(C)C)ccc3O2)c2ccccc2-c2c(N(c3ccc(-c4ccccc4)cc3)c3ccc4c(c3)C3(c5ccccc5O4)c4ccccc4-c4ccccc43)cccc21 ; CC(C)(C)c1ccc2c(c1)C1(c3cc(C(C)(C)C)ccc3O2)c2ccccc2-c2c(N(c3ccc(-c4ccccc4)cc3)c3ccc4c(c3)C(C)(C)c3ccccc3-4)cccc21]

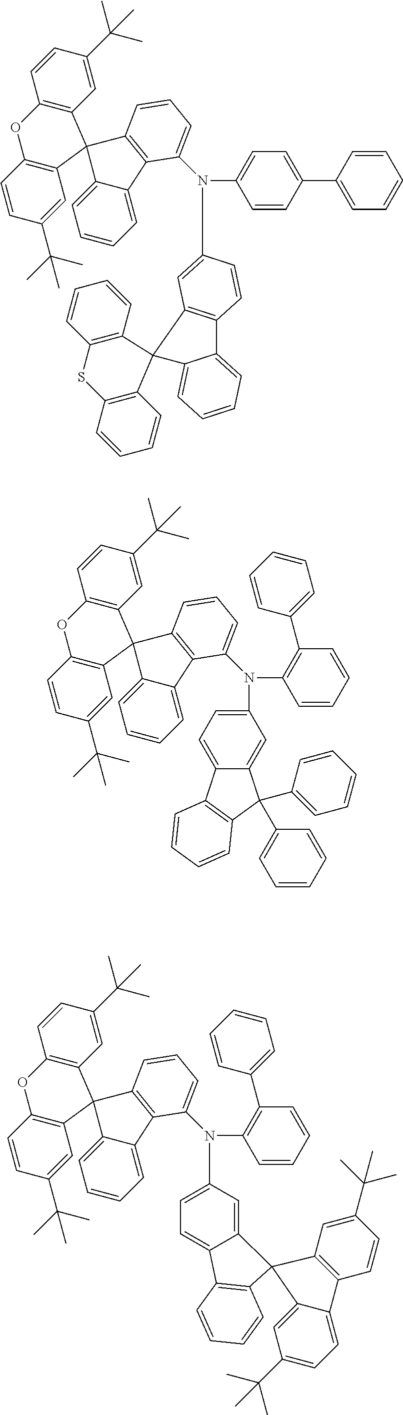 [SMILES: CC(C)(C)c1ccc2c(c1)C1(c3cc(C(C)(C)C)ccc3O2)c2ccccc2-c2c(N(c3ccc(-c4ccccc4)cc3)c3ccc4c(c3)C3(c5ccccc5Sc5ccccc53)c3ccccc3-4)cccc21 ; CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3-4)c3ccccc3-c3ccccc3)cccc21 ; CC(C)(C)c1ccc2c(c1)C1(c3cc(C(C)(C)C)ccc3O2)c2ccccc2-c2c(N(c3ccc4c(c3)C3(c5ccccc5-4)c4cc(C(C)(C)C)ccc4-c4ccc(C(C)(C)C)cc43)c3ccccc3-c3ccccc3)cccc21]

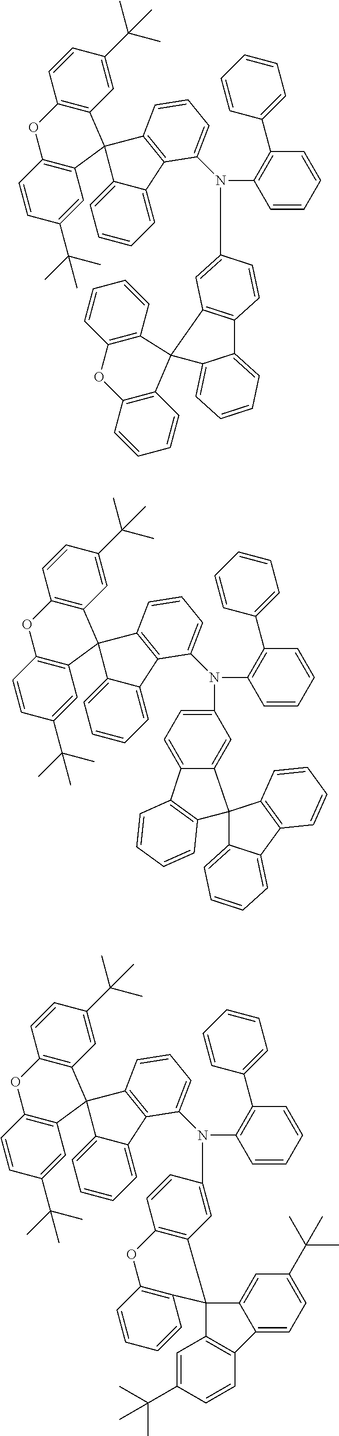 [SMILES: CC(C)(C)c1ccc2c(c1)C1(c3cc(C(C)(C)C)ccc3O2)c2ccccc2-c2c(N(c3ccc4c(c3)C3(c5ccccc5Oc5ccccc53)c3ccccc3-4)c3ccccc3-c3ccccc3)cccc21 ; CC(C)(C)c1ccc2c(c1)C1(c3cc(C(C)(C)C)ccc3O2)c2ccccc2-c2c(N(c3ccc4c(c3)C3(c5ccccc5-c5ccccc53)c3ccccc3-4)c3ccccc3-c3ccccc3)cccc21 ; CC(C)(C)c1ccc2c(c1)C1(c3cc(C(C)(C)C)ccc3O2)c2ccccc2-c2c(N(c3ccc4c(c3)C3(c5ccccc5O4)c4cc(C(C)(C)C)ccc4-c4ccc(C(C)(C)C)cc43)c3ccccc3-c3ccccc3)cccc21]

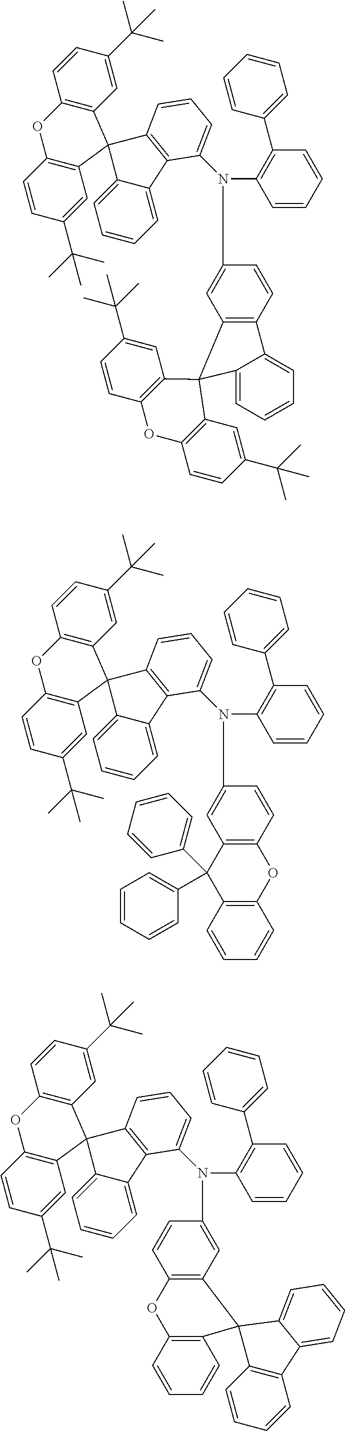 [SMILES: CC(C)(C)c1ccc2c(c1)C1(c3cc(C(C)(C)C)ccc3O2)c2ccccc2-c2ccc(N(c3ccccc3-c3ccccc3)c3cccc4c3-c3ccccc3C43c4cc(C(C)(C)C)ccc4Oc4ccc(C(C)(C)C)cc43)cc21 ; CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3O4)c3ccccc3-c3ccccc3)cccc21 ; CC(C)(C)c1ccc2c(c1)C1(c3cc(C(C)(C)C)ccc3O2)c2ccccc2-c2c(N(c3ccc4c(c3)C3(c5ccccc5O4)c4ccccc4-c4ccccc43)c3ccccc3-c3ccccc3)cccc21]

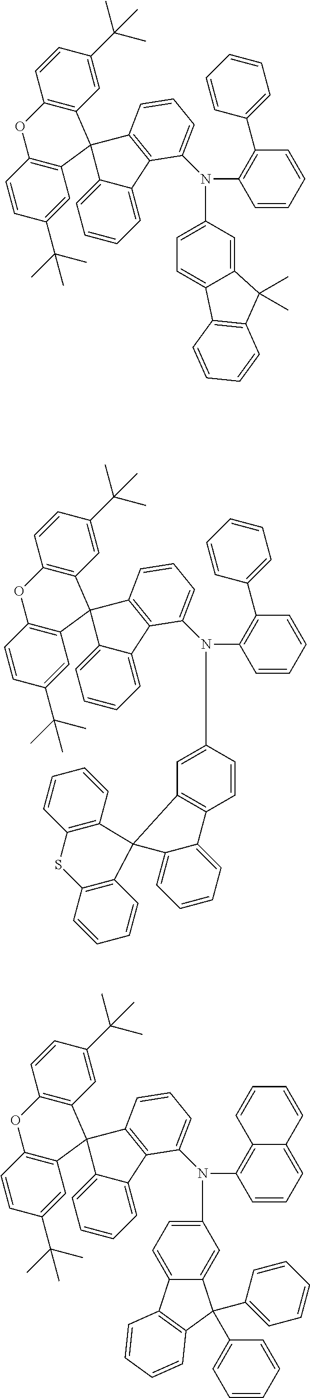 [SMILES: CC(C)(C)c1ccc2c(c1)C1(c3cc(C(C)(C)C)ccc3O2)c2ccccc2-c2c(N(c3ccc4c(c3)C(C)(C)c3ccccc3-4)c3ccccc3-c3ccccc3)cccc21 ; CC(C)(C)c1ccc2c(c1)C1(c3cc(C(C)(C)C)ccc3O2)c2ccccc2-c2c(N(c3ccc4c(c3)C3(c5ccccc5Sc5ccccc53)c3ccccc3-4)c3ccccc3-c3ccccc3)cccc21 ; CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3-4)c3cccc4ccccc34)cccc21]

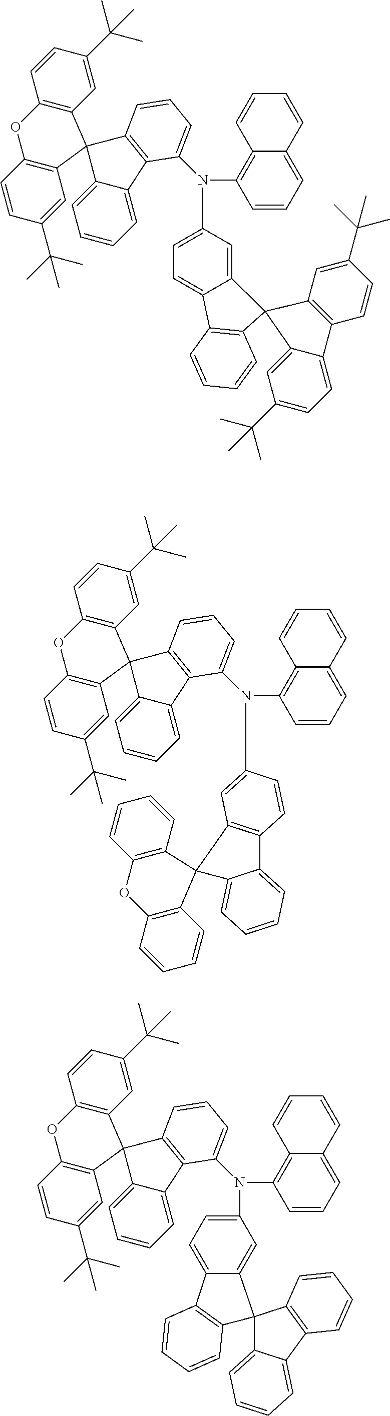

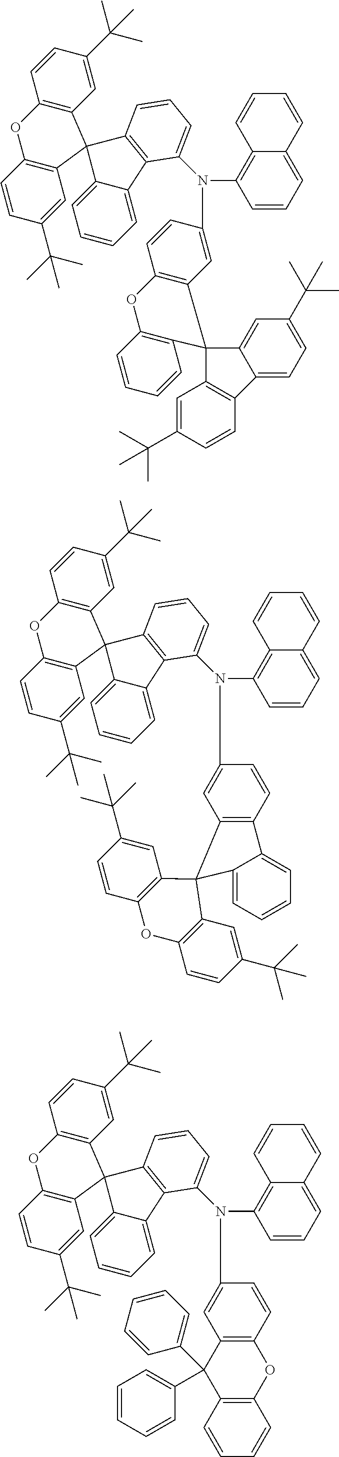

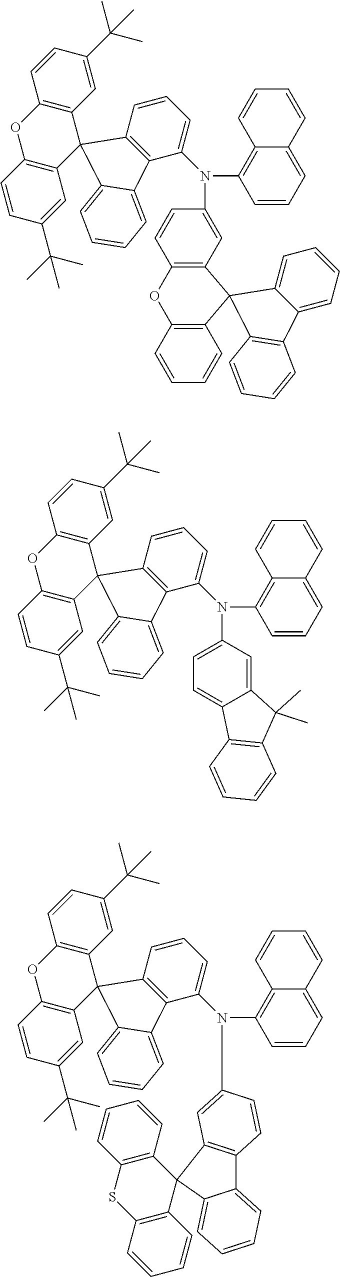 [SMILES: CC(C)(C)c1ccc2c(c1)C1(c3cc(C(C)(C)C)ccc3O2)c2ccccc2-c2c(N(c3ccc4c(c3)C3(c5ccccc5O4)c4ccccc4-c4ccccc43)c3cccc4ccccc34)cccc21 ; CC(C)(C)c1ccc2c(c1)C1(c3cc(C(C)(C)C)ccc3O2)c2ccccc2-c2c(N(c3ccc4c(c3)C(C)(C)c3ccccc3-4)c3cccc4ccccc34)cccc21 ; CC(C)(C)c1ccc2c(c1)C1(c3cc(C(C)(C)C)ccc3O2)c2ccccc2-c2c(N(c3ccc4c(c3)C3(c5ccccc5Sc5ccccc53)c3ccccc3-4)c3cccc4ccccc34)cccc21]

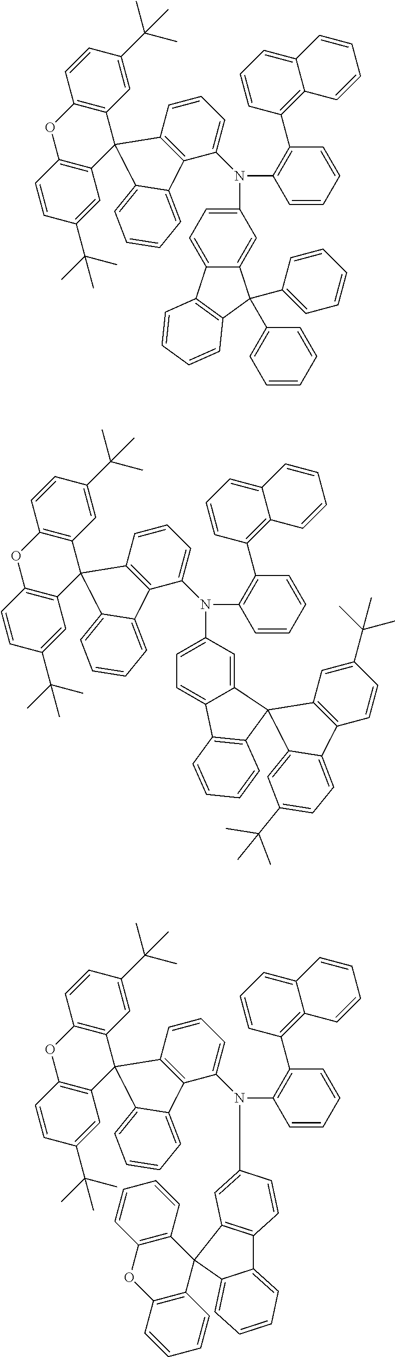 [SMILES: CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3-4)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C3(c5ccccc5-4)c4cc(C(C)(C)C)ccc4-c4ccc(C(C)(C)C)cc43)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C3(c5ccccc5Oc5ccccc53)c3ccccc3-4)c3ccccc3-c3cccc4ccccc34)cccc21]

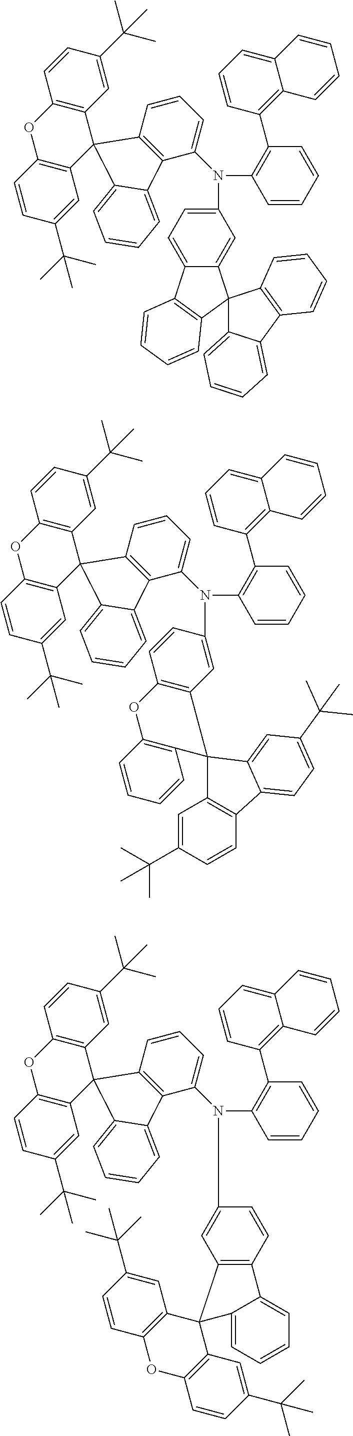 [SMILES: CC(C)(C)c1ccc2c(c1)C1(c3cc(C(C)(C)C)ccc3O2)c2ccccc2-c2c(N(c3ccc4c(c3)C3(c5ccccc5-c5ccccc53)c3ccccc3-4)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C3(c5ccccc5O4)c4cc(C(C)(C)C)ccc4-c4ccc(C(C)(C)C)cc43)c3ccccc3-c3cccc4ccccc34)cccc21 ; CC(C)(C)c1ccc2c(c1)C1(c3cc(C(C)(C)C)ccc3O2)c2ccccc2-c2ccc(N(c3ccccc3-c3cccc4ccccc34)c3cccc4c3-c3ccccc3C43c4cc(C(C)(C)C)ccc4Oc4ccc(C(C)(C)C)cc43)cc21]

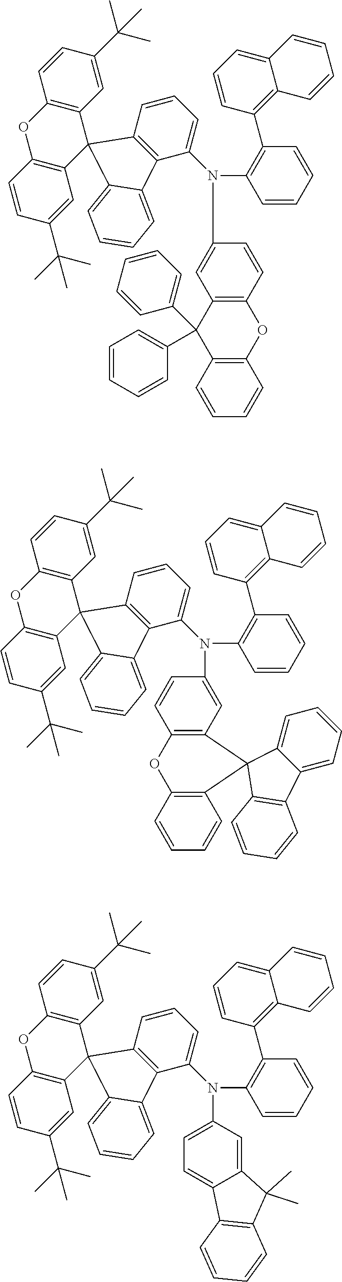 [SMILES: CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3O4)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C3(c5ccccc5O4)c4ccccc4-c4ccccc43)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C(C)(C)c3ccccc3-4)c3ccccc3-c3cccc4ccccc34)cccc21]

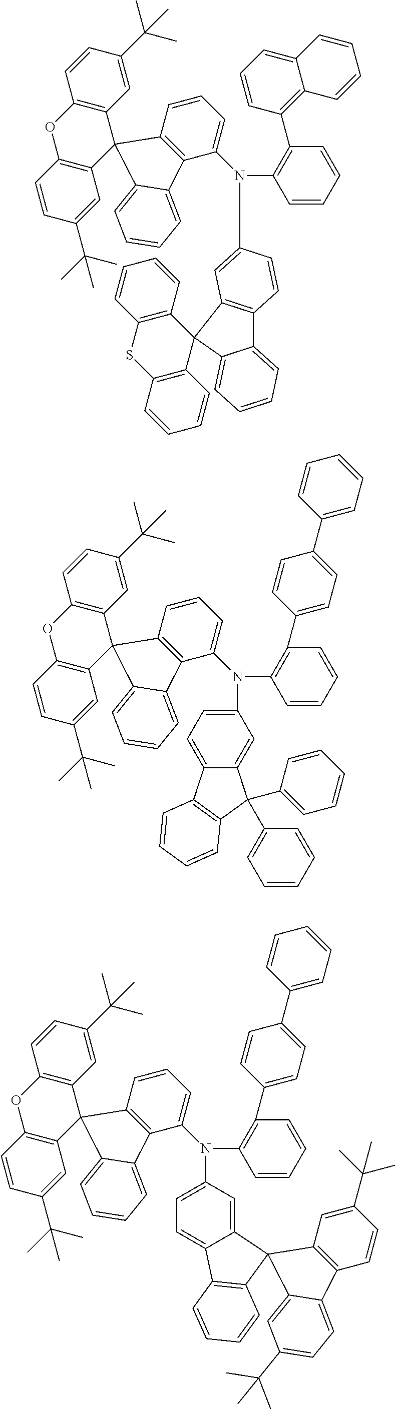

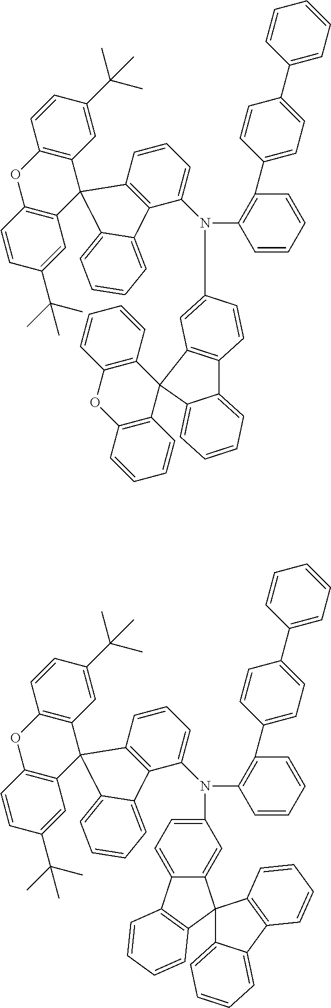 [SMILES: CC(C)(C)c1ccc2c(c1)C1(c3cc(C(C)(C)C)ccc3O2)c2ccccc2-c2c(N(c3ccc4c(c3)C3(c5ccccc5Oc5ccccc53)c3ccccc3-4)c3ccccc3-c3ccc(-c4ccccc4)cc3)cccc21 ; CC(C)(C)c1ccc2c(c1)C1(c3cc(C(C)(C)C)ccc3O2)c2ccccc2-c2c(N(c3ccc4c(c3)C3(c5ccccc5-c5ccccc53)c3ccccc3-4)c3ccccc3-c3ccc(-c4ccccc4)cc3)cccc21]

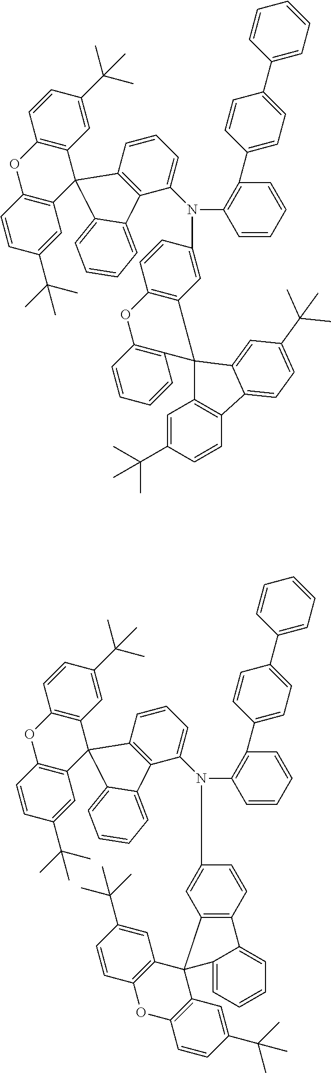 [SMILES: CC(C)(C)c1ccc2c(c1)C1(c3cc(C(C)(C)C)ccc3O2)c2ccccc2-c2c(N(c3ccc4c(c3)C3(c5ccccc5O4)c4cc(C(C)(C)C)ccc4-c4ccc(C(C)(C)C)cc43)c3ccccc3-c3ccc(-c4ccccc4)cc3)cccc21 ; CC(C)(C)c1ccc2c(c1)C1(c3cc(C(C)(C)C)ccc3O2)c2ccccc2-c2ccc(N(c3ccccc3-c3ccc(-c4ccccc4)cc3)c3cccc4c3-c3ccccc3C43c4cc(C(C)(C)C)ccc4Oc4ccc(C(C)(C)C)cc43)cc21]

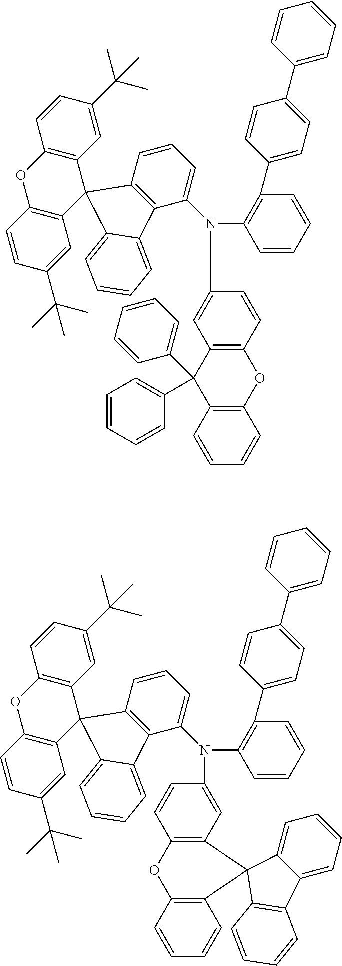 [SMILES: CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3O4)c3ccccc3-c3ccc(-c4ccccc4)cc3)cccc21 ; CC(C)(C)c1ccc2c(c1)C1(c3cc(C(C)(C)C)ccc3O2)c2ccccc2-c2c(N(c3ccc4c(c3)C3(c5ccccc5O4)c4ccccc4-c4ccccc43)c3ccccc3-c3ccc(-c4ccccc4)cc3)cccc21]

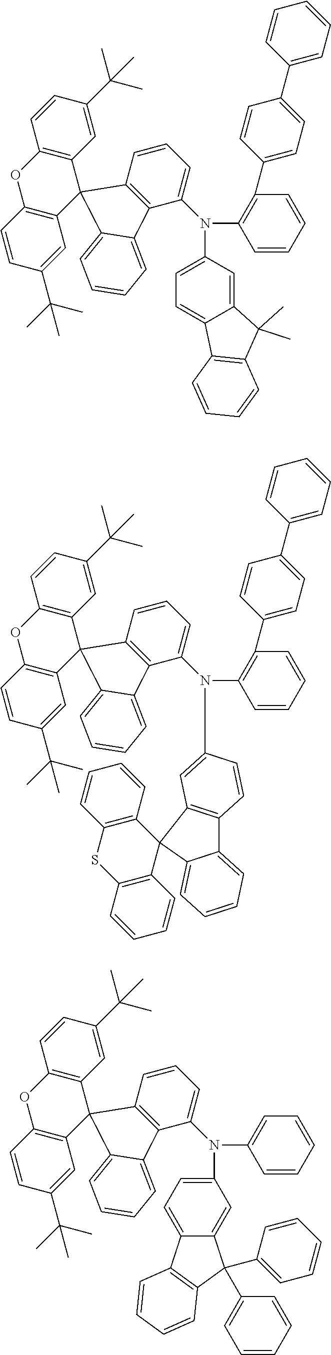

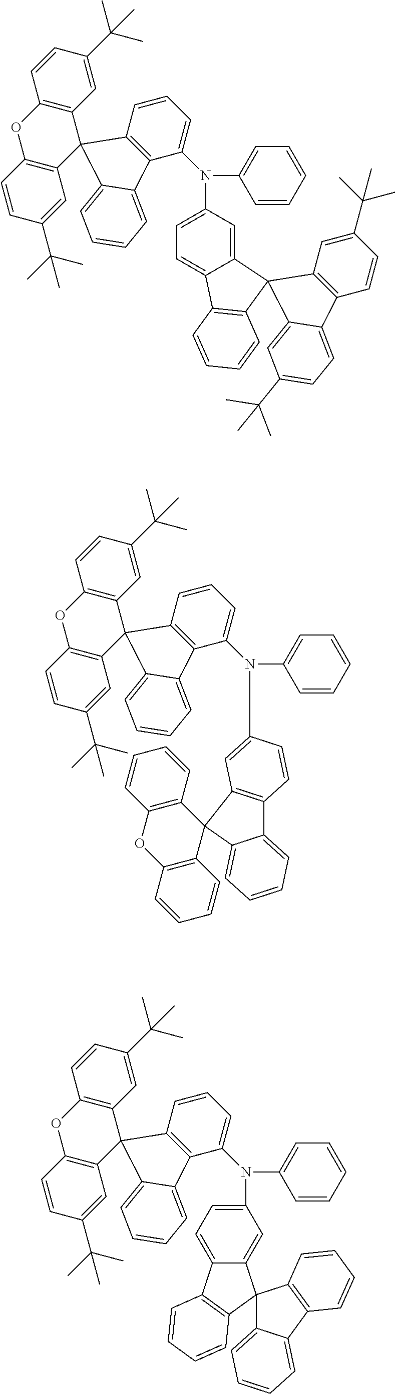 [SMILES: CC(C)(C)c1ccc2c(c1)C1(c3cc(C(C)(C)C)ccc3O2)c2ccccc2-c2c(N(c3ccccc3)c3ccc4c(c3)C3(c5ccccc5-4)c4cc(C(C)(C)C)ccc4-c4ccc(C(C)(C)C)cc43)cccc21 ; CC(C)(C)c1ccc2c(c1)C1(c3cc(C(C)(C)C)ccc3O2)c2ccccc2-c2c(N(c3ccccc3)c3ccc4c(c3)C3(c5ccccc5Oc5ccccc53)c3ccccc3-4)cccc21 ; CC(C)(C)c1ccc2c(c1)C1(c3cc(C(C)(C)C)ccc3O2)c2ccccc2-c2c(N(c3ccccc3)c3ccc4c(c3)C3(c5ccccc5-c5ccccc53)c3ccccc3-4)cccc21]

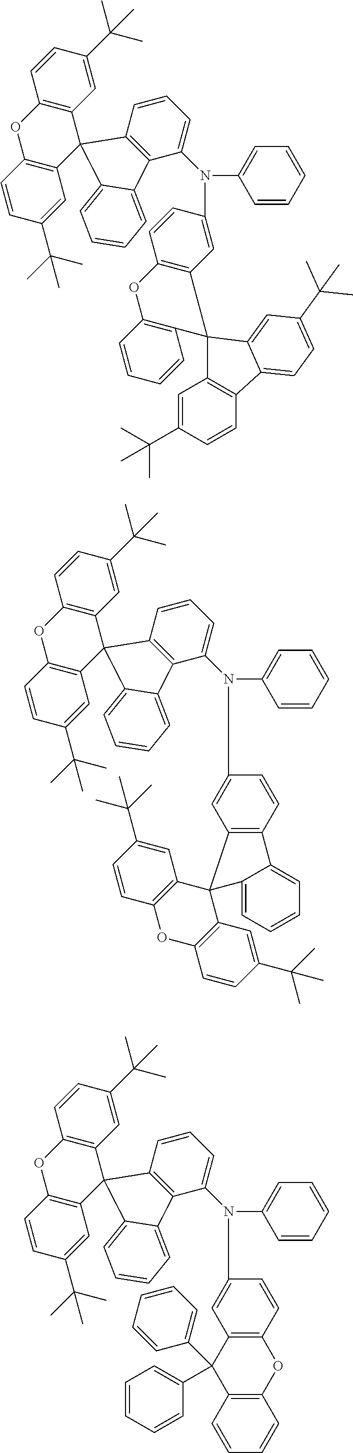

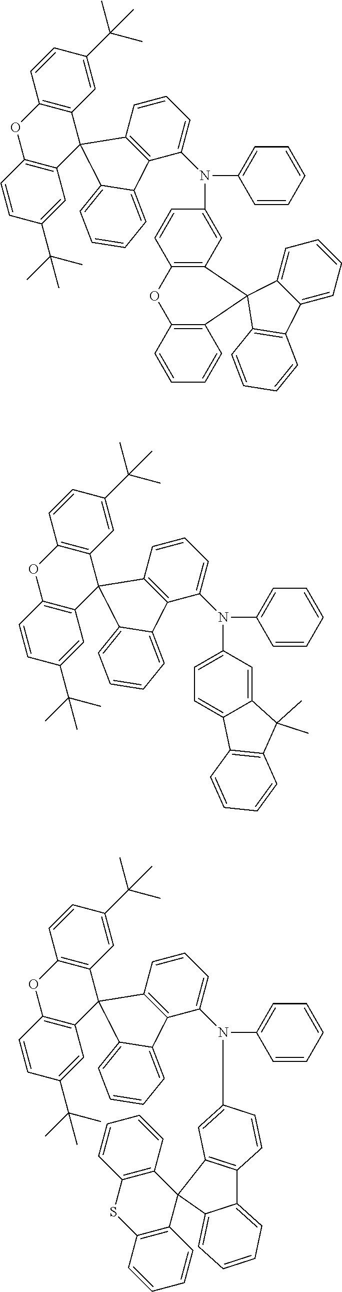 [SMILES: CC(C)(C)c1ccc2c(c1)C1(c3cc(C(C)(C)C)ccc3O2)c2ccccc2-c2c(N(c3ccccc3)c3ccc4c(c3)C3(c5ccccc5O4)c4ccccc4-c4ccccc43)cccc21 ; CC(C)(C)c1ccc2c(c1)C1(c3cc(C(C)(C)C)ccc3O2)c2ccccc2-c2c(N(c3ccccc3)c3ccc4c(c3)C(C)(C)c3ccccc3-4)cccc21 ; CC(C)(C)c1ccc2c(c1)C1(c3cc(C(C)(C)C)ccc3O2)c2ccccc2-c2c(N(c3ccccc3)c3ccc4c(c3)C3(c5ccccc5Sc5ccccc53)c3ccccc3-4)cccc21]

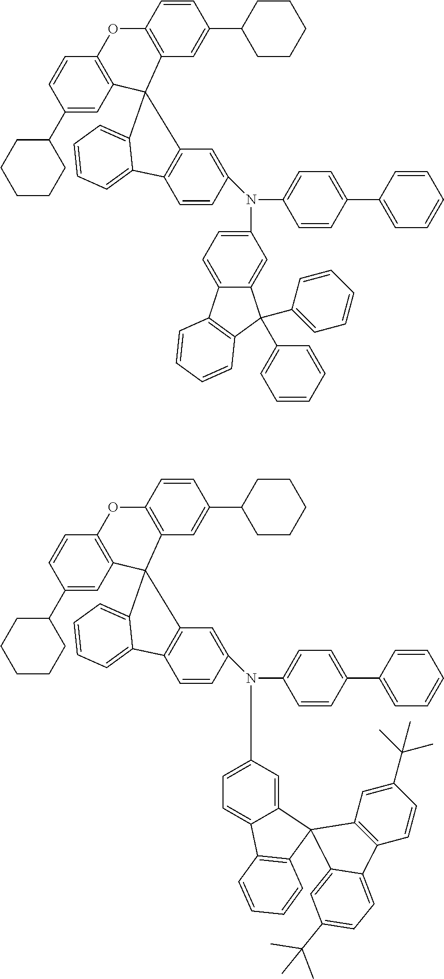 [SMILES: c1ccc(-c2ccc(N(c3ccc4c(c3)C(c3ccccc3)(c3ccccc3)c3ccccc3-4)c3ccc4c(c3)C3(c5cc(C6CCCCC6)ccc5Oc5ccc(C6CCCCC6)cc53)c3ccccc3-4)cc2)cc1 ; CC(C)(C)c1ccc2c(c1)C1(c3ccccc3-c3ccc(N(c4ccc(-c5ccccc5)cc4)c4ccc5c(c4)C4(c6cc(C7CCCCC7)ccc6Oc6ccc(C7CCCCC7)cc64)c4ccccc4-5)cc31)c1cc(C(C)(C)C)ccc1-2]

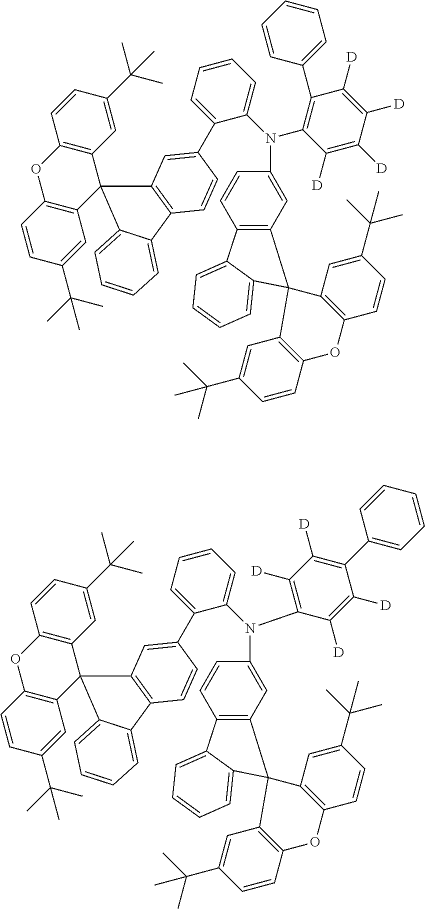 [SMILES: [2H]c1c([2H])c([2H])c(N(c2ccc3c(c2)C2(c4cc(C(C)(C)C)ccc4Oc4ccc(C(C)(C)C)cc42)c2ccccc2-3)c2ccccc2-c2ccc3c(c2)C2(c4cc(C(C)(C)C)ccc4Oc4ccc(C(C)(C)C)cc42)c2ccccc2-3)c(-c2ccccc2)c1[2H] ; [2H]c1c([2H])c(N(c2ccc3c(c2)C2(c4cc(C(C)(C)C)ccc4Oc4ccc(C(C)(C)C)cc42)c2ccccc2-3)c2ccccc2-c2ccc3c(c2)C2(c4cc(C(C)(C)C)ccc4Oc4ccc(C(C)(C)C)cc42)c2ccccc2-3)c([2H])c([2H])c1-c1ccccc1]

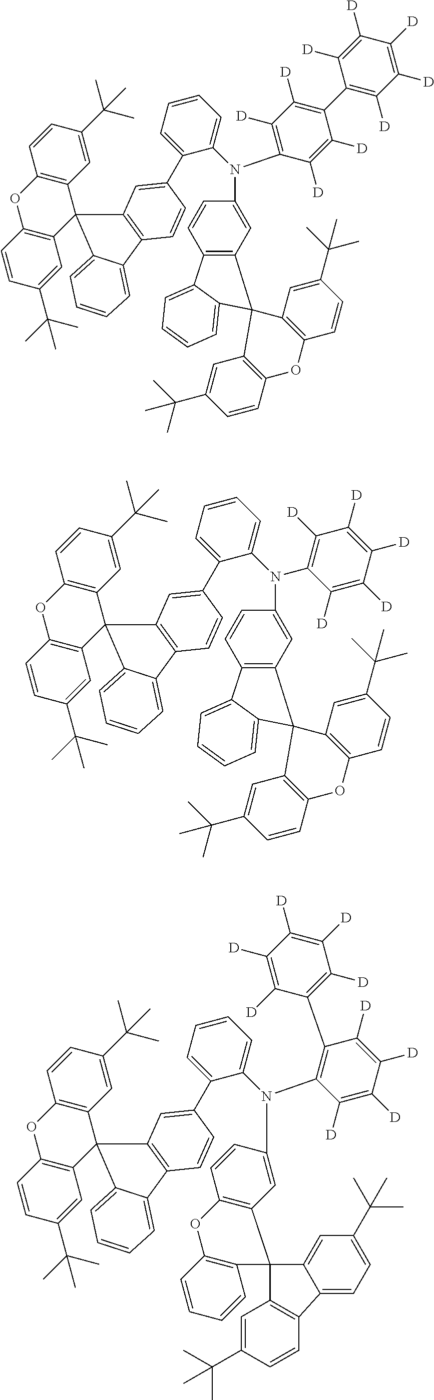

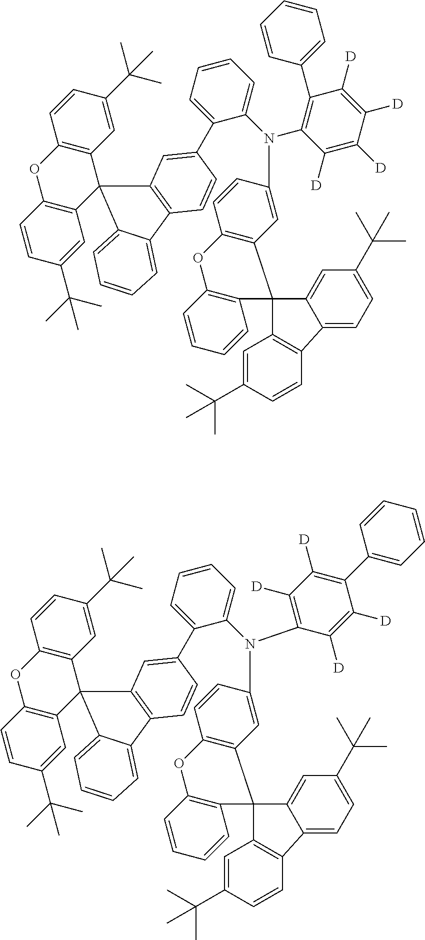 [SMILES: [2H]c1c([2H])c([2H])c(N(c2ccc3c(c2)C2(c4ccccc4O3)c3cc(C(C)(C)C)ccc3-c3ccc(C(C)(C)C)cc32)c2ccccc2-c2ccc3c(c2)C2(c4cc(C(C)(C)C)ccc4Oc4ccc(C(C)(C)C)cc42)c2ccccc2-3)c(-c2ccccc2)c1[2H] ; [2H]c1c([2H])c(N(c2ccc3c(c2)C2(c4ccccc4O3)c3cc(C(C)(C)C)ccc3-c3ccc(C(C)(C)C)cc32)c2ccccc2-c2ccc3c(c2)C2(c4cc(C(C)(C)C)ccc4Oc4ccc(C(C)(C)C)cc42)c2ccccc2-3)c([2H])c([2H])c1-c1ccccc1]

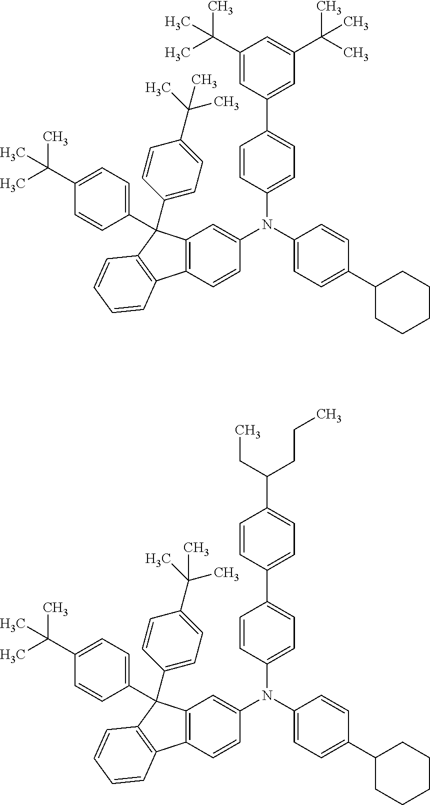 [SMILES: CC(C)(C)c1ccc(C2(c3ccc(C(C)(C)C)cc3)c3ccccc3-c3ccc(N(c4ccc(-c5cc(C(C)(C)C)cc(C(C)(C)C)c5)cc4)c4ccc(C5CCCCC5)cc4)cc32)cc1 ; CCCC(CC)c1ccc(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)cc1]

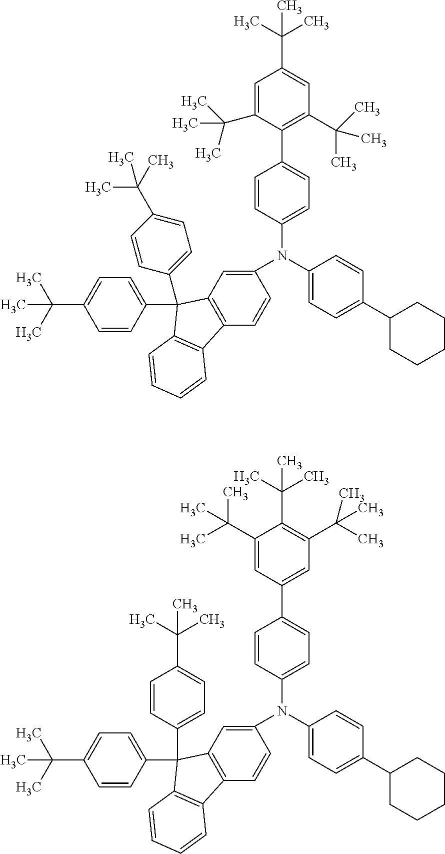 [SMILES: CC(C)(C)c1ccc(C2(c3ccc(C(C)(C)C)cc3)c3ccccc3-c3ccc(N(c4ccc(-c5c(C(C)(C)C)cc(C(C)(C)C)cc5C(C)(C)C)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5cc(C(C)(C)C)c(C(C)(C)C)c(C(C)(C)C)c5)cc4)c4ccc(C5CCCCC5)cc4)cc32)cc1]

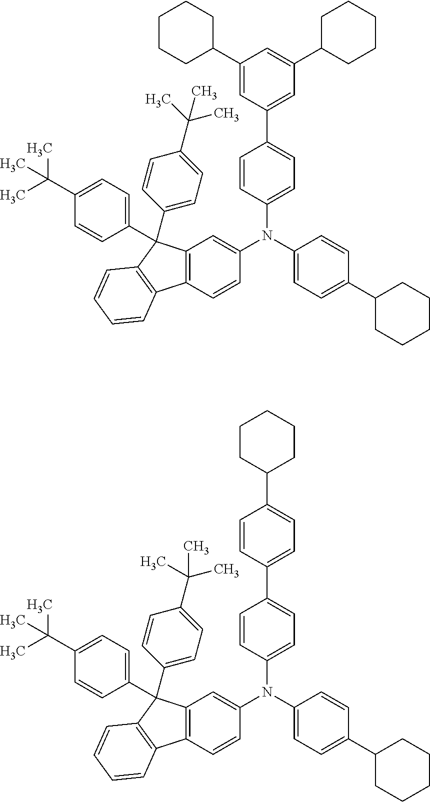 [SMILES: CC(C)(C)c1ccc(C2(c3ccc(C(C)(C)C)cc3)c3ccccc3-c3ccc(N(c4ccc(-c5cc(C6CCCCC6)cc(C6CCCCC6)c5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5ccc(C6CCCCC6)cc5)cc4)c4ccc(C5CCCCC5)cc4)cc32)cc1]

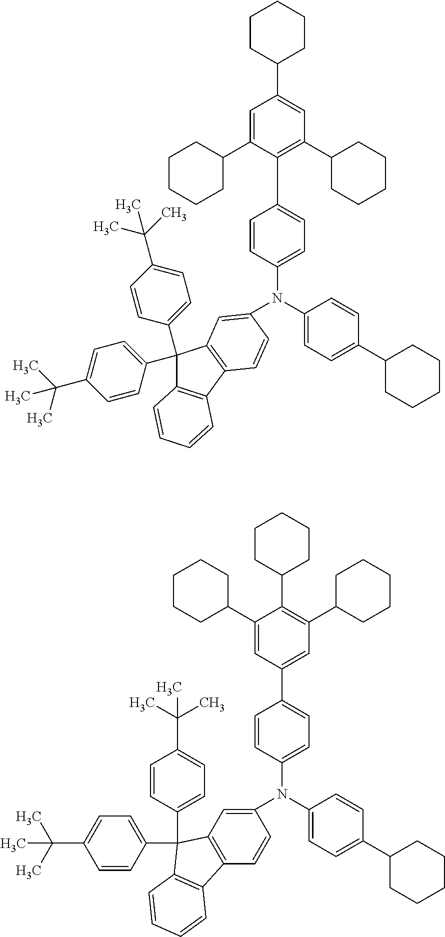 [SMILES: CC(C)(C)c1ccc(C2(c3ccc(C(C)(C)C)cc3)c3ccccc3-c3ccc(N(c4ccc(-c5c(C6CCCCC6)cc(C6CCCCC6)cc5C5CCCCC5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5cc(C6CCCCC6)c(C6CCCCC6)c(C6CCCCC6)c5)cc4)c4ccc(C5CCCCC5)cc4)cc32)cc1]

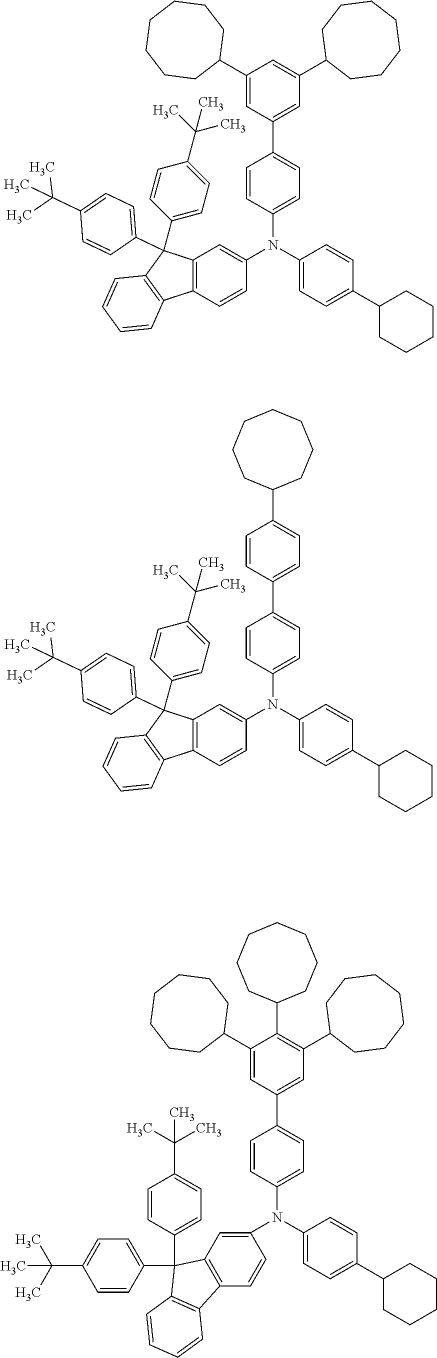 [SMILES: CC(C)(C)c1ccc(C2(c3ccc(C(C)(C)C)cc3)c3ccccc3-c3ccc(N(c4ccc(-c5cc(C6CCCCCCC6)cc(C6CCCCCCC6)c5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5ccc(C6CCCCCCC6)cc5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5cc(C6CCCCCCC6)c(C6CCCCCCC6)c(C6CCCCCCC6)c5)cc4)c4ccc(C5CCCCC5)cc4)cc32)cc1]

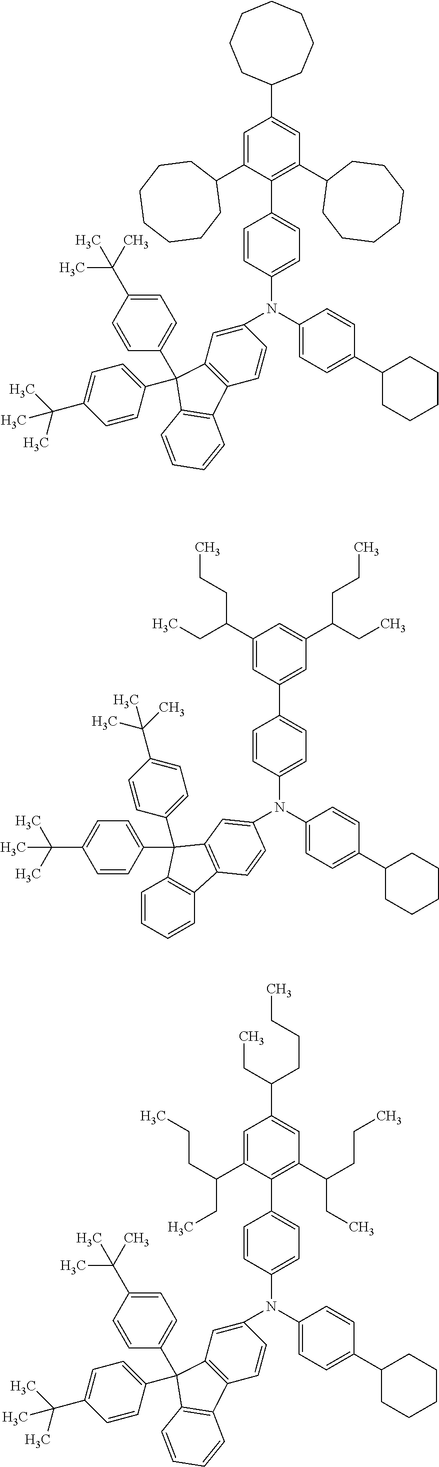 [SMILES: CC(C)(C)c1ccc(C2(c3ccc(C(C)(C)C)cc3)c3ccccc3-c3ccc(N(c4ccc(-c5c(C6CCCCCCC6)cc(C6CCCCCCC6)cc5C5CCCCCCC5)cc4)c4ccc(C5CCCCC5)cc4)cc32)cc1 ; CCCC(CC)c1cc(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)cc(C(CC)CCC)c1 ; CCCCC(CC)c1cc(C(CC)CCC)c(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)c(C(CC)CCC)c1]

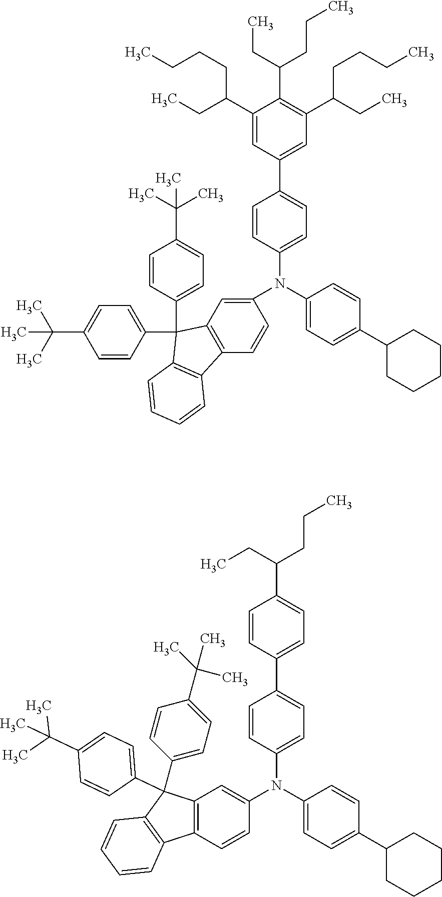 [SMILES: CCCCC(CC)c1cc(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)cc(C(CC)CCCC)c1C(CC)CCC ; CCCC(CC)c1ccc(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)cc1]

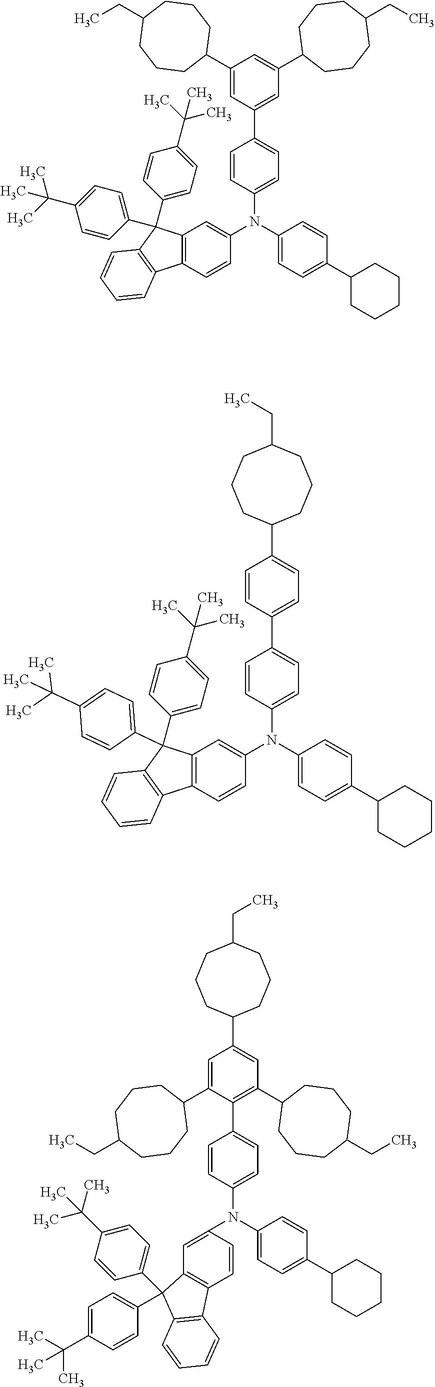

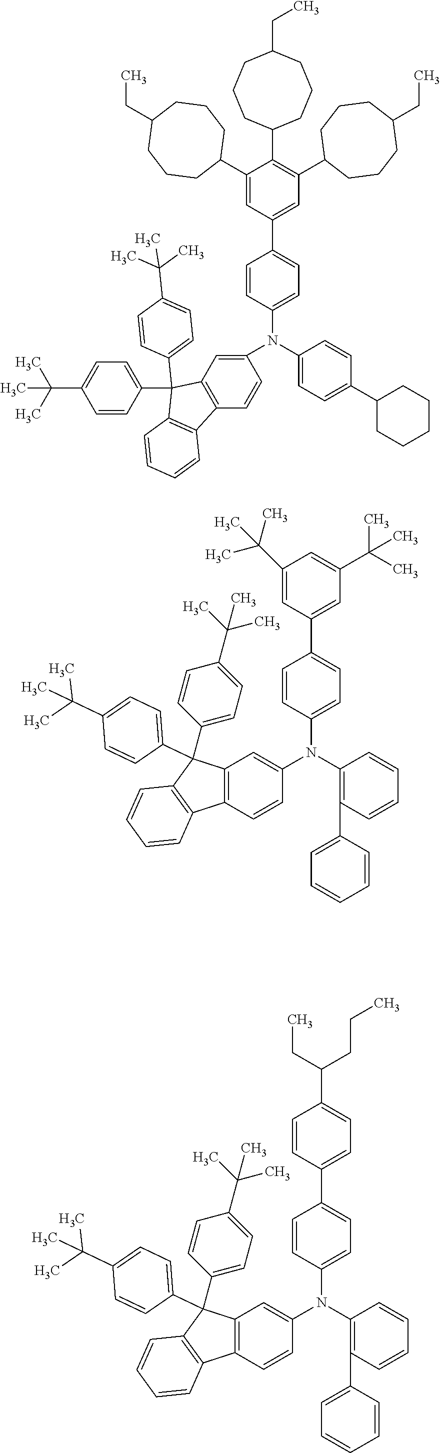

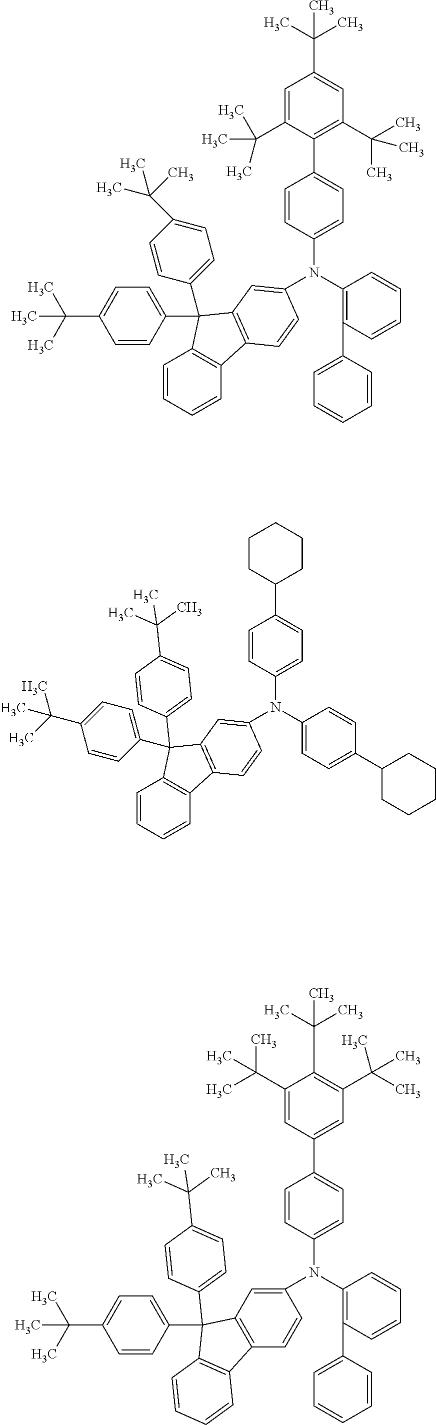

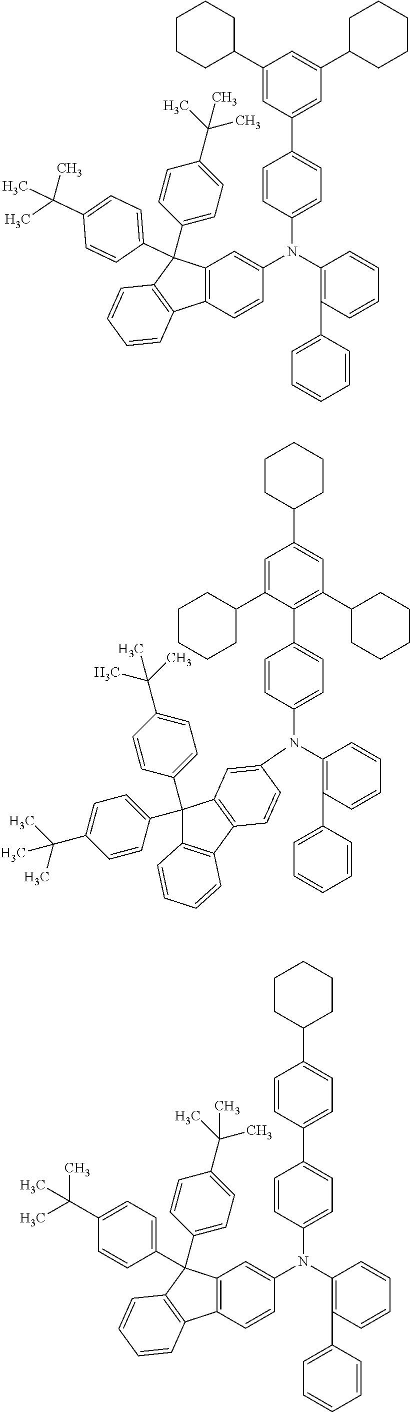 [SMILES: CC(C)(C)c1ccc(C2(c3ccc(C(C)(C)C)cc3)c3ccccc3-c3ccc(N(c4ccc(-c5cc(C6CCCCC6)cc(C6CCCCC6)c5)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5c(C6CCCCC6)cc(C6CCCCC6)cc5C5CCCCC5)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5ccc(C6CCCCC6)cc5)cc4)c4ccccc4-c4ccccc4)cc32)cc1]

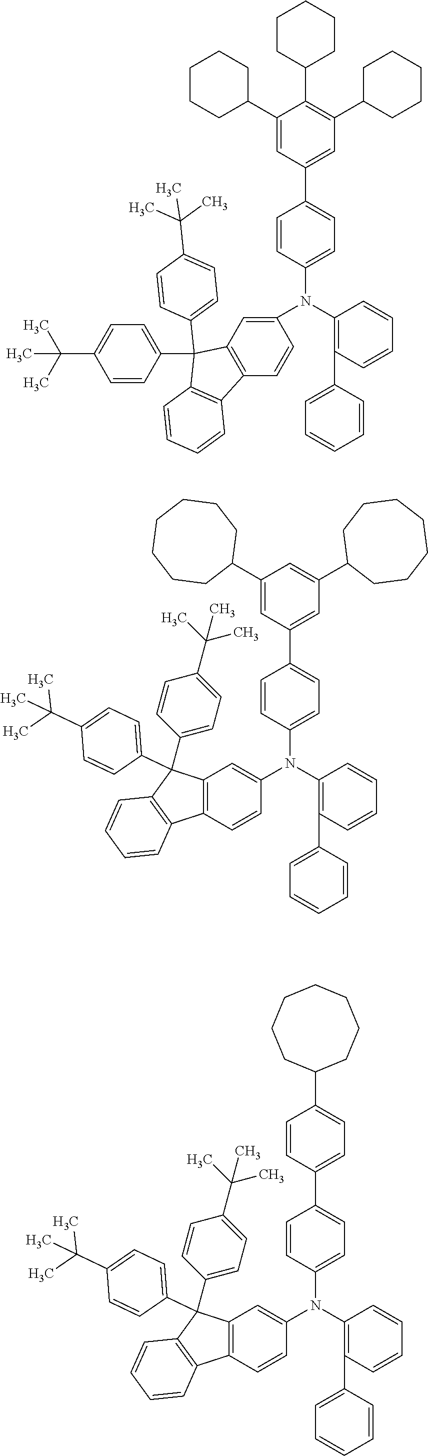 [SMILES: CC(C)(C)c1ccc(C2(c3ccc(C(C)(C)C)cc3)c3ccccc3-c3ccc(N(c4ccc(-c5cc(C6CCCCC6)c(C6CCCCC6)c(C6CCCCC6)c5)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5cc(C6CCCCCCC6)cc(C6CCCCCCC6)c5)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5ccc(C6CCCCCCC6)cc5)cc4)c4ccccc4-c4ccccc4)cc32)cc1]

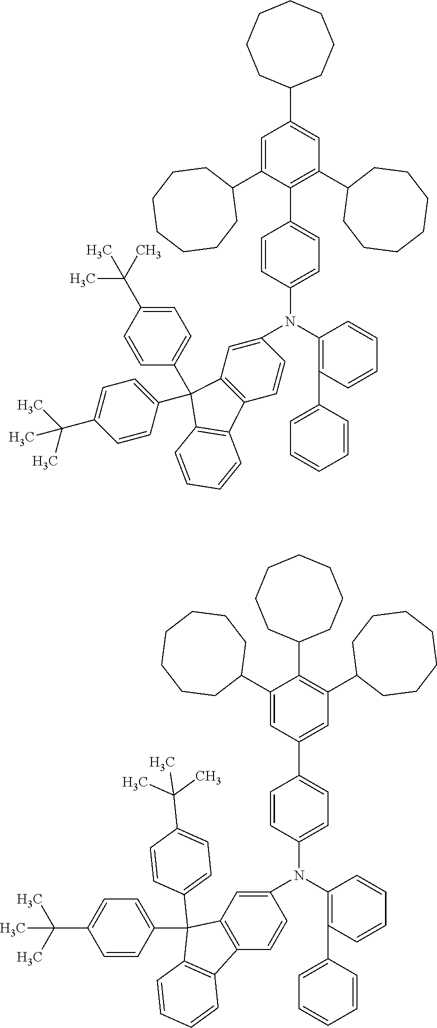 [SMILES: CC(C)(C)c1ccc(C2(c3ccc(C(C)(C)C)cc3)c3ccccc3-c3ccc(N(c4ccc(-c5c(C6CCCCCCC6)cc(C6CCCCCCC6)cc5C5CCCCCCC5)cc4)c4ccccc4-c4ccccc4)cc32)cc1 ; CC(C)(C)c1ccc(C2(c3ccc(C(C)(C)C)cc3)c3ccccc3-c3ccc(N(c4ccc(-c5cc(C6CCCCCCC6)c(C6CCCCCCC6)c(C6CCCCCCC6)c5)cc4)c4ccccc4-c4ccccc4)cc32)cc1]

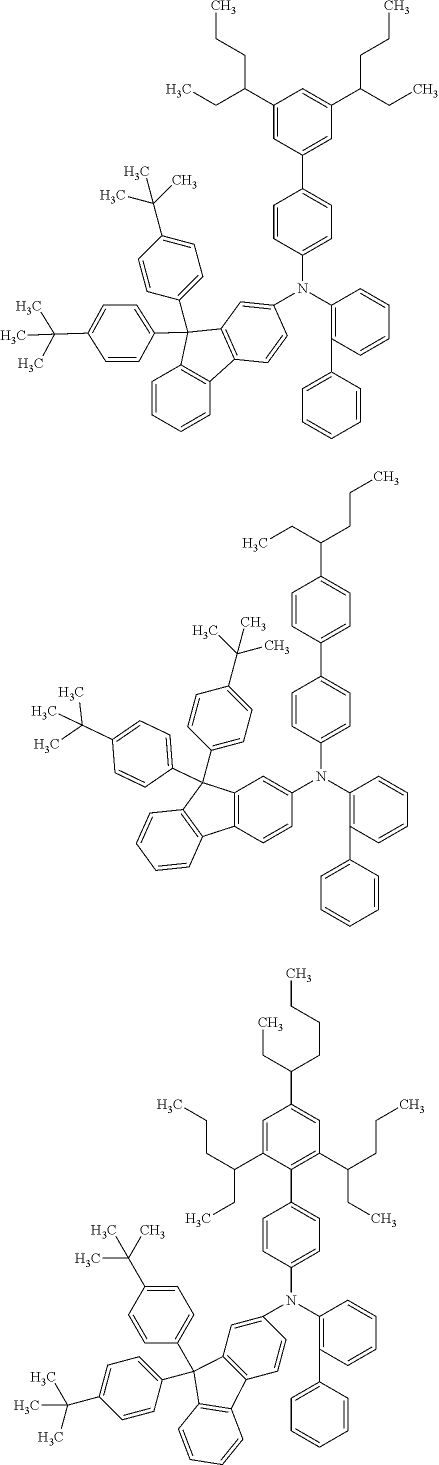

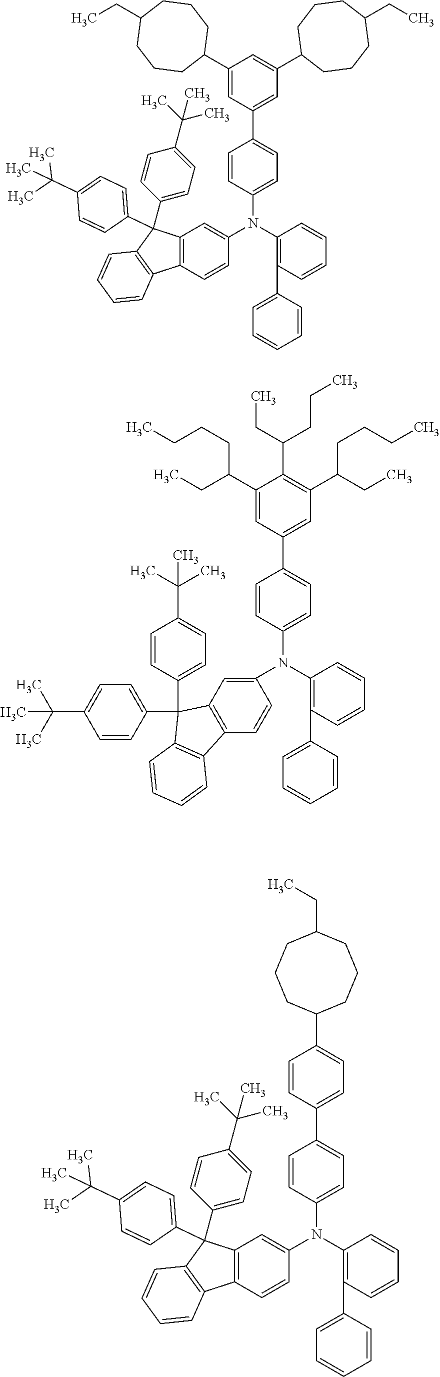

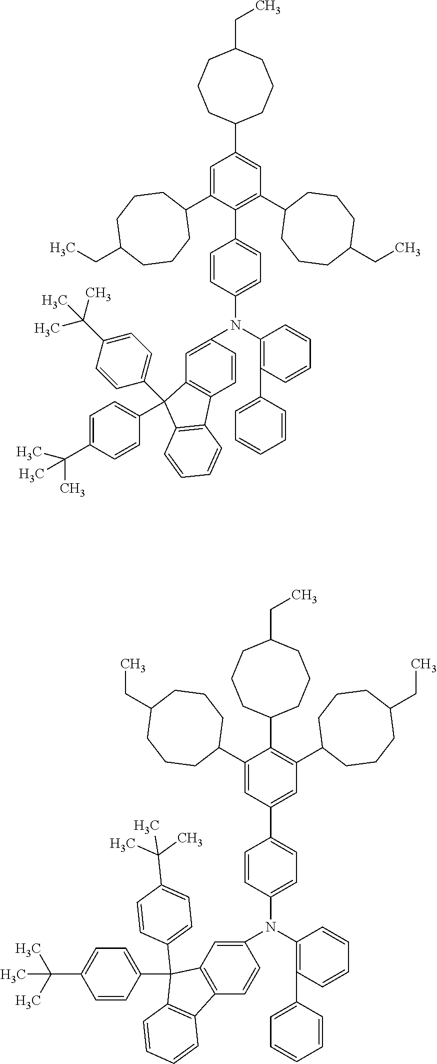

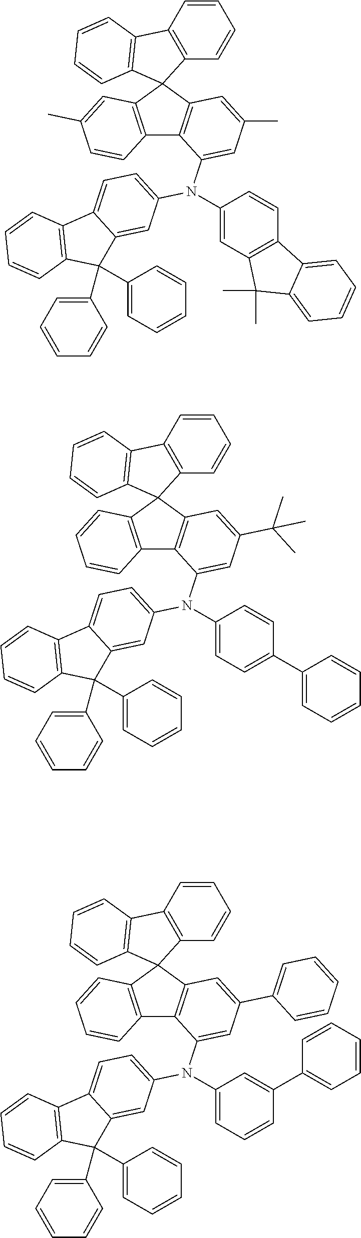 [SMILES: Cc1ccc2c(c1)C1(c3ccccc3-c3ccccc31)c1cc(C)cc(N(c3ccc4c(c3)C(C)(C)c3ccccc3-4)c3ccc4c(c3)C(c3ccccc3)(c3ccccc3)c3ccccc3-4)c1-2 ; CC(C)(C)c1cc(N(c2ccc(-c3ccccc3)cc2)c2ccc3c(c2)C(c2ccccc2)(c2ccccc2)c2ccccc2-3)c2c(c1)C1(c3ccccc3-c3ccccc31)c1ccccc1-2 ; c1ccc(-c2cccc(N(c3ccc4c(c3)C(c3ccccc3)(c3ccccc3)c3ccccc3-4)c3cc(-c4ccccc4)cc4c3-c3ccccc3C43c4ccccc4-c4ccccc43)c2)cc1]

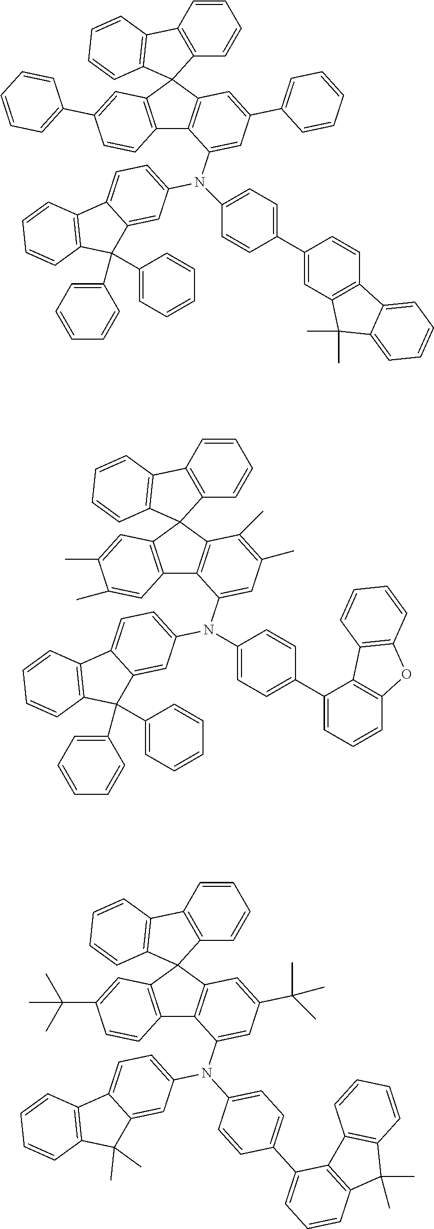 [SMILES: CC1(C)c2ccccc2-c2ccc(-c3ccc(N(c4ccc5c(c4)C(c4ccccc4)(c4ccccc4)c4ccccc4-5)c4cc(-c5ccccc5)cc5c4-c4ccc(-c6ccccc6)cc4C54c5ccccc5-c5ccccc54)cc3)cc21 ; Cc1cc2c(cc1C)C1(c3ccccc3-c3ccccc31)c1c(C)c(C)cc(N(c3ccc(-c4cccc5oc6ccccc6c45)cc3)c3ccc4c(c3)C(c3ccccc3)(c3ccccc3)c3ccccc3-4)c1-2 ; CC(C)(C)c1ccc2c(c1)C1(c3ccccc3-c3ccccc31)c1cc(C(C)(C)C)cc(N(c3ccc(-c4cccc5c4-c4ccccc4C5(C)C)cc3)c3ccc4c(c3)C(C)(C)c3ccccc3-4)c1-2]

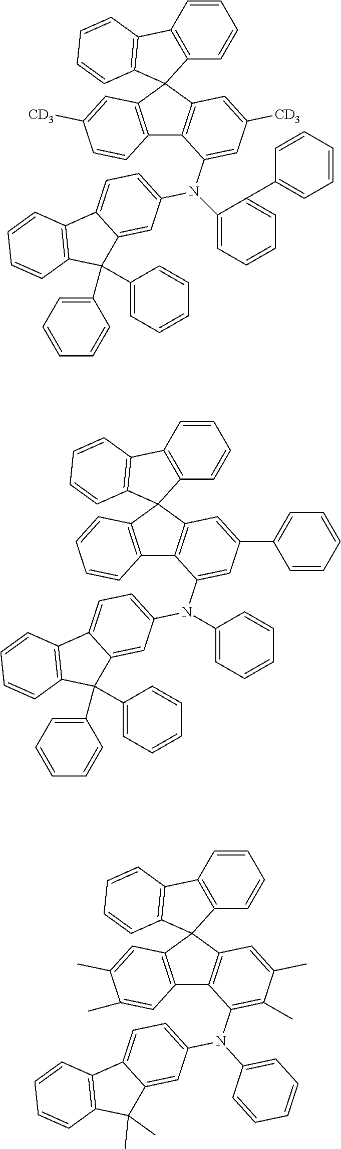 [SMILES: [2H]C([2H])([2H])c1ccc2c(c1)C1(c3ccccc3-c3ccccc31)c1cc(C([2H])([2H])[2H])cc(N(c3ccc4c(c3)C(c3ccccc3)(c3ccccc3)c3ccccc3-4)c3ccccc3-c3ccccc3)c1-2 ; c1ccc(-c2cc(N(c3ccccc3)c3ccc4c(c3)C(c3ccccc3)(c3ccccc3)c3ccccc3-4)c3c(c2)C2(c4ccccc4-c4ccccc42)c2ccccc2-3)cc1 ; Cc1cc2c(cc1C)C1(c3ccccc3-c3ccccc31)c1cc(C)c(C)c(N(c3ccccc3)c3ccc4c(c3)C(C)(C)c3ccccc3-4)c1-2]

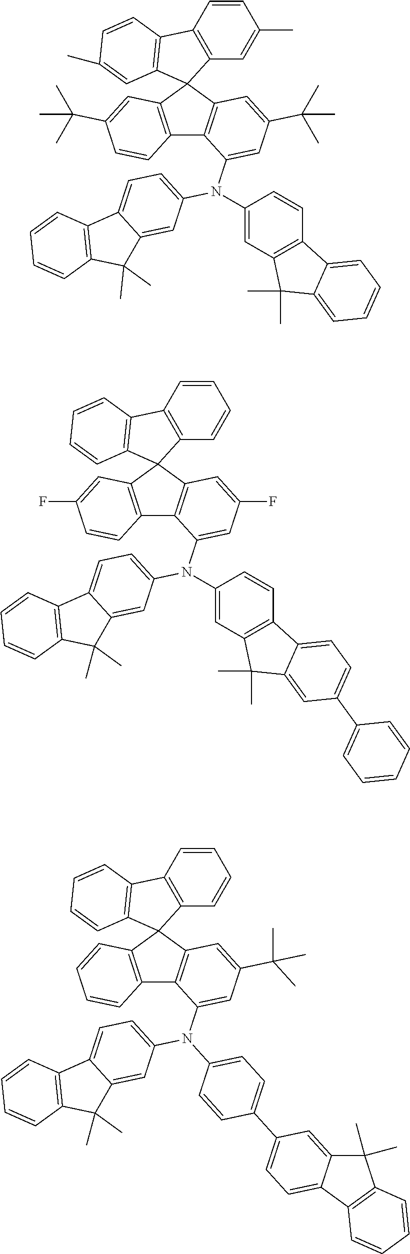 [SMILES: Cc1ccc2c(c1)C1(c3cc(C)ccc3-2)c2cc(C(C)(C)C)ccc2-c2c(N(c3ccc4c(c3)C(C)(C)c3ccccc3-4)c3ccc4c(c3)C(C)(C)c3ccccc3-4)cc(C(C)(C)C)cc21 ; CC1(C)c2ccccc2-c2ccc(N(c3ccc4c(c3)C(C)(C)c3cc(-c5ccccc5)ccc3-4)c3cc(F)cc4c3-c3ccc(F)cc3C43c4ccccc4-c4ccccc43)cc21 ; CC(C)(C)c1cc(N(c2ccc(-c3ccc4c(c3)C(C)(C)c3ccccc3-4)cc2)c2ccc3c(c2)C(C)(C)c2ccccc2-3)c2c(c1)C1(c3ccccc3-c3ccccc31)c1ccccc1-2]

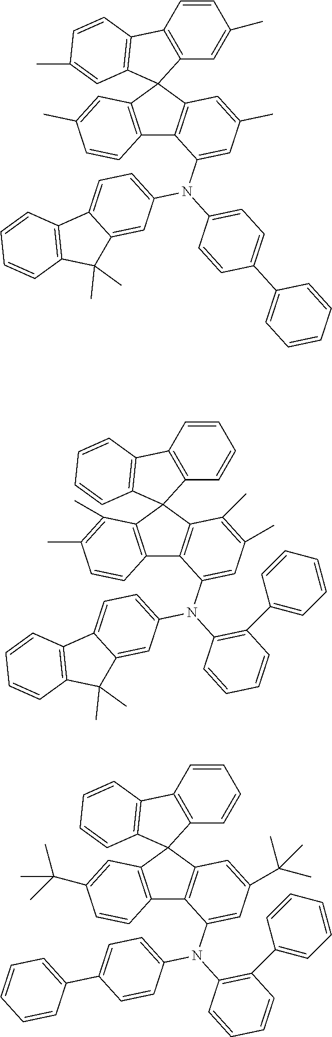 [SMILES: Cc1ccc2c(c1)C1(c3cc(C)ccc3-2)c2cc(C)ccc2-c2c(N(c3ccc(-c4ccccc4)cc3)c3ccc4c(c3)C(C)(C)c3ccccc3-4)cc(C)cc21 ; Cc1ccc2c(c1C)C1(c3ccccc3-c3ccccc31)c1c(C)c(C)cc(N(c3ccc4c(c3)C(C)(C)c3ccccc3-4)c3ccccc3-c3ccccc3)c1-2 ; CC(C)(C)c1ccc2c(c1)C1(c3ccccc3-c3ccccc31)c1cc(C(C)(C)C)cc(N(c3ccc(-c4ccccc4)cc3)c3ccccc3-c3ccccc3)c1-2]

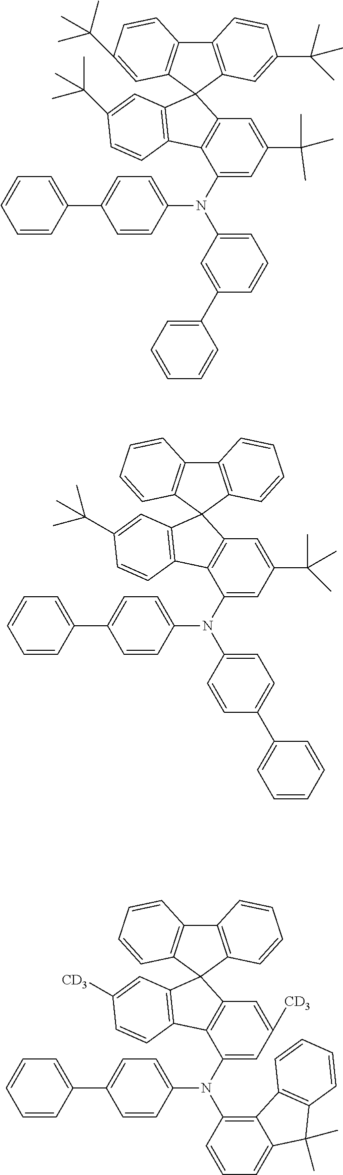 [SMILES: CC(C)(C)c1ccc2c(c1)C1(c3cc(C(C)(C)C)ccc3-2)c2cc(C(C)(C)C)ccc2-c2c(N(c3ccc(-c4ccccc4)cc3)c3cccc(-c4ccccc4)c3)cc(C(C)(C)C)cc21 ; CC(C)(C)c1ccc2c(c1)C1(c3ccccc3-c3ccccc31)c1cc(C(C)(C)C)cc(N(c3ccc(-c4ccccc4)cc3)c3ccc(-c4ccccc4)cc3)c1-2 ; [2H]C([2H])([2H])c1ccc2c(c1)C1(c3ccccc3-c3ccccc31)c1cc(C([2H])([2H])[2H])cc(N(c3ccc(-c4ccccc4)cc3)c3cccc4c3-c3ccccc3C4(C)C)c1-2]

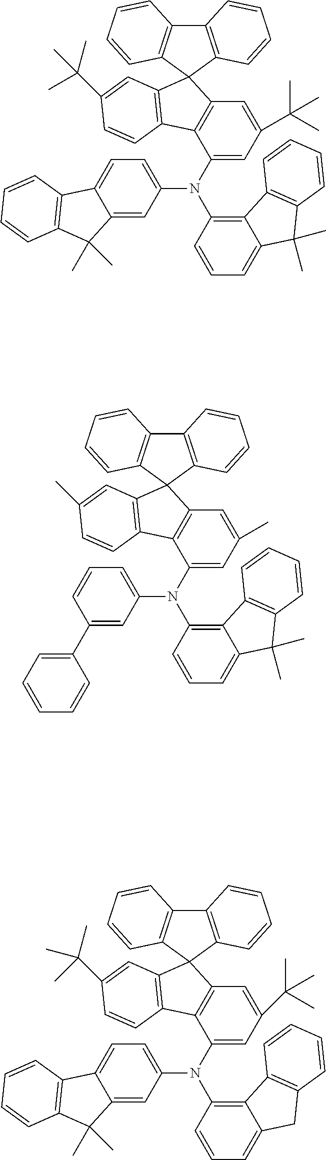 [SMILES: CC(C)(C)c1ccc2c(c1)C1(c3ccccc3-c3ccccc31)c1cc(C(C)(C)C)cc(N(c3ccc4c(c3)C(C)(C)c3ccccc3-4)c3cccc4c3-c3ccccc3C4(C)C)c1-2 ; Cc1ccc2c(c1)C1(c3ccccc3-c3ccccc31)c1cc(C)cc(N(c3cccc(-c4ccccc4)c3)c3cccc4c3-c3ccccc3C4(C)C)c1-2 ; CC(C)(C)c1ccc2c(c1)C1(c3ccccc3-c3ccccc31)c1cc(C(C)(C)C)cc(N(c3ccc4c(c3)C(C)(C)c3ccccc3-4)c3cccc4c3-c3ccccc3C4)c1-2]

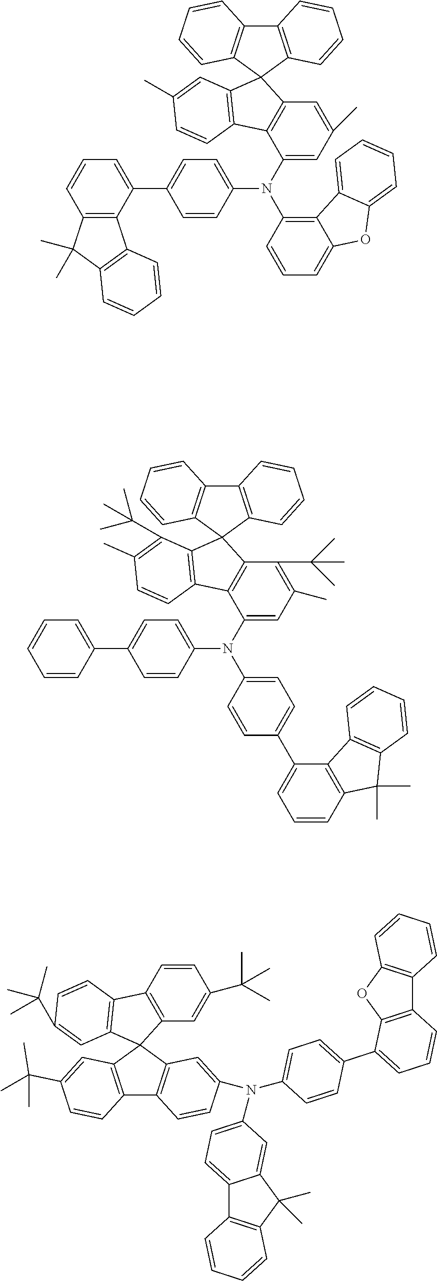

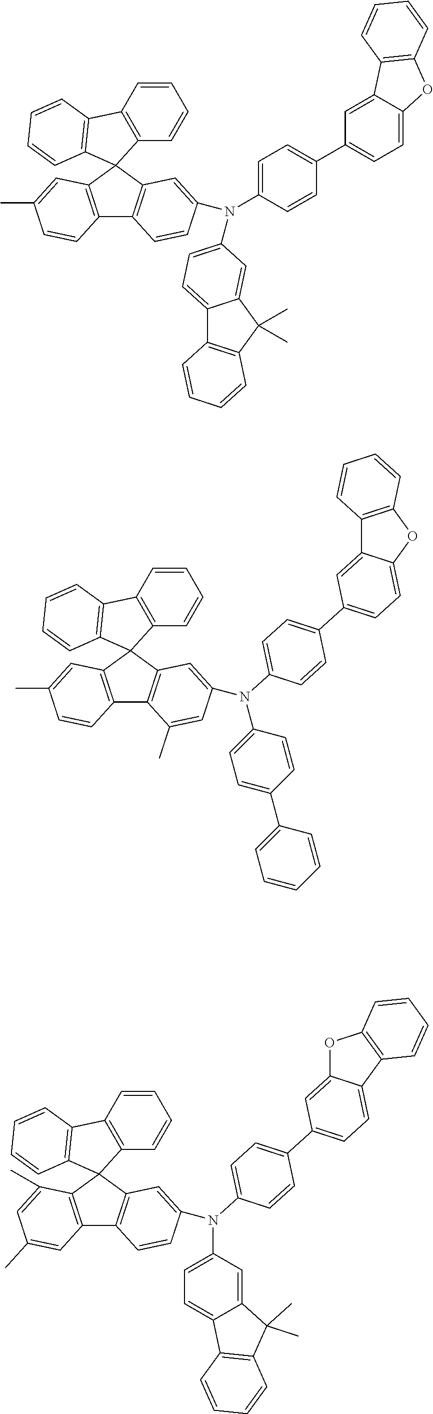 [SMILES: Cc1ccc2c(c1)C1(c3ccccc3-c3ccccc31)c1cc(N(c3ccc(-c4ccc5oc6ccccc6c5c4)cc3)c3ccc4c(c3)C(C)(C)c3ccccc3-4)ccc1-2 ; Cc1ccc2c(c1)C1(c3ccccc3-c3ccccc31)c1cc(N(c3ccc(-c4ccccc4)cc3)c3ccc(-c4ccc5oc6ccccc6c5c4)cc3)cc(C)c1-2 ; Cc1cc(C)c2c(c1)-c1ccc(N(c3ccc(-c4ccc5c(c4)oc4ccccc45)cc3)c3ccc4c(c3)C(C)(C)c3ccccc3-4)cc1C21c2ccccc2-c2ccccc21]

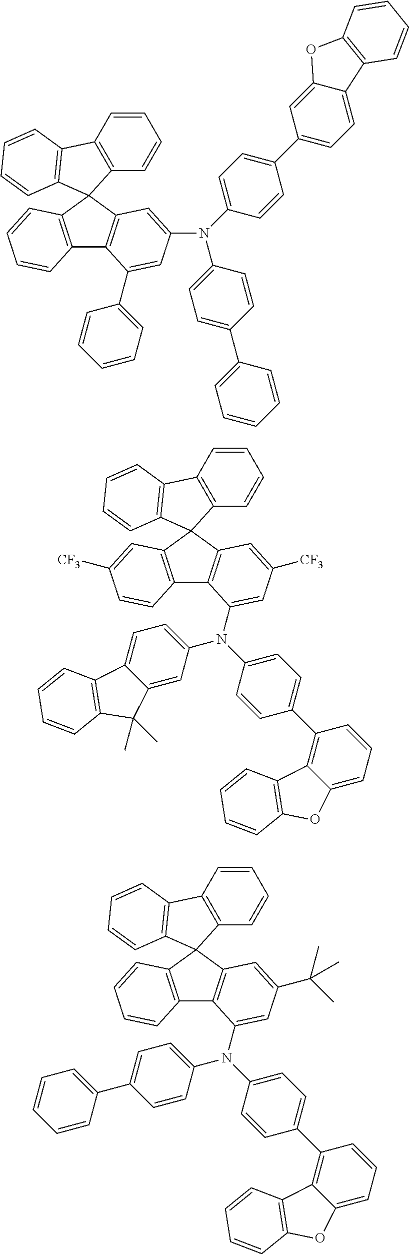

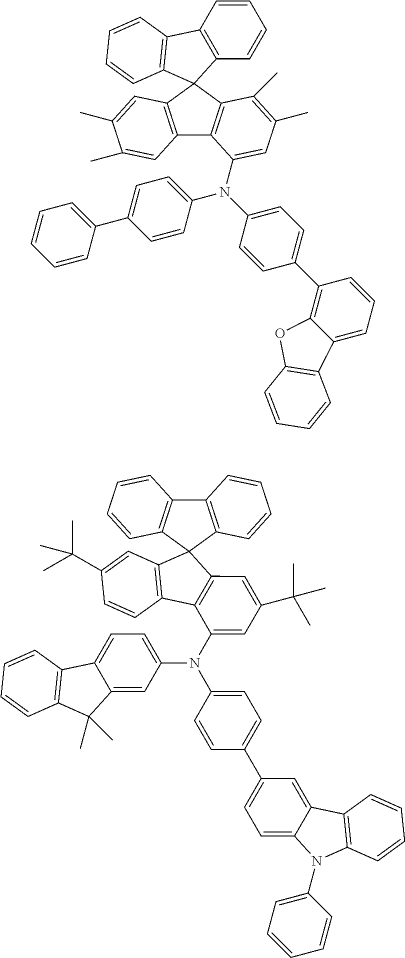 [SMILES: Cc1cc2c(cc1C)C1(c3ccccc3-c3ccccc31)c1c(C)c(C)cc(N(c3ccc(-c4ccccc4)cc3)c3ccc(-c4cccc5c4oc4ccccc45)cc3)c1-2 ; CC(C)(C)c1ccc2c(c1)C1(c3ccccc3-c3ccccc31)c1cc(C(C)(C)C)cc(N(c3ccc(-c4ccc5c(c4)c4ccccc4n5-c4ccccc4)cc3)c3ccc4c(c3)C(C)(C)c3ccccc3-4)c1-2]

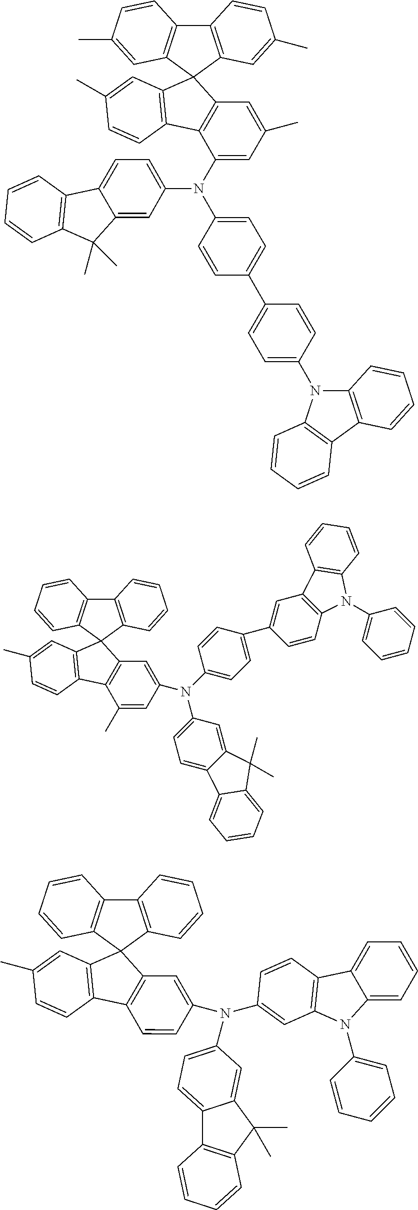

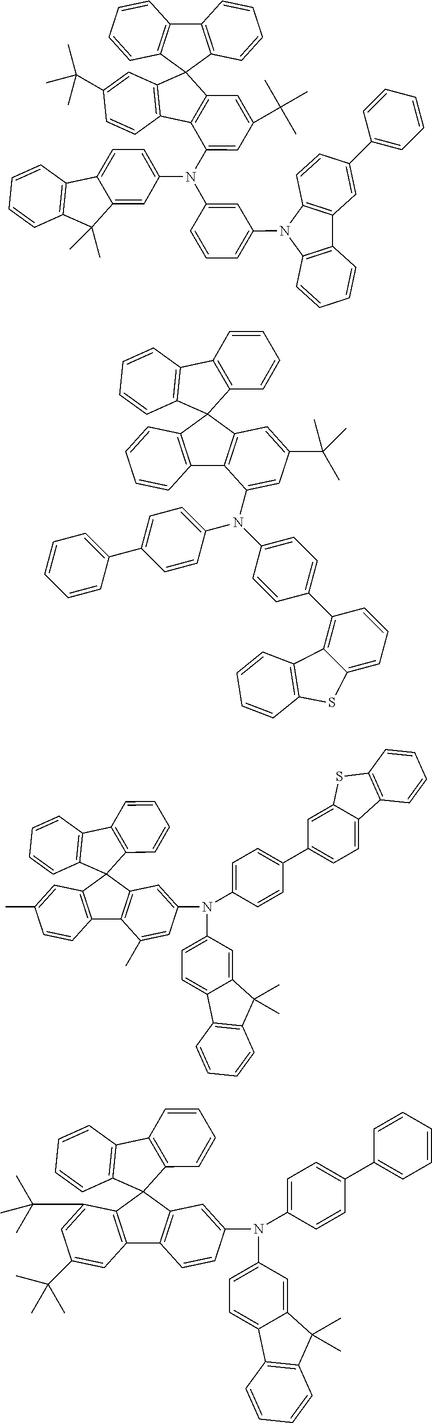

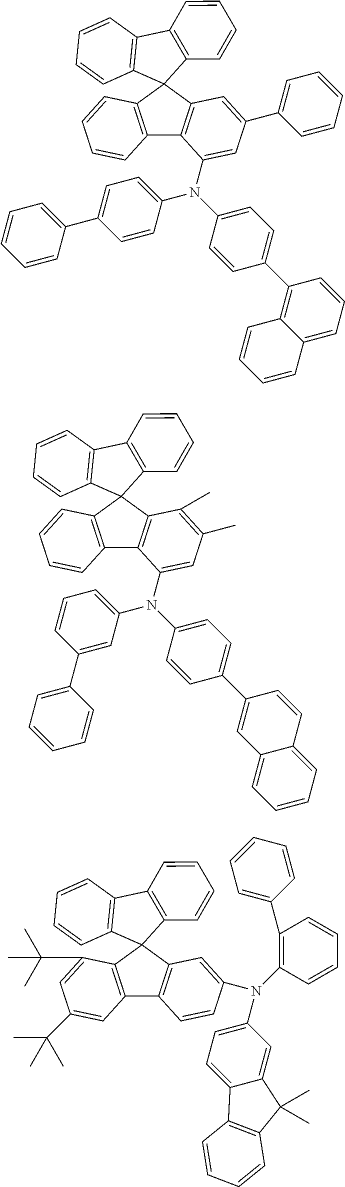

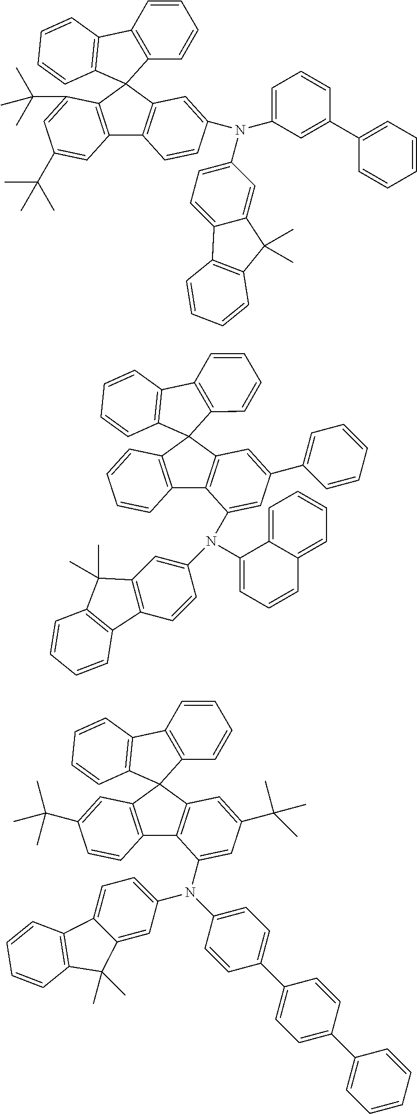

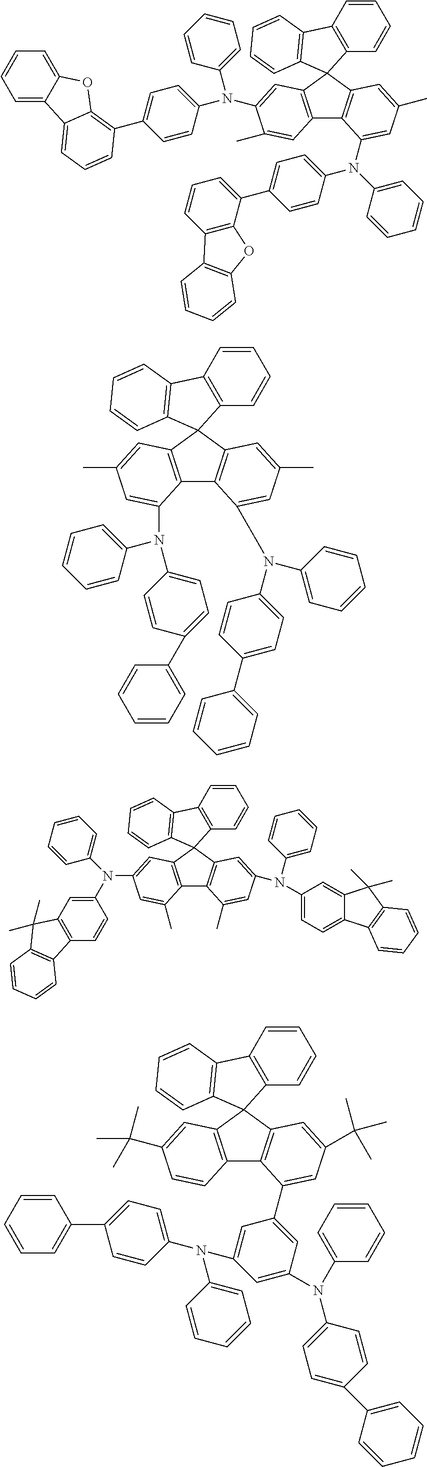

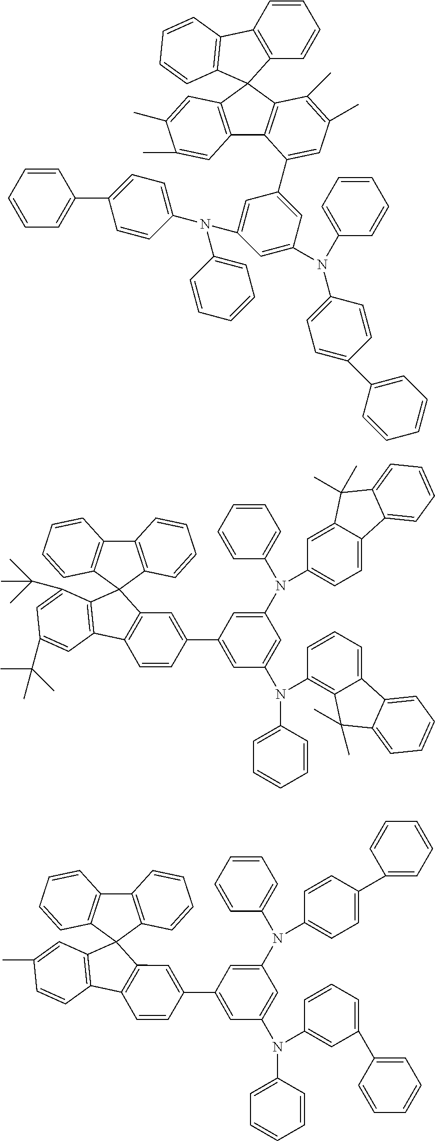

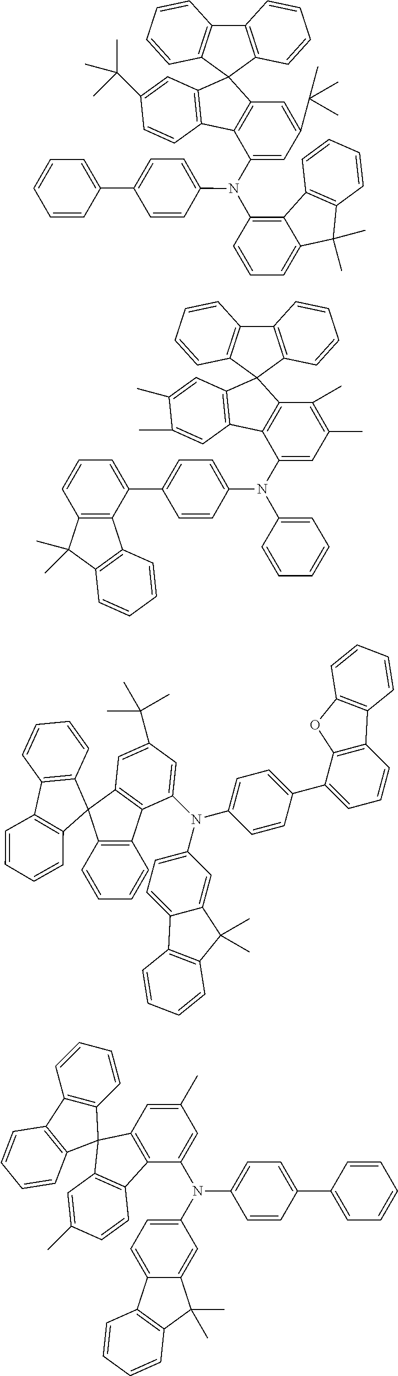

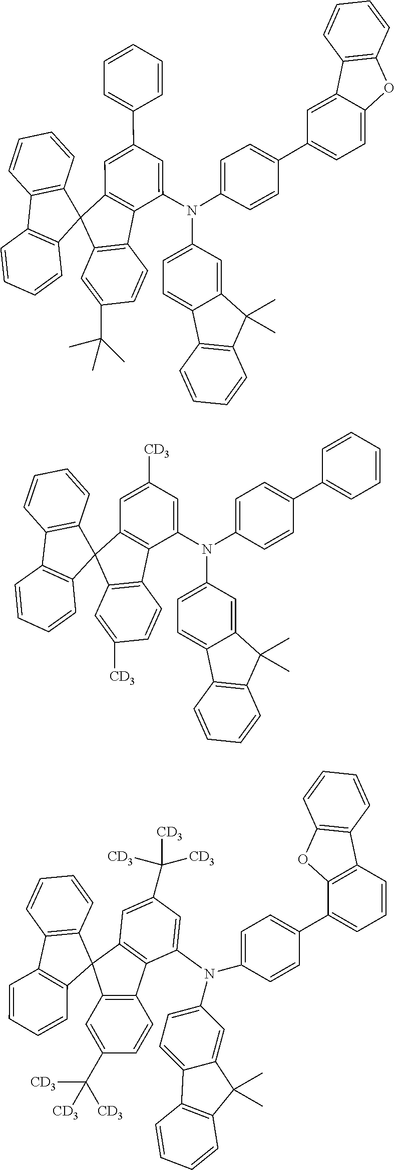 [SMILES: CC(C)(C)c1ccc2c(c1)C1(c3ccccc3-c3ccccc31)c1cc(-c3ccccc3)cc(N(c3ccc(-c4ccc5oc6ccccc6c5c4)cc3)c3ccc4c(c3)C(C)(C)c3ccccc3-4)c1-2 ; [2H]C([2H])([2H])c1ccc2c(c1)C1(c3ccccc3-c3ccccc31)c1cc(C([2H])([2H])[2H])cc(N(c3ccc(-c4ccccc4)cc3)c3ccc4c(c3)C(C)(C)c3ccccc3-4)c1-2 ; [2H]C([2H])([2H])C(c1ccc2c(c1)C1(c3ccccc3-c3ccccc31)c1cc(C(C([2H])([2H])[2H])(C([2H])([2H])[2H])C([2H])([2H])[2H])cc(N(c3ccc(-c4cccc5c4oc4ccccc45)cc3)c3ccc4c(c3)C(C)(C)c3ccccc3-4)c1-2)(C([2H])([2H])[2H])C([2H])([2H])[2H]]

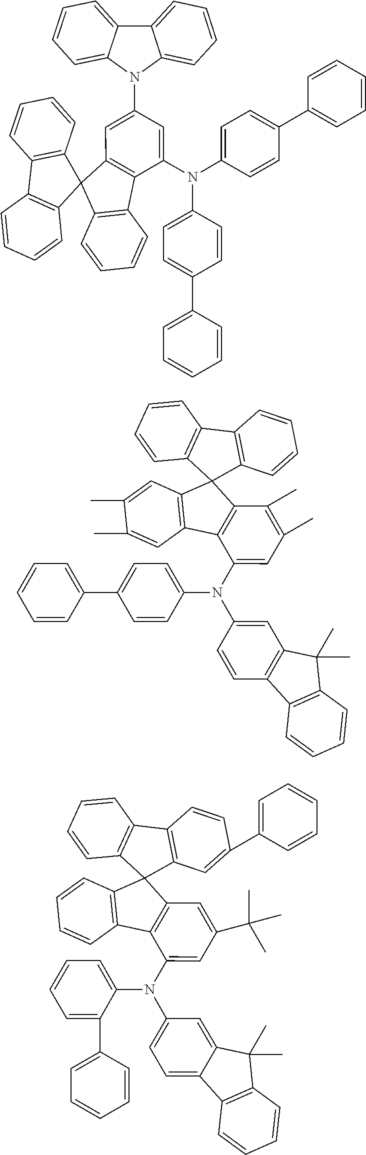

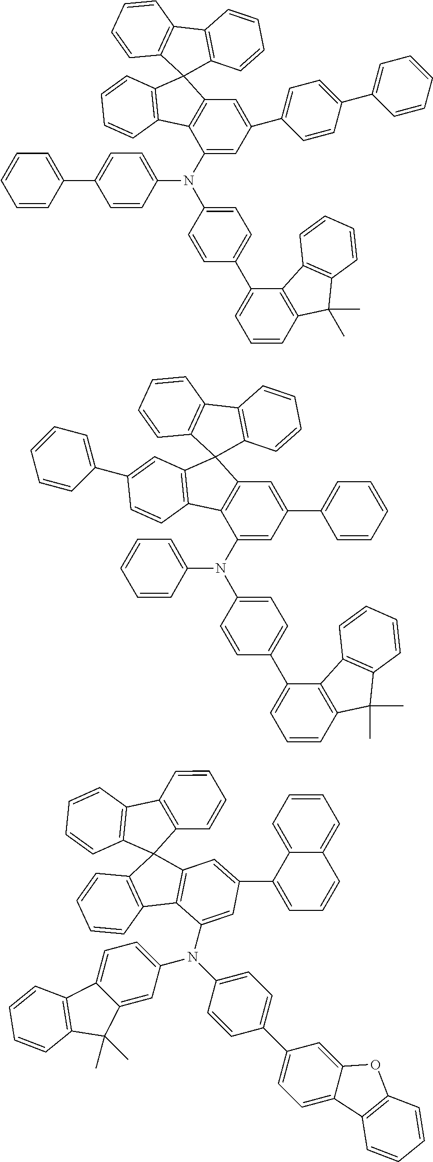

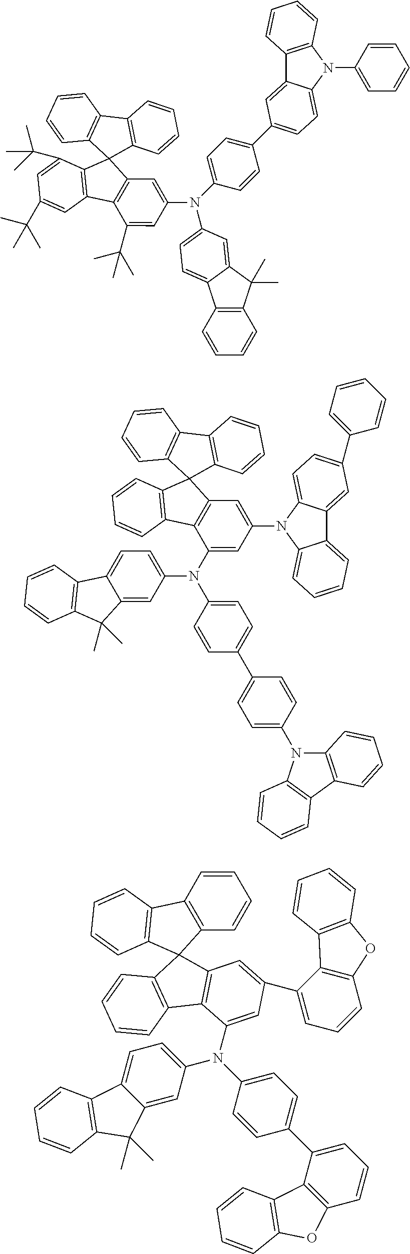 [SMILES: CC(C)(C)c1cc2c(c(C(C)(C)C)c1)C1(c3ccccc3-c3ccccc31)c1cc(N(c3ccc(-c4ccc5c(c4)c4ccccc4n5-c4ccccc4)cc3)c3ccc4c(c3)C(C)(C)c3ccccc3-4)cc(C(C)(C)C)c1-2 ; CC1(C)c2ccccc2-c2ccc(N(c3ccc(-c4ccc(-n5c6ccccc6c6ccccc65)cc4)cc3)c3cc(-n4c5ccccc5c5cc(-c6ccccc6)ccc54)cc4c3-c3ccccc3C43c4ccccc4-c4ccccc43)cc21 ; CC1(C)c2ccccc2-c2ccc(N(c3ccc(-c4cccc5oc6ccccc6c45)cc3)c3cc(-c4cccc5oc6ccccc6c45)cc4c3-c3ccccc3C43c4ccccc4-c4ccccc43)cc21]

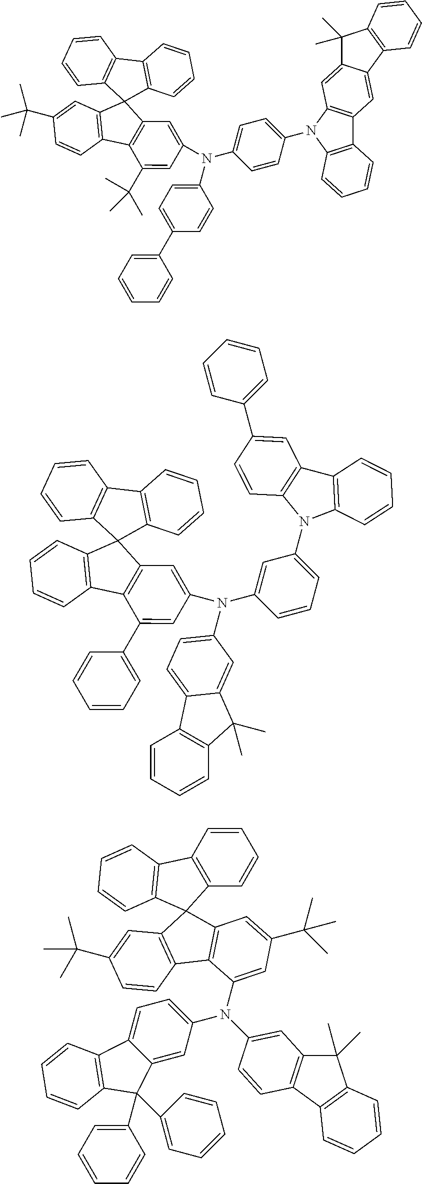

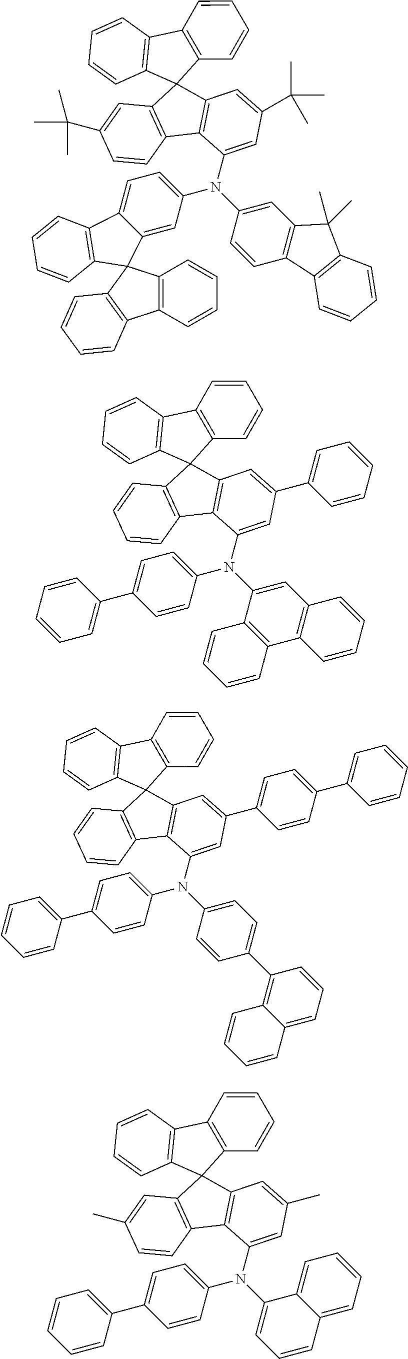

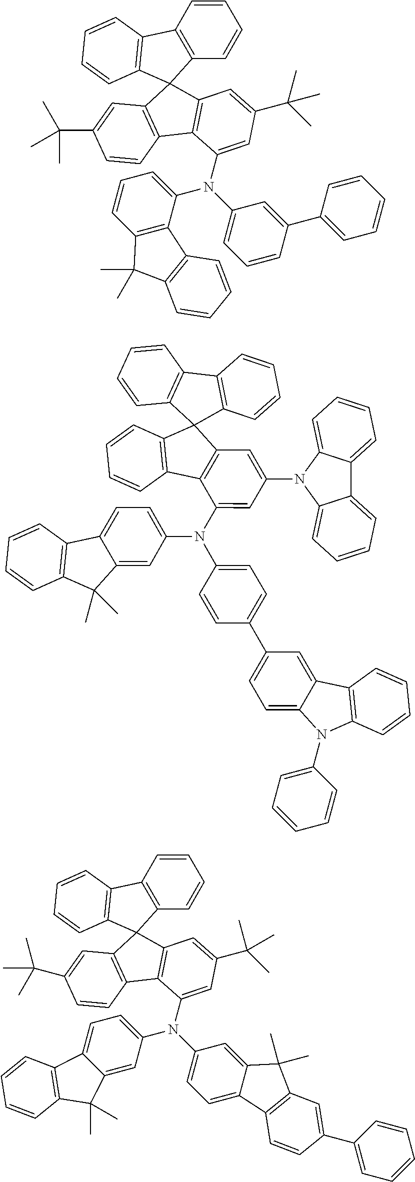

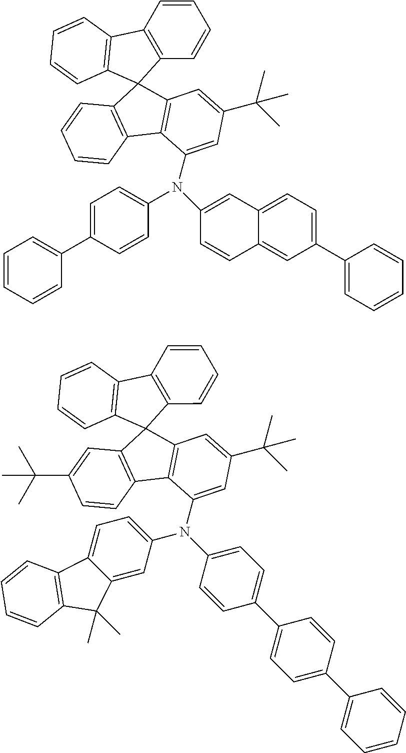 [SMILES: CC(C)(C)c1cc(N(c2ccc(-c3ccccc3)cc2)c2ccc3cc(-c4ccccc4)ccc3c2)c2c(c1)C1(c3ccccc3-c3ccccc31)c1ccccc1-2 ; CC(C)(C)c1ccc2c(c1)C1(c3ccccc3-c3ccccc31)c1cc(C(C)(C)C)cc(N(c3ccc(-c4ccc(-c5ccccc5)cc4)cc3)c3ccc4c(c3)C(C)(C)c3ccccc3-4)c1-2]

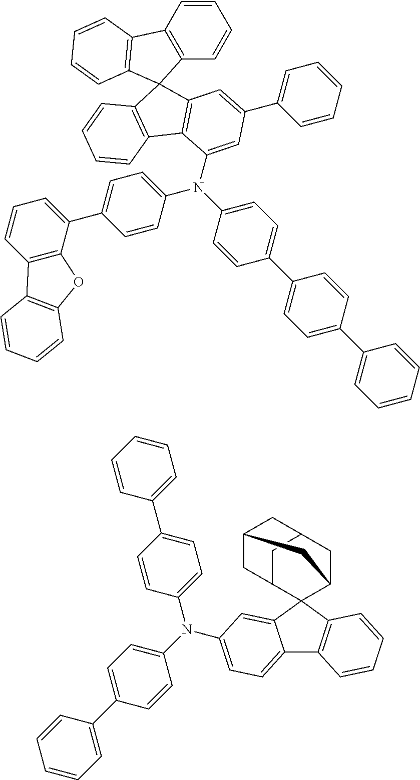 [SMILES: c1ccc(-c2ccc(-c3ccc(N(c4ccc(-c5cccc6c5oc5ccccc56)cc4)c4cc(-c5ccccc5)cc5c4-c4ccccc4C54c5ccccc5-c5ccccc54)cc3)cc2)cc1 ; c1ccc(-c2ccc(N(c3ccc(-c4ccccc4)cc3)c3ccc4c(c3)C3(c5ccccc5-4)C4CC5C[C@H](C4)C[C@H]3C5)cc2)cc1]

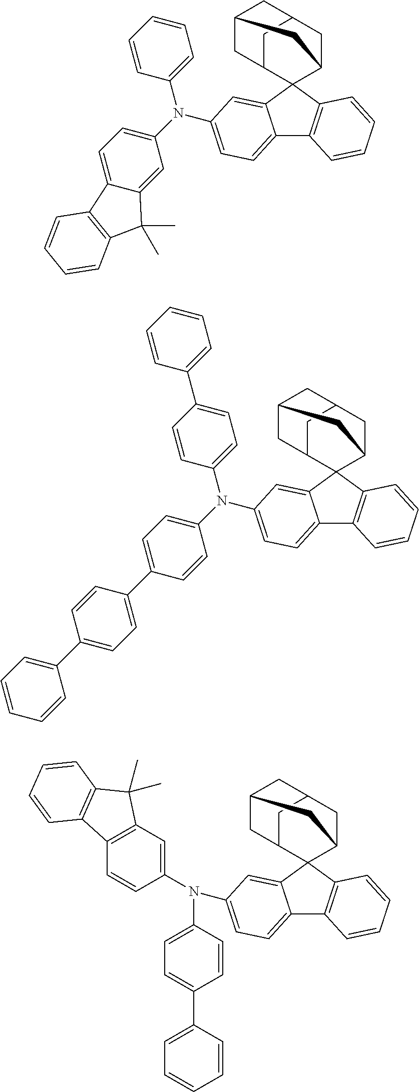

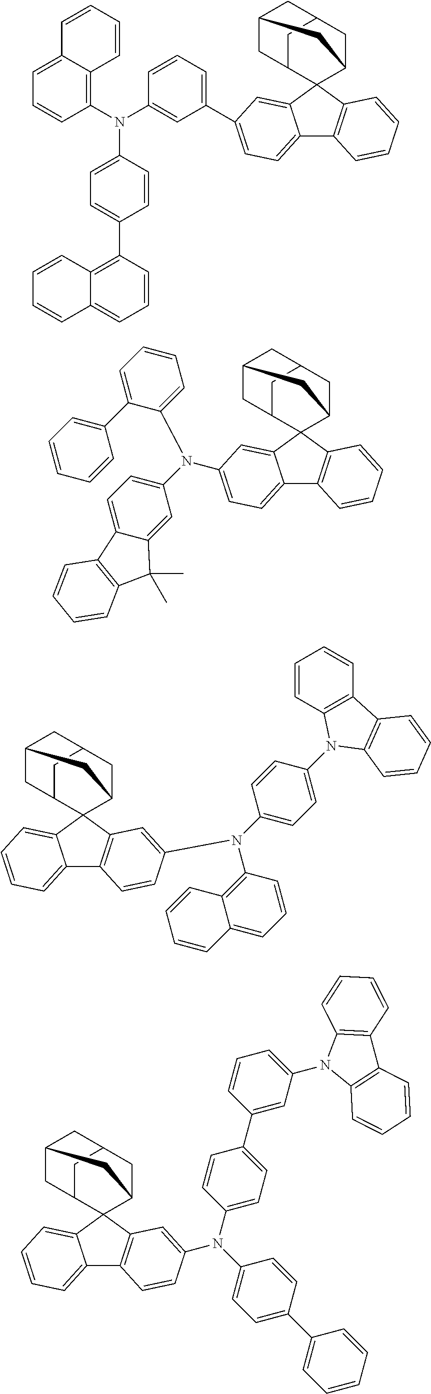

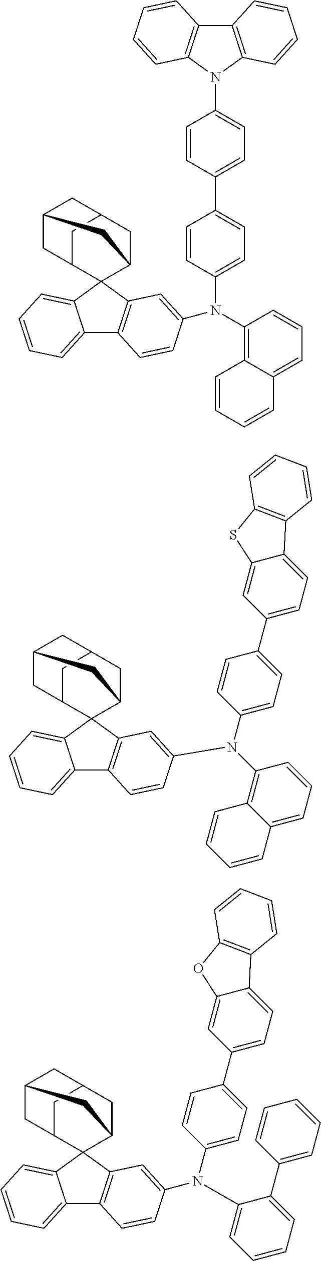

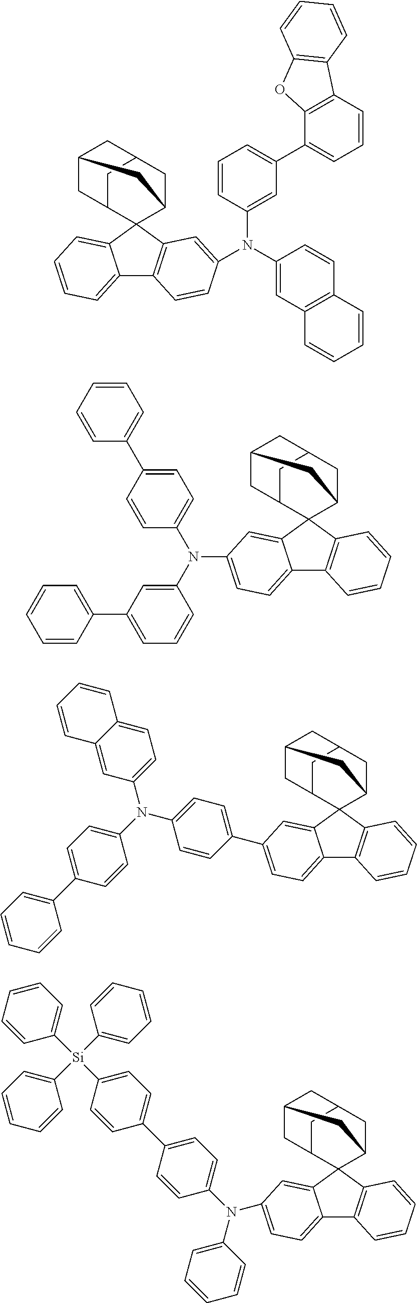

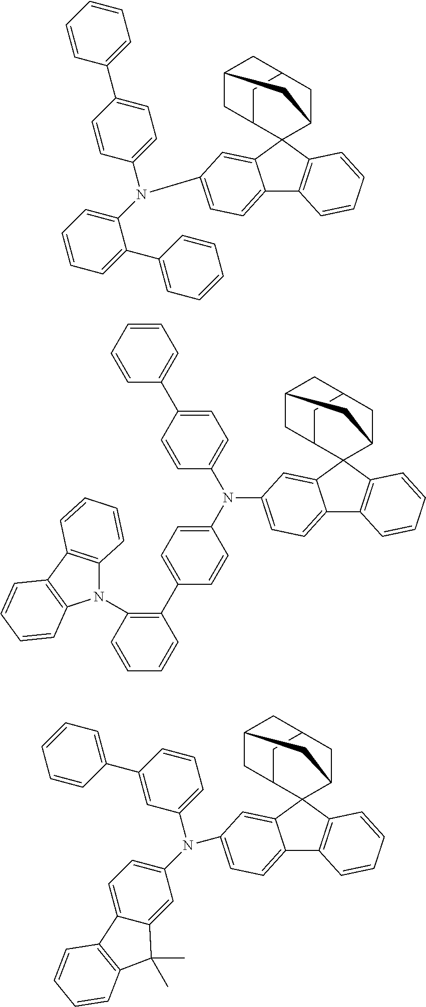

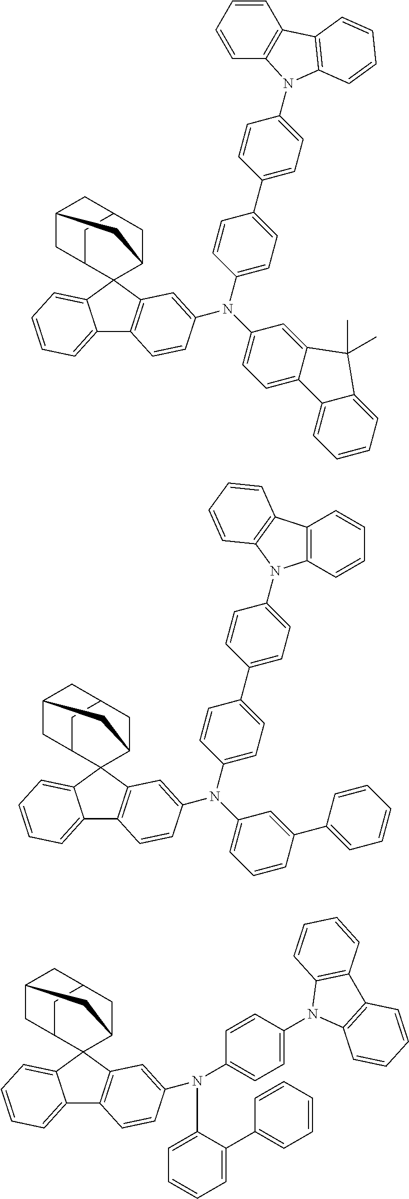 [SMILES: CC1(C)c2ccccc2-c2ccc(N(c3ccc(-c4ccc(-n5c6ccccc6c6ccccc65)cc4)cc3)c3ccc4c(c3)C3(c5ccccc5-4)C4CC5C[C@H](C4)C[C@H]3C5)cc21 ; c1ccc(-c2cccc(N(c3ccc(-c4ccc(-n5c6ccccc6c6ccccc65)cc4)cc3)c3ccc4c(c3)C3(c5ccccc5-4)C4CC5C[C@H](C4)C[C@H]3C5)c2)cc1 ; c1ccc(-c2ccccc2N(c2ccc(-n3c4ccccc4c4ccccc43)cc2)c2ccc3c(c2)C2(c4ccccc4-3)C3CC4C[C@H](C3)C[C@H]2C4)cc1]

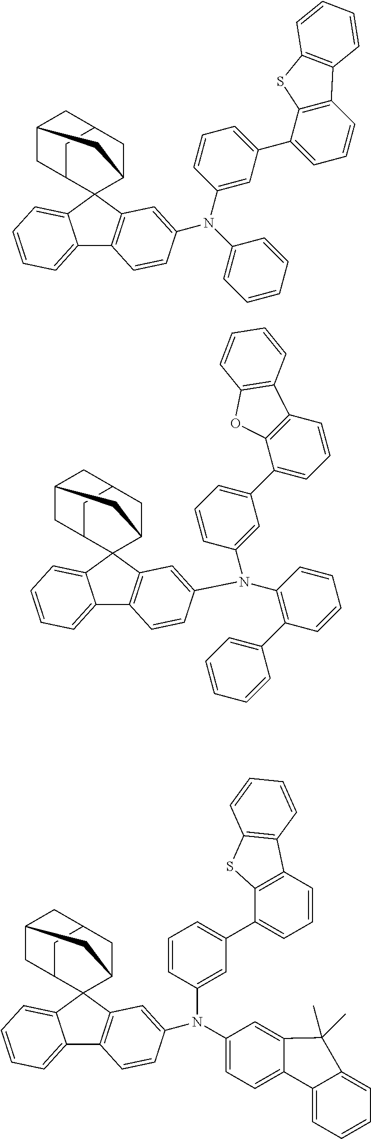

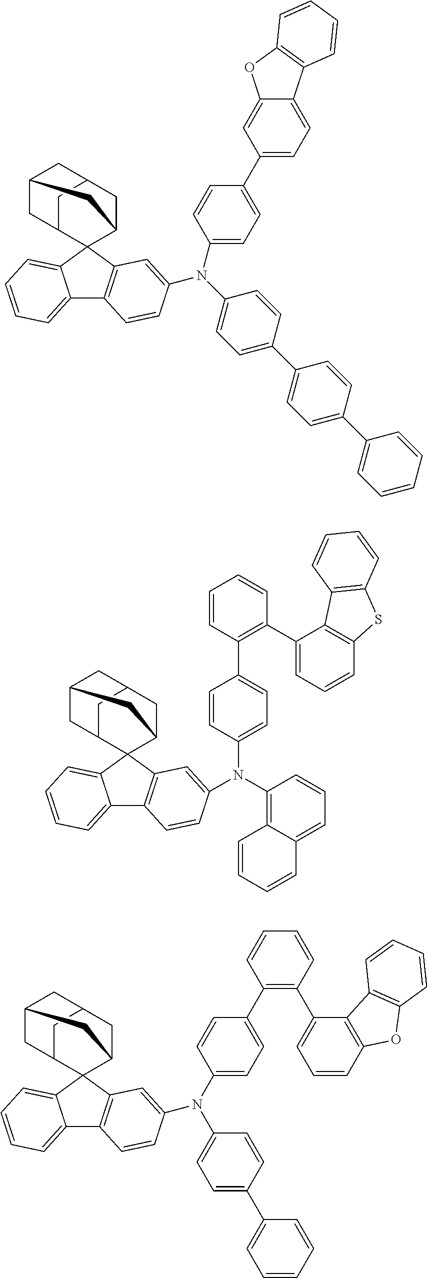

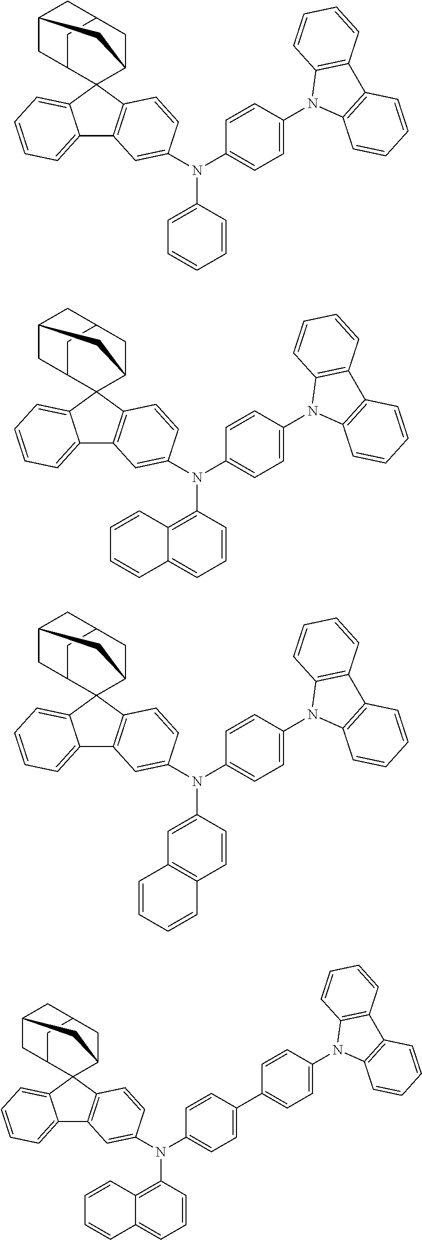 [SMILES: c1ccc(N(c2ccc(-n3c4ccccc4c4ccccc43)cc2)c2ccc3c(c2)-c2ccccc2C32C3CC4C[C@H](C3)C[C@H]2C4)cc1 ; c1ccc2c(c1)-c1cc(N(c3ccc(-n4c5ccccc5c5ccccc54)cc3)c3cccc4ccccc34)ccc1C21C2CC3C[C@H](C2)C[C@H]1C3 ; c1ccc2c(c1)-c1cc(N(c3ccc(-n4c5ccccc5c5ccccc54)cc3)c3ccc4ccccc4c3)ccc1C21C2CC3C[C@H](C2)C[C@H]1C3 ; c1ccc2c(c1)-c1cc(N(c3ccc(-c4ccc(-n5c6ccccc6c6ccccc65)cc4)cc3)c3cccc4ccccc34)ccc1C21C2CC3C[C@H](C2)C[C@H]1C3]

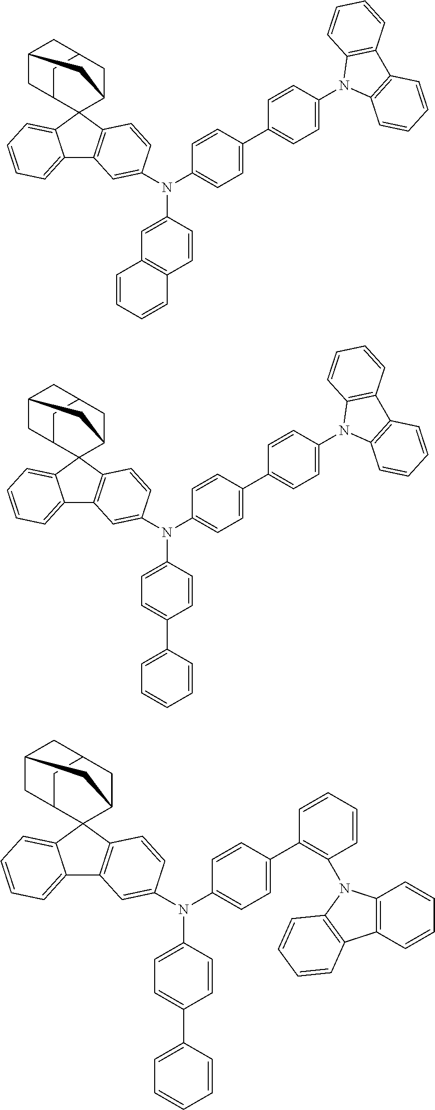 [SMILES: c1ccc2c(c1)-c1cc(N(c3ccc(-c4ccc(-n5c6ccccc6c6ccccc65)cc4)cc3)c3ccc4ccccc4c3)ccc1C21C2CC3C[C@H](C2)C[C@H]1C3 ; c1ccc(-c2ccc(N(c3ccc(-c4ccc(-n5c6ccccc6c6ccccc65)cc4)cc3)c3ccc4c(c3)-c3ccccc3C43C4CC5C[C@H](C4)C[C@H]3C5)cc2)cc1 ; c1ccc(-c2ccc(N(c3ccc(-c4ccccc4-n4c5ccccc5c5ccccc54)cc3)c3ccc4c(c3)-c3ccccc3C43C4CC5C[C@H](C4)C[C@H]3C5)cc2)cc1]

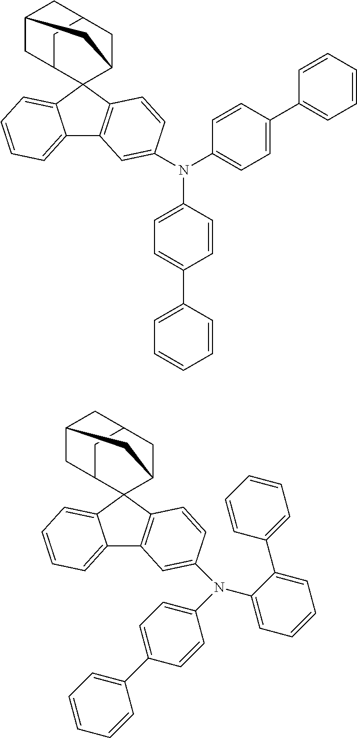 [SMILES: c1ccc(-c2ccc(N(c3ccc(-c4ccccc4)cc3)c3ccc4c(c3)-c3ccccc3C43C4CC5C[C@H](C4)C[C@H]3C5)cc2)cc1 ; c1ccc(-c2ccc(N(c3ccc4c(c3)-c3ccccc3C43C4CC5C[C@H](C4)C[C@H]3C5)c3ccccc3-c3ccccc3)cc2)cc1]

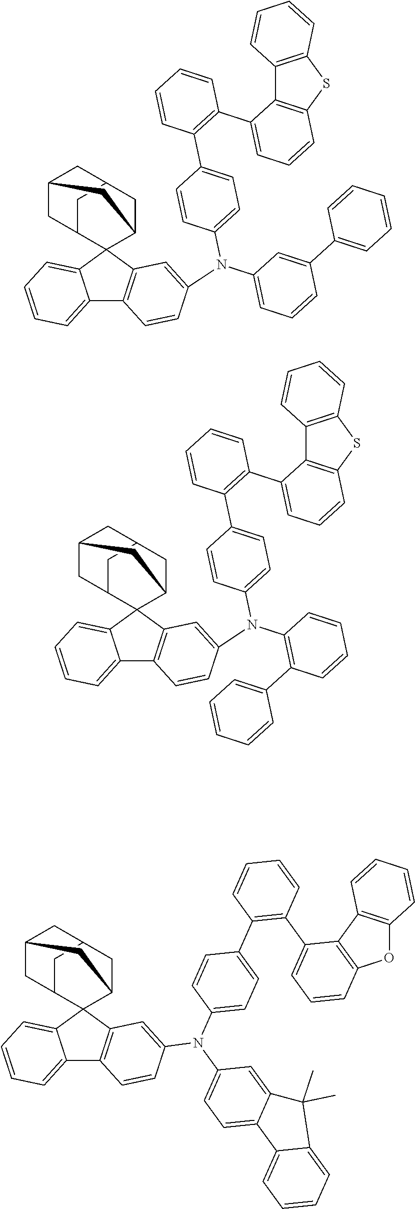 [SMILES: c1ccc(-c2cccc(N(c3ccc(-c4ccccc4-c4cccc5sc6ccccc6c45)cc3)c3ccc4c(c3)C3(c5ccccc5-4)C4CC5C[C@H](C4)C[C@H]3C5)c2)cc1 ; c1ccc(-c2ccccc2N(c2ccc(-c3ccccc3-c3cccc4sc5ccccc5c34)cc2)c2ccc3c(c2)C2(c4ccccc4-3)C3CC4C[C@H](C3)C[C@H]2C4)cc1 ; CC1(C)c2ccccc2-c2ccc(N(c3ccc(-c4ccccc4-c4cccc5oc6ccccc6c45)cc3)c3ccc4c(c3)C3(c5ccccc5-4)C4CC5C[C@H](C4)C[C@H]3C5)cc21]

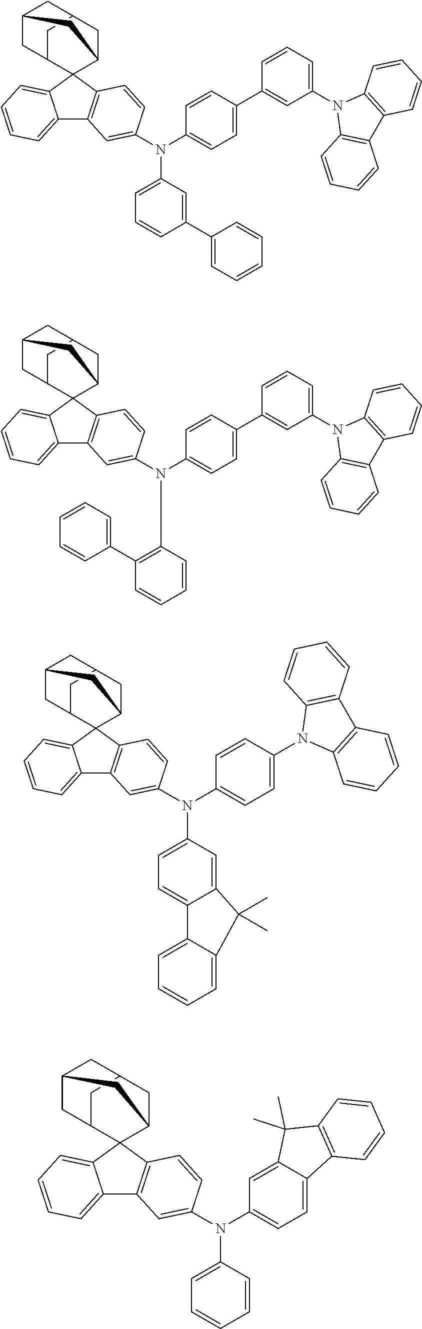 [SMILES: c1ccc(-c2cccc(N(c3ccc(-c4cccc(-n5c6ccccc6c6ccccc65)c4)cc3)c3ccc4c(c3)-c3ccccc3C43C4CC5C[C@H](C4)C[C@H]3C5)c2)cc1 ; c1ccc(-c2ccccc2N(c2ccc(-c3cccc(-n4c5ccccc5c5ccccc54)c3)cc2)c2ccc3c(c2)-c2ccccc2C32C3CC4C[C@H](C3)C[C@H]2C4)cc1 ; CC1(C)c2ccccc2-c2ccc(N(c3ccc(-n4c5ccccc5c5ccccc54)cc3)c3ccc4c(c3)-c3ccccc3C43C4CC5C[C@H](C4)C[C@H]3C5)cc21 ; CC1(C)c2ccccc2-c2ccc(N(c3ccccc3)c3ccc4c(c3)-c3ccccc3C43C4CC5C[C@H](C4)C[C@H]3C5)cc21]

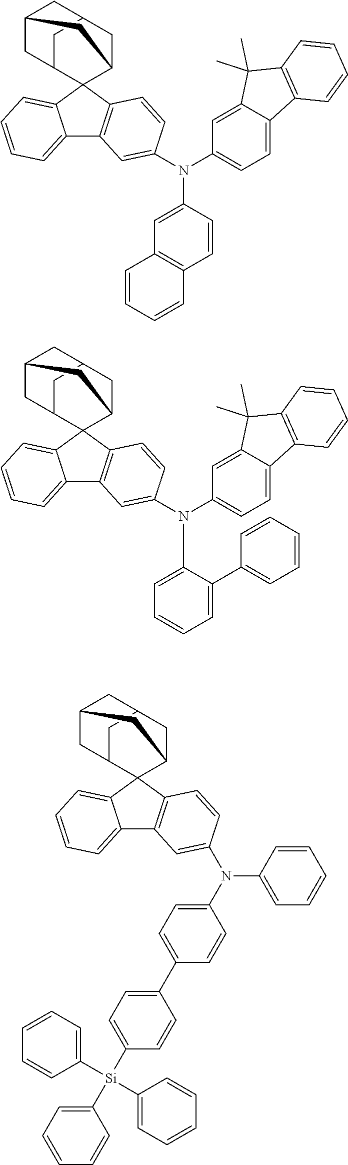 [SMILES: CC1(C)c2ccccc2-c2ccc(N(c3ccc4c(c3)-c3ccccc3C43C4CC5C[C@H](C4)C[C@H]3C5)c3ccc4ccccc4c3)cc21 ; CC1(C)c2ccccc2-c2ccc(N(c3ccc4c(c3)-c3ccccc3C43C4CC5C[C@H](C4)C[C@H]3C5)c3ccccc3-c3ccccc3)cc21 ; c1ccc(N(c2ccc(-c3ccc([Si](c4ccccc4)(c4ccccc4)c4ccccc4)cc3)cc2)c2ccc3c(c2)-c2ccccc2C32C3CC4C[C@H](C3)C[C@H]2C4)cc1]

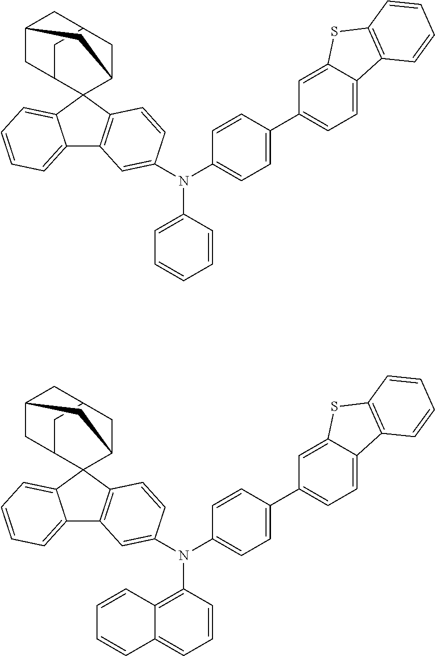 [SMILES: c1ccc(N(c2ccc(-c3ccc4c(c3)sc3ccccc34)cc2)c2ccc3c(c2)-c2ccccc2C32C3CC4C[C@H](C3)C[C@H]2C4)cc1 ; c1ccc2c(c1)-c1cc(N(c3ccc(-c4ccc5c(c4)sc4ccccc45)cc3)c3cccc4ccccc34)ccc1C21C2CC3C[C@H](C2)C[C@H]1C3]

### Hole Transporting Layer

The hole transporting layer is a layer containing a substance exhibiting a high hole transportability.

In an exemplary arrangement of the organic EL device according to the first exemplary embodiment, the hole transporting layers (e.g., the first hole transporting layer and the second hole transporting layer) may contain a compound different from the above-described hole transporting zone material, and for instance, may contain at least one compound selected from the group consisting of an aromatic amine compound, a carbazole derivative, an anthracene derivative, and the like. Specific examples of a compound usable for the hole transporting layer include an aromatic amine compound such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation. TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer, a carbazole derivative such as CBP, CzPA, and PCzPA and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. A layer containing the substance exhibiting a higher hole transportability may be provided in the form of a single layer or a laminated layer of two or more layers of the above substance(s).

In an exemplary arrangement of the organic EL device according to the first exemplary embodiment, the hole transporting zone may include one hole transporting layer, or two or more hole transporting layers.

### Specific Examples of Other Hole Transporting Zone Material

In addition to the above hole transporting zone material, specific examples of other hole transporting zone material include the following compounds. However, the invention is not limited to the specific examples of the hole transporting zone material.

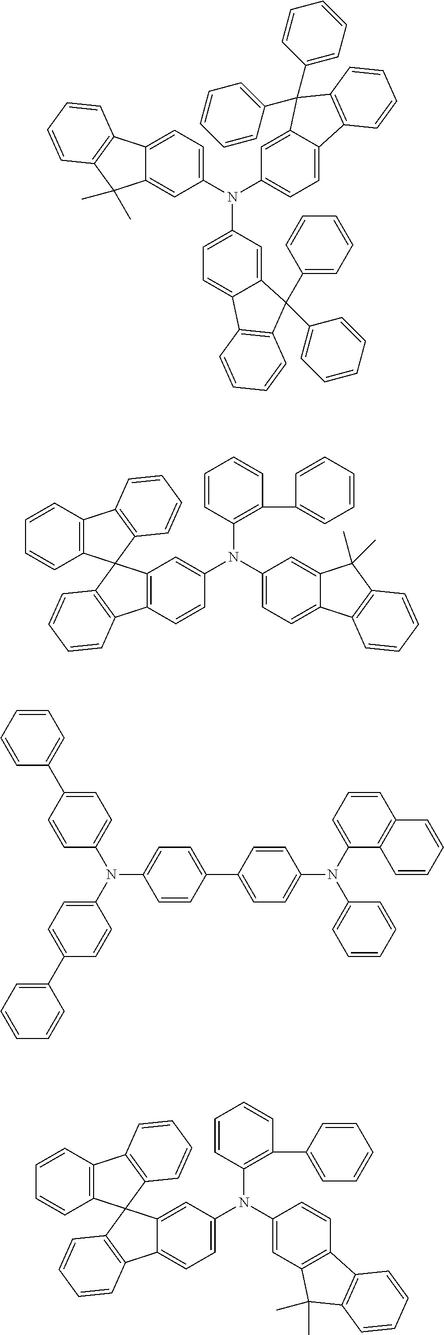 [SMILES: CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; c1ccc(-c2ccc(N(c3ccc(-c4ccccc4)cc3)c3ccc(-c4ccc(N(c5ccccc5)c5cccc6ccccc56)cc4)cc3)cc2)cc1 ; CC1(C)c2ccccc2-c2ccc(N(c3ccc4c(c3)C3(c5ccccc5-c5ccccc53)c3ccccc3-4)c3ccccc3-c3ccccc3)cc21]

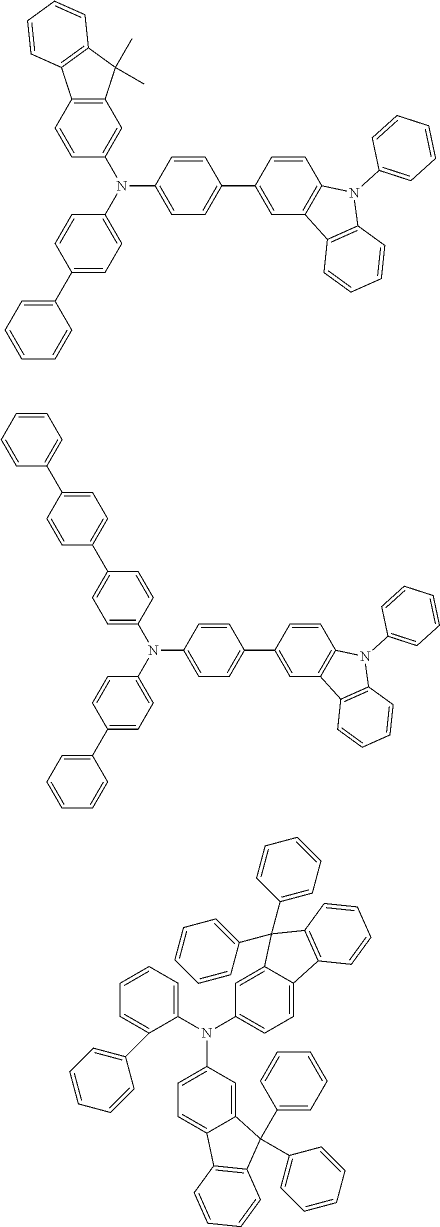 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

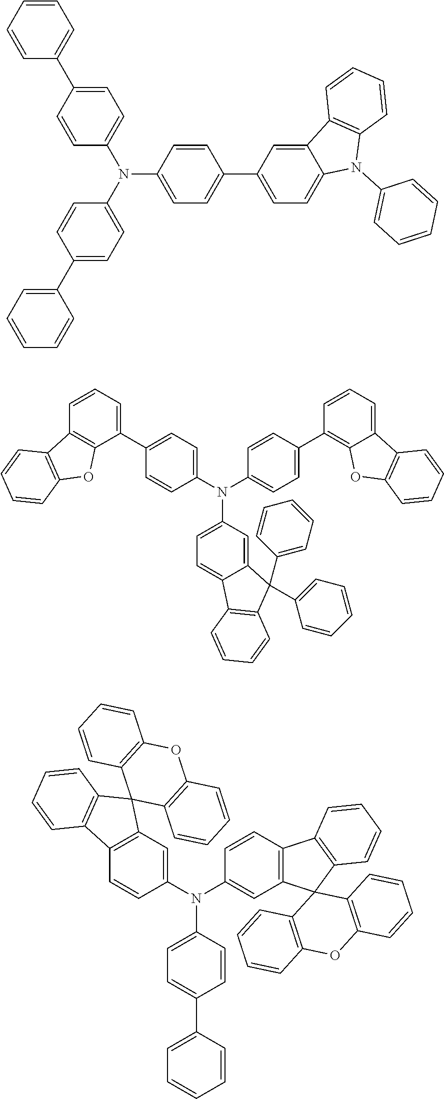 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; c1ccc(-c2ccc(N(c3ccc4c(c3)C3(c5ccccc5Oc5ccccc53)c3ccccc3-4)c3ccc4c(c3)C3(c5ccccc5Oc5ccccc53)c3ccccc3-4)cc2)cc1]

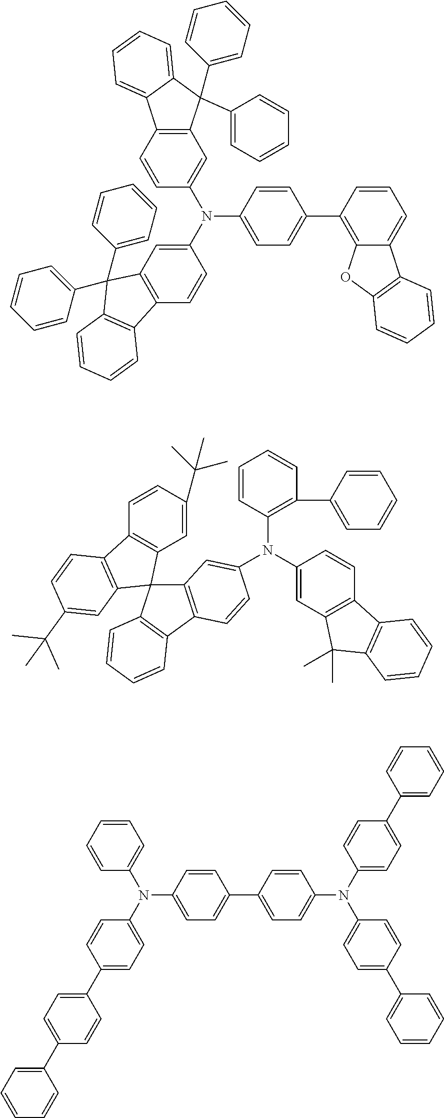 [SMILES: c1ccc(C2(c3ccccc3)c3ccccc3-c3ccc(N(c4ccc(-c5cccc6c5oc5ccccc56)cc4)c4ccc5c(c4)C(c4ccccc4)(c4ccccc4)c4ccccc4-5)cc32)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

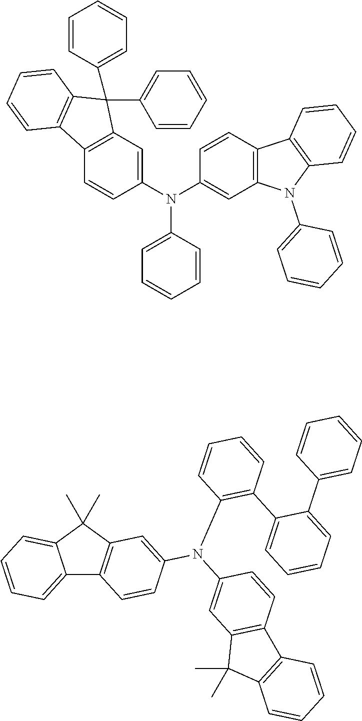 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2ccc(N(c3ccc4c(c3)C(C)(C)c3ccccc3-4)c3ccccc3-c3ccccc3-c3ccccc3)cc21]

### Electron Blocking Layer

Preferably, the electron blocking layer permits transport of holes and blocks electrons from reaching a layer provided closer to the anode (e.g., the hole transporting layer) beyond the electron blocking layer.

In an exemplary arrangement of the organic EL device according to the first exemplary embodiment, the first emitting unit includes the first electron blocking layer and the second emitting unit includes the second electron blocking layer.

In an exemplary arrangement of the organic EL device according to the first exemplary embodiment, a compound contained in the electron blocking layers (e.g., the first electron blocking layer and the second electron blocking layer) is the hole transporting zone material.

In an exemplary arrangement of the organic EL device according to the first exemplary embodiment, a compound contained in the electron blocking layers is a compound represented by the formula (B1) or (B100).

In an exemplary arrangement of the organic EL device according to the first exemplary embodiment, a compound contained in the electron blocking layers is a well-known compound used for the electron blocking layer, which is at least one compound selected from the group consisting of an aromatic amine compound and a carbazole derivative. The compound contained in the electron blocking layers may be a monoamine compound having one substituted or unsubstituted amino group in a molecule. Further, the compound contained in the electron blocking layers may include, in a molecule, a substituted or unsubstituted carbazolyl group and one substituted or unsubstituted amino group.

In order to prevent excitation energy from leaking out from the emitting layer toward neighboring layer(s), the electron blocking layer may block excitons generated in the emitting layer from being transferred to a layer(s) provided closer to the anode (e.g., the hole transporting layer and the hole injecting layer) beyond the electron blocking layer.

### Hole Injecting Layer

In an exemplary arrangement of the organic EL device according to the first exemplary embodiment, the hole injecting layer is disposed between the anode and the emitting zone, or between the charge generating zone and the emitting zone positioned closer to the cathode beyond that charge generating zone.

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the substance exhibiting a high hole injectability further include: an aromatic amine compound, which is a low-molecule organic compound, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1).

In addition, a high polymer compound (e.g., oligomer, dendrimer and polymer) is usable as the substance exhibiting a high hole injectability. Examples of the high polymer compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine](abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) is also usable.

In an exemplary arrangement of the organic EL device according to the exemplary embodiment, a compound (the hole transporting zone material) usable for the hole transporting layer can also be used for the hole injecting layer. In this case, the hole injecting layer preferably contains the hole transporting zone material and an acceptor material.

### Acceptor Material

The acceptor material includes at least one of a first cyclic structure represented by a formula (P11) below or a second cyclic structure represented by a formula (P12) below.

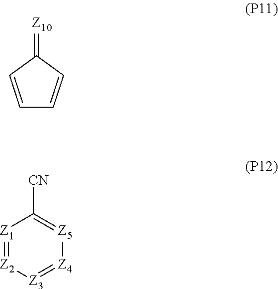

The first cyclic structure represented by the formula (P11) is fused, in a molecule of the acceptor material, to at least one cyclic structure of a substituted or unsubstituted aromatic hydrocarbon ring having 6 to 50 ring carbon atoms or a substituted or unsubstituted heterocycle having 5 to 50 ring atoms; and a structure represented by ═Z₁₀ is represented by a formula (P11a), (P11b), (P11c), (P11d), (P11e), (P11f), (P11g), (P11h), (P11i), (P11j), (P11k) or (P11m) below.

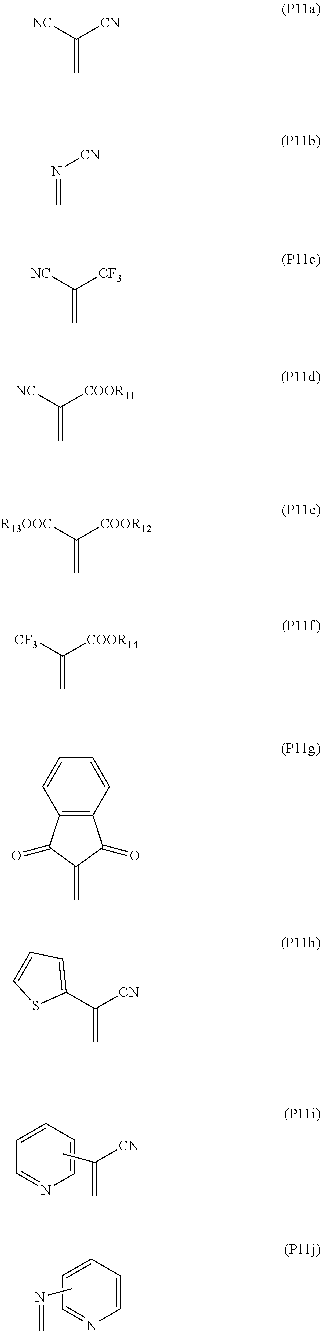

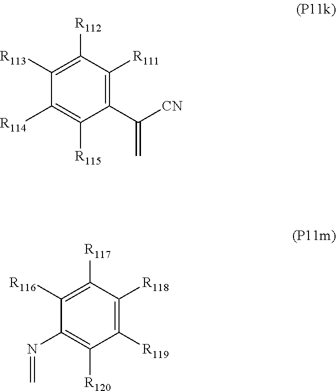

In the formula (P11a), (P11b), (P11c), (P11d), (P11e), (P11f), (P11g), (P11h), (P11 i), (P11j), (P11k) or (P11 m):
R₁₁ to R₁₄ and R₁₁ to R₁₂₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the formula (P12):
Z₁ to Z₅ are each independently a nitrogen atom, a carbon atom bonded to R₁₅, or a carbon atom bonded to another atom in a molecule of the acceptor material;
at least one of Z₁ to Z₅ is a carbon atom bonded to another atom in the molecule of the acceptor material;
R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the acceptor material, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different:
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL devices according to the exemplary embodiment, the acceptor material has at least one cyano group.

In an exemplary arrangement of the organic EL device according to the exemplary embodiment, the hole injecting layer contains the hole transporting zone material, the acceptor material and the hole transporting zone material are different from each other, and a content of the acceptor material in the hole injecting layer is less than 50 mass %.

In an exemplary arrangement of the organic EL device according to the exemplary embodiment, the content of the acceptor material in the hole injecting layer is 10 mass % or less, or 5 mass % or less.

In an exemplary arrangement of the organic EL device according to the exemplary embodiment, the content of the acceptor material in the hole injecting layer is 1 mass % or more, or 3 mass % or less.

In an exemplary arrangement of the organic EL device according to the exemplary embodiment, in a case where the hole injecting layer contains the acceptor material and the hole transporting zone material, a content of the hole transporting zone material in the hole injecting layer is preferably 40 mass % or more, more preferably 45 mass % or more, and still more preferably 50 mass % or more. The content of the hole transporting zone material in the hole injecting layer is preferably 99.5 mass % or less. A total of the content of the acceptor material and the content of the hole transporting zone material in the hole injecting layer is 100 mass % or less.

An ester group herein is at least one group selected from the group consisting of an alkyl ester group and an aryl ester group.

An alkyl ester group herein is represented, for instance, by —C(═O)OR^{E}. R^{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R^{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂. A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having 5 to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms. R^{c} is exemplified by a substituted or unsubstituted alkyl group having 1 to 50 carbon atoms (preferably 1 to 6 carbon atoms).

In the acceptor material, the groups specified to be “substituted or unsubstituted” are also each preferably an “unsubstituted” group.

### Specific Examples of Acceptor Material

Specific examples of the acceptor material include the following compounds. However, the invention is not limited to the specific examples of the acceptor material.

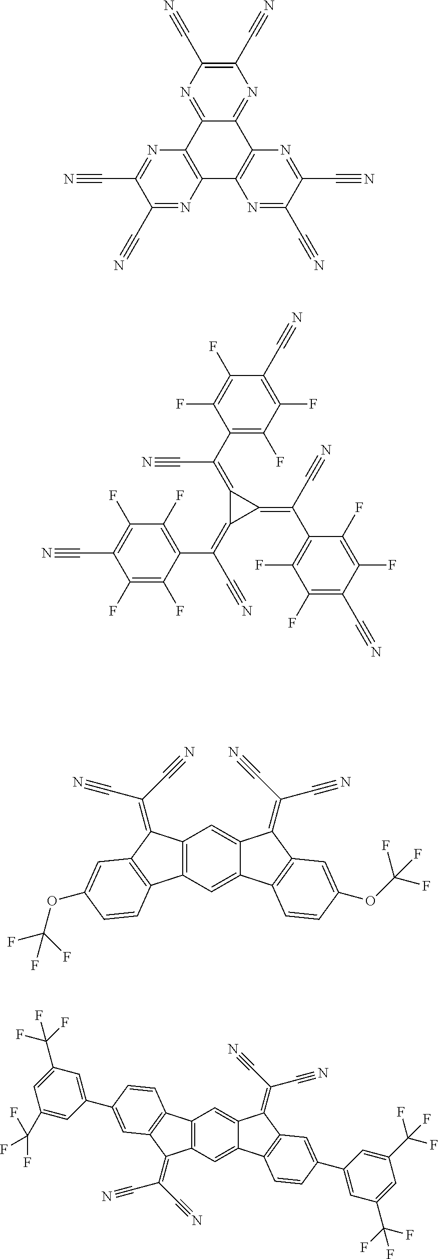 [SMILES: N#Cc1nc2c3nc(C#N)c(C#N)nc3c3nc(C#N)c(C#N)nc3c2nc1C#N ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

### Other Arrangements of Organic EL Device

The arrangement of the organic EL device will be further described below.

### Substrate

A substrate is used as a support for the organic EL device. For instance, glass, quartz, plastics and the like are usable for the substrate. A flexible substrate is also usable. The flexible substrate, which is a bendable substrate, is exemplified by a plastic substrate. Examples of a material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include indium tin oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the Group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys containing the alkali metal or the alkaline earth metal (e.g., MgAg and AlLi), a rare earth metal such as europium (Eu) and ytterbium (Yb), and alloys containing the rare earth metal are also usable for the anode. It should be noted that the vacuum deposition method and the sputtering method are usable for forming the anode using the alkali metal, alkaline earth metal and/or the alloy thereof. Further, when a silver paste is used for the anode, the coating method and the inkjet method are usable.

When the organic EL device is of the bottom emission type, the anode is a light transmissive electrode having light transmissivity. The light transmissive electrode is preferably formed from a light transmissive or semi-transmissive metallic material that allows light from the emitting layer to pass through. The light transmissive or semi-transmissive property herein refers to a property of allowing a transmittance of 50% or more (preferably 80% or more) of the light emitted from the emitting layer. The light transmissive or semi-transmissive metallic material can be selected in use as needed from the above materials listed in the description about the anode. Any material usable for a later-described conductive layer (or a transparent conductive layer) may be used as the light transmissive or semi-transmissive metallic material.

When the organic EL device is of the top emission type, the anode is the light reflective electrode including the light reflective layer. The light reflective layer is preferably formed from a metallic material having light reflectivity. The light reflectivity herein refers to a property of reflecting 50% or more (preferably 80% or more) of light emitted from the emitting layer. The metallic material having light reflectivity can be selected in use as needed from the above materials listed in the description about the anode.

Examples of the metallic material used for the light reflective layer include: a single metal material selected from the group consisting of Al, Ag, Ta, Zn, Mo, W, Ni, Cr, and the like, or an alloy material containing a metal selected from the above group as a main component (preferably 50 mass % or more of the whole); an amorphous alloy selected from the group consisting of NiP, NiB, CrP, CrB, and the like; and microcrystalline alloy selected from the group consisting of NiAl, a silver alloy, and the like.

Also, as the metallic material used for the light reflective layer, at least one alloy selected from the group consisting of APC (silver, palladium and copper alloy), ARA (silver, rubidium and gold alloy), MoCr (molybdenum and chromium alloy), and NiCr (nickel and chromium alloy) is usable.

The light reflective layer may be provided by a single layer or a plurality of layers.

The anode as the light reflectivity electrode may consist of the light reflective layer, or may have a multilayer structure having the light reflective layer and the conductive layer (preferably, the transparent conductive layer). When the anode includes the light reflective layer and the conductive layer, the conductive layer is preferably provided between the light reflective layer and a layer included in a hole transporting zone (e.g., a hole injection layer or a hole transporting layer). Alternatively, the anode may have a multilayer structure in which the light reflective layer is provided between two conductive layers (first conductive layer and second conductive layer). In such a multilayer structure, the first and second conductive layers may be formed from the same material or mutually different materials.

The material used for the conductive layer can be selected in use as needed from the above materials listed in the description about the anode. Metal, an alloy, an electrically conductive compound, a mixture thereof, or the like having a large work function (specifically, 4.0 eV or more) can also be used as the conductive layer (transparent conductive layer) as the transparent electrode.

Further, an alkali metal such as lithium (Li) and cesium (Cs), an alkaline earth metal such as magnesium (Mg), calcium (Ca) and strontium (Sr), an alloy containing at least one selected from the group consisting of an alkali metal and an alkaline earth metal (e.g., MgAg and AlLi), a rare earth metal such as europium (Eu) and ytterbium (Yb), an alloy containing at least one rare earth metal, or the like are also usable for the conductive layer.

### Cathode

It is preferable to use metal, an alloy, an electroconductive compound, a mixture thereof, or the like having a small work function (specifically, 3.8 eV or less) for the cathode. Specific examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), an alloy containing the alkali metal or the alkaline earth metal (e.g., MgAg and AlLi), a rare earth metal such as europium (Eu) and ytterbium (Yb), and an alloy containing the rare earth metal.

It should be noted that the vacuum deposition method and the sputtering method are usable for forming the cathode using the alkali metal, alkaline earth metal and/or the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method, and the like.

When the organic EL device is of the bottom emission type, the cathode is the light reflective electrode. The light reflective electrode is preferably formed from a metallic material having light reflectivity. The metallic material having light reflectivity can be selected in use as needed from the above materials listed in the description about the cathode. Further, any metallic material usable for the light reflective layer given above may be used as the metallic material having light reflectivity.

When the organic EL device is of the top emission type, the cathode is the light transmissive electrode having light transmissivity. The light transmissive electrode is preferably formed from a light transmissive or semi-transmissive metallic material that allows light from the emitting layer to pass through. The light transmissive or semi-transmissive property refers to a property of allowing a transmittance of 50% or more (preferably 80% or more) of the light emitted from the emitting layer. The light transmissive or semi-transmissive metallic material can be selected in use as needed from the above materials listed in the description about the cathode. Any material usable for the above-described conductive layer (or the transparent conductive layer) may be used as the light transmissive or semi-transmissive metallic material.

### Capping Layer

The organic EL device of the top emission type typically includes a capping layer on the top of the cathode. The capping layer may contain, for instance, at least one compound selected from the group consisting of a high polymer compound, metal oxide, metal fluoride, metal boride, silicon nitride, and silicon compound (e.g., silicon oxide). In addition, the capping layer may contain, for instance, at least one compound selected from the group consisting of an aromatic amine derivative, anthracene derivative, pyrene derivative, fluorene derivative, and dibenzofuran derivative. Moreover, a laminate obtained by layering layers containing the above substance(s) is also usable as the capping layer.

The organic EL device according to the exemplary embodiment may be a bottom emission type organic EL device. The organic EL device according to the exemplary embodiment may be a top emission type organic EL device.

When the organic EL device is of the bottom emission type, it is preferable that the anode is a light transmissive electrode having light transmissivity, and the cathode is a light reflective electrode having light reflectivity.

When the organic EL device is of the top emission type, it is preferable that the anode is a light reflective electrode having light reflectivity, and the cathode is the light transmissive electrode having light transmissivity.

### Examples of Schematic Arrangement of Organic EL Device

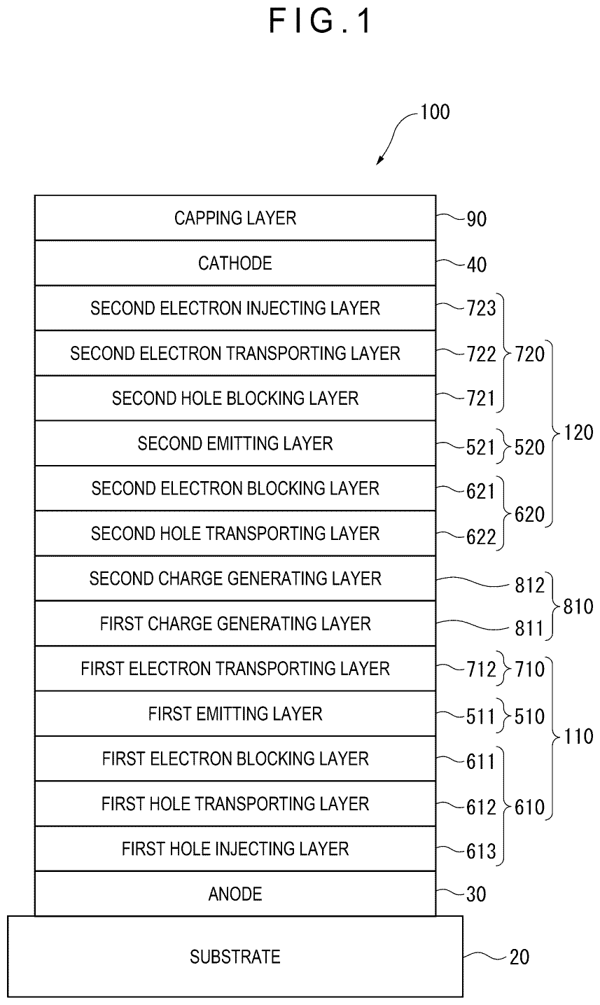

FIG. 1 schematically depicts an exemplary arrangement of an organic EL device according to the exemplary embodiment. An organic EL device 100 depicted in FIG. 1 includes a substrate 20, an anode 30, a cathode 40, a first emitting unit 110 disposed between the anode 30 and the cathode 40, a first charge generating zone 810, and a second emitting unit 120. The first emitting unit 110, the first charge generating zone 810 and the second emitting unit 120 are disposed in this order from a side close to the anode 30. The organic EL device 100 includes a capping layer 90 disposed on a surface of the cathode 40 opposite to a surface facing the second emitting unit 120.

The first emitting unit 110 includes a first hole transporting zone 610, a first emitting zone 510, and a first electron transporting zone 710 in the order from a side close to the anode 30. The first hole transporting zone 610 includes a first hole injecting layer 613, a first hole transporting layer 612, and a first electron blocking layer 611 in the order from the side close to the anode 30. The first emitting zone 510 includes a first emitting layer 511. The first electron transporting zone 710 includes a first electron transporting layer 712.

The first charge generating zone 810 includes a first charge generating layer 811 and a second charge generating layer 812 in the order from a side close to the first emitting unit 110.

The second emitting unit 120 includes a second hole transporting zone 620, a second emitting zone 520, and a second electron transporting zone 720 in the order from a side close to the first charge generating zone 810. The second hole transporting zone 620 includes a second hole transporting layer 622, and a second electron blocking layer 621 in the order from the side close to the first charge generating zone 810. The second emitting zone 520 includes a second emitting layer 521. The second electron transporting zone 720 includes a second hole blocking layer 721, a second electron transporting layer 722, and a second electron injecting layer 723 in the order from a side close to the second emitting zone 520.

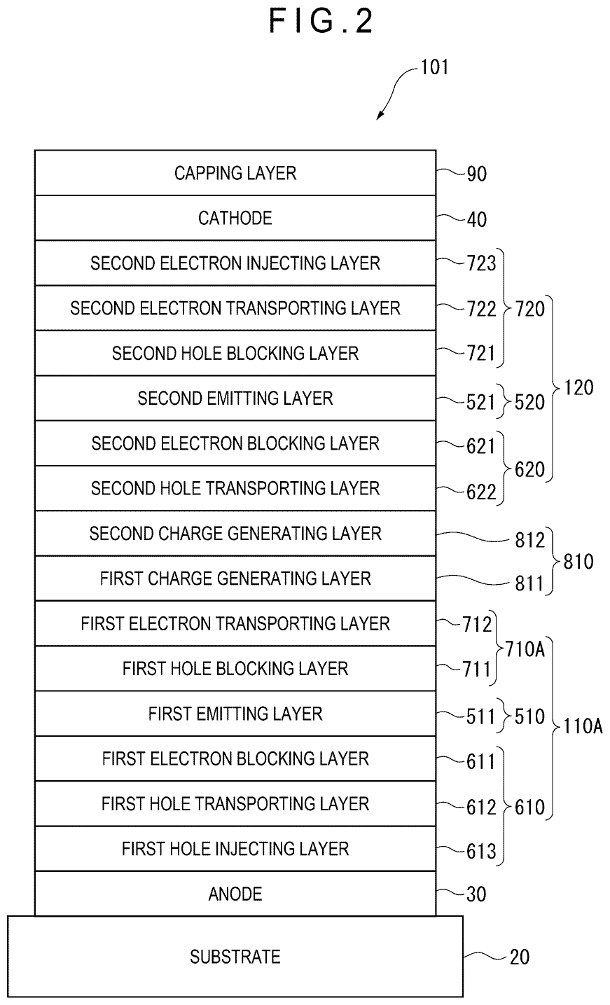

FIG. 2 schematically depicts another exemplary arrangement of the organic EL device according to the exemplary embodiment.

An organic EL device 101 includes the substrate 20, the anode 30, the cathode 40, a first emitting unit 110A disposed between the anode 30 and the cathode 40, the first charge generating zone 810, and the second emitting unit 120. The first emitting unit 110A, the first charge generating zone 810 and the second emitting unit 120 are disposed in this order from a side close to the anode 30. The organic EL device 101 includes the capping layer 90 disposed on a surface of the cathode 40 opposite to a surface facing the second emitting unit 120.

The first emitting unit 110A includes the first hole transporting zone 610, the first emitting zone 510, and a first electron transporting zone 710A in the order from a side close to the anode 30. The first hole transporting zone 610 includes the first hole injecting layer 613, the first hole transporting layer 612, and the first electron blocking layer 611 in the order from the side close to the anode 30. The first emitting zone 510 includes the first emitting layer 511. The first electron transporting zone 710A includes a first hole blocking layer 711 and the first electron transporting layer 712 in the order from the side close to the anode 30.

The first charge generating zone 810 includes the first charge generating layer 811 and the second charge generating layer 812 in the order from a side close to the first emitting unit 110A.

The second emitting unit 120 includes the second hole transporting zone 620, the second emitting zone 520, and the second electron transporting zone 720 in the order from a side close to the first charge generating zone 810. The second hole transporting zone 620 includes the second hole transporting layer 622 and the second electron blocking layer 621 in the order from the side close to the first charge generating zone 810. The second emitting zone 520 includes the second emitting layer 521. The second electron transporting zone 720 includes the second hole blocking layer 721, the second electron transporting layer 722, and the second electron injecting layer 723 in the order from a side close to the second emitting zone 520.

The invention is not limited to the exemplary arrangements of the organic EL device depicted in FIGS. 1 and 2.

### Layer Formation Method

A method of forming each layer of the organic EL device in the exemplary embodiment is subject to no limitation except for the above particular description. Known methods of dry film-forming such as vacuum deposition, sputtering, plasma or ion plating and wet film-forming such as spin coating, dipping, flow coating or ink-jet are applicable.

In the organic EL device of the exemplary embodiment, a layer containing a plurality of substances is, for instance, formable by co-deposition using a plurality of compounds and the like; formable by vapor-deposition using a mixture obtained by mixing in advance (premixing) a plurality of compounds and the like; or formable by coating using a mixture obtained by mixing in advance a plurality of compounds. The mixture obtained by mixing in advance a plurality of compounds may be powder or a solution A method of mixing in advance a plurality of compounds and the like is occasionally referred to as premix. The premix method is not particularly limited. For instance, a vapor-deposition ratio of compounds and the like forming the mixture obtained by the premix is adjustable by adjusting a substituent(s) or the like of the compound(s) forming the mixture to adjust a molecular weight of the compound(s), or adjusting its mixing ratio.

### Film Thickness

A film thickness of each organic compound layer in the organic EL device of the exemplary embodiment is not limited unless otherwise specified above. In general, the film thickness preferably ranges from several nanometers to 1 μm because excessively small film thickness is likely to cause defects (e.g. pin holes) and excessively large film thickness leads to the necessity of applying high voltage and consequent reduction in efficiency.

### Emission Wavelength of Organic EL Device

The organic EL device according to an exemplary arrangement of the exemplary embodiment emits blue light, green light, red light or white light.

Herein, blue light emission refers to light emission having a maximum peak wavelength of an emission spectrum in a range from 430 nm to 480 nm.

Herein, green light emission refers to light emission having a maximum peak wavelength of an emission spectrum in a range from 500 nm to 560 nm.

Herein, red light emission refers to light emission having a maximum peak wavelength of an emission spectrum in a range from 600 nm to 660 nm.

A peak wavelength of the emission spectrum exhibiting the maximum luminous intensity is defined as the maximum peak wavelength.

In an exemplary arrangement of the organic EL device according to the exemplary embodiment, the maximum peak wavelength of light emitted from the organic EL device is in a range from 430 nm to 480 nm.

In an exemplary arrangement of the organic EL device according to the exemplary embodiment, the maximum peak wavelength of light emitted from the organic EL device is in a range from 500 nm to 560 nm.

In an exemplary arrangement of the organic EL device according to the exemplary embodiment, the maximum peak wavelength of light emitted from the organic EL device is in a range from 600 nm to 660 nm.

The maximum peak wavelength of the light emitted from the organic EL device when being driven is measured as follows. Voltage is applied on the organic EL device such that a current density becomes 10 mA/cm², where spectral radiance spectrum is measured by a spectroradiometer CS-2000 (manufactured by Konica Minolta, Inc.). A peak wavelength of an emission spectrum, at which the luminous intensity of the resultant spectral radiance spectrum is at the maximum, is measured and defined as the maximum peak wavelength (unit: nm).

In an exemplary arrangement of the organic EL device according to the first exemplary embodiment, a plurality of emitting units each independently emit blue light, red light or green light. When the plurality of emitting units of the organic EL device according to the first exemplary embodiment each emit green light, red light or blue light, the maximum peak wavelength of the light emitted from each emitting unit is the same as the maximum peak wavelength of the corresponding green light, red light or blue light emitted from the organic EL device.

The maximum peak wavelength of light emitted by each emitting unit of the organic EL device when driven can be measured in the same manner as the measurement method of the maximum peak wavelength of the organic EL device, for instance, by applying the measurement method to a device arrangement with a measurement target emitting unit (i.e., the emitting unit(s) other than the measurement target emitting unit are excluded).

### Second Exemplary Embodiment

### Electronic Device

An electronic device according to a second exemplary embodiment includes the organic electroluminescence device according to the above exemplary embodiment. Examples of the electronic device include a display device and a light-emitting unit.

Examples of the display device include, for instance, a display component (e.g., an organic EL panel module), TV, mobile phone, tablet and personal computer. Examples of the light-emitting unit include an illuminator and a vehicle light. The light-emitting unit can also be used for a display device, for instance, as a backlight of the display device.

### Modifications of Exemplary Embodiments

The scope of the invention is not limited by the above-described exemplary embodiments but includes any modification and improvement as long as such modification and improvement are compatible with the invention.

For instance, the number of emitting layers is not limited to one or two, and more than two emitting layers may be layered. For instance, the rest of the emitting layers may be a fluorescent emitting layer or a phosphorescent emitting layer with the use of emission caused by electron transfer from the triplet excited state directly to the ground state.

The specific structure, shape, and the like of the components in the invention may be designed in any manner as long as an object of the invention can be achieved.

### EXAMPLES

The invention will be described in further detail with reference to Examples. The scope of the invention is by no means limited to Examples.

### Compounds

Structures of compounds contained in the low refractive index layer and used for producing an organic EL device in Example 1 are given below.

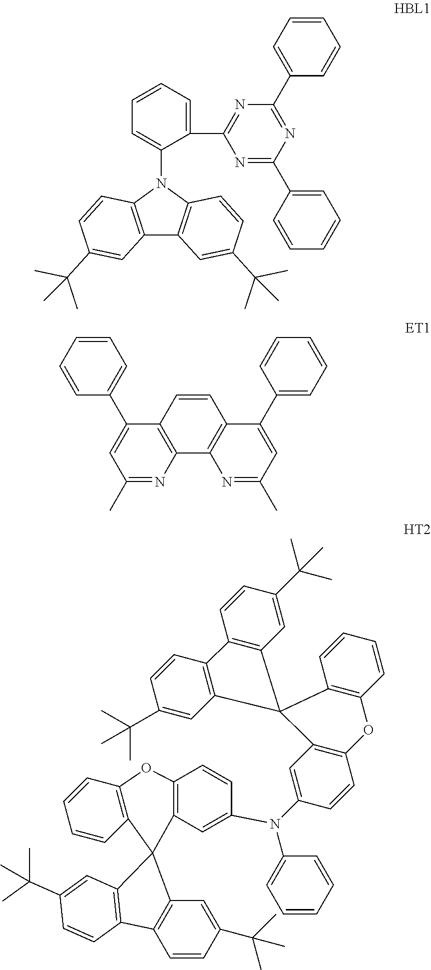

Structures of comparative compounds used for producing an organic EL device in Comparative 1 are given below.

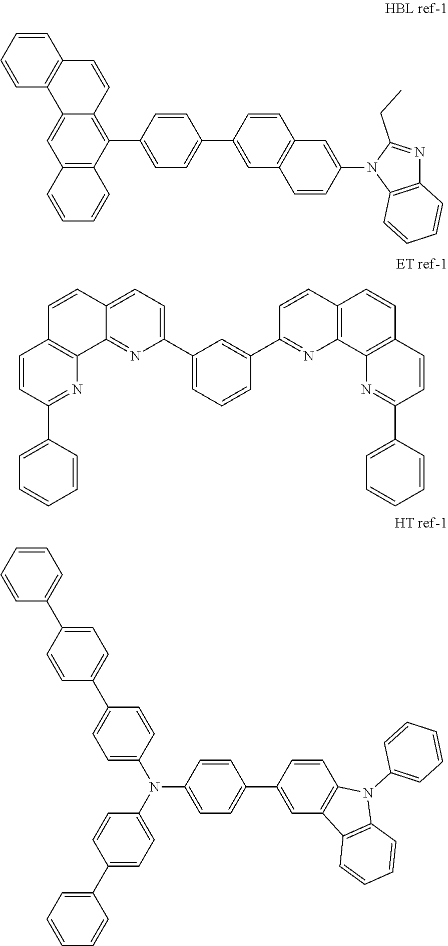

Structures of other compounds used for producing the organic EL devices in Example 1 and Comparative 1 are given below.

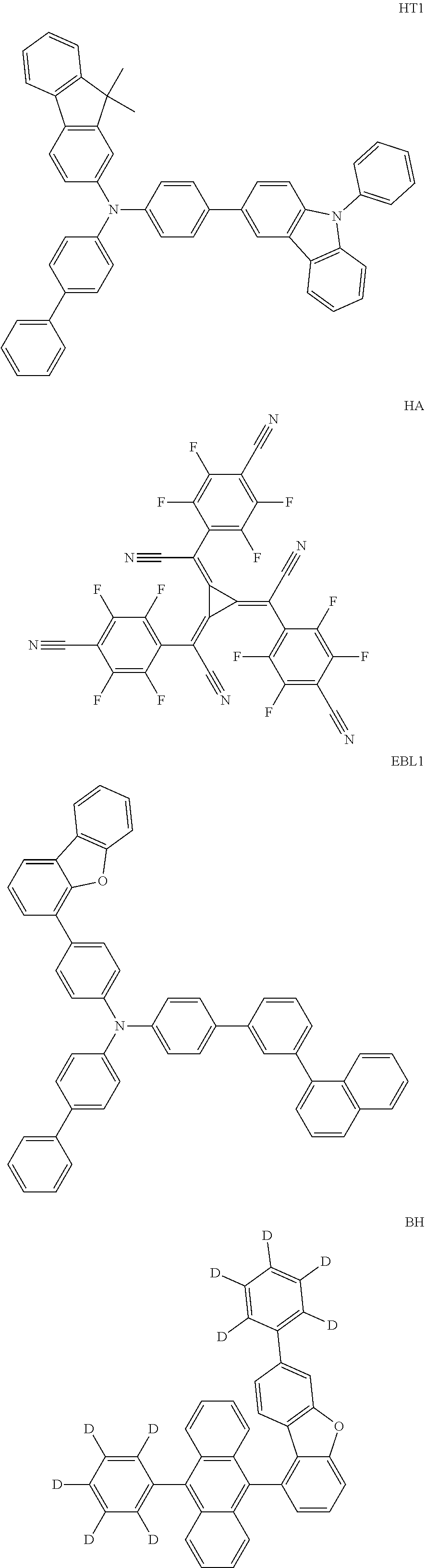 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cccc(-c5cccc6ccccc56)c4)cc3)c3ccc(-c4cccc5c4oc4ccccc45)cc3)cc2)cc1 ; [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H]]

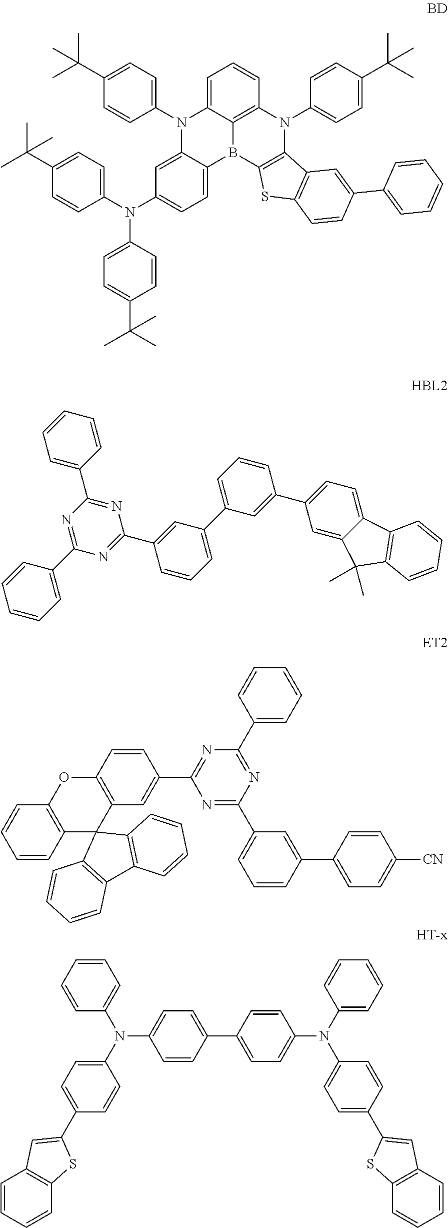

### Production of EL Device

### Example 1

A substrate for device production, which was obtained by layering a metal Ag layer serving as a reflection layer, and an ITO layer serving as a transparent conductive layer having a film thickness of 10 nm in this order onto a glass substrate (25 mm×75 mm×0.7 mm thick), was prepared. An electrical conductive material layer of the substrate for device production includes the metal Ag layer and the ITO layer. Subsequently, the electrical conductive material layer was patterned by etching using a resist pattern as a mask with an ordinary lithography technique to form a lower electrode (anode).

### First Emitting Unit

Next, a compound HT1 and a compound HA were co-deposited to cover the lower electrode (anode), thereby forming a first hole injecting layer having a film thickness of 10 nm. The ratios of the compound HT1 and the compound HA in the first hole injecting layer were 97 mass % and 3 mass %, respectively.

The compound HT1 was vapor-deposited on the first hole injecting layer to form a first hole transporting layer having a film thickness of 25 nm.

Next, a compound EBL1 was vapor-deposited on the first hole transporting layer to form a first electron blocking layer having a film thickness of 5 nm.

A compound BH serving as a first host material and a compound BD serving as a first luminescent compound were co-deposited on the first electron blocking layer, thereby forming a first emitting layer having a film thickness of 19 nm. The ratios of the compound BH and the compound BD in the first emitting layer were 99 mass % and 1 mass %, respectively.

A compound HBL1 was vapor-deposited on the first emitting layer to form a first electron transporting layer having a film thickness of 15 nm.

The first emitting unit including the first hole injecting layer, the first hole transporting layer, the first electron blocking layer, the first emitting layer, and the first electron transporting layer was formed as described above.

### First Charge Generating Zone

A compound ET1 and ytterbium (Yb) were co-deposited on the first electron transporting layer of the first emitting unit to form a first charge generating layer having a film thickness of 7.5 nm. The ratios of the compound ET1 and Yb in the first charge generating layer were 97.5 mass % and 2.5 mass %, respectively.

Next, a compound HT2 and the compound HA were co-deposited on the first charge generating layer to form a second charge generating layer having a film thickness of 10 nm. The ratios of the compound HT2 and the compound HA in the second charge generating layer were 93 mass % and 7 mass %, respectively.

The first charge generating zone including the first charge generating layer and the second charge generating layer was formed as described above.

### Second Emitting Unit

The compound HT2 was vapor-deposited on the second charge generating layer of the first charge generating zone to form a second hole transporting layer having a film thickness of 40 nm.

Next, the compound EBL1 was vapor-deposited on the second hole transporting layer to form a second electron blocking layer having a film thickness of nm.

The compound BH serving as a second host material and the compound BD serving as a second luminescent compound were co-deposited on the second electron blocking layer, thereby forming a second emitting layer having a film thickness of 19 nm. The ratios of the compound BH and the compound BD in the second emitting layer were 99 mass % and 1 mass %, respectively.

A compound HBL2 was vapor-deposited on the second emitting layer to form a second hole blocking layer having a film thickness of 5 nm.

A compound ET2 and Liq were co-deposited on the second hole blocking layer to form a second electron transporting layer having a film thickness of 31 nm. The ratios of the compound ET2 and Liq in the second electron transporting layer were each 50 mass %. Liq is an abbreviation of (8-quinolinolato)lithium.

Ytterbium (Yb) was vapor-deposited on the second electron transporting layer to form a second electron injecting layer having a film thickness of 1 nm.

The second emitting unit including the second hole transporting layer, the second electron blocking layer, the second emitting layer, the second hole blocking layer, the second electron transporting layer, and the second electron injecting layer was formed as described above.

Next, Mg and Ag were co-deposited on the second electron injecting layer of the second emitting unit such that the mixing ratio Mg:Ag (ratio by mass %) was 10%:90% to form an upper electrode (cathode) including a semi-light-transmissive MgAg alloy and having a total film thickness of 13 nm

Subsequently, a compound Ht-x was vapor-deposited over the entire surface of the upper electrode (cathode) to form a capping layer having a film thickness of 65 nm.

A top-emission organic EL device according to Example 1 was produced as described above. A device arrangement of the organic EL device in Example 1 is roughly shown as follows.

Ag/ITO(10)/HT1: HA(10,97%:3%)/HT1(25)/EBL1(5)/BH:BD(19,99%:1%)/HB L₁(15)/ET1:Yb(7.5,97.5%:2.5%)/HT2: HA(10,93%:7%)/HT2(40)/EBL1(5)/BH:BD(19, 99%:1%)/HBL2(5)/ET2: Liq(31,50%:50%)/Yb(1)/Mg:Ag(13,10%:90%)/HT-x(65)

### Comparative 1

An organic EL device in Comparative 1 was produced as in Example 1 except that the compounds HBL1, ET1, and HT2 used in the first electron transporting layer, the first charge generating layer, the second charge generating layer and the second hole transporting layer of Example 1 were replaced with compounds HBL ref-1, ET ref-1 and HT ref-1 listed in Table 1, respectively.

### Evaluation of Organic EL Devices

The produced organic EL devices were evaluated as follows. Table 1 shows the evaluation results. The refractive indices and triplet energies T₁ of the compounds used in the layers in each Example are also shown in Table 1.

### External Quantum Efficiency EQE

Voltage was applied to the organic EL devices such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra were provided under a Lambertian radiation. Table 1 shows the relative value of EQE. The relative value of EQE was calculated based on EQE in each Example (Example 1 and Comparative 1) according to a numerical formula (Numerical Formula X1) below. The unit of the relative value of EQE is %.

$$EQE ( relative value ) = ( EQE of each Example / EQE of Comparative 1 ) \times 100 \qquad ( Numerical Formula X1 )$$

TABLE 1

| | | | | First Electron | | | First Charge | | | Second Charge | | | Second Hole | | |
|---|---|---|---|---|---|---|---|---|---|---|---|---|---|---|---|
| | First Emitting Layer | | | Transporting Layer | | | Generating Layer | | | Generating Layer | | | Transporting Layer | | |
| | | | | Film Thickness: 15 nm | | | Film Thickness: 7.5 nm | | | Film Thickness: 10 nm | | | Film Thickness: 40 nm | | |
| | | | First | First Electron | | | First Charge | | | Second Charge | | | Second Hole | | Device |
| | First | | Lumi- | Transporting | | | Generating | | | Generating | | | Transporting | | Eval- |
| | Host | | nescent | Zone Material | | | Zone Material | | | Zone Material | | | Zone Material | | uation |
| | Material | | Com- | | | Refrac- | | Refrac- | | | Refrac- | Acceptor | | Refrac- | EQE |
| | | T₁ | pound | | T₁ | tive | | tive | Metal | | tive | Material | | tive | (relative |
| | Name | [eV] | Name | Name | [eV] | Index | Name | Index | Name | Name | Index | Name | Name | Index | value) |
| Ex. 1 | BH | 1.85 | BD | HBL1 | 2.90 | 1.69 | ET1 | 1.75 | Yb | HT2 | 1.68 | HA | HT2 | 1.68 | 105% |
| Comp. 1 | BH | 1.85 | BD | HBL | 2.07 | 1.95 | ET | 1.90 | Yb | HT | 2.00 | HA | HT | 2.00 | 100% |
| | | | | ref-1 | | | ref-1 | | | ref-1 | | | ref-1 | | |

In the organic EL device according to Example 1, four low refractive index layers (the first electron transporting layer, the first charge generating layer, the second charge generating layer, and the second hole transporting layer) each contained an organic material with a refractive index of 1.87 or less and were disposed between the first emitting layer in the first emitting unit and the second emitting layer in the second emitting unit. The four low refractive index layers were in direct contact, and a total film thickness thereof was 50 nm or more. The organic EL device according to Example 1 including such low refractive index layers improved light extraction effect, resulting in improvement in external quantum efficiency.

In the organic EL device according to Comparative 1, layers disposed between the first emitting layer in the first emitting unit and the second emitting layer in the second emitting unit each contained an organic material with a refractive index of 1.90 or more, which were not low refractive index layers. Accordingly, in the organic EL device according to Comparative 1, the light extraction effect was not improved and the external quantum efficiency was also low, compared with that according to Example 1.

### Evaluation on Compounds

### Triplet Energy T₁

A measurement target compound was dissolved in EPA (diethylether:isopentane:ethanol=5:5:2 in volume ratio) at a concentration of 10 μmol/L, and the obtained solution was put in a quartz cell to provide a measurement sample. A phosphorescence spectrum (ordinate axis: phosphorescent luminous intensity, abscissa axis: wavelength) of the measurement sample was measured at a low temperature (77K). A tangent was drawn to the rise of the phosphorescence spectrum close to the short-wavelength region. An energy amount was calculated by a conversion equation (F1) below on a basis of a wavelength value λ_{edge} [nm] at an intersection of the tangent and the abscissa axis. The calculated energy amount was defined as triplet energy T₁. It should be noted that the triplet energy T₁ may have an error of about plus or minus 0.02 eV depending on measurement conditions.

$${T}_{1} [ eV ] = 1239 \text{.85} / {λ}_{edge} \qquad Conversion Equation ( F1 )$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 manufactured by Hitachi High-Technologies Corporation was used.

### Refractive Index

The refractive indices of the materials (compounds) contained in the layers forming the emitting units and the charge generating zones were measured as follows.

A measurement target material was vacuum-deposited on a glass substrate to form a film having an approximately 50 nm thickness. Using a spectroscopic ellipsometer (M-2000U1, produced by J. A. Woollam Co., Inc. (US)), the obtained sample film was irradiated with incident light (from ultraviolet light through visible light to near-infrared light) every 5 degrees in a measurement angle range of 45 degrees to 75 degrees to measure change in a deflection state of the light reflected by the sample surface. In order to improve the measurement accuracy of the extinction coefficient, a transmission spectrum in a substrate normal direction (direction perpendicular to a surface of the substrate of the organic EL device) was also measured by M-2000UI. Similarly, the same measurement was performed also on the glass substrate on which no measurement target material was vapor-deposited. The obtained measurement information was fitted using analysis software (Complete EASE) produced by J. A. Woollam Co., Inc.

Refractive indices in an in-plane direction and a normal direction, extinction coefficients in the in-plane direction and the normal direction, and an order parameter of an organic film formed on the substrate were calculated under fitting conditions of using an anisotropic model rotationally symmetric about one axis and setting a parameter MSE indicating a mean square error in the analysis software to be 3.0 or less. A peak close to the long-wavelength region of the extinction coefficient (in-plane direction) was defined as S1, and the order parameter was calculated by a peak wavelength of S1. As fitting conditions for the glass substrate, an isotropic model was used.

Typically, a film formed by vacuum-depositing a low molecular material on the substrate is rotationally symmetric about one axis extending along the substrate normal direction. When an angle formed by the substrate normal direction and a molecular axis in a thin film formed on the substrate is defined as θ and the extinction coefficients in a substrate parallel direction (Ordinary direction) and a substrate perpendicular direction (Extra-Ordinary direction) obtained by performing the variable-angle spectroscopic ellipsometry measurement on the thin film are respectively defined as ko and ke, S′ represented by a formula below is the order parameter.

$${S}^{′} = 1 - 〈 cos 2 θ 〉 = 2 ko / ( ke + 2 ko ) = 2 / 3 ( 1 - S )$$

$$S = ( 1 / 2 ) 〈 3 cos 2 θ - 1 〉 = ( k e - ko ) / ( ke + 2 ko )$$

An evaluation method of the molecular orientation is a publicly known method, and details thereof are described in Organic Electronics, volume 10, page 127 (2009). Further, the method for forming the thin film is a vacuum deposition method.

The order parameter S′ obtained by the variable-angle spectroscopic ellipsometry measurement is 1.0 when all molecules are oriented in parallel with the substrate. When molecules are random without being oriented, the order parameter S′ is 0.66.

Herein, a value at 2.7 eV in the substrate parallel direction (Ordinary direction), from among the values measured above, is defined as a refractive index of the measurement target material. The refractive index at 2.7 eV corresponds to a refractive index at 460 nm. Herein, the refractive index at 2.7 eV (460 nm) in the substrate parallel direction (Ordinary direction) may be referred to as n_{ORD}, and the refractive index at 2.7 eV (460 nm) in the substrate perpendicular direction (Extra-Ordinary direction) may be referred to as n_{EXT}.

When one layer contained a plurality of compounds, a refractive index of the layer, the layer being a film formed by co-depositing the plurality of compounds as the measurement target material on the glass substrate or a film formed by vapor-depositing a mixture containing the plurality of compounds, was measured using a spectroscopic ellipsometer in the same manner as above.

### Maximum Fluorescence Peak Wavelength λ_{FL}

A measurement target compound was dissolved in toluene at a concentration of 5.0×10⁻⁶ mol/L to prepare a toluene solution thereof. The obtained solution was put into a quartz cell (optical path length: 1.0 cm). The maximum fluorescence peak wavelength λ_{FL} (unit: nm) when the solution was excited at 400 nm was measured using a fluorescence spectrum measurement device “fluorospectrophotometer FP-8300” (manufactured by JASCO Corporation).

The maximum fluorescence peak wavelength λ_{FL} of the compound BD was 456 nm.

What is claimed is:

1. An organic electroluminescence device, comprising:
an anode;
a cathode; and
two or more emitting units disposed between the anode and the cathode, wherein
the two or more emitting units include at least a first emitting unit and a second emitting unit,
the first emitting unit and the second emitting unit are disposed in this order from a side close to the anode toward a side close to the cathode,
the first emitting unit includes a first emitting zone,
the second emitting unit includes a second emitting zone,
one or more low refractive index layers are disposed between the first emitting zone and the second emitting zone,
the one or more low refractive index layers each independently contain an organic material having a refractive index of 1.87 or less, and
Condition (TDM1) or (TDM2) below is satisfied:
Condition (TDM1): the one or more low refractive index layers are two or more low refractive index layers, the two or more low refractive index layers are disposed between the first emitting zone and the second emitting zone, at least two of the two or more low refractive index layers are in direct contact with each other, a total film thickness of the at least two low refractive index layers in direct contact is 50 nm or more, and at least one of the at least two low refractive index layers in direct contact contains the organic material and at least one selected from the group consisting of metal and a metal compound; and
Condition (TDM2): at least one low refractive index layer having a film thickness of 50 nm or more of the one or more low refractive index layers is disposed between the first emitting zone and the second emitting zone, and the at least one low refractive index layer having a film thickness of 50 nm or more contains the organic material and at least one selected from the group consisting of metal and a metal compound.

2. The organic electroluminescence device according to claim 1, wherein at least one of the organic material contained in the one or more low refractive index layers has a refractive index of 1.83 or less.

3. The organic electroluminescence device according to claim 1, wherein
charge generating zones are respectively disposed between the two or more emitting units, and
the charge generating zones each independently include at least one charge generating layer.

4. The organic electroluminescence device according to claim 3, wherein at least one of the charge generating zones includes two or more charge generating layers.

5. The organic electroluminescence device according to claim 3, wherein
a first charge generating zone is disposed between the first emitting unit and the second emitting unit, and
the first charge generating zone includes at least a first charge generating layer.

6. The organic electroluminescence device according to claim 5, wherein
when the organic electroluminescence device satisfies Condition (TDM1), one of the at least two low refractive index layers in direct contact in Condition (TDM1) is the first charge generating layer, and
when the organic electroluminescence device satisfies Condition (TDM2), one of the at least one low refractive index layer having a film thickness of 50 nm or more in Condition (TDM2) is the first charge generating layer.

7. The organic electroluminescence device according to claim 6, wherein the first charge generating layer contains the organic material and at least one selected from the group consisting of metal and a metal compound.

8. The organic electroluminescence device according to claim 7, wherein the organic material contained in the first charge generating layer has a refractive index of 1.83 or less.

9. The organic electroluminescence device according to claim 5, wherein
a first electron transporting zone is disposed between the first emitting zone and the first charge generating layer, and
the first electron transporting zone includes one layer or two or more layers.

10. The organic electroluminescence device according to claim 9, wherein the one layer or two or more layers included in the first electron transporting zone are each the low refractive index layer.

11. The organic electroluminescence device according to claim 9, wherein
the first electron transporting zone includes a first electron transporting layer, and
the first charge generating layer is in direct contact with the first electron transporting layer.

12. The organic electroluminescence device according to claim 11, wherein the first electron transporting layer is the low refractive index layer.

13. The organic electroluminescence device according to claim 11, wherein
the first emitting zone includes a first emitting layer,
the first emitting layer contains a first host material,
the first electron transporting layer contains a first electron transporting zone material, and
a triplet energy of the first host material T₁(H1) and a triplet energy of the first electron transporting zone material T₁(E1) satisfy a relationship of a numerical formula (Numerical Formula 1) below,
$${T}_{1} ( E 1 ) > {T}_{1} ( H 1 ) . \qquad ( Numerical Formula 1 )$$

14. The organic electroluminescence device according to claim 13, wherein the first emitting layer is in direct contact with the first electron transporting layer.

15. The organic electroluminescence device according to claim 11, wherein the first electron transporting zone further includes a first hole blocking layer between the first electron transporting layer and the first emitting zone.

16. The organic electroluminescence device according to claim 15, wherein the first hole blocking layer is the low refractive index layer.

17. The organic electroluminescence device according to claim 15, wherein the first hole blocking layer contains a first electron transporting zone material.

18. The organic electroluminescence device according to claim 13, wherein the first electron transporting zone material has a refractive index of 1.83 or less.

19. The organic electroluminescence device according to claim 13, wherein the first electron transporting zone material is a compound represented by a formula (E1) below, 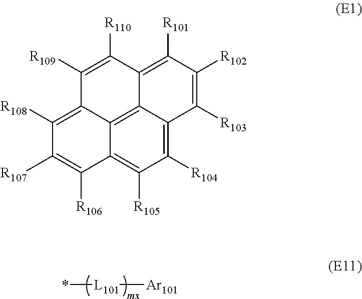
where, in the formula (E1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (E11) above;
at least one of R₁₀₁ to R₁₁₀ is a group represented by the formula (E11);
when a plurality of groups represented by the formula (E11) are present, the plurality of groups represented by the formula (E11) are mutually the same or different;
L₁₀₁ is a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4 or 5, and when mx is 0, -(L₁₀₁)₀- is a single bond;
when two or more L₁₀₁ are present, the two or more L₁₀₁ are mutually the same or different;
when two or more Ar₁₀₁ are present, the two or more Ar₁₀₁ are mutually the same or different; and
* in the formula (E11) represents a bonding position to the pyrene ring in the formula (E1); and
in the formula (E1):
R₉₀₁, R₉₀₂, R₉₀₃, R₉₀₄, R₉₀₅, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different:
when a plurality of R₈₀₁ are present, the plurality of R₈₀₁ are mutually the same or different; and
when a plurality of R₈₀₂ are present, the plurality of R₈₀₂ are mutually the same or different.

20. The organic electroluminescence device according to claim 13, wherein the first electron transporting zone material is a compound represented by a formula (E2) below, 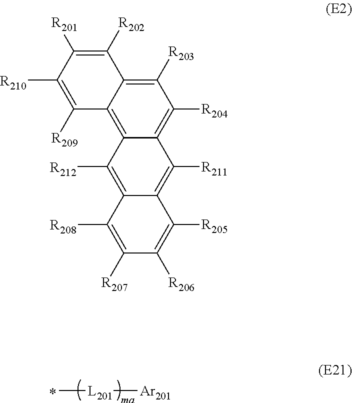
where, in the formula (E2):
at least one combination of adjacent two or more of R₂₀₁ to R₂₁₂ are mutually bonded to form a substituted or unsubstituted monocyclic ring, mutually bonded to form a substituted or unsubstituted fused ring, or not mutually bonded;
R₂₀₁ to R₂₁₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (E21) above;
at least one of R₂₀₁ to R₂₁₂ forming neither the substituted or unsubstituted monocyclic ring nor the substituted or unsubstituted fused ring is a group represent by the formula (E21);
when a plurality of groups represented by the formula (E21) are present, the plurality of groups represented by the formula (E21) are mutually the same or different;
L₂₀₁ is a substituted or unsubstituted arylene group having 6 to 50 ring carbon atoms, or a substituted or unsubstituted divalent heterocyclic group having 5 to 50 ring atoms;
ma is 0, 1, 2, 3, 4 or 5, and when ma is 0, -(L₂₀₁)₀- is a single bond;
when two or more L₂₀₁ are present, the two or more L₂₀₁ are mutually the same or different;
Ar₂₀₁ is a substituted or unsubstituted aryl group having 6 to 50 ring carbon atoms, or a substituted or unsubstituted heterocyclic group having 5 to 50 ring atoms;
when two or more Ar₂₀₁ are present, the two or more Ar₂₀₁ are mutually the same or different;
* in the formula (E21) represents a bonding position to a benz[a]anthracene ring in the formula (E2); and
when at least one combination of adjacent two or more of R₂₀₁ to R₂₁₂ form the substituted or unsubstituted monocyclic ring or the substituted or unsubstituted fused ring, * in the formula (E21) represents a bonding position to a basic skeleton of the formed cyclic structure; and
in the formula (E2):
R₉₀₁, R₉₀₂, R₉₀₃, R₉₀₄, R₉₀₅, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

21. The organic electroluminescence device according to claim 13, wherein the first electron transporting zone material is a compound represented by a formula (E3) below, 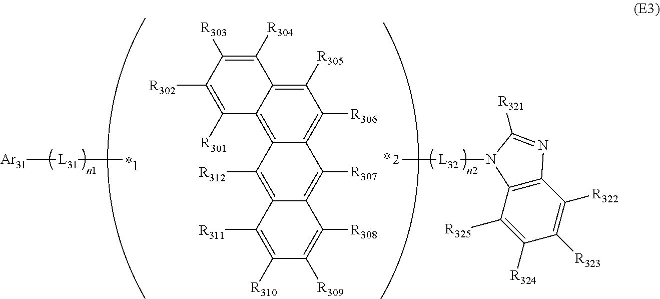
where, in the formula (E3):
one of R₃₀₇ and R₃₁₂ represents a single bond to *1 and the other of R₃₀₇ and R₃₁₂ represents a single bond to *2;
R₃₀₁ to R₃₀₆, R₃₀₈ to R₃₁₁, and R₃₂₂ to R₃₂₅ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₃₂₁ is a substituted or unsubstituted alkyl group having 1 to 6 carbon atoms, or a substituted or unsubstituted cycloalkyl group having 3 to 10 ring carbon atoms:
Ar₃₁ is a hydrogen atom, a substituted or unsubstituted aryl group having 6 to 18 ring carbon atoms, a substituted or unsubstituted oxygen-containing heterocyclic group having 5 to 18 ring atoms, or a substituted or unsubstituted sulfur-containing heterocyclic group having 5 to 18 ring atoms;
L₃₁ and L₃₂ are each independently a substituted or unsubstituted arylene group having 6 to 14 ring carbon atoms, or a substituted or unsubstituted divalent heterocyclic group having 5 to 14 ring atoms;
n1 is 0, 1, 2 or 3, and n2 is 0, 1, 2 or 3;
when n1 is 0, -(L₃₁)₀- is a single bond;
when n1 is 2 or more, two or more L₃₁ are mutually linked in series;
when n1 is 2 or more, the two or more L₃₁ are mutually the same or different;
when n2 is 0, -(L₃₂)₀- is a single bond;
when n2 is 2 or more, two or more L₃₂ are mutually linked in series; and
when n2 is 2 or more, the two or more L₃₂ are mutually the same or different; and
in the formula (E3):
R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

22. The organic electroluminescence device according to claim 13, wherein the first electron transporting zone material is a compound represented by a formula (E4) below, 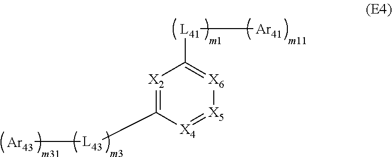
where, in the formula (E4):
X₂ is N or C-(L₄₂)m₂-(Ar₄₂)m₂₁, X₄ is N or C-(L₄₄)m₄-(Ar₄₄)m₄₁, X₅ is N or C-(L₄₅)m₅-(Ar₄₅)m₅₁, X₆ is N or C-(L₄₆)m₆-(Ar₄₆)m₆₁, at least one of X₂, X₄, X₅ or X₆ is a nitrogen atom;
L₄₁ to L₄₆ are each independently a substituted or unsubstituted arylene group having 6 to 50 ring carbon atoms, or a substituted or unsubstituted divalent heterocyclic group having 5 to 50 ring atoms;
m₁ is 0, 1, 2 or 3, and when m₁ is 0, -(L₄₁)₀- is a single bond;
m₂ is 0, 1, 2 or 3, and when m₂ is 0, -(L₄₂)₀- is a single bond;
m₃ is 0, 1, 2 or 3, and when m₃ is 0, -(L₄₃)₀- is a single bond;
m₄ is 0, 1, 2 or 3, and when m₄ is 0, -(L₄₄)₀- is a single bond;
m₅ is 0, 1, 2 or 3, and when m₅ is 0, -(L₄₅)₀- is a single bond;
m₆ is 0, 1, 2 or 3, and when m₆ is 0, -(L₄₆)₀- is a single bond;
m₁₁ is 1, 2, 3 or 4, m₂₁ is 1, 2, 3 or 4, m₃₁ is 1, 2, 3 or 4, m₄₁ is 1, 2, 3 or 4, m₅₁ is 1, 2, 3 or 4, and m₆₁ is 1, 2, 3 or 4;
Ar₄₁ to Ar₄₆ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms; and
at least one of Ar₄₁ to Ar₄₆ is a substituted or unsubstituted aryl group having 13 to 50 ring carbon atoms, or a substituted or unsubstituted heterocyclic group having 13 to 50 ring atoms; and
in the formula (E4):
R₉₁₁, R₉₁₂, R₉₁₃, R₉₁₄, R₉₁₅, R₉₁₆, R₉₁₇, R₉₁₈, R₉₁₉, R₉₂₀, and R₉₂₁ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₁₁ are present, the plurality of R₉₁₁ are mutually the same or different;
when a plurality of R₉₁₂ are present, the plurality of R₉₁₂ are mutually the same or different:
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different:
when a plurality of R₉₁₇ are present, the plurality of R₉₁₇ are mutually the same or different;
when a plurality of R₉₁₈ are present, the plurality of R₉₁₈ are mutually the same or different;
when a plurality of R₉₁₉ are present, the plurality of R₉₁₉ are mutually the same or different;
when a plurality of R₉₂₀ are present, the plurality of R₉₂₀ are mutually the same or different; and
when a plurality of R₉₂₁ are present, the plurality of R₉₂₁ are mutually the same or different.

23. The organic electroluminescence device according to claim 22, wherein the first electron transporting zone material is a compound represented by a formula (E41) below, 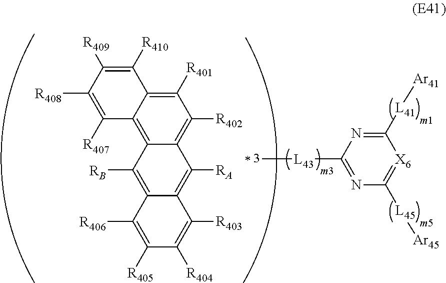
where, in the formula (E41):
L₄₁, L₄₃, and L₄₅ respectively represent the same as L₄₁, L₄₃, and L₄₅ in the formula (E4), and m₁, m₃, and m₅ respectively represent the same as m₁, m₃, and m₅ in the formula (E4);
one of R_{A} and R_{B} represents a single bond with *3, the other of R_{A} and R_{B} not being the single bond with *3 is a hydrogen atom or a substituent S, and “a substituent group” of “a substituted or unsubstituted group” in the substituent S as R_{A} or R_{B} has at least one substituent T;
R₄₀₁ to R₄₀₉ are each independently a hydrogen atom or a substituent R;
the substituent R is selected from the group consisting of a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms;
when two or more substituents R are present, the two or more substituents R are mutually the same or different:
R₄₁₀ is a hydrogen atom;
any combinations of adjacent two or more of R₄₀₁ to R₄₀₉, and one of R_{A} and R_{B} not being a single bond with *3 are not mutually bonded;
X₆ is a nitrogen atom or C—Ar₄₆, and Ar₄₆ is a hydrogen atom or a substituent V;
at least one of Ar₄₁ or Ar₄₅ is a substituent X, and “a substituent group” of “a substituted or unsubstituted group” in the substituent X as Ar₄₁ and Ar₄₅ has at least one substituent U;
Ar₄₁ and Ar₄₅ not being the substituent X is a substituted or unsubstituted aryl group having 6 to 50 ring carbon atoms, or a substituted or unsubstituted heterocyclic group having 5 to 50 ring atoms and including no nitrogen atom;
the substituent X is a group selected from the group consisting of a substituted or unsubstituted biphenylyl group, a substituted or unsubstituted terphenylyl group, a substituted or unsubstituted naphthyl group, a substituted or unsubstituted benzanthryl group, a substituted or unsubstituted phenanthryl group, a substituted or unsubstituted benzophenanthryl group, a substituted or unsubstituted phenalenyl group, a substituted or unsubstituted pyrenyl group, a substituted or unsubstituted chrysenyl group, a substituted or unsubstituted benzochrysenyl group, a substituted or unsubstituted triphenylenyl group, a substituted or unsubstituted benzotriphenylenyl group, a substituted or unsubstituted tetracenyl group, a substituted or unsubstituted pentacenyl group, a substituted or unsubstituted fluorenyl group, a substituted or unsubstituted 9,9′-spirobifluorenyl group, a substituted or unsubstituted benzofluorenyl group, a substituted or unsubstituted dibenzofluorenyl group, a substituted or unsubstituted fluoranthenyl group, a substituted or unsubstituted benzofluoranthenyl group, a substituted or unsubstituted perylenyl group, a heterocyclic group represented by a formula (E411) below, and a heterocyclic group represented by a formula (E412) below;
when two or more substituents X are present, the two or more substituents X are mutually the same or different;
when two or more substituents U are present, the two or more substituents U are mutually the same or different;
the substituent S as R_{A} or R_{B}, the substituent T for “a substituted or unsubstituted group” in R_{A} or R_{B}, the substituent U for “a substituted or unsubstituted group” in Ar₄₁ and Ar₄₅, and the substituent V as Ar₄₆ are each independently selected from the group consisting of a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms; and
when two or more substituents T are present, the two or more substituents T are mutually the same or different; 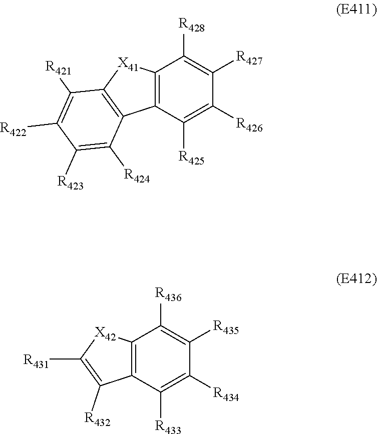
in the formula (E411):
X₄₁ is N(R₄₂₉), an oxygen atom or a sulfur atom;
one of R₄₂₁ to R₄₂₉ represents a single bond with L₄₁ or L₄₅;
at least one combination of adjacent two or more of R₄₂₁ to R₄₂₉ are mutually bonded to form a substituted or unsubstituted monocyclic ring, mutually bonded to form a substituted or unsubstituted fused ring, or not mutually bonded; and
R₄₂₁ to R₄₂₉ not representing a single bond with L₄₁ or L₄₅, not forming the substituted or unsubstituted monocyclic ring, and not forming the substituted or unsubstituted fused ring are each independently selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms and including no nitrogen atom;
in the formula (E412):
X₄₂ is N(R₄₃₇), an oxygen atom or a sulfur atom;
one of R₄₃₁ to R₄₃₇ represents a single bond with L₄₁ or L₄₅;
at least one combination of adjacent two or more of R₄₃₁ to R₄₃₇ are mutually bonded to form a substituted or unsubstituted monocyclic ring, mutually bonded to form a substituted or unsubstituted fused ring, or not mutually bonded; and
R₄₃₁ to R₄₃₇ not representing a single bond with L₄₁ or L₄₅, not forming the substituted or unsubstituted monocyclic ring, and not forming the substituted or unsubstituted fused ring are each independently selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms and including no nitrogen atom; and
in the formulae (E41), (E411) and (E412):
R₉₁₁ to R₉₁₉ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms and including no nitrogen atom;
when a plurality of R₉₁₁ are present, the plurality of R₉₁₁ are mutually the same or different;
when a plurality of R₉₁₂ are present, the plurality of R₉₁₂ are mutually the same or different;
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁ are mutually the same or different; and
when a plurality of R₉₁₉ are present, the plurality of R₉₁₉ are mutually the same or different.

24. The organic electroluminescence device according to claim 22, wherein the first electron transporting zone material is a compound represented by a formula (E42) below, 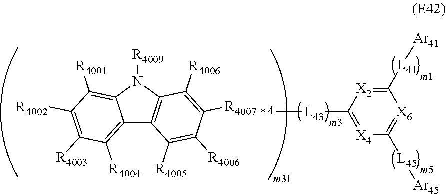
where, in the formula (E42):
X₂, X₄, X₆, L₄₁, L₄₃, L₄₅, Ar₄₁ and Ar₄₅ respectively represent the same as X₂, X₄, X₆, L₄₁, L₄₃, L₄₅, Ar₄₁ and Ar₄₅ in the formula (E4), and m₁, m₃, m₃₁ and m₅ respectively represent the same as m₁, m₃, m₃₁ and m₅ in the formula (E4);
at least one combination of adjacent two or more of R₄₀₀₁ to R₄₀₀₈ are mutually bonded to form a substituted or unsubstituted monocyclic ring, mutually bonded to form a substituted or unsubstituted fused ring, or not mutually bonded;
R₄₀₀₉, and R₄₀₀₁ to R₄₀₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₄₀₀₉, or R₄₀₀₁ to R₄₀₀₈ forming neither the substituted or unsubstituted monocyclic ring nor the substituted or unsubstituted fused ring is a single bond with *4;
*4 represents a bonding position to a carbazole ring in the formula (E42);
when at least one combination of adjacent two or more of R₄₀₀₁ to R₄₀₀₃ form the substituted or unsubstituted monocyclic ring or the substituted or unsubstituted fused ring, *4 in the formula (E42) represents a bonding position to a basic skeleton of the formed cyclic structure; and
in the formula (E42), R₉₁₁, R₉₁₂, R₉₁₃, R₉₁₄, R₉₁₅, R₉₂₀, and R₉₂₁ respectively represent the same as R₉₁₁, R₉₁₂, R₉₁₃, R₉₁₄, R₉₁₅, R₉₂₀, and R₉₂₁ in the formula (E4).

25. The organic electroluminescence device according to claim 22, wherein the first electron transporting zone material is a compound represented by a formula (E43) below, 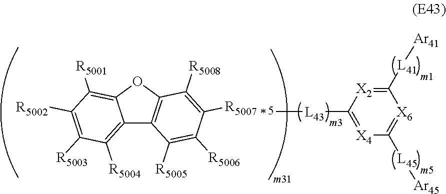
where, in the formula (E43):
X₂, X₄, X₅, L₄₁, L₄₃, L₄₅, Ar₄₁ and Ar₄₅ respectively represent the same as X₂, X₄, X₆, L₄₁, L₄₃, L₄₅, Ar₄₁ and Ar₄₅ in the formula (E4), and m₁, m₃, m₃₁ and m₅ respectively represent the same as m₁, m₃, m₃₁ and m₅ in the formula (E4);
at least one combination of adjacent two or more of R₅₀₀₁ to R₅₀₀₈ are mutually bonded to form a substituted or unsubstituted monocyclic ring, mutually bonded to form a substituted or unsubstituted fused ring, or not mutually bonded;
R₅₀₀₁ to R₅₀₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₅₀₀₁ to R₅₀₀₈ forming neither the substituted or unsubstituted monocyclic ring nor the substituted or unsubstituted fused ring is a single bond with *5;
*5 represents a bonding position to a dibenzofuran ring in the formula (E43);
when at least one combination of adjacent two or more of R₅₀₀₁ to R₅₀₀₈ form the substituted or unsubstituted monocyclic ring or the substituted or unsubstituted fused ring, *5 in the formula (E43) represents a bonding position to a basic skeleton of the formed cyclic structure; and
in the formula (E43), R₉₁₁, R₉₁₂, R₉₁₃, R₉₁₄, R₉₁₅, R₉₂₀, and R₉₂₁ respectively represent the same as R₉₁₁, R₉₁₂, R₉₁₃, R₉₁₄, R₉₁₅, R₉₂₀, and R₉₂₁ in the formula (E4).

26. The organic electroluminescence device according to claim 22, wherein the first electron transporting zone material is a compound represented by a formula (E44) below, 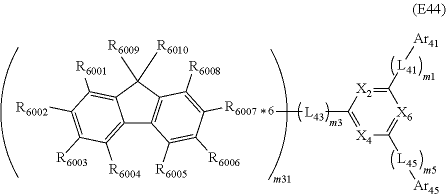
where, in the formula (E44):
X₂, X₄, X₆, L₄₁, L₄₃, L₄₅, Ar₄₁ and Ar₄₅ respectively represent the same as X₂, X₄, X₆, L₄₁, L₄₃, L₄₅, Ar₄₁ and Ar₄₅ in the formula (E4), and m₁, m₃, m₃₁ and m₅ respectively represent the same as m₁, m₃, m₃₁ and m₅ in the formula (E4);
a combination of R₆₀₀₉ and R₆₀₁₀ are mutually bonded to form a substituted or unsubstituted monocyclic ring, mutually bonded to form a substituted or unsubstituted fused ring, or not mutually bonded;
at least one combination of adjacent two or more of R₆₀₀₁ to R₆₀₀₈ are mutually bonded to form a substituted or unsubstituted monocyclic ring, mutually bonded to form a substituted or unsubstituted fused ring, or not mutually bonded;
R₆₀₀₁ to R₆₀₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₆₀₀₁ to R₆₀₁₀ forming neither the substituted or unsubstituted monocyclic ring nor the substituted or unsubstituted fused ring is a single bond with *6;
*6 represents a bonding position to a fluorene ring in the formula (E44);
when at least one combination of adjacent two or more of R₆₀₀₁ to R₆₀₁₀ form the substituted or unsubstituted monocyclic ring or the substituted or unsubstituted fused ring, *6 in the formula (E44) represents a bonding position to a basic skeleton of the formed cyclic structure; and
in the formula (E44), R₉₁₁, R₉₁₂, R₉₁₃, R₉₁₄, R₉₁₅, R₉₂₀, and R₉₂₁ respectively represent the same as R₉₁₁, R₉₁₂, R₉₁₃, R₉₁₄, R₉₁₅, R₉₂₀, and R₉₂₁ in the formula (E4).

27. The organic electroluminescence device according to claim 13, wherein the first electron transporting zone material is a compound represented by a formula (E5) below, 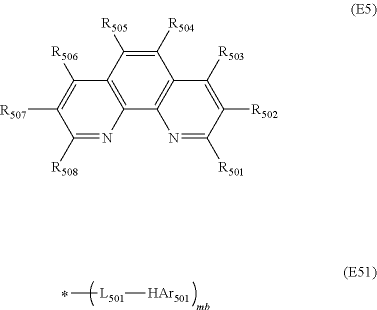
where, in the formula (E5):
at least one combination of adjacent two or more of R₅₀ to R₅₀₈ are mutually bonded to form a substituted or unsubstituted monocyclic ring, mutually bonded to form a substituted or unsubstituted fused ring, or not mutually bonded;
R₅₀₁ to R₅₀₈ forming neither the substituted or unsubstituted monocyclic ring nor the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₉₀₅), a substituted or unsubstituted alkoxycarbonyl group having 1 to 50 carbon atoms, a halogen atom, a cyano group, a nitro group, a carboxy group a group represented by —N(R_{906N})(R_{907N}), or a group represented by a formula (E51) above:
when a plurality of groups represented by the formula (E51) are present, the plurality of groups represented by the formula (E51) are mutually the same or different;
L₅₀₁ is a single bond, a substituted or unsubstituted arylene group having 6 to 50 ring carbon atoms, or a substituted or unsubstituted divalent heterocyclic group having 5 to 50 ring atoms;
HAr₅₀₁ is a substituted or unsubstituted aryl group having 6 to 50 ring carbon atoms, or a substituted or unsubstituted heterocyclic group having 5 to 50 ring atoms;
mb is 1, 2, 3 or 4;
when mb is 2, 3 or 4;
two or more L₅₀₁ are mutually the same or different;
two or more HAr₅₀₁ are mutually the same or different;
* in the formula (E51) represents a bonding position to a phenanthroline ring in the formula (E5); and
when at least one combination of adjacent two or more of R₅₀₁ to R₅₀₈ form the substituted or unsubstituted monocyclic ring or the substituted or unsubstituted fused ring, * in the formula (E51) represents a bonding position to a basic skeleton of the formed cyclic structure; and
in the formula (E5):
R₉₀₄ and R₉₀₅ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₄ are present, the plurality of R₉₀₄ are mutually the same or different;
when a plurality of R₉₀₅ are present, the plurality of R₉₀₅ are mutually the same or different:
R_{905N} and R_{906N} are each independently a substituted or unsubstituted aryl group having 6 to 50 ring carbon atoms;
when a plurality of R_{905N} are present, the plurality of R_{905N} are mutually the same or different; and
when a plurality of R_{906N} are present, the plurality of R_{906N} are mutually the same or different.

28. The organic electroluminescence device according to claim 27, wherein at least one of R₅₀₁ to Ros is a group represented by the formula (E51);
the group represented by the formula (E51) is a group represented by one of formulae (E511) to (E515) below, 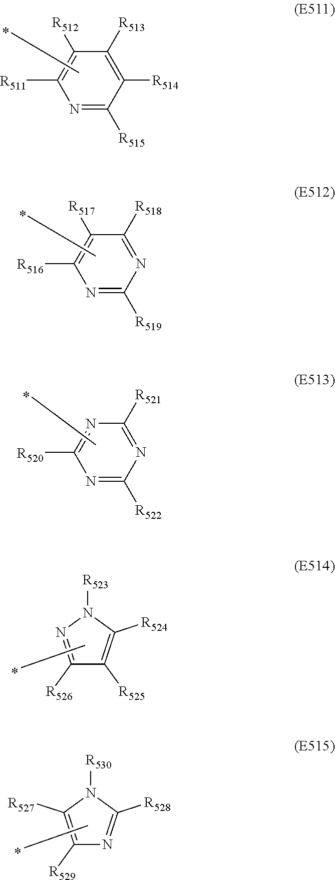
where, in the formula (E511), one of R₅₁₁, R₅₁₂, R₅₁₃, R₅₁₄ and R₅₁₅ represents a single bond with L₅₀₁;
in the formula (E512), one of R₅₁₆, R₅₁₇, R₅₁₈, and R₅₁₉ represents a single bond with L₅₀₁;
in the formula (E513), one of R₅₂₀, R₅₂₁, and R₅₂₂ represents a single bond with L₅₀₁;
in the formula (E514), one of R₅₂₃, R₅₂₄, R₅₂₅, and R₅₂₆ represents a single bond with L₅₀₁;
in the formula (E515), one of R₅₂₇, R₅₂₈, R₅₂₉, and R₅₃₀ represents a single bond with L₅₀₁;
at least one combination of adjacent two or more of R₅₁₁ to R₅₃₀ are mutually bonded to form a substituted or unsubstituted monocyclic ring, mutually bonded to form a substituted or unsubstituted fused ring, or not mutually bonded;
R₅₁₁ to R₅₃₀ not representing a single bond with L₅₀₁, not forming the substituted or unsubstituted monocyclic ring, and not forming the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₀₀₄), a group represented by —S—(R₅₀₅), a substituted or unsubstituted alkoxycarbonyl group having 1 to 50 carbon atoms, a halogen atom, a cyano group, a nitro group, a carboxy group, or a group represented by —N(R_{905N})(R_{906N}); and
R₉₀₄, R₉₀₅, R_{905N}, and R_{906N} respectively represent the same as R₉₀₄, R₉₀₅, R_{905N}, and R_{906N} in the formula (E5), and * represents a bonding position.

29. The organic electroluminescence device according to claim 27, wherein at least one of R₅₀₁ to R₅₀₈ is a group represented by the formula (E51); and
the group represented by the formula (E51) is a group represented by one of formulae (E516) to (E526) below, 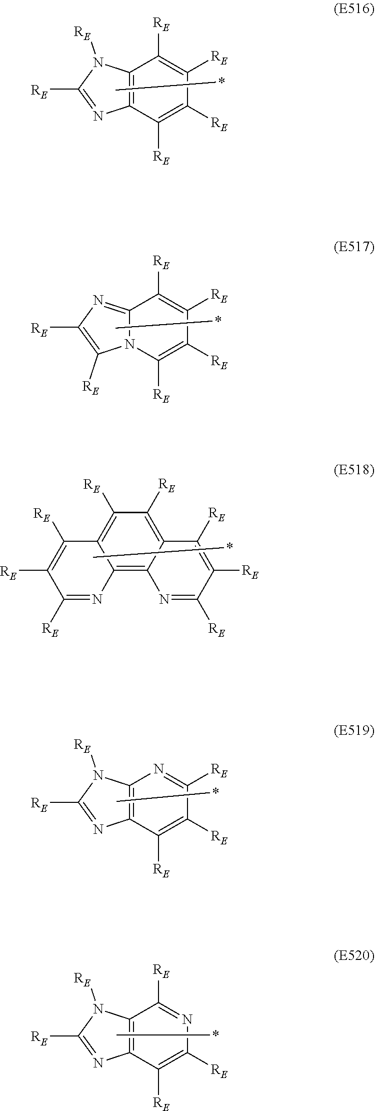 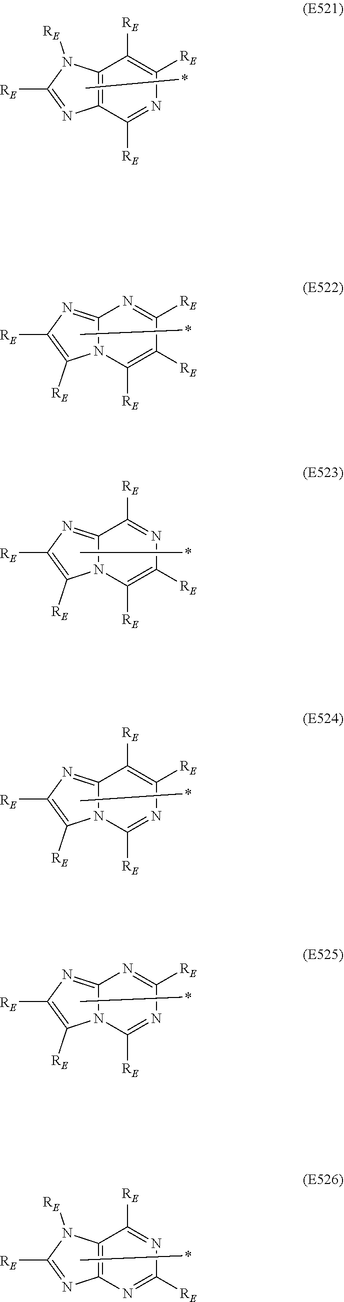
where, in the formulae (E516) to (E526):
one of R_{E} represents a single bond with L₅₀₁;
at least one combination of adjacent two or more of a plurality of R_{E} are mutually bonded to form a substituted or unsubstituted monocyclic ring, mutually bonded to form a substituted or unsubstituted fused ring, or not mutually bonded;
each R_{E} not representing a single bond with L₅₀₁, not forming the substituted or unsubstituted monocyclic ring, and not forming the substituted or unsubstituted fused ring is independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₉₀₅), a substituted or unsubstituted alkoxycarbonyl group having 1 to 50 carbon atoms, a halogen atom, a cyano group, a nitro group, a carboxy group, or a group represented by —N(R_{905N})(R_{906N});
R₉₀₄, R₉₀₅, R_{905N}, and R_{906N} respectively represent the same as R₉₀₄, R₉₀₅, R_{905N}, and R_{906N} in the formula (E5); and
a plurality of R_{E} are mutually the same or different, and * represents a bonding position.

30. The organic electroluminescence device according to claim 13, wherein the first electron transporting zone material is a compound represented by a formula (E61) or (E62) below, 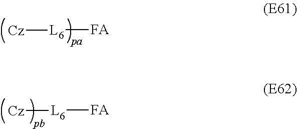
where, in the formulae (E61) and (E62):
each Cz is independently carbazolyl groups or indolyl groups represented by one formula selected from the group consisting of formulae (E63), (E64), (E65), (E66), (E67) and (E68) below;
each L₆ is independently a single bond, a substituted or unsubstituted arylene group having 6 to 50 ring carbon atoms, or a substituted or unsubstituted divalent heterocyclic group having 5 to 50 ring atoms;
pa is 0, 1, 2, 3, 4, 5, 6, 7, 8, 9 or 10, and pb is 0, 1, 2, 3, 4, 5, 6, 7, 8, 9 or 10;
when a plurality of L₆ are present, the plurality of L₆ are mutually the same or different:
when a plurality of Cz are present, the plurality of Cz are mutually the same or different; and
each FA is independently a substituted or unsubstituted fused ring group having 6 to 50 ring carbon atoms, where FA is not an unsubstituted carbazolyl group; and 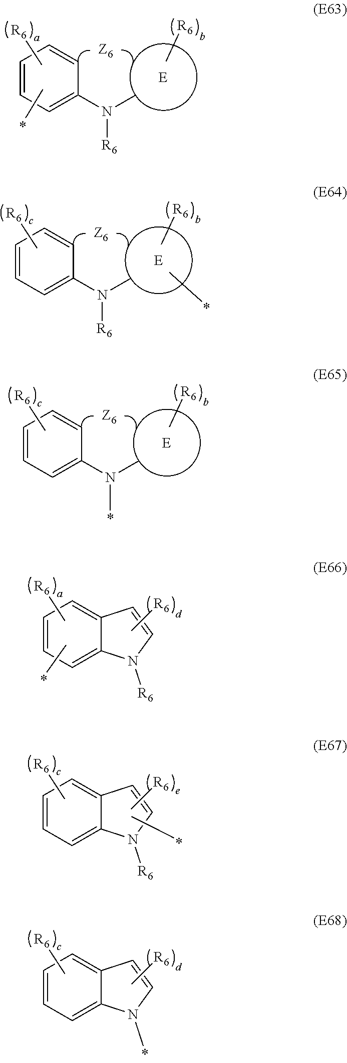
in the formulae (E63), (E64), (E65), (E66), (E67) and (E68):
each Z₆ is independently a single bond, —C(R₆₀₁)(R₆₀₂)—, —Si(R₆₀₃)(R₆₀₄)—, —O—, —CO—, or —N(R₆₀₅)—;
R₆₀₁, R₆₀₂, R₆₀₃, R₆₀₄ and R₆₀₅ are each independently a hydrogen atom, a substituted or unsubstituted aryl group having 6 to 50 ring carbon atoms, a substituted or unsubstituted heterocyclic group having 5 to 50 ring atoms, or a substituted or unsubstituted alkyl group having 1 to 50 carbon atoms;
a ring E is each independently a substituted or unsubstituted aliphatic hydrocarbon ring having 3 to 20 ring carbon atoms, a substituted or unsubstituted nitrogen-atom-containing nonaromatic heterocycle having 3 to 20 ring atoms, a substituted or unsubstituted aromatic hydrocarbon ring having 4 to 50 ring carbon atoms, or a substituted or unsubstituted aromatic heterocycle having 4 to 50 ring atoms;
a is 3, each b is independently Q, 1, 2, 3 or 4, c is 4, d is 2, and e is 1;
at least one combination of adjacent two or more of a plurality of R₆ are mutually bonded to form a substituted or unsubstituted monocyclic ring, mutually bonded to form a substituted or unsubstituted fused ring, or not mutually bonded;
each R₆ forming neither the substituted or unsubstituted monocyclic ring nor the substituted or unsubstituted fused ring is independently a hydrogen atom, a substituted or unsubstituted aryl group having 6 to 50 ring carbon atoms, a substituted or unsubstituted heterocyclic group having 5 to 50 ring atoms, a substituted or unsubstituted alkyl group having 1 to 50 carbon atoms, a group represented by —O—(R₉₀₄), a group represented by —S—(R₅₀₅), a substituted or unsubstituted aralkyl group having 7 to 50 carbon atoms, a carboxy group, a halogen atom, a cyano group, or a nitro group;
a plurality of R₆₀₁ are mutually the same or different;
a plurality of R₆₀₂ are mutually the same or different;
a plurality of R₆₀₃ are mutually the same or different;
a plurality of R₆₀₄ are mutually the same or different;
a plurality of R₆₀₅ are mutually the same or different;
a plurality of R₆ are mutually the same or different;
* represents a bonding position;
in the compound represented by the formula (E61) or (E62), R₉₀₄ and R₉₀₅ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₄ are present, the plurality of R₉₀₄ are mutually the same or different; and
when a plurality of R₉₀₅ are present, the plurality of R₉₀₅ are mutually the same or different.

31. The organic electroluminescence device according to claim 30, wherein a group represented by the formula (E63) is a group represented by one formula selected from the group consisting of formulae (E631), (E632), (E633) and (E634) below, 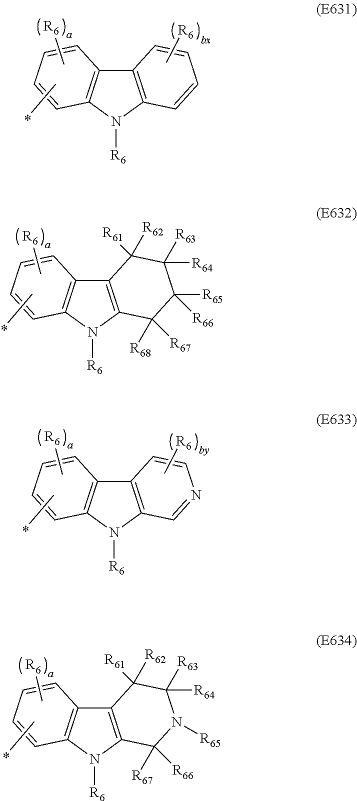
where, R₆ and a in the formulae (E631), (E632), (E633) and (E634) respectively represent the same as R₆ and a in the formula (E63), bx is 4, by is 3, R₆₁ to R₆₈ each independently represent the same as R₆ in the formula (E63), a plurality of R₆ are mutually the same or different, and * represents a bonding position.

32. The organic electroluminescence device according to claim 30, wherein a group represented by the formula (E65) is a group represented by one formula selected from the group consisting of formulae (E651), (E652), (E653) and (E654) below, 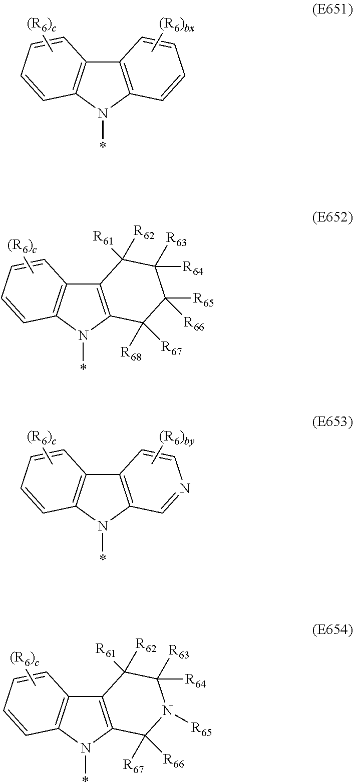
where, in the formulae (E651), (E652), (E653), and (E654), R₆ and c respectively represent the same as R₆ and c in the formula (E65), bx is 4, by is 3, R₆₁ to R₆₈ each independently represent the same as R₆ in the formula (E65), a plurality of R₆ are mutually the same or different, and * represents a bonding position.

33. The organic electroluminescence device according to claim 13, wherein the first electron transporting zone material is a compound represented by a formula (E7) below, 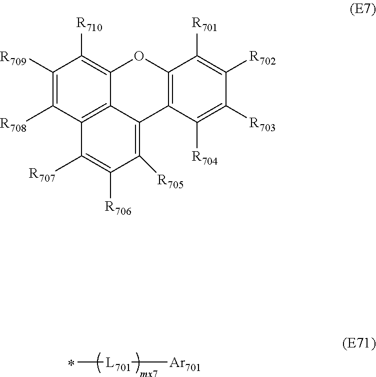
where, in the formula (E7):
R₇₀₁ to R₇₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by a formula (E71) above;
at least one of R₇₀₁ to R₇₁₀ is a group represented by the formula (E71);
when a plurality of groups represented by the formula (E71) are present, the plurality of groups represented by the formula (E71) are mutually the same or different;
L₇₀₁ is a single bond, a substituted or unsubstituted arylene group having 6 to 50 ring carbon atoms, or a substituted or unsubstituted divalent heterocyclic group having 5 to 50 ring atoms;
Ar₇₀₁ is a substituted or unsubstituted aryl group having 6 to 50 ring carbon atoms, or a substituted or unsubstituted heterocyclic group having 5 to 50 ring atoms;
mx7 is 0, 1, 2, 3, 4 or 5, and when mx7 is 0, -(L₇₀₁)₀- is a single bond;
when two or more L₇₀₁ are present, the two or more L₇₀₁ are mutually the same or different;
when two or more Ar₇₀₁ are present, the two or more Ar₇₀₁ are mutually the same or different;
* in the formula (E71) represents a bonding position to a ring represented by the formula (E7);
in the compound represented by the formula (E7), R₉₀₁, R₉₀₂, R₉₀₃, R₉₀₄, R₉₀₅, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

34. The organic electroluminescence device according to claim 18, wherein
the first charge generating layer contains the organic material and at least one selected from the group consisting of metal and a metal compound, and
the organic material contained in the first charge generating layer has a refractive index of 1.83 or less.

35. The organic electroluminescence device according to claim 5, wherein
the first charge generating zone further includes a second charge generating layer, and
the second charge generating layer is disposed between the first charge generating layer and the second emitting zone.

36. The organic electroluminescence device according to claim 35, wherein when the organic electroluminescence device satisfies Condition (TDM1), the at least two low refractive index layers in direct contact in Condition (TDM1) include the first charge generating layer and the second charge generating layer.

37. The organic electroluminescence device according to claim 35, wherein the first charge generating layer is in direct contact with the second charge generating layer.

38. The organic electroluminescence device according to claim 35, wherein a second hole transporting layer is disposed between the second charge generating layer and the second emitting zone.

39. The organic electroluminescence device according to claim 38, wherein the second hole transporting layer is the low refractive index layer.

40. The organic electroluminescence device according to claim 38, wherein a total film thickness of the first charge generating layer, the second charge generating layer, and the second hole transporting layer is 50 nm or more.

41. The organic electroluminescence device according to claim 38, wherein the second hole transporting layer contains a second hole transporting zone material.

42. The organic electroluminescence device according to claim 41, wherein the second hole transporting zone material has a refractive index of 1.83 or less.

43. The organic electroluminescence device according to claim 41, wherein the second hole transporting zone material is a compound represented by a formula (B100) below, 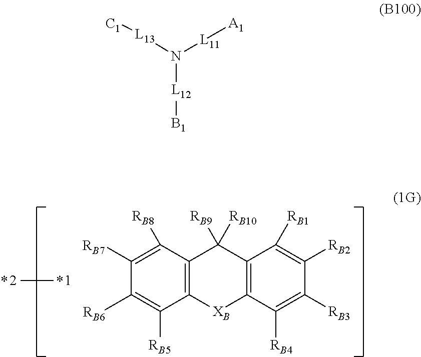
where, in the formula (B₁₀₀):
L₁₁, L₁₂, and L₁₃ are each independently a single bond, a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
A₁, B₁, and C₁ are each independently a substituted or unsubstituted aryl group having 6 to 50 ring carbon atoms, a substituted or unsubstituted heterocyclic group having 5 to 50 ring atoms, a group represented by —Si(R_{C1})(R_{C2})(R_{C3}), or a group represented by a formula (1G) above;
at least one selected from the group consisting of A₁, B₁, and C₁ is a group represented by the formula (1 G);
R_{C1}, R_{C2}, and R_{C3} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different; and
in the formula (1G):
X_{B} is a single bond, an oxygen atom, a sulfur atom, N(R_{B11}) or C(R_{B12})(R_{B13});
when a plurality of X_{B} are present, the plurality of X_{B} are mutually the same or different;
when X_{B} is C(R_{B12})(R_{B13}), a combination of R_{B12} and R_{B13} are mutually bonded to form a substituted or unsubstituted monocyclic ring, mutually bonded to form a substituted or unsubstituted fused ring, or not mutually bonded:
one of R_{B1}, R_{B2}, R_{B3}, R_{B4}, R_{B5}, R_{B6}, R_{B7}, R_{B8}, R_{B9}, R_{B10}, R_{B11}, R_{B12} and R_{B13} is a single bond bonded to *1;
R_{B1}, R_{B2}, R_{B3}, R_{B4}, R_{B5}, R_{B6}, R_{B7}, R_{B8}, and R_{B11} not being the single bond bonded to *1 are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a combination of R_{B9} and R_{B10} are mutually bonded to form a substituted or unsubstituted monocyclic ring, mutually bonded to form a substituted or unsubstituted fused ring, or not mutually bonded;
R_{B9}, R_{B10}, R_{B12} and R_{B13} not being the single bond bonded to *1, not forming the substituted or unsubstituted monocyclic ring, and not forming the substituted or unsubstituted fused ring are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms;
*2 is a bonding position to L₁₁, L₁₂ or L₁₃;
when two or more groups represented by the formula (1G) are present, the two or more groups represented by the formula (1G) are mutually the same or different;
in the compound represented by the formula (B₁₀₀), R₉₀₁, R₉₀₂, R₉₀₃ and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

44. The organic electroluminescence device according to claim 1, wherein the organic electroluminescence device satisfies Condition (TDM1), and the at least two low refractive index layers in direct contact in Condition (TDM1) contain mutually different compounds.

45. The organic electroluminescence device according to claim 1, wherein
the first emitting zone contains a first luminescent compound,
the second emitting zone contains a second luminescent compound,
the first luminescent compound and the second luminescent compound are mutually the same or different, and
one or both of the first luminescent compound and the second luminescent compound are compounds that emit light having a maximum peak wavelength of 500 nm or less.

46. The organic electroluminescence device according to claim 1, wherein the two or more emitting units further include a third emitting unit.

47. The organic electroluminescence device according to claim 1, wherein when the organic electroluminescence device satisfies Condition (TDM1) and an absolute value of a difference between the refractive indices of two organic materials is defined as Δn, at least one Δn is less than 0.10, the two organic materials being selected from the group consisting of the organic materials respectively contained in the at least two low refractive index layers in direct contact in Condition (TMD1).

48. The organic electroluminescence device according to claim 1, wherein the organic electroluminescence device satisfies Condition (TDM1), and a total film thickness of the at least two low refractive index layers in direct contact in Condition (TDM1) is 100 nm or less.

49. An electronic device comprising the organic electroluminescence device according to claim 1.
